(19) United States
(12) Patent Application Publication
(10) Pub. No.: US 2026/0002074 A1
(43) Pub. Date: Jan. 1, 2026

(54) ELECTRONIC DEVICE

(71) Applicant: Merck Patent GmbH, Darmstadt (DE)

(72) Inventors: Jens ENGELHART, Darmstadt (DE); Sebastian Meyer, Darmstadt (DE); Aaron Lackner, Darmstadt (DE); Lara-Isabel Rodriguez, Darmstadt (DE); Rémi Manouk Anémian, Frankfurt am Main (DE); Florian Maier-Flaig, Darmstadt (DE)

(21) Appl. No.: 19/326,811

(22) Filed: Sep. 12, 2025

Related U.S. Application Data
(63) Continuation of application No. 17/298,545, filed on May 29, 2021.

(30) Foreign Application Priority Data
Nov. 29, 2018 (EP) 18209047.2

(51) Int. Cl. C09K 11/06; C09K 11/02; H10K 50/11; H10K 50/15; H10K 50/16; H10K 85/30; H10K 85/60; H10K 101/10

(52) U.S. Cl. CPC C09K 11/06; C09K 11/02; H10K 85/30; H10K 85/615; H10K 85/624; H10K 85/626; H10K 85/654; H10K 85/6574; H10K 85/658; C09K 2211/1007; C09K 2211/1014; C09K 2211/1018; H10K 50/11; H10K 50/15; H10K 50/16; H10K 2101/10

(57) ABSTRACT

The invention relates to an electronic device, to the use thereof, and to a method for the production thereof.

The present application relates to an electronic device comprising emitting compounds of a particular structure type in an emitting layer, and comprising particular fluorenyl or spirobifluorenyl compounds in another layer. The other layer is preferably an electron-transporting layer.

Electronic devices in the context of this application are understood to mean what are called organic electronic devices, which comprise organic semiconductor materials as functional materials. More particularly, these are understood to mean OLEDs (organic electroluminescent devices). The term OLEDs is understood to mean electronic devices which have one or more layers comprising organic compounds and emit light on application of electrical voltage. The construction and general principle of function of OLEDs are known to those skilled in the art.

In electronic devices, especially OLEDs, there is continuing great interest in an improvement in the performance data.

Known materials for electron-transporting layers in electronic devices are a multitude of different materials. An important substance class is that of compounds having a group selected from spirobifluorene and fluorene, and a group selected from electron-deficient nitrogen-containing heteroaromatics, especially triazine and pyrimidine.

Known emitting compounds in electronic devices are likewise a multitude of different compounds. Essentially fluorescent compounds are employed for this use, for example indenofluorenamine derivatives, or phosphorescent compounds typically selected from transition metal complexes with an organometallic bond, especially iridium complexes such as Ir(PPy)₃ (tris[2-phenylpyridinato-C²,N]iridium(III)). Fluorescent compounds used have also been bridged triarylboron compounds with a particular structure. For these compounds, in particular constructions, a high external quantum efficiency has been found when they are used as emitters in OLEDs.

There is therefore a great interest in combining these compounds in a suitable manner with other compounds in other layers of the electronic device in order to achieve good properties of the electronic device, especially in relation to lifetime, efficiency, operating voltage, low roll-off and a narrow emission band, i.e. an emission band with a very low half-height width.

It has now been found that the combination of the abovementioned triarylboron derivatives in an emitting layer with particular spirobifluorenyl derivatives and fluorenyl derivatives in another layer leads to particularly good properties of the electronic device. More particularly, long lifetime, high efficiency, low operating voltage, low roll-off and emission with a minimum half-height width were found to be advantageous properties.

The present invention thus provides an electronic device comprising a first electrode, a second electrode and, arranged inbetween,
an emitting layer comprising a compound of a formula (EM-1)

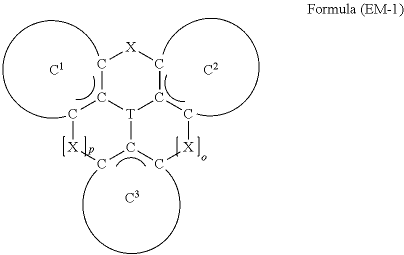

for which:
T is B, P, P(═O) or SiR^{E1},
X is the same or different at each instance and is selected from O, S, NR^{E2} and C(R^{E2})₂, where there must be at least one X present which is selected from O, S and NR^{E2}.
C¹, C² and C³ are the same or different and are selected from ring systems which have 5 to 40 ring atoms and are substituted by R^{E3} radicals;
R^{E1} is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where the alkyl, alkoxy, alkenyl and alkynyl groups mentioned and the aromatic ring systems and heteroaromatic ring systems mentioned are each substituted by R^{E4} radicals; and where one or more CH₂ groups in the alkyl, alkoxy, alkenyl and alkynyl groups mentioned may be replaced by —R^{E4}C═CR^{E4}—, —C≡C—, —Si(R^{E4})₂, C═O, C═NR^{E4}, —C(═O)O—, —C(═O)NR^{E4}—, NR^{E4}, P(═O)(R^{E4}), —O—, —S—, SO or SO₂;
R^{E2} is the same or different at each instance and is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where the alkyl, alkoxy, alkenyl and alkynyl groups mentioned and the aromatic ring systems and heteroaromatic ring systems mentioned are each substituted by R^{E4} radicals; and where one or more CH₂ groups in the alkyl, alkoxy, alkenyl and alkynyl groups mentioned may be replaced by —R^{E4}C═CR^{E4}—, —C≡C—, Si(R^{E4})₂, C═O, C═NR^{E4}, —C(═O)O—, —C(═O)NR^{E4}—, NR^{E4}, P(═O)(R^{E4}), —O—, —S—, SO or SO₂; where two or more R^{E2} radicals may be joined to one another and may form a ring, and where one or more R^{E2} radicals may be joined via their R^{E4} radicals to a ring selected from C¹, C² and C³ and may form a ring;
R^{E3} is the same or different at each instance and is selected from H, D, F, Cl, Br, I, C(═O)R^{E4}, CN, Si(R^{E4})₃, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E3} radicals may be joined to one another and may form a ring; where the alkyl, alkoxy, alkenyl and alkynyl groups mentioned and the aromatic ring systems and heteroaromatic ring systems mentioned are each substituted by R^{E4} radicals; and where one or more CH₂ groups in the alkyl, alkoxy, alkenyl and alkynyl groups mentioned may be replaced by —R^{E4}C═CR^{E4}—, —C≡C—, Si(R^{E4})₂, C═O, C═NR^{E4}, —C(═O)O—, —C(═O)NR^{E4}—, NR^{E4}, P(═O)(R^{E4}), —O—, —S—, SO or SO₂;
R^{E4} is the same or different at each instance and is selected from H, D, F, Cl, Br, I, C(═O)R^{E5}, CN, Si(R^{E5})₃, N(R^{E5})₂, P(═O)(R^{E5})₂, OR^{E5}, S(═O)R^{E}s S(═O)₂R^{E5}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E4} radicals may be joined to one another and may form a ring; where the alkyl, alkoxy, alkenyl and alkynyl groups mentioned and the aromatic ring systems and heteroaromatic ring systems mentioned are each substituted by R^{E5} radicals; and where one or more CH₂ groups in the alkyl, alkoxy, alkenyl and alkynyl groups mentioned may be replaced by —R^{E5}C═CR^{E5}—, —C≡C—, Si(R^{E5})₂, C═O, C═NR^{E5}, —C(═O)O—, —C(═O)NR^{E5}—, NR^{E5}, P(═O)(R^{E5}), —O—, —S—, SO or SO₂;
R^{E5} is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R^{E5} radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
o and p are the same or different and are 0 or 1, where p=0 and o=0 mean that the X group indicated by p or o together with its bonds to the rings C¹, C² and C³ is absent;
   a layer E which is disposed between the emitting layer and the second electrode and comprises a compound of a formula (E-1)

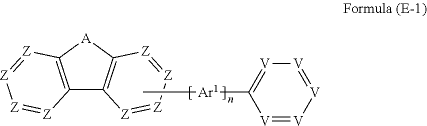

where
A is

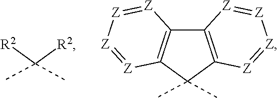

O or S, where the dotted bonds indicate the bonds of A to the rest of the formula;
Z, when no

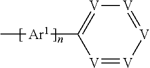

group is bonded thereto, is the same or different at each instance and is N and CR¹, and, when a

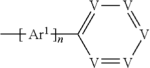

group is bonded thereto, is C;
V is the same or different at each instance and is selected from N and CR⁴, where at least two V groups in the ring must be N;
Ar¹ is the same or different at each instance and is selected from aromatic ring systems which have 6 to 40 aromatic ring atoms and are substituted by R³ radicals, and heteroaromatic ring systems which have 5 to 40 aromatic ring atoms and are substituted by R³ radicals;
R¹ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals may be joined to one another and may form a ring; where the alkyl, alkoxy, alkenyl and alkynyl groups mentioned and the aromatic ring systems and heteroaromatic ring systems mentioned are each substituted by R⁵ radicals; and where one or more CH₂ groups in the alkyl, alkoxy, alkenyl and alkynyl groups mentioned may be replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R² is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R² radicals may be joined to one another and may form a ring; where the alkyl, alkoxy, alkenyl and alkynyl groups mentioned and the aromatic ring systems and heteroaromatic ring systems mentioned are each substituted by R⁵ radicals; and where one or more CH₂ groups in the alkyl, alkoxy, alkenyl and alkynyl groups mentioned may be replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R³ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals may be joined to one another and may form a ring; where the alkyl, alkoxy, alkenyl and alkynyl groups mentioned and the aromatic ring systems and heteroaromatic ring systems mentioned are each substituted by R⁵ radicals; and where one or more CH₂ groups in the alkyl, alkoxy, alkenyl and alkynyl groups mentioned may be replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R⁴ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals may be joined to one another and may form a ring; where the alkyl, alkoxy, alkenyl and alkynyl groups mentioned and the aromatic ring systems and heteroaromatic ring systems mentioned are each substituted by R⁵ radicals; and where one or more CH₂ groups in the alkyl, alkoxy, alkenyl and alkynyl groups mentioned may be replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R⁵ is the same or different at each instance and is selected from H, D, F, Cl, Br, I, C(═O)R⁶, CN, Si(R⁶)₃, N(R⁶)₂, P(═O)(R⁶)₂, OR⁶, S(═O)R⁶, S(═O)₂R⁶, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁵ radicals may be joined to one another and may form a ring; where the alkyl, alkoxy, alkenyl and alkynyl groups mentioned and the aromatic ring systems and heteroaromatic ring systems mentioned are each substituted by R⁶ radicals; and where one or more CH₂ groups in the alkyl, alkoxy, alkenyl and alkynyl groups mentioned may be replaced by —R⁶C═CR⁶—, —C≡C—, Si(R⁶)₂, C═O, C═NR⁶, —C(═O)O—, —C(═O)NR⁶—, NR⁶, P(═O)(R⁶), —O—, —S—, SO or SO₂;
R⁶ is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁶ radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
n is 0, 1, 2, 3 or 4.

The “C” groups in formula (EM-1) indicate carbon atoms that are part of the ring systems C¹, C² and C³. The arc between the carbon atoms indicates that double bonds are present in such a way that each carbon atom has four bonds and each has three groups bonded thereto.

In the case that n=0, the Ar¹ group is absent and the two groups bonded to the Ar¹ group in formula (E-1) are bonded directly to one another. In the case that n=2, 3 or 4, there are 2, 3 or 4 Ar¹ groups bonded in succession.

The definitions which follow are applicable to the chemical groups that are used in the present application. They are applicable unless any more specific definitions are given.

The term “ring system” is understood to mean any desired rings that may be individual rings or a system comprising multiple individual rings fused to one another, as is the case, for example, in decalin or fluorene. The rings may be the same or different and may be aliphatic, heteroaliphatic, aromatic or heteroaromatic. The ring atoms may be selected from carbon and heteroatoms, especially C, O, S, Si, B, P and N.

An aryl group in the context of this invention is understood to mean either a single aromatic cycle, i.e. benzene, or a fused aromatic polycycle, for example naphthalene, phenanthrene or anthracene. A fused aromatic polycycle in the context of the present application consists of two or more single aromatic cycles fused to one another. Fusion between cycles is understood here to mean that the cycles share at least one edge with one another. An aryl group in the context of this invention contains 6 to 40 aromatic ring atoms of which none is a heteroatom.

A heteroaryl group in the context of this invention is understood to mean either a single heteroaromatic cycle, for example pyridine, pyrimidine or thiophene, or a fused heteroaromatic polycycle, for example quinoline or carbazole. A fused heteroaromatic polycycle in the context of the present application consists of two or more single aromatic or heteroaromatic cycles that are fused to one another, where at least one of the aromatic and heteroaromatic cycles is a heteroaromatic cycle. Fusion between cycles is understood here to mean that the cycles share at least one edge with one another. A heteroaryl group in the context of this invention contains 5 to 40 aromatic ring atoms of which at least one is a heteroatom. The heteroatoms of the heteroaryl group are preferably selected from N, O and S.

An aryl or heteroaryl group, each of which may be substituted by the abovementioned radicals, is especially understood to mean groups derived from benzene, naphthalene, anthracene, phenanthrene, pyrene, dihydropyrene, chrysene, perylene, triphenylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, benzimidazolo[1,2-a]benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aromatic ring system in the context of this invention is a system which does not necessarily contain solely aryl groups, but which may additionally contain one or more nonaromatic rings fused to at least one aryl group. These nonaromatic rings contain exclusively carbon atoms as ring atoms. Examples of groups covered by this definition are tetrahydronaphthalene, fluorene and spirobifluorene. In addition, the term “aromatic ring system” includes systems that consist of two or more aromatic ring systems joined to one another via single bonds, for example biphenyl, terphenyl, 7-phenyl-2-fluorenyl, quaterphenyl and 3,5-diphenyl-1-phenyl. An aromatic ring system in the context of this invention contains 6 to 40 carbon atoms and no heteroatoms in the ring system. The definition of “aromatic ring system” does not include heteroaryl groups.

A heteroaromatic ring system conforms to the abovementioned definition of an aromatic ring system, except that it must contain at least one heteroatom as ring atom. As is the case for the aromatic ring system, the heteroaromatic ring system need not contain exclusively aryl groups and heteroaryl groups, but may additionally contain one or more nonaromatic rings fused to at least one aryl or heteroaryl group. The nonaromatic rings may contain exclusively carbon atoms as ring atoms, or they may additionally contain one or more heteroatoms, where the heteroatoms are preferably selected from N, O and S. One example of such a heteroaromatic ring system is benzopyranyl. In addition, the term “heteroaromatic ring system” is understood to mean systems that consist of two or more aromatic or heteroaromatic ring systems that are bonded to one another via single bonds, for example 4,6-diphenyl-2-triazinyl. A heteroaromatic ring system in the context of this invention contains 5 to 40 ring atoms selected from carbon and heteroatoms, where at least one of the ring atoms is a heteroatom. The heteroatoms of the heteroaromatic ring system are preferably selected from N, O and S.

The terms “heteroaromatic ring system” and “aromatic ring system” as defined in the present application thus differ from one another in that an aromatic ring system cannot have a heteroatom as ring atom, whereas a heteroaromatic ring system must have at least one heteroatom as ring atom. This heteroatom may be present as a ring atom of a nonaromatic heterocyclic ring or as a ring atom of an aromatic heterocyclic ring.

In accordance with the above definitions, any aryl group is covered by the term “aromatic ring system”, and any heteroaryl group is covered by the term “heteroaromatic ring system”.

An aromatic ring system having 6 to 40 aromatic ring atoms or a heteroaromatic ring system having 5 to 40 aromatic ring atoms is especially understood to mean groups derived from the groups mentioned above under aryl groups and heteroaryl groups, and from biphenyl, terphenyl, quaterphenyl, fluorene, spirobifluorene, dihydrophenanthrene, dihydropyrene, tetrahydropyrene, indenofluorene, truxene, isotruxene, spirotruxene, spiroisotruxene, indenocarbazole, or from combinations of these groups.

In the context of the present invention, a straight-chain alkyl group having 1 to 20 carbon atoms and a branched or cyclic alkyl group having 3 to 20 carbon atoms and an alkenyl or alkynyl group having 2 to 40 carbon atoms in which individual hydrogen atoms or CH₂ groups may also be substituted by the groups mentioned above in the definition of the radicals are preferably understood to mean the methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl radicals.

An alkoxy or thioalkyl group having 1 to 20 carbon atoms in which individual hydrogen atoms or CH₂ groups may also be replaced by the groups mentioned above in the definition of the radicals is preferably understood to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio.

The wording that two or more radicals together may form a ring, in the context of the present application, shall be understood to mean, inter alia, that the two radicals are joined to one another by a chemical bond. In addition, however, the abovementioned wording shall also be understood to mean that, if one of the two radicals is hydrogen, the second radical binds to the position to which the hydrogen atom was bonded, forming a ring.

T is preferably B.

X is preferably the same at each instance. More preferably, X is the same at each instance and is NR^{E2}. More preferably, at least one of the indices o and p is 1, such that at least two X groups are present in the formula (EM-1), and at least two X groups in the formula (EM-1) are selected from O, S and NR^{E}, more preferably NR^{E}.

C¹, C² and C³ are preferably the same at each instance. They are further preferably selected from ring systems in which the ring atoms are selected from C, Si, N, P, O, S, B. The ring systems may be aliphatic, aromatic, heteroaliphatic or heteroaromatic. Preferably, the individual ring containing the carbon atoms shown in formula (EM-1) is aromatic or heteroaromatic, more preferably aromatic.

Preferably, C¹, C² and C³ are aromatic or heteroaromatic, more preferably aromatic. C¹, C² and C³ are preferably the same or different at each instance, preferably the same, and are selected from benzene, naphthalene, fluorene, carbazole, dibenzofuran and dibenzothiophene, each substituted by R^{E3} radicals. More preferably, C¹, C² and C³ are benzene in each case substituted by R^{E3} radicals.

Preferably, R^{E1} is an aromatic or heteroaromatic ring system substituted by one or more R^{E4} radicals.

Preferably, R^{E2} is the same or different at each instance and is selected from straight-chain alkyl groups having 1 to 20 carbon atoms, branched or cyclic alkyl groups having 3 to 20 carbon atoms, aromatic ring systems having 6 to 40 aromatic ring atoms, and heteroaromatic ring systems having 5 to 40 aromatic ring atoms; where the alkyl groups mentioned and the aromatic ring systems and heteroaromatic ring systems mentioned are each substituted by R^{E4} radicals, where two or more R^{E2} radicals may be joined to one another and may form a ring, and where one or more R^{E2} radicals may be joined via their R^{E4} radicals to a ring selected from C¹, C² and C³ and may form a ring. More preferably, R^{E2} is the same or different at each instance and is selected from aromatic ring systems which have 6 to 40 aromatic ring atoms and are each substituted by R^{E4} radicals, where two or more R^{E2} radicals may be joined to one another and may form a ring and where one or more R^{E2} radicals may be joined via their R^{E4} radicals to a ring selected from C¹, C² and C³ and may form a ring.

In a preferred embodiment, the R^{E2} radicals selected are the same at each instance. In addition, in a preferred embodiment, C¹, C², C³ and all R^{E2} radicals selected are the same, especially phenyl that may have appropriate substitution, in which case preferably all phenyl groups in question have the same substitution.

Preferably, R^{E3} is the same or different at each instance and is selected from H, D, F, CN, Si(R^{E4})₃, N(R^{E4})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{E4} radicals; and where one or more CH₂ groups in the alkyl or alkoxy groups mentioned may be replaced by —C≡C—, —R^{E4}C═CR^{E4}—, Si(R^{E4})₂, C═O, C═NR^{E4}, —NR^{E4}—, —O—, —S—, —C(═O)O— or —C(═O)NR^{E4}—.

More preferably, at least one R^{E3} radical in formula (EM-1) is selected from alkyl groups having 1 to 10 carbon atoms, N(R^{E4})₂, aromatic ring systems having 6 to 40 aromatic ring atoms, and heteroaromatic ring systems having 5 to 40 aromatic ring atoms, where the alkyl groups mentioned, the aromatic ring systems mentioned and the heteroaromatic ring systems mentioned are each substituted by R^{E4} radicals. Most preferably, at least one R^{E3} radical in formula (EM-1) is selected from alkyl groups which have 1 to 10 carbon atoms and are substituted by R^{E4} radicals, and N(R^{E4})₂.

Preferably, R^{E4} is the same or different at each instance and is selected from H, D, F, CN, Si(R^{E5})₃, N(R^{E5})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{E5} radicals; and where one or more CH₂ groups in the alkyl or alkoxy groups mentioned may be replaced by —C≡C—, —R^{E5}=CR^{E5}—, Si(R^{E5})₂, C═O, C═NR^{E5}, —NR^{E5}—, —O—, —S—, —C(═O)O— or —C(═O)NR^{E5}.

Preferably, at least one of the indices o and p is 1. More preferably, one of the indices o and p is 1, and the other of the indices o and p is 0.

Preferably, the compound of the formula (EM-1) is a mirror-symmetric compound of a formula (EM-1S)

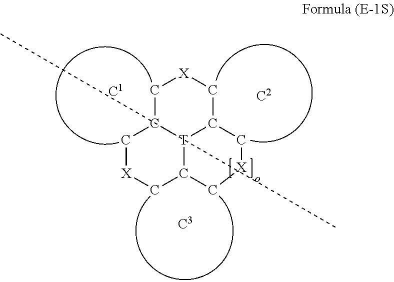

where the X groups selected are the same, the C² and C³ groups selected are the same, and all the groups that occur are selected such that the compound is mirror-symmetric, with a mirror plane that includes the dotted line and is at right angles to the plane of the paper.

In a preferred embodiment of the invention, the compound of the formula (EM-1) conforms to the formula (EM-1-1)

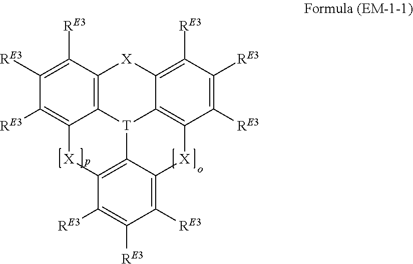

where the variables that occur are as defined above.

In a preferred embodiment, the compound of the formula (EM-1-1) conforms to a mirror-symmetric compound of the formula (EM-1-1S)

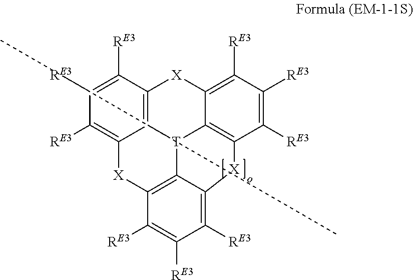

where the X groups selected are the same, and all the groups that occur are selected such that the compound is mirror-symmetric, with a mirror plane that includes the dotted line and is at right angles to the plane of the paper.

In an alternative preferred embodiment, the compound of the formula (EM-1-1) is not mirror-symmetric in the mirror plane shown in formula (EM-1-1S).

It is especially preferred when, in formula (EM-1-1),
T is B, and/or
X is NR^{E2}, and/or
one of the indices p and o is 1, and the other of the indices p and o is 0.
at least one R^{E3} radical is selected from alkyl groups having 1 to 10 carbon atoms, N(R^{E4})₂, aromatic ring systems having 6 to 40 aromatic ring atoms, and heteroaromatic ring systems having 5 to 40 aromatic ring atoms, where the alkyl groups mentioned, the aromatic ring systems mentioned and the heteroaromatic ring systems mentioned are each substituted by R^{E4} radicals.

Preferably, in formula (EM-1-1), R^{E2} is phenyl substituted by R^{E4} radicals.

Most preferably, at least one R^{E3} radical in formula (EM-1-1) is selected from alkyl groups which have 1 to 10 carbon atoms and are substituted by R^{E4} radicals, and N(R^{E4})₂.

Particular preference is given to the formula (EM-1-1-1).

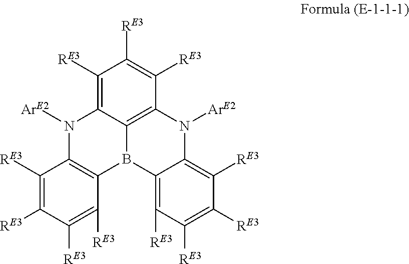

where Ar^{E2} is the same or different at each instance and is selected from aromatic ring systems which have 6 to 40 aromatic ring atoms and are substituted by R^{E4}, and heteroaromatic ring systems which have 5 to 40 aromatic ring atoms and are substituted by R^{E4}, more preferably phenyl or biphenyl, each substituted by R^{E4} radicals. In a preferred embodiment, the Ar^{E2} radicals selected are the same at each instance. In an alternative preferred embodiment, the Ar^{E2} radicals selected are different at each instance.

The other variables that occur are as defined above.

Preferably, in the formula, at least one R^{E3} radical is selected from alkyl groups having 1 to 10 carbon atoms, N(R^{E4})₂, aromatic ring systems having 6 to 40 aromatic ring atoms, and heteroaromatic ring systems having 5 to 40 aromatic ring atoms, where the alkyl groups mentioned, the aromatic ring systems mentioned and the heteroaromatic ring systems mentioned are each substituted by R^{E4} radicals. Most preferably, at least one R^{E3} radical in the formula is selected from alkyl groups which have 1 to 10 carbon atoms and are substituted by R^{E4} radicals, and N(R^{E4})₂.

In a preferred embodiment, the compound of the formula (EM-1-1-1) is mirror-symmetric in a mirror plane which is at right angles to the plane of the paper and includes the bond from the boron to the uppermost of the three phenyl groups shown. Preferably, in this case, in formula (EM-1-1-1), R^{E2} is phenyl or biphenyl, each substituted by R^{E4} radicals.

In an alternative preferred embodiment, the compound of the formula (EM-1-1-1) is not mirror-symmetric in a mirror plane which is at right angles to the plane of the paper and includes the bond from the boron to the uppermost of the three phenyl groups shown. Preferably, in this case, in formula (EM-1-1-1), R^{E2} is the same or different and is selected from phenyl and biphenyl, each substituted by R^{E4} radicals.

Very particular preference is given to the formulae (EM-1-1-1-1) and (EM-1-1-1-2)

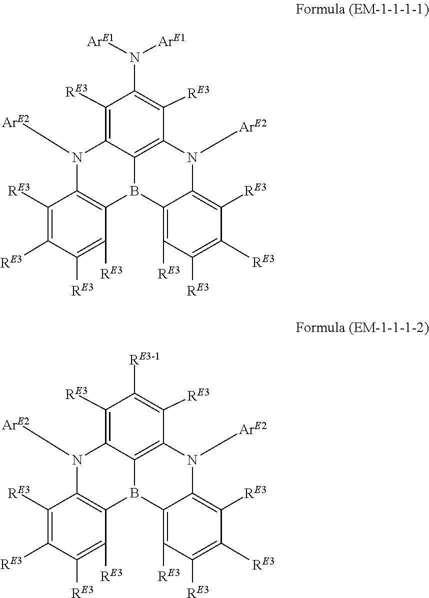

where Ar^{E1} is the same or different at each instance and is selected from aromatic ring systems which have 6 to 40 aromatic ring atoms and are substituted by R^{E5}, and heteroaromatic ring systems which have 5 to 40 aromatic ring atoms and are substituted by R^{E5}, and

where Ar^{E2} is the same or different at each instance and is selected from aromatic ring systems which have 6 to 40 aromatic ring atoms and are substituted by R^{E4}, and heteroaromatic ring systems which have 5 to 40 aromatic ring atoms and are substituted by R^{E4}, more preferably phenyl or biphenyl, each substituted by R^{E4} radicals, and where R^{E3-1} is selected from alkyl groups which have 1 to 10 carbon atoms and are substituted by R^{E4} radicals, preferably methyl, ethyl, n-propyl, i-propyl and tert-butyl, more preferably methyl.

The other variables that occur are as defined above.

Ar^{E1} is preferably the same or different at each instance and is selected from phenyl, biphenyl, terphenyl, fluorenyl, naphthyl, dibenzofuranyl, dibenzothiophenyl and carbazolyl, each substituted by R^{E5} radicals, and combinations of two or more of these groups. More preferably, Ar^{E1} is the same or different at each instance and is selected from phenyl, o-biphenyl, m-biphenyl, p-biphenyl, terphenyl, p-tolyl, m-tolyl, o-tolyl, p-tert-butyl-phenyl, m-tert-butyl-phenyl, o-tert-butyl-phenyl, 9,9′-dimethylfluorenyl, 9,9′-diphenylfluorenyl, naphthyl, naphthyl, dibenzothiophenyl, dibenzofuranyl, naphthylphenylene, dibenzofuranylphenylene, dibenzothiophenylphenylene, carbazolylphenylene, especially N-carbazolylphenylene.

In a preferred embodiment, the compound of the formula (EM-1-1-1-1) or (EM-1-1-1-2) is mirror-symmetric in a mirror plane which is at right angles to the plane of the paper and includes the bond from the boron to the uppermost of the three phenyl groups shown. The two Ar^{E1} groups selected may be the same or different and are preferably the same.

In an alternative preferred embodiment, the compound of the formula (EM-1-1-1-1) or (EM-1-1-1-2) is not mirror-symmetric in a mirror plane which is at right angles to the plane of the paper and includes the bond from the boron to the uppermost of the three phenyl groups shown. The two Ar^{E1} groups selected may be the same or different and are preferably different.

Most preferred are the formulae (EM-1-1-1-1-1) and (EM-1-1-1-1-2)

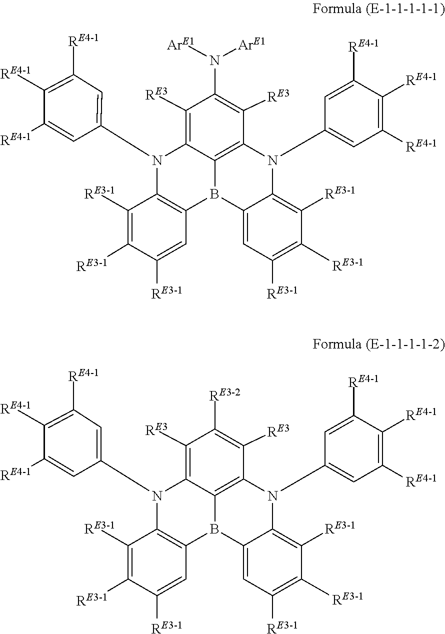

where R^{E3-1} is as defined for R^{E3}; and R^{E3-2} is selected from alkyl groups which have 1 to 10 carbon atoms and are substituted by R^{E4} radicals, preferably methyl, ethyl, isopropyl and tert-butyl, more preferably methyl; and R^{E4-1} is as defined for R^{E4}, and where the other variables are as defined above.

Preferably, in formula (EM-1-1-1-1-1) and (EM-1-1-1-1-2), R^{E3-1} and R^{E4-1} are the same or different at each instance and are selected from H, alkyl groups which have 1 to 10 carbon atoms and are substituted by R^{E4} or R^{E5} radicals and are preferably unsubstituted, and aromatic ring systems which have 6 to 40 ring atoms and are substituted by R^{E4} or R^{E5} radicals. Preferably, exactly one or two R^{E3-1} or R^{E4-1} radicals per benzene ring are selected from alkyl groups which have 1 to 10 carbon atoms and are substituted by R^{E4} or R^{E5} radicals and are preferably unsubstituted, and aromatic ring systems which have 6 to 40 ring atoms and are substituted by R^{E4} or R^{E5} radicals, and the other R^{E3-1} or R^{E4-1} radicals are H.

In a preferred embodiment, the units marked by a circle in formula (EM-1-1-1-1)

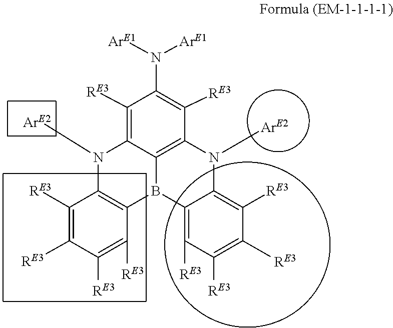

are each the same, and the units marked by a rectangle are likewise each the same. More preferably, all four marked units are the same.

Preferably, the units marked by circle and rectangle are the same or different, preferably the same, and are selected from appropriately substituted benzene, naphthalene, fluorene, dibenzofuran and dibenzothiophene. Particular preference is given to appropriately substituted benzene.

The compound of the formula (EM-1-1-1-1) can be depicted as compound A-B containing the two subunits A and B:

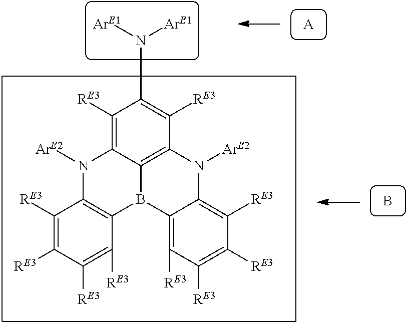

Preferred embodiments of the A unit are as follows (“B” in the formulae refers correspondingly to the B unit):

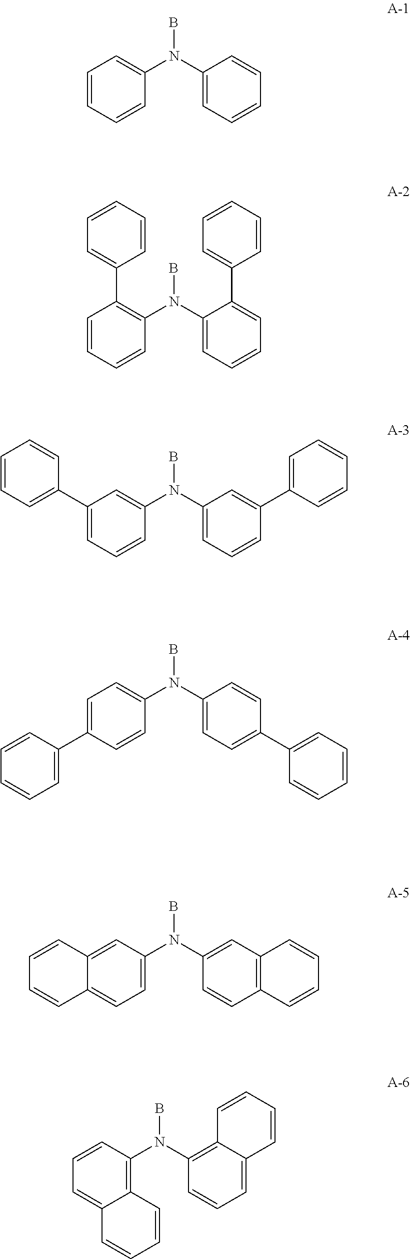

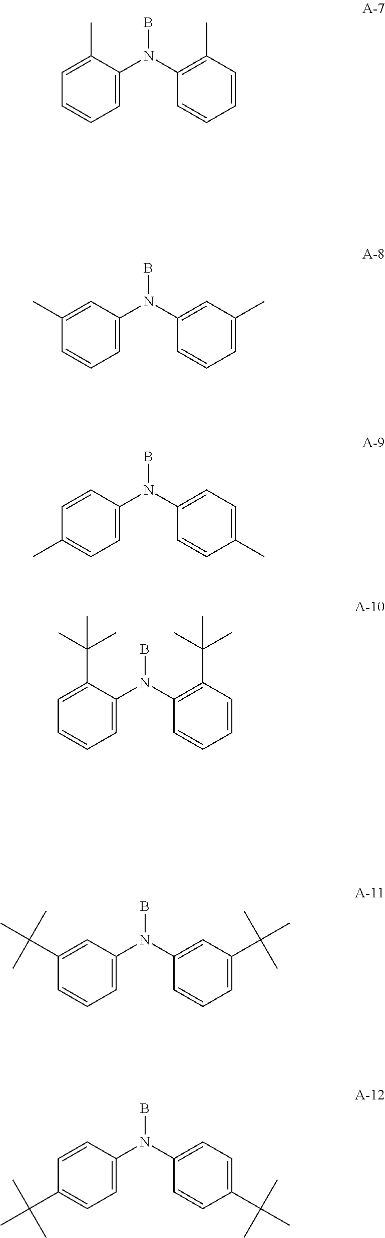

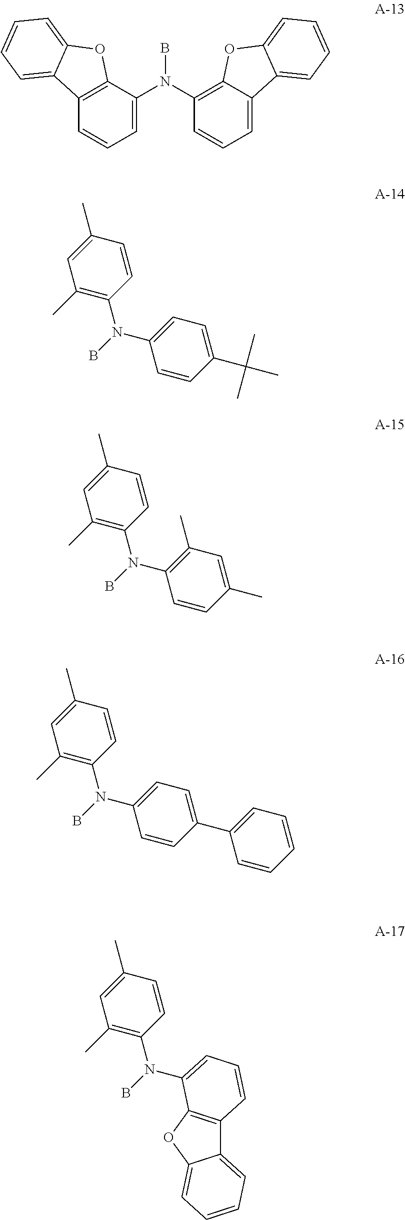

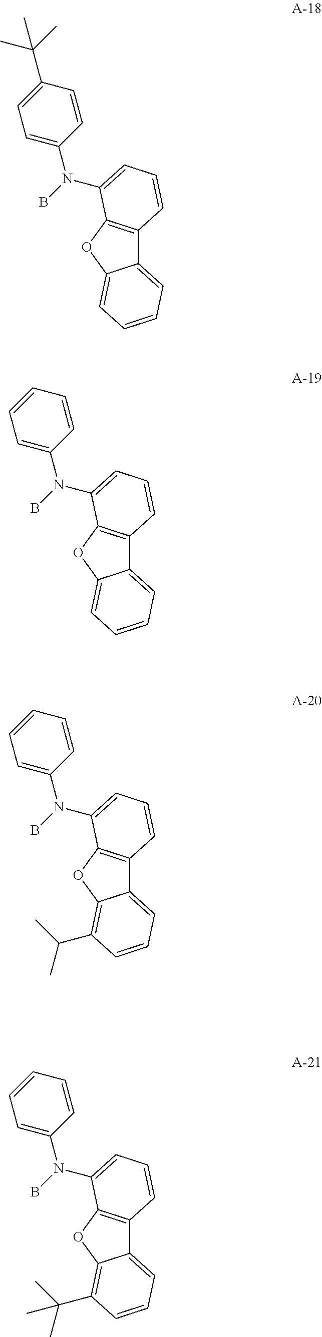

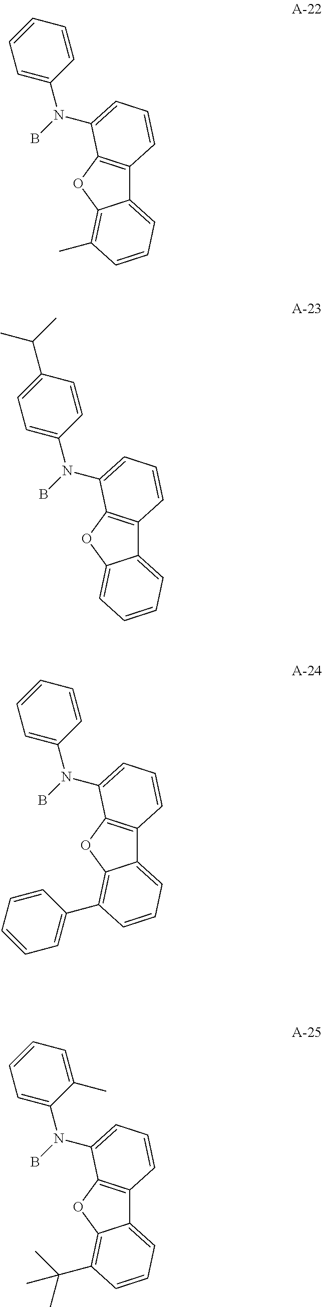

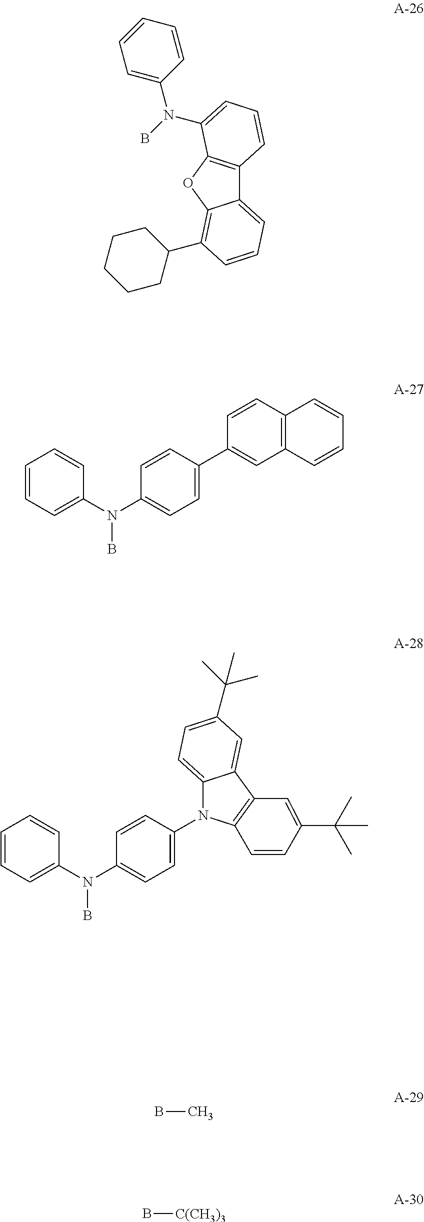

Preferred embodiments of the B unit are as follows (“A” in the formulae refers correspondingly to the A unit):

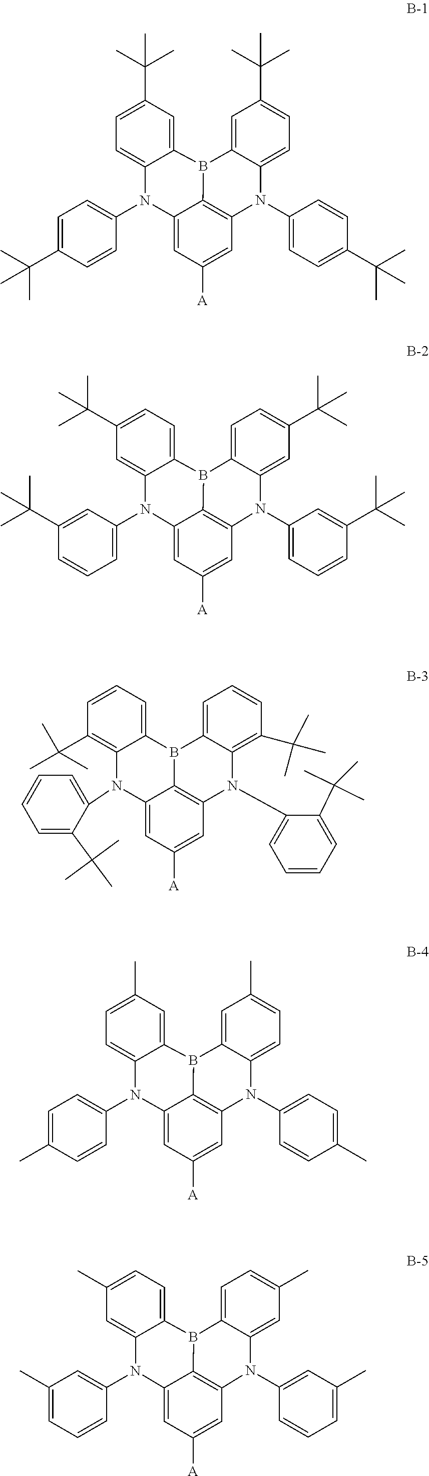

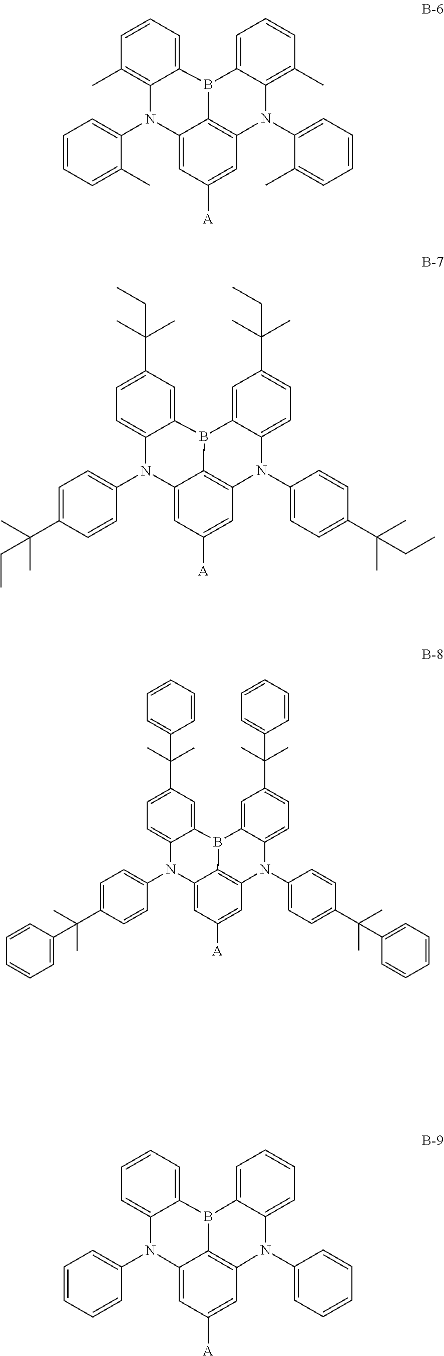

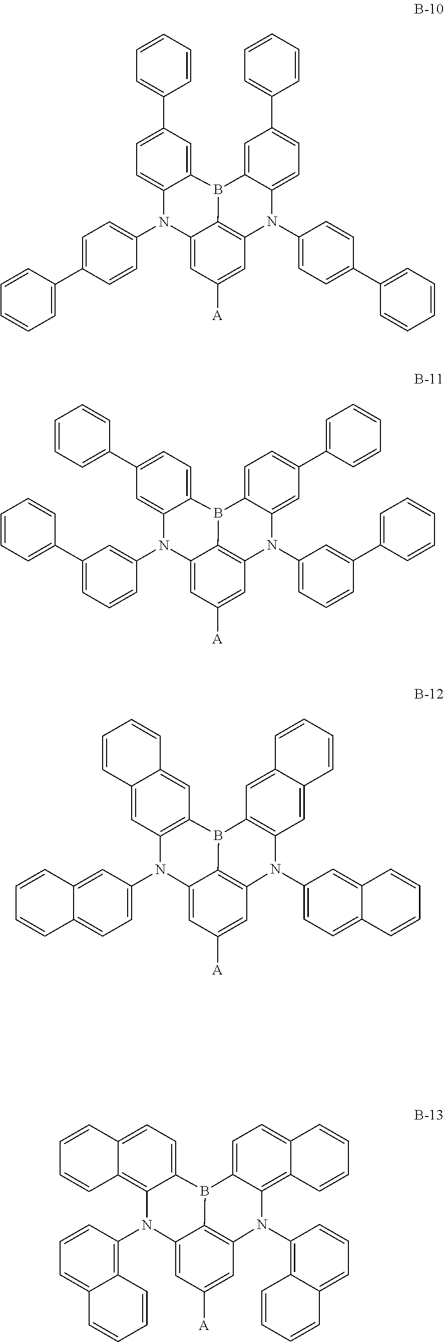

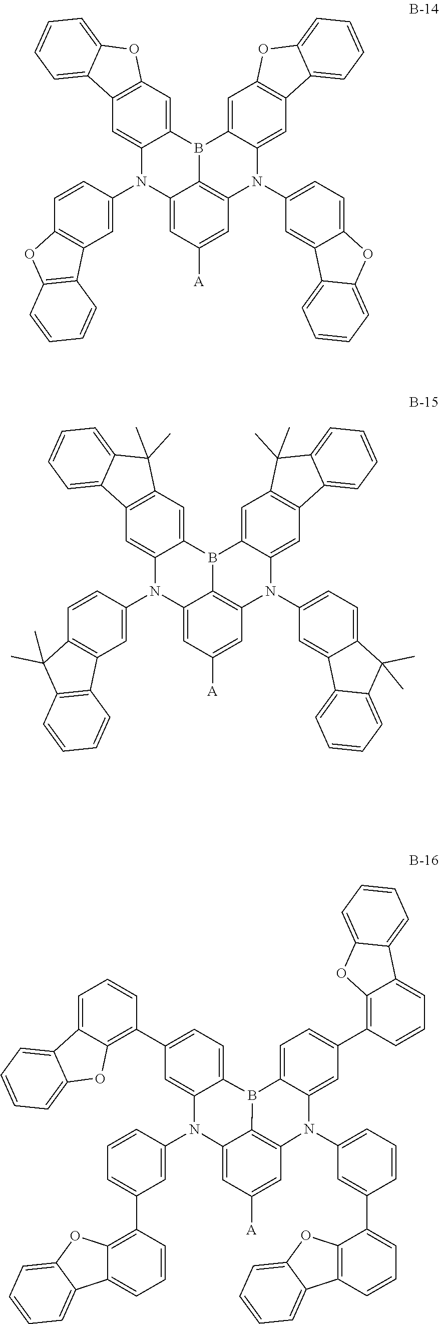

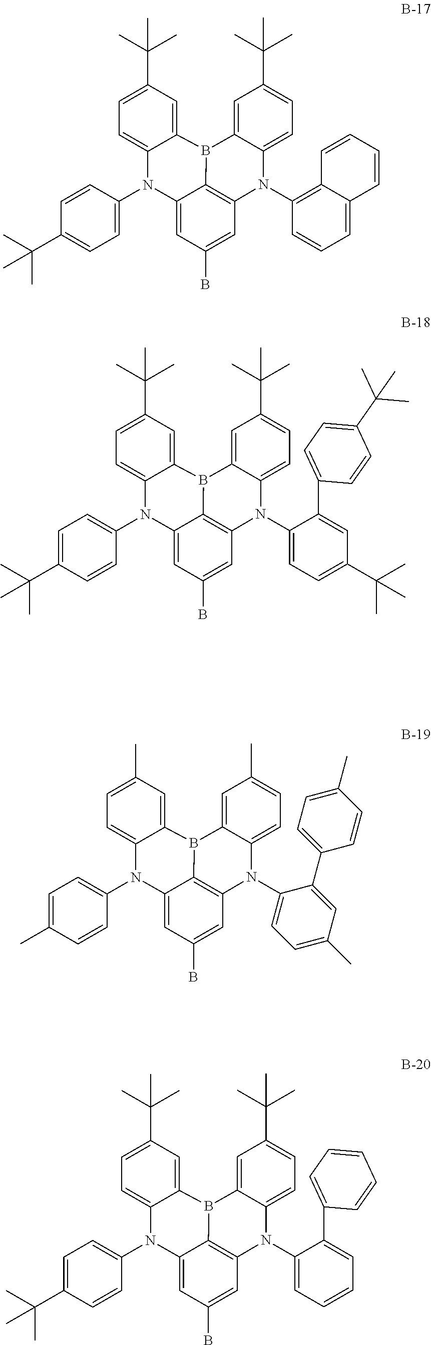

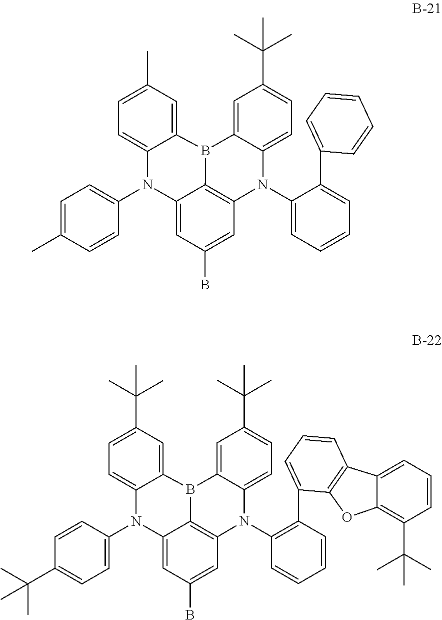

Preferred embodiments of the compounds of the formula (EM-1-1-1-1) are thus compounds of the following formulae in which part A and part B of the formula are selected as follows:

| Formula | | |
|---|---|---|
| (EM-1-1-1-1-X) | | |
| with X= | Part A | Part B |
| 1 | A-1 | B-1 |
| 2 | A-1 | B-2 |
| 3 | A-1 | B-3 |
| 4 | A-1 | B-4 |
| 5 | A-1 | B-5 |
| 6 | A-1 | B-6 |
| 7 | A-1 | B-7 |
| 8 | A-1 | B-8 |
| 9 | A-1 | B-9 |
| 10 | A-1 | B-10 |
| 11 | A-1 | B-11 |
| 12 | A-1 | B-12 |
| 13 | A-1 | B-13 |
| 14 | A-1 | B-14 |
| 15 | A-1 | B-15 |
| 16 | A-1 | B-16 |
| 17 | A-1 | B-17 |
| 18 | A-1 | B-18 |
| 19 | A-1 | B-19 |
| 20 | A-1 | B-20 |
| 21 | A-1 | B-21 |
| 22 | A-1 | B-22 |
| 23 | A-2 | B-1 |
| 24 | A-2 | B-2 |
| 25 | A-2 | B-3 |
| 26 | A-2 | B-4 |
| 27 | A-2 | B-5 |
| 28 | A-2 | B-6 |
| 29 | A-2 | B-7 |
| 30 | A-2 | B-8 |
| 31 | A-2 | B-9 |
| 32 | A-2 | B-10 |
| 33 | A-2 | B-11 |
| 34 | A-2 | B-12 |
| 35 | A-2 | B-13 |
| 36 | A-2 | B-14 |
| 37 | A-2 | B-15 |
| 38 | A-2 | B-16 |
| 39 | A-2 | B-17 |
| 40 | A-2 | B-18 |
| 41 | A-2 | B-19 |
| 42 | A-2 | B-20 |
| 43 | A-2 | B-21 |
| 44 | A-2 | B-22 |
| 45 | A-3 | B-1 |
| 46 | A-3 | B-2 |
| 47 | A-3 | B-3 |
| 48 | A-3 | B-4 |
| 49 | A-3 | B-5 |
| 50 | A-3 | B-6 |
| 51 | A-3 | B-7 |
| 52 | A-3 | B-8 |
| 53 | A-3 | B-9 |
| 54 | A-3 | B-10 |
| 55 | A-3 | B-11 |
| 56 | A-3 | B-12 |
| 57 | A-3 | B-13 |
| 58 | A-3 | B-14 |
| 59 | A-3 | B-15 |
| 60 | A-3 | B-16 |
| 61 | A-3 | B-17 |
| 62 | A-3 | B-18 |
| 63 | A-3 | B-19 |
| 64 | A-3 | B-20 |
| 65 | A-3 | B-21 |
| 66 | A-3 | B-22 |
| 67 | A-4 | B-1 |
| 68 | A-4 | B-2 |
| 69 | A-4 | B-3 |
| 70 | A-4 | B-4 |
| 71 | A-4 | B-5 |
| 72 | A-4 | B-6 |
| 73 | A-4 | B-7 |
| 74 | A-4 | B-8 |
| 75 | A-4 | B-9 |
| 76 | A-4 | B-10 |
| 77 | A-4 | B-11 |
| 78 | A-4 | B-12 |
| 79 | A-4 | B-13 |
| 80 | A-4 | B-14 |
| 81 | A-4 | B-15 |
| 82 | A-4 | B-16 |
| 83 | A-4 | B-17 |
| 84 | A-4 | B-18 |
| 85 | A-4 | B-19 |
| 86 | A-4 | B-20 |
| 87 | A-4 | B-21 |
| 88 | A-4 | B-22 |
| 89 | A-5 | B-1 |
| 90 | A-5 | B-2 |
| 91 | A-5 | B-3 |
| 92 | A-5 | B-4 |
| 93 | A-5 | B-5 |
| 94 | A-5 | B-6 |
| 95 | A-5 | B-7 |
| 96 | A-5 | B-8 |
| 97 | A-5 | B-9 |
| 98 | A-5 | B-10 |
| 99 | A-5 | B-11 |
| 100 | A-5 | B-12 |
| 101 | A-5 | B-13 |
| 102 | A-5 | B-14 |
| 103 | A-5 | B-15 |
| 104 | A-5 | B-16 |
| 105 | A-5 | B-17 |
| 106 | A-5 | B-18 |
| 107 | A-5 | B-19 |
| 108 | A-5 | B-20 |
| 109 | A-5 | B-21 |
| 110 | A-5 | B-22 |
| 111 | A-6 | B-1 |
| 112 | A-6 | B-2 |
| 113 | A-6 | B-3 |
| 114 | A-6 | B-4 |
| 115 | A-6 | B-5 |
| 116 | A-6 | B-6 |
| 117 | A-6 | B-7 |
| 118 | A-6 | B-8 |
| 119 | A-6 | B-9 |
| 120 | A-6 | B-10 |
| 121 | A-6 | B-11 |
| 122 | A-6 | B-12 |
| 123 | A-6 | B-13 |
| 124 | A-6 | B-14 |
| 125 | A-6 | B-15 |
| 126 | A-6 | B-16 |
| 127 | A-6 | B-17 |
| 128 | A-6 | B-18 |
| 129 | A-6 | B-19 |
| 130 | A-6 | B-20 |
| 131 | A-6 | B-21 |
| 132 | A-6 | B-22 |
| 133 | A-7 | B-1 |
| 134 | A-7 | B-2 |
| 135 | A-7 | B-3 |
| 136 | A-7 | B-4 |
| 137 | A-7 | B-5 |
| 138 | A-7 | B-6 |
| 139 | A-7 | B-7 |
| 140 | A-7 | B-8 |
| 141 | A-7 | B-9 |
| 142 | A-7 | B-10 |
| 143 | A-7 | B-11 |
| 144 | A-7 | B-12 |
| 145 | A-7 | B-13 |
| 146 | A-7 | B-14 |
| 147 | A-7 | B-15 |
| 148 | A-7 | B-16 |
| 149 | A-7 | B-17 |
| 150 | A-7 | B-18 |
| 151 | A-7 | B-19 |
| 152 | A-7 | B-20 |
| 153 | A-7 | B-21 |
| 154 | A-7 | B-22 |
| 155 | A-8 | B-1 |
| 156 | A-8 | B-2 |
| 157 | A-8 | B-3 |
| 158 | A-8 | B-4 |
| 159 | A-8 | B-5 |
| 160 | A-8 | B-6 |
| 161 | A-8 | B-7 |
| 162 | A-8 | B-8 |
| 163 | A-8 | B-9 |
| 164 | A-8 | B-10 |
| 165 | A-8 | B-11 |
| 166 | A-8 | B-12 |
| 167 | A-8 | B-13 |
| 168 | A-8 | B-14 |
| 169 | A-8 | B-15 |
| 170 | A-8 | B-16 |
| 171 | A-8 | B-17 |
| 172 | A-8 | B-18 |
| 173 | A-8 | B-19 |
| 174 | A-8 | B-20 |
| 175 | A-8 | B-21 |
| 176 | A-8 | B-22 |
| 177 | A-9 | B-1 |
| 178 | A-9 | B-2 |
| 179 | A-9 | B-3 |
| 180 | A-9 | B-4 |
| 181 | A-9 | B-5 |
| 182 | A-9 | B-6 |
| 183 | A-9 | B-7 |
| 184 | A-9 | B-8 |
| 185 | A-9 | B-9 |
| 186 | A-9 | B-10 |
| 187 | A-9 | B-11 |
| 188 | A-9 | B-12 |
| 189 | A-9 | B-13 |
| 190 | A-9 | B-14 |
| 191 | A-9 | B-15 |
| 192 | A-9 | B-16 |
| 193 | A-9 | B-17 |
| 194 | A-9 | B-18 |
| 195 | A-9 | B-19 |
| 196 | A-9 | B-20 |
| 197 | A-9 | B-21 |
| 198 | A-9 | B-22 |
| 199 | A-10 | B-1 |
| 200 | A-10 | B-2 |
| 201 | A-10 | B-3 |
| 202 | A-10 | B-4 |
| 203 | A-10 | B-5 |
| 204 | A-10 | B-6 |
| 205 | A-10 | B-7 |
| 206 | A-10 | B-8 |
| 207 | A-10 | B-9 |
| 208 | A-10 | B-10 |
| 209 | A-10 | B-11 |
| 210 | A-10 | B-12 |
| 211 | A-10 | B-13 |
| 212 | A-10 | B-14 |
| 213 | A-10 | B-15 |
| 214 | A-10 | B-16 |
| 215 | A-10 | B-17 |
| 216 | A-10 | B-18 |
| 217 | A-10 | B-19 |
| 218 | A-10 | B-20 |
| 219 | A-10 | B-21 |
| 220 | A-10 | B-22 |
| 221 | A-11 | B-1 |
| 222 | A-11 | B-2 |
| 223 | A-11 | B-3 |
| 224 | A-11 | B-4 |
| 225 | A-11 | B-5 |
| 226 | A-11 | B-6 |
| 227 | A-11 | B-7 |
| 228 | A-11 | B-8 |
| 229 | A-11 | B-9 |
| 230 | A-11 | B-10 |
| 231 | A-11 | B-11 |
| 232 | A-11 | B-12 |
| 233 | A-11 | B-13 |
| 234 | A-11 | B-14 |
| 235 | A-11 | B-15 |
| 236 | A-11 | B-16 |
| 237 | A-11 | B-17 |
| 238 | A-11 | B-18 |
| 239 | A-11 | B-19 |
| 240 | A-11 | B-20 |
| 241 | A-11 | B-21 |
| 242 | A-11 | B-22 |
| 243 | A-12 | B-1 |
| 244 | A-12 | B-2 |
| 245 | A-12 | B-3 |
| 246 | A-12 | B-4 |
| 247 | A-12 | B-5 |
| 248 | A-12 | B-6 |
| 249 | A-12 | B-7 |
| 250 | A-12 | B-8 |
| 251 | A-12 | B-9 |
| 252 | A-12 | B-10 |
| 253 | A-12 | B-11 |
| 254 | A-12 | B-12 |
| 255 | A-12 | B-13 |
| 256 | A-12 | B-14 |
| 257 | A-12 | B-15 |
| 258 | A-12 | B-16 |
| 259 | A-12 | B-17 |
| 260 | A-12 | B-18 |
| 261 | A-12 | B-19 |
| 262 | A-12 | B-20 |
| 263 | A-12 | B-21 |
| 264 | A-12 | B-22 |
| 265 | A-13 | B-1 |
| 266 | A-13 | B-2 |
| 267 | A-13 | B-3 |
| 268 | A-13 | B-4 |
| 269 | A-13 | B-5 |
| 270 | A-13 | B-6 |
| 271 | A-13 | B-7 |
| 272 | A-13 | B-8 |
| 273 | A-13 | B-9 |
| 274 | A-13 | B-10 |
| 275 | A-13 | B-11 |
| 276 | A-13 | B-12 |
| 277 | A-13 | B-13 |
| 278 | A-13 | B-14 |
| 279 | A-13 | B-15 |
| 280 | A-13 | B-16 |
| 281 | A-13 | B-17 |
| 282 | A-13 | B-18 |
| 283 | A-13 | B-19 |
| 284 | A-13 | B-20 |
| 285 | A-13 | B-21 |
| 286 | A-13 | B-22 |
| 287 | A-14 | B-1 |
| 288 | A-14 | B-2 |
| 289 | A-14 | B-3 |
| 290 | A-14 | B-4 |
| 291 | A-14 | B-5 |
| 292 | A-14 | B-6 |
| 293 | A-14 | B-7 |
| 294 | A-14 | B-8 |
| 295 | A-14 | B-9 |
| 296 | A-14 | B-10 |
| 297 | A-14 | B-11 |
| 298 | A-14 | B-12 |
| 299 | A-14 | B-13 |
| 300 | A-14 | B-14 |
| 301 | A-14 | B-15 |
| 302 | A-14 | B-16 |
| 303 | A-14 | B-17 |
| 304 | A-14 | B-18 |
| 305 | A-14 | B-19 |
| 306 | A-14 | B-20 |
| 307 | A-14 | B-21 |
| 308 | A-14 | B-22 |
| 309 | A-15 | B-1 |
| 310 | A-15 | B-2 |
| 311 | A-15 | B-3 |
| 312 | A-15 | B-4 |
| 313 | A-15 | B-5 |
| 314 | A-15 | B-6 |
| 315 | A-15 | B-7 |
| 316 | A-15 | B-8 |
| 317 | A-15 | B-9 |
| 318 | A-15 | B-10 |
| 319 | A-15 | B-11 |
| 320 | A-15 | B-12 |
| 321 | A-15 | B-13 |
| 322 | A-15 | B-14 |
| 323 | A-15 | B-15 |
| 324 | A-15 | B-16 |
| 325 | A-15 | B-17 |
| 326 | A-15 | B-18 |
| 327 | A-15 | B-19 |
| 328 | A-15 | B-20 |
| 329 | A-15 | B-21 |
| 330 | A-15 | B-22 |
| 331 | A-16 | B-1 |
| 332 | A-16 | B-2 |
| 333 | A-16 | B-3 |
| 334 | A-16 | B-4 |
| 335 | A-16 | B-5 |
| 336 | A-16 | B-6 |
| 337 | A-16 | B-7 |
| 338 | A-16 | B-8 |
| 339 | A-16 | B-9 |
| 340 | A-16 | B-10 |
| 341 | A-16 | B-11 |
| 342 | A-16 | B-12 |
| 343 | A-16 | B-13 |
| 344 | A-16 | B-14 |
| 345 | A-16 | B-15 |
| 346 | A-16 | B-16 |
| 347 | A-16 | B-17 |
| 348 | A-16 | B-18 |
| 349 | A-16 | B-19 |
| 350 | A-16 | B-20 |
| 351 | A-16 | B-21 |
| 352 | A-16 | B-22 |
| 353 | A-17 | B-1 |
| 354 | A-17 | B-2 |
| 355 | A-17 | B-3 |
| 356 | A-17 | B-4 |
| 357 | A-17 | B-5 |
| 358 | A-17 | B-6 |
| 359 | A-17 | B-7 |
| 360 | A-17 | B-8 |
| 361 | A-17 | B-9 |
| 362 | A-17 | B-10 |
| 363 | A-17 | B-11 |
| 364 | A-17 | B-12 |
| 365 | A-17 | B-13 |
| 366 | A-17 | B-14 |
| 367 | A-17 | B-15 |
| 368 | A-17 | B-16 |
| 369 | A-17 | B-17 |
| 370 | A-17 | B-18 |
| 371 | A-17 | B-19 |
| 372 | A-17 | B-20 |
| 373 | A-17 | B-21 |
| 374 | A-17 | B-22 |
| 375 | A-18 | B-1 |
| 376 | A-18 | B-2 |
| 377 | A-18 | B-3 |
| 378 | A-18 | B-4 |
| 379 | A-18 | B-5 |
| 380 | A-18 | B-6 |
| 381 | A-18 | B-7 |
| 382 | A-18 | B-8 |
| 383 | A-18 | B-9 |
| 384 | A-18 | B-10 |
| 385 | A-18 | B-11 |
| 386 | A-18 | B-12 |
| 387 | A-18 | B-13 |
| 388 | A-18 | B-14 |
| 389 | A-18 | B-15 |
| 390 | A-18 | B-16 |
| 391 | A-18 | B-17 |
| 392 | A-18 | B-18 |
| 393 | A-18 | B-19 |
| 394 | A-18 | B-20 |
| 395 | A-18 | B-21 |
| 396 | A-18 | B-22 |
| 397 | A-19 | B-1 |
| 398 | A-19 | B-2 |
| 399 | A-19 | B-3 |
| 400 | A-19 | B-4 |
| 401 | A-19 | B-5 |
| 402 | A-19 | B-6 |
| 403 | A-19 | B-7 |
| 404 | A-19 | B-8 |
| 405 | A-19 | B-9 |
| 406 | A-19 | B-10 |
| 407 | A-19 | B-11 |
| 408 | A-19 | B-12 |
| 409 | A-19 | B-13 |
| 410 | A-19 | B-14 |
| 411 | A-19 | B-15 |
| 412 | A-19 | B-16 |
| 413 | A-19 | B-17 |
| 414 | A-19 | B-18 |
| 415 | A-19 | B-19 |
| 416 | A-19 | B-20 |
| 417 | A-19 | B-21 |
| 418 | A-19 | B-22 |
| 419 | A-20 | B-1 |
| 420 | A-20 | B-2 |
| 421 | A-20 | B-3 |
| 422 | A-20 | B-4 |
| 423 | A-20 | B-5 |
| 424 | A-20 | B-6 |
| 425 | A-20 | B-7 |
| 426 | A-20 | B-8 |
| 427 | A-20 | B-9 |
| 428 | A-20 | B-10 |
| 429 | A-20 | B-11 |
| 430 | A-20 | B-12 |
| 431 | A-20 | B-13 |
| 432 | A-20 | B-14 |
| 433 | A-20 | B-15 |
| 434 | A-20 | B-16 |
| 435 | A-20 | B-17 |
| 436 | A-20 | B-18 |
| 437 | A-20 | B-19 |
| 438 | A-20 | B-20 |
| 439 | A-20 | B-21 |
| 440 | A-20 | B-22 |
| 441 | A-21 | B-1 |
| 442 | A-21 | B-2 |
| 443 | A-21 | B-3 |
| 444 | A-21 | B-4 |
| 445 | A-21 | B-5 |
| 446 | A-21 | B-6 |
| 447 | A-21 | B-7 |
| 448 | A-21 | B-8 |
| 449 | A-21 | B-9 |
| 450 | A-21 | B-10 |
| 451 | A-21 | B-11 |
| 452 | A-21 | B-12 |
| 453 | A-21 | B-13 |
| 454 | A-21 | B-14 |
| 455 | A-21 | B-15 |
| 456 | A-21 | B-16 |
| 457 | A-21 | B-17 |
| 458 | A-21 | B-18 |
| 459 | A-21 | B-19 |
| 460 | A-21 | B-20 |
| 461 | A-21 | B-21 |
| 462 | A-21 | B-22 |
| 463 | A-22 | B-1 |
| 464 | A-22 | B-2 |
| 465 | A-22 | B-3 |
| 466 | A-22 | B-4 |
| 467 | A-22 | B-5 |
| 468 | A-22 | B-6 |
| 469 | A-22 | B-7 |
| 470 | A-22 | B-8 |
| 471 | A-22 | B-9 |
| 472 | A-22 | B-10 |
| 473 | A-22 | B-11 |
| 474 | A-22 | B-12 |
| 475 | A-22 | B-13 |
| 476 | A-22 | B-14 |
| 477 | A-22 | B-15 |
| 478 | A-22 | B-16 |
| 479 | A-22 | B-17 |
| 480 | A-22 | B-18 |
| 481 | A-22 | B-19 |
| 482 | A-22 | B-20 |
| 483 | A-22 | B-21 |
| 484 | A-22 | B-22 |
| 485 | A-23 | B-1 |
| 486 | A-23 | B-2 |
| 487 | A-23 | B-3 |
| 488 | A-23 | B-4 |
| 489 | A-23 | B-5 |
| 490 | A-23 | B-6 |
| 491 | A-23 | B-7 |
| 492 | A-23 | B-8 |
| 493 | A-23 | B-9 |
| 494 | A-23 | B-10 |
| 495 | A-23 | B-11 |
| 496 | A-23 | B-12 |
| 497 | A-23 | B-13 |
| 498 | A-23 | B-14 |
| 499 | A-23 | B-15 |
| 500 | A-23 | B-16 |
| 501 | A-23 | B-17 |
| 502 | A-23 | B-18 |
| 503 | A-23 | B-19 |
| 504 | A-23 | B-20 |
| 505 | A-23 | B-21 |
| 506 | A-23 | B-22 |
| 507 | A-24 | B-1 |
| 508 | A-24 | B-2 |
| 509 | A-24 | B-3 |
| 510 | A-24 | B-4 |
| 511 | A-24 | B-5 |
| 512 | A-24 | B-6 |
| 513 | A-24 | B-7 |
| 514 | A-24 | B-8 |
| 515 | A-24 | B-9 |
| 516 | A-24 | B-10 |
| 517 | A-24 | B-11 |
| 518 | A-24 | B-12 |
| 519 | A-24 | B-13 |
| 520 | A-24 | B-14 |
| 521 | A-24 | B-15 |
| 522 | A-24 | B-16 |
| 523 | A-24 | B-17 |
| 524 | A-24 | B-18 |
| 525 | A-24 | B-19 |
| 526 | A-24 | B-20 |
| 527 | A-24 | B-21 |
| 528 | A-24 | B-22 |
| 529 | A-25 | B-1 |
| 530 | A-25 | B-2 |
| 531 | A-25 | B-3 |
| 532 | A-25 | B-4 |
| 533 | A-25 | B-5 |
| 534 | A-25 | B-6 |
| 535 | A-25 | B-7 |
| 536 | A-25 | B-8 |
| 537 | A-25 | B-9 |
| 538 | A-25 | B-10 |
| 539 | A-25 | B-11 |
| 540 | A-25 | B-12 |
| 541 | A-25 | B-13 |
| 542 | A-25 | B-14 |
| 543 | A-25 | B-15 |
| 544 | A-25 | B-16 |
| 545 | A-25 | B-17 |
| 546 | A-25 | B-18 |
| 547 | A-25 | B-19 |
| 548 | A-25 | B-20 |
| 549 | A-25 | B-21 |
| 550 | A-25 | B-22 |
| 551 | A-26 | B-1 |
| 552 | A-26 | B-2 |
| 553 | A-26 | B-3 |
| 554 | A-26 | B-4 |
| 555 | A-26 | B-5 |
| 556 | A-26 | B-6 |
| 557 | A-26 | B-7 |
| 558 | A-26 | B-8 |
| 559 | A-26 | B-9 |
| 560 | A-26 | B-10 |
| 561 | A-26 | B-11 |
| 562 | A-26 | B-12 |
| 563 | A-26 | B-13 |
| 564 | A-26 | B-14 |
| 565 | A-26 | B-15 |
| 566 | A-26 | B-16 |
| 567 | A-26 | B-17 |
| 568 | A-26 | B-18 |
| 569 | A-26 | B-19 |
| 570 | A-26 | B-20 |
| 571 | A-26 | B-21 |
| 572 | A-26 | B-22 |
| 573 | A-27 | B-1 |
| 574 | A-27 | B-2 |
| 575 | A-27 | B-3 |
| 576 | A-27 | B-4 |
| 577 | A-27 | B-5 |
| 578 | A-27 | B-6 |
| 579 | A-27 | B-7 |
| 580 | A-27 | B-8 |
| 581 | A-27 | B-9 |
| 582 | A-27 | B-10 |
| 583 | A-27 | B-11 |
| 584 | A-27 | B-12 |
| 585 | A-27 | B-13 |
| 586 | A-27 | B-14 |
| 587 | A-27 | B-15 |
| 588 | A-27 | B-16 |
| 589 | A-27 | B-17 |
| 590 | A-27 | B-18 |
| 591 | A-27 | B-19 |
| 592 | A-27 | B-20 |
| 593 | A-27 | B-21 |
| 594 | A-27 | B-22 |
| 595 | A-28 | B-1 |
| 596 | A-28 | B-2 |
| 597 | A-28 | B-3 |
| 598 | A-28 | B-4 |
| 599 | A-28 | B-5 |
| 600 | A-28 | B-6 |
| 601 | A-28 | B-7 |
| 602 | A-28 | B-8 |
| 603 | A-28 | B-9 |
| 604 | A-28 | B-10 |
| 605 | A-28 | B-11 |
| 606 | A-28 | B-12 |
| 607 | A-28 | B-13 |
| 608 | A-28 | B-14 |
| 609 | A-28 | B-15 |
| 610 | A-28 | B-16 |
| 611 | A-28 | B-17 |
| 612 | A-28 | B-18 |
| 613 | A-28 | B-19 |
| 614 | A-28 | B-20 |
| 615 | A-28 | B-21 |
| 616 | A-28 | B-22 |
| 617 | A-29 | B-1 |
| 618 | A-29 | B-2 |
| 619 | A-29 | B-3 |
| 620 | A-29 | B-4 |
| 621 | A-29 | B-5 |
| 622 | A-29 | B-6 |
| 623 | A-29 | B-7 |
| 624 | A-29 | B-8 |
| 625 | A-29 | B-9 |
| 626 | A-29 | B-10 |
| 627 | A-29 | B-11 |
| 628 | A-29 | B-12 |
| 629 | A-29 | B-13 |
| 630 | A-29 | B-14 |
| 631 | A-29 | B-15 |
| 632 | A-29 | B-16 |
| 633 | A-29 | B-17 |
| 634 | A-29 | B-18 |
| 635 | A-29 | B-19 |
| 636 | A-29 | B-20 |
| 637 | A-29 | B-21 |
| 638 | A-29 | B-22 |
| 639 | A-30 | B-1 |
| 640 | A-30 | B-2 |
| 641 | A-30 | B-3 |
| 642 | A-30 | B-4 |
| 643 | A-30 | B-5 |
| 644 | A-30 | B-6 |
| 645 | A-30 | B-7 |
| 646 | A-30 | B-8 |
| 647 | A-30 | B-9 |
| 648 | A-30 | B-10 |
| 649 | A-30 | B-11 |
| 650 | A-30 | B-12 |
| 651 | A-30 | B-13 |
| 652 | A-30 | B-14 |
| 653 | A-30 | B-15 |
| 654 | A-30 | B-16 |
| 655 | A-30 | B-17 |
| 656 | A-30 | B-18 |
| 657 | A-30 | B-19 |
| 658 | A-30 | B-20 |
| 659 | A-30 | B-21 |
| 660 | A-30 | B-22 |

Preferred compounds of formula (EM-1) are shown in the following table:

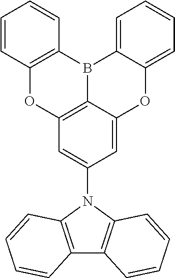 [SMILES: c1ccc2c(c1)Oc1cc(-n3c4ccccc4c4ccccc43)cc3c1B2c1ccccc1O3]

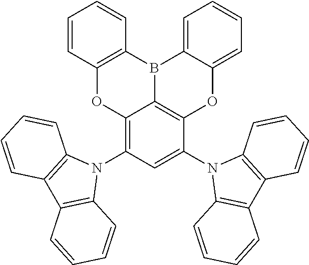 [SMILES: c1ccc2c(c1)Oc1c(-n3c4ccccc4c4ccccc43)cc(-n3c4ccccc4c4ccccc43)c3c1B2c1ccccc1O3]

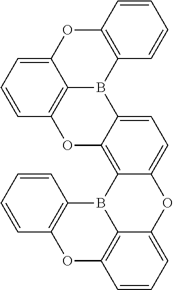 [SMILES: c1ccc2c(c1)Oc1cccc3c1B2c1ccc2c(c1O3)B1c3ccccc3Oc3cccc(c31)O2]

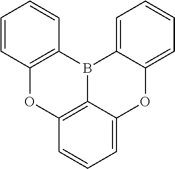 [SMILES: c1ccc2c(c1)Oc1cccc3c1B2c1ccccc1O3]

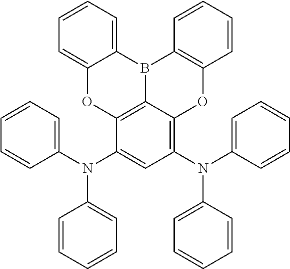 [SMILES: c1ccc(N(c2ccccc2)c2cc(N(c3ccccc3)c3ccccc3)c3c4c2Oc2ccccc2B4c2ccccc2O3)cc1]

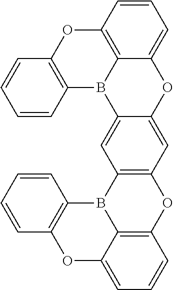 [SMILES: c1ccc2c(c1)Oc1cccc3c1B2c1cc2c(cc1O3)Oc1cccc3c1B2c1ccccc1O3]

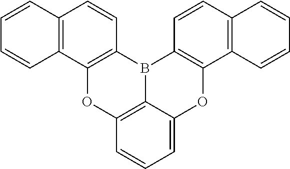 [SMILES: c1cc2c3c(c1)Oc1c(ccc4ccccc14)B3c1ccc3ccccc3c1O2]

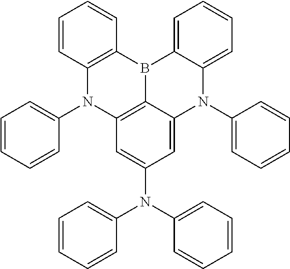 [SMILES: c1ccc(N(c2ccccc2)c2cc3c4c(c2)N(c2ccccc2)c2ccccc2B4c2ccccc2N3c2ccccc2)cc1]

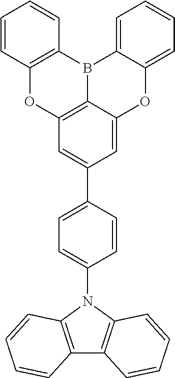 [SMILES: c1ccc2c(c1)Oc1cc(-c3ccc(-n4c5ccccc5c5ccccc54)cc3)cc3c1B2c1ccccc1O3]

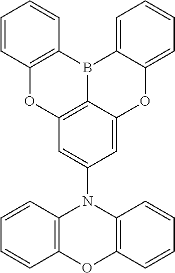 [SMILES: c1ccc2c(c1)Oc1cc(N3c4ccccc4Oc4ccccc43)cc3c1B2c1ccccc1O3]

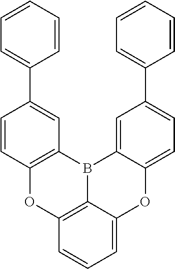 [SMILES: c1ccc(-c2ccc3c(c2)B2c4cc(-c5ccccc5)ccc4Oc4cccc(c42)O3)cc1]

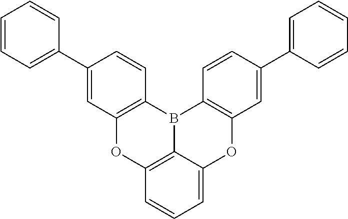 [SMILES: c1ccc(-c2ccc3c(c2)Oc2cccc4c2B3c2ccc(-c3ccccc3)cc2O4)cc1]

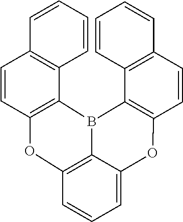 [SMILES: c1cc2c3c(c1)Oc1ccc4ccccc4c1B3c1c(ccc3ccccc13)O2]

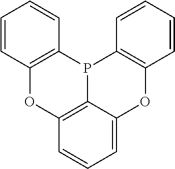 [SMILES: c1ccc2c(c1)Oc1cccc3c1P2c1ccccc1O3]

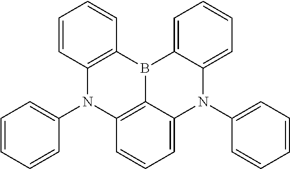 [SMILES: c1ccc(N2c3ccccc3B3c4ccccc4N(c4ccccc4)c4cccc2c43)cc1]

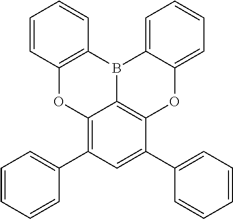 [SMILES: c1ccc(-c2cc(-c3ccccc3)c3c4c2Oc2ccccc2B4c2ccccc2O3)cc1]

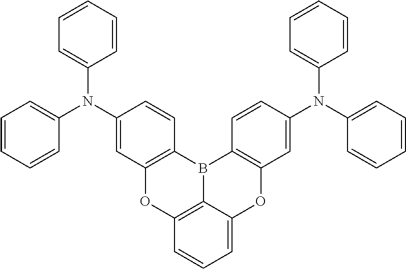 [SMILES: c1ccc(N(c2ccccc2)c2ccc3c(c2)Oc2cccc4c2B3c2ccc(N(c3ccccc3)c3ccccc3)cc2O4)cc1]

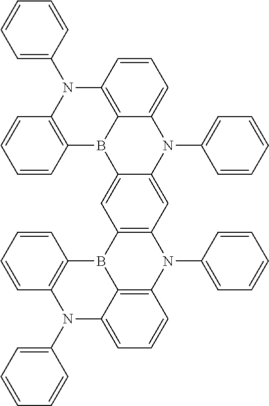 [SMILES: c1ccc(N2c3ccccc3B3c4cc5c(cc4N(c4ccccc4)c4cccc2c43)N(c2ccccc2)c2cccc3c2B5c2ccccc2N3c2ccccc2)cc1]

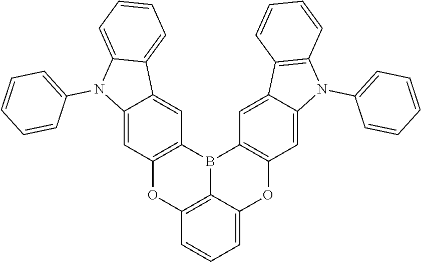 [SMILES: c1ccc(-n2c3ccccc3c3cc4c(cc32)Oc2cccc3c2B4c2cc4c5ccccc5n(-c5ccccc5)c4cc2O3)cc1]

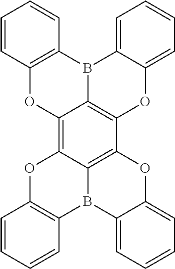 [SMILES: c1ccc2c(c1)Oc1c3c4c(c5c1B2c1ccccc1O5)Oc1ccccc1B4c1ccccc1O3]

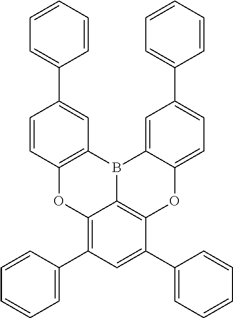 [SMILES: c1ccc(-c2ccc3c(c2)B2c4cc(-c5ccccc5)ccc4Oc4c(-c5ccccc5)cc(-c5ccccc5)c(c42)O3)cc1]

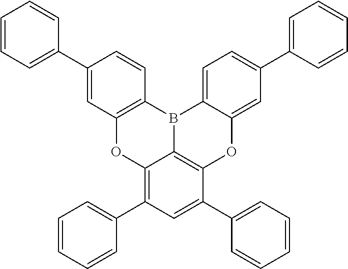 [SMILES: c1ccc(-c2ccc3c(c2)Oc2c(-c4ccccc4)cc(-c4ccccc4)c4c2B3c2ccc(-c3ccccc3)cc2O4)cc1]

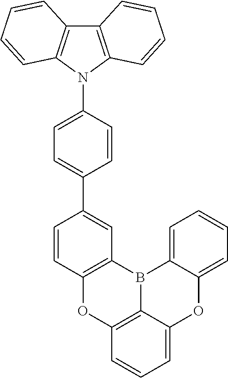 [SMILES: c1ccc2c(c1)Oc1cccc3c1B2c1cc(-c2ccc(-n4c5ccccc5c5ccccc54)cc2)ccc1O3]

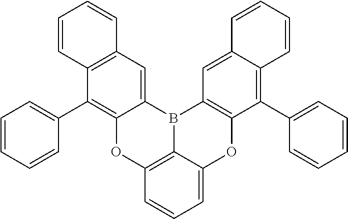 [SMILES: c1ccc(-c2c3c(cc4ccccc24)B2c4cc5ccccc5c(-c5ccccc5)c4Oc4cccc(c42)O3)cc1]

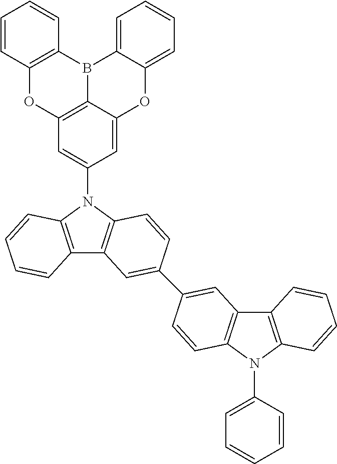 [SMILES: c1ccc(-n2c3ccccc3c3cc(-c4ccc5c(c4)c4ccccc4n5-c4cc5c6c(c4)Oc4ccccc4B6c4ccccc4O5)ccc32)cc1]

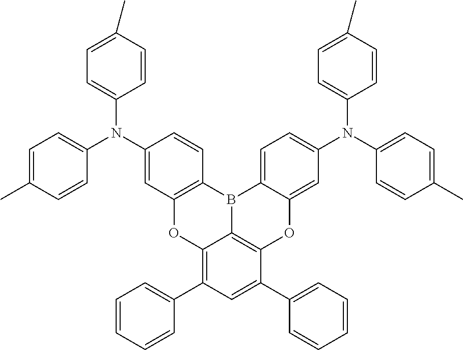

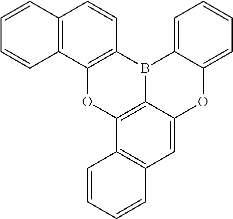 [SMILES: c1ccc2c(c1)Oc1cc3ccccc3c3c1B2c1ccc2ccccc2c1O3]

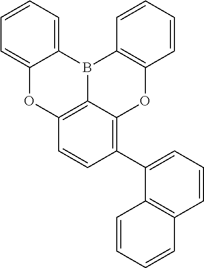 [SMILES: c1ccc2c(c1)Oc1ccc(-c3cccc4ccccc34)c3c1B2c1ccccc1O3]

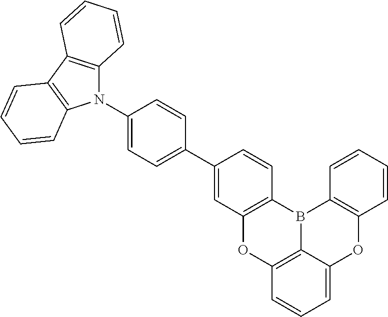 [SMILES: c1ccc2c(c1)Oc1cccc3c1B2c1ccc(-c2ccc(-n4c5ccccc5c5ccccc54)cc2)cc1O3]

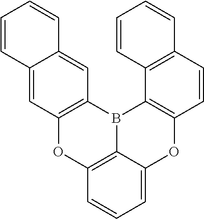 [SMILES: c1cc2c3c(c1)Oc1ccc4ccccc4c1B3c1cc3ccccc3cc1O2]

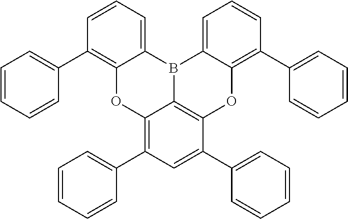 [SMILES: c1ccc(-c2cccc3c2Oc2c(-c4ccccc4)cc(-c4ccccc4)c4c2B3c2cccc(-c3ccccc3)c2O4)cc1]

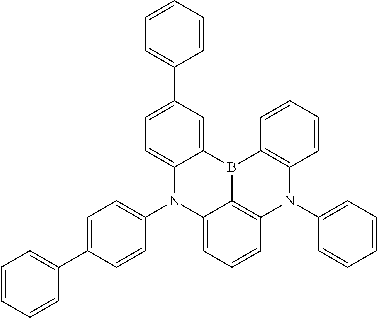 [SMILES: c1ccc(-c2ccc(N3c4ccc(-c5ccccc5)cc4B4c5ccccc5N(c5ccccc5)c5cccc3c54)cc2)cc1]

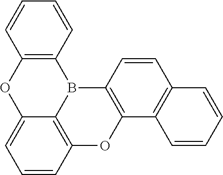 [SMILES: c1ccc2c(c1)Oc1cccc3c1B2c1ccc2ccccc2c1O3]

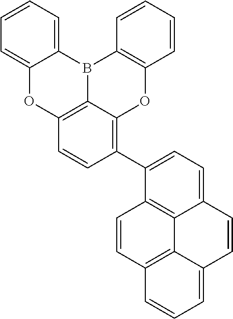 [SMILES: c1ccc2c(c1)Oc1ccc(-c3ccc4ccc5cccc6ccc3c4c56)c3c1B2c1ccccc1O3]

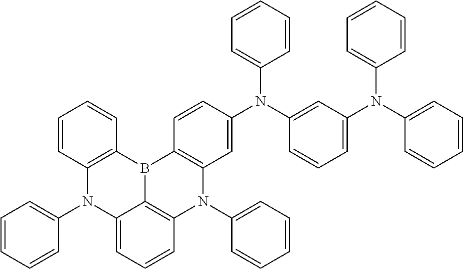 [SMILES: c1ccc(N(c2ccccc2)c2cccc(N(c3ccccc3)c3ccc4c(c3)N(c3ccccc3)c3cccc5c3B4c3ccccc3N5c3ccccc3)c2)cc1]

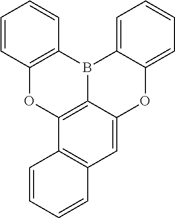 [SMILES: c1ccc2c(c1)Oc1cc3ccccc3c3c1B2c1ccccc1O3]

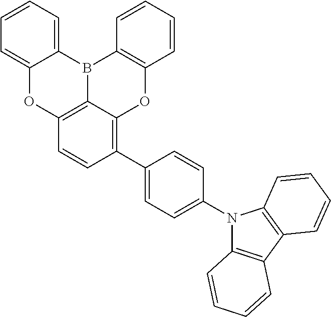 [SMILES: c1ccc2c(c1)Oc1ccc(-c3ccc(-n4c5ccccc5c5ccccc54)cc3)c3c1B2c1ccccc1O3]

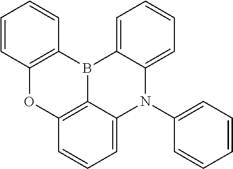 [SMILES: c1ccc(N2c3ccccc3B3c4ccccc4Oc4cccc2c43)cc1]

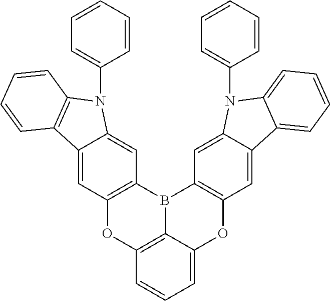 [SMILES: c1ccc(-n2c3ccccc3c3cc4c(cc32)B2c3cc5c(cc3Oc3cccc(c32)O4)c2ccccc2n5-c2ccccc2)cc1]

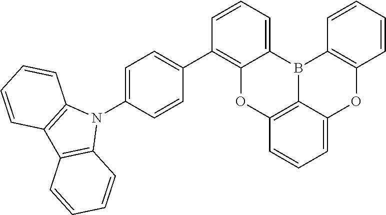 [SMILES: c1ccc2c(c1)Oc1cccc3c1B2c1cccc(-c2ccc(-n4c5ccccc5c5ccccc54)cc2)c1O3]

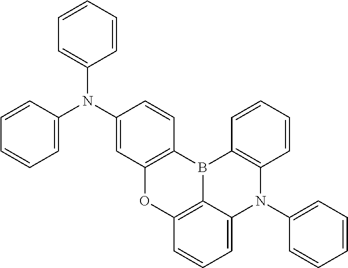 [SMILES: c1ccc(N(c2ccccc2)c2ccc3c(c2)Oc2cccc4c2B3c2ccccc2N4c2ccccc2)cc1]

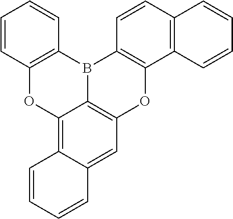 [SMILES: c1ccc2c(c1)Oc1c3c(cc4ccccc14)Oc1c(ccc4ccccc14)B23]

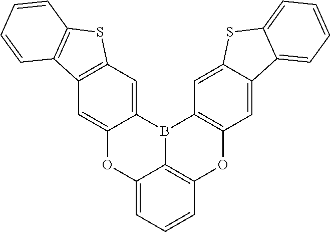 [SMILES: c1cc2c3c(c1)Oc1cc4c(cc1B3c1cc3sc5ccccc5c3cc1O2)sc1ccccc14]

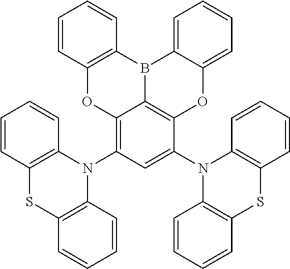 [SMILES: c1ccc2c(c1)Oc1c(N3c4ccccc4Sc4ccccc43)cc(N3c4ccccc4Sc4ccccc43)c3c1B2c1ccccc1O3]

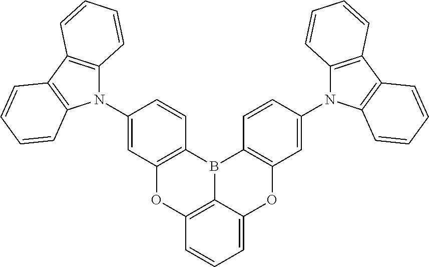 [SMILES: c1cc2c3c(c1)Oc1cc(-n4c5ccccc5c5ccccc54)ccc1B3c1ccc(-n3c4ccccc4c4ccccc43)cc1O2]

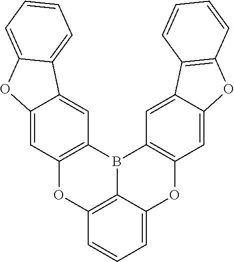 [SMILES: c1cc2c3c(c1)Oc1cc4oc5ccccc5c4cc1B3c1cc3c(cc1O2)oc1ccccc13]

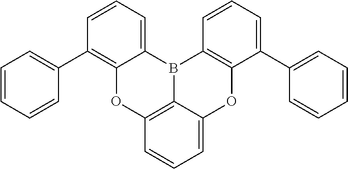 [SMILES: c1ccc(-c2cccc3c2Oc2cccc4c2B3c2cccc(-c3ccccc3)c2O4)cc1]

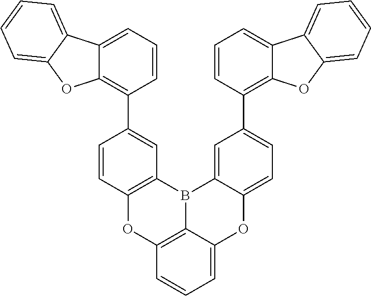 [SMILES: c1cc2c3c(c1)Oc1ccc(-c4cccc5c4oc4ccccc45)cc1B3c1cc(-c3cccc4c3oc3ccccc34)ccc1O2]

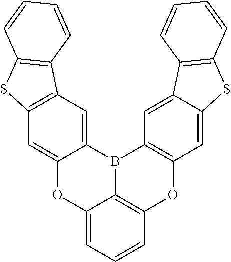 [SMILES: c1cc2c3c(c1)Oc1cc4sc5ccccc5c4cc1B3c1cc3c(cc1O2)sc1ccccc13]

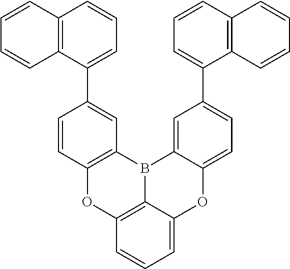 [SMILES: c1cc2c3c(c1)Oc1ccc(-c4cccc5ccccc45)cc1B3c1cc(-c3cccc4ccccc34)ccc1O2]

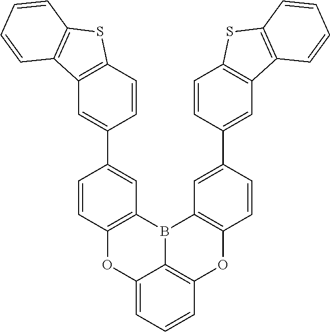 [SMILES: c1cc2c3c(c1)Oc1ccc(-c4ccc5sc6ccccc6c5c4)cc1B3c1cc(-c3ccc4sc5ccccc5c4c3)ccc1O2]

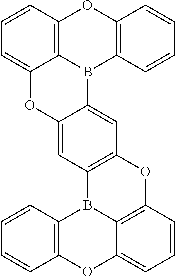 [SMILES: c1ccc2c(c1)Oc1cccc3c1B2c1cc2c(cc1O3)B1c3ccccc3Oc3cccc(c31)O2]

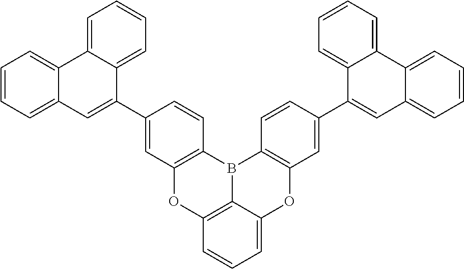 [SMILES: c1cc2c3c(c1)Oc1cc(-c4cc5ccccc5c5ccccc45)ccc1B3c1ccc(-c3cc4ccccc4c4ccccc34)cc1O2]

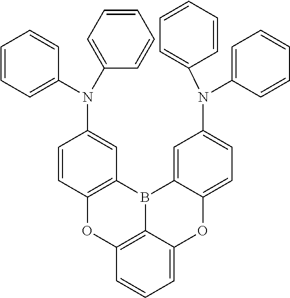 [SMILES: c1ccc(N(c2ccccc2)c2ccc3c(c2)B2c4cc(N(c5ccccc5)c5ccccc5)ccc4Oc4cccc(c42)O3)cc1]

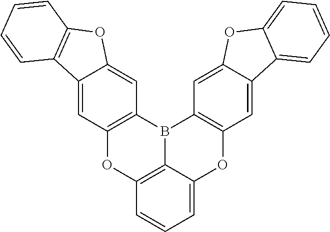 [SMILES: c1cc2c3c(c1)Oc1cc4c(cc1B3c1cc3oc5ccccc5c3cc1O2)oc1ccccc14]

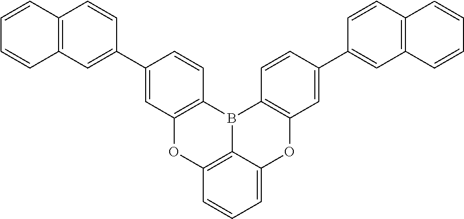 [SMILES: c1cc2c3c(c1)Oc1cc(-c4ccc5ccccc5c4)ccc1B3c1ccc(-c3ccc4ccccc4c3)cc1O2]

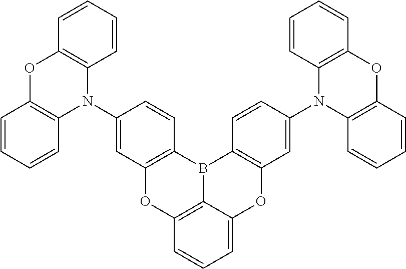 [SMILES: c1ccc2c(c1)Oc1ccccc1N2c1ccc2c(c1)Oc1cccc3c1B2c1ccc(N2c4ccccc4Oc4ccccc42)cc1O3]

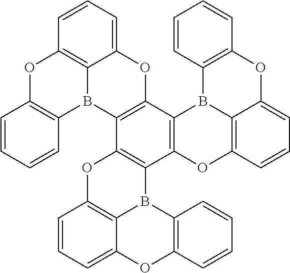 [SMILES: c1ccc2c(c1)Oc1cccc3c1B2c1c2c(c4c(c1O3)B1c3ccccc3Oc3cccc(c31)O4)B1c3ccccc3Oc3cccc(c31)O2]

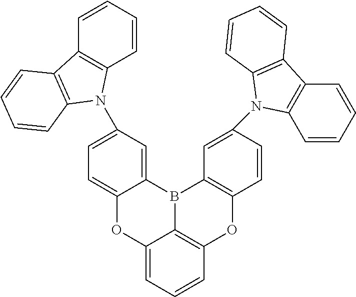 [SMILES: c1cc2c3c(c1)Oc1ccc(-n4c5ccccc5c5ccccc54)cc1B3c1cc(-n3c4ccccc4c4ccccc43)ccc1O2]

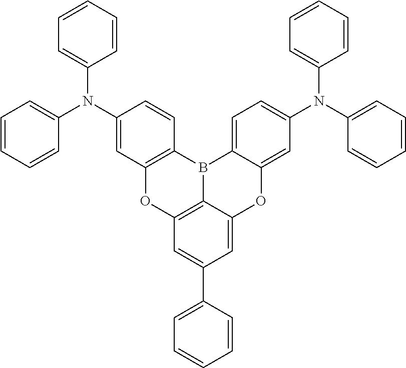 [SMILES: c1ccc(-c2cc3c4c(c2)Oc2cc(N(c5ccccc5)c5ccccc5)ccc2B4c2ccc(N(c4ccccc4)c4ccccc4)cc2O3)cc1]

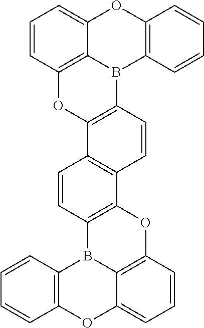 [SMILES: c1ccc2c(c1)Oc1cccc3c1B2c1ccc2c4c(ccc2c1O3)B1c2ccccc2Oc2cccc(c21)O4]

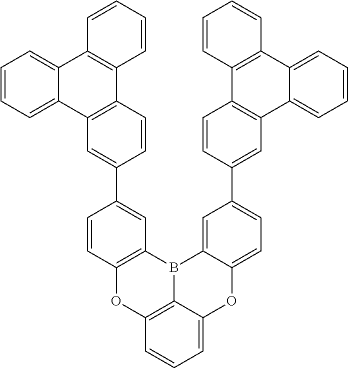 [SMILES: c1cc2c3c(c1)Oc1ccc(-c4ccc5c6ccccc6c6ccccc6c5c4)cc1B3c1cc(-c3ccc4c5ccccc5c5ccccc5c4c3)ccc1O2]

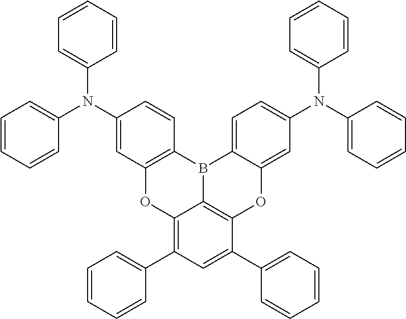 [SMILES: c1ccc(-c2cc(-c3ccccc3)c3c4c2Oc2cc(N(c5ccccc5)c5ccccc5)ccc2B4c2ccc(N(c4ccccc4)c4ccccc4)cc2O3)cc1]

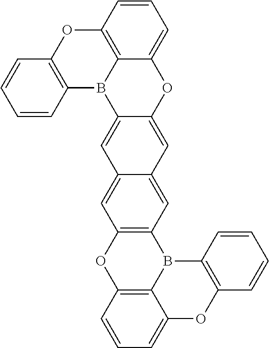 [SMILES: c1ccc2c(c1)Oc1cccc3c1B2c1cc2cc4c(cc2cc1O3)B1c2ccccc2Oc2cccc(c21)O4]

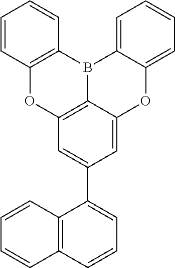 [SMILES: c1ccc2c(c1)Oc1cc(-c3cccc4ccccc34)cc3c1B2c1ccccc1O3]

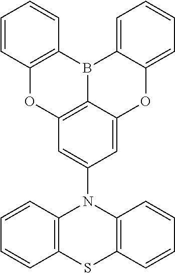 [SMILES: c1ccc2c(c1)Oc1cc(N3c4ccccc4Sc4ccccc43)cc3c1B2c1ccccc1O3]

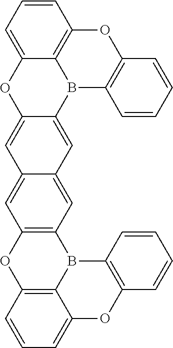 [SMILES: c1ccc2c(c1)Oc1cccc3c1B2c1cc2cc4c(cc2cc1O3)Oc1cccc2c1B4c1ccccc1O2]

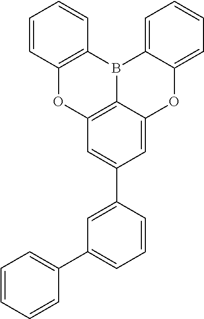 [SMILES: c1ccc(-c2cccc(-c3cc4c5c(c3)Oc3ccccc3B5c3ccccc3O4)c2)cc1]

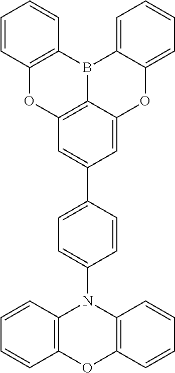 [SMILES: c1ccc2c(c1)Oc1cc(-c3ccc(N4c5ccccc5Oc5ccccc54)cc3)cc3c1B2c1ccccc1O3]

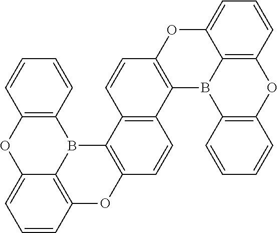 [SMILES: c1ccc2c(c1)Oc1cccc3c1B2c1c(ccc2c4c(ccc12)Oc1cccc2c1B4c1ccccc1O2)O3]

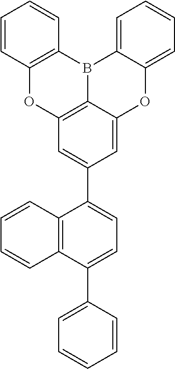 [SMILES: c1ccc(-c2ccc(-c3cc4c5c(c3)Oc3ccccc3B5c3ccccc3O4)c3ccccc23)cc1]

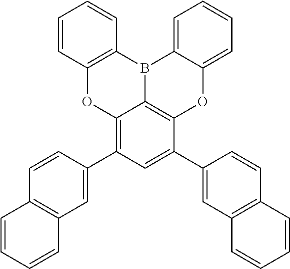 [SMILES: c1ccc2c(c1)Oc1c(-c3ccc4ccccc4c3)cc(-c3ccc4ccccc4c3)c3c1B2c1ccccc1O3]

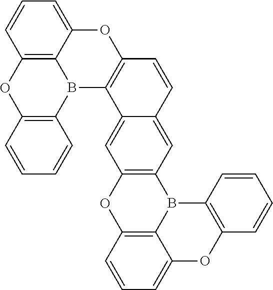 [SMILES: c1ccc2c(c1)Oc1cccc3c1B2c1cc2ccc4c(c2cc1O3)B1c2ccccc2Oc2cccc(c21)O4]

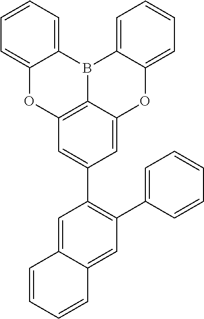 [SMILES: c1ccc(-c2cc3ccccc3cc2-c2cc3c4c(c2)Oc2ccccc2B4c2ccccc2O3)cc1]

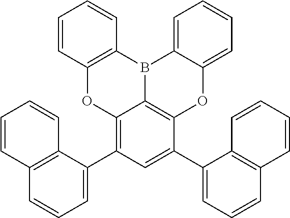 [SMILES: c1ccc2c(c1)Oc1c(-c3cccc4ccccc34)cc(-c3cccc4ccccc34)c3c1B2c1ccccc1O3]

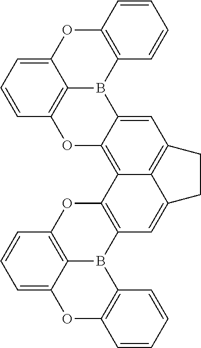 [SMILES: c1ccc2c(c1)Oc1cccc3c1B2c1cc2c4c(cc5c(c4c1O3)Oc1cccc3c1B5c1ccccc1O3)CC2]

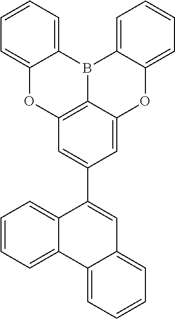 [SMILES: c1ccc2c(c1)Oc1cc(-c3cc4ccccc4c4ccccc34)cc3c1B2c1ccccc1O3]

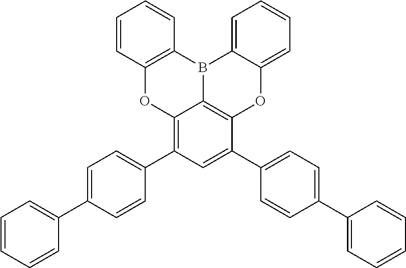 [SMILES: c1ccc(-c2ccc(-c3cc(-c4ccc(-c5ccccc5)cc4)c4c5c3Oc3ccccc3B5c3ccccc3O4)cc2)cc1]

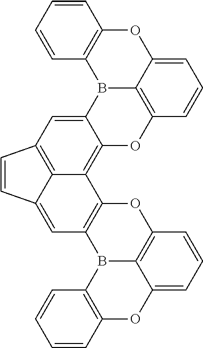 [SMILES: C1=Cc2cc3c(c4c5c(cc1c24)B1c2ccccc2Oc2cccc(c21)O5)Oc1cccc2c1B3c1ccccc1O2]

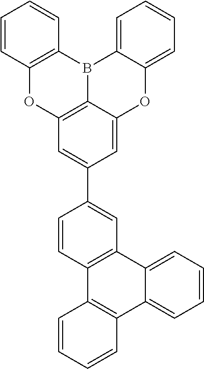 [SMILES: c1ccc2c(c1)Oc1cc(-c3ccc4c5ccccc5c5ccccc5c4c3)cc3c1B2c1ccccc1O3]

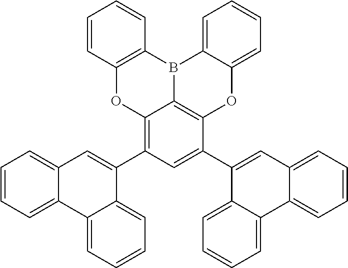 [SMILES: c1ccc2c(c1)Oc1c(-c3cc4ccccc4c4ccccc34)cc(-c3cc4ccccc4c4ccccc34)c3c1B2c1ccccc1O3]

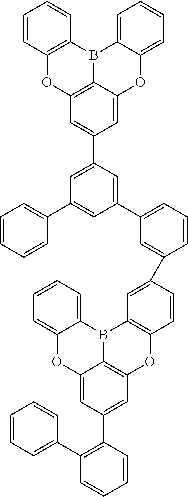 [SMILES: c1ccc(-c2cc(-c3cccc(-c4ccc5c(c4)B4c6ccccc6Oc6cc(-c7ccccc7-c7ccccc7)cc(c64)O5)c3)cc(-c3cc4c5c(c3)Oc3ccccc3B5c3ccccc3O4)c2)cc1]

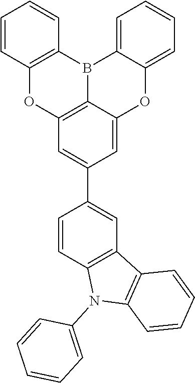 [SMILES: c1ccc(-n2c3ccccc3c3cc(-c4cc5c6c(c4)Oc4ccccc4B6c4ccccc4O5)ccc32)cc1]

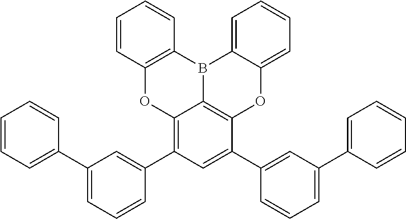 [SMILES: c1ccc(-c2cccc(-c3cc(-c4cccc(-c5ccccc5)c4)c4c5c3Oc3ccccc3B5c3ccccc3O4)c2)cc1]

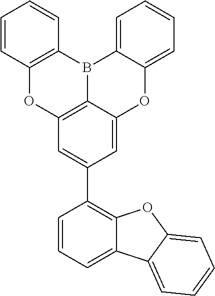 [SMILES: c1ccc2c(c1)Oc1cc(-c3cccc4c3oc3ccccc34)cc3c1B2c1ccccc1O3]

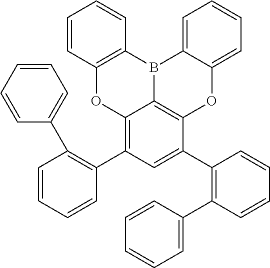 [SMILES: c1ccc(-c2ccccc2-c2cc(-c3ccccc3-c3ccccc3)c3c4c2Oc2ccccc2B4c2ccccc2O3)cc1]

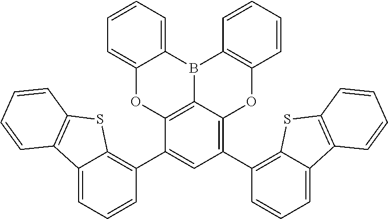 [SMILES: c1ccc2c(c1)Oc1c(-c3cccc4c3sc3ccccc34)cc(-c3cccc4c3sc3ccccc34)c3c1B2c1ccccc1O3]

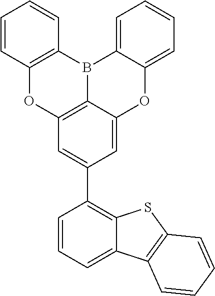 [SMILES: c1ccc2c(c1)Oc1cc(-c3cccc4c3sc3ccccc34)cc3c1B2c1ccccc1O3]

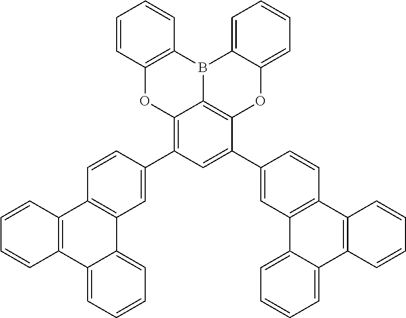 [SMILES: c1ccc2c(c1)Oc1c(-c3ccc4c5ccccc5c5ccccc5c4c3)cc(-c3ccc4c5ccccc5c5ccccc5c4c3)c3c1B2c1ccccc1O3]

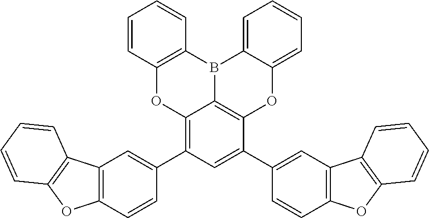 [SMILES: c1ccc2c(c1)Oc1c(-c3ccc4oc5ccccc5c4c3)cc(-c3ccc4oc5ccccc5c4c3)c3c1B2c1ccccc1O3]

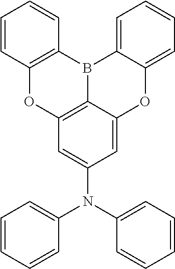 [SMILES: c1ccc(N(c2ccccc2)c2cc3c4c(c2)Oc2ccccc2B4c2ccccc2O3)cc1]

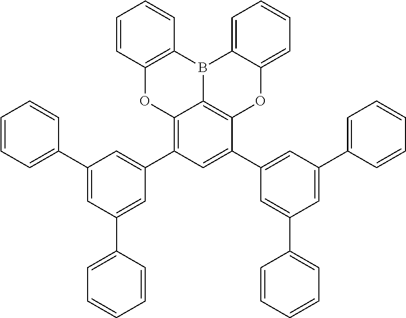 [SMILES: c1ccc(-c2cc(-c3ccccc3)cc(-c3cc(-c4cc(-c5ccccc5)cc(-c5ccccc5)c4)c4c5c3Oc3ccccc3B5c3ccccc3O4)c2)cc1]

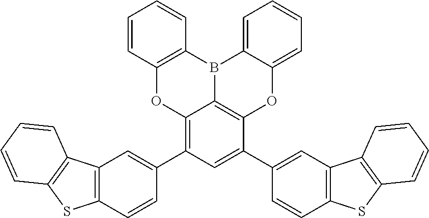 [SMILES: c1ccc2c(c1)Oc1c(-c3ccc4sc5ccccc5c4c3)cc(-c3ccc4sc5ccccc5c4c3)c3c1B2c1ccccc1O3]

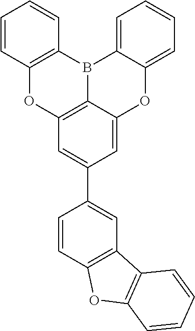 [SMILES: c1ccc2c(c1)Oc1cc(-c3ccc4oc5ccccc5c4c3)cc3c1B2c1ccccc1O3]

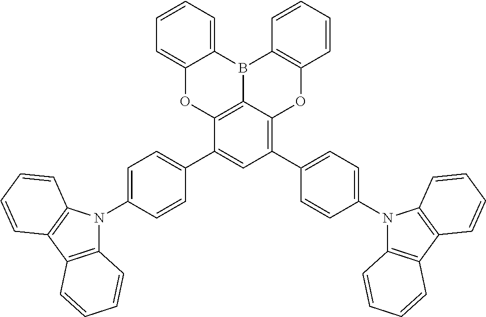 [SMILES: c1ccc2c(c1)Oc1c(-c3ccc(-n4c5ccccc5c5ccccc54)cc3)cc(-c3ccc(-n4c5ccccc5c5ccccc54)cc3)c3c1B2c1ccccc1O3]

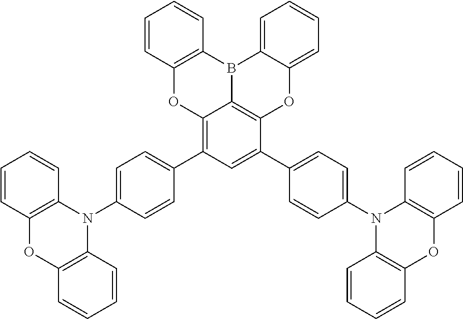 [SMILES: c1ccc2c(c1)Oc1c(-c3ccc(N4c5ccccc5Oc5ccccc54)cc3)cc(-c3ccc(N4c5ccccc5Oc5ccccc54)cc3)c3c1B2c1ccccc1O3]

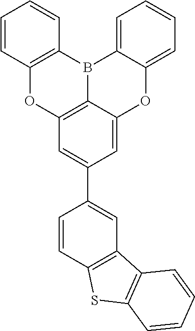 [SMILES: c1ccc2c(c1)Oc1cc(-c3ccc4sc5ccccc5c4c3)cc3c1B2c1ccccc1O3]

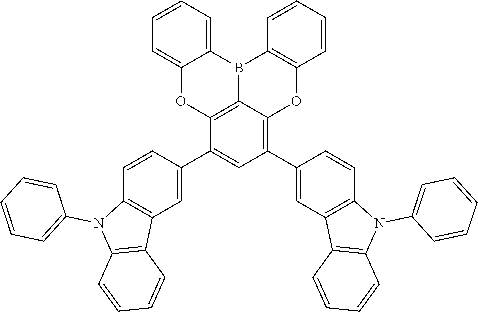 [SMILES: c1ccc(-n2c3ccccc3c3cc(-c4cc(-c5ccc6c(c5)c5ccccc5n6-c5ccccc5)c5c6c4Oc4ccccc4B6c4ccccc4O5)ccc32)cc1]

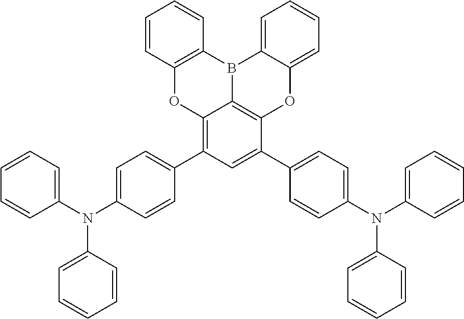 [SMILES: c1ccc(N(c2ccccc2)c2ccc(-c3cc(-c4ccc(N(c5ccccc5)c5ccccc5)cc4)c4c5c3Oc3ccccc3B5c3ccccc3O4)cc2)cc1]

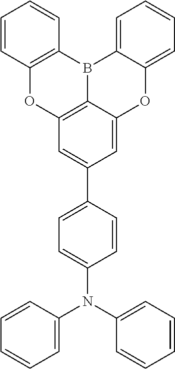 [SMILES: c1ccc(N(c2ccccc2)c2ccc(-c3cc4c5c(c3)Oc3ccccc3B5c3ccccc3O4)cc2)cc1]

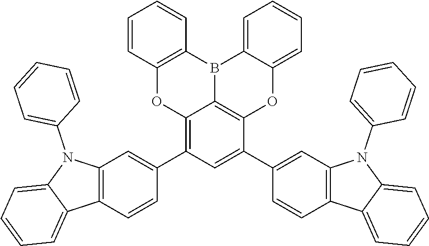 [SMILES: c1ccc(-n2c3ccccc3c3ccc(-c4cc(-c5ccc6c7ccccc7n(-c7ccccc7)c6c5)c5c6c4Oc4ccccc4B6c4ccccc4O5)cc32)cc1]

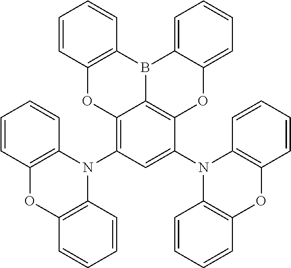 [SMILES: c1ccc2c(c1)Oc1c(N3c4ccccc4Oc4ccccc43)cc(N3c4ccccc4Oc4ccccc43)c3c1B2c1ccccc1O3]

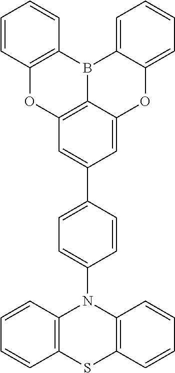 [SMILES: c1ccc2c(c1)Oc1cc(-c3ccc(N4c5ccccc5Sc5ccccc54)cc3)cc3c1B2c1ccccc1O3]

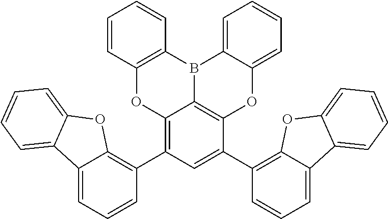 [SMILES: c1ccc2c(c1)Oc1c(-c3cccc4c3oc3ccccc34)cc(-c3cccc4c3oc3ccccc34)c3c1B2c1ccccc1O3]

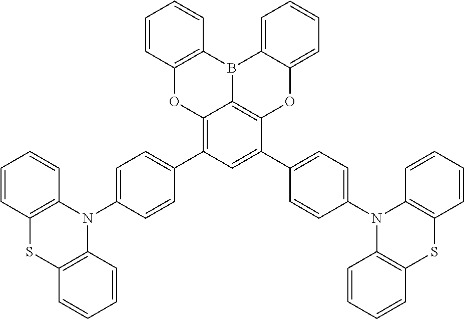 [SMILES: c1ccc2c(c1)Oc1c(-c3ccc(N4c5ccccc5Sc5ccccc54)cc3)cc(-c3ccc(N4c5ccccc5Sc5ccccc54)cc3)c3c1B2c1ccccc1O3]

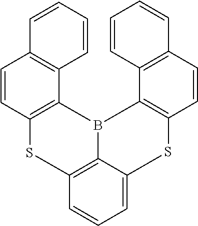 [SMILES: c1cc2c3c(c1)Sc1ccc4ccccc4c1B3c1c(ccc3ccccc13)S2]

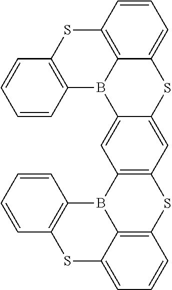 [SMILES: c1ccc2c(c1)Sc1cccc3c1B2c1cc2c(cc1S3)Sc1cccc3c1B2c1ccccc1S3]

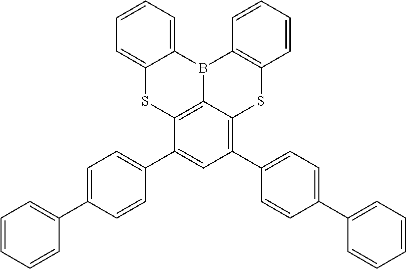 [SMILES: c1ccc(-c2ccc(-c3cc(-c4ccc(-c5ccccc5)cc4)c4c5c3Sc3ccccc3B5c3ccccc3S4)cc2)cc1]

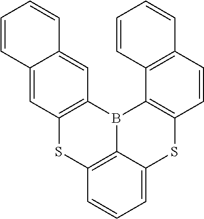 [SMILES: c1cc2c3c(c1)Sc1ccc4ccccc4c1B3c1cc3ccccc3cc1S2]

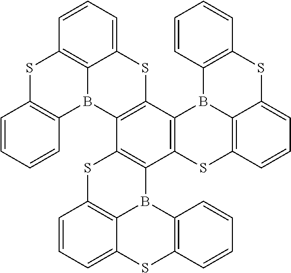 [SMILES: c1ccc2c(c1)Sc1cccc3c1B2c1c2c(c4c(c1S3)B1c3ccccc3Sc3cccc(c31)S4)B1c3ccccc3Sc3cccc(c31)S2]

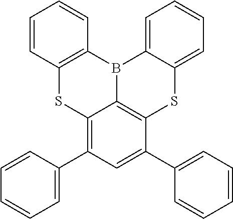 [SMILES: c1ccc(-c2cc(-c3ccccc3)c3c4c2Sc2ccccc2B4c2ccccc2S3)cc1]

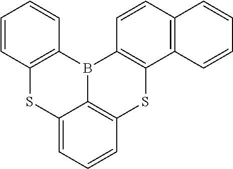 [SMILES: c1ccc2c(c1)Sc1cccc3c1B2c1ccc2ccccc2c1S3]

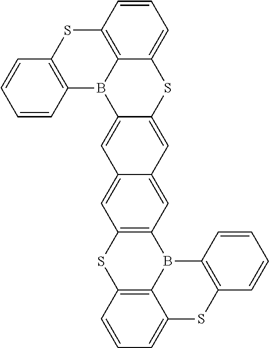 [SMILES: c1ccc2c(c1)Sc1cccc3c1B2c1cc2cc4c(cc2cc1S3)B1c2ccccc2Sc2cccc(c21)S4]

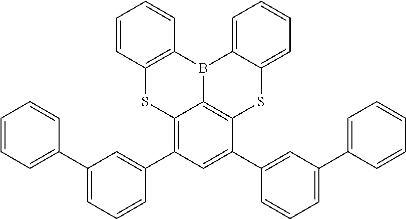 [SMILES: c1ccc(-c2cccc(-c3cc(-c4cccc(-c5ccccc5)c4)c4c5c3Sc3ccccc3B5c3ccccc3S4)c2)cc1]

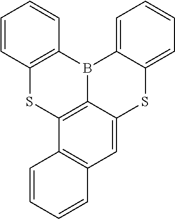 [SMILES: c1ccc2c(c1)Sc1cc3ccccc3c3c1B2c1ccccc1S3]

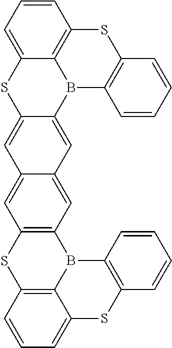 [SMILES: c1ccc2c(c1)Sc1cccc3c1B2c1cc2cc4c(cc2cc1S3)Sc1cccc2c1B4c1ccccc1S2]

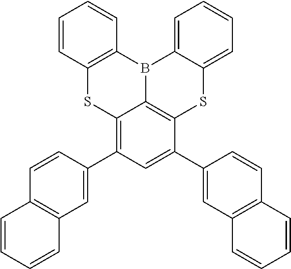 [SMILES: c1ccc2c(c1)Sc1c(-c3ccc4ccccc4c3)cc(-c3ccc4ccccc4c3)c3c1B2c1ccccc1S3]

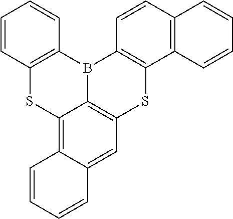 [SMILES: c1ccc2c(c1)Sc1c3c(cc4ccccc14)Sc1c(ccc4ccccc14)B23]

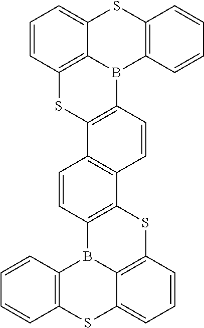 [SMILES: c1ccc2c(c1)Sc1cccc3c1B2c1ccc2c4c(ccc2c1S3)B1c2ccccc2Sc2cccc(c21)S4]

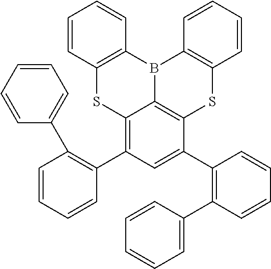 [SMILES: c1ccc(-c2ccccc2-c2cc(-c3ccccc3-c3ccccc3)c3c4c2Sc2ccccc2B4c2ccccc2S3)cc1]

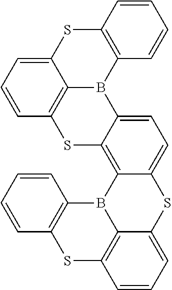 [SMILES: c1ccc2c(c1)Sc1cccc3c1B2c1ccc2c(c1S3)B1c3ccccc3Sc3cccc(c31)S2]

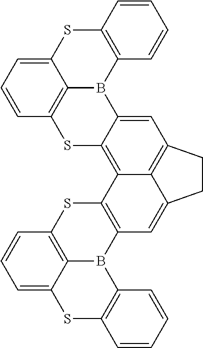 [SMILES: c1ccc2c(c1)Sc1cccc3c1B2c1cc2c4c(cc5c(c4c1S3)Sc1cccc3c1B5c1ccccc1S3)CC2]

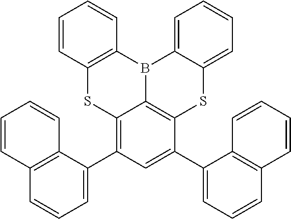 [SMILES: c1ccc2c(c1)Sc1c(-c3cccc4ccccc34)cc(-c3cccc4ccccc34)c3c1B2c1ccccc1S3]

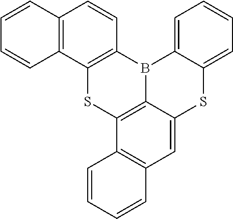 [SMILES: c1ccc2c(c1)Sc1cc3ccccc3c3c1B2c1ccc2ccccc2c1S3]

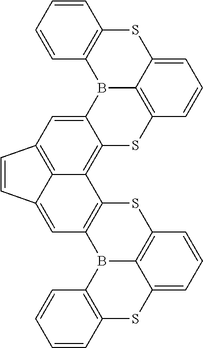 [SMILES: C1=Cc2cc3c(c4c5c(cc1c24)B1c2ccccc2Sc2cccc(c21)S5)Sc1cccc2c1B3c1ccccc1S2]

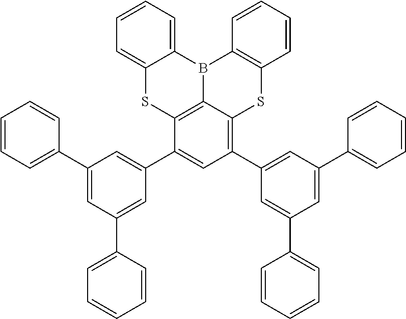 [SMILES: c1ccc(-c2cc(-c3ccccc3)cc(-c3cc(-c4cc(-c5ccccc5)cc(-c5ccccc5)c4)c4c5c3Sc3ccccc3B5c3ccccc3S4)c2)cc1]

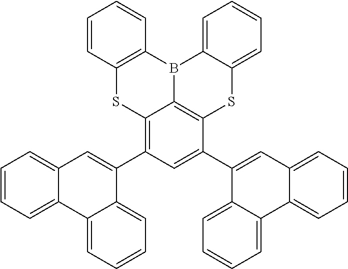 [SMILES: c1ccc2c(c1)Sc1c(-c3cc4ccccc4c4ccccc34)cc(-c3cc4ccccc4c4ccccc34)c3c1B2c1ccccc1S3]

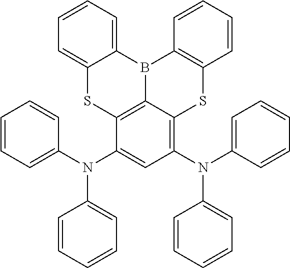 [SMILES: c1ccc(N(c2ccccc2)c2cc(N(c3ccccc3)c3ccccc3)c3c4c2Sc2ccccc2B4c2ccccc2S3)cc1]

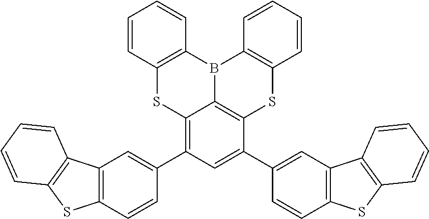 [SMILES: c1ccc2c(c1)Sc1c(-c3ccc4sc5ccccc5c4c3)cc(-c3ccc4sc5ccccc5c4c3)c3c1B2c1ccccc1S3]

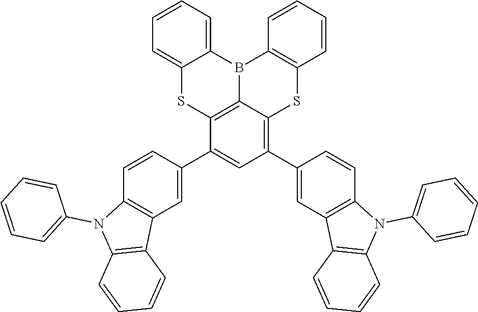 [SMILES: c1ccc(-n2c3ccccc3c3cc(-c4cc(-c5ccc6c(c5)c5ccccc5n6-c5ccccc5)c5c6c4Sc4ccccc4B6c4ccccc4S5)ccc32)cc1]

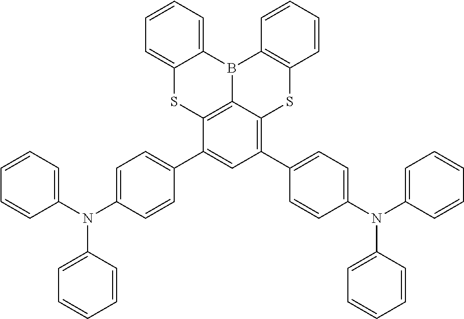 [SMILES: c1ccc(N(c2ccccc2)c2ccc(-c3cc(-c4ccc(N(c5ccccc5)c5ccccc5)cc4)c4c5c3Sc3ccccc3B5c3ccccc3S4)cc2)cc1]

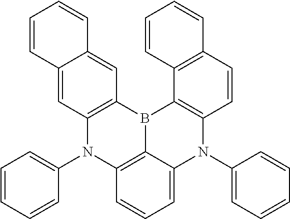 [SMILES: c1ccc(N2c3cc4ccccc4cc3B3c4c2cccc4N(c2ccccc2)c2ccc4ccccc4c23)cc1]

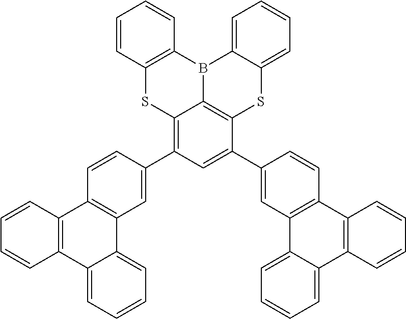 [SMILES: c1ccc2c(c1)Sc1c(-c3ccc4c5ccccc5c5ccccc5c4c3)cc(-c3ccc4c5ccccc5c5ccccc5c4c3)c3c1B2c1ccccc1S3]

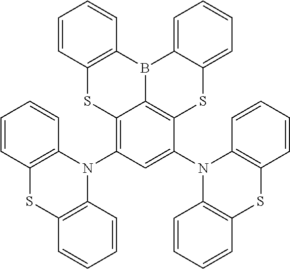 [SMILES: c1ccc2c(c1)Sc1c(N3c4ccccc4Sc4ccccc43)cc(N3c4ccccc4Sc4ccccc43)c3c1B2c1ccccc1S3]

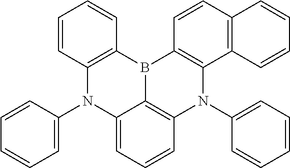 [SMILES: c1ccc(N2c3ccccc3B3c4ccc5ccccc5c4N(c4ccccc4)c4cccc2c43)cc1]

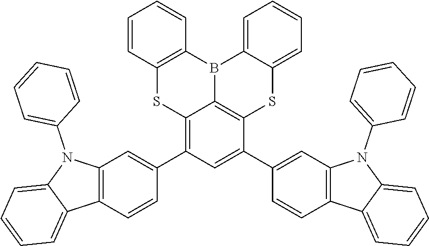 [SMILES: c1ccc(-n2c3ccccc3c3ccc(-c4cc(-c5ccc6c7ccccc7n(-c7ccccc7)c6c5)c5c6c4Sc4ccccc4B6c4ccccc4S5)cc32)cc1]

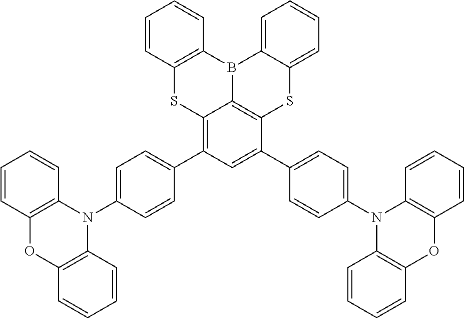 [SMILES: c1ccc2c(c1)Oc1ccccc1N2c1ccc(-c2cc(-c3ccc(N4c5ccccc5Oc5ccccc54)cc3)c3c4c2Sc2ccccc2B4c2ccccc2S3)cc1]

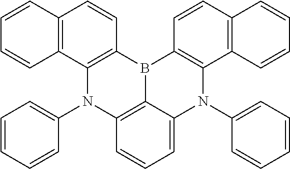 [SMILES: c1ccc(N2c3cccc4c3B(c3ccc5ccccc5c32)c2ccc3ccccc3c2N4c2ccccc2)cc1]

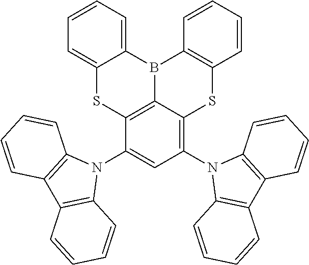

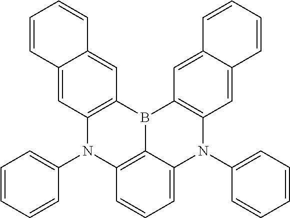 [SMILES: c1ccc(N2c3cc4ccccc4cc3B3c4cc5ccccc5cc4N(c4ccccc4)c4cccc2c43)cc1]

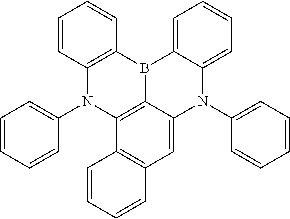 [SMILES: c1ccc(N2c3ccccc3B3c4ccccc4N(c4ccccc4)c4c3c2cc2ccccc42)cc1]

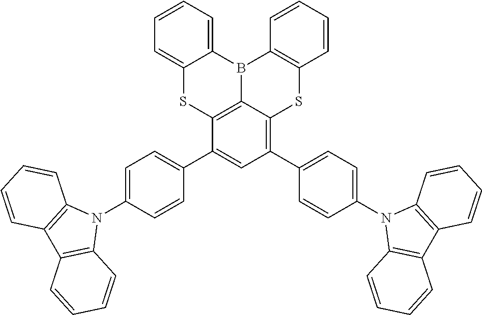 [SMILES: c1ccc2c(c1)Sc1c(-c3ccc(-n4c5ccccc5c5ccccc54)cc3)cc(-c3ccc(-n4c5ccccc5c5ccccc54)cc3)c3c1B2c1ccccc1S3]

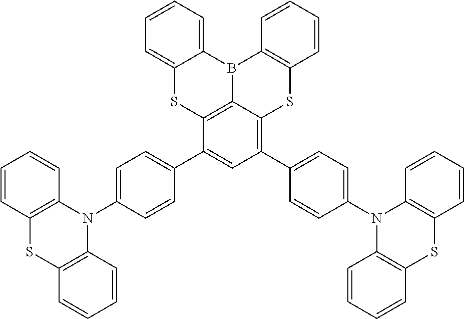 [SMILES: c1ccc2c(c1)Sc1c(-c3ccc(N4c5ccccc5Sc5ccccc54)cc3)cc(-c3ccc(N4c5ccccc5Sc5ccccc54)cc3)c3c1B2c1ccccc1S3]

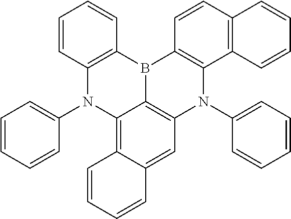 [SMILES: c1ccc(N2c3cc4ccccc4c4c3B(c3ccccc3N4c3ccccc3)c3ccc4ccccc4c32)cc1]

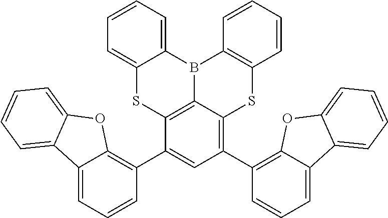 [SMILES: c1ccc2c(c1)Sc1c(-c3cccc4c3oc3ccccc34)cc(-c3cccc4c3oc3ccccc34)c3c1B2c1ccccc1S3]

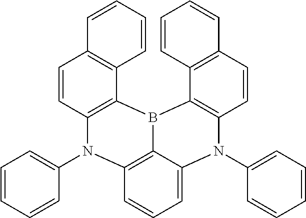 [SMILES: c1ccc(N2c3cccc4c3B(c3c2ccc2ccccc32)c2c(ccc3ccccc23)N4c2ccccc2)cc1]

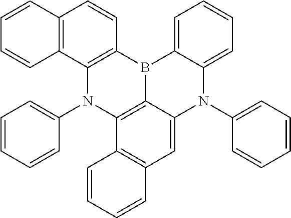 [SMILES: c1ccc(N2c3ccccc3B3c4ccc5ccccc5c4N(c4ccccc4)c4c3c2cc2ccccc42)cc1]

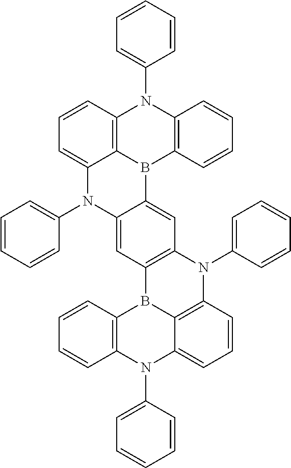 [SMILES: c1ccc(N2c3ccccc3B3c4cc5c(cc4N(c4ccccc4)c4cccc2c43)B2c3ccccc3N(c3ccccc3)c3cccc(c32)N5c2ccccc2)cc1]

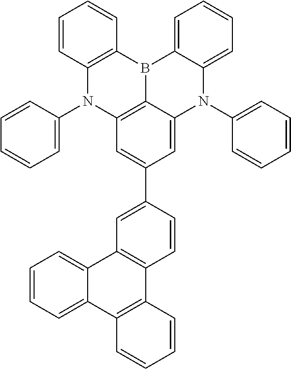 [SMILES: c1ccc(N2c3ccccc3B3c4ccccc4N(c4ccccc4)c4cc(-c5ccc6c7ccccc7c7ccccc7c6c5)cc2c43)cc1]

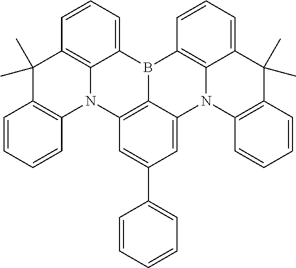

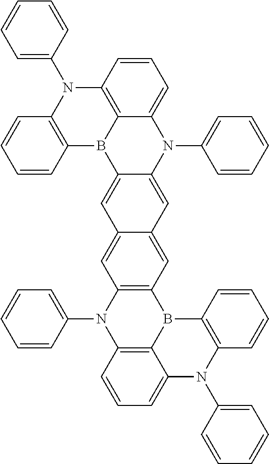 [SMILES: c1ccc(N2c3ccccc3B3c4cc5cc6c(cc5cc4N(c4ccccc4)c4cccc2c43)B2c3ccccc3N(c3ccccc3)c3cccc(c32)N6c2ccccc2)cc1]

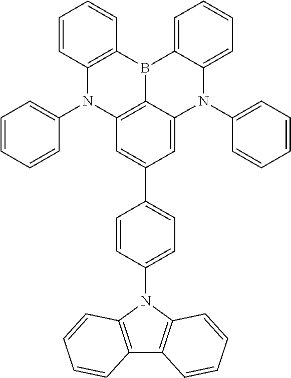 [SMILES: c1ccc(N2c3ccccc3B3c4ccccc4N(c4ccccc4)c4cc(-c5ccc(-n6c7ccccc7c7ccccc76)cc5)cc2c43)cc1]

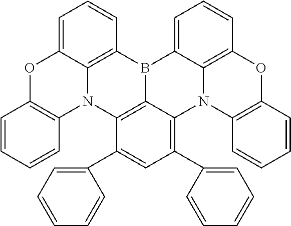 [SMILES: c1ccc(-c2cc(-c3ccccc3)c3c4c2N2c5ccccc5Oc5cccc(c52)B4c2cccc4c2N3c2ccccc2O4)cc1]

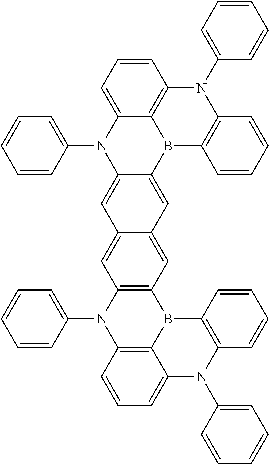 [SMILES: c1ccc(N2c3ccccc3B3c4cc5cc6c(cc5cc4N(c4ccccc4)c4cccc2c43)N(c2ccccc2)c2cccc3c2B6c2ccccc2N3c2ccccc2)cc1]

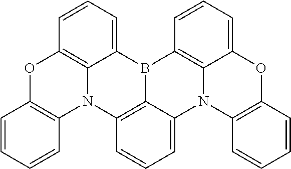 [SMILES: c1ccc2c(c1)Oc1cccc3c1N2c1cccc2c1B3c1cccc3c1N2c1ccccc1O3]

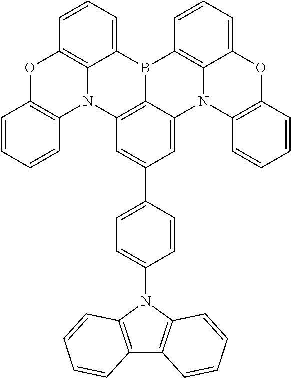 [SMILES: c1ccc2c(c1)Oc1cccc3c1N2c1cc(-c2ccc(-n4c5ccccc5c5ccccc54)cc2)cc2c1B3c1cccc3c1N2c1ccccc1O3]

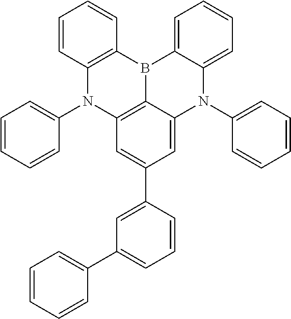 [SMILES: c1ccc(-c2cccc(-c3cc4c5c(c3)N(c3ccccc3)c3ccccc3B5c3ccccc3N4c3ccccc3)c2)cc1]

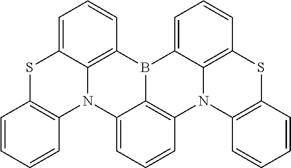 [SMILES: c1ccc2c(c1)Sc1cccc3c1N2c1cccc2c1B3c1cccc3c1N2c1ccccc1S3]

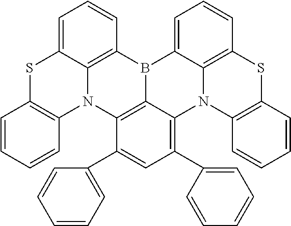 [SMILES: c1ccc(-c2cc(-c3ccccc3)c3c4c2N2c5ccccc5Sc5cccc(c52)B4c2cccc4c2N3c2ccccc2S4)cc1]

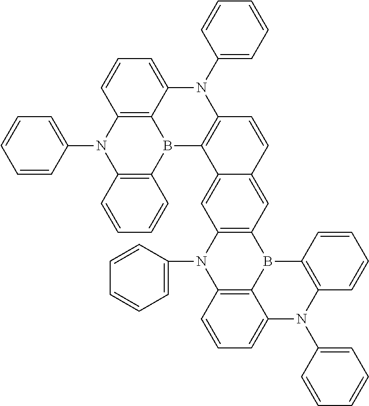 [SMILES: c1ccc(N2c3ccccc3B3c4cc5ccc6c(c5cc4N(c4ccccc4)c4cccc2c43)B2c3ccccc3N(c3ccccc3)c3cccc(c32)N6c2ccccc2)cc1]

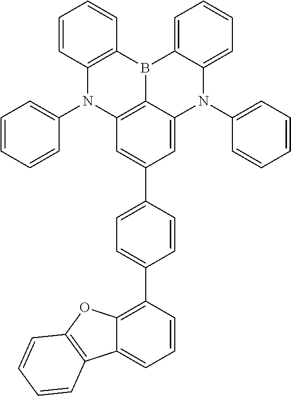 [SMILES: c1ccc(N2c3ccccc3B3c4ccccc4N(c4ccccc4)c4cc(-c5ccc(-c6cccc7c6oc6ccccc67)cc5)cc2c43)cc1]

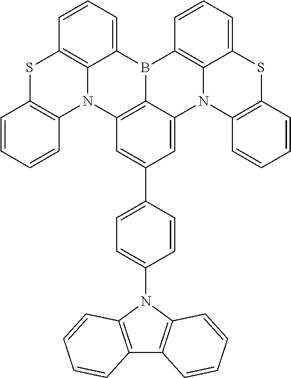 [SMILES: c1ccc2c(c1)Sc1cccc3c1N2c1cc(-c2ccc(-n4c5ccccc5c5ccccc54)cc2)cc2c1B3c1cccc3c1N2c1ccccc1S3]

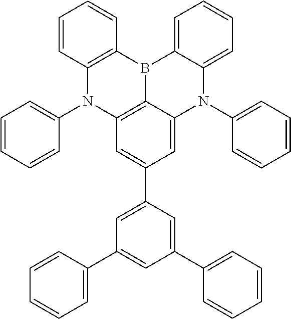 [SMILES: c1ccc(-c2cc(-c3ccccc3)cc(-c3cc4c5c(c3)N(c3ccccc3)c3ccccc3B5c3ccccc3N4c3ccccc3)c2)cc1]

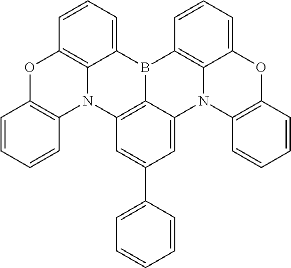 [SMILES: c1ccc(-c2cc3c4c(c2)N2c5ccccc5Oc5cccc(c52)B4c2cccc4c2N3c2ccccc2O4)cc1]

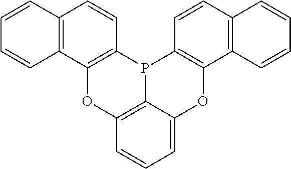 [SMILES: c1cc2c3c(c1)Oc1c(ccc4ccccc14)P3c1ccc3ccccc3c1O2]

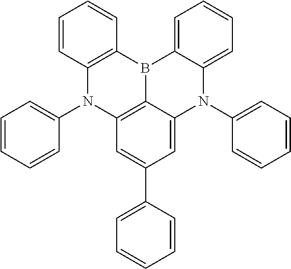 [SMILES: c1ccc(-c2cc3c4c(c2)N(c2ccccc2)c2ccccc2B4c2ccccc2N3c2ccccc2)cc1]

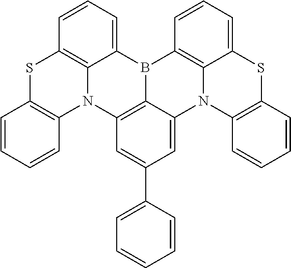 [SMILES: c1ccc(-c2cc3c4c(c2)N2c5ccccc5Sc5cccc(c52)B4c2cccc4c2N3c2ccccc2S4)cc1]

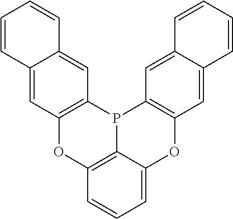 [SMILES: c1cc2c3c(c1)Oc1cc4ccccc4cc1P3c1cc3ccccc3cc1O2]

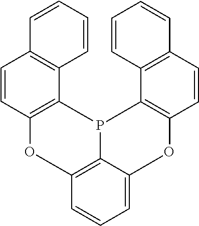 [SMILES: c1cc2c3c(c1)Oc1ccc4ccccc4c1P3c1c(ccc3ccccc13)O2]

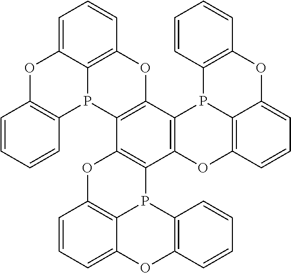 [SMILES: c1ccc2c(c1)oc1cccc3oc4c(c5oc6cccc7oc8ccccc8p(c76)c5c5oc6cccc7oc8ccccc8p(c76)c45)p2c13]

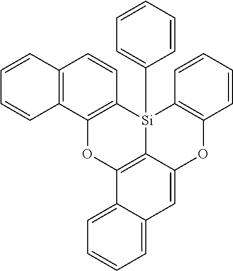 [SMILES: c1ccc([Si]23c4ccccc4Oc4cc5ccccc5c(c42)Oc2c3ccc3ccccc23)cc1]

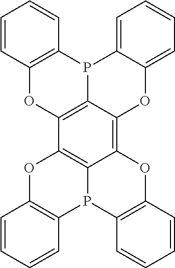 [SMILES: c1ccc2c(c1)oc1c3oc4ccccc4p4c5ccccc5oc(c5oc6ccccc6p2c15)c34]

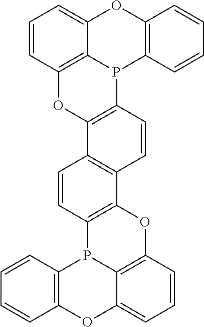 [SMILES: c1ccc2c(c1)Oc1cccc3oc4c5ccc6c(oc7cccc8c7p6-c6ccccc6O8)c5ccc4p-2c13]

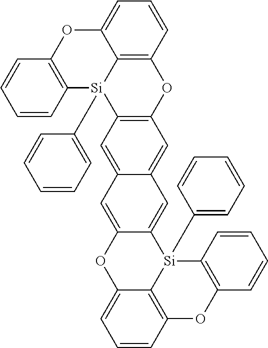 [SMILES: c1ccc([Si]23c4ccccc4Oc4cccc(c42)Oc2cc4cc5c(cc4cc23)Oc2cccc3c2[Si]5(c2ccccc2)c2ccccc2O3)cc1]

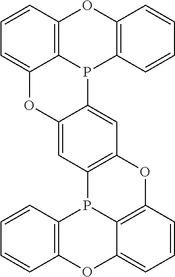 [SMILES: c1ccc2c(c1)oc1cccc3oc4cc5c(cc4p2c13)oc1cccc2oc3ccccc3p5c21]

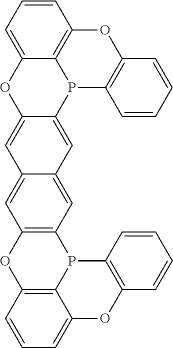 [SMILES: c1ccc2c(c1)Oc1cccc3oc4cc5cc6oc7cccc8c7p(c6cc5cc4p-2c13)-c1ccccc1O8]

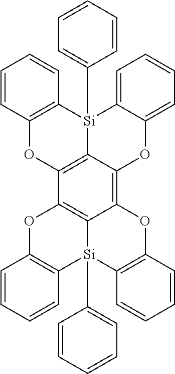 [SMILES: c1ccc([Si]23c4ccccc4Oc4c5c6c(c(c42)Oc2ccccc23)Oc2ccccc2[Si]6(c2ccccc2)c2ccccc2O5)cc1]

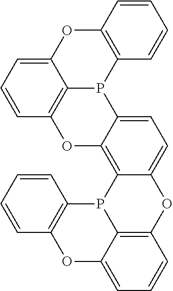 [SMILES: c1ccc2c(c1)oc1cccc3oc4c(ccc5oc6cccc7oc8ccccc8p(c76)c54)p2c13]

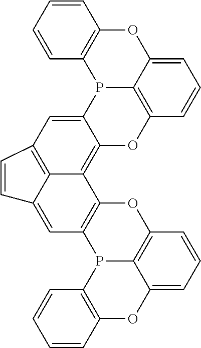 [SMILES: c1ccc2c(c1)oc1cccc3oc4c5c6oc7cccc8oc9ccccc9p(c6cc6ccc(cc4p2c13)c65)c87]

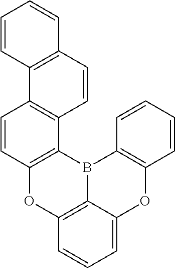 [SMILES: c1ccc2c(c1)Oc1cccc3c1B2c1c(ccc2c1ccc1ccccc12)O3]

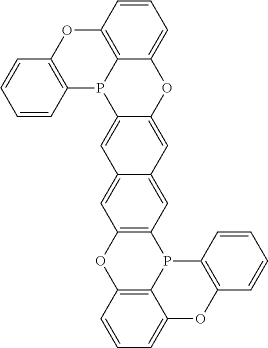 [SMILES: c1ccc2c(c1)Oc1cccc3oc4cc5cc6c(cc5cc4p-2c13)oc1cccc2c1p6-c1ccccc1O2]

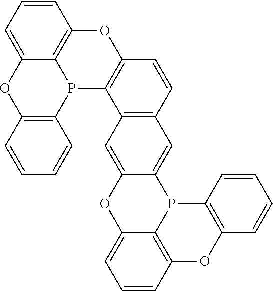 [SMILES: c1ccc2c(c1)Oc1cccc3oc4cc5c(ccc6oc7cccc8c7p(c65)-c5ccccc5O8)cc4p-2c13]

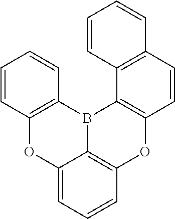 [SMILES: c1ccc2c(c1)Oc1cccc3c1B2c1c(ccc2ccccc12)O3]

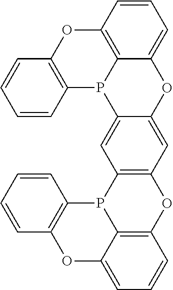 [SMILES: c1ccc2c(c1)oc1cccc3oc4cc5oc6cccc7oc8ccccc8p(c5cc4p2c13)c76]

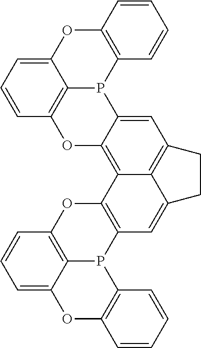 [SMILES: c1ccc2c(c1)Oc1cccc3oc4c5c6c(cc4p-2c13)CCc6cc1c5oc2cccc3c2p1-c1ccccc1O3]

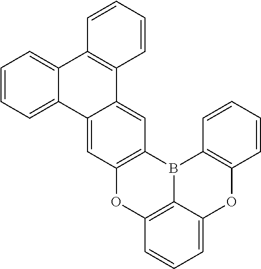 [SMILES: c1ccc2c(c1)Oc1cccc3c1B2c1cc2c4ccccc4c4ccccc4c2cc1O3]

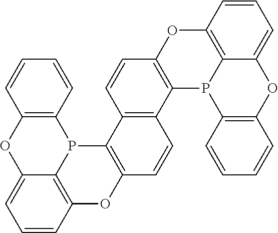 [SMILES: c1ccc2c(c1)Oc1cccc3oc4ccc5c(ccc6oc7cccc8c7p(c65)-c5ccccc5O8)c4p-2c13]

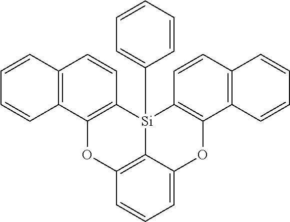 [SMILES: c1ccc([Si]23c4ccc5ccccc5c4Oc4cccc(c42)Oc2c3ccc3ccccc23)cc1]

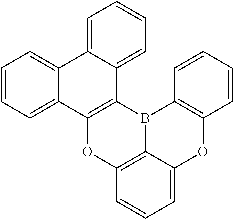 [SMILES: c1ccc2c(c1)Oc1cccc3c1B2c1c(c2ccccc2c2ccccc12)O3]

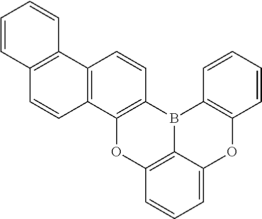 [SMILES: c1ccc2c(c1)Oc1cccc3c1B2c1ccc2c(ccc4ccccc42)c1O3]

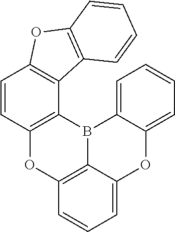 [SMILES: c1ccc2c(c1)Oc1cccc3c1B2c1c(ccc2oc4ccccc4c12)O3]

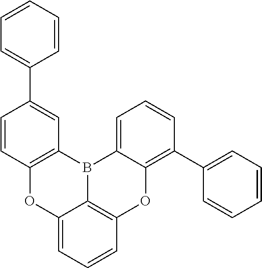 [SMILES: c1ccc(-c2ccc3c(c2)B2c4cccc(-c5ccccc5)c4Oc4cccc(c42)O3)cc1]

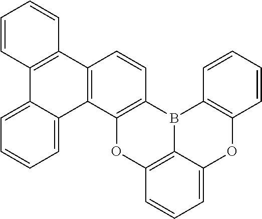 [SMILES: c1ccc2c(c1)Oc1cccc3c1B2c1ccc2c4ccccc4c4ccccc4c2c1O3]

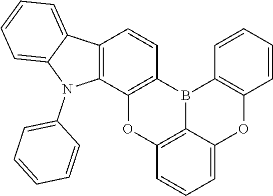 [SMILES: c1ccc(-n2c3ccccc3c3ccc4c(c32)Oc2cccc3c2B4c2ccccc2O3)cc1]

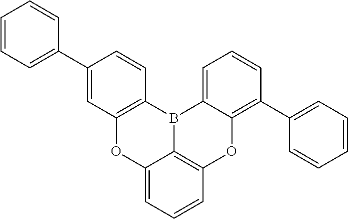 [SMILES: c1ccc(-c2ccc3c(c2)Oc2cccc4c2B3c2cccc(-c3ccccc3)c2O4)cc1]

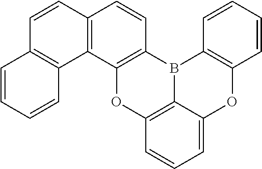 [SMILES: c1ccc2c(c1)Oc1cccc3c1B2c1ccc2ccc4ccccc4c2c1O3]

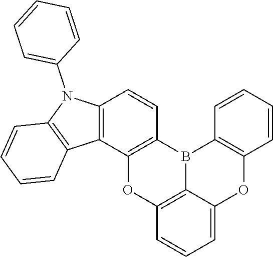 [SMILES: c1ccc(-n2c3ccccc3c3c4c(ccc32)B2c3ccccc3Oc3cccc(c32)O4)cc1]

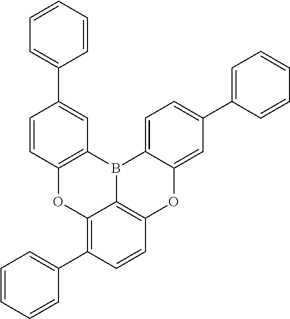 [SMILES: c1ccc(-c2ccc3c(c2)Oc2ccc(-c4ccccc4)c4c2B3c2cc(-c3ccccc3)ccc2O4)cc1]

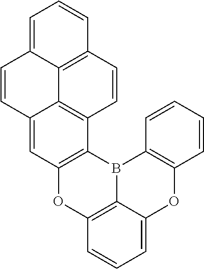 [SMILES: c1ccc2c(c1)Oc1cccc3c1B2c1c(cc2ccc4cccc5ccc1c2c45)O3]

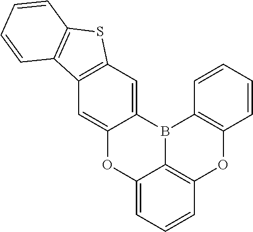 [SMILES: c1ccc2c(c1)Oc1cccc3c1B2c1cc2sc4ccccc4c2cc1O3]

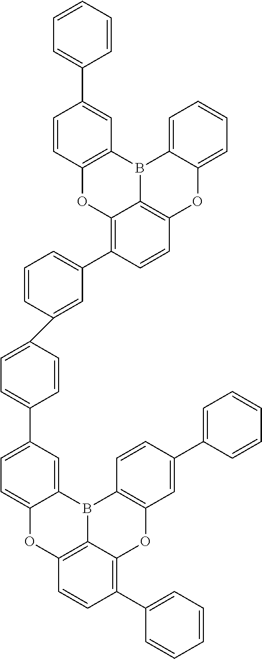 [SMILES: c1ccc(-c2ccc3c(c2)Oc2c(-c4ccccc4)ccc4c2B3c2cc(-c3ccc(-c5cccc(-c6ccc7c8c6Oc6ccc(-c9ccccc9)cc6B8c6ccccc6O7)c5)cc3)ccc2O4)cc1]

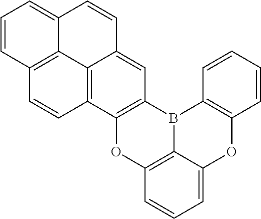 [SMILES: c1ccc2c(c1)Oc1cccc3c1B2c1cc2ccc4cccc5ccc(c1O3)c2c45]

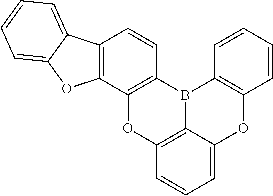 [SMILES: c1ccc2c(c1)Oc1cccc3c1B2c1ccc2c(oc4ccccc42)c1O3]

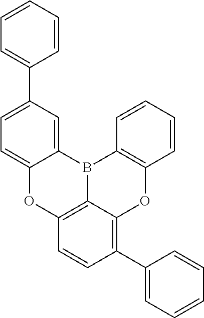 [SMILES: c1ccc(-c2ccc3c(c2)B2c4ccccc4Oc4c(-c5ccccc5)ccc(c42)O3)cc1]

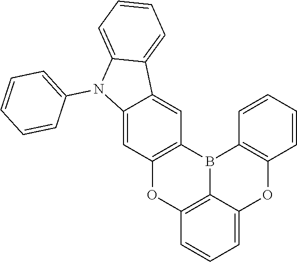 [SMILES: c1ccc(-n2c3ccccc3c3cc4c(cc32)Oc2cccc3c2B4c2ccccc2O3)cc1]

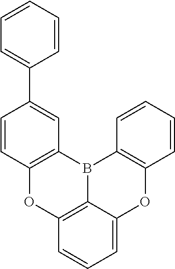 [SMILES: c1ccc(-c2ccc3c(c2)B2c4ccccc4Oc4cccc(c42)O3)cc1]

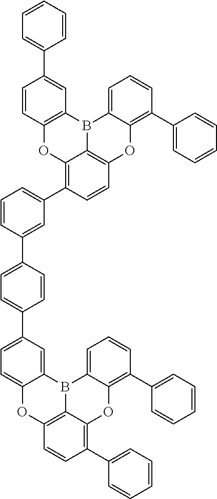 [SMILES: c1ccc(-c2ccc3c(c2)B2c4cccc(-c5ccccc5)c4Oc4ccc(-c5cccc(-c6ccc(-c7ccc8c(c7)B7c9cccc(-c%10ccccc%10)c9Oc9c(-c%10ccccc%10)ccc(c97)O8)cc6)c5)c(c42)O3)cc1]

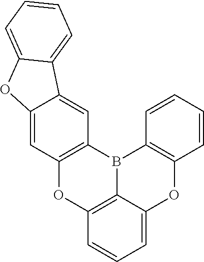 [SMILES: c1ccc2c(c1)Oc1cccc3c1B2c1cc2c(cc1O3)oc1ccccc12]

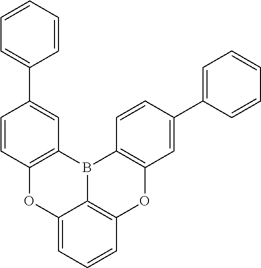 [SMILES: c1ccc(-c2ccc3c(c2)Oc2cccc4c2B3c2cc(-c3ccccc3)ccc2O4)cc1]

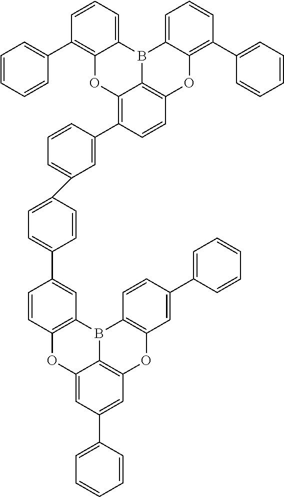 [SMILES: c1ccc(-c2ccc3c(c2)Oc2cc(-c4ccccc4)cc4c2B3c2cc(-c3ccc(-c5cccc(-c6ccc7c8c6Oc6c(cccc6-c6ccccc6)B8c6cccc(-c8ccccc8)c6O7)c5)cc3)ccc2O4)cc1]

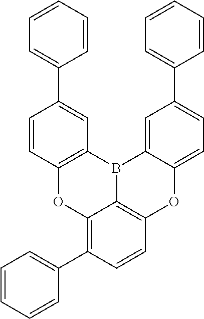 [SMILES: c1ccc(-c2ccc3c(c2)B2c4cc(-c5ccccc5)ccc4Oc4c(-c5ccccc5)ccc(c42)O3)cc1]

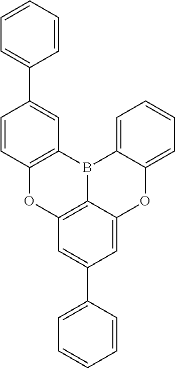 [SMILES: c1ccc(-c2cc3c4c(c2)Oc2ccc(-c5ccccc5)cc2B4c2ccccc2O3)cc1]

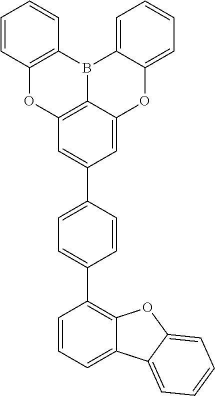 [SMILES: c1ccc2c(c1)Oc1cc(-c3ccc(-c4cccc5c4oc4ccccc45)cc3)cc3c1B2c1ccccc1O3]

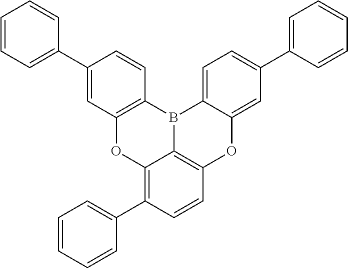 [SMILES: c1ccc(-c2ccc3c(c2)Oc2ccc(-c4ccccc4)c4c2B3c2ccc(-c3ccccc3)cc2O4)cc1]

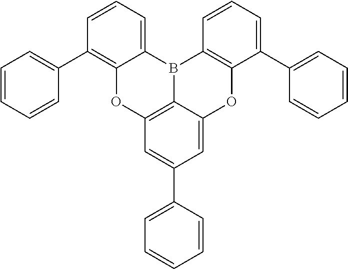 [SMILES: c1ccc(-c2cc3c4c(c2)Oc2c(cccc2-c2ccccc2)B4c2cccc(-c4ccccc4)c2O3)cc1]

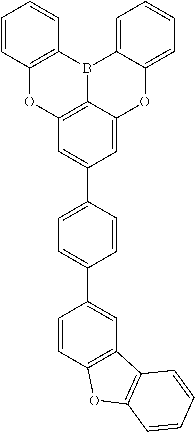 [SMILES: c1ccc2c(c1)Oc1cc(-c3ccc(-c4ccc5oc6ccccc6c5c4)cc3)cc3c1B2c1ccccc1O3]

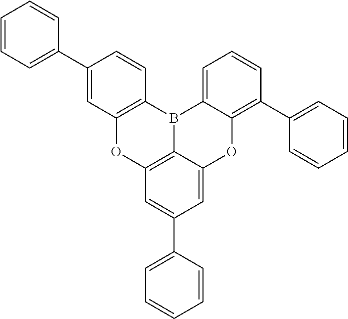 [SMILES: c1ccc(-c2ccc3c(c2)Oc2cc(-c4ccccc4)cc4c2B3c2cccc(-c3ccccc3)c2O4)cc1]

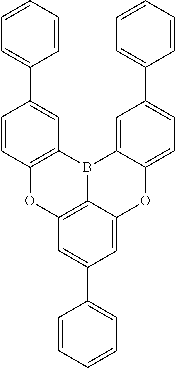 [SMILES: c1ccc(-c2cc3c4c(c2)Oc2ccc(-c5ccccc5)cc2B4c2cc(-c4ccccc4)ccc2O3)cc1]

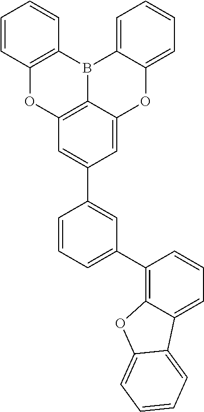 [SMILES: c1cc(-c2cc3c4c(c2)Oc2ccccc2B4c2ccccc2O3)cc(-c2cccc3c2oc2ccccc23)c1]

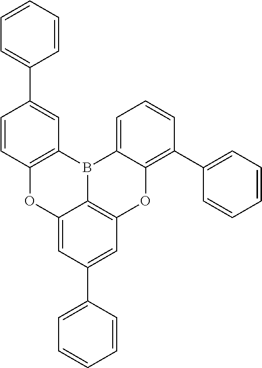 [SMILES: c1ccc(-c2cc3c4c(c2)Oc2c(cccc2-c2ccccc2)B4c2cc(-c4ccccc4)ccc2O3)cc1]

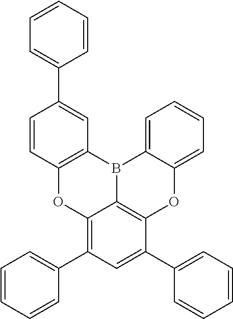 [SMILES: c1ccc(-c2ccc3c(c2)B2c4ccccc4Oc4c(-c5ccccc5)cc(-c5ccccc5)c(c42)O3)cc1]

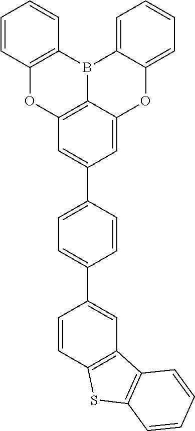 [SMILES: c1ccc2c(c1)Oc1cc(-c3ccc(-c4ccc5sc6ccccc6c5c4)cc3)cc3c1B2c1ccccc1O3]

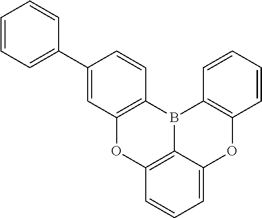 [SMILES: c1ccc(-c2ccc3c(c2)Oc2cccc4c2B3c2ccccc2O4)cc1]

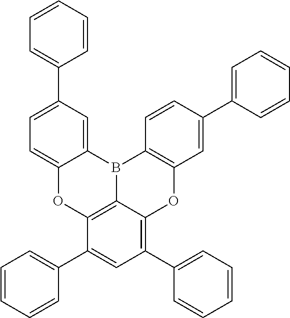 [SMILES: c1ccc(-c2ccc3c(c2)Oc2c(-c4ccccc4)cc(-c4ccccc4)c4c2B3c2cc(-c3ccccc3)ccc2O4)cc1]

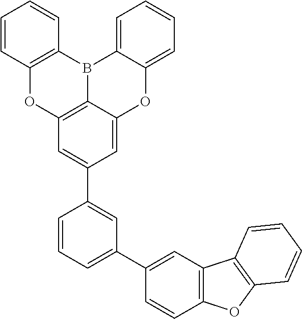 [SMILES: c1cc(-c2cc3c4c(c2)Oc2ccccc2B4c2ccccc2O3)cc(-c2ccc3oc4ccccc4c3c2)c1]

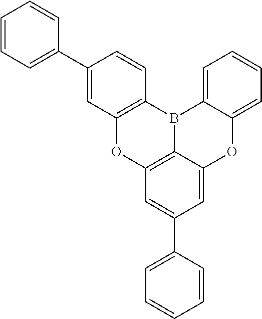 [SMILES: c1ccc(-c2ccc3c(c2)Oc2cc(-c4ccccc4)cc4c2B3c2ccccc2O4)cc1]

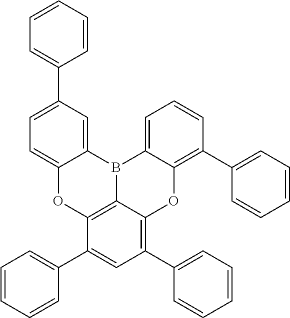 [SMILES: c1ccc(-c2ccc3c(c2)B2c4cccc(-c5ccccc5)c4Oc4c(-c5ccccc5)cc(-c5ccccc5)c(c42)O3)cc1]

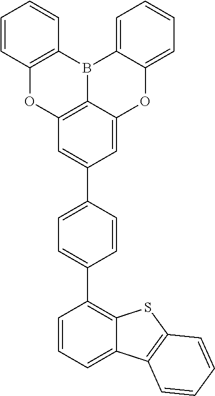 [SMILES: c1ccc2c(c1)Oc1cc(-c3ccc(-c4cccc5c4sc4ccccc45)cc3)cc3c1B2c1ccccc1O3]

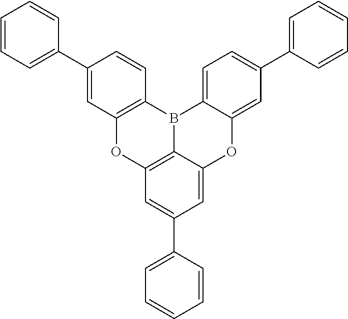 [SMILES: c1ccc(-c2ccc3c(c2)Oc2cc(-c4ccccc4)cc4c2B3c2ccc(-c3ccccc3)cc2O4)cc1]

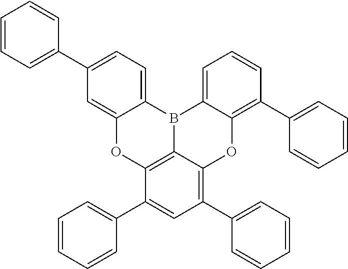 [SMILES: c1ccc(-c2ccc3c(c2)Oc2c(-c4ccccc4)cc(-c4ccccc4)c4c2B3c2cccc(-c3ccccc3)c2O4)cc1]

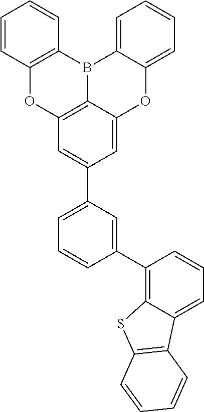 [SMILES: c1cc(-c2cc3c4c(c2)Oc2ccccc2B4c2ccccc2O3)cc(-c2cccc3c2sc2ccccc23)c1]

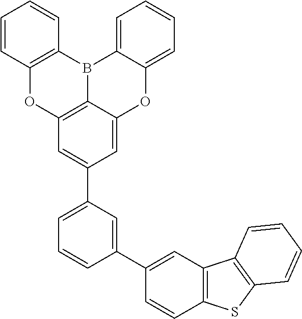 [SMILES: c1cc(-c2cc3c4c(c2)Oc2ccccc2B4c2ccccc2O3)cc(-c2ccc3sc4ccccc4c3c2)c1]

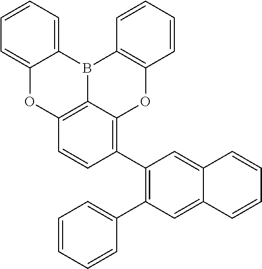 [SMILES: c1ccc(-c2cc3ccccc3cc2-c2ccc3c4c2Oc2ccccc2B4c2ccccc2O3)cc1]

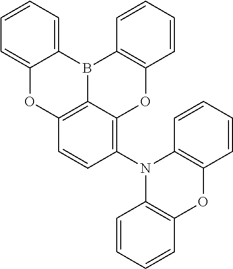 [SMILES: c1ccc2c(c1)Oc1ccc(N3c4ccccc4Oc4ccccc43)c3c1B2c1ccccc1O3]

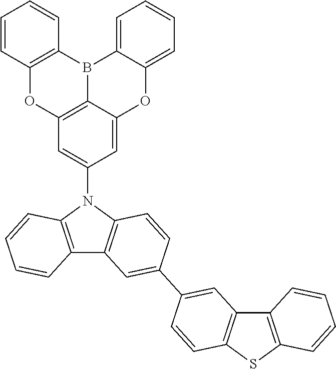 [SMILES: c1ccc2c(c1)Oc1cc(-n3c4ccccc4c4cc(-c5ccc6sc7ccccc7c6c5)ccc43)cc3c1B2c1ccccc1O3]

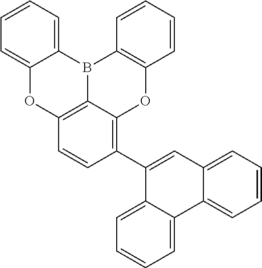 [SMILES: c1ccc2c(c1)Oc1ccc(-c3cc4ccccc4c4ccccc34)c3c1B2c1ccccc1O3]

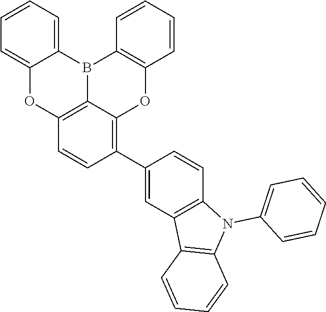 [SMILES: c1ccc(-n2c3ccccc3c3cc(-c4ccc5c6c4Oc4ccccc4B6c4ccccc4O5)ccc32)cc1]

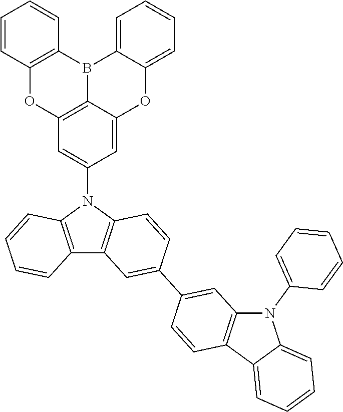 [SMILES: c1ccc(-n2c3ccccc3c3ccc(-c4ccc5c(c4)c4ccccc4n5-c4cc5c6c(c4)Oc4ccccc4B6c4ccccc4O5)cc32)cc1]

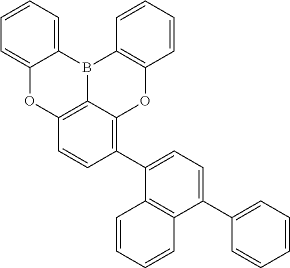 [SMILES: c1ccc(-c2ccc(-c3ccc4c5c3Oc3ccccc3B5c3ccccc3O4)c3ccccc23)cc1]

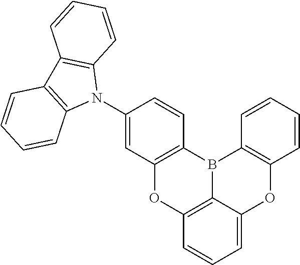 [SMILES: c1ccc2c(c1)Oc1cccc3c1B2c1ccc(-n2c4ccccc4c4ccccc42)cc1O3]

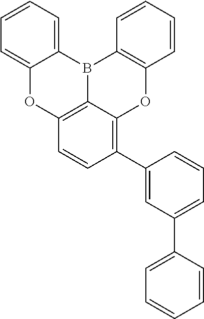 [SMILES: c1ccc(-c2cccc(-c3ccc4c5c3Oc3ccccc3B5c3ccccc3O4)c2)cc1]

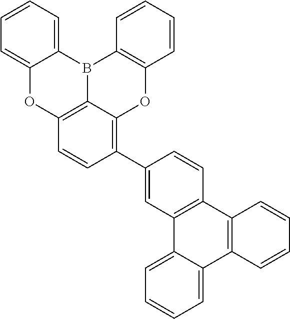 [SMILES: c1ccc2c(c1)Oc1ccc(-c3ccc4c5ccccc5c5ccccc5c4c3)c3c1B2c1ccccc1O3]

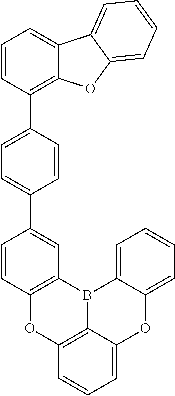 [SMILES: c1ccc2c(c1)Oc1cccc3c1B2c1cc(-c2ccc(-c4cccc5c4oc4ccccc45)cc2)ccc1O3]

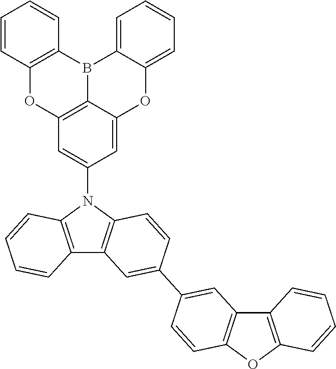 [SMILES: c1ccc2c(c1)Oc1cc(-n3c4ccccc4c4cc(-c5ccc6oc7ccccc7c6c5)ccc43)cc3c1B2c1ccccc1O3]

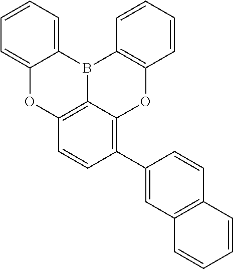 [SMILES: c1ccc2c(c1)Oc1ccc(-c3ccc4ccccc4c3)c3c1B2c1ccccc1O3]

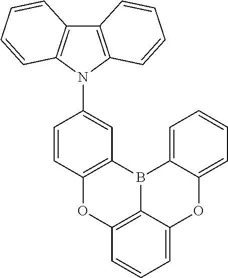 [SMILES: c1ccc2c(c1)Oc1cccc3c1B2c1cc(-n2c4ccccc4c4ccccc42)ccc1O3]

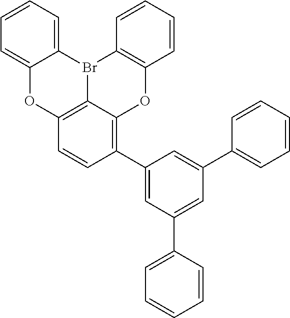

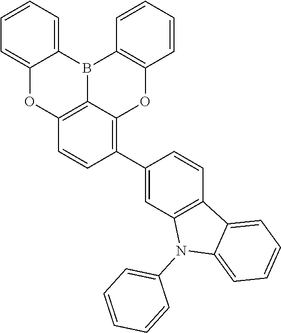 [SMILES: c1ccc(-n2c3ccccc3c3ccc(-c4ccc5c6c4Oc4ccccc4B6c4ccccc4O5)cc32)cc1]

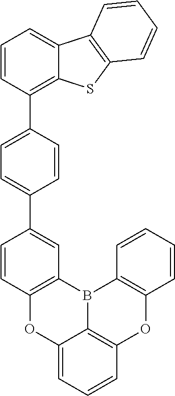 [SMILES: c1ccc2c(c1)Oc1cccc3c1B2c1cc(-c2ccc(-c4cccc5c4sc4ccccc45)cc2)ccc1O3]

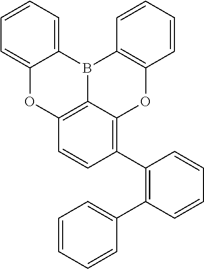 [SMILES: c1ccc(-c2ccccc2-c2ccc3c4c2Oc2ccccc2B4c2ccccc2O3)cc1]

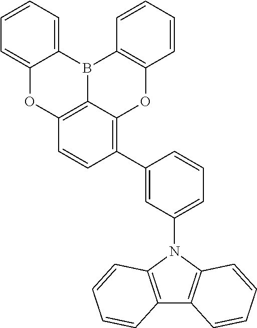 [SMILES: c1cc(-c2ccc3c4c2Oc2ccccc2B4c2ccccc2O3)cc(-n2c3ccccc3c3ccccc32)c1]

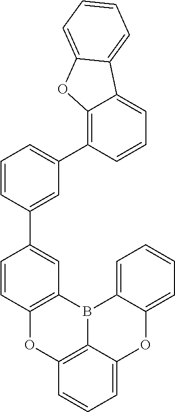 [SMILES: c1cc(-c2ccc3c(c2)B2c4ccccc4Oc4cccc(c42)O3)cc(-c2cccc3c2oc2ccccc23)c1]

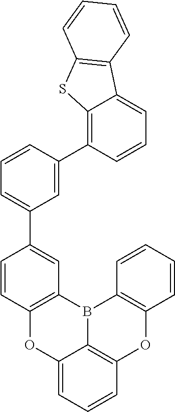 [SMILES: c1cc(-c2ccc3c(c2)B2c4ccccc4Oc4cccc(c42)O3)cc(-c2cccc3c2sc2ccccc23)c1]

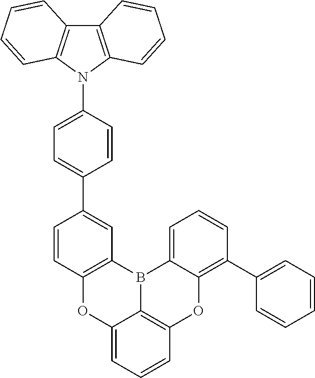 [SMILES: c1ccc(-c2cccc3c2Oc2cccc4c2B3c2cc(-c3ccc(-n5c6ccccc6c6ccccc65)cc3)ccc2O4)cc1]

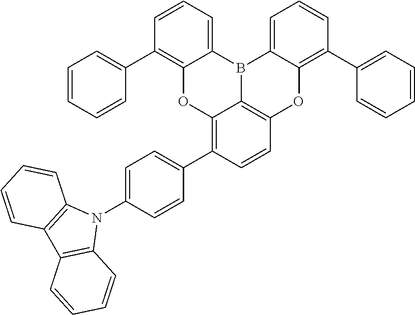 [SMILES: c1ccc(-c2cccc3c2Oc2ccc(-c4ccc(-n5c6ccccc6c6ccccc65)cc4)c4c2B3c2cccc(-c3ccccc3)c2O4)cc1]

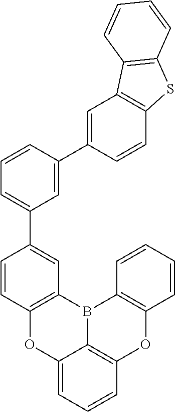 [SMILES: c1cc(-c2ccc3c(c2)B2c4ccccc4Oc4cccc(c42)O3)cc(-c2ccc3sc4ccccc4c3c2)c1]

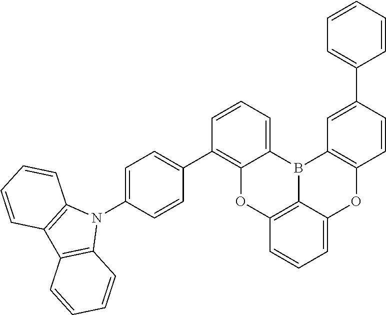 [SMILES: c1ccc(-c2ccc3c(c2)B2c4cccc(-c5ccc(-n6c7ccccc7c7ccccc76)cc5)c4Oc4cccc(c42)O3)cc1]

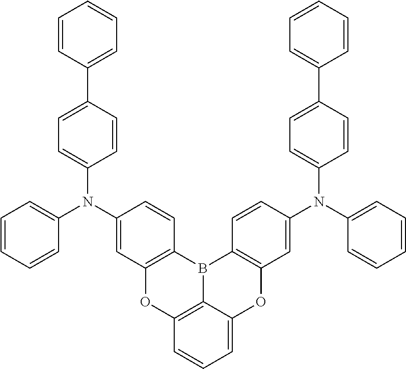 [SMILES: c1ccc(-c2ccc(N(c3ccccc3)c3ccc4c(c3)Oc3cccc5c3B4c3ccc(N(c4ccccc4)c4ccc(-c6ccccc6)cc4)cc3O5)cc2)cc1]

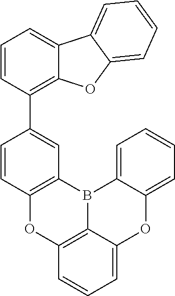 [SMILES: c1ccc2c(c1)Oc1cccc3c1B2c1cc(-c2cccc4c2oc2ccccc24)ccc1O3]

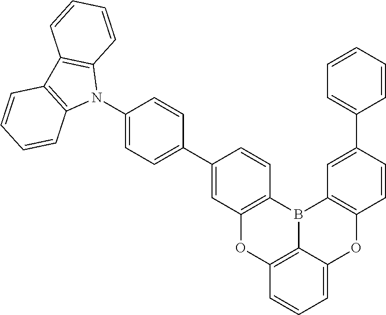 [SMILES: c1ccc(-c2ccc3c(c2)B2c4ccc(-c5ccc(-n6c7ccccc7c7ccccc76)cc5)cc4Oc4cccc(c42)O3)cc1]

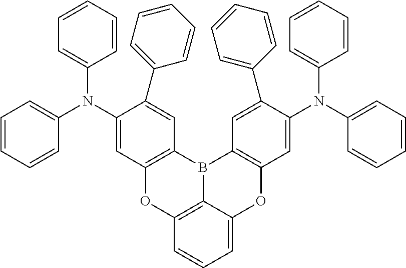 [SMILES: c1ccc(-c2cc3c(cc2N(c2ccccc2)c2ccccc2)Oc2cccc4c2B3c2cc(-c3ccccc3)c(N(c3ccccc3)c3ccccc3)cc2O4)cc1]

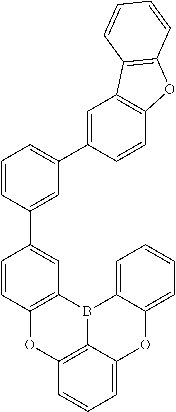 [SMILES: c1cc(-c2ccc3c(c2)B2c4ccccc4Oc4cccc(c42)O3)cc(-c2ccc3oc4ccccc4c3c2)c1]

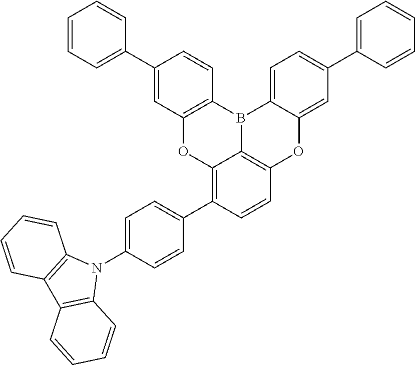 [SMILES: c1ccc(-c2ccc3c(c2)Oc2ccc(-c4ccc(-n5c6ccccc6c6ccccc65)cc4)c4c2B3c2ccc(-c3ccccc3)cc2O4)cc1]

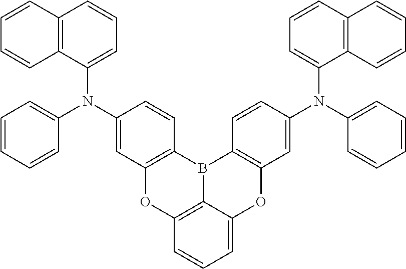 [SMILES: c1ccc(N(c2ccc3c(c2)Oc2cccc4c2B3c2ccc(N(c3ccccc3)c3cccc5ccccc35)cc2O4)c2cccc3ccccc23)cc1]

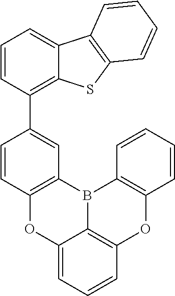 [SMILES: c1ccc2c(c1)Oc1cccc3c1B2c1cc(-c2cccc4c2sc2ccccc24)ccc1O3]

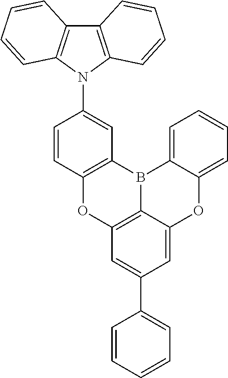 [SMILES: c1ccc(-c2cc3c4c(c2)Oc2ccc(-n5c6ccccc6c6ccccc65)cc2B4c2ccccc2O3)cc1]

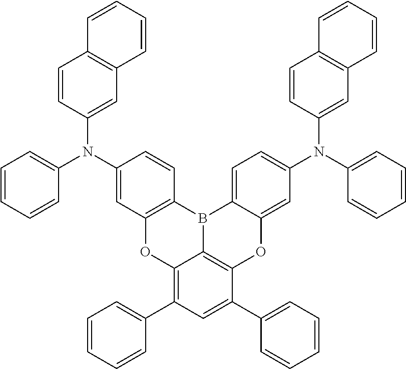 [SMILES: c1ccc(-c2cc(-c3ccccc3)c3c4c2Oc2cc(N(c5ccccc5)c5ccc6ccccc6c5)ccc2B4c2ccc(N(c4ccccc4)c4ccc5ccccc5c4)cc2O3)cc1]

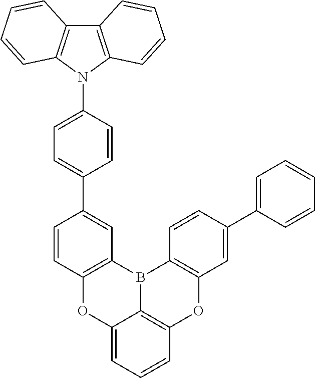 [SMILES: c1ccc(-c2ccc3c(c2)Oc2cccc4c2B3c2cc(-c3ccc(-n5c6ccccc6c6ccccc65)cc3)ccc2O4)cc1]

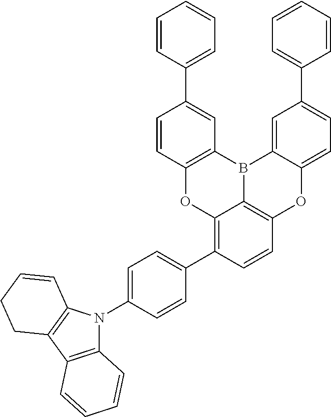 [SMILES: C1=Cc2c(c3ccccc3n2-c2ccc(-c3ccc4c5c3Oc3ccc(-c6ccccc6)cc3B5c3cc(-c5ccccc5)ccc3O4)cc2)CC1]

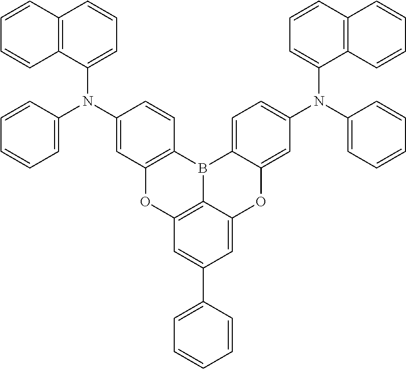 [SMILES: c1ccc(-c2cc3c4c(c2)Oc2cc(N(c5ccccc5)c5cccc6ccccc56)ccc2B4c2ccc(N(c4ccccc4)c4cccc5ccccc45)cc2O3)cc1]

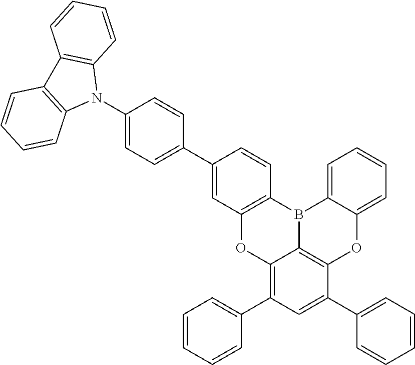 [SMILES: c1ccc(-c2cc(-c3ccccc3)c3c4c2Oc2ccccc2B4c2ccc(-c4ccc(-n5c6ccccc6c6ccccc65)cc4)cc2O3)cc1]

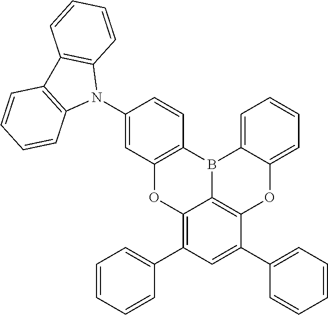 [SMILES: c1ccc(-c2cc(-c3ccccc3)c3c4c2Oc2ccccc2B4c2ccc(-n4c5ccccc5c5ccccc54)cc2O3)cc1]

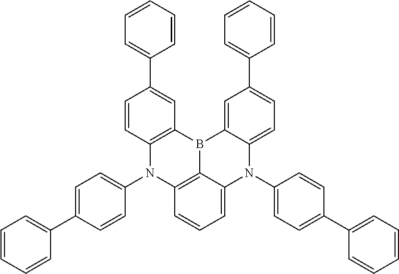 [SMILES: c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1]

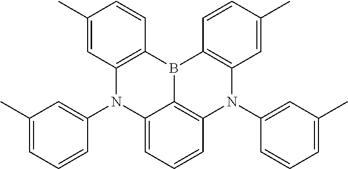

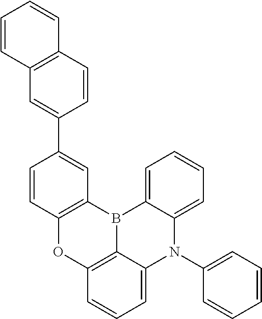 [SMILES: c1ccc(N2c3ccccc3B3c4cc(-c5ccc6ccccc6c5)ccc4Oc4cccc2c43)cc1]

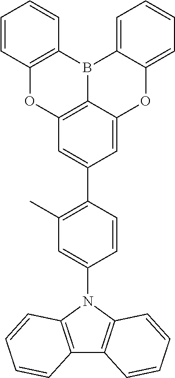 [SMILES: Cc1cc(-n2c3ccccc3c3ccccc32)ccc1-c1cc2c3c(c1)Oc1ccccc1B3c1ccccc1O2]

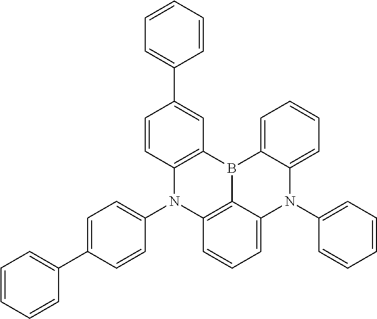 [SMILES: c1ccc(-c2ccc(N3c4ccc(-c5ccccc5)cc4B4c5ccccc5N(c5ccccc5)c5cccc3c54)cc2)cc1]

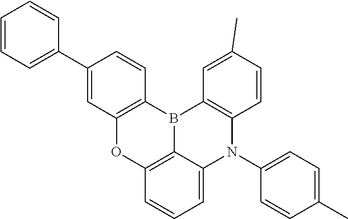 [SMILES: Cc1ccc(N2c3ccc(C)cc3B3c4ccc(-c5ccccc5)cc4Oc4cccc2c43)cc1]

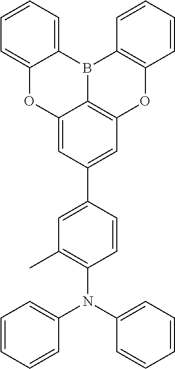 [SMILES: Cc1cc(-c2cc3c4c(c2)Oc2ccccc2B4c2ccccc2O3)ccc1N(c1ccccc1)c1ccccc1]

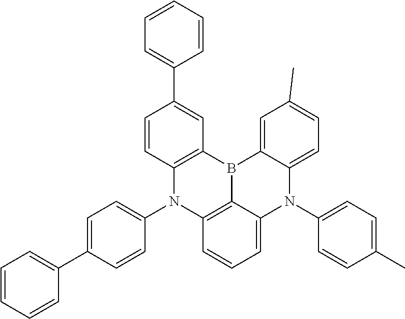 [SMILES: Cc1ccc(N2c3ccc(C)cc3B3c4cc(-c5ccccc5)ccc4N(c4ccc(-c5ccccc5)cc4)c4cccc2c43)cc1]

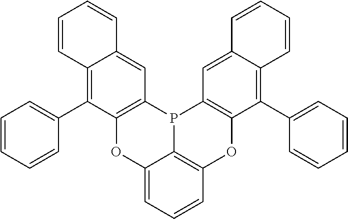 [SMILES: c1ccc(-c2c3c(cc4ccccc24)P2c4cc5ccccc5c(-c5ccccc5)c4Oc4cccc(c42)O3)cc1]

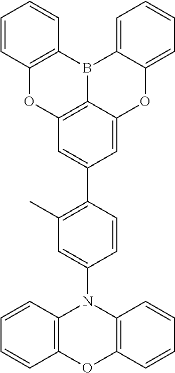 [SMILES: Cc1cc(N2c3ccccc3Oc3ccccc32)ccc1-c1cc2c3c(c1)Oc1ccccc1B3c1ccccc1O2]

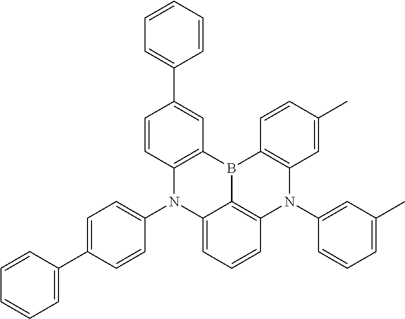 [SMILES: Cc1cccc(N2c3cc(C)ccc3B3c4cc(-c5ccccc5)ccc4N(c4ccc(-c5ccccc5)cc4)c4cccc2c43)c1]

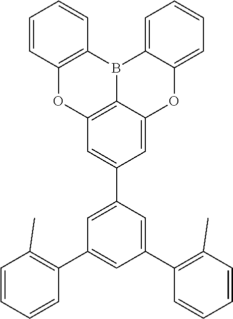 [SMILES: Cc1ccccc1-c1cc(-c2cc3c4c(c2)Oc2ccccc2B4c2ccccc2O3)cc(-c2ccccc2C)c1]

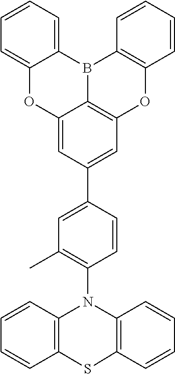 [SMILES: Cc1cc(-c2cc3c4c(c2)Oc2ccccc2B4c2ccccc2O3)ccc1N1c2ccccc2Sc2ccccc21]

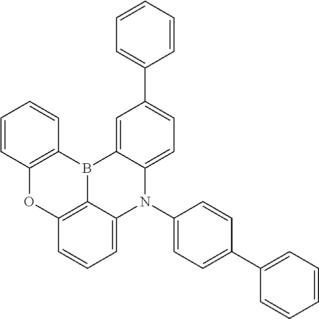 [SMILES: c1ccc(-c2ccc(N3c4ccc(-c5ccccc5)cc4B4c5ccccc5Oc5cccc3c54)cc2)cc1]

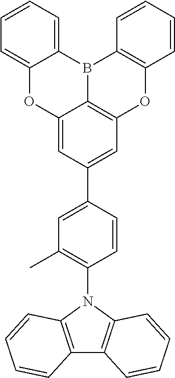 [SMILES: Cc1cc(-c2cc3c4c(c2)Oc2ccccc2B4c2ccccc2O3)ccc1-n1c2ccccc2c2ccccc21]

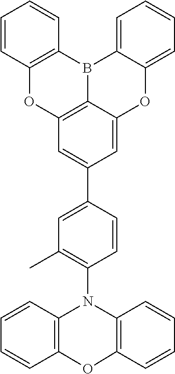 [SMILES: Cc1cc(-c2cc3c4c(c2)Oc2ccccc2B4c2ccccc2O3)ccc1N1c2ccccc2Oc2ccccc21]

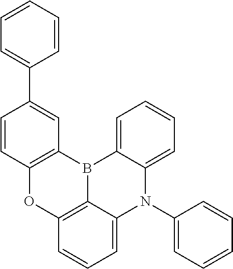 [SMILES: c1ccc(-c2ccc3c(c2)B2c4ccccc4N(c4ccccc4)c4cccc(c42)O3)cc1]

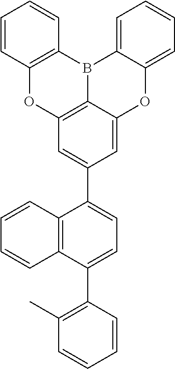 [SMILES: Cc1ccccc1-c1ccc(-c2cc3c4c(c2)Oc2ccccc2B4c2ccccc2O3)c2ccccc12]

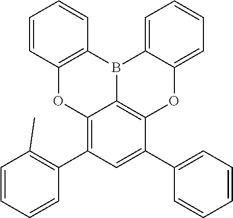 [SMILES: Cc1ccccc1-c1cc(-c2ccccc2)c2c3c1Oc1ccccc1B3c1ccccc1O2]

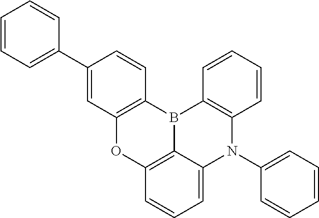 [SMILES: c1ccc(-c2ccc3c(c2)Oc2cccc4c2B3c2ccccc2N4c2ccccc2)cc1]

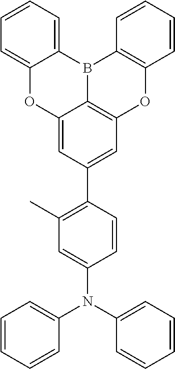 [SMILES: Cc1cc(N(c2ccccc2)c2ccccc2)ccc1-c1cc2c3c(c1)Oc1ccccc1B3c1ccccc1O2]

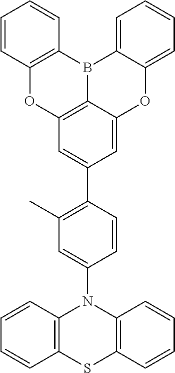 [SMILES: Cc1cc(N2c3ccccc3Sc3ccccc32)ccc1-c1cc2c3c(c1)Oc1ccccc1B3c1ccccc1O2]

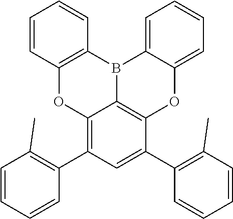 [SMILES: Cc1ccccc1-c1cc(-c2ccccc2C)c2c3c1Oc1ccccc1B3c1ccccc1O2]

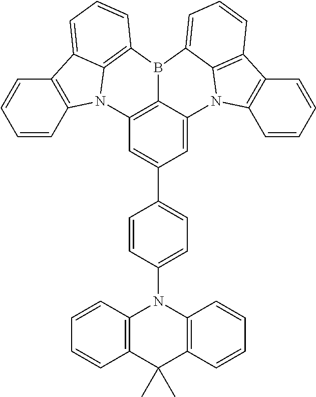 [SMILES: CC1(C)c2ccccc2N(c2ccc(-c3cc4c5c(c3)-n3c6ccccc6c6cccc(c63)B5c3cccc5c6ccccc6n-4c35)cc2)c2ccccc21]

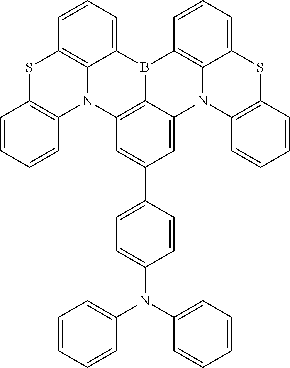 [SMILES: c1ccc(N(c2ccccc2)c2ccc(-c3cc4c5c(c3)N3c6ccccc6Sc6cccc(c63)B5c3cccc5c3N4c3ccccc3S5)cc2)cc1]

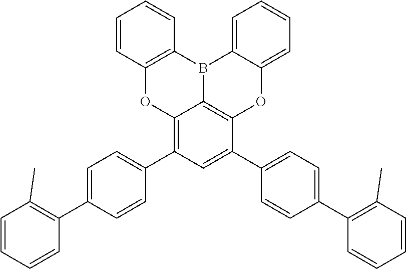 [SMILES: Cc1ccccc1-c1ccc(-c2cc(-c3ccc(-c4ccccc4C)cc3)c3c4c2Oc2ccccc2B4c2ccccc2O3)cc1]

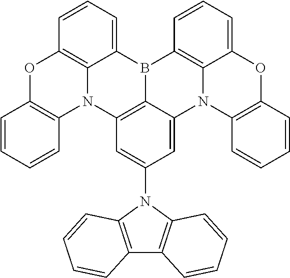 [SMILES: c1ccc2c(c1)Oc1cccc3c1N2c1cc(-n2c4ccccc4c4ccccc42)cc2c1B3c1cccc3c1N2c1ccccc1O3]

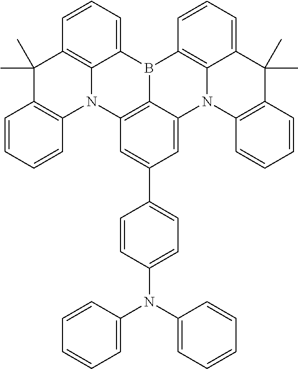

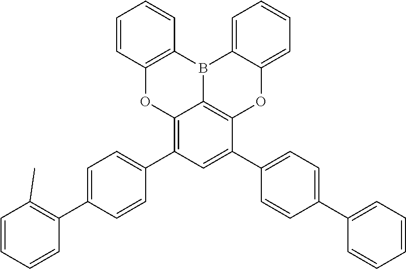 [SMILES: Cc1ccccc1-c1ccc(-c2cc(-c3ccc(-c4ccccc4)cc3)c3c4c2Oc2ccccc2B4c2ccccc2O3)cc1]

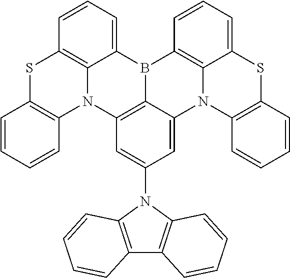 [SMILES: c1ccc2c(c1)Sc1cccc3c1N2c1cc(-n2c4ccccc4c4ccccc42)cc2c1B3c1cccc3c1N2c1ccccc1S3]

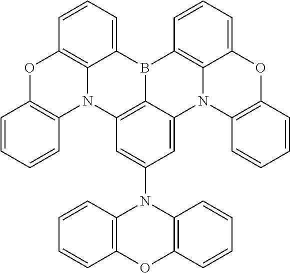 [SMILES: c1ccc2c(c1)Oc1ccccc1N2c1cc2c3c(c1)N1c4ccccc4Oc4cccc(c41)B3c1cccc3c1N2c1ccccc1O3]

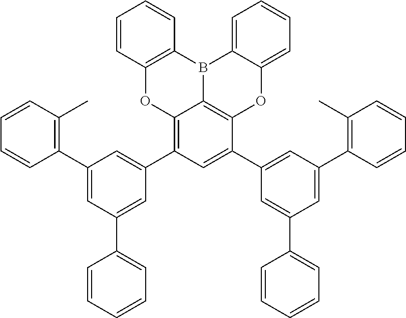 [SMILES: Cc1ccccc1-c1cc(-c2ccccc2)cc(-c2cc(-c3cc(-c4ccccc4)cc(-c4ccccc4C)c3)c3c4c2Oc2ccccc2B4c2ccccc2O3)c1]

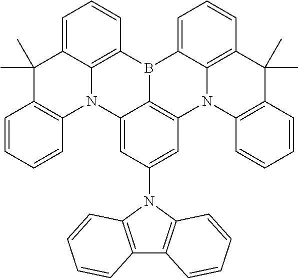

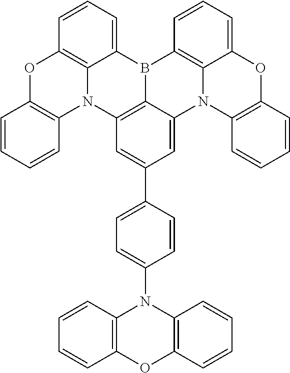 [SMILES: c1ccc2c(c1)Oc1ccccc1N2c1ccc(-c2cc3c4c(c2)N2c5ccccc5Oc5cccc(c52)B4c2cccc4c2N3c2ccccc2O4)cc1]

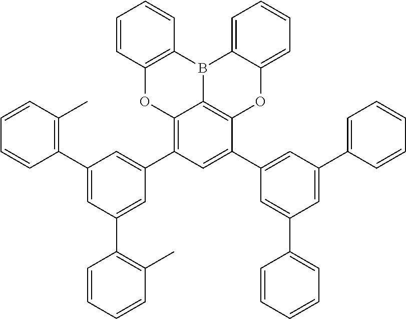 [SMILES: Cc1ccccc1-c1cc(-c2ccccc2C)cc(-c2cc(-c3cc(-c4ccccc4)cc(-c4ccccc4)c3)c3c4c2Oc2ccccc2B4c2ccccc2O3)c1]

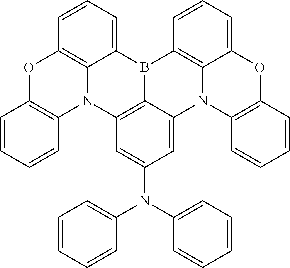 [SMILES: c1ccc(N(c2ccccc2)c2cc3c4c(c2)N2c5ccccc5Oc5cccc(c52)B4c2cccc4c2N3c2ccccc2O4)cc1]

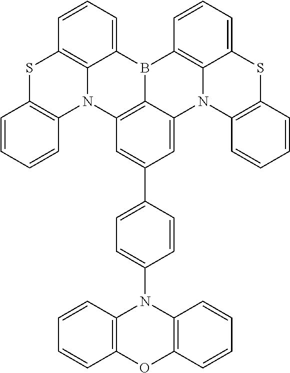 [SMILES: c1ccc2c(c1)Oc1ccccc1N2c1ccc(-c2cc3c4c(c2)N2c5ccccc5Sc5cccc(c52)B4c2cccc4c2N3c2ccccc2S4)cc1]

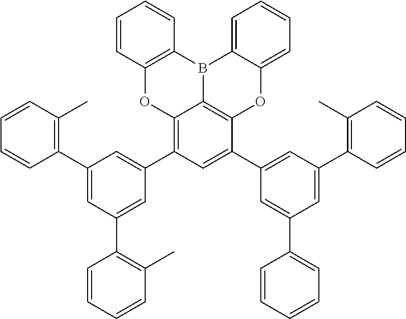 [SMILES: Cc1ccccc1-c1cc(-c2ccccc2)cc(-c2cc(-c3cc(-c4ccccc4C)cc(-c4ccccc4C)c3)c3c4c2Oc2ccccc2B4c2ccccc2O3)c1]

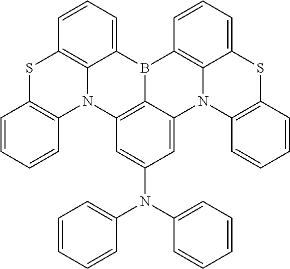 [SMILES: c1ccc(N(c2ccccc2)c2cc3c4c(c2)N2c5ccccc5Sc5cccc(c52)B4c2cccc4c2N3c2ccccc2S4)cc1]

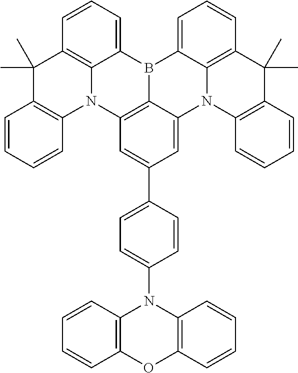

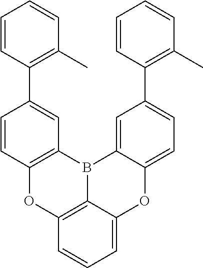 [SMILES: Cc1ccccc1-c1ccc2c(c1)B1c3cc(-c4ccccc4C)ccc3Oc3cccc(c31)O2]

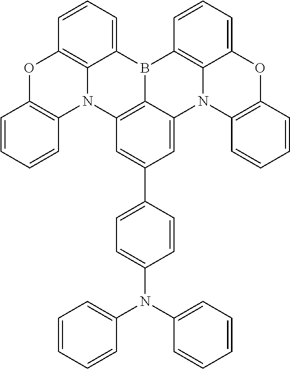 [SMILES: c1ccc(N(c2ccccc2)c2ccc(-c3cc4c5c(c3)N3c6ccccc6Oc6cccc(c63)B5c3cccc5c3N4c3ccccc3O5)cc2)cc1]

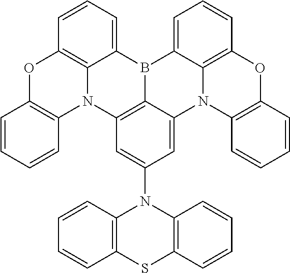 [SMILES: c1ccc2c(c1)Oc1cccc3c1N2c1cc(N2c4ccccc4Sc4ccccc42)cc2c1B3c1cccc3c1N2c1ccccc1O3]

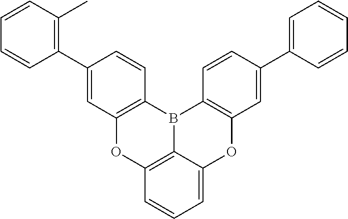 [SMILES: Cc1ccccc1-c1ccc2c(c1)Oc1cccc3c1B2c1ccc(-c2ccccc2)cc1O3]

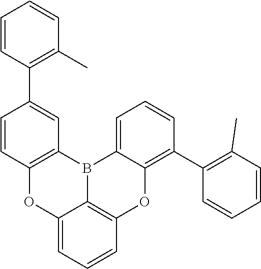 [SMILES: Cc1ccccc1-c1ccc2c(c1)B1c3cccc(-c4ccccc4C)c3Oc3cccc(c31)O2]

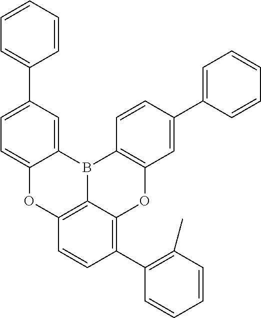 [SMILES: Cc1ccccc1-c1ccc2c3c1Oc1cc(-c4ccccc4)ccc1B3c1cc(-c3ccccc3)ccc1O2]

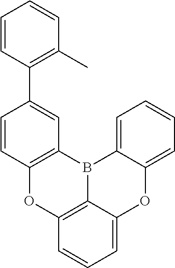 [SMILES: Cc1ccccc1-c1ccc2c(c1)B1c3ccccc3Oc3cccc(c31)O2]

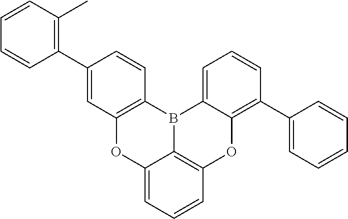 [SMILES: Cc1ccccc1-c1ccc2c(c1)Oc1cccc3c1B2c1cccc(-c2ccccc2)c1O3]

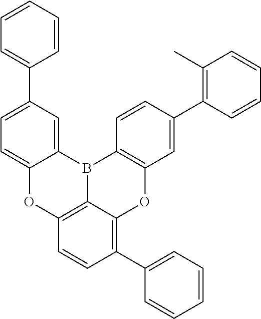 [SMILES: Cc1ccccc1-c1ccc2c(c1)Oc1c(-c3ccccc3)ccc3c1B2c1cc(-c2ccccc2)ccc1O3]

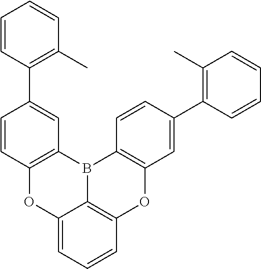 [SMILES: Cc1ccccc1-c1ccc2c(c1)Oc1cccc3c1B2c1cc(-c2ccccc2C)ccc1O3]

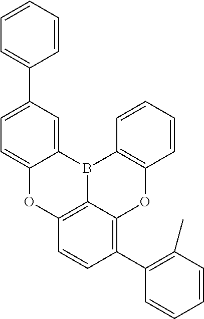 [SMILES: Cc1ccccc1-c1ccc2c3c1Oc1ccccc1B3c1cc(-c3ccccc3)ccc1O2]

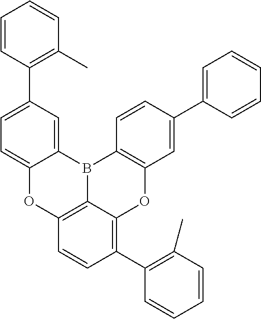 [SMILES: Cc1ccccc1-c1ccc2c(c1)B1c3ccc(-c4ccccc4)cc3Oc3c(-c4ccccc4C)ccc(c31)O2]

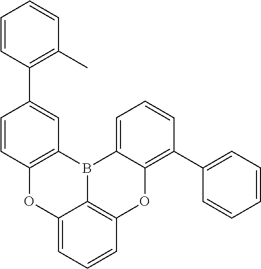 [SMILES: Cc1ccccc1-c1ccc2c(c1)B1c3cccc(-c4ccccc4)c3Oc3cccc(c31)O2]

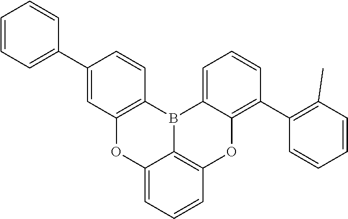 [SMILES: Cc1ccccc1-c1cccc2c1Oc1cccc3c1B2c1ccc(-c2ccccc2)cc1O3]

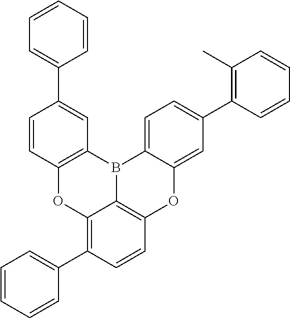 [SMILES: Cc1ccccc1-c1ccc2c(c1)Oc1ccc(-c3ccccc3)c3c1B2c1cc(-c2ccccc2)ccc1O3]

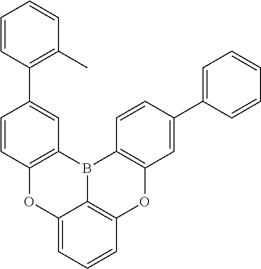 [SMILES: Cc1ccccc1-c1ccc2c(c1)B1c3ccc(-c4ccccc4)cc3Oc3cccc(c31)O2]

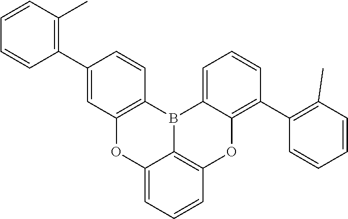 [SMILES: Cc1ccccc1-c1ccc2c(c1)Oc1cccc3c1B2c1cccc(-c2ccccc2C)c1O3]

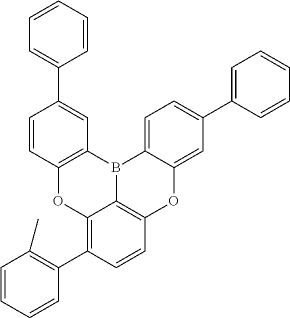 [SMILES: Cc1ccccc1-c1ccc2c3c1Oc1ccc(-c4ccccc4)cc1B3c1ccc(-c3ccccc3)cc1O2]

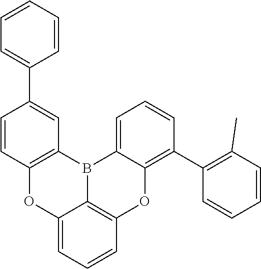 [SMILES: Cc1ccccc1-c1cccc2c1Oc1cccc3c1B2c1cc(-c2ccccc2)ccc1O3]

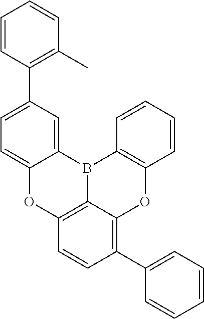 [SMILES: Cc1ccccc1-c1ccc2c(c1)B1c3ccccc3Oc3c(-c4ccccc4)ccc(c31)O2]

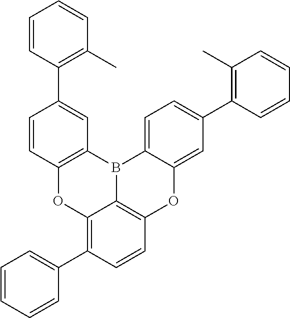 [SMILES: Cc1ccccc1-c1ccc2c(c1)Oc1ccc(-c3ccccc3)c3c1B2c1cc(-c2ccccc2C)ccc1O3]

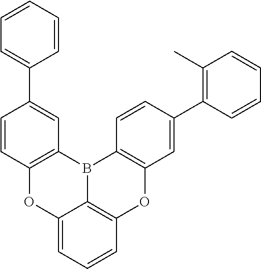 [SMILES: Cc1ccccc1-c1ccc2c(c1)Oc1cccc3c1B2c1cc(-c2ccccc2)ccc1O3]

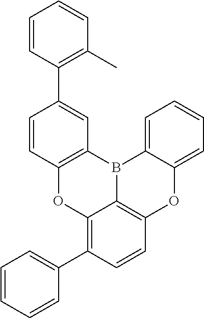 [SMILES: Cc1ccccc1-c1ccc2c(c1)B1c3ccccc3Oc3ccc(-c4ccccc4)c(c31)O2]

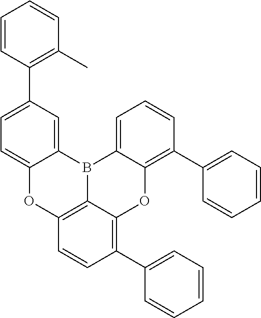 [SMILES: Cc1ccccc1-c1ccc2c(c1)B1c3cccc(-c4ccccc4)c3Oc3c(-c4ccccc4)ccc(c31)O2]

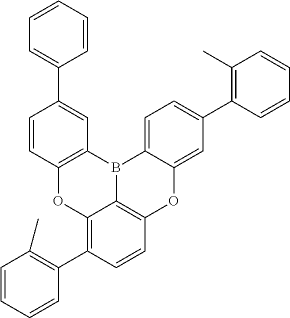 [SMILES: Cc1ccccc1-c1ccc2c(c1)Oc1ccc(-c3ccccc3C)c3c1B2c1cc(-c2ccccc2)ccc1O3]

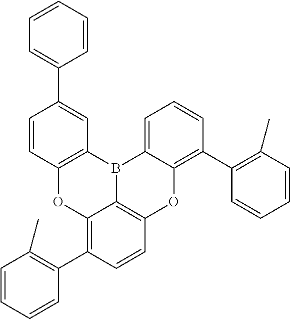 [SMILES: Cc1ccccc1-c1cccc2c1Oc1ccc(-c3ccccc3C)c3c1B2c1cc(-c2ccccc2)ccc1O3]

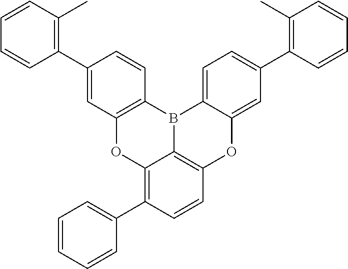 [SMILES: Cc1ccccc1-c1ccc2c(c1)Oc1ccc(-c3ccccc3)c3c1B2c1ccc(-c2ccccc2C)cc1O3]

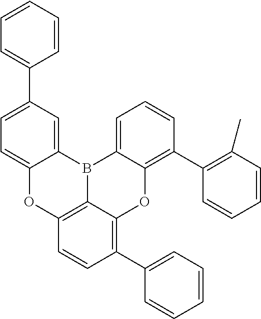 [SMILES: Cc1ccccc1-c1cccc2c1Oc1c(-c3ccccc3)ccc3c1B2c1cc(-c2ccccc2)ccc1O3]

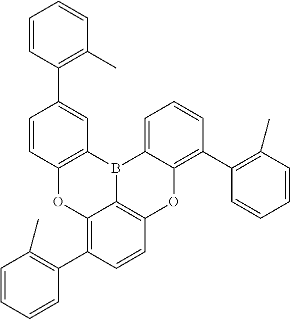 [SMILES: Cc1ccccc1-c1ccc2c(c1)B1c3cccc(-c4ccccc4C)c3Oc3ccc(-c4ccccc4C)c(c31)O2]

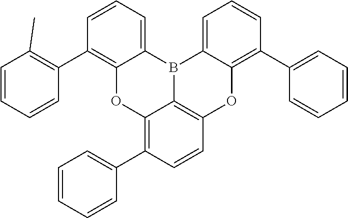 [SMILES: Cc1ccccc1-c1cccc2c1Oc1c(-c3ccccc3)ccc3c1B2c1cccc(-c2ccccc2)c1O3]

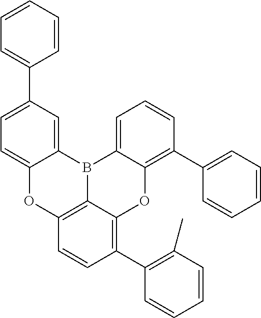 [SMILES: Cc1ccccc1-c1ccc2c3c1Oc1c(cccc1-c1ccccc1)B3c1cc(-c3ccccc3)ccc1O2]

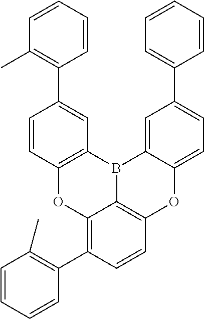 [SMILES: Cc1ccccc1-c1ccc2c(c1)B1c3cc(-c4ccccc4)ccc3Oc3ccc(-c4ccccc4C)c(c31)O2]

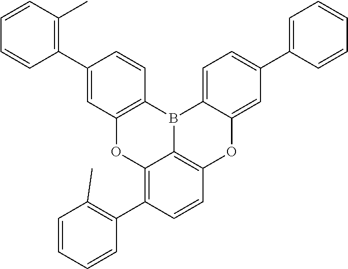 [SMILES: Cc1ccccc1-c1ccc2c(c1)Oc1c(-c3ccccc3C)ccc3c1B2c1ccc(-c2ccccc2)cc1O3]

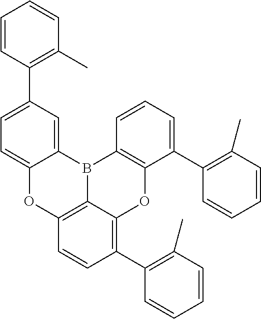 [SMILES: Cc1ccccc1-c1ccc2c(c1)B1c3cccc(-c4ccccc4C)c3Oc3c(-c4ccccc4C)ccc(c31)O2]

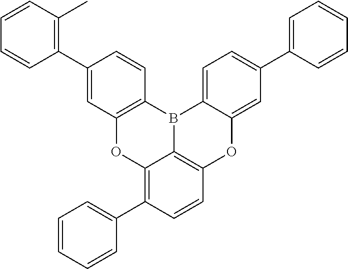 [SMILES: Cc1ccccc1-c1ccc2c(c1)Oc1c(-c3ccccc3)ccc3c1B2c1ccc(-c2ccccc2)cc1O3]

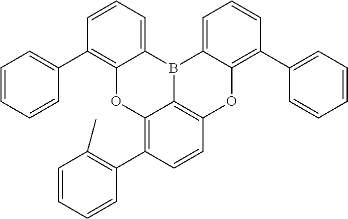 [SMILES: Cc1ccccc1-c1ccc2c3c1Oc1c(cccc1-c1ccccc1)B3c1cccc(-c3ccccc3)c1O2]

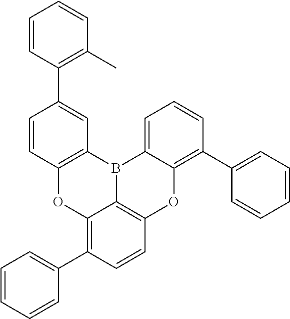 [SMILES: Cc1ccccc1-c1ccc2c(c1)B1c3cccc(-c4ccccc4)c3Oc3ccc(-c4ccccc4)c(c31)O2]

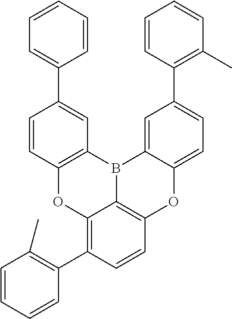 [SMILES: Cc1ccccc1-c1ccc2c(c1)B1c3cc(-c4ccccc4)ccc3Oc3c(-c4ccccc4C)ccc(c31)O2]

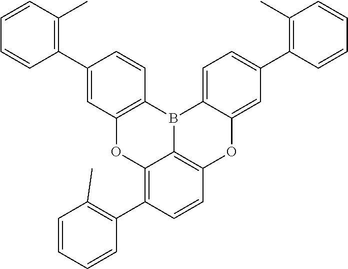 [SMILES: Cc1ccccc1-c1ccc2c(c1)Oc1ccc(-c3ccccc3C)c3c1B2c1ccc(-c2ccccc2C)cc1O3]

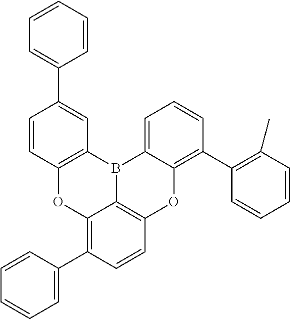 [SMILES: Cc1ccccc1-c1cccc2c1Oc1ccc(-c3ccccc3)c3c1B2c1cc(-c2ccccc2)ccc1O3]

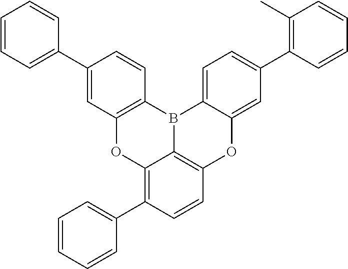 [SMILES: Cc1ccccc1-c1ccc2c(c1)Oc1ccc(-c3ccccc3)c3c1B2c1ccc(-c2ccccc2)cc1O3]

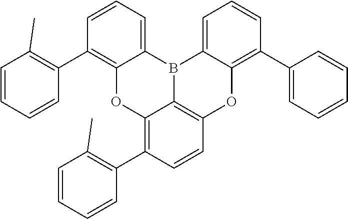 [SMILES: Cc1ccccc1-c1cccc2c1Oc1c(-c3ccccc3C)ccc3c1B2c1cccc(-c2ccccc2)c1O3]

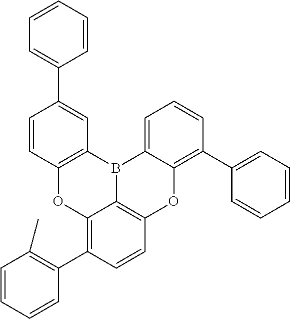 [SMILES: Cc1ccccc1-c1ccc2c3c1Oc1ccc(-c4ccccc4)cc1B3c1cccc(-c3ccccc3)c1O2]

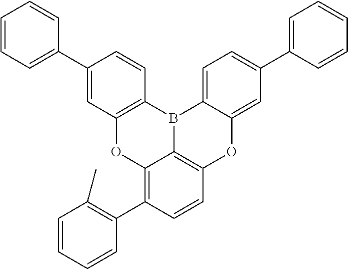 [SMILES: Cc1ccccc1-c1ccc2c3c1Oc1cc(-c4ccccc4)ccc1B3c1ccc(-c3ccccc3)cc1O2]

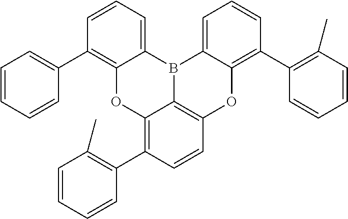 [SMILES: Cc1ccccc1-c1cccc2c1Oc1ccc(-c3ccccc3C)c3c1B2c1cccc(-c2ccccc2)c1O3]

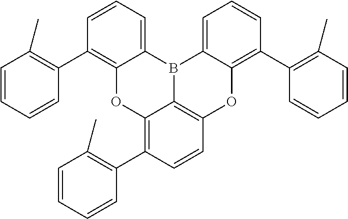 [SMILES: Cc1ccccc1-c1cccc2c1Oc1ccc(-c3ccccc3C)c3c1B2c1cccc(-c2ccccc2C)c1O3]

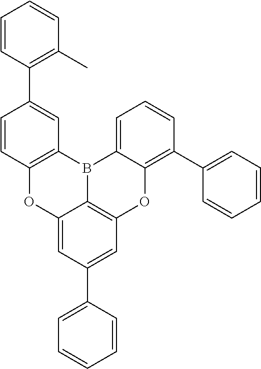 [SMILES: Cc1ccccc1-c1ccc2c(c1)B1c3cccc(-c4ccccc4)c3Oc3cc(-c4ccccc4)cc(c31)O2]

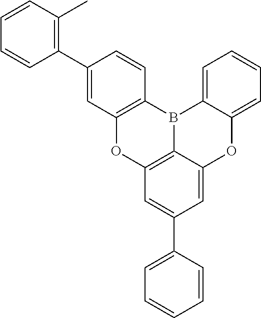 [SMILES: Cc1ccccc1-c1ccc2c(c1)Oc1cc(-c3ccccc3)cc3c1B2c1ccccc1O3]

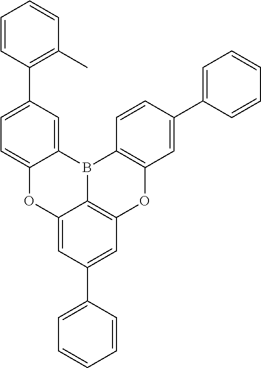 [SMILES: Cc1ccccc1-c1ccc2c(c1)B1c3ccc(-c4ccccc4)cc3Oc3cc(-c4ccccc4)cc(c31)O2]

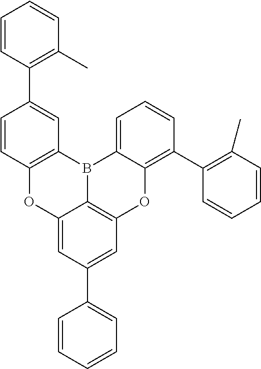 [SMILES: Cc1ccccc1-c1ccc2c(c1)B1c3cccc(-c4ccccc4C)c3Oc3cc(-c4ccccc4)cc(c31)O2]

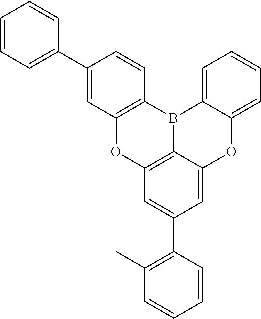 [SMILES: Cc1ccccc1-c1cc2c3c(c1)Oc1cc(-c4ccccc4)ccc1B3c1ccccc1O2]

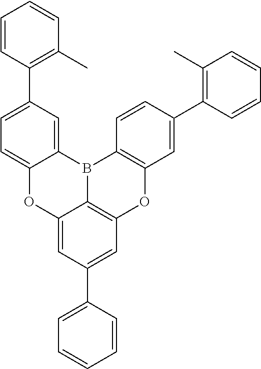 [SMILES: Cc1ccccc1-c1ccc2c(c1)Oc1cc(-c3ccccc3)cc3c1B2c1cc(-c2ccccc2C)ccc1O3]

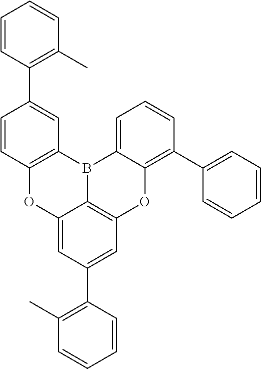 [SMILES: Cc1ccccc1-c1cc2c3c(c1)Oc1c(cccc1-c1ccccc1)B3c1cc(-c3ccccc3C)ccc1O2]

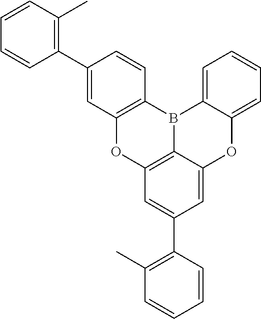 [SMILES: Cc1ccccc1-c1ccc2c(c1)Oc1cc(-c3ccccc3C)cc3c1B2c1ccccc1O3]

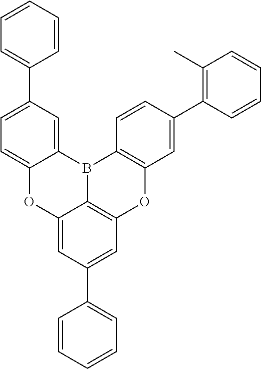 [SMILES: Cc1ccccc1-c1ccc2c(c1)Oc1cc(-c3ccccc3)cc3c1B2c1cc(-c2ccccc2)ccc1O3]

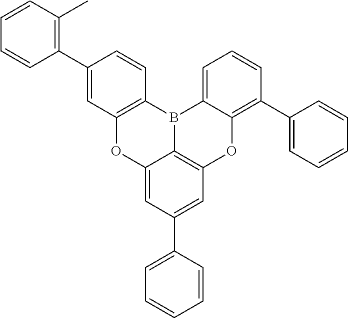 [SMILES: Cc1ccccc1-c1ccc2c(c1)Oc1cc(-c3ccccc3)cc3c1B2c1cccc(-c2ccccc2)c1O3]

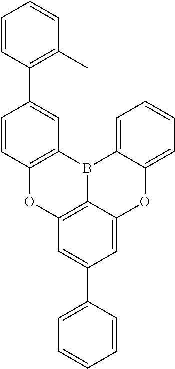 [SMILES: Cc1ccccc1-c1ccc2c(c1)B1c3ccccc3Oc3cc(-c4ccccc4)cc(c31)O2]

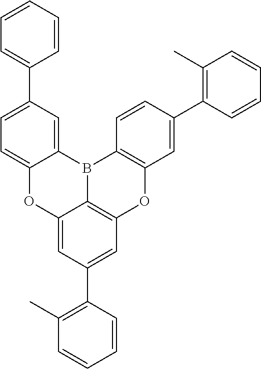 [SMILES: Cc1ccccc1-c1ccc2c(c1)Oc1cc(-c3ccccc3C)cc3c1B2c1cc(-c2ccccc2)ccc1O3]

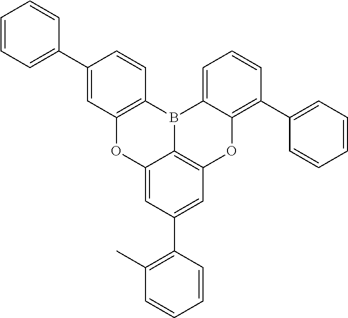 [SMILES: Cc1ccccc1-c1cc2c3c(c1)Oc1c(cccc1-c1ccccc1)B3c1ccc(-c3ccccc3)cc1O2]

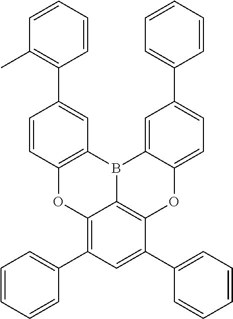 [SMILES: Cc1ccccc1-c1ccc2c(c1)B1c3cc(-c4ccccc4)ccc3Oc3c(-c4ccccc4)cc(-c4ccccc4)c(c31)O2]

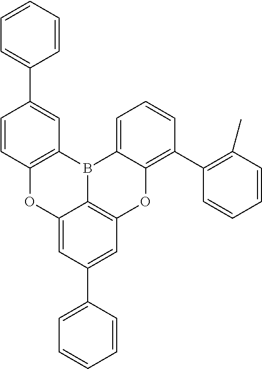 [SMILES: Cc1ccccc1-c1cccc2c1Oc1cc(-c3ccccc3)cc3c1B2c1cc(-c2ccccc2)ccc1O3]

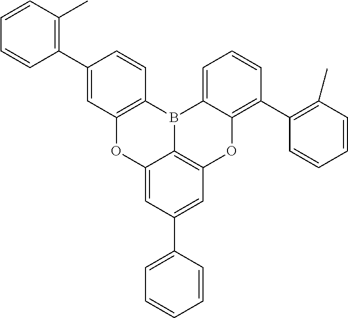 [SMILES: Cc1ccccc1-c1ccc2c(c1)Oc1cc(-c3ccccc3)cc3c1B2c1cccc(-c2ccccc2C)c1O3]

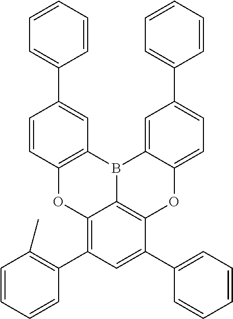 [SMILES: Cc1ccccc1-c1cc(-c2ccccc2)c2c3c1Oc1ccc(-c4ccccc4)cc1B3c1cc(-c3ccccc3)ccc1O2]

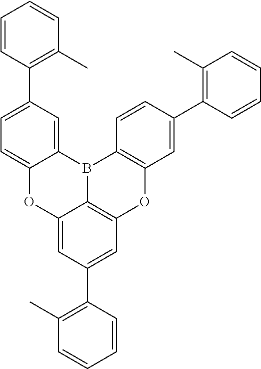 [SMILES: Cc1ccccc1-c1ccc2c(c1)Oc1cc(-c3ccccc3C)cc3c1B2c1cc(-c2ccccc2C)ccc1O3]

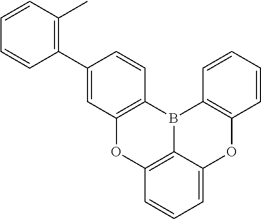 [SMILES: Cc1ccccc1-c1ccc2c(c1)Oc1cccc3c1B2c1ccccc1O3]

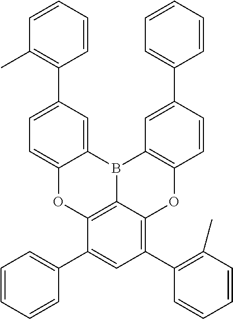 [SMILES: Cc1ccccc1-c1ccc2c(c1)B1c3cc(-c4ccccc4)ccc3Oc3c(-c4ccccc4C)cc(-c4ccccc4)c(c31)O2]

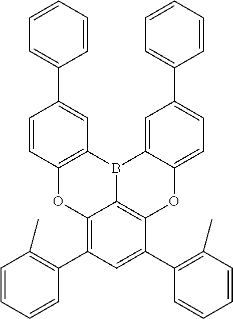 [SMILES: Cc1ccccc1-c1cc(-c2ccccc2C)c2c3c1Oc1ccc(-c4ccccc4)cc1B3c1cc(-c3ccccc3)ccc1O2]

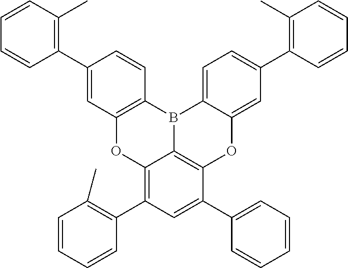 [SMILES: Cc1ccccc1-c1ccc2c(c1)Oc1c(-c3ccccc3)cc(-c3ccccc3C)c3c1B2c1ccc(-c2ccccc2C)cc1O3]

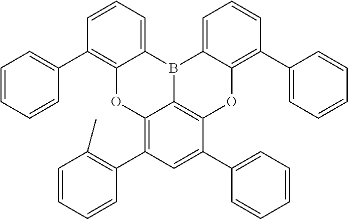 [SMILES: Cc1ccccc1-c1cc(-c2ccccc2)c2c3c1Oc1c(cccc1-c1ccccc1)B3c1cccc(-c3ccccc3)c1O2]

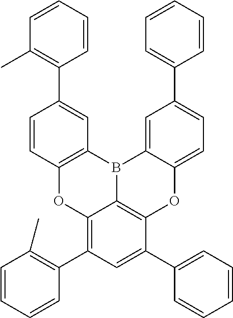 [SMILES: Cc1ccccc1-c1ccc2c(c1)B1c3cc(-c4ccccc4)ccc3Oc3c(-c4ccccc4)cc(-c4ccccc4C)c(c31)O2]

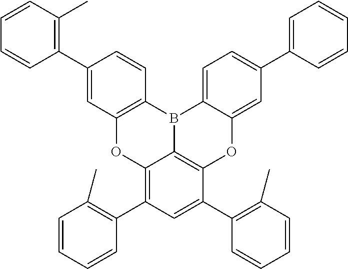 [SMILES: Cc1ccccc1-c1ccc2c(c1)Oc1c(-c3ccccc3C)cc(-c3ccccc3C)c3c1B2c1ccc(-c2ccccc2)cc1O3]

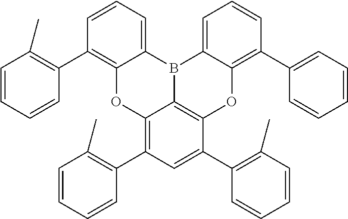 [SMILES: Cc1ccccc1-c1cccc2c1Oc1c(-c3ccccc3C)cc(-c3ccccc3C)c3c1B2c1cccc(-c2ccccc2)c1O3]

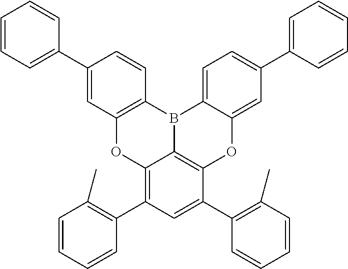 [SMILES: Cc1ccccc1-c1cc(-c2ccccc2C)c2c3c1Oc1cc(-c4ccccc4)ccc1B3c1ccc(-c3ccccc3)cc1O2]

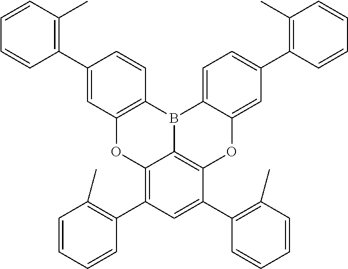 [SMILES: Cc1ccccc1-c1ccc2c(c1)Oc1c(-c3ccccc3C)cc(-c3ccccc3C)c3c1B2c1ccc(-c2ccccc2C)cc1O3]

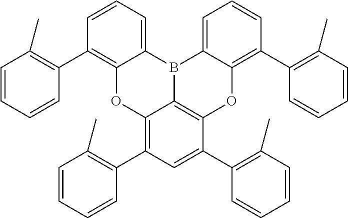 [SMILES: Cc1ccccc1-c1cccc2c1Oc1c(-c3ccccc3C)cc(-c3ccccc3C)c3c1B2c1cccc(-c2ccccc2C)c1O3]

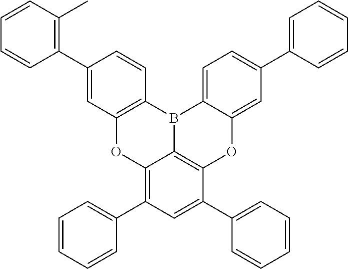 [SMILES: Cc1ccccc1-c1ccc2c(c1)Oc1c(-c3ccccc3)cc(-c3ccccc3)c3c1B2c1ccc(-c2ccccc2)cc1O3]

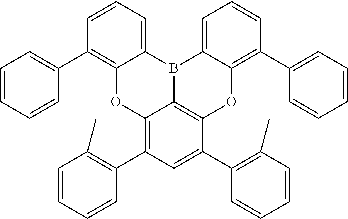 [SMILES: Cc1ccccc1-c1cc(-c2ccccc2C)c2c3c1Oc1c(cccc1-c1ccccc1)B3c1cccc(-c3ccccc3)c1O2]

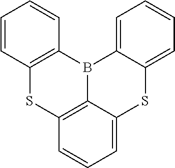 [SMILES: c1ccc2c(c1)Sc1cccc3c1B2c1ccccc1S3]

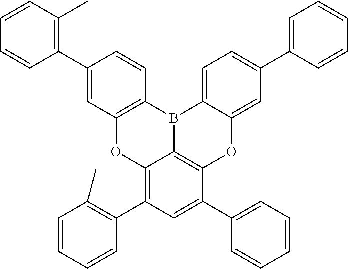 [SMILES: Cc1ccccc1-c1ccc2c(c1)Oc1c(-c3ccccc3C)cc(-c3ccccc3)c3c1B2c1ccc(-c2ccccc2)cc1O3]

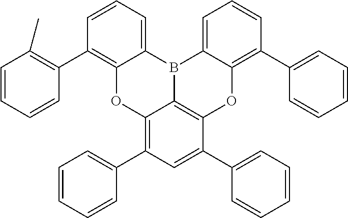 [SMILES: Cc1ccccc1-c1cccc2c1Oc1c(-c3ccccc3)cc(-c3ccccc3)c3c1B2c1cccc(-c2ccccc2)c1O3]

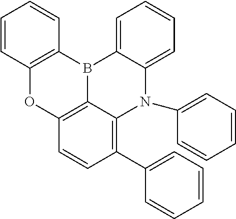 [SMILES: c1ccc(-c2ccc3c4c2N(c2ccccc2)c2ccccc2B4c2ccccc2O3)cc1]

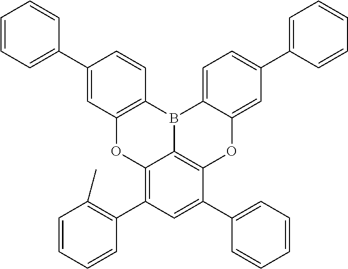 [SMILES: Cc1ccccc1-c1cc(-c2ccccc2)c2c3c1Oc1cc(-c4ccccc4)ccc1B3c1ccc(-c3ccccc3)cc1O2]

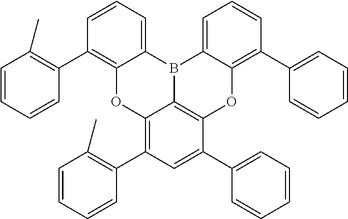 [SMILES: Cc1ccccc1-c1cccc2c1Oc1c(-c3ccccc3C)cc(-c3ccccc3)c3c1B2c1cccc(-c2ccccc2)c1O3]

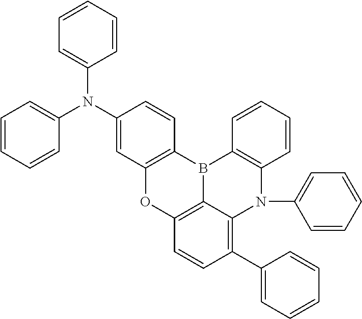 [SMILES: c1ccc(-c2ccc3c4c2N(c2ccccc2)c2ccccc2B4c2ccc(N(c4ccccc4)c4ccccc4)cc2O3)cc1]

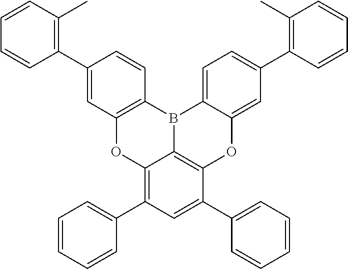 [SMILES: Cc1ccccc1-c1ccc2c(c1)Oc1c(-c3ccccc3)cc(-c3ccccc3)c3c1B2c1ccc(-c2ccccc2C)cc1O3]

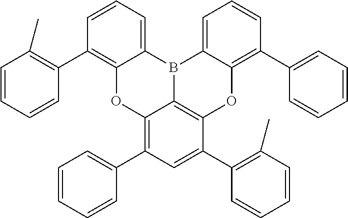 [SMILES: Cc1ccccc1-c1cccc2c1Oc1c(-c3ccccc3)cc(-c3ccccc3C)c3c1B2c1cccc(-c2ccccc2)c1O3]

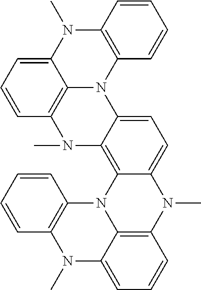 [SMILES: Cn1c2ccccc2n2c3ccc4c(c3n(C)c3cccc1c32)n1c2ccccc2n(C)c2cccc(c21)n4C]

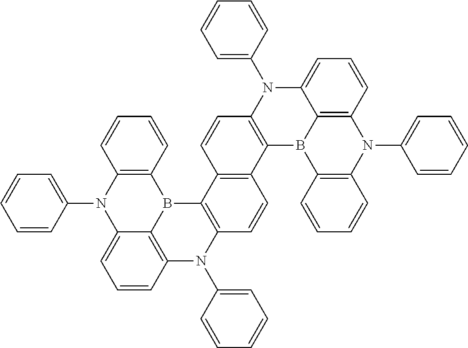 [SMILES: c1ccc(N2c3ccccc3B3c4c2cccc4N(c2ccccc2)c2ccc4c5c(ccc4c23)N(c2ccccc2)c2cccc3c2B5c2ccccc2N3c2ccccc2)cc1]

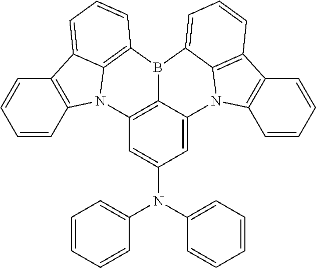 [SMILES: c1ccc(N(c2ccccc2)c2cc3c4c(c2)-n2c5ccccc5c5cccc(c52)B4c2cccc4c5ccccc5n-3c24)cc1]

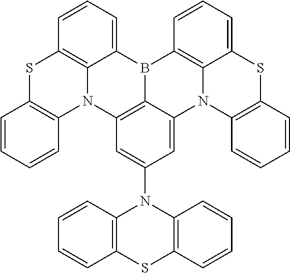 [SMILES: c1ccc2c(c1)Sc1ccccc1N2c1cc2c3c(c1)N1c4ccccc4Sc4cccc(c41)B3c1cccc3c1N2c1ccccc1S3]

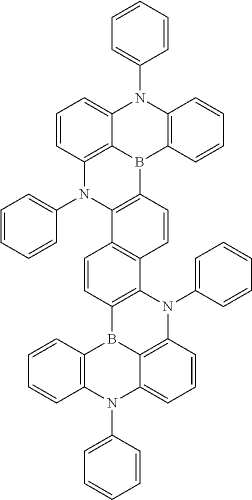 [SMILES: c1ccc(N2c3ccccc3B3c4ccc5c6c(ccc5c4N(c4ccccc4)c4cccc2c43)B2c3ccccc3N(c3ccccc3)c3cccc(c32)N6c2ccccc2)cc1]

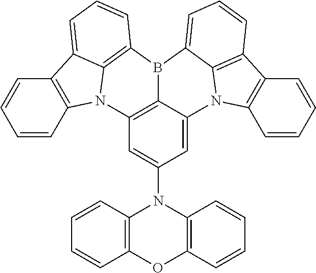 [SMILES: c1ccc2c(c1)Oc1ccccc1N2c1cc2c3c(c1)-n1c4ccccc4c4cccc(c41)B3c1cccc3c4ccccc4n-2c13]

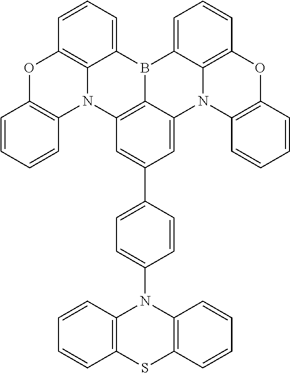 [SMILES: c1ccc2c(c1)Oc1cccc3c1N2c1cc(-c2ccc(N4c5ccccc5Sc5ccccc54)cc2)cc2c1B3c1cccc3c1N2c1ccccc1O3]

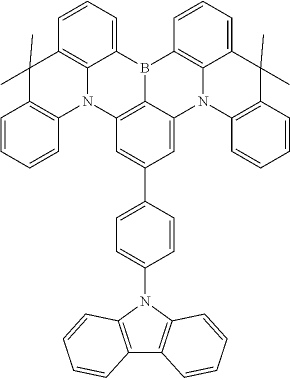 [SMILES: CC1(C)c2ccccc2N2c3cc(-c4ccc(-n5c6ccccc6c6ccccc65)cc4)cc4c3B(c3cccc1c32)c1cccc2c1N4c1ccccc1C2(C)C]

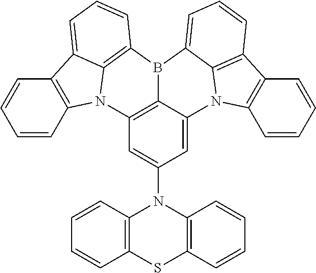 [SMILES: c1ccc2c(c1)Sc1ccccc1N2c1cc2c3c(c1)-n1c4ccccc4c4cccc(c41)B3c1cccc3c4ccccc4n-2c13]

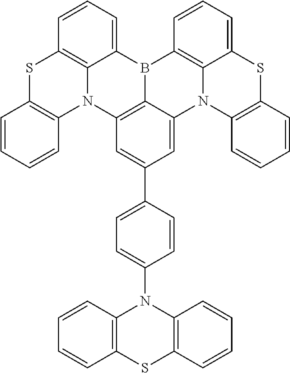 [SMILES: c1ccc2c(c1)Sc1ccccc1N2c1ccc(-c2cc3c4c(c2)N2c5ccccc5Sc5cccc(c52)B4c2cccc4c2N3c2ccccc2S4)cc1]

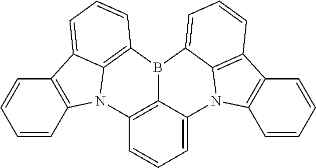 [SMILES: c1cc2c3c(c1)-n1c4ccccc4c4cccc(c41)B3c1cccc3c4ccccc4n-2c13]

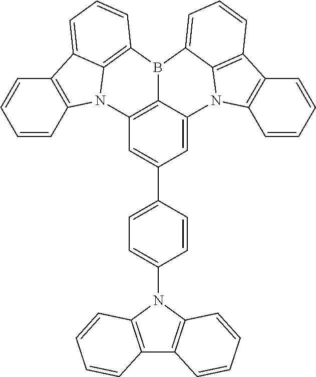 [SMILES: c1ccc2c(c1)c1ccccc1n2-c1ccc(-c2cc3c4c(c2)-n2c5ccccc5c5cccc(c52)B4c2cccc4c5ccccc5n-3c24)cc1]

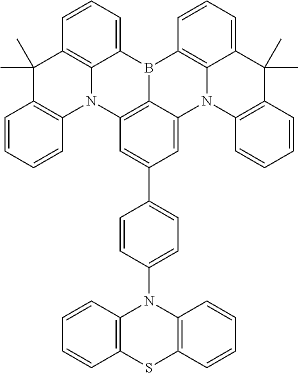

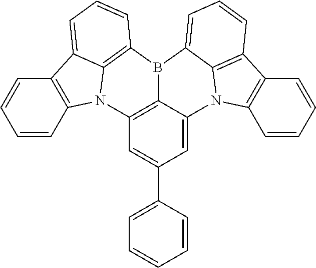 [SMILES: c1ccc(-c2cc3c4c(c2)-n2c5ccccc5c5cccc(c52)B4c2cccc4c5ccccc5n-3c24)cc1]

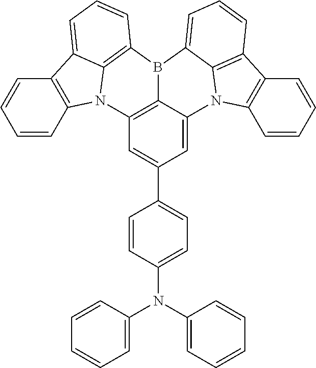 [SMILES: c1ccc(N(c2ccccc2)c2ccc(-c3cc4c5c(c3)-n3c6ccccc6c6cccc(c63)B5c3cccc5c6ccccc6n-4c35)cc2)cc1]

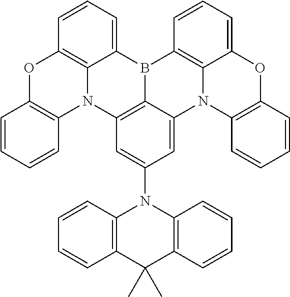 [SMILES: CC1(C)c2ccccc2N(c2cc3c4c(c2)N2c5ccccc5Oc5cccc(c52)B4c2cccc4c2N3c2ccccc2O4)c2ccccc21]

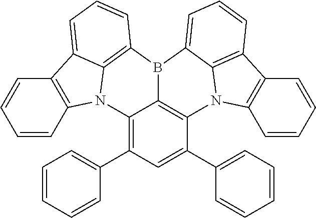 [SMILES: c1ccc(-c2cc(-c3ccccc3)c3c4c2-n2c5ccccc5c5cccc(c52)B4c2cccc4c5ccccc5n-3c24)cc1]

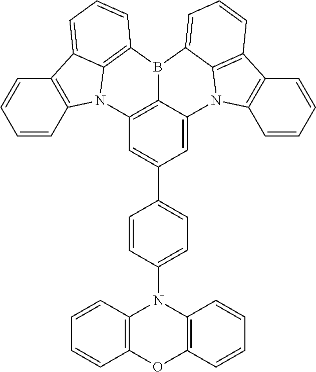 [SMILES: c1ccc2c(c1)Oc1ccccc1N2c1ccc(-c2cc3c4c(c2)-n2c5ccccc5c5cccc(c52)B4c2cccc4c5ccccc5n-3c24)cc1]

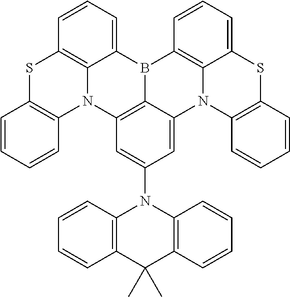 [SMILES: CC1(C)c2ccccc2N(c2cc3c4c(c2)N2c5ccccc5Sc5cccc(c52)B4c2cccc4c2N3c2ccccc2S4)c2ccccc21]

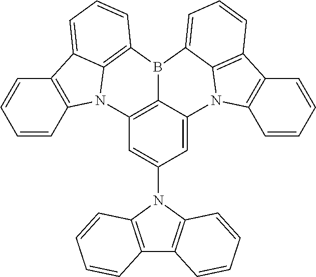 [SMILES: c1ccc2c(c1)c1ccccc1n2-c1cc2c3c(c1)-n1c4ccccc4c4cccc(c41)B3c1cccc3c4ccccc4n-2c13]

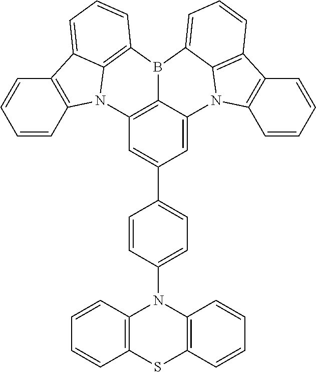 [SMILES: c1ccc2c(c1)Sc1ccccc1N2c1ccc(-c2cc3c4c(c2)-n2c5ccccc5c5cccc(c52)B4c2cccc4c5ccccc5n-3c24)cc1]

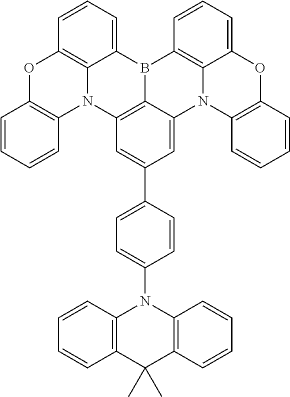 [SMILES: CC1(C)c2ccccc2N(c2ccc(-c3cc4c5c(c3)N3c6ccccc6Oc6cccc(c63)B5c3cccc5c3N4c3ccccc3O5)cc2)c2ccccc21]

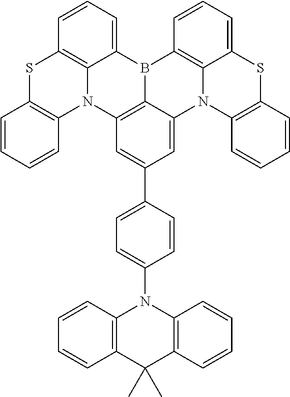 [SMILES: CC1(C)c2ccccc2N(c2ccc(-c3cc4c5c(c3)N3c6ccccc6Sc6cccc(c63)B5c3cccc5c3N4c3ccccc3S5)cc2)c2ccccc21]

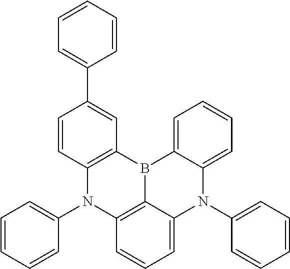 [SMILES: c1ccc(-c2ccc3c(c2)B2c4ccccc4N(c4ccccc4)c4cccc(c42)N3c2ccccc2)cc1]

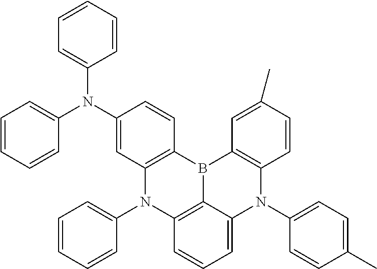 [SMILES: Cc1ccc(N2c3ccc(C)cc3B3c4ccc(N(c5ccccc5)c5ccccc5)cc4N(c4ccccc4)c4cccc2c43)cc1]

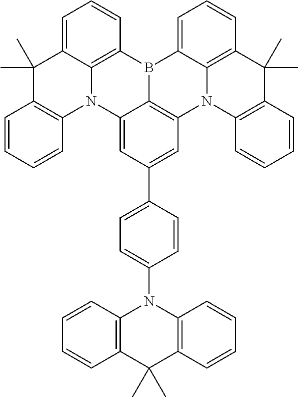

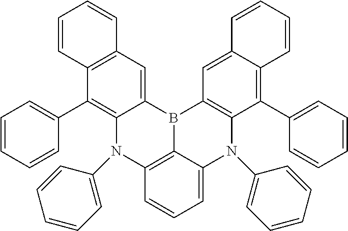 [SMILES: c1ccc(-c2c3c(cc4ccccc24)B2c4cc5ccccc5c(-c5ccccc5)c4N(c4ccccc4)c4cccc(c42)N3c2ccccc2)cc1]

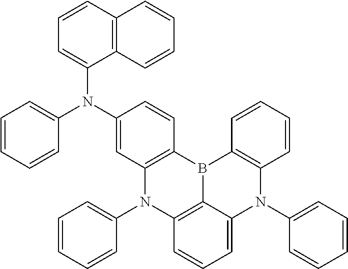 [SMILES: c1ccc(N2c3ccccc3B3c4ccc(N(c5ccccc5)c5cccc6ccccc56)cc4N(c4ccccc4)c4cccc2c43)cc1]

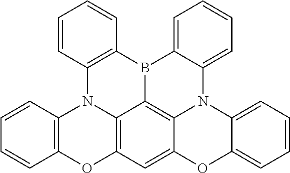 [SMILES: c1ccc2c(c1)B1c3ccccc3-n3c4ccccc4oc4cc5oc6ccccc6n-2c5c1c43]

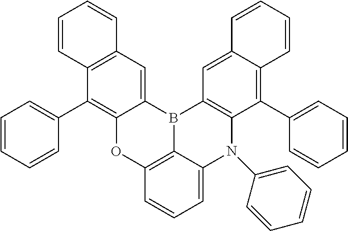 [SMILES: c1ccc(-c2c3c(cc4ccccc24)B2c4cc5ccccc5c(-c5ccccc5)c4N(c4ccccc4)c4cccc(c42)O3)cc1]

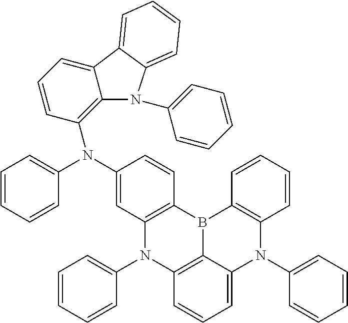 [SMILES: c1ccc(N2c3ccccc3B3c4ccc(N(c5ccccc5)c5cccc6c7ccccc7n(-c7ccccc7)c56)cc4N(c4ccccc4)c4cccc2c43)cc1]

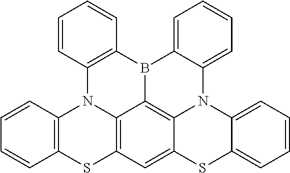 [SMILES: c1ccc2c(c1)B1c3ccccc3-n3c4ccccc4sc4cc5sc6ccccc6n-2c5c1c43]

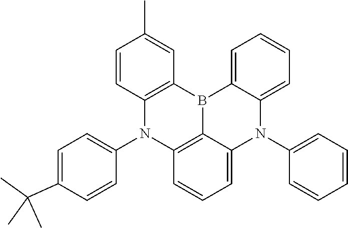 [SMILES: Cc1ccc2c(c1)B1c3ccccc3N(c3ccccc3)c3cccc(c31)N2c1ccc(C(C)(C)C)cc1]

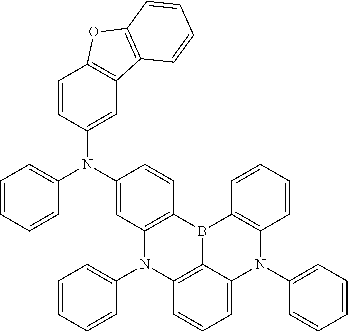 [SMILES: c1ccc(N(c2ccc3c(c2)N(c2ccccc2)c2cccc4c2B3c2ccccc2N4c2ccccc2)c2ccc3oc4ccccc4c3c2)cc1]

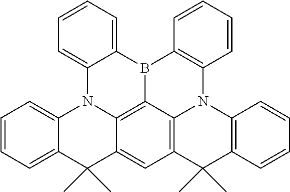 [SMILES: CC1(C)c2ccccc2N2c3ccccc3B3c4ccccc4N4c5ccccc5C(C)(C)c5cc1c2c3c54]

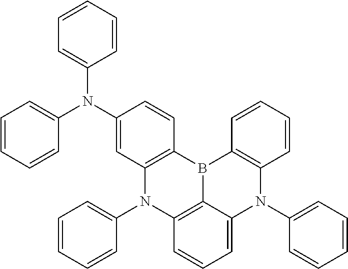 [SMILES: c1ccc(N(c2ccccc2)c2ccc3c(c2)N(c2ccccc2)c2cccc4c2B3c2ccccc2N4c2ccccc2)cc1]

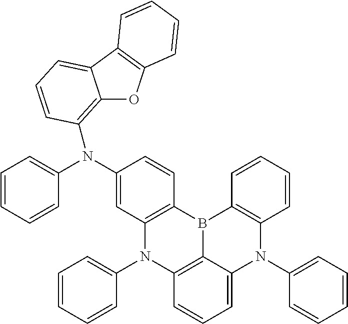 [SMILES: c1ccc(N2c3ccccc3B3c4ccc(N(c5ccccc5)c5cccc6c5oc5ccccc56)cc4N(c4ccccc4)c4cccc2c43)cc1]

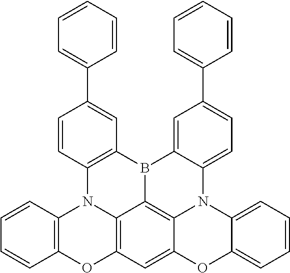 [SMILES: c1ccc(-c2ccc3c(c2)B2c4cc(-c5ccccc5)ccc4-n4c5ccccc5oc5cc6oc7ccccc7n-3c6c2c54)cc1]

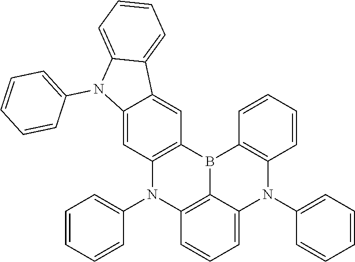 [SMILES: c1ccc(N2c3ccccc3B3c4cc5c6ccccc6n(-c6ccccc6)c5cc4N(c4ccccc4)c4cccc2c43)cc1]

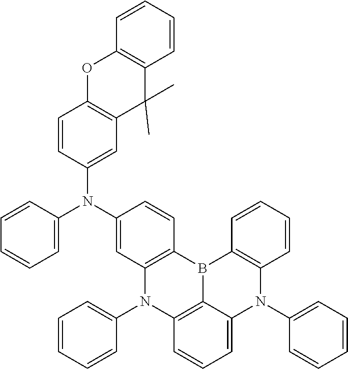 [SMILES: CC1(C)c2ccccc2Oc2ccc(N(c3ccccc3)c3ccc4c(c3)N(c3ccccc3)c3cccc5c3B4c3ccccc3N5c3ccccc3)cc21]

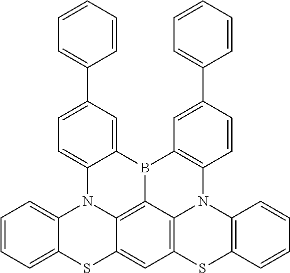 [SMILES: c1ccc(-c2ccc3c(c2)B2c4cc(-c5ccccc5)ccc4-n4c5ccccc5sc5cc6sc7ccccc7n-3c6c2c54)cc1]

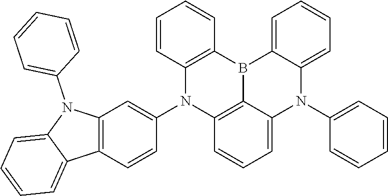 [SMILES: c1ccc(N2c3ccccc3B3c4ccccc4N(c4ccc5c6ccccc6n(-c6ccccc6)c5c4)c4cccc2c43)cc1]

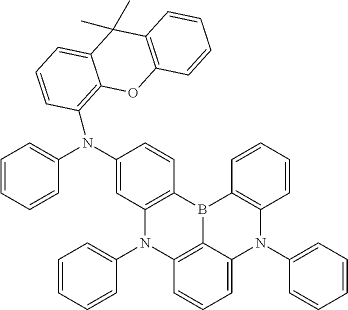 [SMILES: CC1(C)c2ccccc2Oc2c(N(c3ccccc3)c3ccc4c(c3)N(c3ccccc3)c3cccc5c3B4c3ccccc3N5c3ccccc3)cccc21]

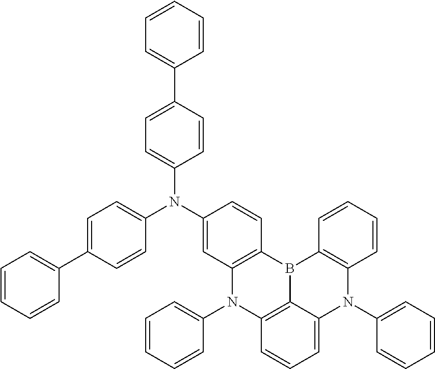 [SMILES: c1ccc(-c2ccc(N(c3ccc(-c4ccccc4)cc3)c3ccc4c(c3)N(c3ccccc3)c3cccc5c3B4c3ccccc3N5c3ccccc3)cc2)cc1]

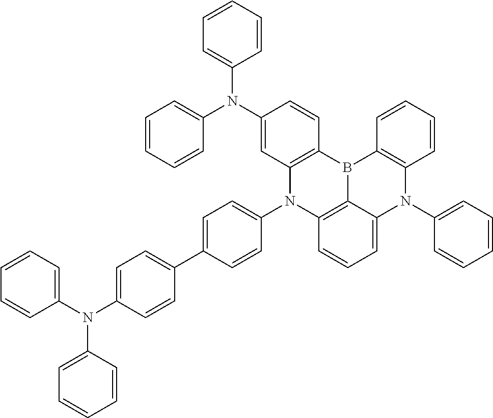 [SMILES: c1ccc(N(c2ccccc2)c2ccc(-c3ccc(N4c5cc(N(c6ccccc6)c6ccccc6)ccc5B5c6ccccc6N(c6ccccc6)c6cccc4c65)cc3)cc2)cc1]

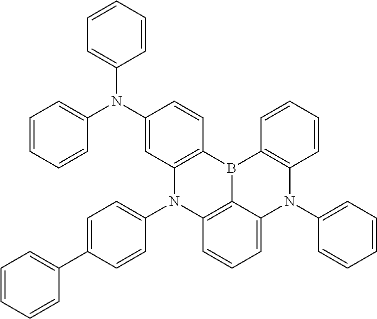 [SMILES: c1ccc(-c2ccc(N3c4cc(N(c5ccccc5)c5ccccc5)ccc4B4c5ccccc5N(c5ccccc5)c5cccc3c54)cc2)cc1]

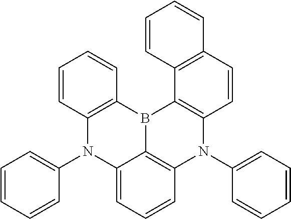 [SMILES: c1ccc(N2c3ccccc3B3c4c2cccc4N(c2ccccc2)c2ccc4ccccc4c23)cc1]

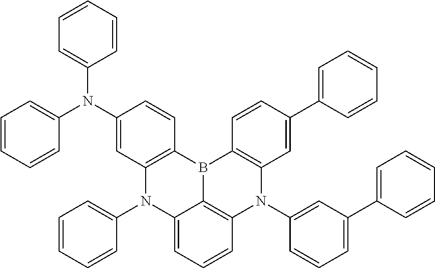 [SMILES: c1ccc(-c2cccc(N3c4cc(-c5ccccc5)ccc4B4c5ccc(N(c6ccccc6)c6ccccc6)cc5N(c5ccccc5)c5cccc3c54)c2)cc1]

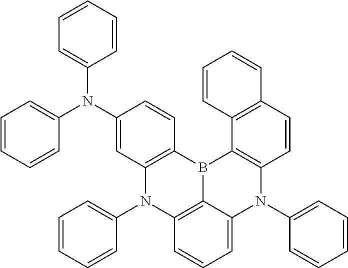 [SMILES: c1ccc(N(c2ccccc2)c2ccc3c(c2)N(c2ccccc2)c2cccc4c2B3c2c(ccc3ccccc23)N4c2ccccc2)cc1]

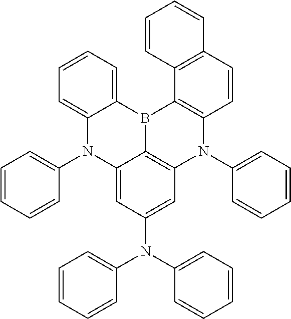 [SMILES: c1ccc(N(c2ccccc2)c2cc3c4c(c2)N(c2ccccc2)c2ccc5ccccc5c2B4c2ccccc2N3c2ccccc2)cc1]

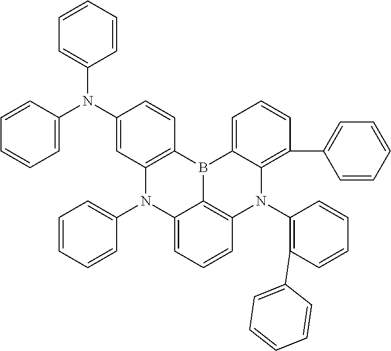 [SMILES: c1ccc(-c2ccccc2N2c3cccc4c3B(c3ccc(N(c5ccccc5)c5ccccc5)cc3N4c3ccccc3)c3cccc(-c4ccccc4)c32)cc1]

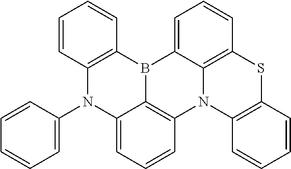 [SMILES: c1ccc(N2c3ccccc3B3c4cccc5c4N(c4ccccc4S5)c4cccc2c43)cc1]

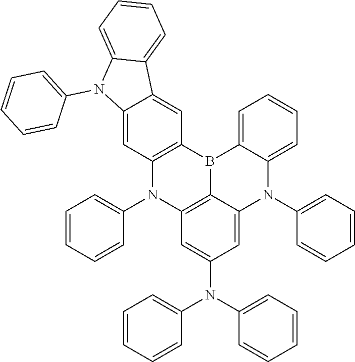 [SMILES: c1ccc(N(c2ccccc2)c2cc3c4c(c2)N(c2ccccc2)c2cc5c(cc2B4c2ccccc2N3c2ccccc2)c2ccccc2n5-c2ccccc2)cc1]

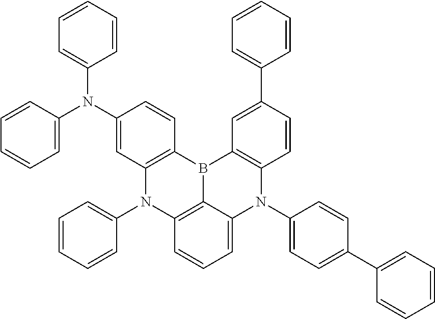 [SMILES: c1ccc(-c2ccc(N3c4ccc(-c5ccccc5)cc4B4c5ccc(N(c6ccccc6)c6ccccc6)cc5N(c5ccccc5)c5cccc3c54)cc2)cc1]

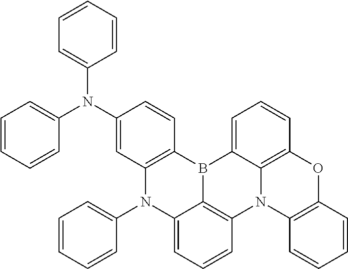 [SMILES: c1ccc(N(c2ccccc2)c2ccc3c(c2)N(c2ccccc2)c2cccc4c2B3c2cccc3c2N4c2ccccc2O3)cc1]

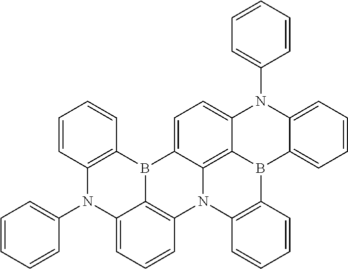 [SMILES: c1ccc(N2c3ccccc3B3c4ccc5c6c4N(c4ccccc4B6c4ccccc4N5c4ccccc4)c4cccc2c43)cc1]

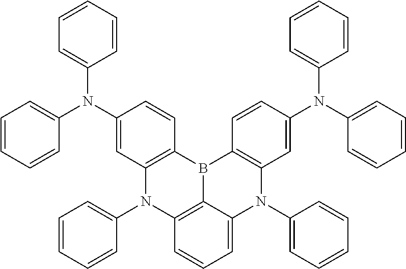 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1]

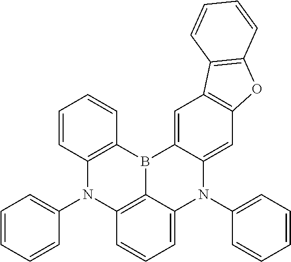 [SMILES: c1ccc(N2c3ccccc3B3c4cc5c(cc4N(c4ccccc4)c4cccc2c43)oc2ccccc25)cc1]

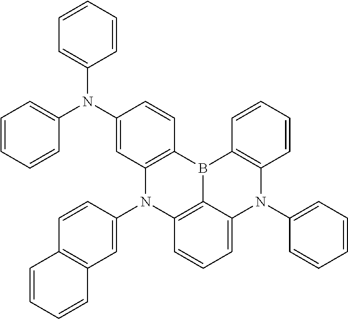 [SMILES: c1ccc(N(c2ccccc2)c2ccc3c(c2)N(c2ccc4ccccc4c2)c2cccc4c2B3c2ccccc2N4c2ccccc2)cc1]

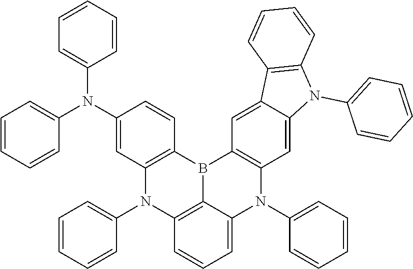 [SMILES: c1ccc(N(c2ccccc2)c2ccc3c(c2)N(c2ccccc2)c2cccc4c2B3c2cc3c5ccccc5n(-c5ccccc5)c3cc2N4c2ccccc2)cc1]

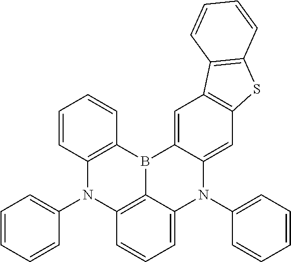 [SMILES: c1ccc(N2c3ccccc3B3c4cc5c(cc4N(c4ccccc4)c4cccc2c43)sc2ccccc25)cc1]

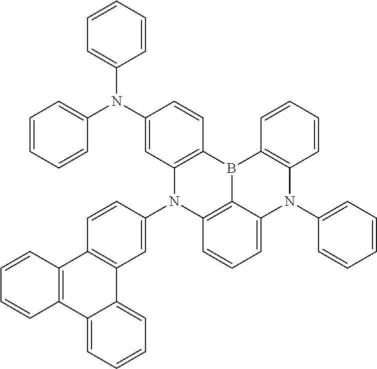 [SMILES: c1ccc(N(c2ccccc2)c2ccc3c(c2)N(c2ccc4c5ccccc5c5ccccc5c4c2)c2cccc4c2B3c2ccccc2N4c2ccccc2)cc1]

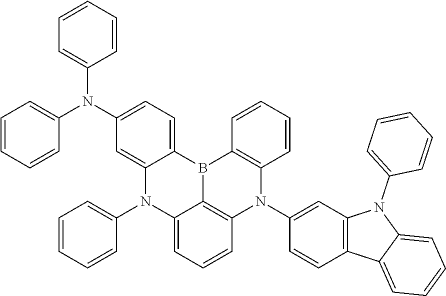 [SMILES: c1ccc(N(c2ccccc2)c2ccc3c(c2)N(c2ccccc2)c2cccc4c2B3c2ccccc2N4c2ccc3c4ccccc4n(-c4ccccc4)c3c2)cc1]

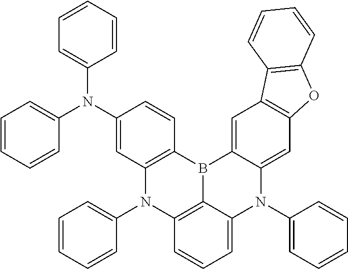 [SMILES: c1ccc(N(c2ccccc2)c2ccc3c(c2)N(c2ccccc2)c2cccc4c2B3c2cc3c(cc2N4c2ccccc2)oc2ccccc23)cc1]

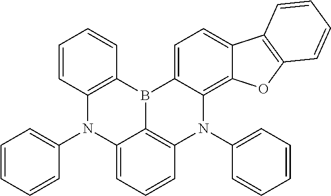 [SMILES: c1ccc(N2c3ccccc3B3c4ccc5c(oc6ccccc65)c4N(c4ccccc4)c4cccc2c43)cc1]

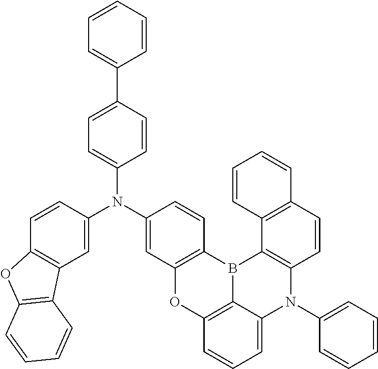 [SMILES: c1ccc(-c2ccc(N(c3ccc4c(c3)Oc3cccc5c3B4c3c(ccc4ccccc34)N5c3ccccc3)c3ccc4oc5ccccc5c4c3)cc2)cc1]

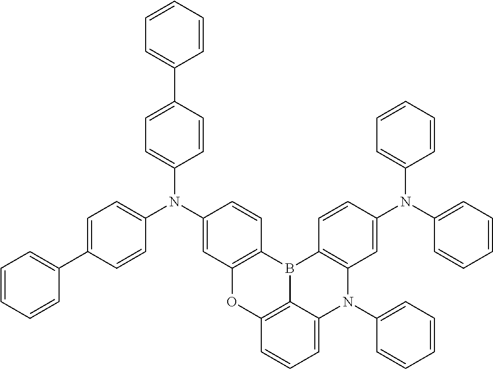 [SMILES: c1ccc(-c2ccc(N(c3ccc(-c4ccccc4)cc3)c3ccc4c(c3)Oc3cccc5c3B4c3ccc(N(c4ccccc4)c4ccccc4)cc3N5c3ccccc3)cc2)cc1]

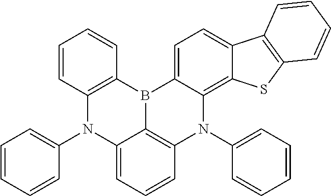 [SMILES: c1ccc(N2c3ccccc3B3c4ccc5c(sc6ccccc65)c4N(c4ccccc4)c4cccc2c43)cc1]

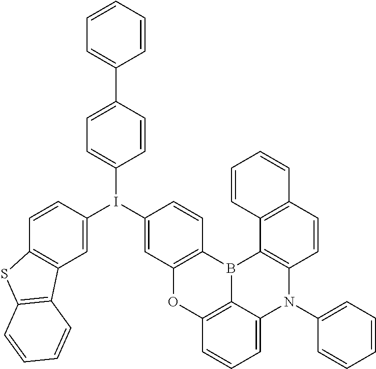 [SMILES: c1ccc(-c2ccc(I(c3ccc4c(c3)Oc3cccc5c3B4c3c(ccc4ccccc34)N5c3ccccc3)c3ccc4sc5ccccc5c4c3)cc2)cc1]

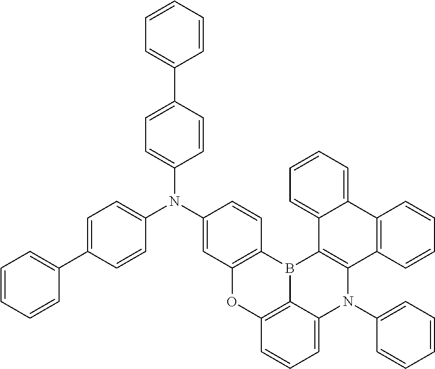 [SMILES: c1ccc(-c2ccc(N(c3ccc(-c4ccccc4)cc3)c3ccc4c(c3)Oc3cccc5c3B4c3c(c4ccccc4c4ccccc34)N5c3ccccc3)cc2)cc1]

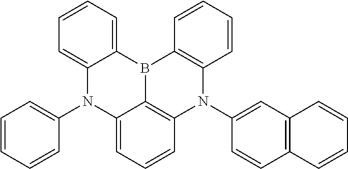 [SMILES: c1ccc(N2c3ccccc3B3c4ccccc4N(c4ccc5ccccc5c4)c4cccc2c43)cc1]

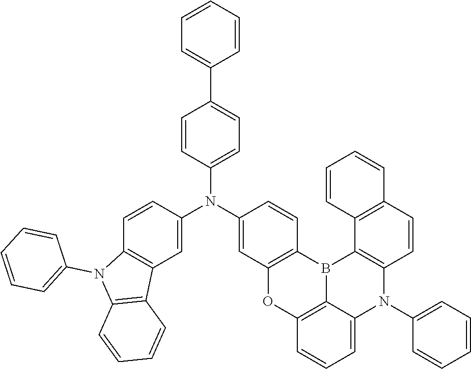 [SMILES: c1ccc(-c2ccc(N(c3ccc4c(c3)Oc3cccc5c3B4c3c(ccc4ccccc34)N5c3ccccc3)c3ccc4c(c3)c3ccccc3n4-c3ccccc3)cc2)cc1]

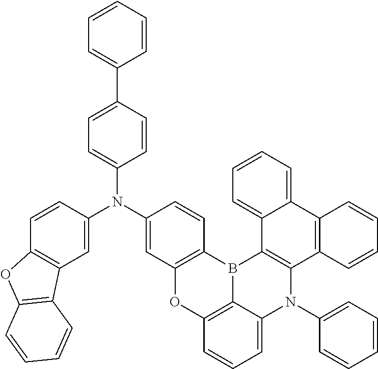 [SMILES: c1ccc(-c2ccc(N(c3ccc4c(c3)Oc3cccc5c3B4c3c(c4ccccc4c4ccccc34)N5c3ccccc3)c3ccc4oc5ccccc5c4c3)cc2)cc1]

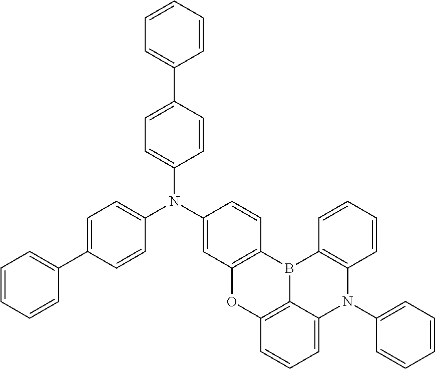 [SMILES: c1ccc(-c2ccc(N(c3ccc(-c4ccccc4)cc3)c3ccc4c(c3)Oc3cccc5c3B4c3ccccc3N5c3ccccc3)cc2)cc1]

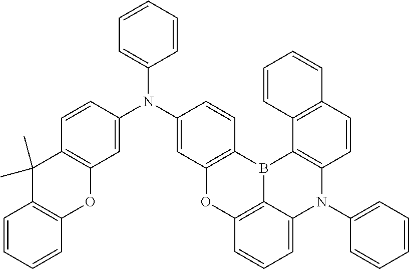 [SMILES: CC1(C)c2ccccc2Oc2cc(N(c3ccccc3)c3ccc4c(c3)Oc3cccc5c3B4c3c(ccc4ccccc34)N5c3ccccc3)ccc21]

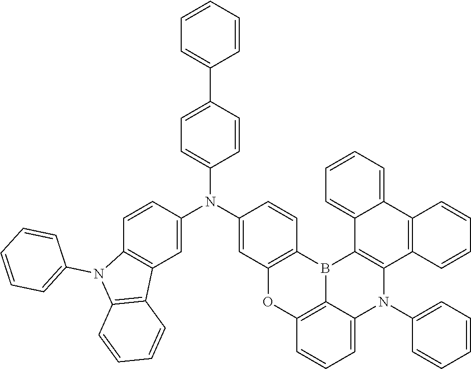 [SMILES: c1ccc(-c2ccc(N(c3ccc4c(c3)Oc3cccc5c3B4c3c(c4ccccc4c4ccccc34)N5c3ccccc3)c3ccc4c(c3)c3ccccc3n4-c3ccccc3)cc2)cc1]

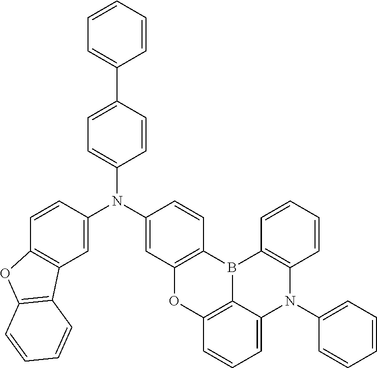 [SMILES: c1ccc(-c2ccc(N(c3ccc4c(c3)Oc3cccc5c3B4c3ccccc3N5c3ccccc3)c3ccc4oc5ccccc5c4c3)cc2)cc1]

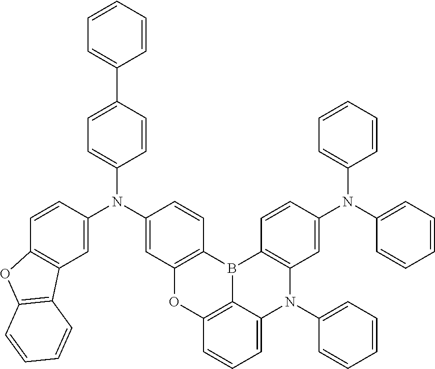 [SMILES: c1ccc(-c2ccc(N(c3ccc4c(c3)Oc3cccc5c3B4c3ccc(N(c4ccccc4)c4ccccc4)cc3N5c3ccccc3)c3ccc4oc5ccccc5c4c3)cc2)cc1]

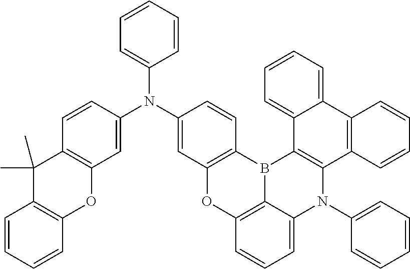 [SMILES: CC1(C)c2ccccc2Oc2cc(N(c3ccccc3)c3ccc4c(c3)Oc3cccc5c3B4c3c(c4ccccc4c4ccccc34)N5c3ccccc3)ccc21]

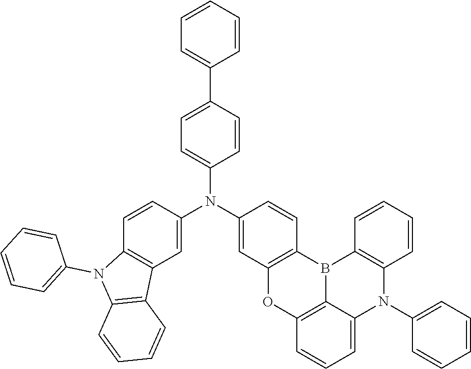 [SMILES: c1ccc(-c2ccc(N(c3ccc4c(c3)Oc3cccc5c3B4c3ccccc3N5c3ccccc3)c3ccc4c(c3)c3ccccc3n4-c3ccccc3)cc2)cc1]

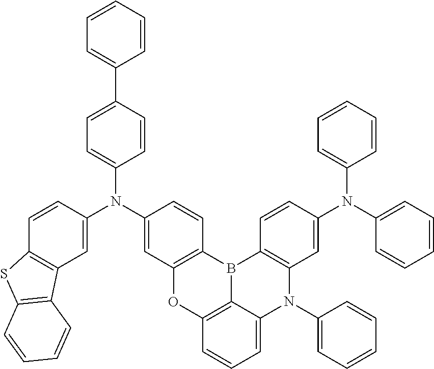 [SMILES: c1ccc(-c2ccc(N(c3ccc4c(c3)Oc3cccc5c3B4c3ccc(N(c4ccccc4)c4ccccc4)cc3N5c3ccccc3)c3ccc4sc5ccccc5c4c3)cc2)cc1]

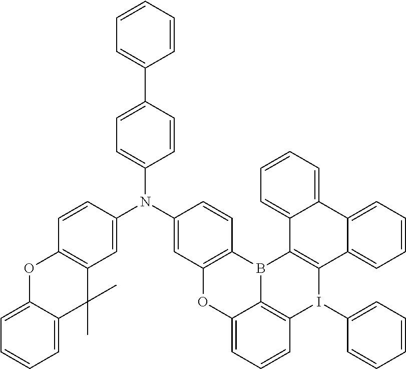 [SMILES: CC1(C)c2ccccc2Oc2ccc(N(c3ccc(-c4ccccc4)cc3)c3ccc4c(c3)Oc3cccc5c3B4c3c(c4ccccc4c4ccccc34)I5c3ccccc3)cc21]

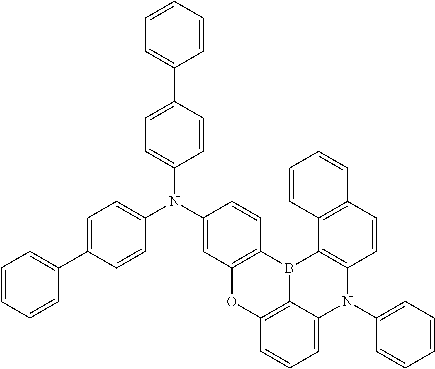 [SMILES: c1ccc(-c2ccc(N(c3ccc(-c4ccccc4)cc3)c3ccc4c(c3)Oc3cccc5c3B4c3c(ccc4ccccc34)N5c3ccccc3)cc2)cc1]

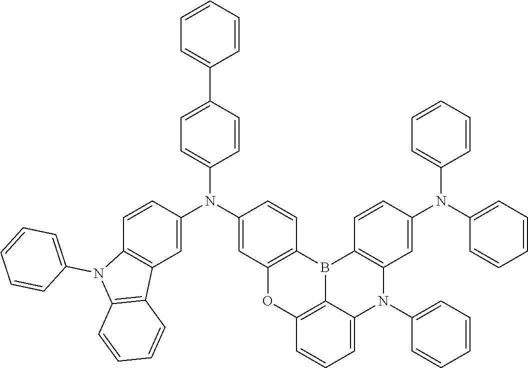 [SMILES: c1ccc(-c2ccc(N(c3ccc4c(c3)Oc3cccc5c3B4c3ccc(N(c4ccccc4)c4ccccc4)cc3N5c3ccccc3)c3ccc4c(c3)c3ccccc3n4-c3ccccc3)cc2)cc1]

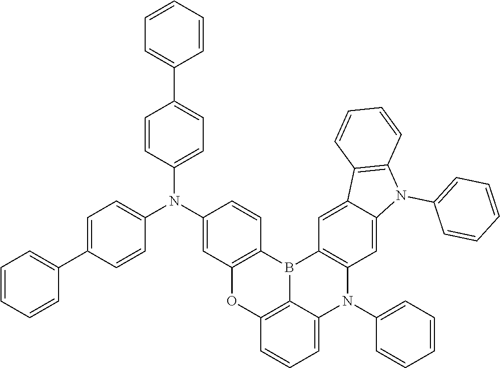 [SMILES: c1ccc(-c2ccc(N(c3ccc(-c4ccccc4)cc3)c3ccc4c(c3)Oc3cccc5c3B4c3cc4c6ccccc6n(-c6ccccc6)c4cc3N5c3ccccc3)cc2)cc1]

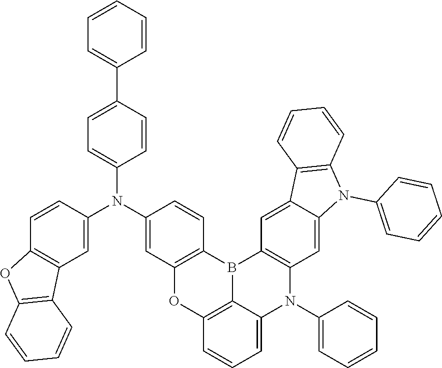 [SMILES: c1ccc(-c2ccc(N(c3ccc4c(c3)Oc3cccc5c3B4c3cc4c6ccccc6n(-c6ccccc6)c4cc3N5c3ccccc3)c3ccc4oc5ccccc5c4c3)cc2)cc1]

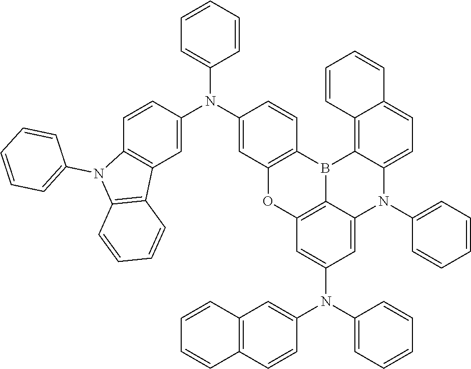 [SMILES: c1ccc(N(c2cc3c4c(c2)N(c2ccccc2)c2ccc5ccccc5c2B4c2ccc(N(c4ccccc4)c4ccc5c(c4)c4ccccc4n5-c4ccccc4)cc2O3)c2ccc3ccccc3c2)cc1]

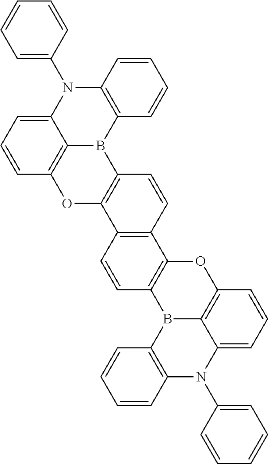 [SMILES: c1ccc(N2c3ccccc3B3c4ccc5c6c(ccc5c4Oc4cccc2c43)B2c3ccccc3N(c3ccccc3)c3cccc(c32)O6)cc1]

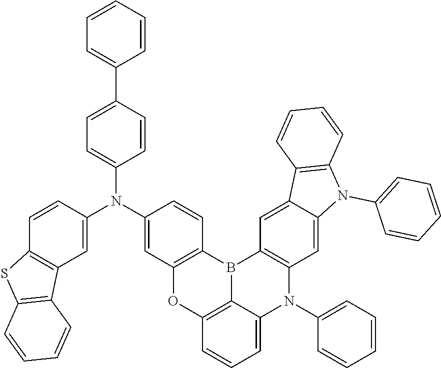 [SMILES: c1ccc(-c2ccc(N(c3ccc4c(c3)Oc3cccc5c3B4c3cc4c6ccccc6n(-c6ccccc6)c4cc3N5c3ccccc3)c3ccc4sc5ccccc5c4c3)cc2)cc1]

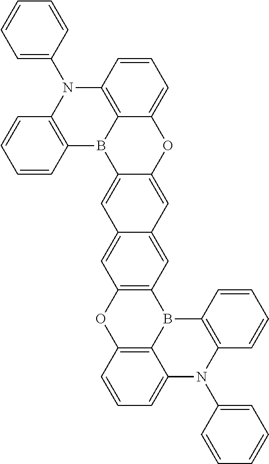 [SMILES: c1ccc(N2c3ccccc3B3c4cc5cc6c(cc5cc4Oc4cccc2c43)B2c3ccccc3N(c3ccccc3)c3cccc(c32)O6)cc1]

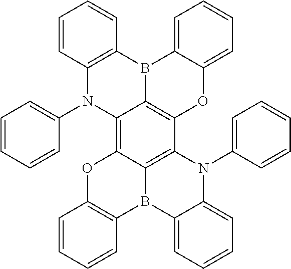 [SMILES: c1ccc(N2c3ccccc3B3c4ccccc4Oc4c3c2c2c3c4N(c4ccccc4)c4ccccc4B3c3ccccc3O2)cc1]

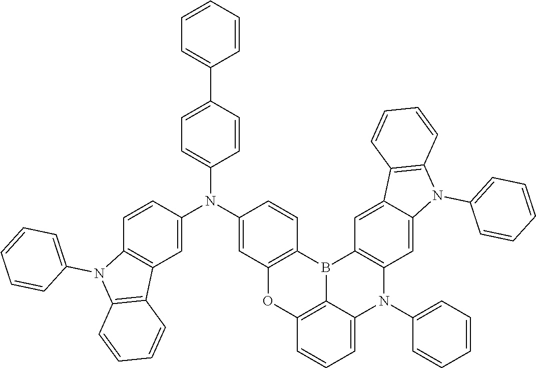 [SMILES: c1ccc(-c2ccc(N(c3ccc4c(c3)Oc3cccc5c3B4c3cc4c6ccccc6n(-c6ccccc6)c4cc3N5c3ccccc3)c3ccc4c(c3)c3ccccc3n4-c3ccccc3)cc2)cc1]

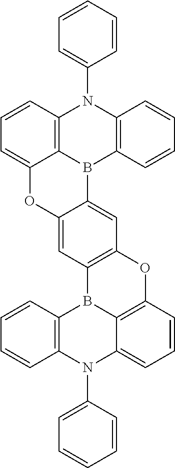 [SMILES: c1ccc(N2c3ccccc3B3c4cc5c(cc4Oc4cccc2c43)B2c3ccccc3N(c3ccccc3)c3cccc(c32)O5)cc1]

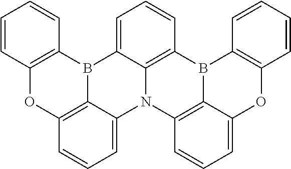 [SMILES: c1ccc2c(c1)Oc1cccc3c1B2c1cccc2c1N3c1cccc3c1B2c1ccccc1O3]

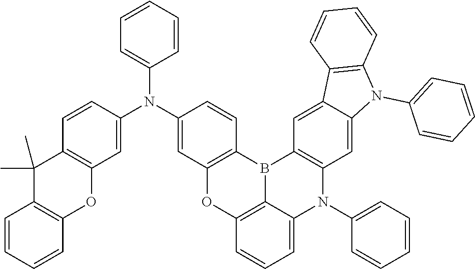 [SMILES: CC1(C)c2ccccc2Oc2cc(N(c3ccccc3)c3ccc4c(c3)Oc3cccc5c3B4c3cc4c6ccccc6n(-c6ccccc6)c4cc3N5c3ccccc3)ccc21]

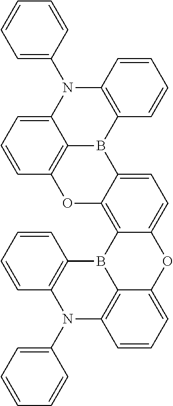 [SMILES: c1ccc(N2c3ccccc3B3c4ccc5c(c4Oc4cccc2c43)B2c3ccccc3N(c3ccccc3)c3cccc(c32)O5)cc1]

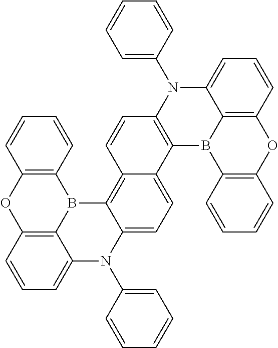 [SMILES: c1ccc(N2c3cccc4c3B(c3ccccc3O4)c3c2ccc2c4c(ccc32)N(c2ccccc2)c2cccc3c2B4c2ccccc2O3)cc1]

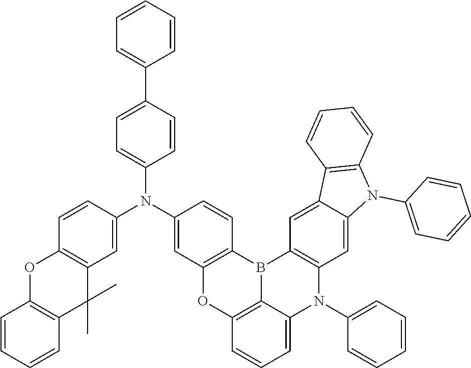 [SMILES: CC1(C)c2ccccc2Oc2ccc(N(c3ccc(-c4ccccc4)cc3)c3ccc4c(c3)Oc3cccc5c3B4c3cc4c6ccccc6n(-c6ccccc6)c4cc3N5c3ccccc3)cc21]

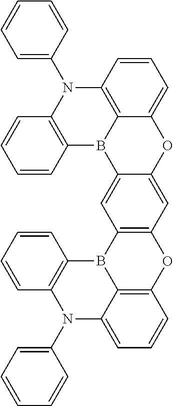 [SMILES: c1ccc(N2c3ccccc3B3c4cc5c(cc4Oc4cccc2c43)Oc2cccc3c2B5c2ccccc2N3c2ccccc2)cc1]

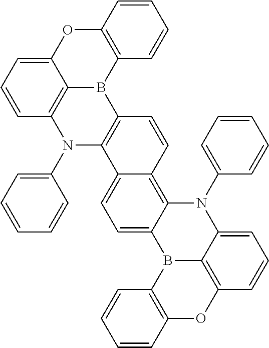 [SMILES: c1ccc(N2c3cccc4c3B(c3ccccc3O4)c3ccc4c5c(ccc4c32)B2c3ccccc3Oc3cccc(c32)N5c2ccccc2)cc1]

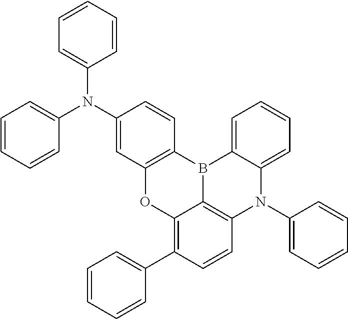 [SMILES: c1ccc(-c2ccc3c4c2Oc2cc(N(c5ccccc5)c5ccccc5)ccc2B4c2ccccc2N3c2ccccc2)cc1]

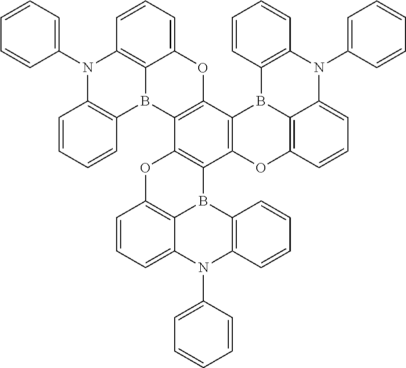 [SMILES: c1ccc(N2c3ccccc3B3c4c(cccc42)Oc2c4c(c5c(c23)Oc2cccc3c2B5c2ccccc2N3c2ccccc2)Oc2cccc3c2B4c2ccccc2N3c2ccccc2)cc1]

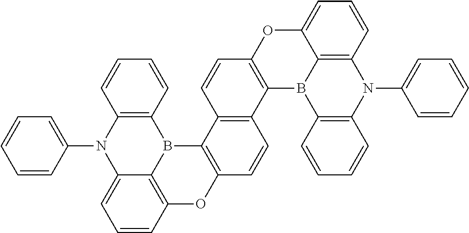 [SMILES: c1ccc(N2c3ccccc3B3c4c(cccc42)Oc2ccc4c5c(ccc4c23)Oc2cccc3c2B5c2ccccc2N3c2ccccc2)cc1]

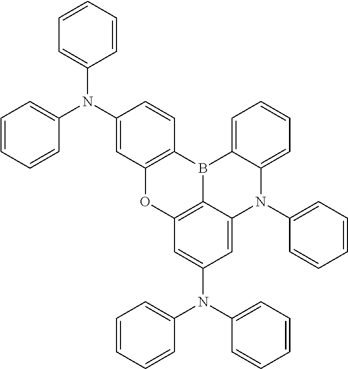 [SMILES: c1ccc(N(c2ccccc2)c2ccc3c(c2)Oc2cc(N(c4ccccc4)c4ccccc4)cc4c2B3c2ccccc2N4c2ccccc2)cc1]

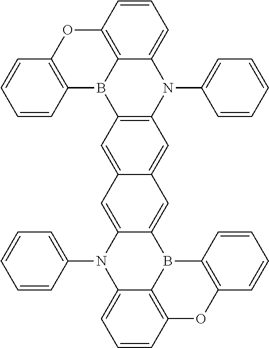 [SMILES: c1ccc(N2c3cc4cc5c(cc4cc3B3c4ccccc4Oc4cccc2c43)N(c2ccccc2)c2cccc3c2B5c2ccccc2O3)cc1]

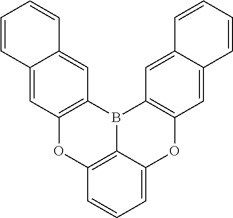 [SMILES: c1cc2c3c(c1)Oc1cc4ccccc4cc1B3c1cc3ccccc3cc1O2]

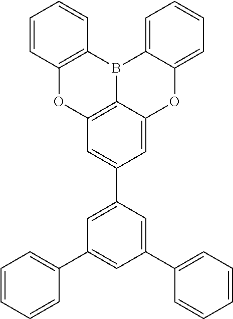 [SMILES: c1ccc(-c2cc(-c3ccccc3)cc(-c3cc4c5c(c3)Oc3ccccc3B5c3ccccc3O4)c2)cc1]

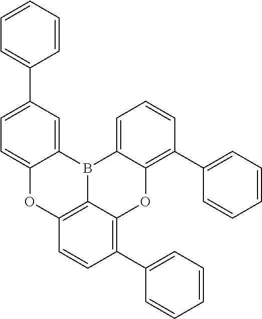 [SMILES: c1ccc(-c2ccc3c(c2)B2c4cccc(-c5ccccc5)c4Oc4c(-c5ccccc5)ccc(c42)O3)cc1]

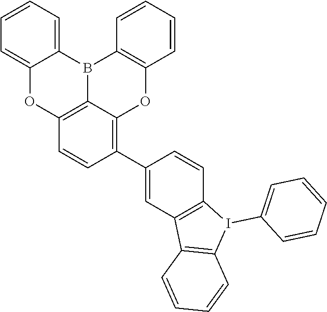 [SMILES: c1ccc(I2c3ccccc3-c3cc(-c4ccc5c6c4Oc4ccccc4B6c4ccccc4O5)ccc32)cc1]

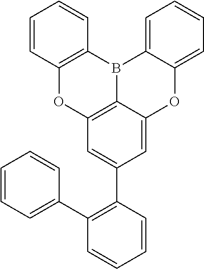 [SMILES: c1ccc(-c2ccccc2-c2cc3c4c(c2)Oc2ccccc2B4c2ccccc2O3)cc1]

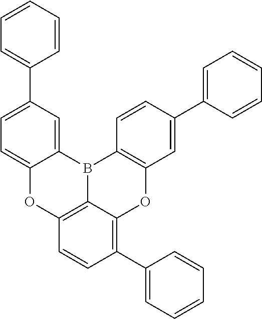 [SMILES: c1ccc(-c2ccc3c(c2)Oc2c(-c4ccccc4)ccc4c2B3c2cc(-c3ccccc3)ccc2O4)cc1]

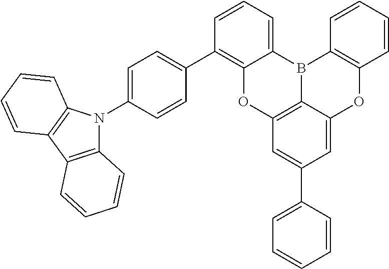 [SMILES: c1ccc(-c2cc3c4c(c2)Oc2c(cccc2-c2ccc(-n5c6ccccc6c6ccccc65)cc2)B4c2ccccc2O3)cc1]

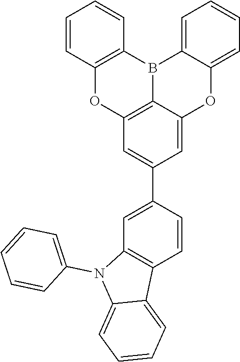 [SMILES: c1ccc(-n2c3ccccc3c3ccc(-c4cc5c6c(c4)Oc4ccccc4B6c4ccccc4O5)cc32)cc1]

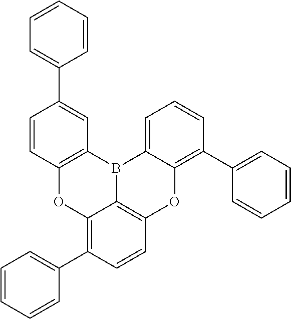 [SMILES: c1ccc(-c2ccc3c(c2)B2c4cccc(-c5ccccc5)c4Oc4ccc(-c5ccccc5)c(c42)O3)cc1]

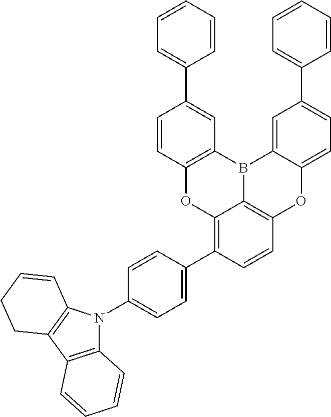 [SMILES: C1=Cc2c(c3ccccc3n2-c2ccc(-c3ccc4c5c3Oc3ccc(-c6ccccc6)cc3B5c3cc(-c5ccccc5)ccc3O4)cc2)CC1]

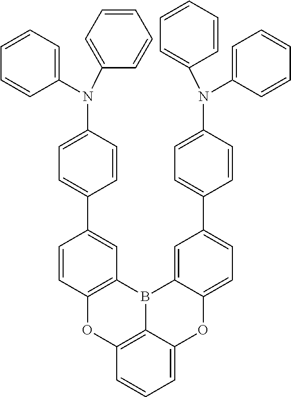 [SMILES: c1ccc(N(c2ccccc2)c2ccc(-c3ccc4c(c3)B3c5cc(-c6ccc(N(c7ccccc7)c7ccccc7)cc6)ccc5Oc5cccc(c53)O4)cc2)cc1]

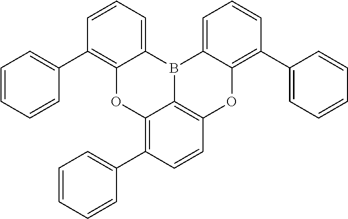 [SMILES: c1ccc(-c2cccc3c2Oc2ccc(-c4ccccc4)c4c2B3c2cccc(-c3ccccc3)c2O4)cc1]

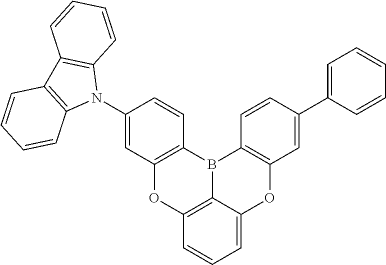 [SMILES: c1ccc(-c2ccc3c(c2)Oc2cccc4c2B3c2ccc(-n3c5ccccc5c5ccccc53)cc2O4)cc1]

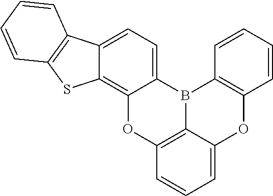 [SMILES: c1ccc2c(c1)Oc1cccc3c1B2c1ccc2c(sc4ccccc42)c1O3]

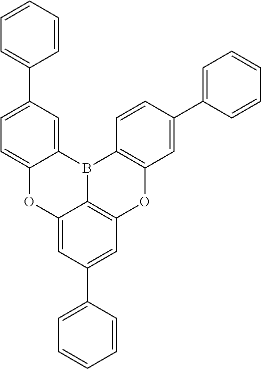 [SMILES: c1ccc(-c2ccc3c(c2)Oc2cc(-c4ccccc4)cc4c2B3c2cc(-c3ccccc3)ccc2O4)cc1]

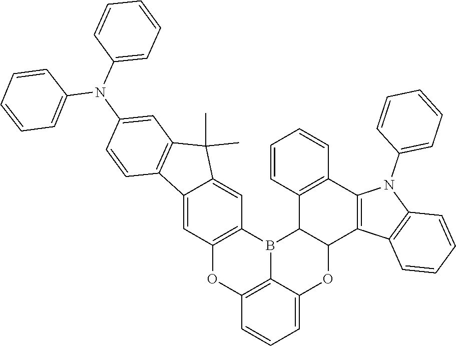 [SMILES: CC1(C)c2cc(N(c3ccccc3)c3ccccc3)ccc2-c2cc3c(cc21)B1c2c(cccc2OC2c4c(n(-c5ccccc5)c5ccccc45)-c4ccccc4C12)O3]

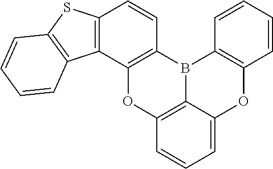 [SMILES: c1ccc2c(c1)Oc1cccc3c1B2c1ccc2sc4ccccc4c2c1O3]

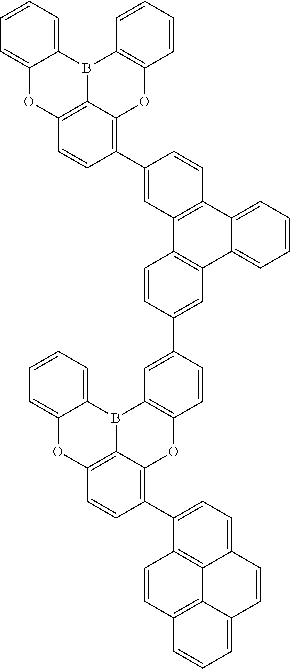 [SMILES: c1ccc2c(c1)Oc1ccc(-c3ccc4c5ccccc5c5cc(-c6ccc7c(c6)B6c8ccccc8Oc8ccc(-c9ccc%10ccc%11cccc%12ccc9c%10c%11%12)c(c86)O7)ccc5c4c3)c3c1B2c1ccccc1O3]

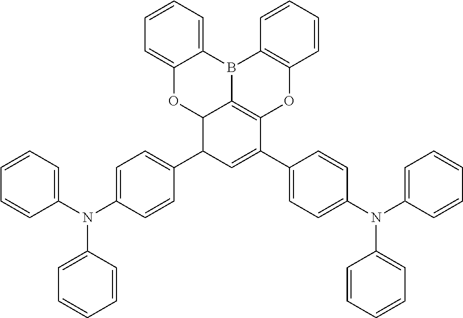 [SMILES: C1=C(c2ccc(N(c3ccccc3)c3ccccc3)cc2)C2=C3B(c4ccccc4O2)c2ccccc2OC3C1c1ccc(N(c2ccccc2)c2ccccc2)cc1]

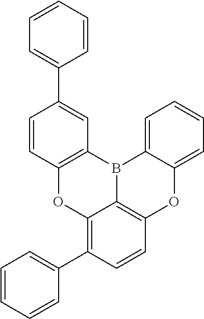 [SMILES: c1ccc(-c2ccc3c(c2)B2c4ccccc4Oc4ccc(-c5ccccc5)c(c42)O3)cc1]

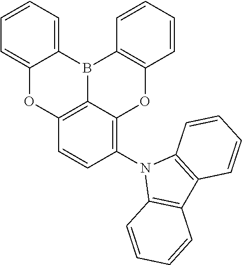 [SMILES: c1ccc2c(c1)Oc1ccc(-n3c4ccccc4c4ccccc43)c3c1B2c1ccccc1O3]

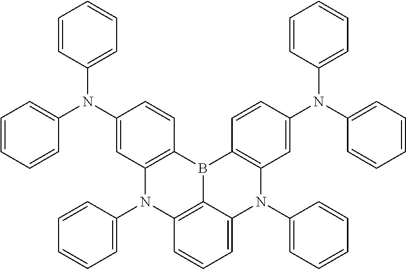 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1]

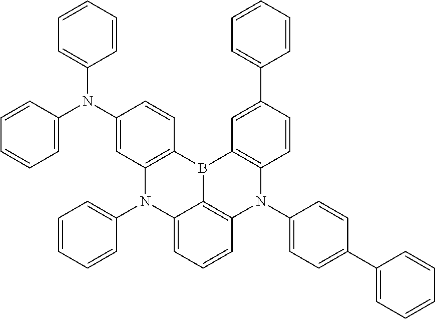 [SMILES: c1ccc(-c2ccc(N3c4ccc(-c5ccccc5)cc4B4c5ccc(N(c6ccccc6)c6ccccc6)cc5N(c5ccccc5)c5cccc3c54)cc2)cc1]

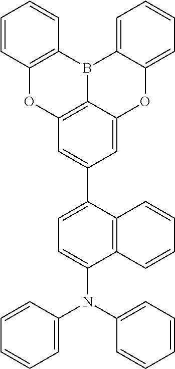 [SMILES: c1ccc(N(c2ccccc2)c2ccc(-c3cc4c5c(c3)Oc3ccccc3B5c3ccccc3O4)c3ccccc23)cc1]

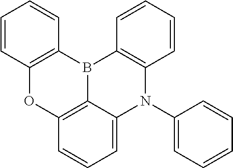 [SMILES: c1ccc(N2c3ccccc3B3c4ccccc4Oc4cccc2c43)cc1]

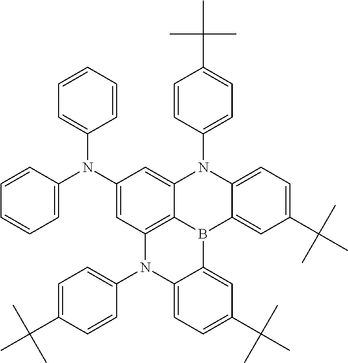 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

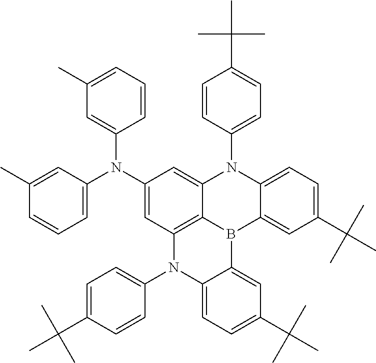 [SMILES: Cc1cccc(N(c2cccc(C)c2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c1]

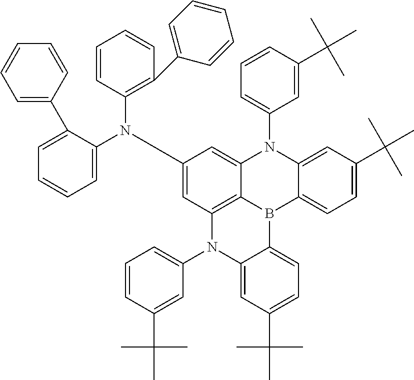 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5-c5ccccc5)c5ccccc5-c5ccccc5)cc2c43)c1]

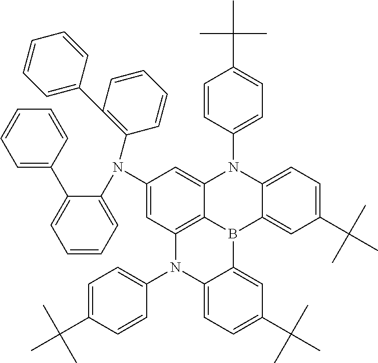 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5-c5ccccc5)c5ccccc5-c5ccccc5)cc2c43)cc1]

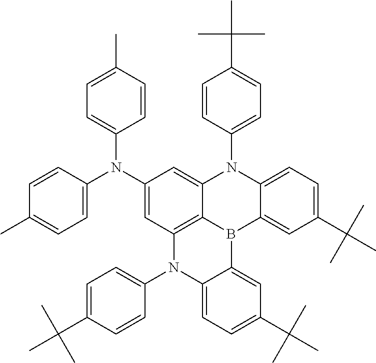 [SMILES: Cc1ccc(N(c2ccc(C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1]

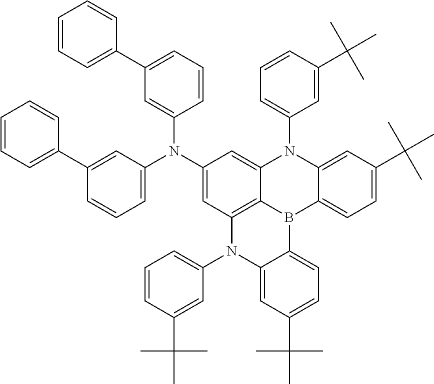 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5cccc(-c6ccccc6)c5)c5cccc(-c6ccccc6)c5)cc2c43)c1]

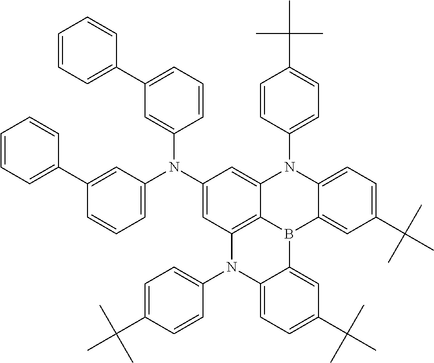 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc(-c6ccccc6)c5)c5cccc(-c6ccccc6)c5)cc2c43)cc1]

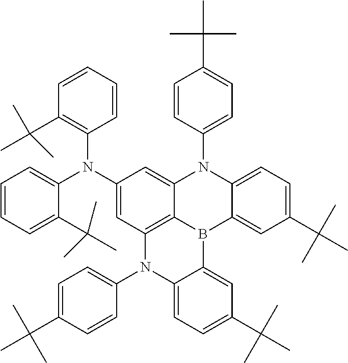 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5C(C)(C)C)c5ccccc5C(C)(C)C)cc2c43)cc1]

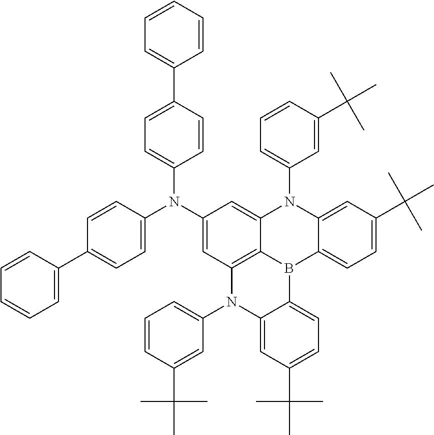 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccc(-c6ccccc6)cc5)c5ccc(-c6ccccc6)cc5)cc2c43)c1]

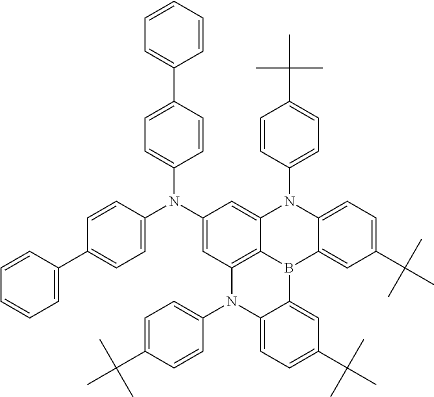 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccc(-c6ccccc6)cc5)c5ccc(-c6ccccc6)cc5)cc2c43)cc1]

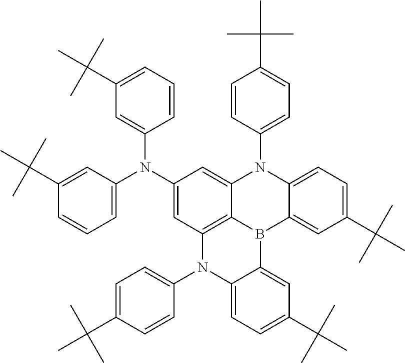 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc(C(C)(C)C)c5)c5cccc(C(C)(C)C)c5)cc2c43)cc1]

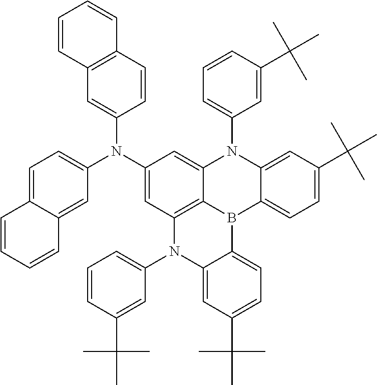 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccc6ccccc6c5)c5ccc6ccccc6c5)cc2c43)c1]

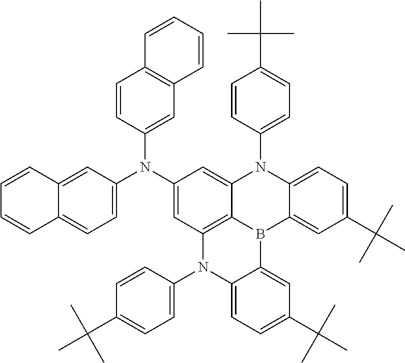 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccc6ccccc6c5)c5ccc6ccccc6c5)cc2c43)cc1]

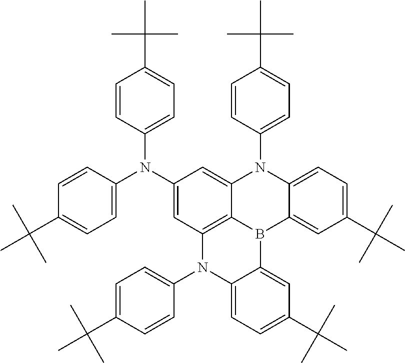 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1]

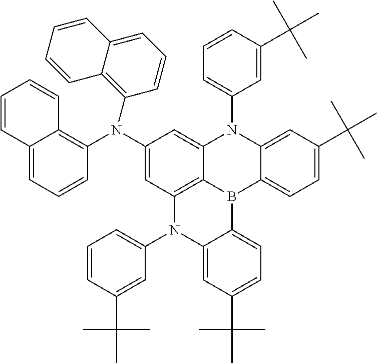 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5cccc6ccccc56)c5cccc6ccccc56)cc2c43)c1]

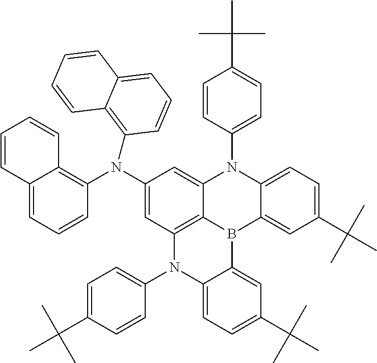 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc6ccccc56)c5cccc6ccccc56)cc2c43)cc1]

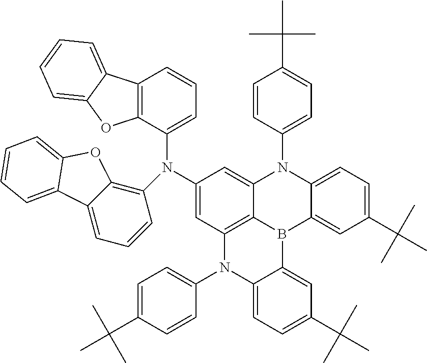 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5cccc6c5oc5ccccc56)c5cccc6c5oc5ccccc56)cc2c43)cc1]

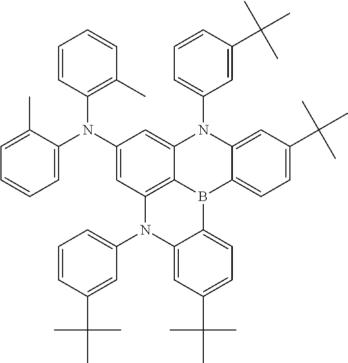 [SMILES: Cc1ccccc1N(c1cc2c3c(c1)N(c1cccc(C(C)(C)C)c1)c1cc(C(C)(C)C)ccc1B3c1ccc(C(C)(C)C)cc1N2c1cccc(C(C)(C)C)c1)c1ccccc1C]

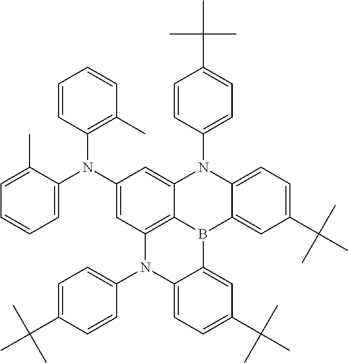 [SMILES: Cc1ccccc1N(c1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1)c1ccccc1C]

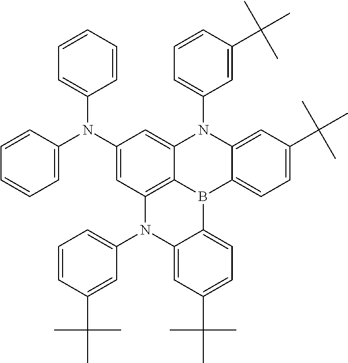 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5ccccc5)cc2c43)c1]

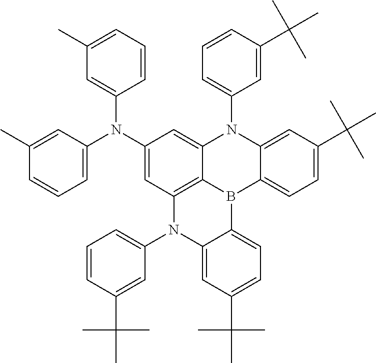 [SMILES: Cc1cccc(N(c2cccc(C)c2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c1]

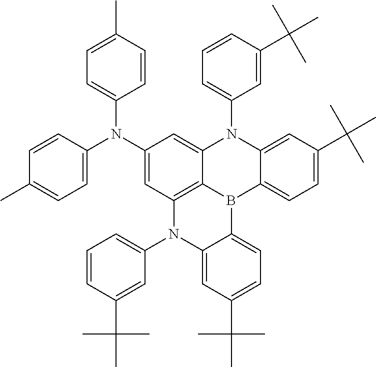 [SMILES: Cc1ccc(N(c2ccc(C)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)cc1]

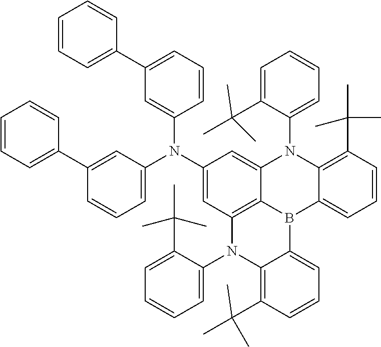 [SMILES: CC(C)(C)c1ccccc1N1c2cc(N(c3cccc(-c4ccccc4)c3)c3cccc(-c4ccccc4)c3)cc3c2B(c2cccc(C(C)(C)C)c21)c1cccc(C(C)(C)C)c1N3c1ccccc1C(C)(C)C]

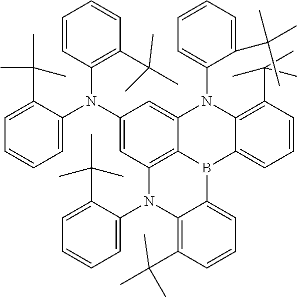 [SMILES: CC(C)(C)c1ccccc1N(c1cc2c3c(c1)N(c1ccccc1C(C)(C)C)c1c(cccc1C(C)(C)C)B3c1cccc(C(C)(C)C)c1N2c1ccccc1C(C)(C)C)c1ccccc1C(C)(C)C]

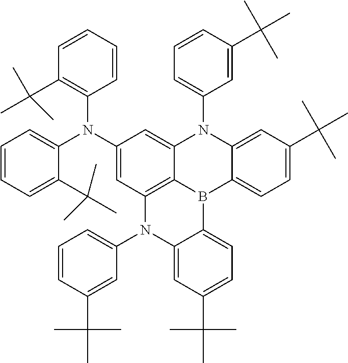 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5C(C)(C)C)c5ccccc5C(C)(C)C)cc2c43)c1]

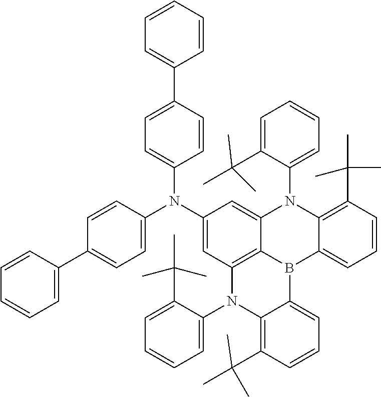 [SMILES: CC(C)(C)c1ccccc1N1c2cc(N(c3ccc(-c4ccccc4)cc3)c3ccc(-c4ccccc4)cc3)cc3c2B(c2cccc(C(C)(C)C)c21)c1cccc(C(C)(C)C)c1N3c1ccccc1C(C)(C)C]

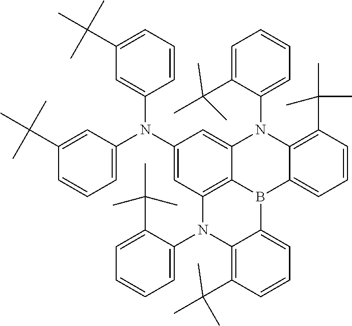 [SMILES: CC(C)(C)c1cccc(N(c2cccc(C(C)(C)C)c2)c2cc3c4c(c2)N(c2ccccc2C(C)(C)C)c2c(cccc2C(C)(C)C)B4c2cccc(C(C)(C)C)c2N3c2ccccc2C(C)(C)C)c1]

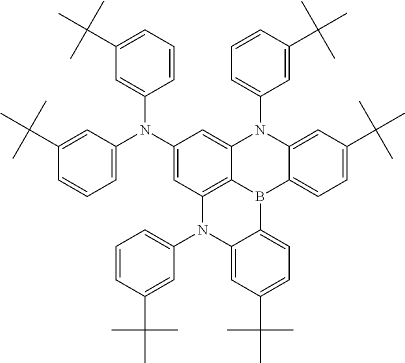 [SMILES: CC(C)(C)c1cccc(N(c2cccc(C(C)(C)C)c2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c1]

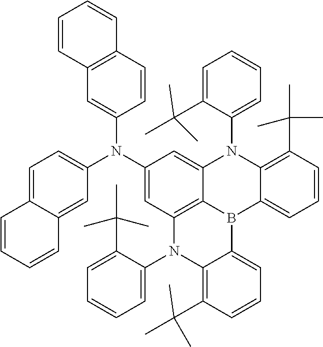 [SMILES: CC(C)(C)c1ccccc1N1c2cc(N(c3ccc4ccccc4c3)c3ccc4ccccc4c3)cc3c2B(c2cccc(C(C)(C)C)c21)c1cccc(C(C)(C)C)c1N3c1ccccc1C(C)(C)C]

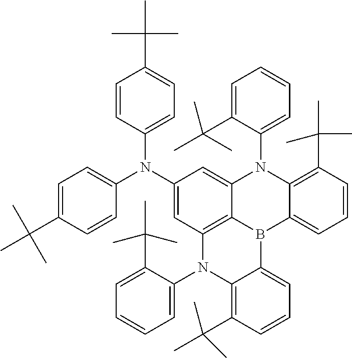 [SMILES: CC(C)(C)c1ccc(N(c2ccc(C(C)(C)C)cc2)c2cc3c4c(c2)N(c2ccccc2C(C)(C)C)c2c(cccc2C(C)(C)C)B4c2cccc(C(C)(C)C)c2N3c2ccccc2C(C)(C)C)cc1]

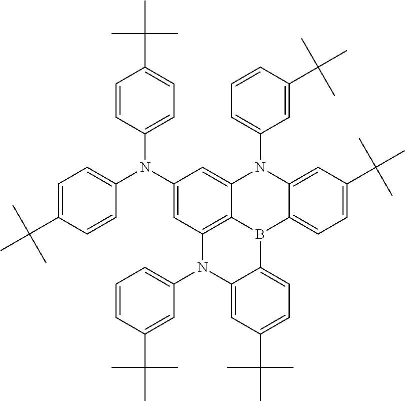 [SMILES: CC(C)(C)c1ccc(N(c2ccc(C(C)(C)C)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)cc1]

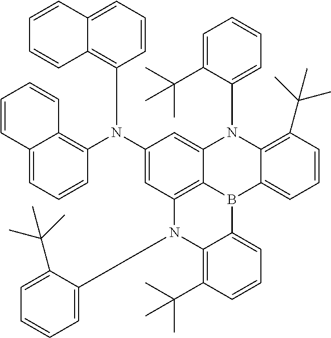 [SMILES: CC(C)(C)c1ccccc1N1c2cc(N(c3cccc4ccccc34)c3cccc4ccccc34)cc3c2B(c2cccc(C(C)(C)C)c21)c1cccc(C(C)(C)C)c1N3c1ccccc1C(C)(C)C]

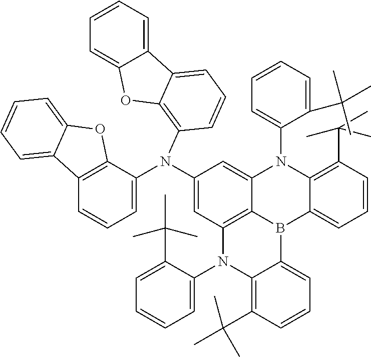 [SMILES: CC(C)(C)c1ccccc1N1c2cc(N(c3cccc4c3oc3ccccc34)c3cccc4c3oc3ccccc34)cc3c2B(c2cccc(C(C)(C)C)c21)c1cccc(C(C)(C)C)c1N3c1ccccc1C(C)(C)C]

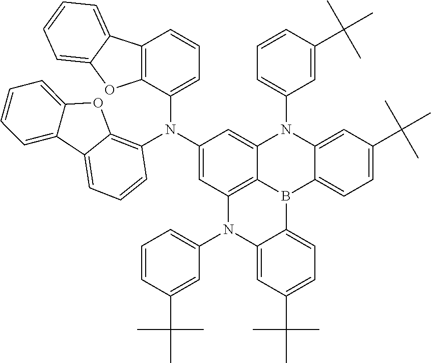 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5cccc6c5oc5ccccc56)c5cccc6c5oc5ccccc56)cc2c43)c1]

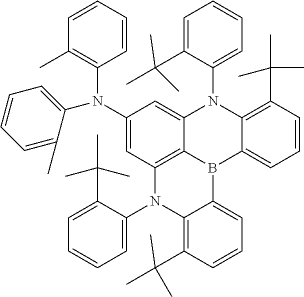 [SMILES: Cc1ccccc1N(c1cc2c3c(c1)N(c1ccccc1C(C)(C)C)c1c(cccc1C(C)(C)C)B3c1cccc(C(C)(C)C)c1N2c1ccccc1C(C)(C)C)c1ccccc1C]

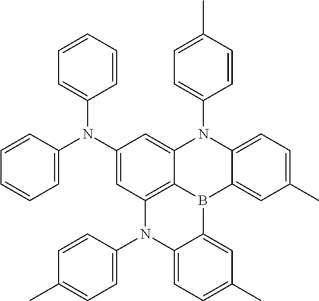 [SMILES: Cc1ccc(N2c3ccc(C)cc3B3c4cc(C)ccc4N(c4ccc(C)cc4)c4cc(N(c5ccccc5)c5ccccc5)cc2c43)cc1]

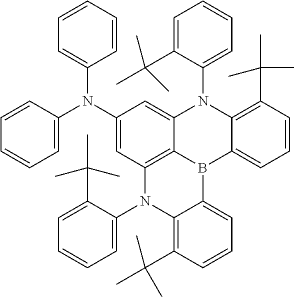 [SMILES: CC(C)(C)c1ccccc1N1c2cc(N(c3ccccc3)c3ccccc3)cc3c2B(c2cccc(C(C)(C)C)c21)c1cccc(C(C)(C)C)c1N3c1ccccc1C(C)(C)C]

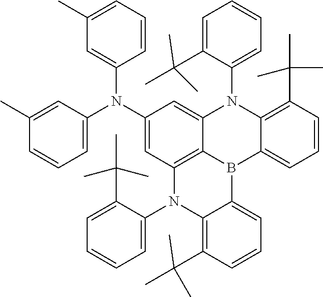 [SMILES: Cc1cccc(N(c2cccc(C)c2)c2cc3c4c(c2)N(c2ccccc2C(C)(C)C)c2c(cccc2C(C)(C)C)B4c2cccc(C(C)(C)C)c2N3c2ccccc2C(C)(C)C)c1]

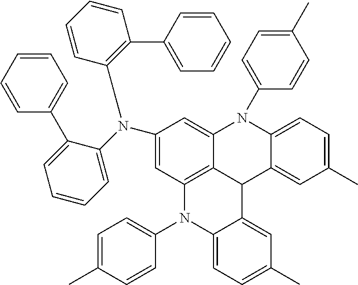 [SMILES: Cc1ccc(N2c3ccc(C)cc3C3c4cc(C)ccc4N(c4ccc(C)cc4)c4cc(N(c5ccccc5-c5ccccc5)c5ccccc5-c5ccccc5)cc2c43)cc1]

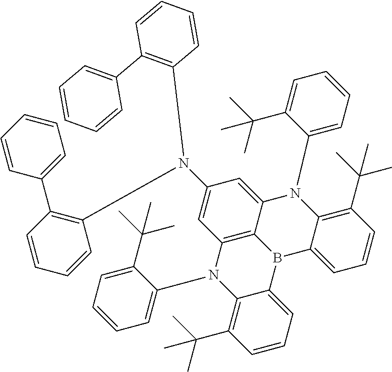 [SMILES: CC(C)(C)c1ccccc1N1c2cc(N(c3ccccc3-c3ccccc3)c3ccccc3-c3ccccc3)cc3c2B(c2cccc(C(C)(C)C)c21)c1cccc(C(C)(C)C)c1N3c1ccccc1C(C)(C)C]

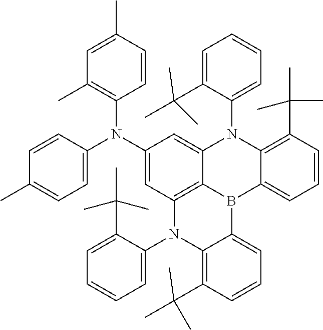 [SMILES: Cc1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2ccc(C)cc2C)cc1]

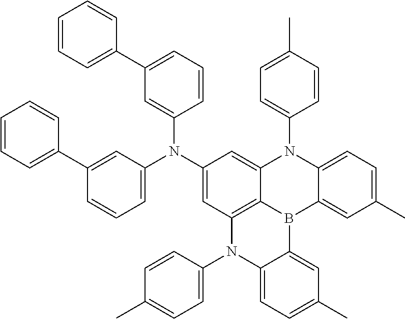 [SMILES: Cc1ccc(N2c3ccc(C)cc3B3c4cc(C)ccc4N(c4ccc(C)cc4)c4cc(N(c5cccc(-c6ccccc6)c5)c5cccc(-c6ccccc6)c5)cc2c43)cc1]

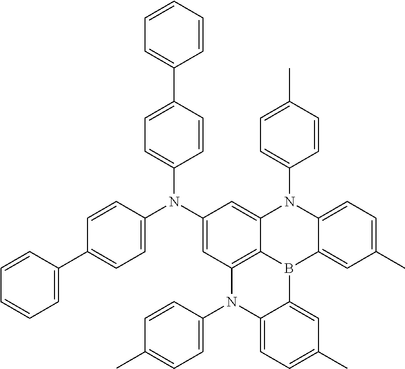 [SMILES: Cc1ccc(N2c3ccc(C)cc3B3c4cc(C)ccc4N(c4ccc(C)cc4)c4cc(N(c5ccc(-c6ccccc6)cc5)c5ccc(-c6ccccc6)cc5)cc2c43)cc1]

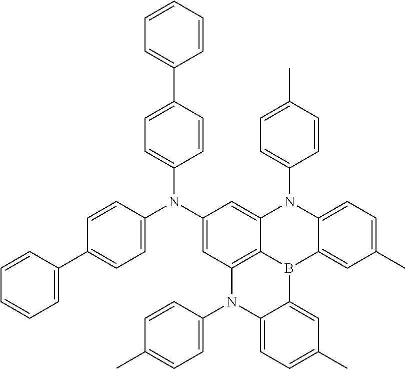 [SMILES: Cc1ccc(N2c3ccc(C)cc3B3c4cc(C)ccc4N(c4ccc(C)cc4)c4cc(N(c5ccc(-c6ccccc6)cc5)c5ccc(-c6ccccc6)cc5)cc2c43)cc1]

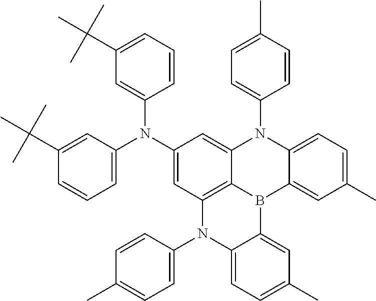 [SMILES: Cc1ccc(N2c3ccc(C)cc3B3c4cc(C)ccc4N(c4ccc(C)cc4)c4cc(N(c5cccc(C(C)(C)C)c5)c5cccc(C(C)(C)C)c5)cc2c43)cc1]

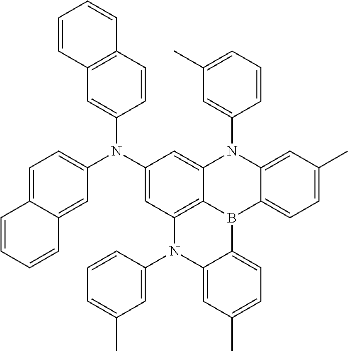 [SMILES: Cc1cccc(N2c3cc(C)ccc3B3c4ccc(C)cc4N(c4cccc(C)c4)c4cc(N(c5ccc6ccccc6c5)c5ccc6ccccc6c5)cc2c43)c1]

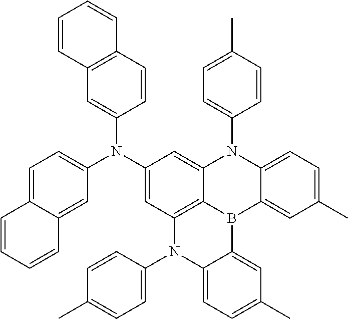 [SMILES: Cc1ccc(N2c3ccc(C)cc3B3c4cc(C)ccc4N(c4ccc(C)cc4)c4cc(N(c5ccc6ccccc6c5)c5ccc6ccccc6c5)cc2c43)cc1]

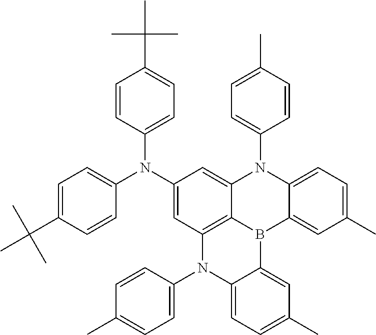 [SMILES: Cc1ccc(N2c3ccc(C)cc3B3c4cc(C)ccc4N(c4ccc(C)cc4)c4cc(N(c5ccc(C(C)(C)C)cc5)c5ccc(C(C)(C)C)cc5)cc2c43)cc1]

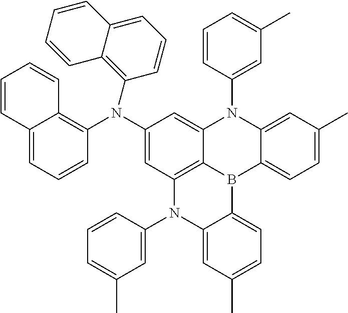 [SMILES: Cc1cccc(N2c3cc(C)ccc3B3c4ccc(C)cc4N(c4cccc(C)c4)c4cc(N(c5cccc6ccccc56)c5cccc6ccccc56)cc2c43)c1]

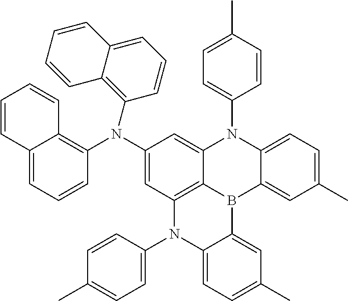 [SMILES: Cc1ccc(N2c3ccc(C)cc3B3c4cc(C)ccc4N(c4ccc(C)cc4)c4cc(N(c5cccc6ccccc56)c5cccc6ccccc56)cc2c43)cc1]

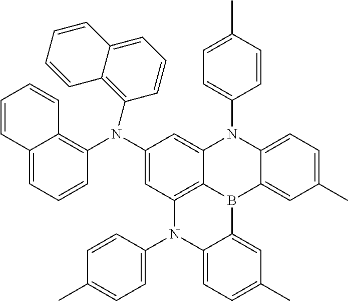 [SMILES: Cc1ccc(N2c3ccc(C)cc3B3c4cc(C)ccc4N(c4ccc(C)cc4)c4cc(N(c5cccc6ccccc56)c5cccc6ccccc56)cc2c43)cc1]

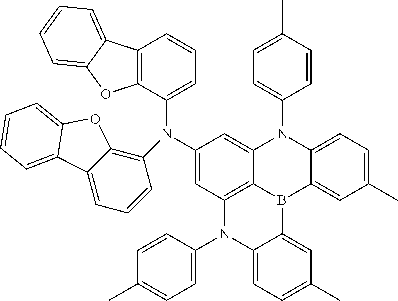 [SMILES: Cc1ccc(N2c3ccc(C)cc3B3c4cc(C)ccc4N(c4ccc(C)cc4)c4cc(N(c5cccc6c5oc5ccccc56)c5cccc6c5oc5ccccc56)cc2c43)cc1]

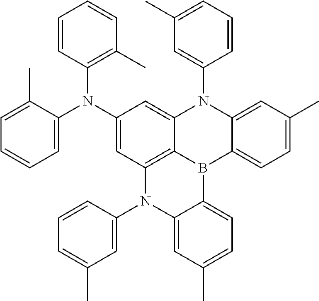 [SMILES: Cc1cccc(N2c3cc(C)ccc3B3c4ccc(C)cc4N(c4cccc(C)c4)c4cc(N(c5ccccc5C)c5ccccc5C)cc2c43)c1]

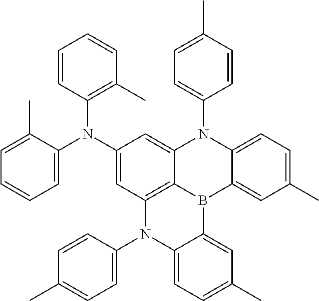 [SMILES: Cc1ccc(N2c3ccc(C)cc3B3c4cc(C)ccc4N(c4ccc(C)cc4)c4cc(N(c5ccccc5C)c5ccccc5C)cc2c43)cc1]

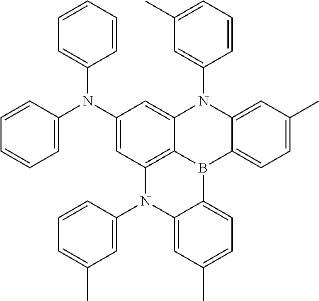 [SMILES: Cc1cccc(N2c3cc(C)ccc3B3c4ccc(C)cc4N(c4cccc(C)c4)c4cc(N(c5ccccc5)c5ccccc5)cc2c43)c1]

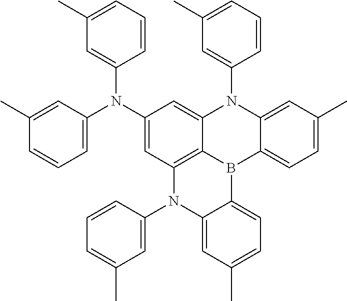

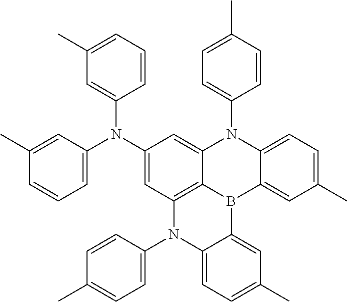

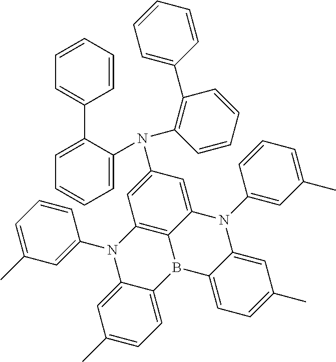

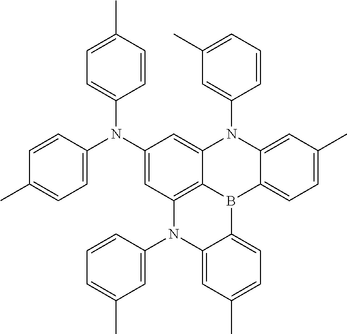

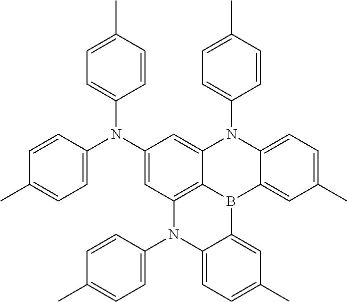

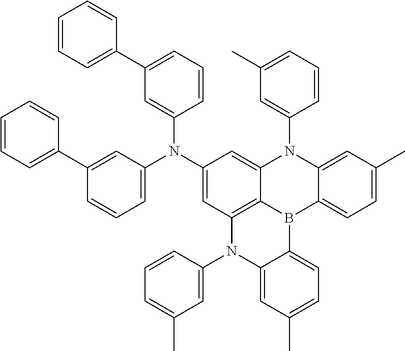 [SMILES: Cc1cccc(N2c3cc(C)ccc3B3c4ccc(C)cc4N(c4cccc(C)c4)c4cc(N(c5cccc(-c6ccccc6)c5)c5cccc(-c6ccccc6)c5)cc2c43)c1]

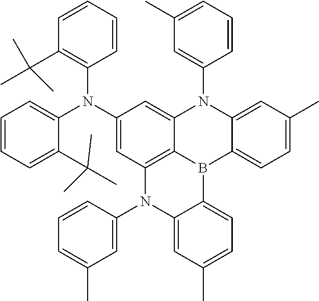 [SMILES: Cc1cccc(N2c3cc(C)ccc3B3c4ccc(C)cc4N(c4cccc(C)c4)c4cc(N(c5ccccc5C(C)(C)C)c5ccccc5C(C)(C)C)cc2c43)c1]

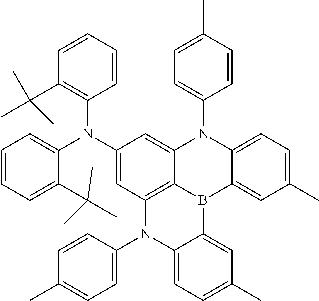 [SMILES: Cc1ccc(N2c3ccc(C)cc3B3c4cc(C)ccc4N(c4ccc(C)cc4)c4cc(N(c5ccccc5C(C)(C)C)c5ccccc5C(C)(C)C)cc2c43)cc1]

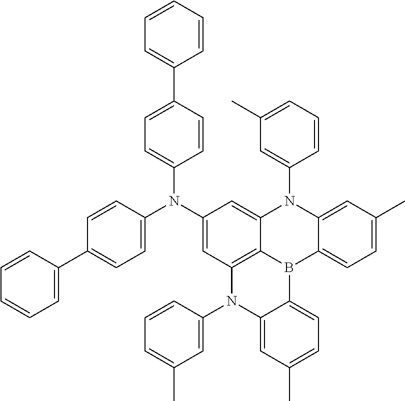 [SMILES: Cc1cccc(N2c3cc(C)ccc3B3c4ccc(C)cc4N(c4cccc(C)c4)c4cc(N(c5ccc(-c6ccccc6)cc5)c5ccc(-c6ccccc6)cc5)cc2c43)c1]

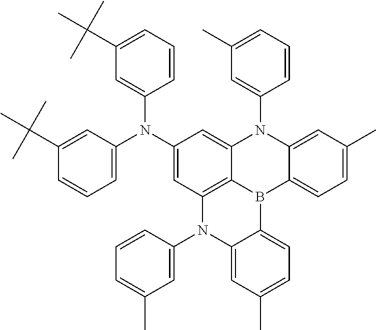 [SMILES: Cc1cccc(N2c3cc(C)ccc3B3c4ccc(C)cc4N(c4cccc(C)c4)c4cc(N(c5cccc(C(C)(C)C)c5)c5cccc(C(C)(C)C)c5)cc2c43)c1]

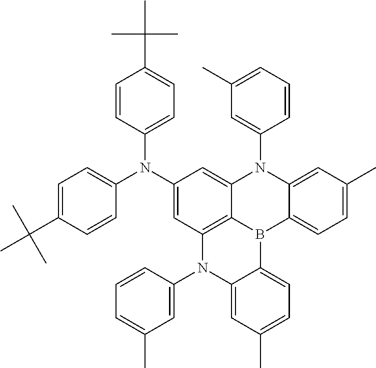 [SMILES: Cc1cccc(N2c3cc(C)ccc3B3c4ccc(C)cc4N(c4cccc(C)c4)c4cc(N(c5ccc(C(C)(C)C)cc5)c5ccc(C(C)(C)C)cc5)cc2c43)c1]

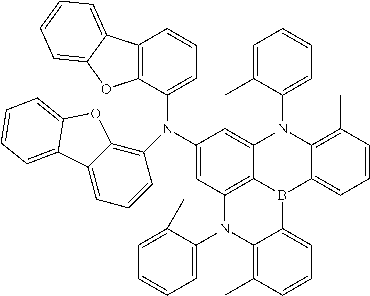 [SMILES: Cc1ccccc1N1c2cc(N(c3cccc4c3oc3ccccc34)c3cccc4c3oc3ccccc34)cc3c2B(c2cccc(C)c21)c1cccc(C)c1N3c1ccccc1C]

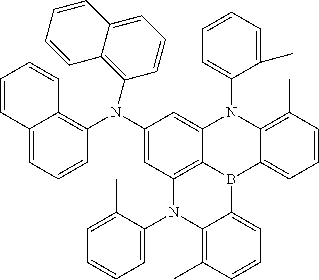 [SMILES: Cc1ccccc1N1c2cc(N(c3cccc4ccccc34)c3cccc4ccccc34)cc3c2B(c2cccc(C)c21)c1cccc(C)c1N3c1ccccc1C]

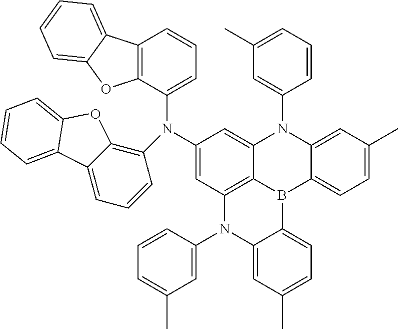 [SMILES: Cc1cccc(N2c3cc(C)ccc3B3c4ccc(C)cc4N(c4cccc(C)c4)c4cc(N(c5cccc6c5oc5ccccc56)c5cccc6c5oc5ccccc56)cc2c43)c1]

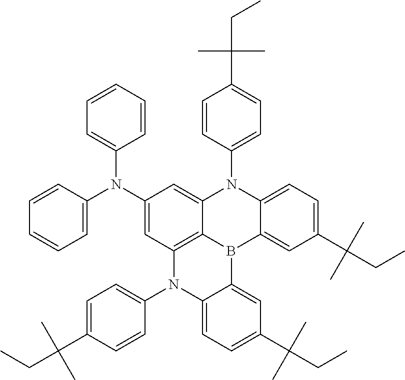 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5ccccc5)cc2c43)cc1]

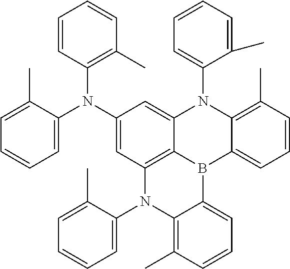 [SMILES: Cc1ccccc1N(c1cc2c3c(c1)N(c1ccccc1C)c1c(C)cccc1B3c1cccc(C)c1N2c1ccccc1C)c1ccccc1C]

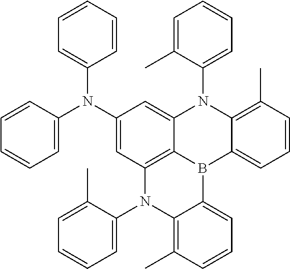 [SMILES: Cc1ccccc1N1c2cc(N(c3ccccc3)c3ccccc3)cc3c2B(c2cccc(C)c21)c1cccc(C)c1N3c1ccccc1C]

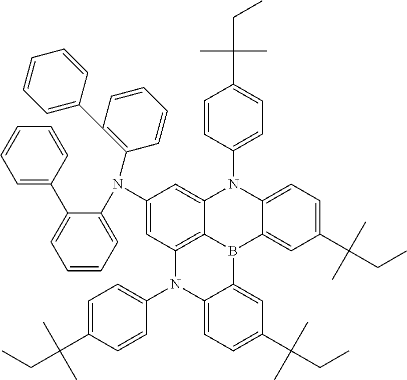 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5-c5ccccc5)c5ccccc5-c5ccccc5)cc2c43)cc1]

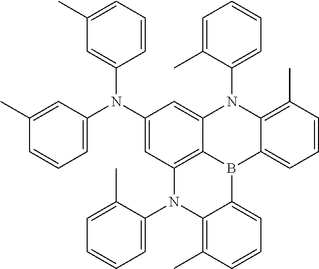 [SMILES: Cc1cccc(N(c2cccc(C)c2)c2cc3c4c(c2)N(c2ccccc2C)c2c(C)cccc2B4c2cccc(C)c2N3c2ccccc2C)c1]

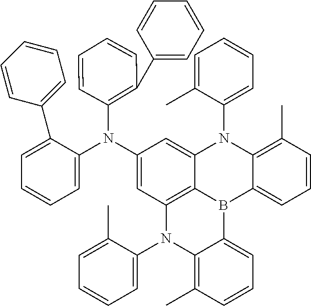 [SMILES: Cc1ccccc1N1c2cc(N(c3ccccc3-c3ccccc3)c3ccccc3-c3ccccc3)cc3c2B(c2cccc(C)c21)c1cccc(C)c1N3c1ccccc1C]

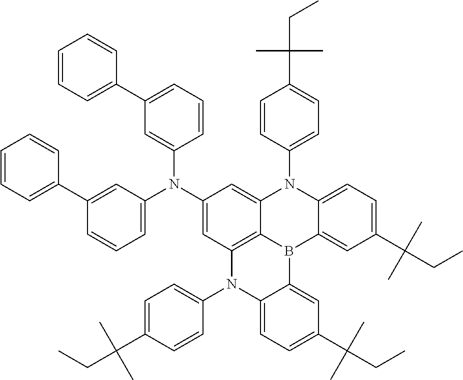 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc(-c6ccccc6)c5)c5cccc(-c6ccccc6)c5)cc2c43)cc1]

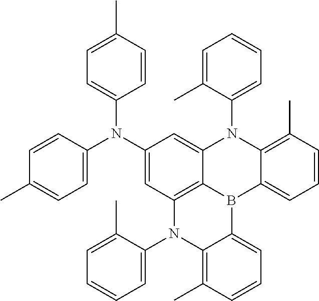 [SMILES: Cc1ccc(N(c2ccc(C)cc2)c2cc3c4c(c2)N(c2ccccc2C)c2c(C)cccc2B4c2cccc(C)c2N3c2ccccc2C)cc1]

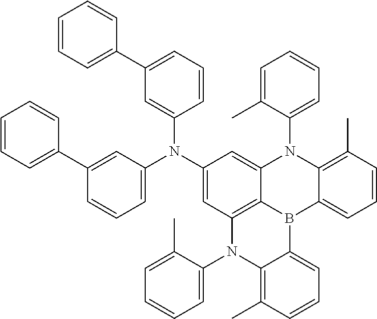 [SMILES: Cc1ccccc1N1c2cc(N(c3cccc(-c4ccccc4)c3)c3cccc(-c4ccccc4)c3)cc3c2B(c2cccc(C)c21)c1cccc(C)c1N3c1ccccc1C]

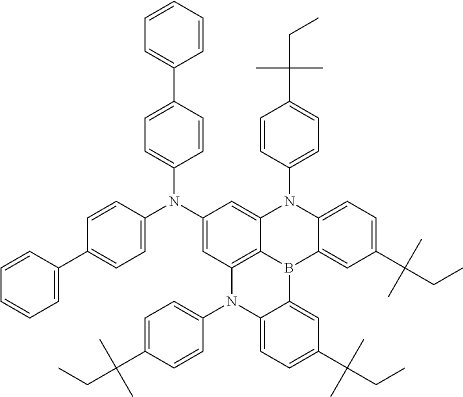 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(-c6ccccc6)cc5)c5ccc(-c6ccccc6)cc5)cc2c43)cc1]

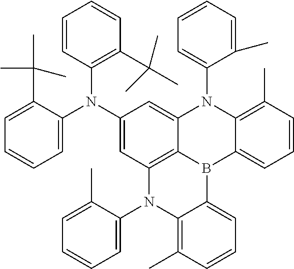 [SMILES: Cc1ccccc1N1c2cc(N(c3ccccc3C(C)(C)C)c3ccccc3C(C)(C)C)cc3c2B(c2cccc(C)c21)c1cccc(C)c1N3c1ccccc1C]

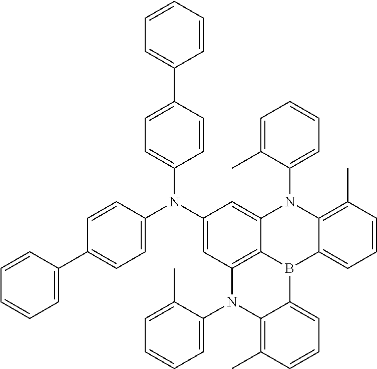 [SMILES: Cc1ccccc1N1c2cc(N(c3ccc(-c4ccccc4)cc3)c3ccc(-c4ccccc4)cc3)cc3c2B(c2cccc(C)c21)c1cccc(C)c1N3c1ccccc1C]

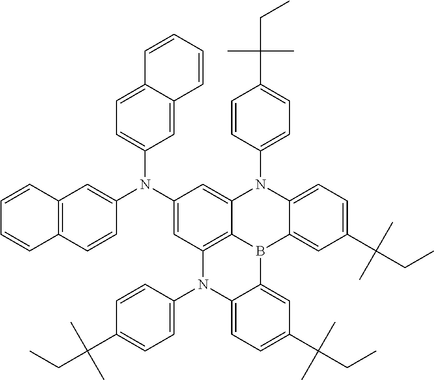 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc6ccccc6c5)c5ccc6ccccc6c5)cc2c43)cc1]

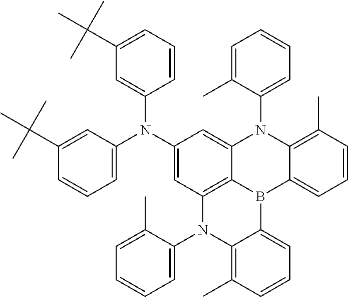 [SMILES: Cc1ccccc1N1c2cc(N(c3cccc(C(C)(C)C)c3)c3cccc(C(C)(C)C)c3)cc3c2B(c2cccc(C)c21)c1cccc(C)c1N3c1ccccc1C]

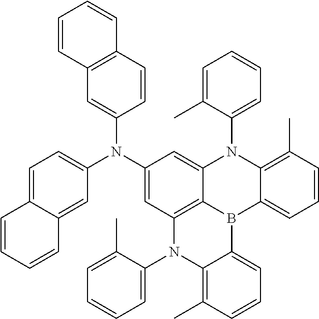 [SMILES: Cc1ccccc1N1c2cc(N(c3ccc4ccccc4c3)c3ccc4ccccc4c3)cc3c2B(c2cccc(C)c21)c1cccc(C)c1N3c1ccccc1C]

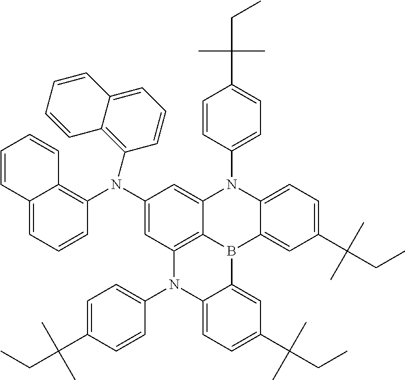 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc6ccccc56)c5cccc6ccccc56)cc2c43)cc1]

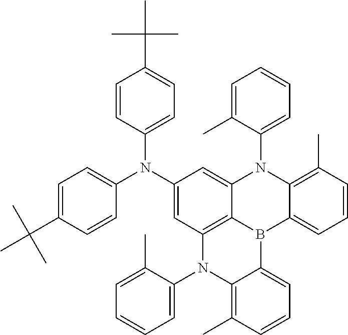 [SMILES: Cc1ccccc1N1c2cc(N(c3ccc(C(C)(C)C)cc3)c3ccc(C(C)(C)C)cc3)cc3c2B(c2cccc(C)c21)c1cccc(C)c1N3c1ccccc1C]

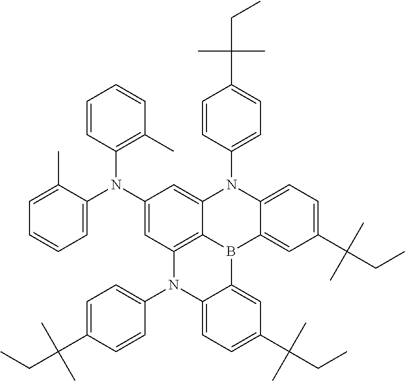 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5C)c5ccccc5C)cc2c43)cc1]

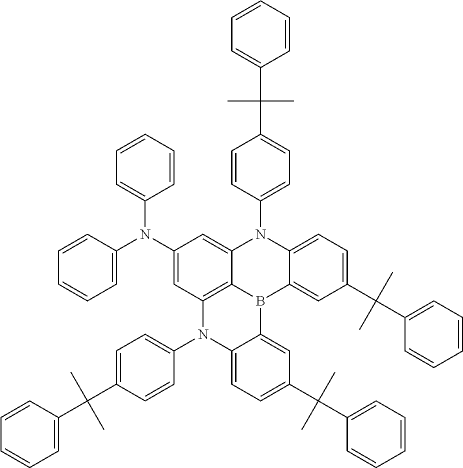 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5ccccc5)cc2c43)cc1]

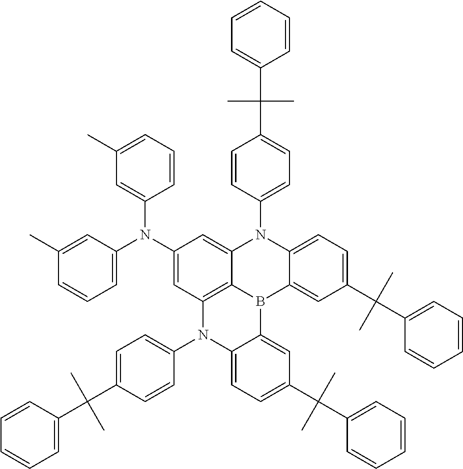 [SMILES: Cc1cccc(N(c2cccc(C)c2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c1]

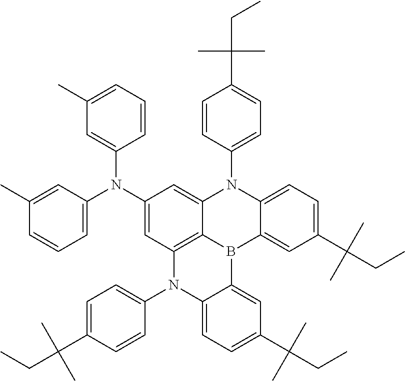 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc(C)c5)c5cccc(C)c5)cc2c43)cc1]

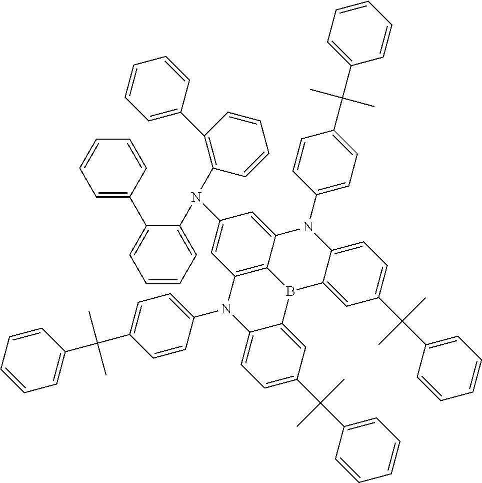 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5-c5ccccc5)c5ccccc5-c5ccccc5)cc2c43)cc1]

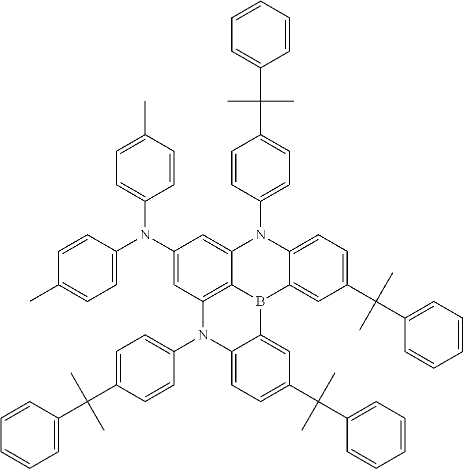 [SMILES: Cc1ccc(N(c2ccc(C)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)cc1]

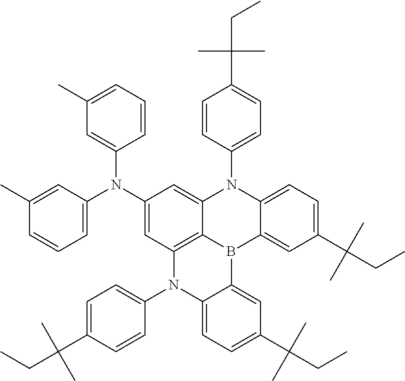 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc(C)c5)c5cccc(C)c5)cc2c43)cc1]

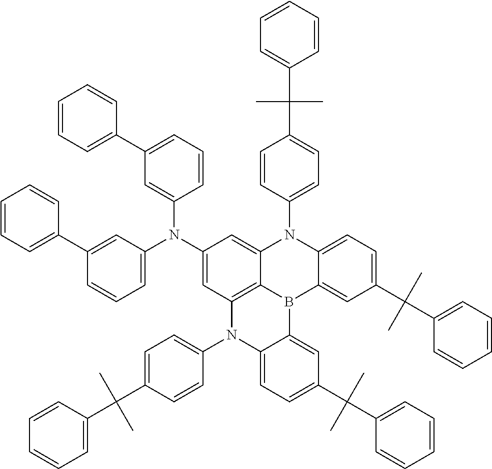 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5cccc(-c6ccccc6)c5)c5cccc(-c6ccccc6)c5)cc2c43)cc1]

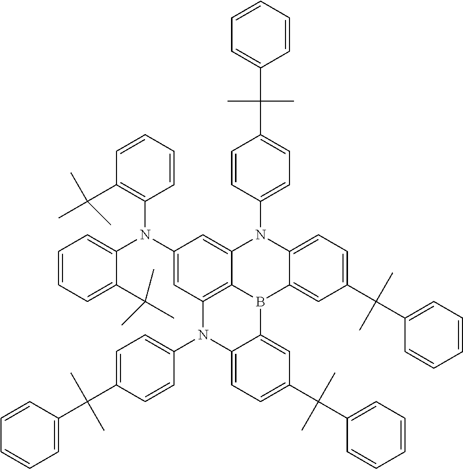 [SMILES: CC(C)(C)c1ccccc1N(c1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1)c1ccccc1C(C)(C)C]

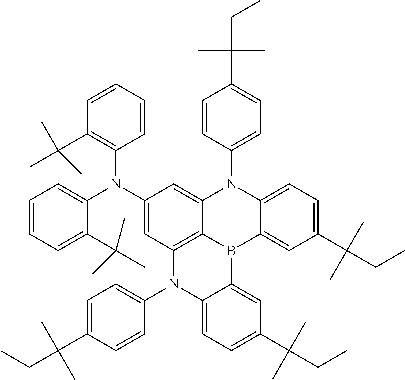 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5C(C)(C)C)c5ccccc5C(C)(C)C)cc2c43)cc1]

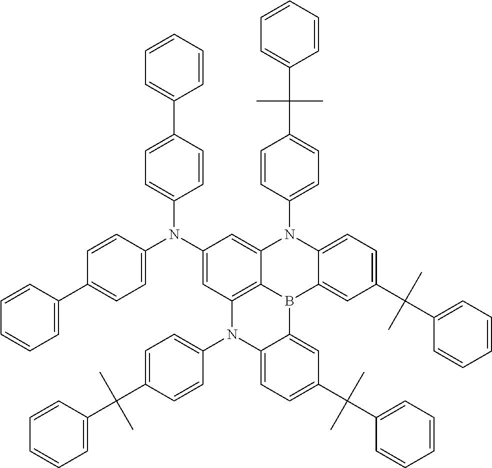 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccc(-c6ccccc6)cc5)c5ccc(-c6ccccc6)cc5)cc2c43)cc1]

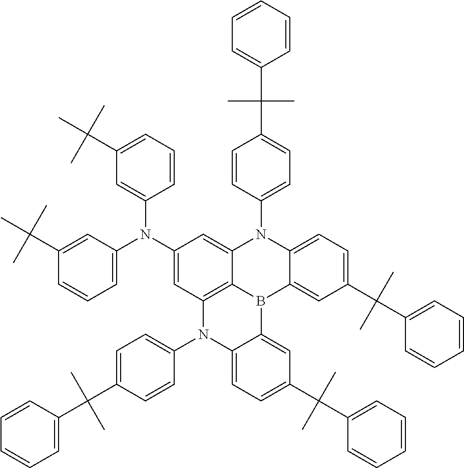 [SMILES: CC(C)(C)c1cccc(N(c2cccc(C(C)(C)C)c2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c1]

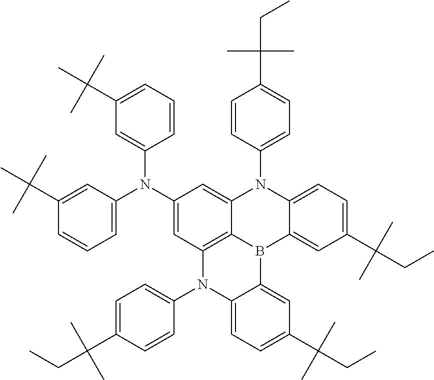 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc(C(C)(C)C)c5)c5cccc(C(C)(C)C)c5)cc2c43)cc1]

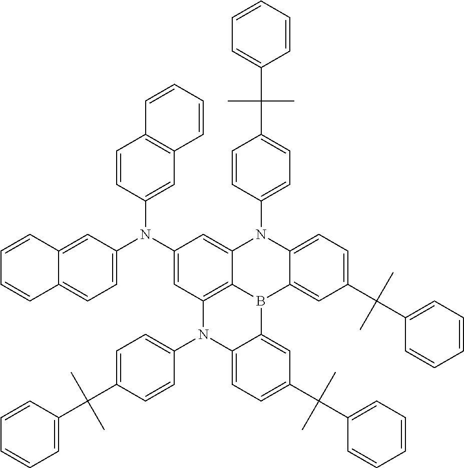 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccc6ccccc6c5)c5ccc6ccccc6c5)cc2c43)cc1]

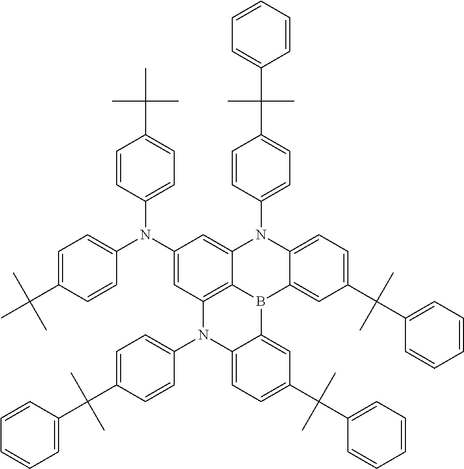 [SMILES: CC(C)(C)c1ccc(N(c2ccc(C(C)(C)C)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)cc1]

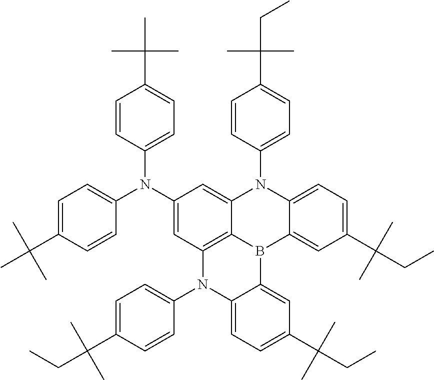 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)(C)C)cc5)c5ccc(C(C)(C)C)cc5)cc2c43)cc1]

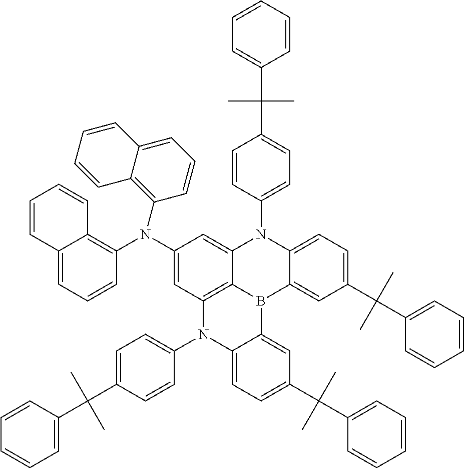 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5cccc6ccccc56)c5cccc6ccccc56)cc2c43)cc1]

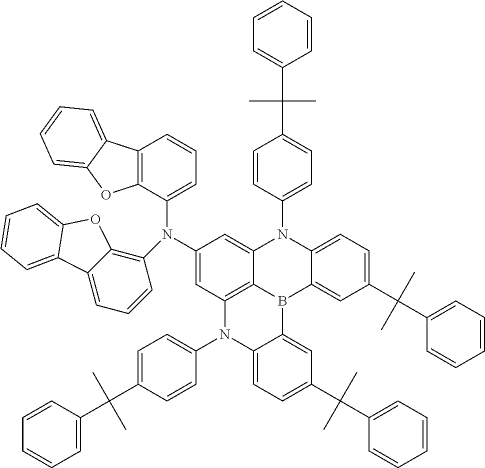 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5cccc6c5oc5ccccc56)c5cccc6c5oc5ccccc56)cc2c43)cc1]

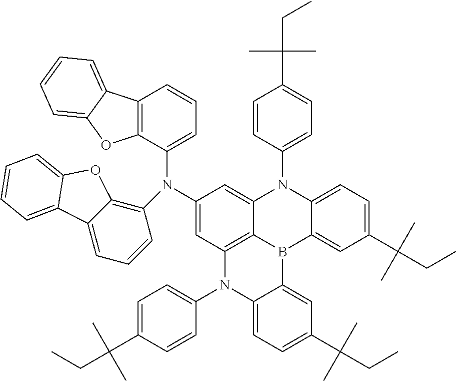 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5cccc6c5oc5ccccc56)c5cccc6c5oc5ccccc56)cc2c43)cc1]

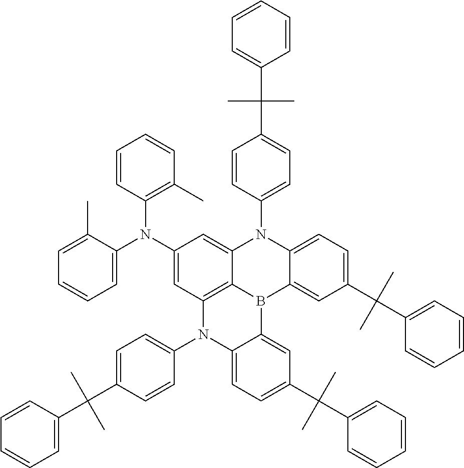 [SMILES: Cc1ccccc1N(c1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1)c1ccccc1C]

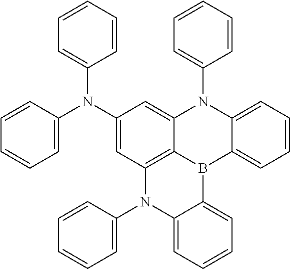 [SMILES: c1ccc(N(c2ccccc2)c2cc3c4c(c2)N(c2ccccc2)c2ccccc2B4c2ccccc2N3c2ccccc2)cc1]

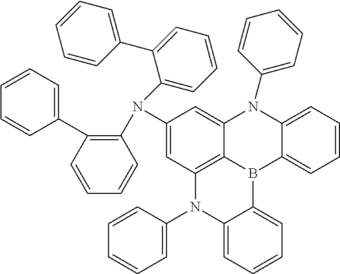 [SMILES: c1ccc(-c2ccccc2N(c2cc3c4c(c2)N(c2ccccc2)c2ccccc2B4c2ccccc2N3c2ccccc2)c2ccccc2-c2ccccc2)cc1]

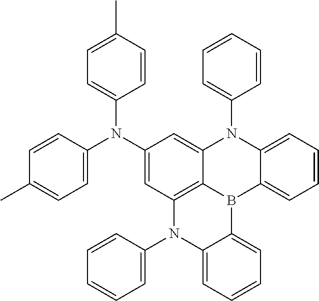 [SMILES: Cc1ccc(N(c2ccc(C)cc2)c2cc3c4c(c2)N(c2ccccc2)c2ccccc2B4c2ccccc2N3c2ccccc2)cc1]

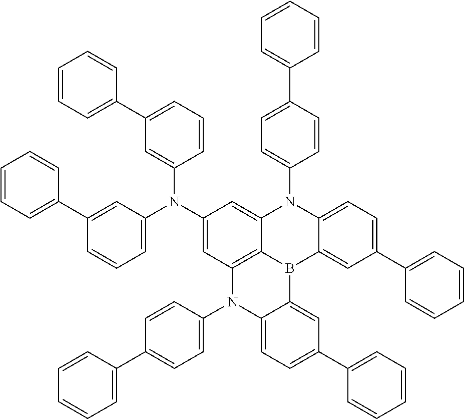 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6cccc(-c7ccccc7)c6)c6cccc(-c7ccccc7)c6)cc3c54)cc2)cc1]

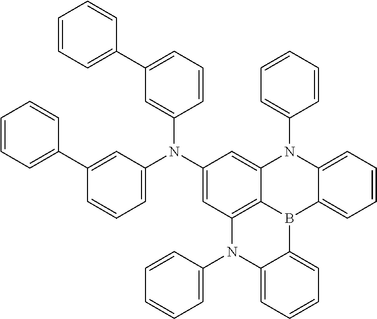 [SMILES: c1ccc(-c2cccc(N(c3cccc(-c4ccccc4)c3)c3cc4c5c(c3)N(c3ccccc3)c3ccccc3B5c3ccccc3N4c3ccccc3)c2)cc1]

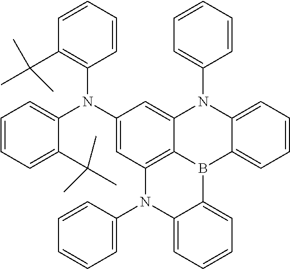 [SMILES: CC(C)(C)c1ccccc1N(c1cc2c3c(c1)N(c1ccccc1)c1ccccc1B3c1ccccc1N2c1ccccc1)c1ccccc1C(C)(C)C]

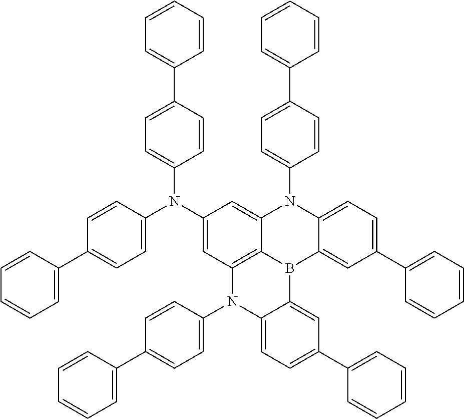 [SMILES: c1ccc(-c2ccc(N(c3ccc(-c4ccccc4)cc3)c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)cc2)cc1]

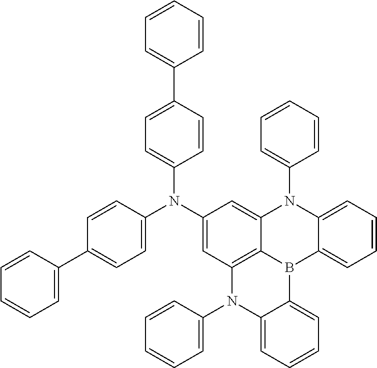 [SMILES: c1ccc(-c2ccc(N(c3ccc(-c4ccccc4)cc3)c3cc4c5c(c3)N(c3ccccc3)c3ccccc3B5c3ccccc3N4c3ccccc3)cc2)cc1]

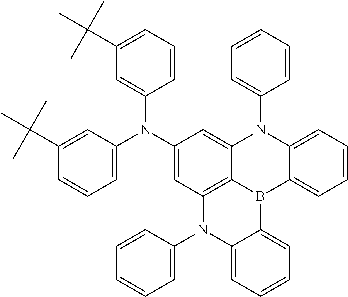 [SMILES: CC(C)(C)c1cccc(N(c2cccc(C(C)(C)C)c2)c2cc3c4c(c2)N(c2ccccc2)c2ccccc2B4c2ccccc2N3c2ccccc2)c1]

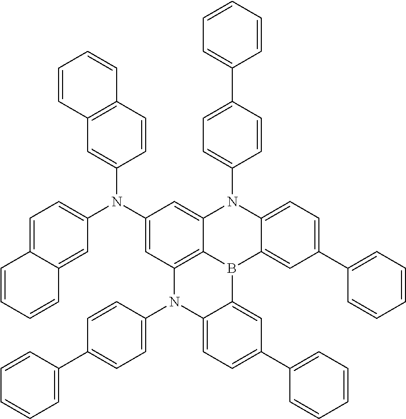 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6ccc7ccccc7c6)c6ccc7ccccc7c6)cc3c54)cc2)cc1]

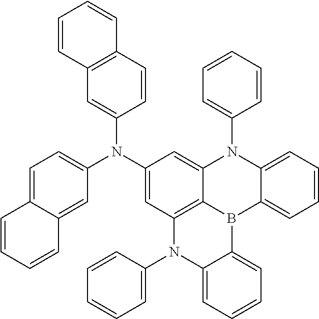 [SMILES: c1ccc(N2c3ccccc3B3c4ccccc4N(c4ccccc4)c4cc(N(c5ccc6ccccc6c5)c5ccc6ccccc6c5)cc2c43)cc1]

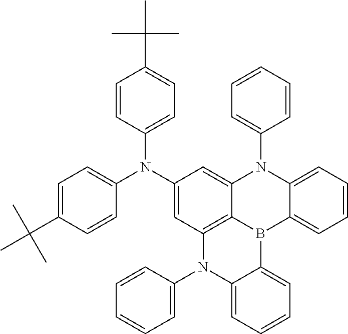 [SMILES: CC(C)(C)c1ccc(N(c2ccc(C(C)(C)C)cc2)c2cc3c4c(c2)N(c2ccccc2)c2ccccc2B4c2ccccc2N3c2ccccc2)cc1]

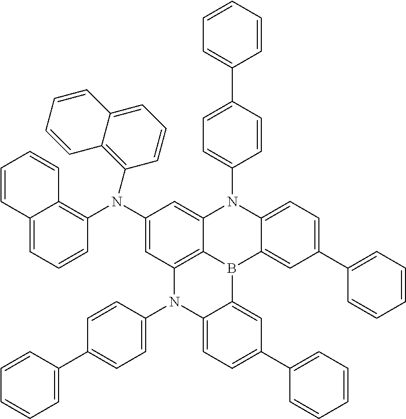 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6cccc7ccccc67)c6cccc7ccccc67)cc3c54)cc2)cc1]

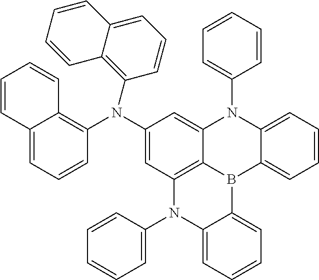 [SMILES: c1ccc(N2c3ccccc3B3c4ccccc4N(c4ccccc4)c4cc(N(c5cccc6ccccc56)c5cccc6ccccc56)cc2c43)cc1]

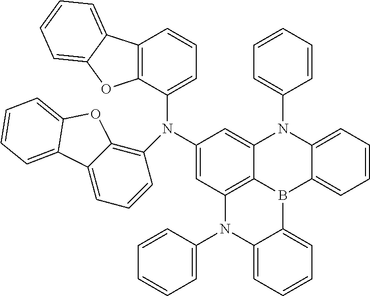 [SMILES: c1ccc(N2c3ccccc3B3c4ccccc4N(c4ccccc4)c4cc(N(c5cccc6c5oc5ccccc56)c5cccc6c5oc5ccccc56)cc2c43)cc1]

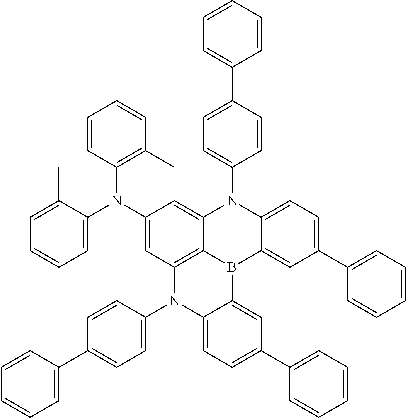 [SMILES: Cc1ccccc1N(c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1)c1ccccc1C]

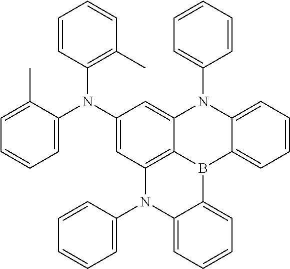 [SMILES: Cc1ccccc1N(c1cc2c3c(c1)N(c1ccccc1)c1ccccc1B3c1ccccc1N2c1ccccc1)c1ccccc1C]

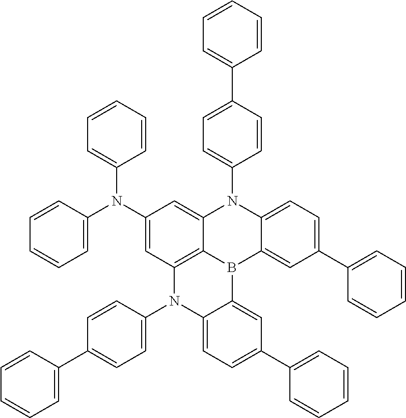 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6ccccc6)c6ccccc6)cc3c54)cc2)cc1]

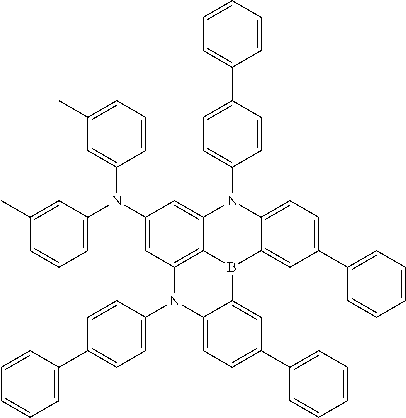 [SMILES: Cc1cccc(N(c2cccc(C)c2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)c1]

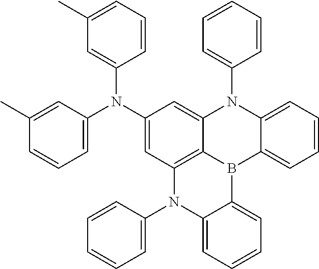 [SMILES: Cc1cccc(N(c2cccc(C)c2)c2cc3c4c(c2)N(c2ccccc2)c2ccccc2B4c2ccccc2N3c2ccccc2)c1]

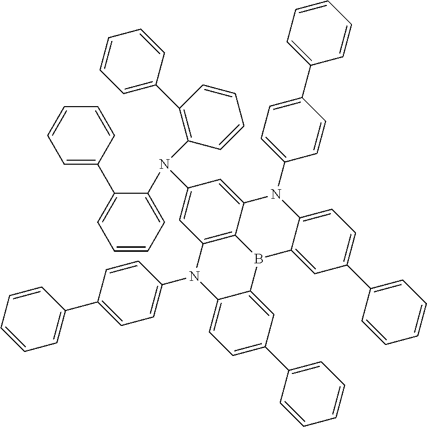 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6ccccc6-c6ccccc6)c6ccccc6-c6ccccc6)cc3c54)cc2)cc1]

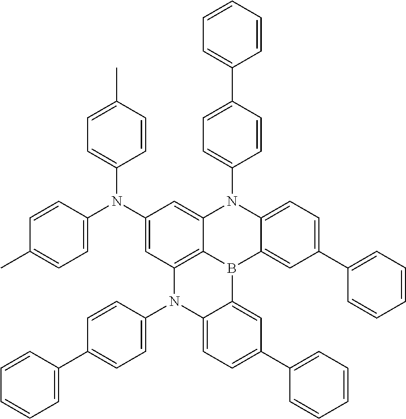 [SMILES: Cc1ccc(N(c2ccc(C)cc2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)cc1]

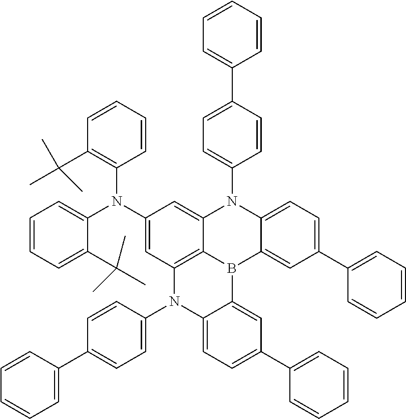 [SMILES: CC(C)(C)c1ccccc1N(c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1)c1ccccc1C(C)(C)C]

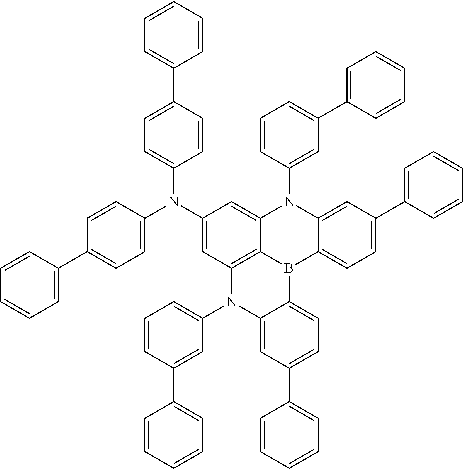 [SMILES: c1ccc(-c2ccc(N(c3ccc(-c4ccccc4)cc3)c3cc4c5c(c3)N(c3cccc(-c6ccccc6)c3)c3cc(-c6ccccc6)ccc3B5c3ccc(-c5ccccc5)cc3N4c3cccc(-c4ccccc4)c3)cc2)cc1]

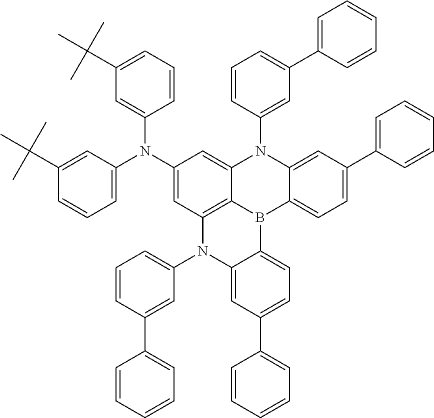 [SMILES: CC(C)(C)c1cccc(N(c2cccc(C(C)(C)C)c2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)c1]

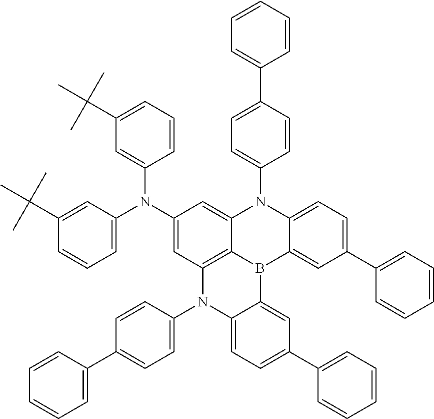 [SMILES: CC(C)(C)c1cccc(N(c2cccc(C(C)(C)C)c2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)c1]

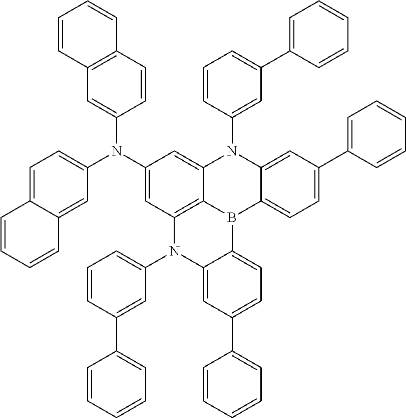 [SMILES: c1ccc(-c2cccc(N3c4cc(-c5ccccc5)ccc4B4c5ccc(-c6ccccc6)cc5N(c5cccc(-c6ccccc6)c5)c5cc(N(c6ccc7ccccc7c6)c6ccc7ccccc7c6)cc3c54)c2)cc1]

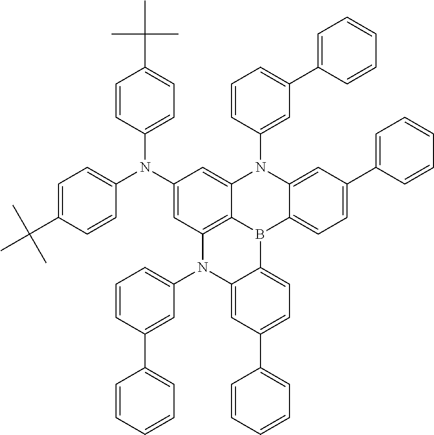 [SMILES: CC(C)(C)c1ccc(N(c2ccc(C(C)(C)C)cc2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)cc1]

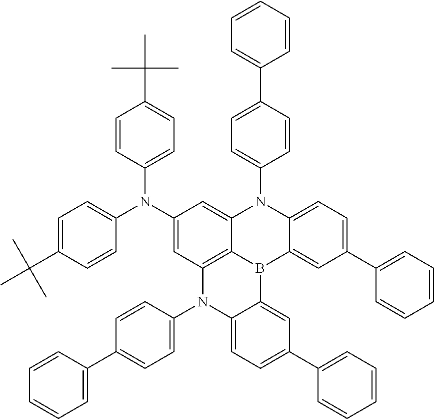 [SMILES: CC(C)(C)c1ccc(N(c2ccc(C(C)(C)C)cc2)c2cc3c4c(c2)N(c2ccc(-c5ccccc5)cc2)c2ccc(-c5ccccc5)cc2B4c2cc(-c4ccccc4)ccc2N3c2ccc(-c3ccccc3)cc2)cc1]

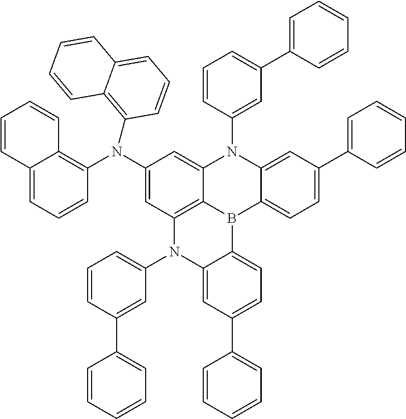 [SMILES: c1ccc(-c2cccc(N3c4cc(-c5ccccc5)ccc4B4c5ccc(-c6ccccc6)cc5N(c5cccc(-c6ccccc6)c5)c5cc(N(c6cccc7ccccc67)c6cccc7ccccc67)cc3c54)c2)cc1]

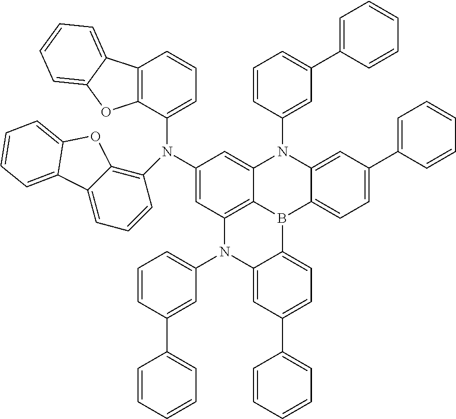 [SMILES: c1ccc(-c2cccc(N3c4cc(-c5ccccc5)ccc4B4c5ccc(-c6ccccc6)cc5N(c5cccc(-c6ccccc6)c5)c5cc(N(c6cccc7c6oc6ccccc67)c6cccc7c6oc6ccccc67)cc3c54)c2)cc1]

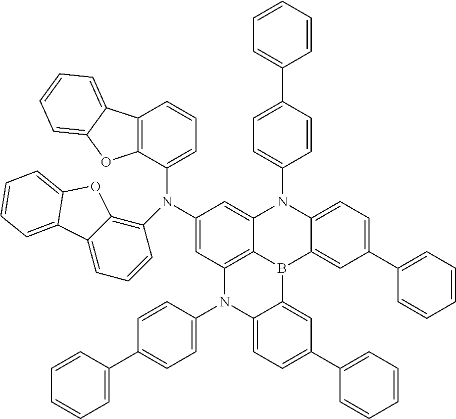 [SMILES: c1ccc(-c2ccc(N3c4ccc(-c5ccccc5)cc4B4c5cc(-c6ccccc6)ccc5N(c5ccc(-c6ccccc6)cc5)c5cc(N(c6cccc7c6oc6ccccc67)c6cccc7c6oc6ccccc67)cc3c54)cc2)cc1]

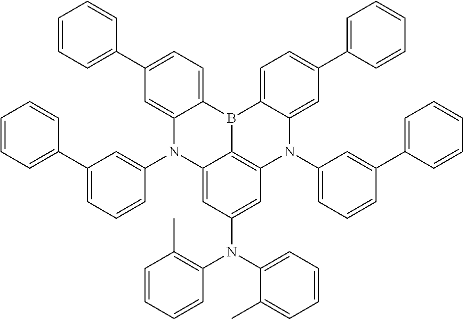 [SMILES: Cc1ccccc1N(c1cc2c3c(c1)N(c1cccc(-c4ccccc4)c1)c1cc(-c4ccccc4)ccc1B3c1ccc(-c3ccccc3)cc1N2c1cccc(-c2ccccc2)c1)c1ccccc1C]

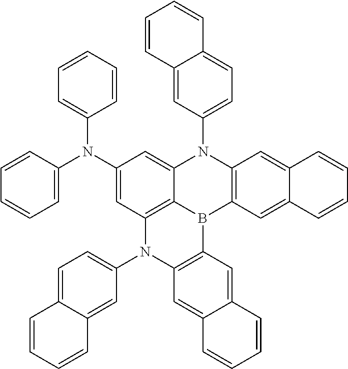 [SMILES: c1ccc(N(c2ccccc2)c2cc3c4c(c2)N(c2ccc5ccccc5c2)c2cc5ccccc5cc2B4c2cc4ccccc4cc2N3c2ccc3ccccc3c2)cc1]

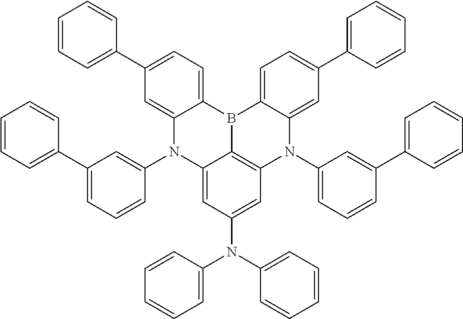 [SMILES: c1ccc(-c2cccc(N3c4cc(-c5ccccc5)ccc4B4c5ccc(-c6ccccc6)cc5N(c5cccc(-c6ccccc6)c5)c5cc(N(c6ccccc6)c6ccccc6)cc3c54)c2)cc1]

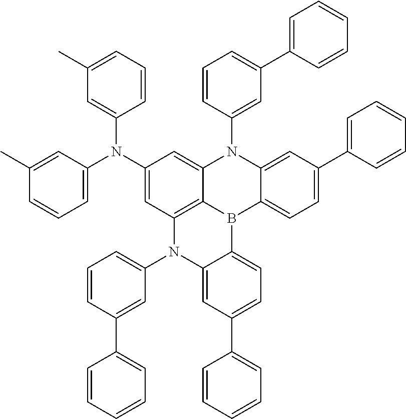 [SMILES: Cc1cccc(N(c2cccc(C)c2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)c1]

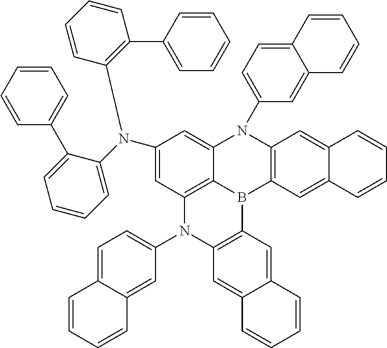 [SMILES: c1ccc(-c2ccccc2N(c2cc3c4c(c2)N(c2ccc5ccccc5c2)c2cc5ccccc5cc2B4c2cc4ccccc4cc2N3c2ccc3ccccc3c2)c2ccccc2-c2ccccc2)cc1]

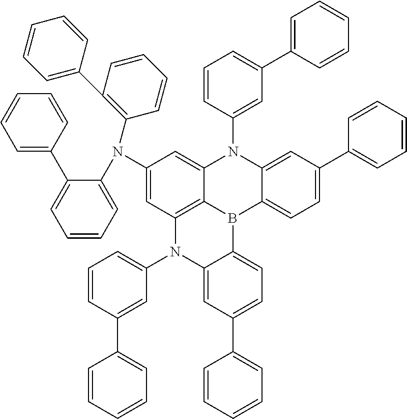 [SMILES: c1ccc(-c2cccc(N3c4cc(-c5ccccc5)ccc4B4c5ccc(-c6ccccc6)cc5N(c5cccc(-c6ccccc6)c5)c5cc(N(c6ccccc6-c6ccccc6)c6ccccc6-c6ccccc6)cc3c54)c2)cc1]

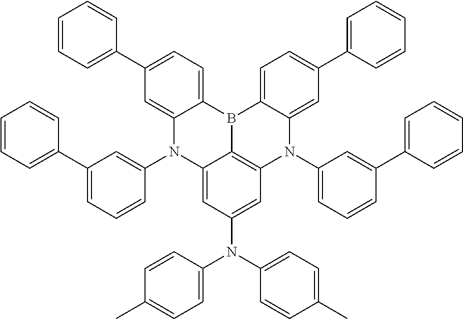 [SMILES: Cc1ccc(N(c2ccc(C)cc2)c2cc3c4c(c2)N(c2cccc(-c5ccccc5)c2)c2cc(-c5ccccc5)ccc2B4c2ccc(-c4ccccc4)cc2N3c2cccc(-c3ccccc3)c2)cc1]

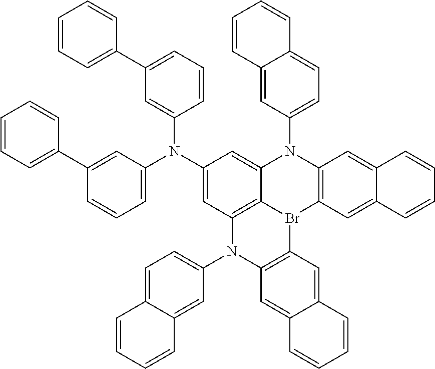

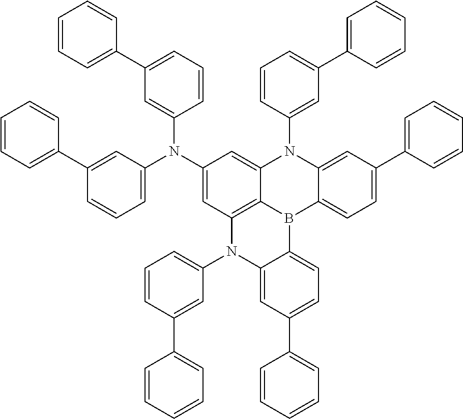 [SMILES: c1ccc(-c2cccc(N(c3cccc(-c4ccccc4)c3)c3cc4c5c(c3)N(c3cccc(-c6ccccc6)c3)c3cc(-c6ccccc6)ccc3B5c3ccc(-c5ccccc5)cc3N4c3cccc(-c4ccccc4)c3)c2)cc1]

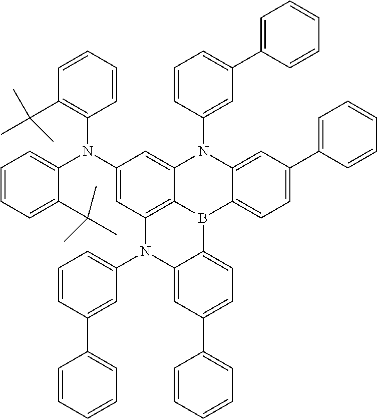 [SMILES: CC(C)(C)c1ccccc1N(c1cc2c3c(c1)N(c1cccc(-c4ccccc4)c1)c1cc(-c4ccccc4)ccc1B3c1ccc(-c3ccccc3)cc1N2c1cccc(-c2ccccc2)c1)c1ccccc1C(C)(C)C]

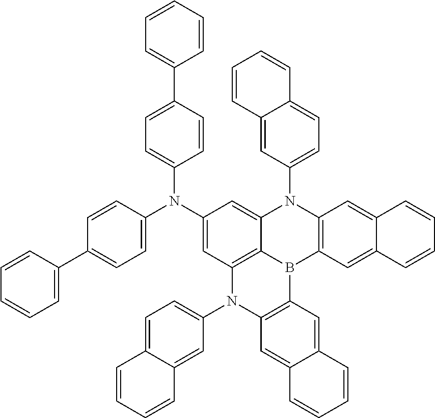 [SMILES: c1ccc(-c2ccc(N(c3ccc(-c4ccccc4)cc3)c3cc4c5c(c3)N(c3ccc6ccccc6c3)c3cc6ccccc6cc3B5c3cc5ccccc5cc3N4c3ccc4ccccc4c3)cc2)cc1]

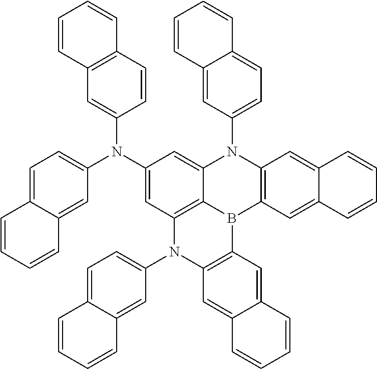 [SMILES: c1ccc2cc(N(c3cc4c5c(c3)N(c3ccc6ccccc6c3)c3cc6ccccc6cc3B5c3cc5ccccc5cc3N4c3ccc4ccccc4c3)c3ccc4ccccc4c3)ccc2c1]

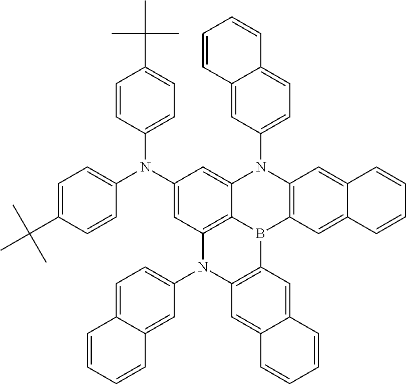 [SMILES: CC(C)(C)c1ccc(N(c2ccc(C(C)(C)C)cc2)c2cc3c4c(c2)N(c2ccc5ccccc5c2)c2cc5ccccc5cc2B4c2cc4ccccc4cc2N3c2ccc3ccccc3c2)cc1]

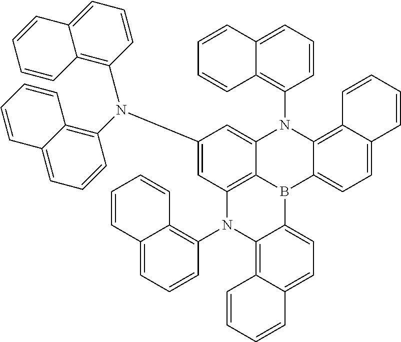 [SMILES: c1ccc2c(N(c3cc4c5c(c3)N(c3cccc6ccccc36)c3c(ccc6ccccc36)B5c3ccc5ccccc5c3N4c3cccc4ccccc34)c3cccc4ccccc34)cccc2c1]

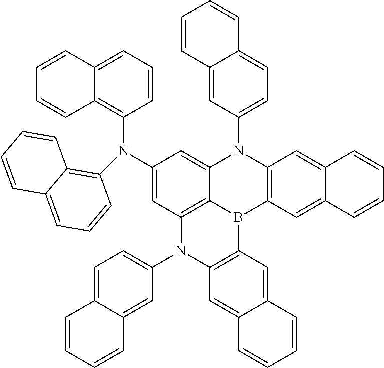 [SMILES: c1ccc2cc(N3c4cc5ccccc5cc4B4c5cc6ccccc6cc5N(c5ccc6ccccc6c5)c5cc(N(c6cccc7ccccc67)c6cccc7ccccc67)cc3c54)ccc2c1]

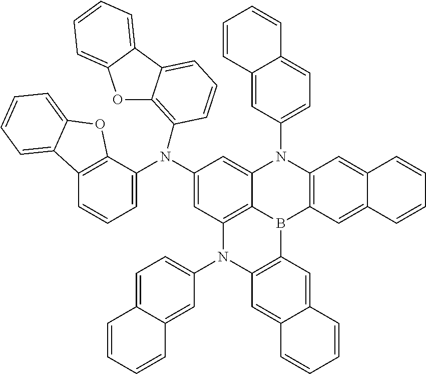 [SMILES: c1ccc2cc(N3c4cc5ccccc5cc4B4c5cc6ccccc6cc5N(c5ccc6ccccc6c5)c5cc(N(c6cccc7c6oc6ccccc67)c6cccc7c6oc6ccccc67)cc3c54)ccc2c1]

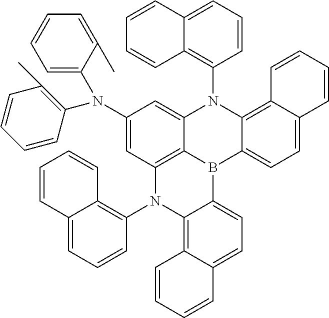 [SMILES: Cc1ccccc1N(c1cc2c3c(c1)N(c1cccc4ccccc14)c1c(ccc4ccccc14)B3c1ccc3ccccc3c1N2c1cccc2ccccc12)c1ccccc1C]

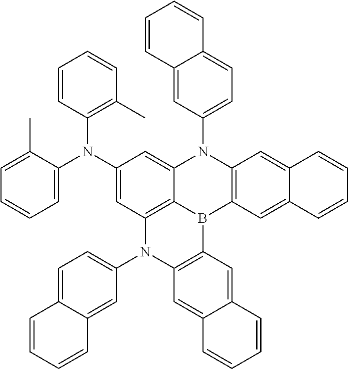 [SMILES: Cc1ccccc1N(c1cc2c3c(c1)N(c1ccc4ccccc4c1)c1cc4ccccc4cc1B3c1cc3ccccc3cc1N2c1ccc2ccccc2c1)c1ccccc1C]

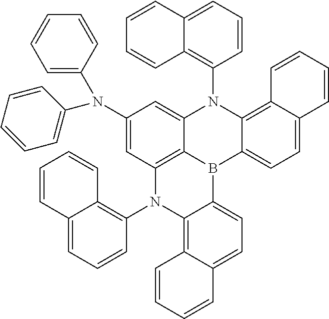 [SMILES: c1ccc(N(c2ccccc2)c2cc3c4c(c2)N(c2cccc5ccccc25)c2c(ccc5ccccc25)B4c2ccc4ccccc4c2N3c2cccc3ccccc23)cc1]

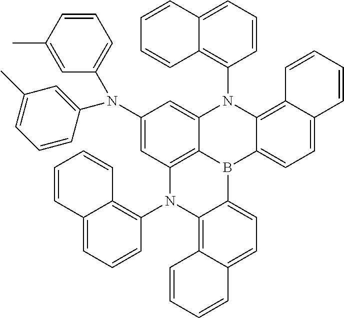 [SMILES: Cc1cccc(N(c2cccc(C)c2)c2cc3c4c(c2)N(c2cccc5ccccc25)c2c(ccc5ccccc25)B4c2ccc4ccccc4c2N3c2cccc3ccccc23)c1]

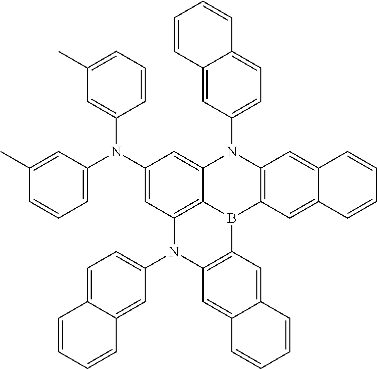 [SMILES: Cc1cccc(N(c2cccc(C)c2)c2cc3c4c(c2)N(c2ccc5ccccc5c2)c2cc5ccccc5cc2B4c2cc4ccccc4cc2N3c2ccc3ccccc3c2)c1]

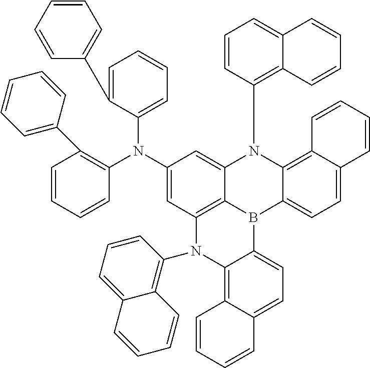 [SMILES: c1ccc(-c2ccccc2N(c2cc3c4c(c2)N(c2cccc5ccccc25)c2c(ccc5ccccc25)B4c2ccc4ccccc4c2N3c2cccc3ccccc23)c2ccccc2-c2ccccc2)cc1]

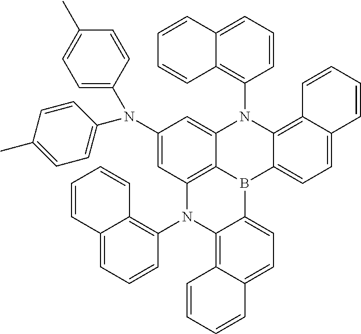 [SMILES: Cc1ccc(N(c2ccc(C)cc2)c2cc3c4c(c2)N(c2cccc5ccccc25)c2c(ccc5ccccc25)B4c2ccc4ccccc4c2N3c2cccc3ccccc23)cc1]

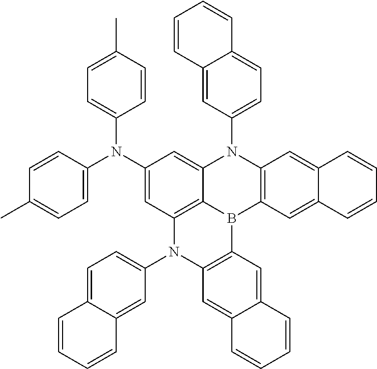 [SMILES: Cc1ccc(N(c2ccc(C)cc2)c2cc3c4c(c2)N(c2ccc5ccccc5c2)c2cc5ccccc5cc2B4c2cc4ccccc4cc2N3c2ccc3ccccc3c2)cc1]

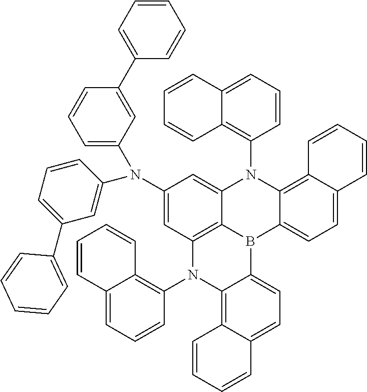 [SMILES: c1ccc(-c2cccc(N(c3cccc(-c4ccccc4)c3)c3cc4c5c(c3)N(c3cccc6ccccc36)c3c(ccc6ccccc36)B5c3ccc5ccccc5c3N4c3cccc4ccccc34)c2)cc1]

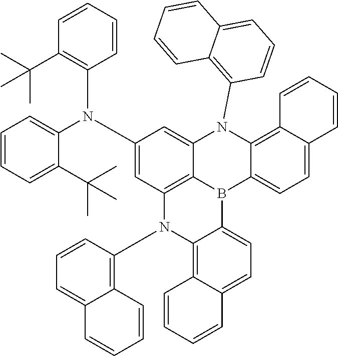 [SMILES: CC(C)(C)c1ccccc1N(c1cc2c3c(c1)N(c1cccc4ccccc14)c1c(ccc4ccccc14)B3c1ccc3ccccc3c1N2c1cccc2ccccc12)c1ccccc1C(C)(C)C]

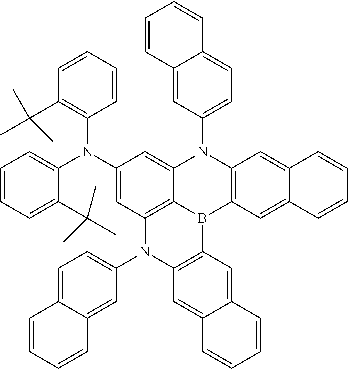 [SMILES: CC(C)(C)c1ccccc1N(c1cc2c3c(c1)N(c1ccc4ccccc4c1)c1cc4ccccc4cc1B3c1cc3ccccc3cc1N2c1ccc2ccccc2c1)c1ccccc1C(C)(C)C]

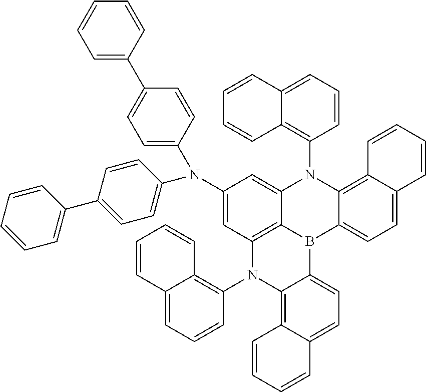 [SMILES: c1ccc(-c2ccc(N(c3ccc(-c4ccccc4)cc3)c3cc4c5c(c3)N(c3cccc6ccccc36)c3c(ccc6ccccc36)B5c3ccc5ccccc5c3N4c3cccc4ccccc34)cc2)cc1]

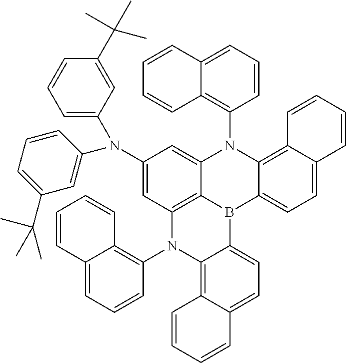 [SMILES: CC(C)(C)c1cccc(N(c2cccc(C(C)(C)C)c2)c2cc3c4c(c2)N(c2cccc5ccccc25)c2c(ccc5ccccc25)B4c2ccc4ccccc4c2N3c2cccc3ccccc23)c1]

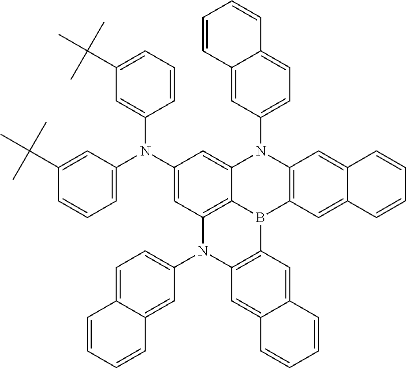 [SMILES: CC(C)(C)c1cccc(N(c2cccc(C(C)(C)C)c2)c2cc3c4c(c2)N(c2ccc5ccccc5c2)c2cc5ccccc5cc2B4c2cc4ccccc4cc2N3c2ccc3ccccc3c2)c1]

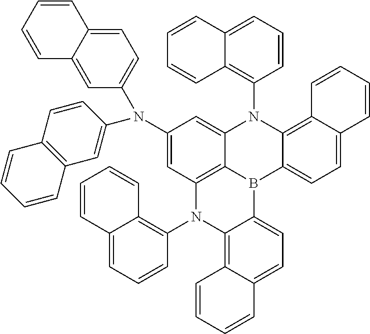 [SMILES: c1ccc2cc(N(c3cc4c5c(c3)N(c3cccc6ccccc36)c3c(ccc6ccccc36)B5c3ccc5ccccc5c3N4c3cccc4ccccc34)c3ccc4ccccc4c3)ccc2c1]

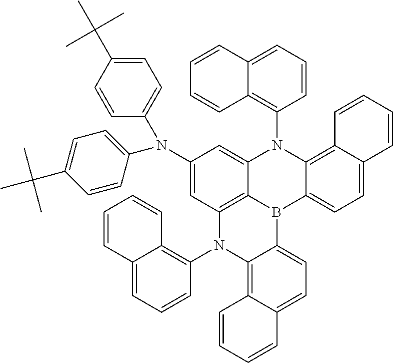 [SMILES: CC(C)(C)c1ccc(N(c2ccc(C(C)(C)C)cc2)c2cc3c4c(c2)N(c2cccc5ccccc25)c2c(ccc5ccccc25)B4c2ccc4ccccc4c2N3c2cccc3ccccc23)cc1]

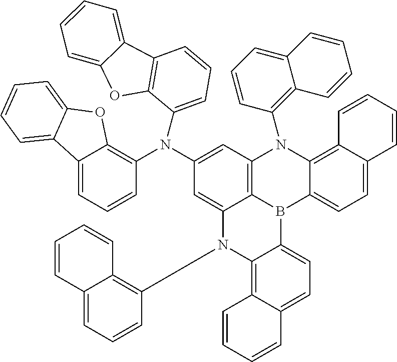 [SMILES: c1ccc2c(N3c4cc(N(c5cccc6c5oc5ccccc56)c5cccc6c5oc5ccccc56)cc5c4B(c4ccc6ccccc6c43)c3ccc4ccccc4c3N5c3cccc4ccccc34)cccc2c1]

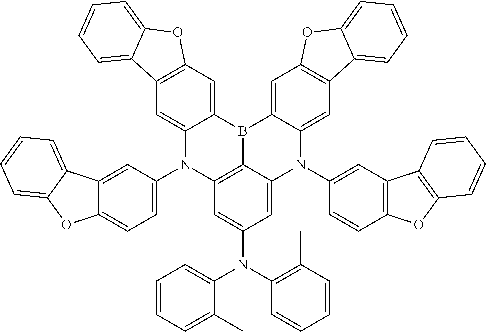 [SMILES: Cc1ccccc1N(c1cc2c3c(c1)N(c1ccc4oc5ccccc5c4c1)c1cc4c(cc1B3c1cc3oc5ccccc5c3cc1N2c1ccc2oc3ccccc3c2c1)oc1ccccc14)c1ccccc1C]

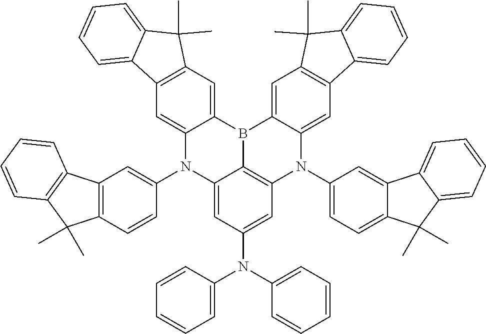 [SMILES: CC1(C)c2ccccc2-c2cc(N3c4cc5c(cc4B4c6cc7c(cc6N(c6ccc8c(c6)-c6ccccc6C8(C)C)c6cc(N(c8ccccc8)c8ccccc8)cc3c64)-c3ccccc3C7(C)C)C(C)(C)c3ccccc3-5)ccc21]

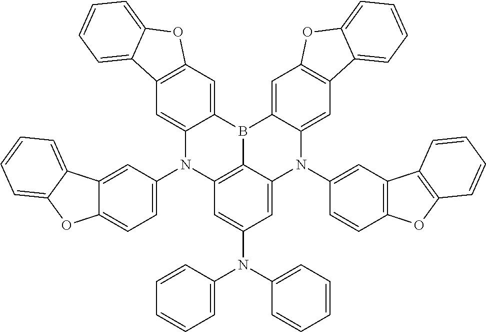 [SMILES: c1ccc(N(c2ccccc2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)cc1]

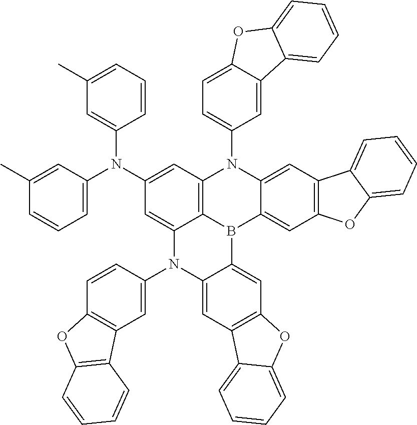 [SMILES: Cc1cccc(N(c2cccc(C)c2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)c1]

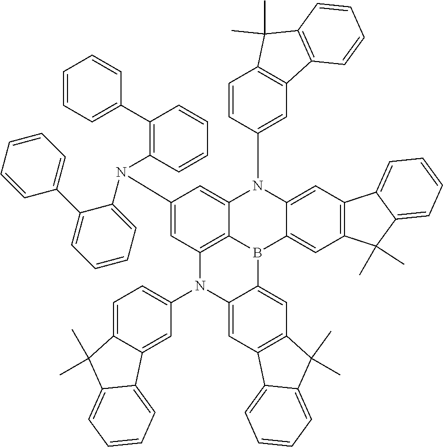 [SMILES: CC1(C)c2ccccc2-c2cc(N3c4cc5c(cc4B4c6cc7c(cc6N(c6ccc8c(c6)-c6ccccc6C8(C)C)c6cc(N(c8ccccc8-c8ccccc8)c8ccccc8-c8ccccc8)cc3c64)-c3ccccc3C7(C)C)C(C)(C)c3ccccc3-5)ccc21]

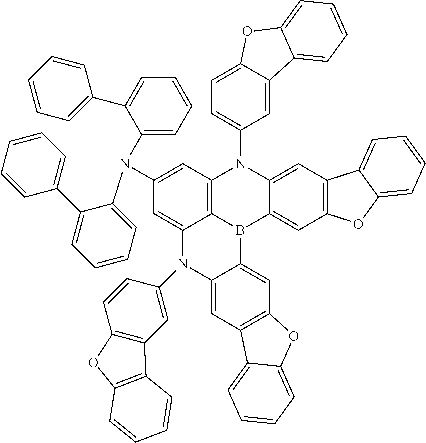 [SMILES: c1ccc(-c2ccccc2N(c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)c2ccccc2-c2ccccc2)cc1]

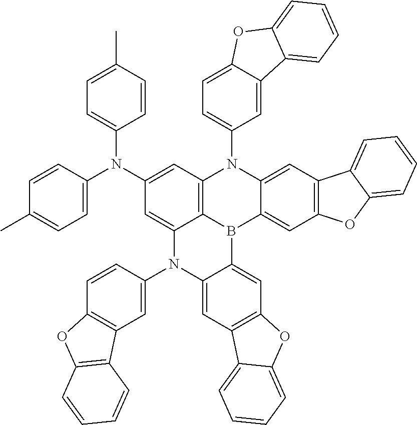 [SMILES: Cc1ccc(N(c2ccc(C)cc2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)cc1]

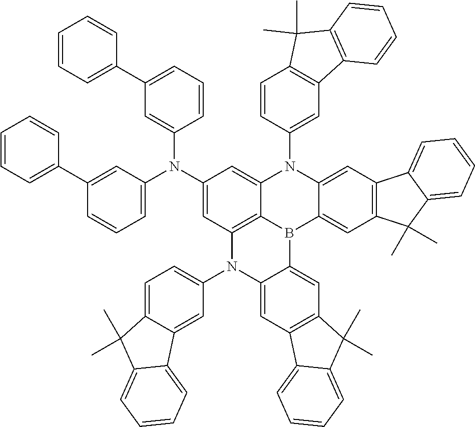 [SMILES: CC1(C)c2ccccc2-c2cc(N3c4cc5c(cc4B4c6cc7c(cc6N(c6ccc8c(c6)-c6ccccc6C8(C)C)c6cc(N(c8cccc(-c9ccccc9)c8)c8cccc(-c9ccccc9)c8)cc3c64)-c3ccccc3C7(C)C)C(C)(C)c3ccccc3-5)ccc21]

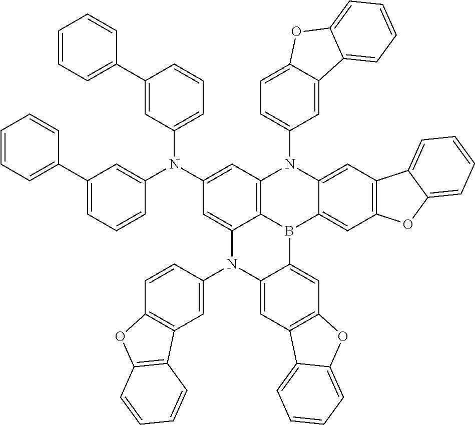 [SMILES: c1ccc(-c2cccc(N(c3cccc(-c4ccccc4)c3)c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)c2)cc1]

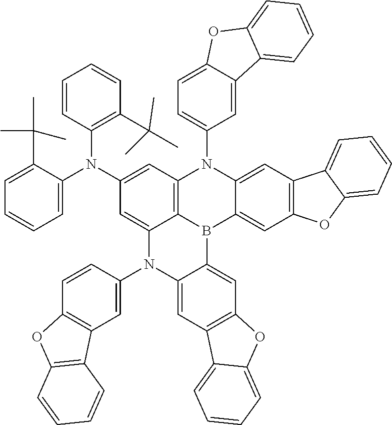 [SMILES: CC(C)(C)c1ccccc1N(c1cc2c3c(c1)N(c1ccc4oc5ccccc5c4c1)c1cc4c(cc1B3c1cc3oc5ccccc5c3cc1N2c1ccc2oc3ccccc3c2c1)oc1ccccc14)c1ccccc1C(C)(C)C]

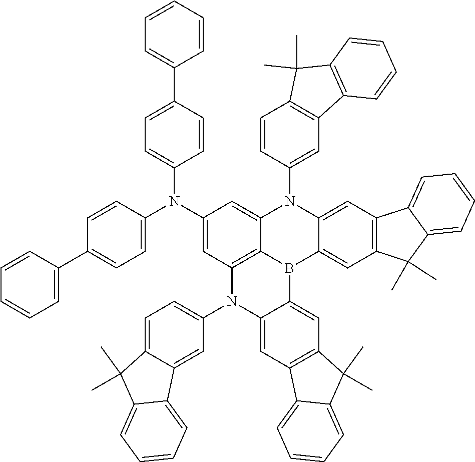 [SMILES: CC1(C)c2ccccc2-c2cc(N3c4cc5c(cc4B4c6cc7c(cc6N(c6ccc8c(c6)-c6ccccc6C8(C)C)c6cc(N(c8ccc(-c9ccccc9)cc8)c8ccc(-c9ccccc9)cc8)cc3c64)-c3ccccc3C7(C)C)C(C)(C)c3ccccc3-5)ccc21]

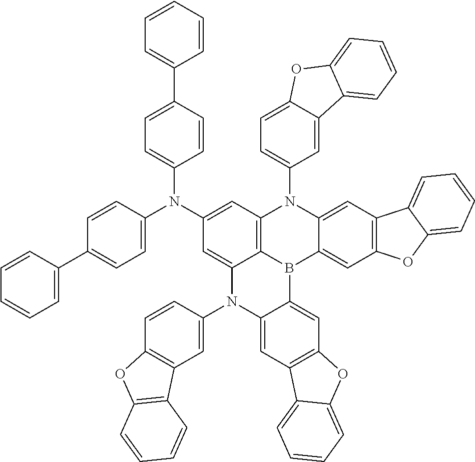 [SMILES: c1ccc(-c2ccc(N(c3ccc(-c4ccccc4)cc3)c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)cc2)cc1]

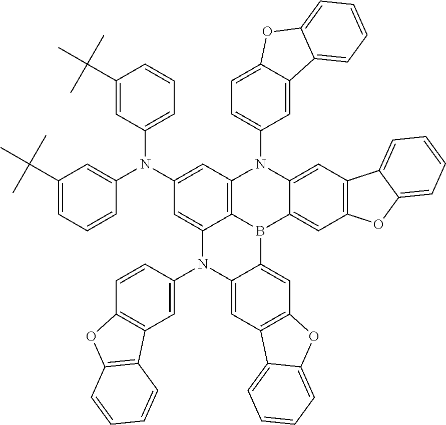 [SMILES: CC(C)(C)c1cccc(N(c2cccc(C(C)(C)C)c2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)c1]

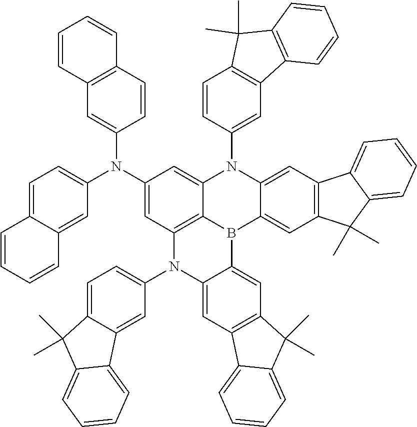 [SMILES: CC1(C)c2ccccc2-c2cc(N3c4cc5c(cc4B4c6cc7c(cc6N(c6ccc8c(c6)-c6ccccc6C8(C)C)c6cc(N(c8ccc9ccccc9c8)c8ccc9ccccc9c8)cc3c64)-c3ccccc3C7(C)C)C(C)(C)c3ccccc3-5)ccc21]

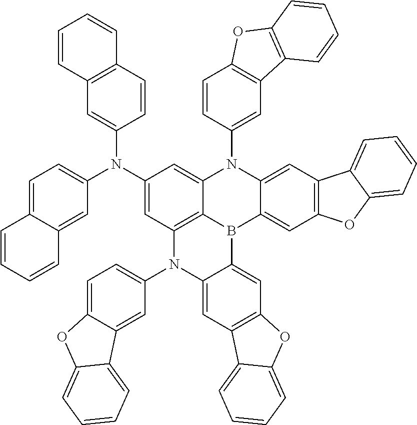 [SMILES: c1ccc2cc(N(c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)c3ccc4ccccc4c3)ccc2c1]

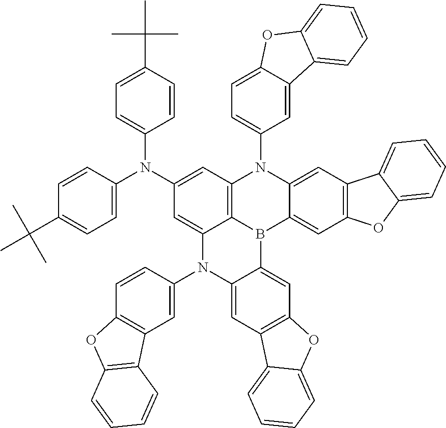 [SMILES: CC(C)(C)c1ccc(N(c2ccc(C(C)(C)C)cc2)c2cc3c4c(c2)N(c2ccc5oc6ccccc6c5c2)c2cc5c(cc2B4c2cc4oc6ccccc6c4cc2N3c2ccc3oc4ccccc4c3c2)oc2ccccc25)cc1]

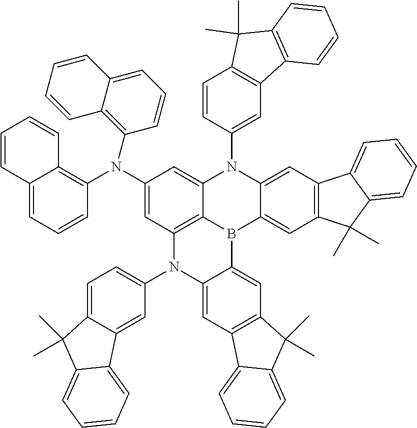 [SMILES: CC1(C)c2ccccc2-c2cc(N3c4cc5c(cc4B4c6cc7c(cc6N(c6ccc8c(c6)-c6ccccc6C8(C)C)c6cc(N(c8cccc9ccccc89)c8cccc9ccccc89)cc3c64)-c3ccccc3C7(C)C)C(C)(C)c3ccccc3-5)ccc21]

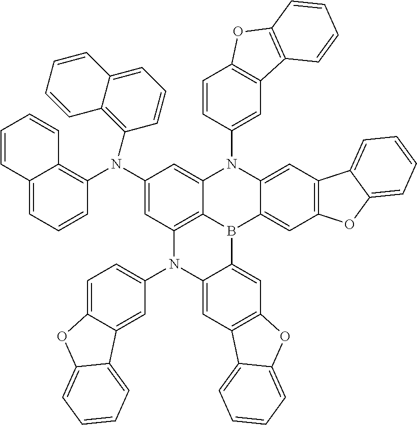 [SMILES: c1ccc2c(N(c3cc4c5c(c3)N(c3ccc6oc7ccccc7c6c3)c3cc6c(cc3B5c3cc5oc7ccccc7c5cc3N4c3ccc4oc5ccccc5c4c3)oc3ccccc36)c3cccc4ccccc34)cccc2c1]

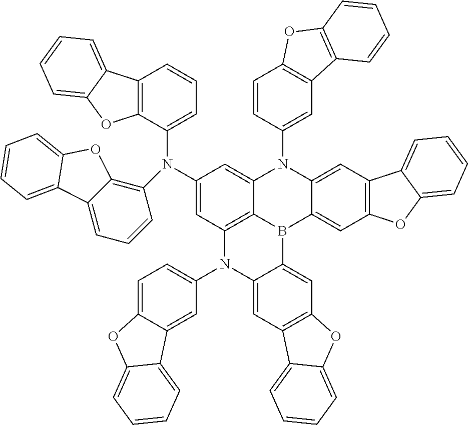 [SMILES: c1ccc2c(c1)oc1ccc(N3c4cc5c(cc4B4c6cc7oc8ccccc8c7cc6N(c6ccc7oc8ccccc8c7c6)c6cc(N(c7cccc8c7oc7ccccc78)c7cccc8c7oc7ccccc78)cc3c64)oc3ccccc35)cc12]

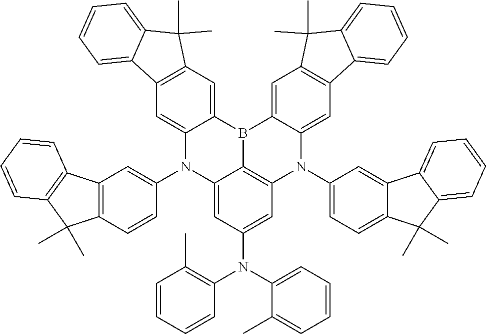 [SMILES: Cc1ccccc1N(c1cc2c3c(c1)N(c1ccc4c(c1)-c1ccccc1C4(C)C)c1cc4c(cc1B3c1cc3c(cc1N2c1ccc2c(c1)-c1ccccc1C2(C)C)-c1ccccc1C3(C)C)C(C)(C)c1ccccc1-4)c1ccccc1C]

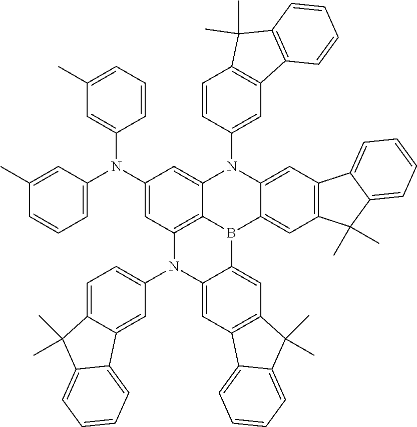 [SMILES: Cc1cccc(N(c2cccc(C)c2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)c1]

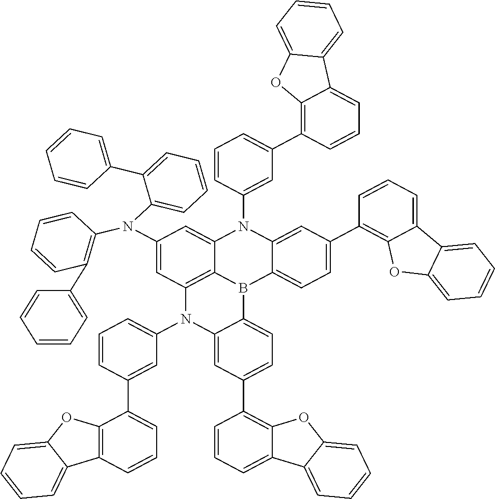 [SMILES: c1ccc(-c2ccccc2N(c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)c2ccccc2-c2ccccc2)cc1]

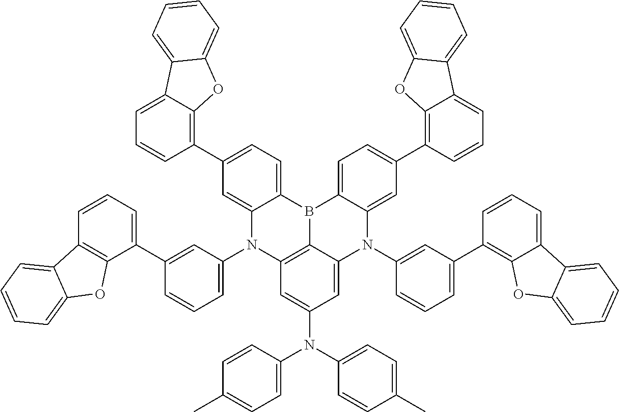 [SMILES: Cc1ccc(N(c2ccc(C)cc2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)cc1]

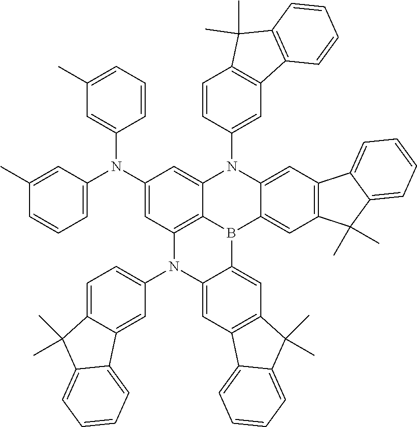 [SMILES: Cc1cccc(N(c2cccc(C)c2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)c1]

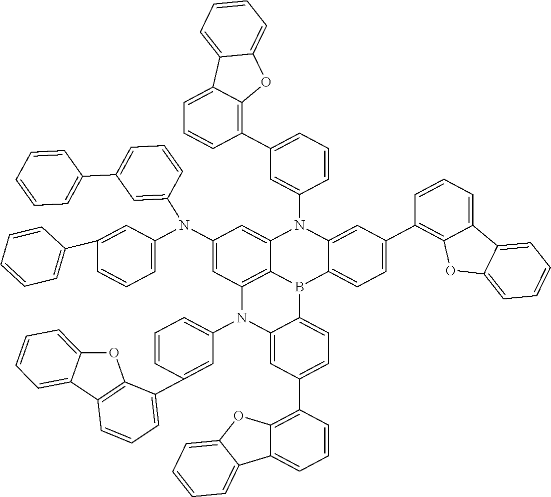 [SMILES: c1ccc(-c2cccc(N(c3cccc(-c4ccccc4)c3)c3cc4c5c(c3)N(c3cccc(-c6cccc7c6oc6ccccc67)c3)c3cc(-c6cccc7c6oc6ccccc67)ccc3B5c3ccc(-c5cccc6c5oc5ccccc56)cc3N4c3cccc(-c4cccc5c4oc4ccccc45)c3)c2)cc1]

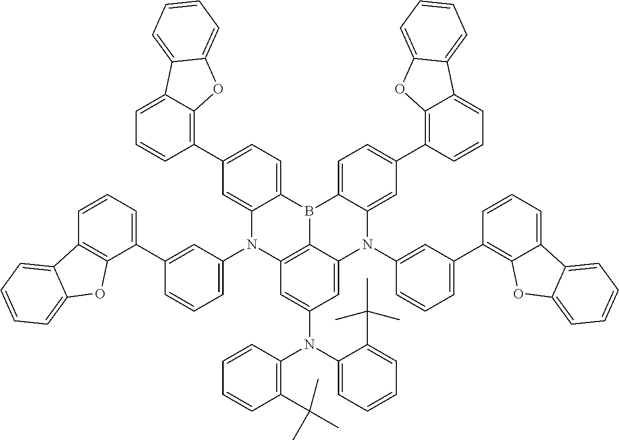 [SMILES: CC(C)(C)c1ccccc1N(c1cc2c3c(c1)N(c1cccc(-c4cccc5c4oc4ccccc45)c1)c1cc(-c4cccc5c4oc4ccccc45)ccc1B3c1ccc(-c3cccc4c3oc3ccccc34)cc1N2c1cccc(-c2cccc3c2oc2ccccc23)c1)c1ccccc1C(C)(C)C]

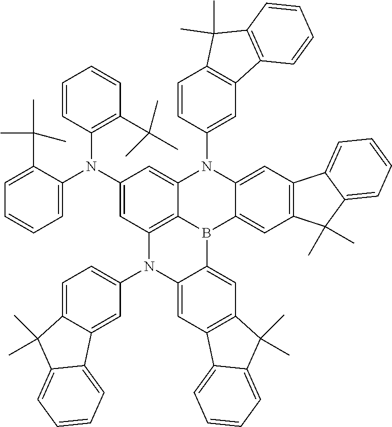 [SMILES: CC(C)(C)c1ccccc1N(c1cc2c3c(c1)N(c1ccc4c(c1)-c1ccccc1C4(C)C)c1cc4c(cc1B3c1cc3c(cc1N2c1ccc2c(c1)-c1ccccc1C2(C)C)-c1ccccc1C3(C)C)C(C)(C)c1ccccc1-4)c1ccccc1C(C)(C)C]

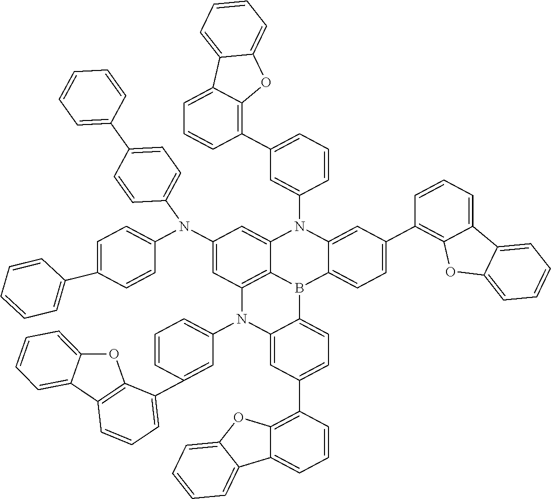 [SMILES: c1ccc(-c2ccc(N(c3ccc(-c4ccccc4)cc3)c3cc4c5c(c3)N(c3cccc(-c6cccc7c6oc6ccccc67)c3)c3cc(-c6cccc7c6oc6ccccc67)ccc3B5c3ccc(-c5cccc6c5oc5ccccc56)cc3N4c3cccc(-c4cccc5c4oc4ccccc45)c3)cc2)cc1]

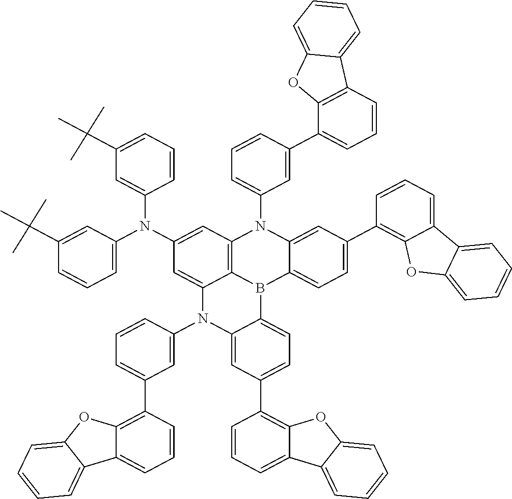 [SMILES: CC(C)(C)c1cccc(N(c2cccc(C(C)(C)C)c2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)c1]

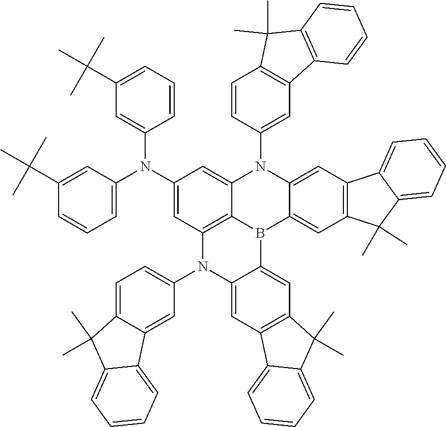 [SMILES: CC(C)(C)c1cccc(N(c2cccc(C(C)(C)C)c2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)c1]

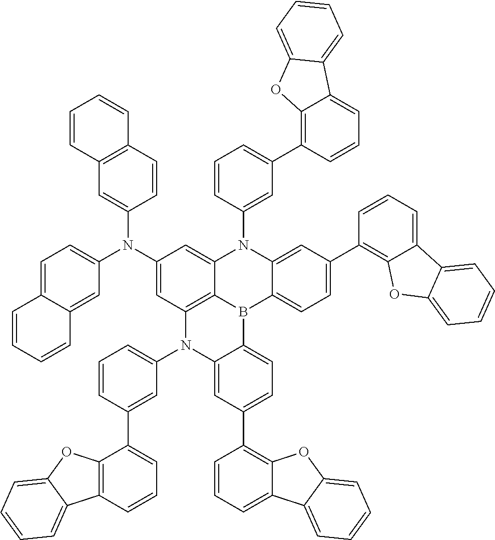 [SMILES: c1cc(-c2cccc3c2oc2ccccc23)cc(N2c3cc(-c4cccc5c4oc4ccccc45)ccc3B3c4ccc(-c5cccc6c5oc5ccccc56)cc4N(c4cccc(-c5cccc6c5oc5ccccc56)c4)c4cc(N(c5ccc6ccccc6c5)c5ccc6ccccc6c5)cc2c43)c1]

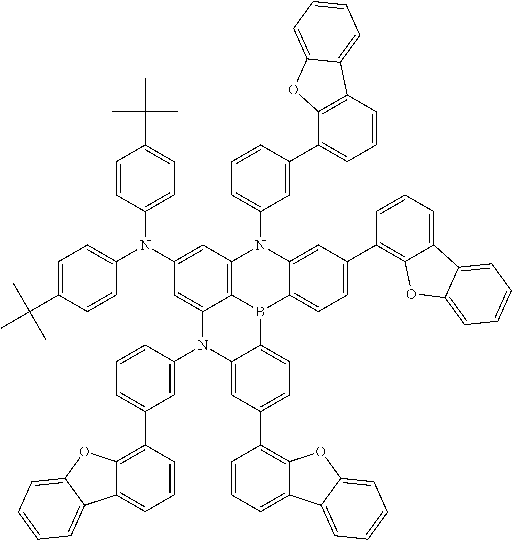 [SMILES: CC(C)(C)c1ccc(N(c2ccc(C(C)(C)C)cc2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)cc1]

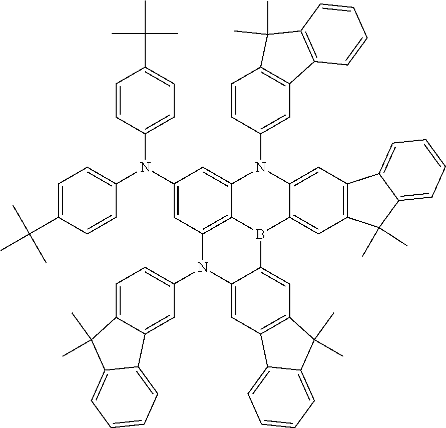 [SMILES: CC(C)(C)c1ccc(N(c2ccc(C(C)(C)C)cc2)c2cc3c4c(c2)N(c2ccc5c(c2)-c2ccccc2C5(C)C)c2cc5c(cc2B4c2cc4c(cc2N3c2ccc3c(c2)-c2ccccc2C3(C)C)-c2ccccc2C4(C)C)C(C)(C)c2ccccc2-5)cc1]

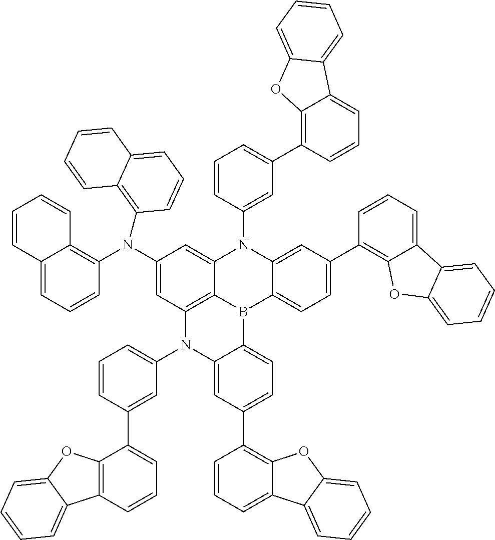 [SMILES: c1cc(-c2cccc3c2oc2ccccc23)cc(N2c3cc(-c4cccc5c4oc4ccccc45)ccc3B3c4ccc(-c5cccc6c5oc5ccccc56)cc4N(c4cccc(-c5cccc6c5oc5ccccc56)c4)c4cc(N(c5cccc6ccccc56)c5cccc6ccccc56)cc2c43)c1]

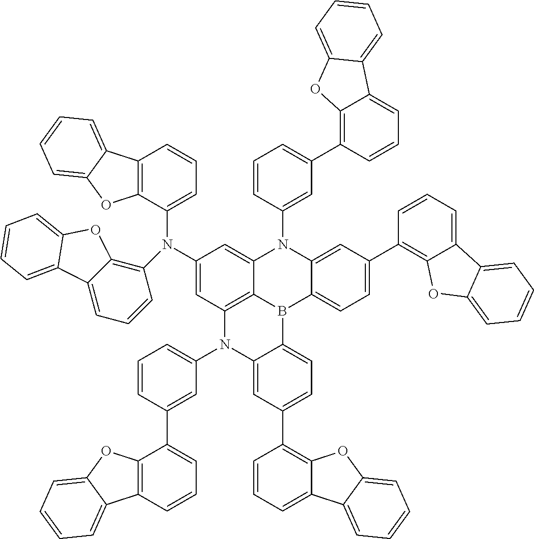 [SMILES: c1cc(-c2cccc3c2oc2ccccc23)cc(N2c3cc(-c4cccc5c4oc4ccccc45)ccc3B3c4ccc(-c5cccc6c5oc5ccccc56)cc4N(c4cccc(-c5cccc6c5oc5ccccc56)c4)c4cc(N(c5cccc6c5oc5ccccc56)c5cccc6c5oc5ccccc56)cc2c43)c1]

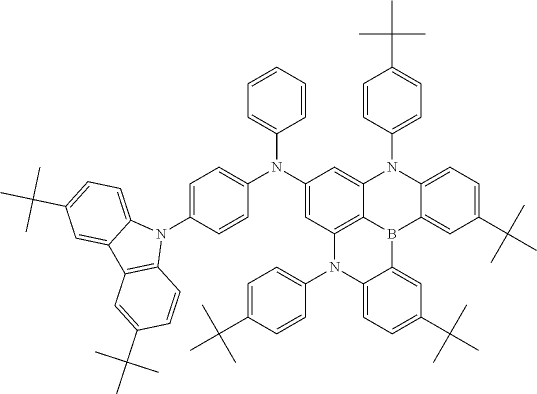 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccc(-n6c7ccc(C(C)(C)C)cc7c7cc(C(C)(C)C)ccc76)cc5)cc2c43)cc1]

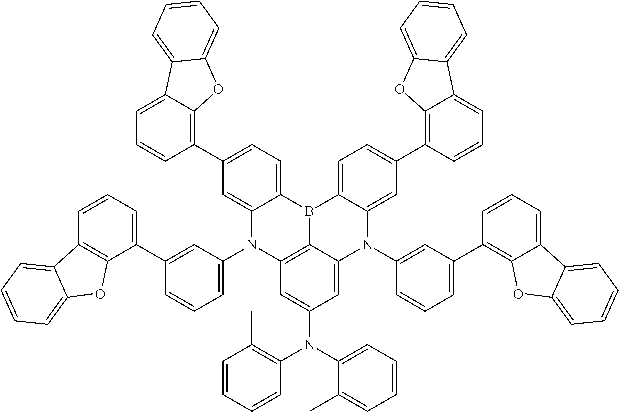 [SMILES: Cc1ccccc1N(c1cc2c3c(c1)N(c1cccc(-c4cccc5c4oc4ccccc45)c1)c1cc(-c4cccc5c4oc4ccccc45)ccc1B3c1ccc(-c3cccc4c3oc3ccccc34)cc1N2c1cccc(-c2cccc3c2oc2ccccc23)c1)c1ccccc1C]

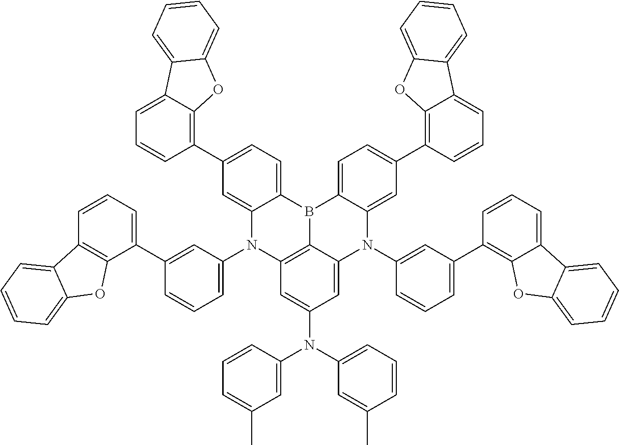 [SMILES: Cc1cccc(N(c2cccc(C)c2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)c1]

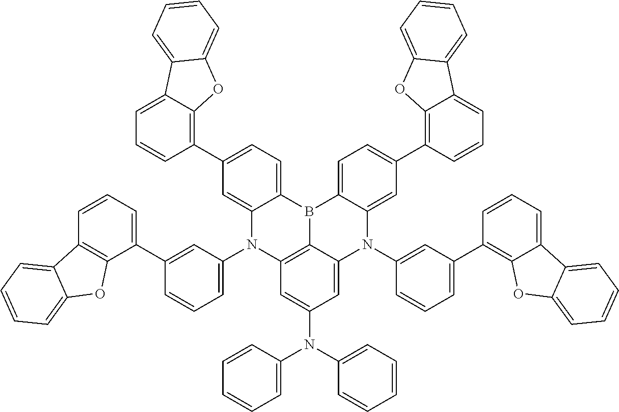 [SMILES: c1ccc(N(c2ccccc2)c2cc3c4c(c2)N(c2cccc(-c5cccc6c5oc5ccccc56)c2)c2cc(-c5cccc6c5oc5ccccc56)ccc2B4c2ccc(-c4cccc5c4oc4ccccc45)cc2N3c2cccc(-c3cccc4c3oc3ccccc34)c2)cc1]

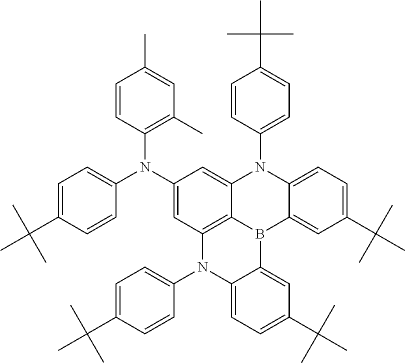 [SMILES: Cc1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c(C)c1]

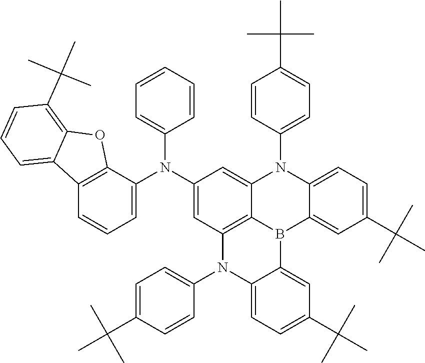 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5c(C(C)(C)C)cccc56)cc2c43)cc1]

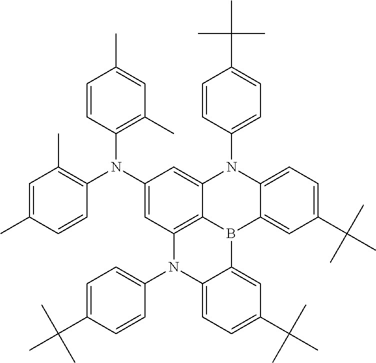 [SMILES: Cc1ccc(N(c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c2ccc(C)cc2C)c(C)c1]

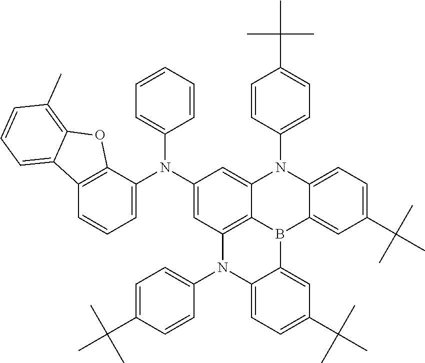 [SMILES: Cc1cccc2c1oc1c(N(c3ccccc3)c3cc4c5c(c3)N(c3ccc(C(C)(C)C)cc3)c3ccc(C(C)(C)C)cc3B5c3cc(C(C)(C)C)ccc3N4c3ccc(C(C)(C)C)cc3)cccc12]

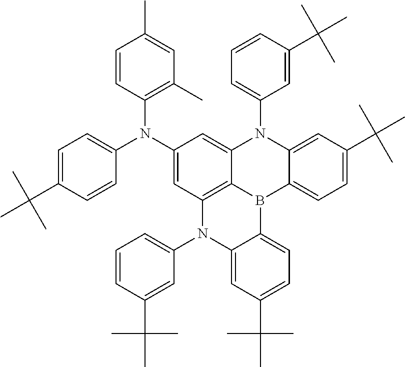 [SMILES: Cc1ccc(N(c2ccc(C(C)(C)C)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c(C)c1]

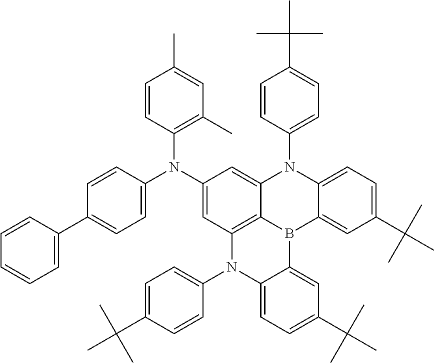 [SMILES: Cc1ccc(N(c2ccc(-c3ccccc3)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c(C)c1]

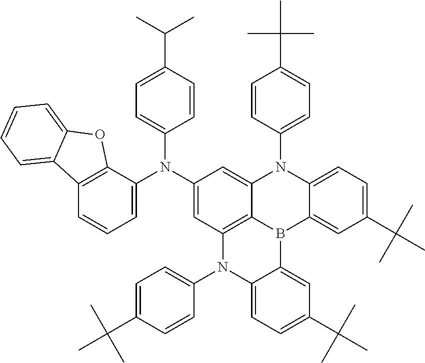 [SMILES: CC(C)c1ccc(N(c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c2cccc3c2oc2ccccc23)cc1]

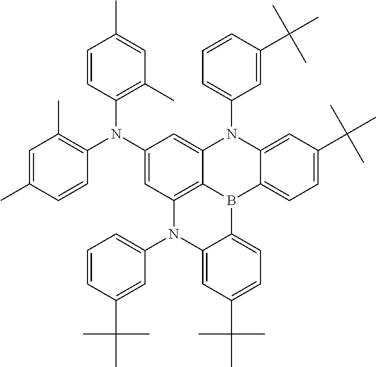 [SMILES: Cc1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2ccc(C)cc2C)c(C)c1]

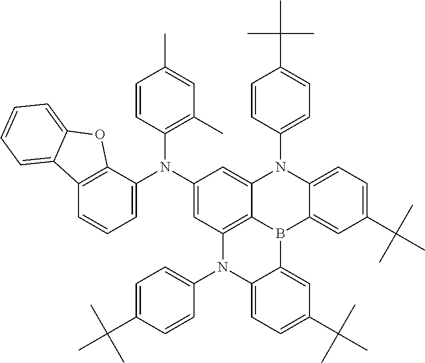 [SMILES: Cc1ccc(N(c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c2cccc3c2oc2ccccc23)c(C)c1]

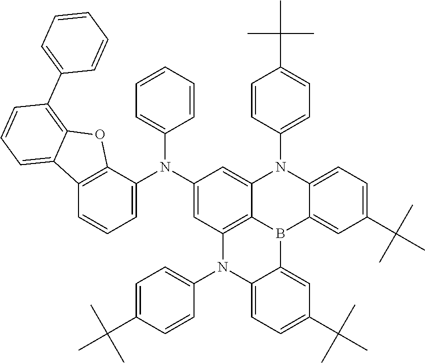 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5c(-c7ccccc7)cccc56)cc2c43)cc1]

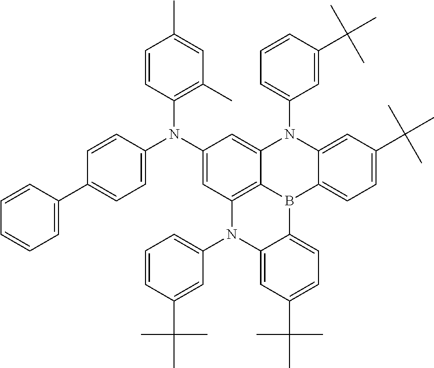 [SMILES: Cc1ccc(N(c2ccc(-c3ccccc3)cc2)c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c(C)c1]

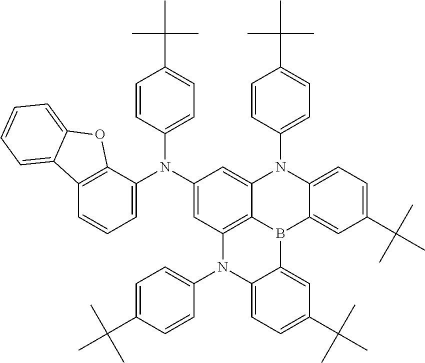 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccc(C(C)(C)C)cc5)c5cccc6c5oc5ccccc56)cc2c43)cc1]

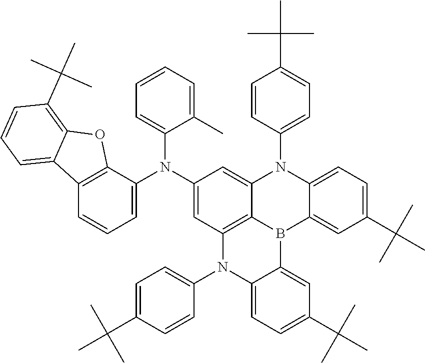 [SMILES: Cc1ccccc1N(c1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1)c1cccc2c1oc1c(C(C)(C)C)cccc12]

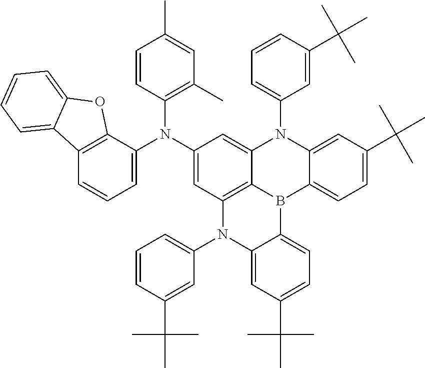 [SMILES: Cc1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2cccc3c2oc2ccccc23)c(C)c1]

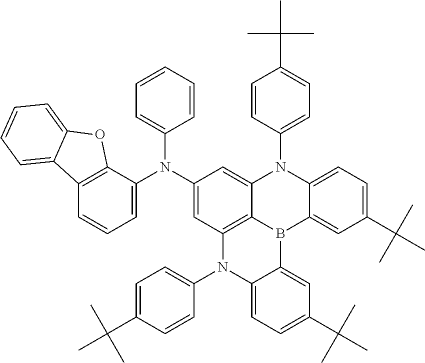 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5ccccc56)cc2c43)cc1]

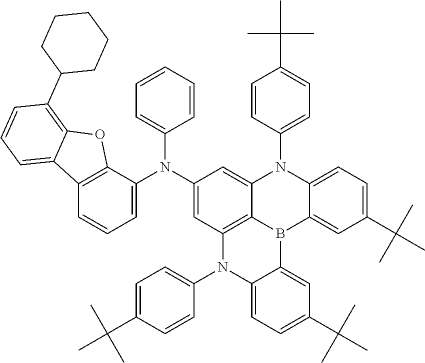 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6c5oc5c(C7CCCCC7)cccc56)cc2c43)cc1]

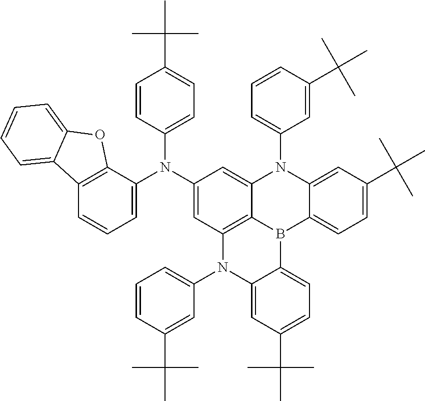 [SMILES: CC(C)(C)c1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2cccc3c2oc2ccccc23)cc1]

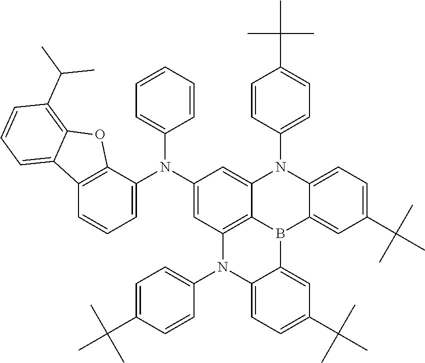 [SMILES: CC(C)c1cccc2c1oc1c(N(c3ccccc3)c3cc4c5c(c3)N(c3ccc(C(C)(C)C)cc3)c3ccc(C(C)(C)C)cc3B5c3cc(C(C)(C)C)ccc3N4c3ccc(C(C)(C)C)cc3)cccc12]

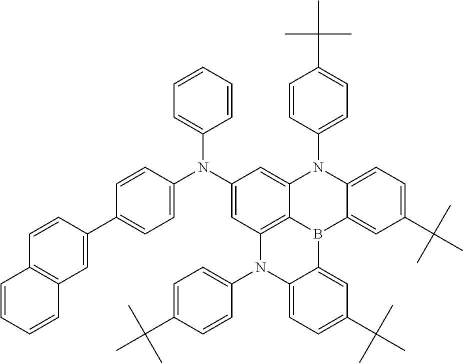 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccc(-c6ccc7ccccc7c6)cc5)cc2c43)cc1]

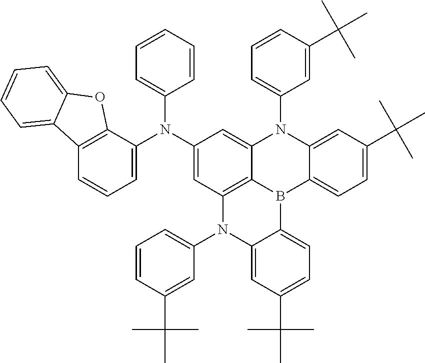 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5ccccc56)cc2c43)c1]

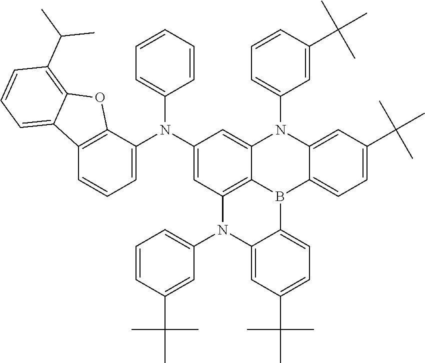 [SMILES: CC(C)c1cccc2c1oc1c(N(c3ccccc3)c3cc4c5c(c3)N(c3cccc(C(C)(C)C)c3)c3cc(C(C)(C)C)ccc3B5c3ccc(C(C)(C)C)cc3N4c3cccc(C(C)(C)C)c3)cccc12]

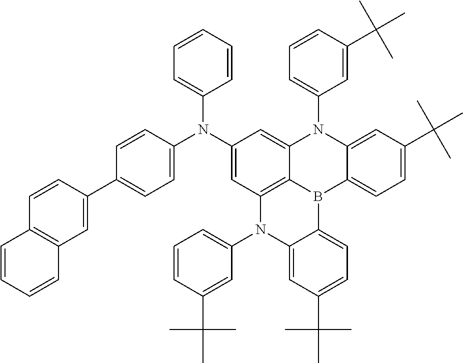 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5ccc(-c6ccc7ccccc7c6)cc5)cc2c43)c1]

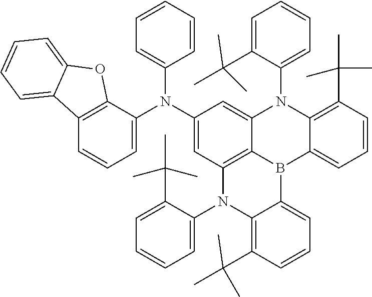 [SMILES: CC(C)(C)c1ccccc1N1c2cc(N(c3ccccc3)c3cccc4c3oc3ccccc34)cc3c2B(c2cccc(C(C)(C)C)c21)c1cccc(C(C)(C)C)c1N3c1ccccc1C(C)(C)C]

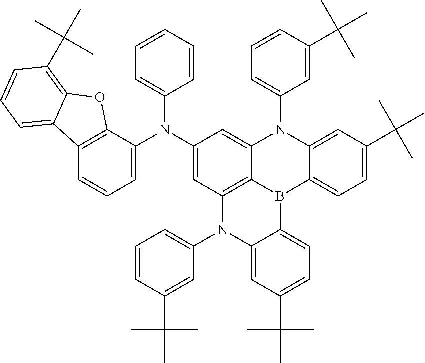 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5c(C(C)(C)C)cccc56)cc2c43)c1]

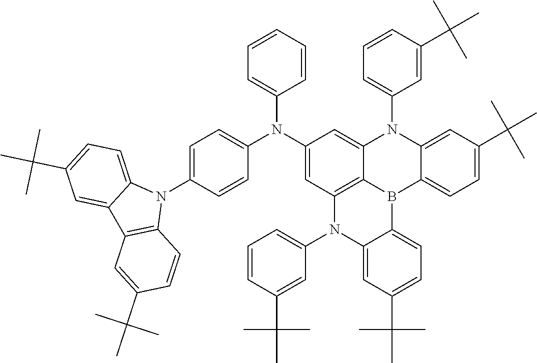 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5ccc(-n6c7ccc(C(C)(C)C)cc7c7cc(C(C)(C)C)ccc76)cc5)cc2c43)c1]

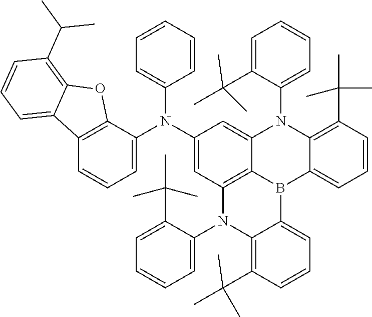 [SMILES: CC(C)c1cccc2c1oc1c(N(c3ccccc3)c3cc4c5c(c3)N(c3ccccc3C(C)(C)C)c3c(cccc3C(C)(C)C)B5c3cccc(C(C)(C)C)c3N4c3ccccc3C(C)(C)C)cccc12]

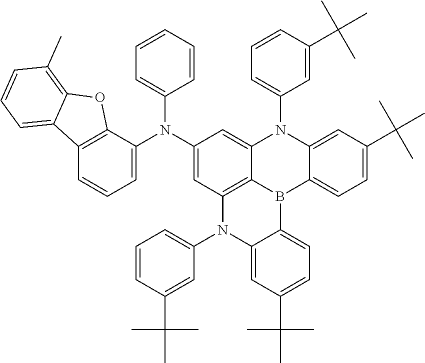 [SMILES: Cc1cccc2c1oc1c(N(c3ccccc3)c3cc4c5c(c3)N(c3cccc(C(C)(C)C)c3)c3cc(C(C)(C)C)ccc3B5c3ccc(C(C)(C)C)cc3N4c3cccc(C(C)(C)C)c3)cccc12]

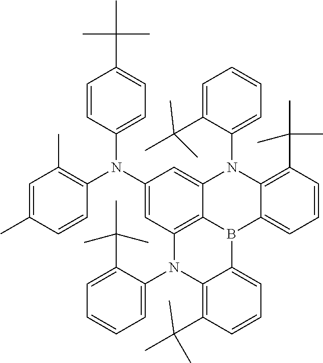 [SMILES: Cc1ccc(N(c2ccc(C(C)(C)C)cc2)c2cc3c4c(c2)N(c2ccccc2C(C)(C)C)c2c(cccc2C(C)(C)C)B4c2cccc(C(C)(C)C)c2N3c2ccccc2C(C)(C)C)c(C)c1]

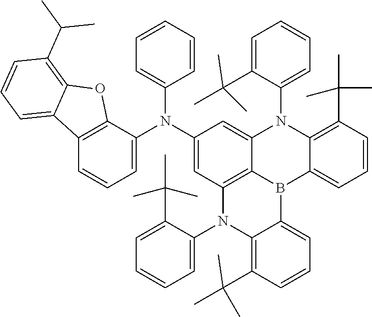 [SMILES: CC(C)c1cccc2c1oc1c(N(c3ccccc3)c3cc4c5c(c3)N(c3ccccc3C(C)(C)C)c3c(cccc3C(C)(C)C)B5c3cccc(C(C)(C)C)c3N4c3ccccc3C(C)(C)C)cccc12]

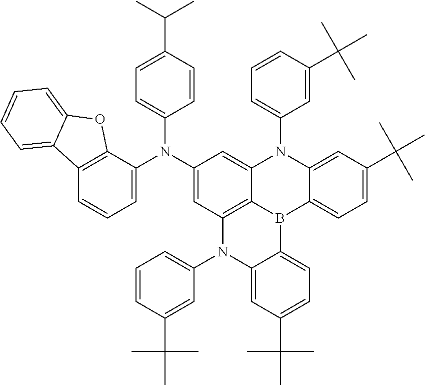 [SMILES: CC(C)c1ccc(N(c2cc3c4c(c2)N(c2cccc(C(C)(C)C)c2)c2cc(C(C)(C)C)ccc2B4c2ccc(C(C)(C)C)cc2N3c2cccc(C(C)(C)C)c2)c2cccc3c2oc2ccccc23)cc1]

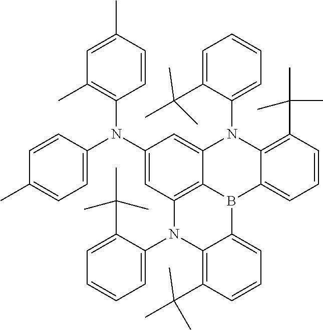 [SMILES: Cc1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2ccc(C)cc2C)cc1]

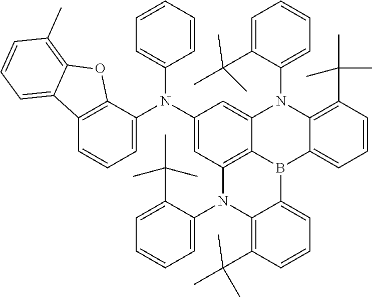 [SMILES: Cc1cccc2c1oc1c(N(c3ccccc3)c3cc4c5c(c3)N(c3ccccc3C(C)(C)C)c3c(cccc3C(C)(C)C)B5c3cccc(C(C)(C)C)c3N4c3ccccc3C(C)(C)C)cccc12]

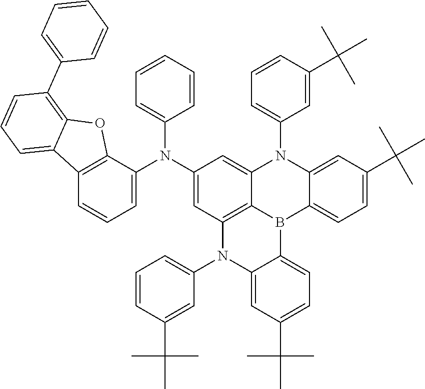 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5c(-c7ccccc7)cccc56)cc2c43)c1]

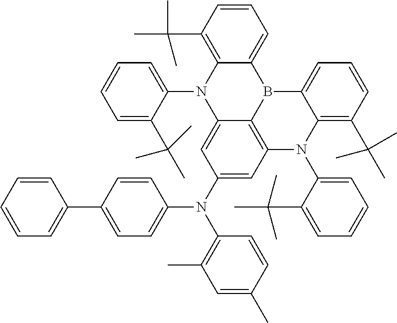 [SMILES: Cc1ccc(N(c2ccc(-c3ccccc3)cc2)c2cc3c4c(c2)N(c2ccccc2C(C)(C)C)c2c(cccc2C(C)(C)C)B4c2cccc(C(C)(C)C)c2N3c2ccccc2C(C)(C)C)c(C)c1]

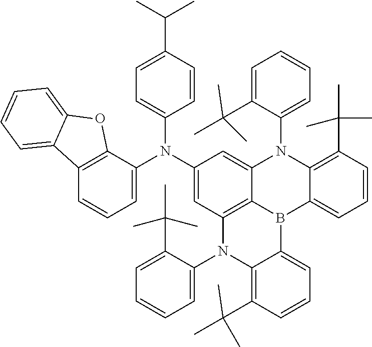 [SMILES: CC(C)c1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2cccc3c2oc2ccccc23)cc1]

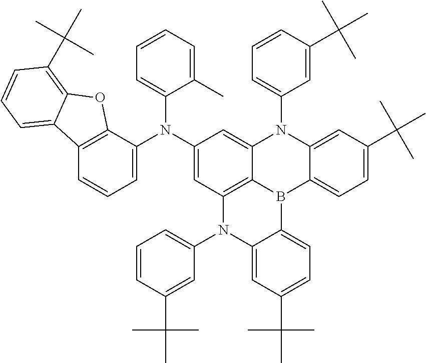 [SMILES: Cc1ccccc1N(c1cc2c3c(c1)N(c1cccc(C(C)(C)C)c1)c1cc(C(C)(C)C)ccc1B3c1ccc(C(C)(C)C)cc1N2c1cccc(C(C)(C)C)c1)c1cccc2c1oc1c(C(C)(C)C)cccc12]

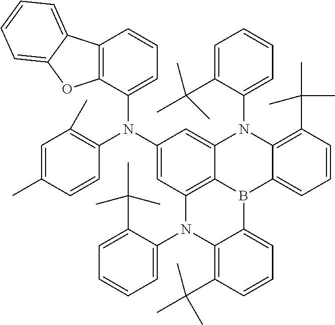 [SMILES: Cc1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2cccc3c2oc2ccccc23)c(C)c1]

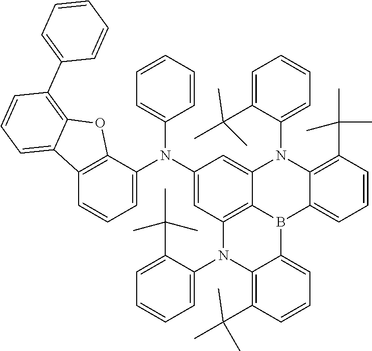 [SMILES: CC(C)(C)c1ccccc1N1c2cc(N(c3ccccc3)c3cccc4c3oc3c(-c5ccccc5)cccc34)cc3c2B(c2cccc(C(C)(C)C)c21)c1cccc(C(C)(C)C)c1N3c1ccccc1C(C)(C)C]

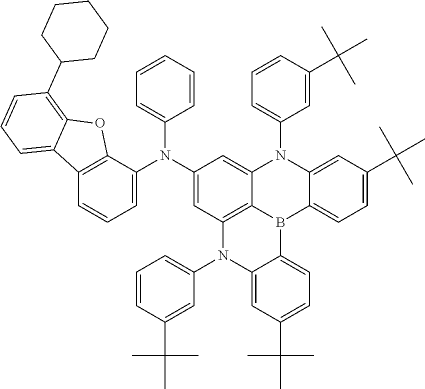 [SMILES: CC(C)(C)c1cccc(N2c3cc(C(C)(C)C)ccc3B3c4ccc(C(C)(C)C)cc4N(c4cccc(C(C)(C)C)c4)c4cc(N(c5ccccc5)c5cccc6c5oc5c(C7CCCCC7)cccc56)cc2c43)c1]

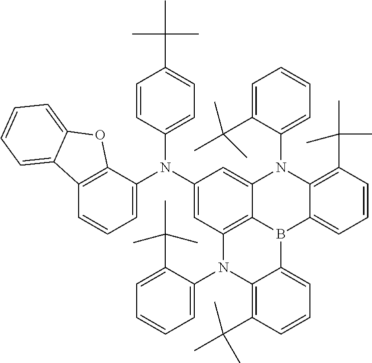 [SMILES: CC(C)(C)c1ccc(N(c2cc3c4c(c2)N(c2ccccc2C(C)(C)C)c2c(cccc2C(C)(C)C)B4c2cccc(C(C)(C)C)c2N3c2ccccc2C(C)(C)C)c2cccc3c2oc2ccccc23)cc1]

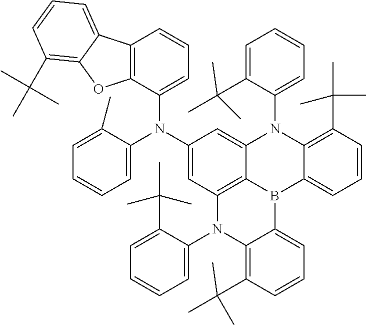 [SMILES: Cc1ccccc1N(c1cc2c3c(c1)N(c1ccccc1C(C)(C)C)c1c(cccc1C(C)(C)C)B3c1cccc(C(C)(C)C)c1N2c1ccccc1C(C)(C)C)c1cccc2c1oc1c(C(C)(C)C)cccc12]

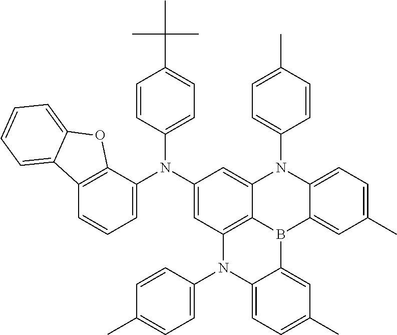 [SMILES: Cc1ccc(N2c3ccc(C)cc3B3c4cc(C)ccc4N(c4ccc(C)cc4)c4cc(N(c5ccc(C(C)(C)C)cc5)c5cccc6c5oc5ccccc56)cc2c43)cc1]

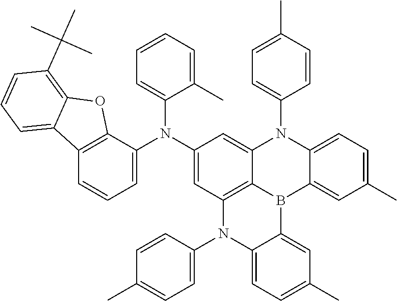 [SMILES: Cc1ccc(N2c3ccc(C)cc3B3c4cc(C)ccc4N(c4ccc(C)cc4)c4cc(N(c5ccccc5C)c5cccc6c5oc5c(C(C)(C)C)cccc56)cc2c43)cc1]

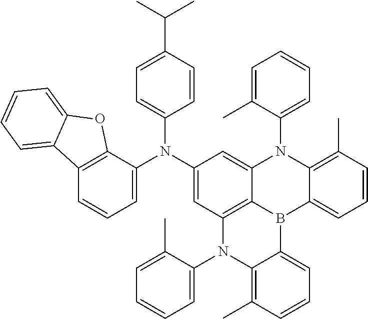 [SMILES: Cc1ccccc1N1c2cc(N(c3ccc(C(C)C)cc3)c3cccc4c3oc3ccccc34)cc3c2B(c2cccc(C)c21)c1cccc(C)c1N3c1ccccc1C]

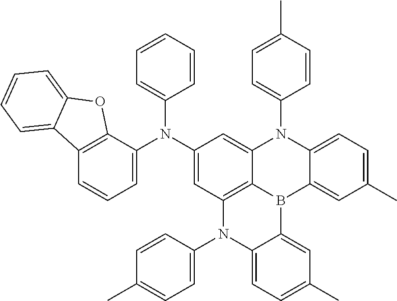 [SMILES: Cc1ccc(N2c3ccc(C)cc3B3c4cc(C)ccc4N(c4ccc(C)cc4)c4cc(N(c5ccccc5)c5cccc6c5oc5ccccc56)cc2c43)cc1]

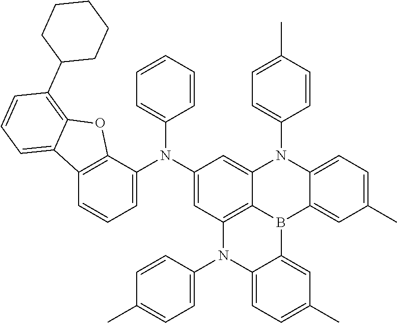 [SMILES: Cc1ccc(N2c3ccc(C)cc3B3c4cc(C)ccc4N(c4ccc(C)cc4)c4cc(N(c5ccccc5)c5cccc6c5oc5c(C7CCCCC7)cccc56)cc2c43)cc1]

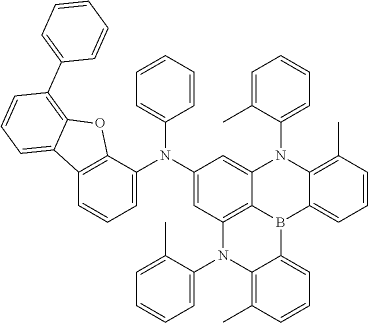 [SMILES: Cc1ccccc1N1c2cc(N(c3ccccc3)c3cccc4c3oc3c(-c5ccccc5)cccc34)cc3c2B(c2cccc(C)c21)c1cccc(C)c1N3c1ccccc1C]

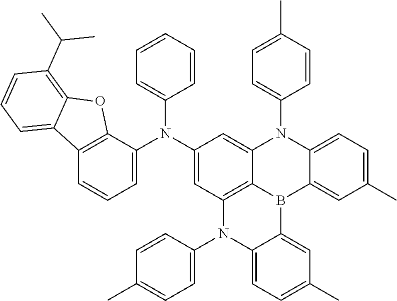 [SMILES: Cc1ccc(N2c3ccc(C)cc3B3c4cc(C)ccc4N(c4ccc(C)cc4)c4cc(N(c5ccccc5)c5cccc6c5oc5c(C(C)C)cccc56)cc2c43)cc1]

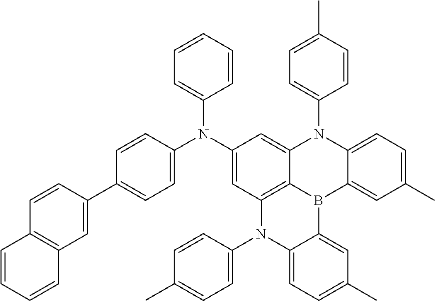 [SMILES: Cc1ccc(N2c3ccc(C)cc3B3c4cc(C)ccc4N(c4ccc(C)cc4)c4cc(N(c5ccccc5)c5ccc(-c6ccc7ccccc7c6)cc5)cc2c43)cc1]

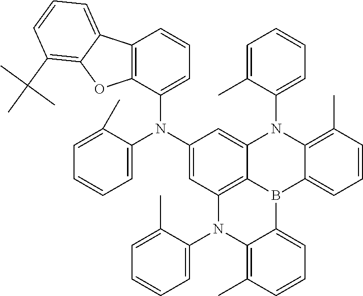 [SMILES: Cc1ccccc1N1c2cc(N(c3ccccc3C)c3cccc4c3oc3c(C(C)(C)C)cccc34)cc3c2B(c2cccc(C)c21)c1cccc(C)c1N3c1ccccc1C]

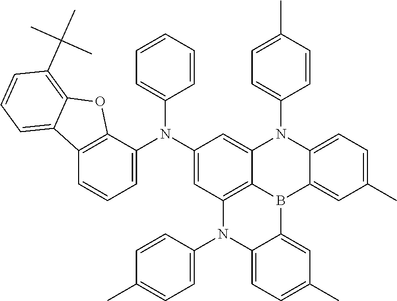 [SMILES: Cc1ccc(N2c3ccc(C)cc3B3c4cc(C)ccc4N(c4ccc(C)cc4)c4cc(N(c5ccccc5)c5cccc6c5oc5c(C(C)(C)C)cccc56)cc2c43)cc1]

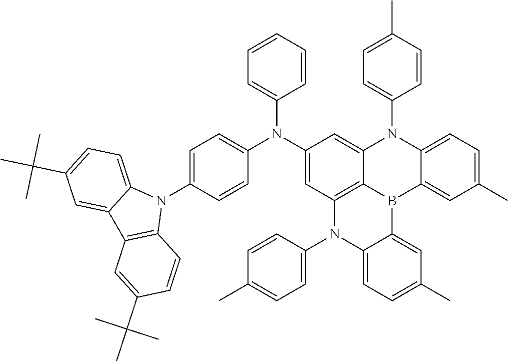 [SMILES: Cc1ccc(N2c3ccc(C)cc3B3c4cc(C)ccc4N(c4ccc(C)cc4)c4cc(N(c5ccccc5)c5ccc(-n6c7ccc(C(C)(C)C)cc7c7cc(C(C)(C)C)ccc76)cc5)cc2c43)cc1]

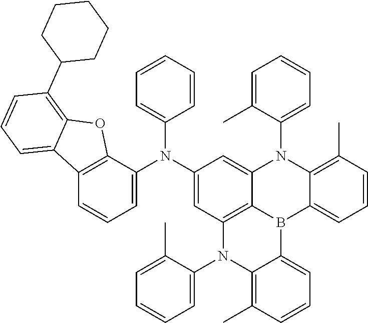 [SMILES: Cc1ccccc1N1c2cc(N(c3ccccc3)c3cccc4c3oc3c(C5CCCCC5)cccc34)cc3c2B(c2cccc(C)c21)c1cccc(C)c1N3c1ccccc1C]

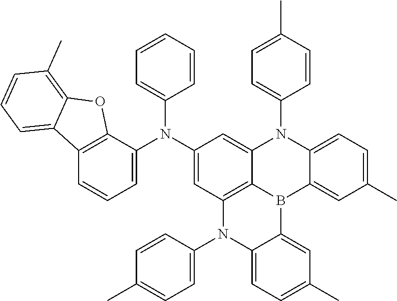 [SMILES: Cc1ccc(N2c3ccc(C)cc3B3c4cc(C)ccc4N(c4ccc(C)cc4)c4cc(N(c5ccccc5)c5cccc6c5oc5c(C)cccc56)cc2c43)cc1]

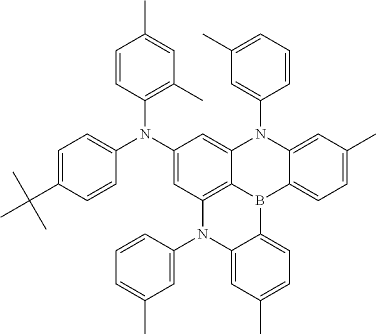 [SMILES: Cc1cccc(N2c3cc(C)ccc3B3c4ccc(C)cc4N(c4cccc(C)c4)c4cc(N(c5ccc(C(C)(C)C)cc5)c5ccc(C)cc5C)cc2c43)c1]

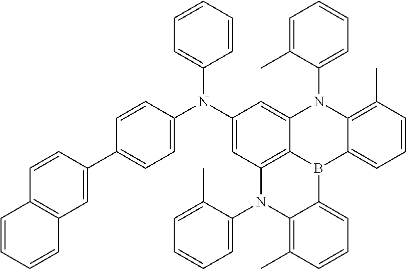 [SMILES: Cc1ccccc1N1c2cc(N(c3ccccc3)c3ccc(-c4ccc5ccccc5c4)cc3)cc3c2B(c2cccc(C)c21)c1cccc(C)c1N3c1ccccc1C]

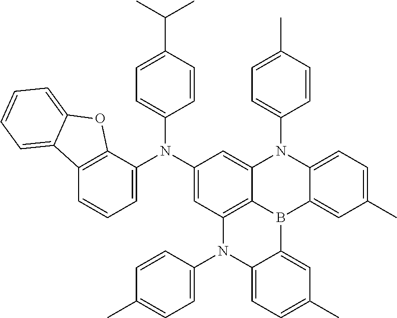 [SMILES: Cc1ccc(N2c3ccc(C)cc3B3c4cc(C)ccc4N(c4ccc(C)cc4)c4cc(N(c5ccc(C(C)C)cc5)c5cccc6c5oc5ccccc56)cc2c43)cc1]

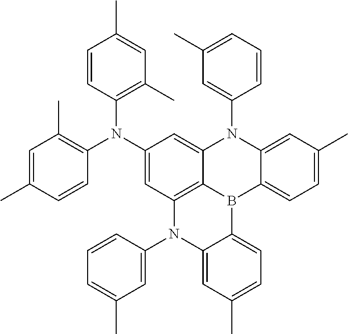

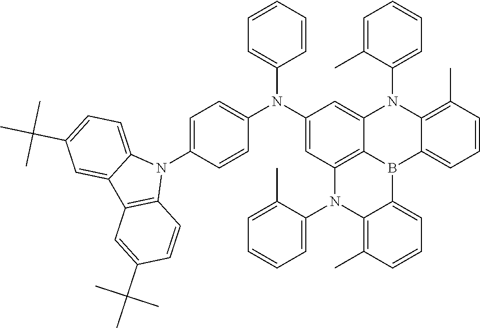 [SMILES: Cc1ccccc1N1c2cc(N(c3ccccc3)c3ccc(-n4c5ccc(C(C)(C)C)cc5c5cc(C(C)(C)C)ccc54)cc3)cc3c2B(c2cccc(C)c21)c1cccc(C)c1N3c1ccccc1C]

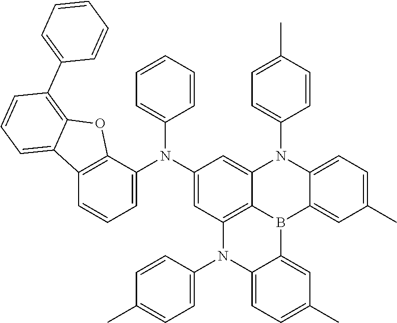 [SMILES: Cc1ccc(N2c3ccc(C)cc3B3c4cc(C)ccc4N(c4ccc(C)cc4)c4cc(N(c5ccccc5)c5cccc6c5oc5c(-c7ccccc7)cccc56)cc2c43)cc1]

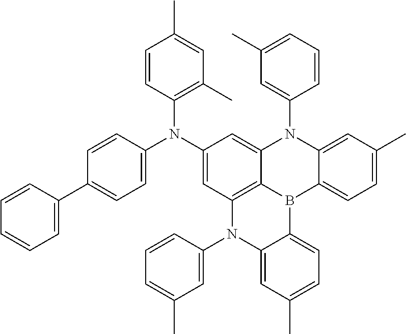 [SMILES: Cc1cccc(N2c3cc(C)ccc3B3c4ccc(C)cc4N(c4cccc(C)c4)c4cc(N(c5ccc(-c6ccccc6)cc5)c5ccc(C)cc5C)cc2c43)c1]

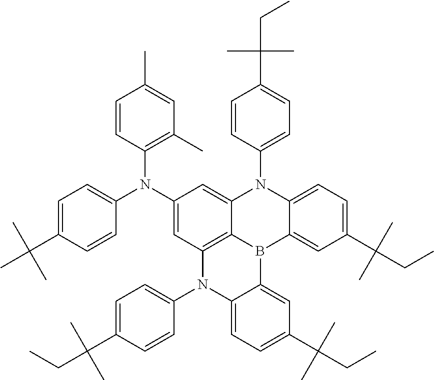 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)(C)C)cc5)c5ccc(C)cc5C)cc2c43)cc1]

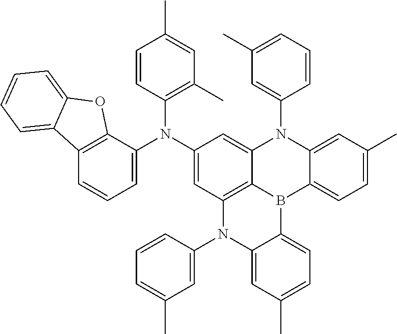 [SMILES: Cc1cccc(N2c3cc(C)ccc3B3c4ccc(C)cc4N(c4cccc(C)c4)c4cc(N(c5ccc(C)cc5C)c5cccc6c5oc5ccccc56)cc2c43)c1]

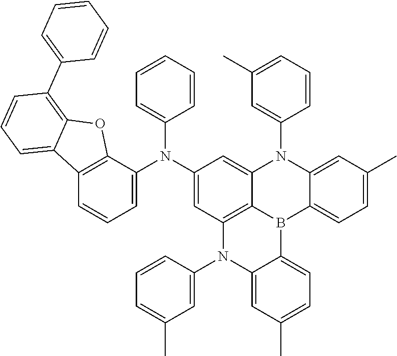 [SMILES: Cc1cccc(N2c3cc(C)ccc3B3c4ccc(C)cc4N(c4cccc(C)c4)c4cc(N(c5ccccc5)c5cccc6c5oc5c(-c7ccccc7)cccc56)cc2c43)c1]

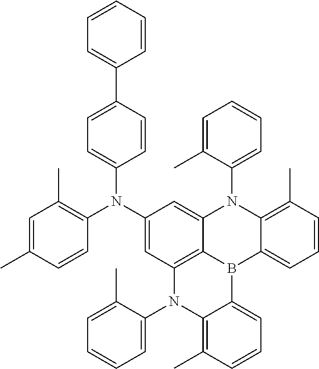 [SMILES: Cc1ccc(N(c2ccc(-c3ccccc3)cc2)c2cc3c4c(c2)N(c2ccccc2C)c2c(C)cccc2B4c2cccc(C)c2N3c2ccccc2C)c(C)c1]

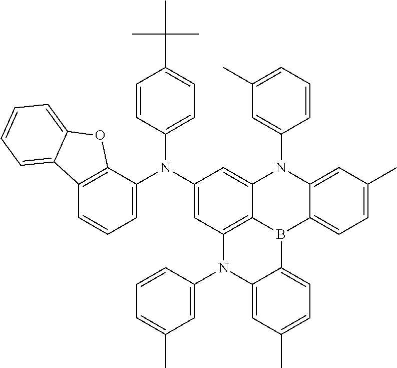 [SMILES: Cc1cccc(N2c3cc(C)ccc3B3c4ccc(C)cc4N(c4cccc(C)c4)c4cc(N(c5ccc(C(C)(C)C)cc5)c5cccc6c5oc5ccccc56)cc2c43)c1]

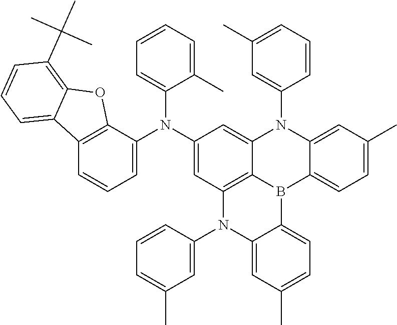 [SMILES: Cc1cccc(N2c3cc(C)ccc3B3c4ccc(C)cc4N(c4cccc(C)c4)c4cc(N(c5ccccc5C)c5cccc6c5oc5c(C(C)(C)C)cccc56)cc2c43)c1]

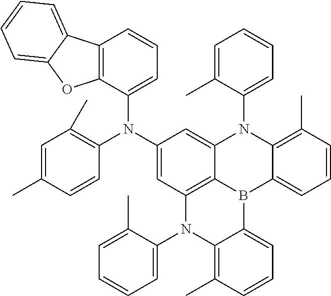 [SMILES: Cc1ccc(N(c2cc3c4c(c2)N(c2ccccc2C)c2c(C)cccc2B4c2cccc(C)c2N3c2ccccc2C)c2cccc3c2oc2ccccc23)c(C)c1]

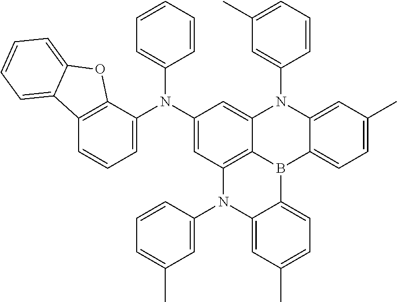 [SMILES: Cc1cccc(N2c3cc(C)ccc3B3c4ccc(C)cc4N(c4cccc(C)c4)c4cc(N(c5ccccc5)c5cccc6c5oc5ccccc56)cc2c43)c1]

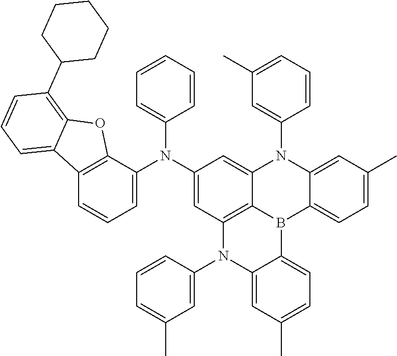 [SMILES: Cc1cccc(N2c3cc(C)ccc3B3c4ccc(C)cc4N(c4cccc(C)c4)c4cc(N(c5ccccc5)c5cccc6c5oc5c(C7CCCCC7)cccc56)cc2c43)c1]

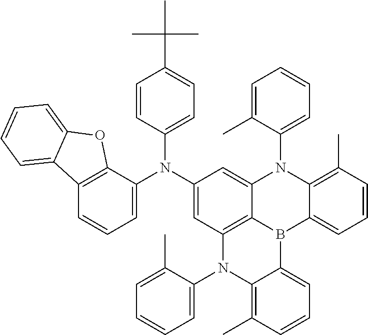 [SMILES: Cc1ccccc1N1c2cc(N(c3ccc(C(C)(C)C)cc3)c3cccc4c3oc3ccccc34)cc3c2B(c2cccc(C)c21)c1cccc(C)c1N3c1ccccc1C]

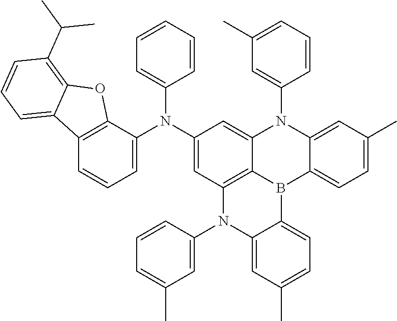 [SMILES: Cc1cccc(N2c3cc(C)ccc3B3c4ccc(C)cc4N(c4cccc(C)c4)c4cc(N(c5ccccc5)c5cccc6c5oc5c(C(C)C)cccc56)cc2c43)c1]

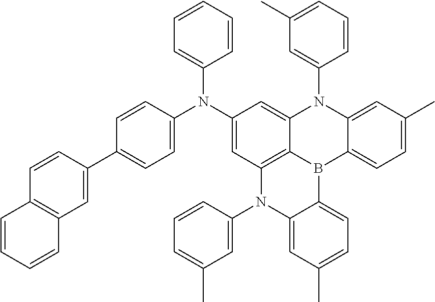 [SMILES: Cc1cccc(N2c3cc(C)ccc3B3c4ccc(C)cc4N(c4cccc(C)c4)c4cc(N(c5ccccc5)c5ccc(-c6ccc7ccccc7c6)cc5)cc2c43)c1]

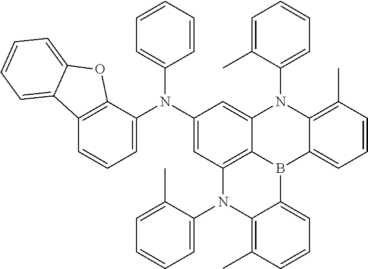 [SMILES: Cc1ccccc1N1c2cc(N(c3ccccc3)c3cccc4c3oc3ccccc34)cc3c2B(c2cccc(C)c21)c1cccc(C)c1N3c1ccccc1C]

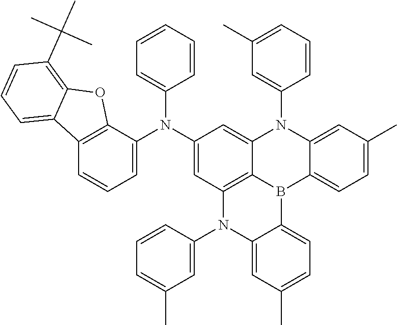 [SMILES: Cc1cccc(N2c3cc(C)ccc3B3c4ccc(C)cc4N(c4cccc(C)c4)c4cc(N(c5ccccc5)c5cccc6c5oc5c(C(C)(C)C)cccc56)cc2c43)c1]

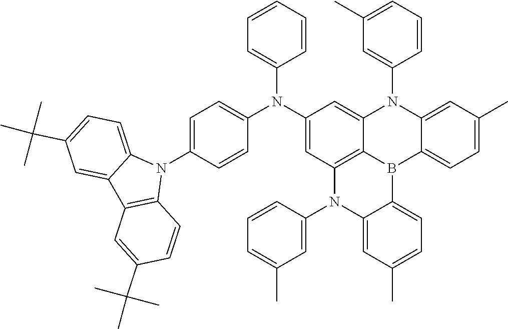 [SMILES: Cc1cccc(N2c3cc(C)ccc3B3c4ccc(C)cc4N(c4cccc(C)c4)c4cc(N(c5ccccc5)c5ccc(-n6c7ccc(C(C)(C)C)cc7c7cc(C(C)(C)C)ccc76)cc5)cc2c43)c1]

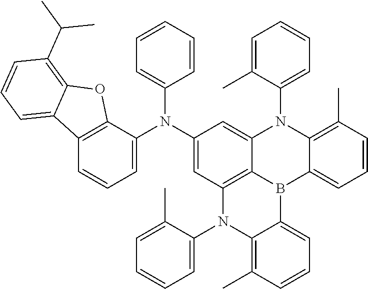 [SMILES: Cc1ccccc1N1c2cc(N(c3ccccc3)c3cccc4c3oc3c(C(C)C)cccc34)cc3c2B(c2cccc(C)c21)c1cccc(C)c1N3c1ccccc1C]

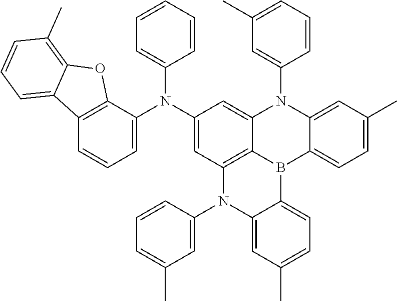 [SMILES: Cc1cccc(N2c3cc(C)ccc3B3c4ccc(C)cc4N(c4cccc(C)c4)c4cc(N(c5ccccc5)c5cccc6c5oc5c(C)cccc56)cc2c43)c1]

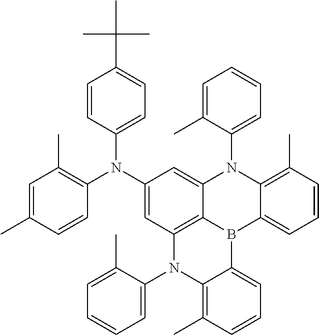 [SMILES: Cc1ccc(N(c2ccc(C(C)(C)C)cc2)c2cc3c4c(c2)N(c2ccccc2C)c2c(C)cccc2B4c2cccc(C)c2N3c2ccccc2C)c(C)c1]

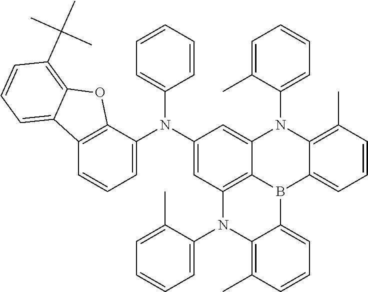 [SMILES: Cc1ccccc1N1c2cc(N(c3ccccc3)c3cccc4c3oc3c(C(C)(C)C)cccc34)cc3c2B(c2cccc(C)c21)c1cccc(C)c1N3c1ccccc1C]

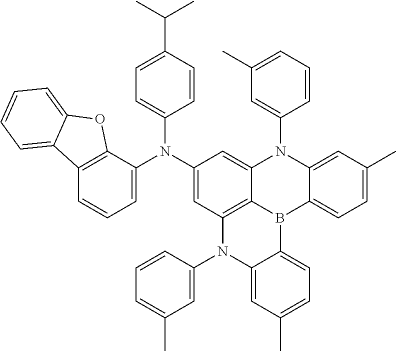 [SMILES: Cc1cccc(N2c3cc(C)ccc3B3c4ccc(C)cc4N(c4cccc(C)c4)c4cc(N(c5ccc(C(C)C)cc5)c5cccc6c5oc5ccccc56)cc2c43)c1]

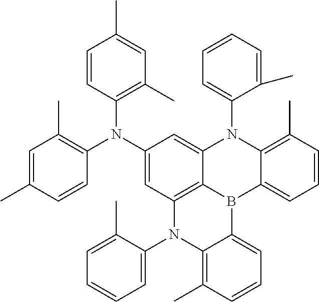 [SMILES: Cc1ccc(N(c2cc3c4c(c2)N(c2ccccc2C)c2c(C)cccc2B4c2cccc(C)c2N3c2ccccc2C)c2ccc(C)cc2C)c(C)c1]

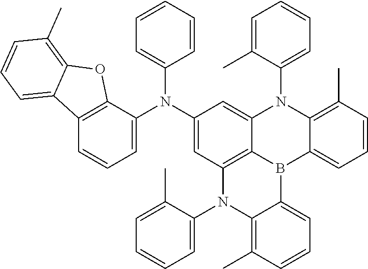 [SMILES: Cc1ccccc1N1c2cc(N(c3ccccc3)c3cccc4c3oc3c(C)cccc34)cc3c2B(c2cccc(C)c21)c1cccc(C)c1N3c1ccccc1C]

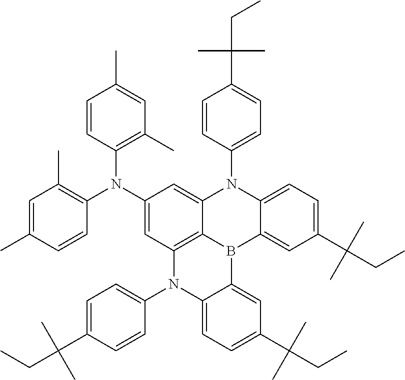 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C)cc5C)c5ccc(C)cc5C)cc2c43)cc1]

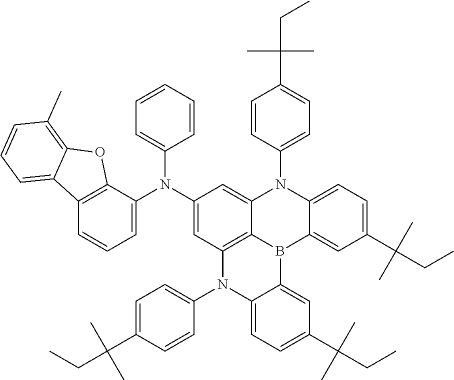 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C)cccc56)cc2c43)cc1]

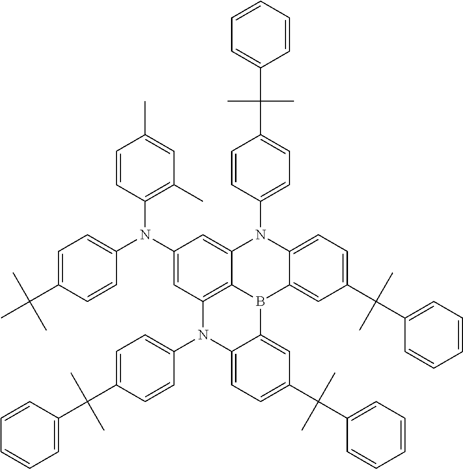 [SMILES: Cc1ccc(N(c2ccc(C(C)(C)C)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c(C)c1]

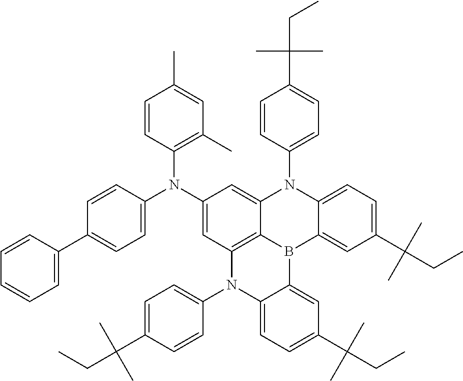 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(-c6ccccc6)cc5)c5ccc(C)cc5C)cc2c43)cc1]

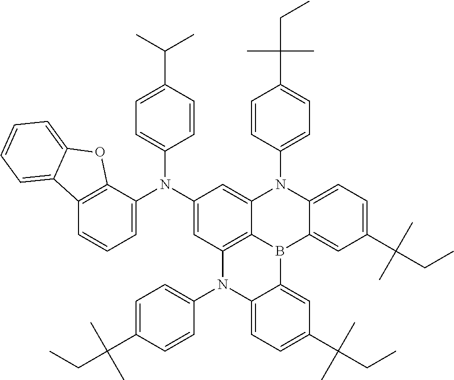 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)C)cc5)c5cccc6c5oc5ccccc56)cc2c43)cc1]

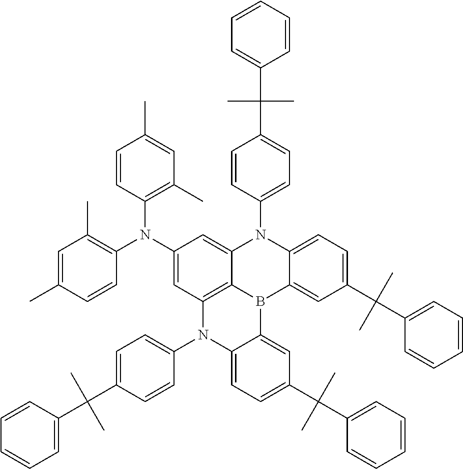 [SMILES: Cc1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2ccc(C)cc2C)c(C)c1]

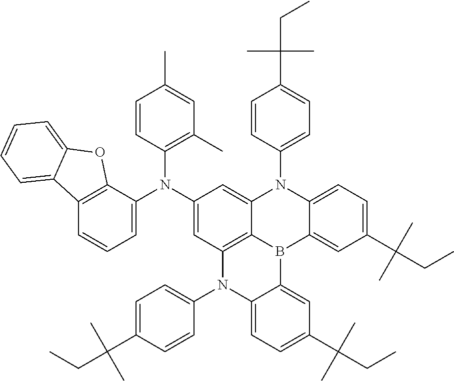 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C)cc5C)c5cccc6c5oc5ccccc56)cc2c43)cc1]

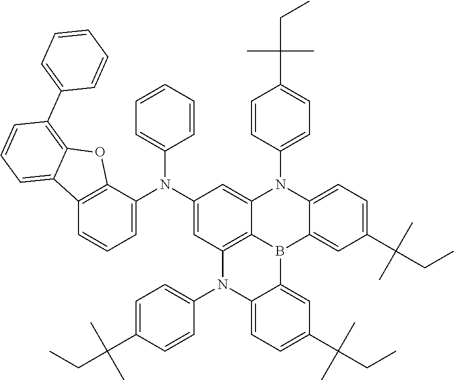 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(-c7ccccc7)cccc56)cc2c43)cc1]

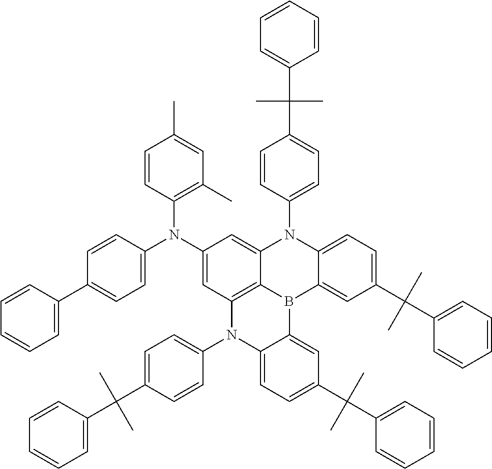 [SMILES: Cc1ccc(N(c2ccc(-c3ccccc3)cc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c(C)c1]

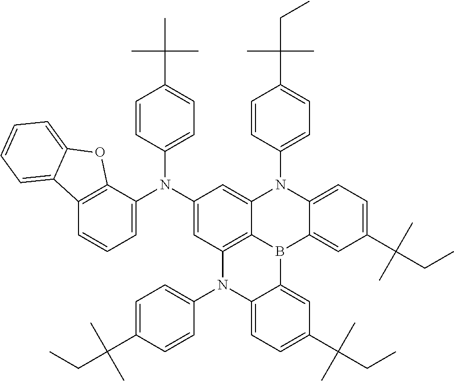 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccc(C(C)(C)C)cc5)c5cccc6c5oc5ccccc56)cc2c43)cc1]

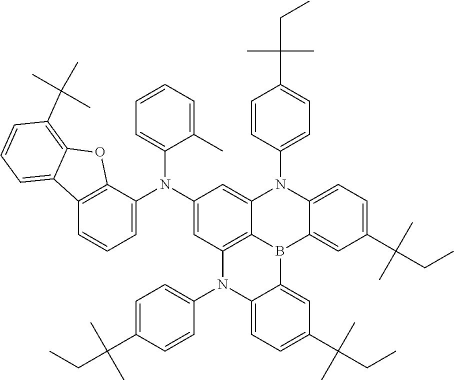 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5C)c5cccc6c5oc5c(C(C)(C)C)cccc56)cc2c43)cc1]

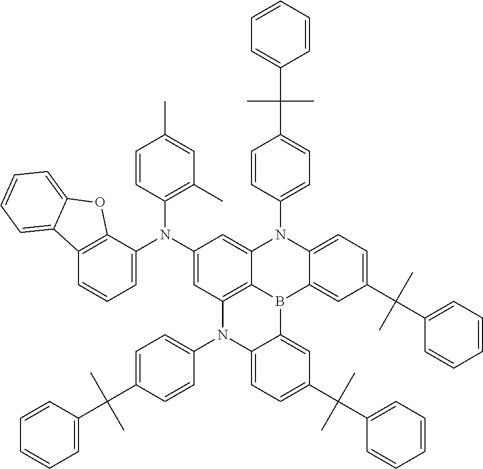 [SMILES: Cc1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2cccc3c2oc2ccccc23)c(C)c1]

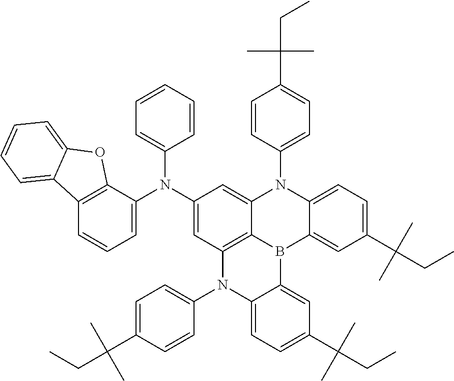 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5ccccc56)cc2c43)cc1]

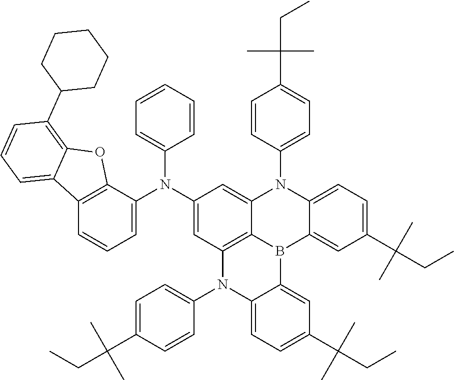 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C7CCCCC7)cccc56)cc2c43)cc1]

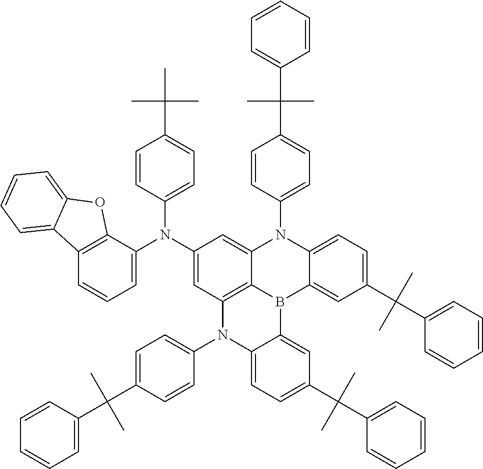 [SMILES: CC(C)(C)c1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2cccc3c2oc2ccccc23)cc1]

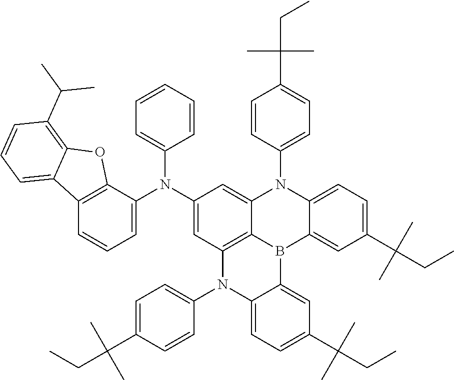 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C(C)C)cccc56)cc2c43)cc1]

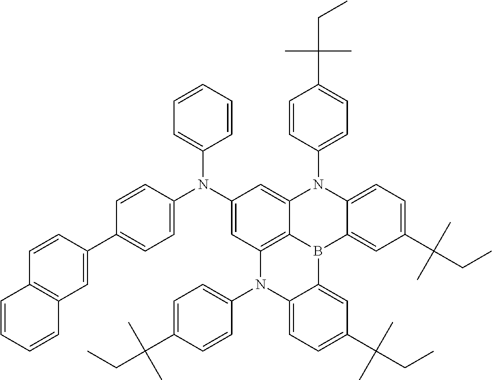 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5ccc(-c6ccc7ccccc7c6)cc5)cc2c43)cc1]

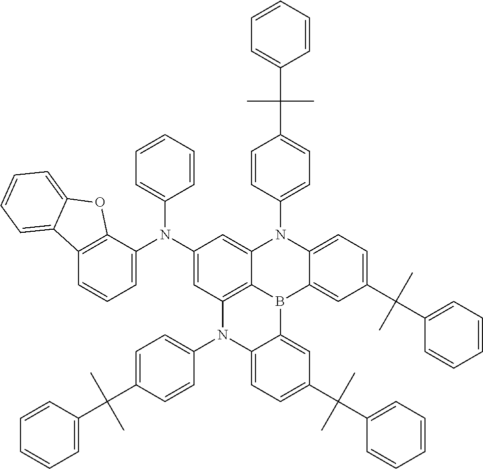 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5cccc6c5oc5ccccc56)cc2c43)cc1]

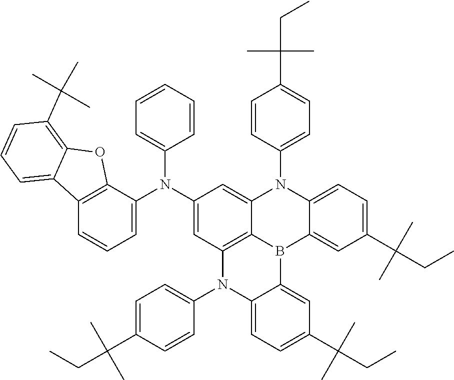 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5cccc6c5oc5c(C(C)(C)C)cccc56)cc2c43)cc1]

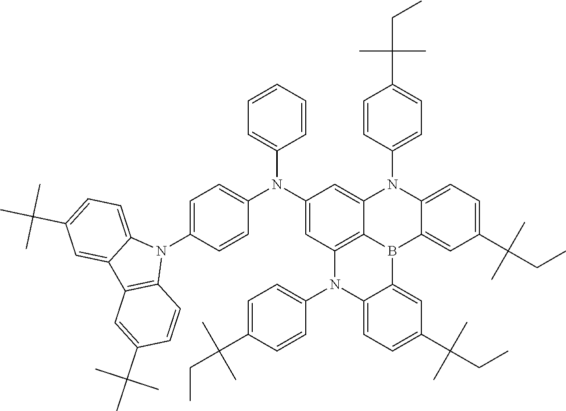 [SMILES: CCC(C)(C)c1ccc(N2c3ccc(C(C)(C)CC)cc3B3c4cc(C(C)(C)CC)ccc4N(c4ccc(C(C)(C)CC)cc4)c4cc(N(c5ccccc5)c5ccc(-n6c7ccc(C(C)(C)C)cc7c7cc(C(C)(C)C)ccc76)cc5)cc2c43)cc1]

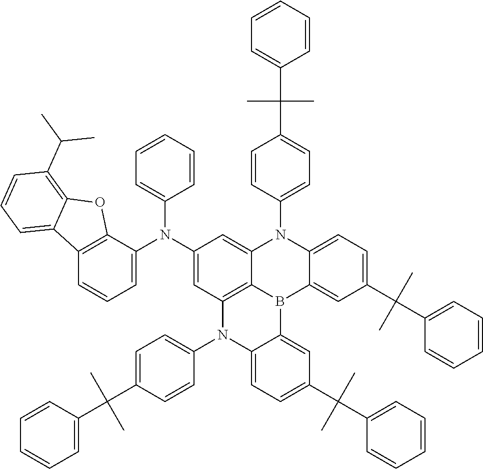 [SMILES: CC(C)c1cccc2c1oc1c(N(c3ccccc3)c3cc4c5c(c3)N(c3ccc(C(C)(C)c6ccccc6)cc3)c3ccc(C(C)(C)c6ccccc6)cc3B5c3cc(C(C)(C)c5ccccc5)ccc3N4c3ccc(C(C)(C)c4ccccc4)cc3)cccc12]

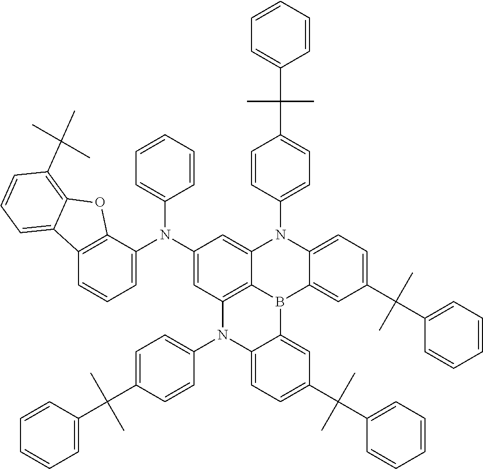 [SMILES: CC(C)(C)c1cccc2c1oc1c(N(c3ccccc3)c3cc4c5c(c3)N(c3ccc(C(C)(C)c6ccccc6)cc3)c3ccc(C(C)(C)c6ccccc6)cc3B5c3cc(C(C)(C)c5ccccc5)ccc3N4c3ccc(C(C)(C)c4ccccc4)cc3)cccc12]

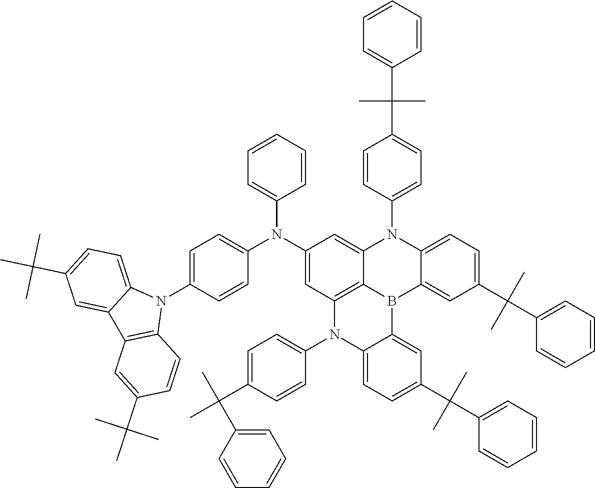 [SMILES: CC(C)(C)c1ccc2c(c1)c1cc(C(C)(C)C)ccc1n2-c1ccc(N(c2ccccc2)c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)cc1]

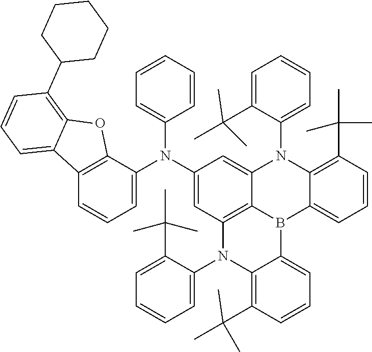 [SMILES: CC(C)(C)c1ccccc1N1c2cc(N(c3ccccc3)c3cccc4c3oc3c(C5CCCCC5)cccc34)cc3c2B(c2cccc(C(C)(C)C)c21)c1cccc(C(C)(C)C)c1N3c1ccccc1C(C)(C)C]

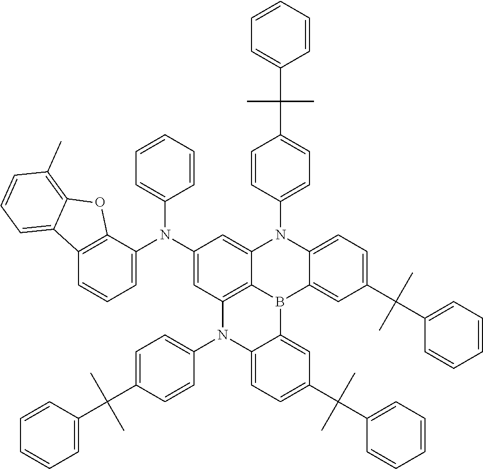 [SMILES: Cc1cccc2c1oc1c(N(c3ccccc3)c3cc4c5c(c3)N(c3ccc(C(C)(C)c6ccccc6)cc3)c3ccc(C(C)(C)c6ccccc6)cc3B5c3cc(C(C)(C)c5ccccc5)ccc3N4c3ccc(C(C)(C)c4ccccc4)cc3)cccc12]

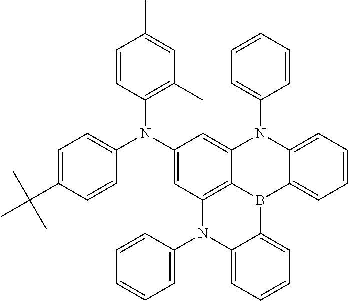 [SMILES: Cc1ccc(N(c2ccc(C(C)(C)C)cc2)c2cc3c4c(c2)N(c2ccccc2)c2ccccc2B4c2ccccc2N3c2ccccc2)c(C)c1]

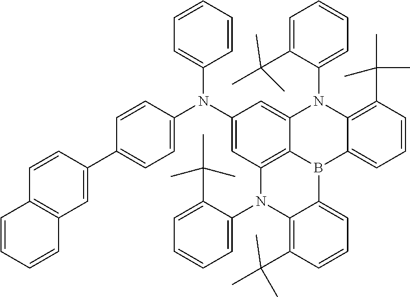 [SMILES: CC(C)(C)c1ccccc1N1c2cc(N(c3ccccc3)c3ccc(-c4ccc5ccccc5c4)cc3)cc3c2B(c2cccc(C(C)(C)C)c21)c1cccc(C(C)(C)C)c1N3c1ccccc1C(C)(C)C]

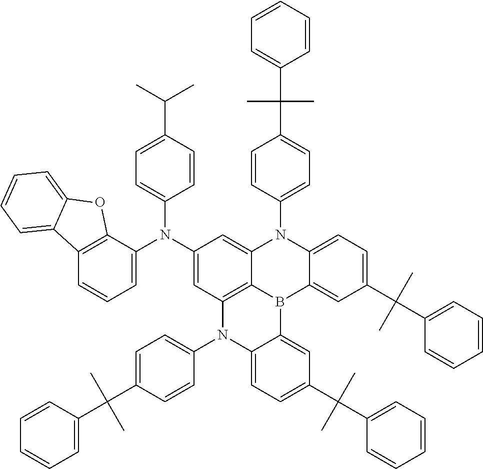 [SMILES: CC(C)c1ccc(N(c2cc3c4c(c2)N(c2ccc(C(C)(C)c5ccccc5)cc2)c2ccc(C(C)(C)c5ccccc5)cc2B4c2cc(C(C)(C)c4ccccc4)ccc2N3c2ccc(C(C)(C)c3ccccc3)cc2)c2cccc3c2oc2ccccc23)cc1]

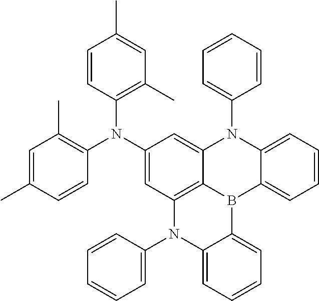 [SMILES: Cc1ccc(N(c2cc3c4c(c2)N(c2ccccc2)c2ccccc2B4c2ccccc2N3c2ccccc2)c2ccc(C)cc2C)c(C)c1]

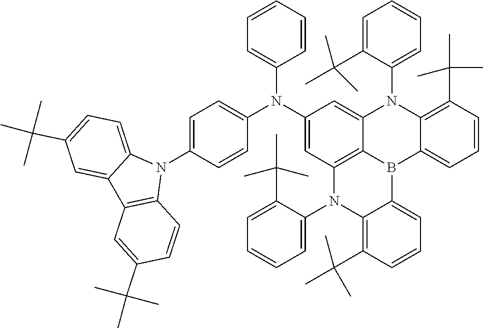 [SMILES: CC(C)(C)c1ccc2c(c1)c1cc(C(C)(C)C)ccc1n2-c1ccc(N(c2ccccc2)c2cc3c4c(c2)N(c2ccccc2C(C)(C)C)c2c(cccc2C(C)(C)C)B4c2cccc(C(C)(C)C)c2N3c2ccccc2C(C)(C)C)cc1]

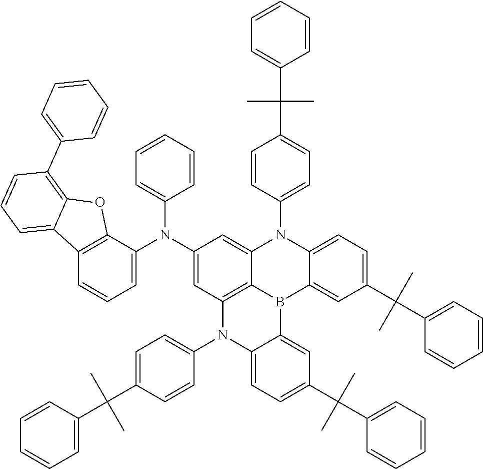 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5cccc6c5oc5c(-c7ccccc7)cccc56)cc2c43)cc1]

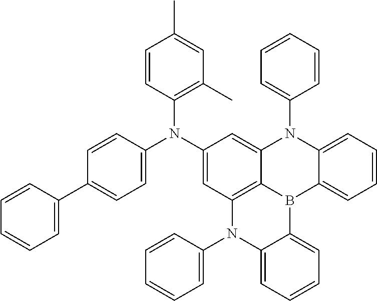 [SMILES: Cc1ccc(N(c2ccc(-c3ccccc3)cc2)c2cc3c4c(c2)N(c2ccccc2)c2ccccc2B4c2ccccc2N3c2ccccc2)c(C)c1]

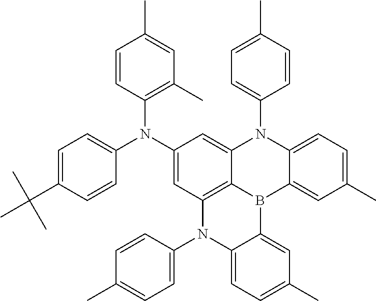 [SMILES: Cc1ccc(N2c3ccc(C)cc3B3c4cc(C)ccc4N(c4ccc(C)cc4)c4cc(N(c5ccc(C(C)(C)C)cc5)c5ccc(C)cc5C)cc2c43)cc1]

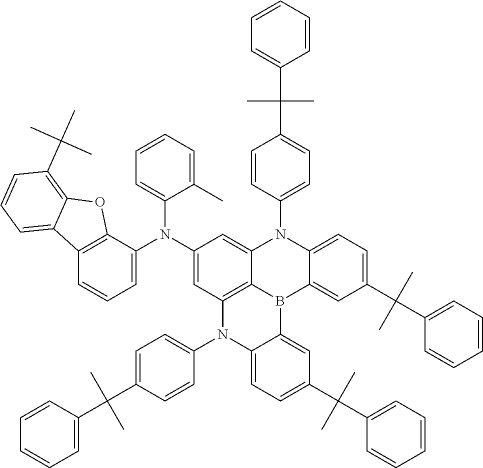 [SMILES: Cc1ccccc1N(c1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1)c1cccc2c1oc1c(C(C)(C)C)cccc12]

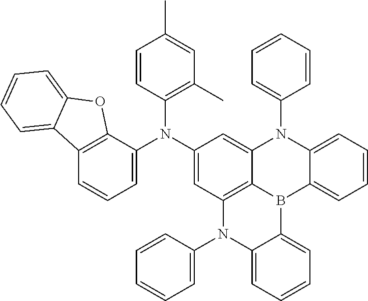 [SMILES: Cc1ccc(N(c2cc3c4c(c2)N(c2ccccc2)c2ccccc2B4c2ccccc2N3c2ccccc2)c2cccc3c2oc2ccccc23)c(C)c1]

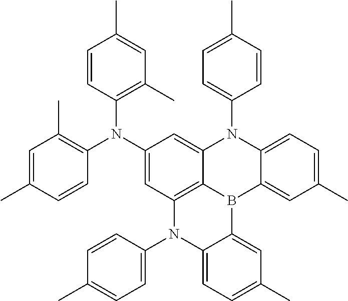

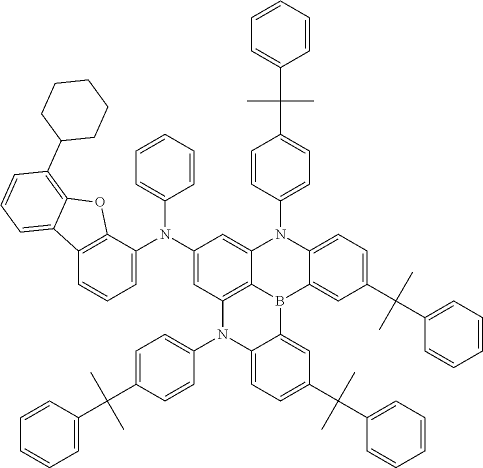 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5cccc6c5oc5c(C7CCCCC7)cccc56)cc2c43)cc1]

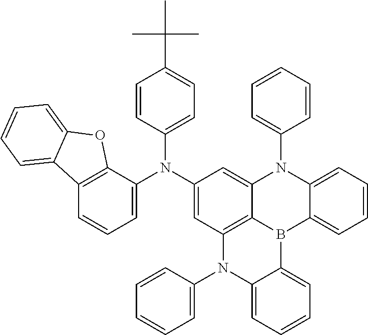 [SMILES: CC(C)(C)c1ccc(N(c2cc3c4c(c2)N(c2ccccc2)c2ccccc2B4c2ccccc2N3c2ccccc2)c2cccc3c2oc2ccccc23)cc1]

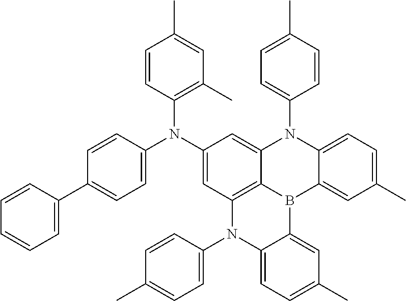 [SMILES: Cc1ccc(N2c3ccc(C)cc3B3c4cc(C)ccc4N(c4ccc(C)cc4)c4cc(N(c5ccc(-c6ccccc6)cc5)c5ccc(C)cc5C)cc2c43)cc1]

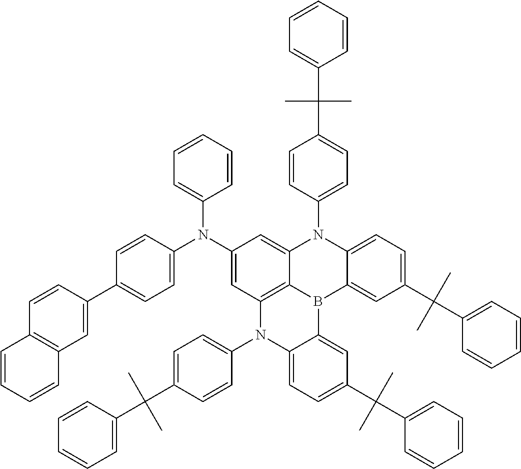 [SMILES: CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cc(N(c5ccccc5)c5ccc(-c6ccc7ccccc7c6)cc5)cc2c43)cc1]

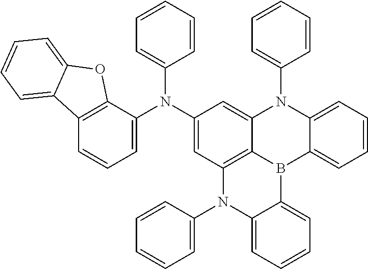 [SMILES: c1ccc(N2c3ccccc3B3c4ccccc4N(c4ccccc4)c4cc(N(c5ccccc5)c5cccc6c5oc5ccccc56)cc2c43)cc1]

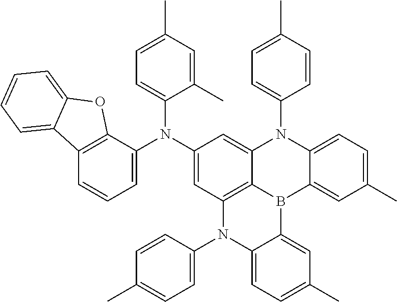 [SMILES: Cc1ccc(N2c3ccc(C)cc3B3c4cc(C)ccc4N(c4ccc(C)cc4)c4cc(N(c5ccc(C)cc5C)c5cccc6c5oc5ccccc56)cc2c43)cc1]

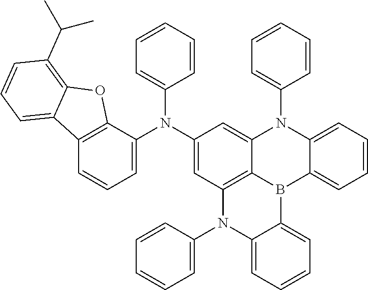 [SMILES: CC(C)c1cccc2c1oc1c(N(c3ccccc3)c3cc4c5c(c3)N(c3ccccc3)c3ccccc3B5c3ccccc3N4c3ccccc3)cccc12]

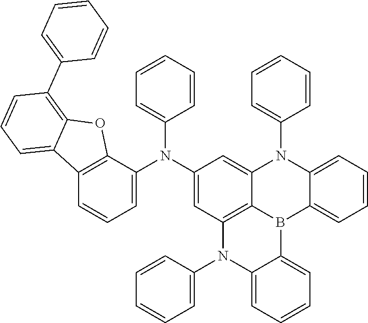 [SMILES: c1ccc(-c2cccc3c2oc2c(N(c4ccccc4)c4cc5c6c(c4)N(c4ccccc4)c4ccccc4B6c4ccccc4N5c4ccccc4)cccc23)cc1]

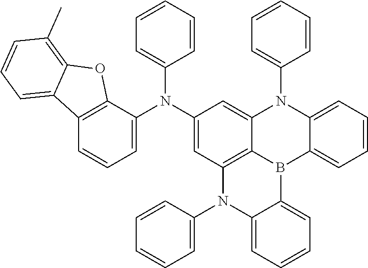 [SMILES: Cc1cccc2c1oc1c(N(c3ccccc3)c3cc4c5c(c3)N(c3ccccc3)c3ccccc3B5c3ccccc3N4c3ccccc3)cccc12]

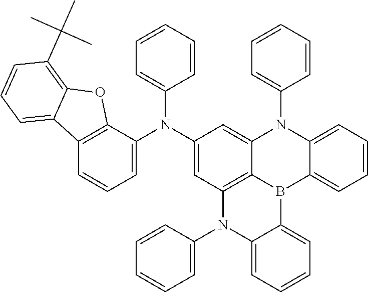 [SMILES: CC(C)(C)c1cccc2c1oc1c(N(c3ccccc3)c3cc4c5c(c3)N(c3ccccc3)c3ccccc3B5c3ccccc3N4c3ccccc3)cccc12]

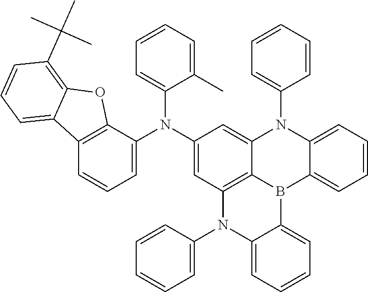 [SMILES: Cc1ccccc1N(c1cc2c3c(c1)N(c1ccccc1)c1ccccc1B3c1ccccc1N2c1ccccc1)c1cccc2c1oc1c(C(C)(C)C)cccc12]

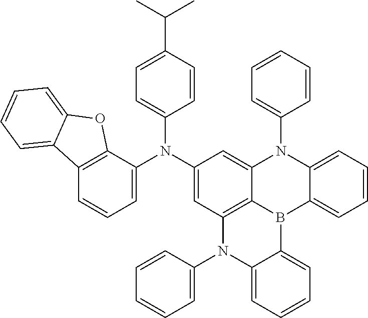 [SMILES: CC(C)c1ccc(N(c2cc3c4c(c2)N(c2ccccc2)c2ccccc2B4c2ccccc2N3c2ccccc2)c2cccc3c2oc2ccccc23)cc1]

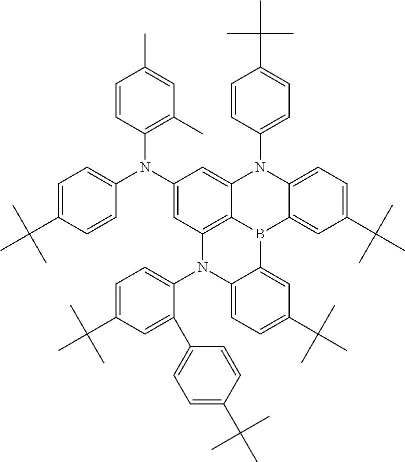 [SMILES: Cc1ccc(N(c2ccc(C(C)(C)C)cc2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c(C)c1]

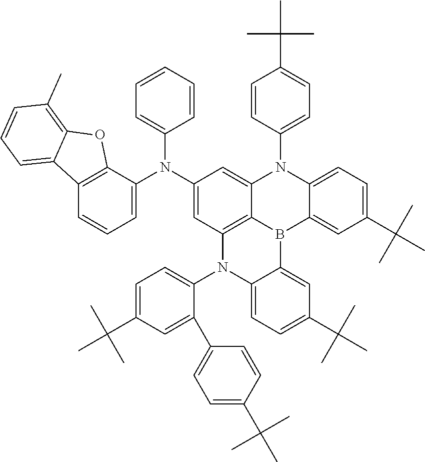 [SMILES: Cc1cccc2c1oc1c(N(c3ccccc3)c3cc4c5c(c3)N(c3ccc(C(C)(C)C)cc3-c3ccc(C(C)(C)C)cc3)c3ccc(C(C)(C)C)cc3B5c3cc(C(C)(C)C)ccc3N4c3ccc(C(C)(C)C)cc3)cccc12]

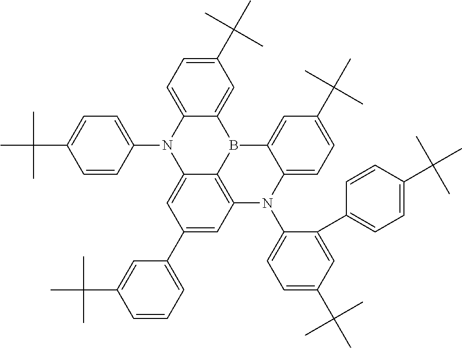 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5cccc(C(C)(C)C)c5)cc2c43)cc1]

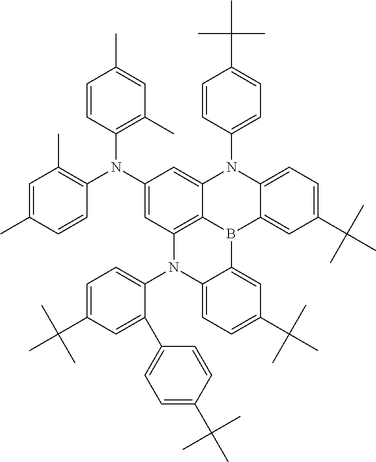 [SMILES: Cc1ccc(N(c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c2ccc(C)cc2C)c(C)c1]

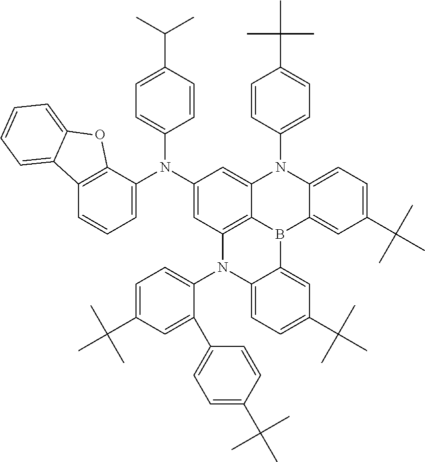 [SMILES: CC(C)c1ccc(N(c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c2cccc3c2oc2ccccc23)cc1]

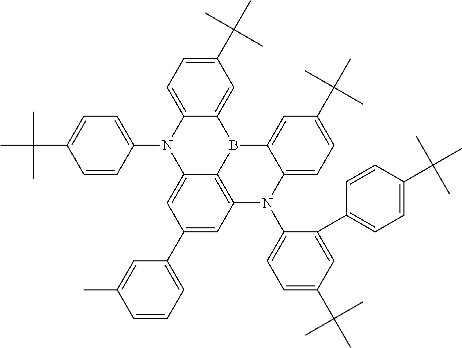 [SMILES: Cc1cccc(-c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c1]

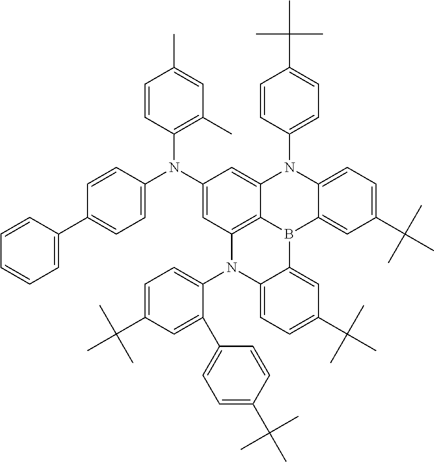 [SMILES: Cc1ccc(N(c2ccc(-c3ccccc3)cc2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c(C)c1]

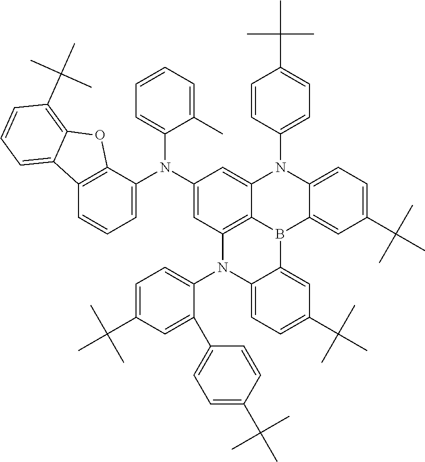 [SMILES: Cc1ccccc1N(c1cc2c3c(c1)N(c1ccc(C(C)(C)C)cc1-c1ccc(C(C)(C)C)cc1)c1ccc(C(C)(C)C)cc1B3c1cc(C(C)(C)C)ccc1N2c1ccc(C(C)(C)C)cc1)c1cccc2c1oc1c(C(C)(C)C)cccc12]

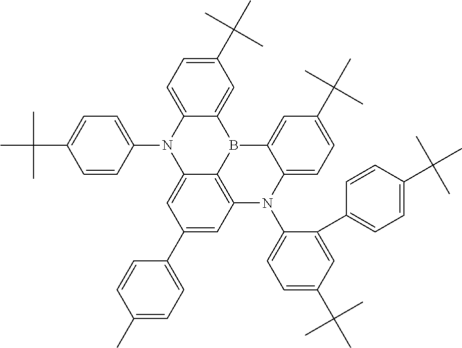 [SMILES: Cc1ccc(-c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)cc1]

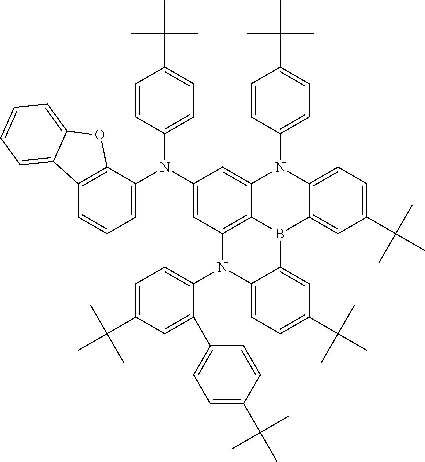 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc(C(C)(C)C)cc5)c5cccc6c5oc5ccccc56)cc2c43)cc1]

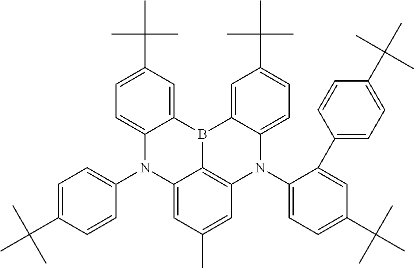 [SMILES: Cc1cc2c3c(c1)N(c1ccc(C(C)(C)C)cc1-c1ccc(C(C)(C)C)cc1)c1ccc(C(C)(C)C)cc1B3c1cc(C(C)(C)C)ccc1N2c1ccc(C(C)(C)C)cc1]

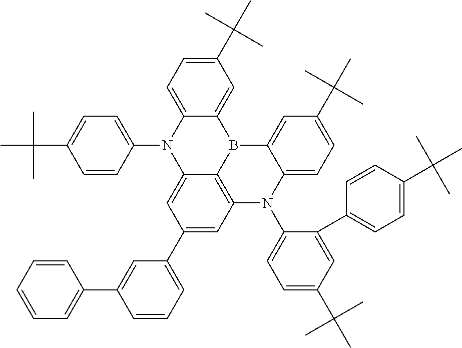 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5cccc(-c6ccccc6)c5)cc2c43)cc1]

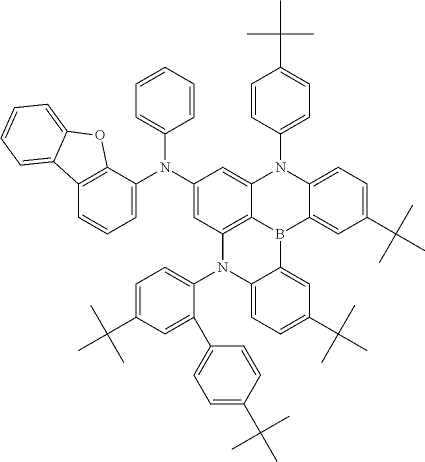 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccccc5)c5cccc6c5oc5ccccc56)cc2c43)cc1]

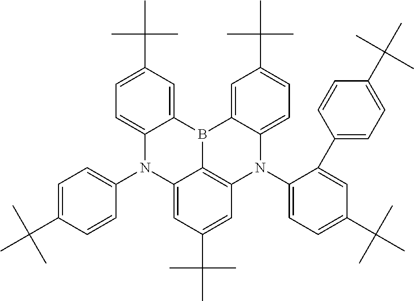 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(C(C)(C)C)cc2c43)cc1]

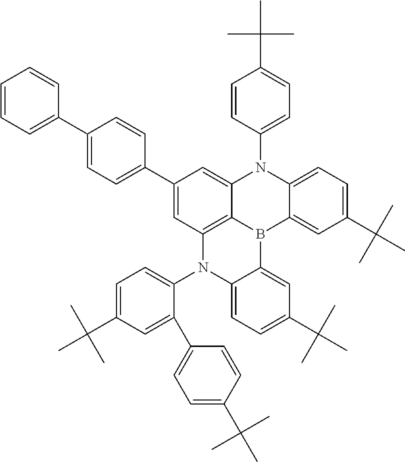 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5ccc(-c6ccccc6)cc5)cc2c43)cc1]

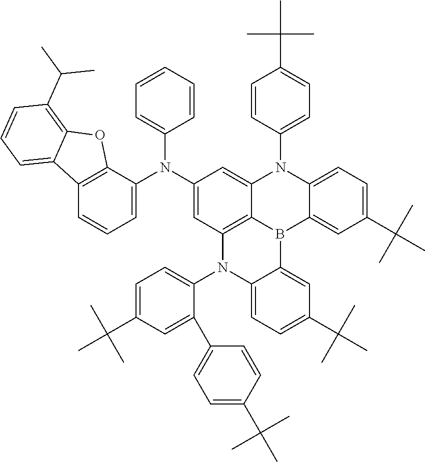 [SMILES: CC(C)c1cccc2c1oc1c(N(c3ccccc3)c3cc4c5c(c3)N(c3ccc(C(C)(C)C)cc3-c3ccc(C(C)(C)C)cc3)c3ccc(C(C)(C)C)cc3B5c3cc(C(C)(C)C)ccc3N4c3ccc(C(C)(C)C)cc3)cccc12]

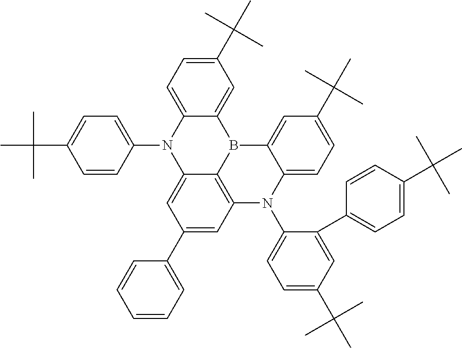 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(-c5ccccc5)cc2c43)cc1]

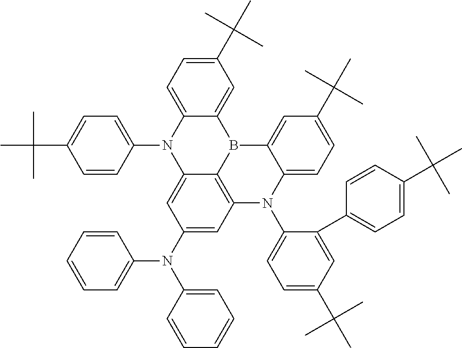 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

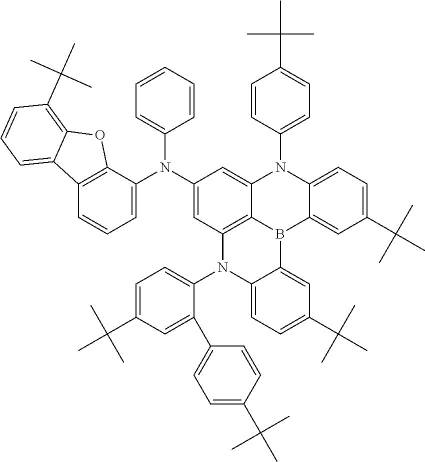 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccccc5)c5cccc6c5oc5c(C(C)(C)C)cccc56)cc2c43)cc1]

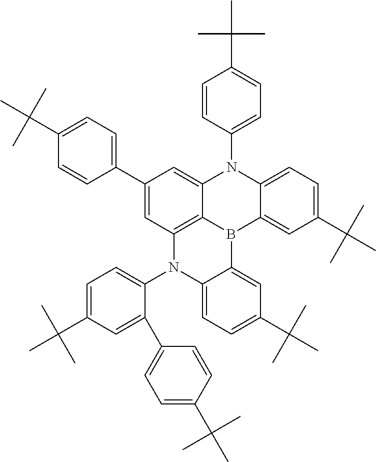 [SMILES: CC(C)(C)c1ccc(-c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)cc1]

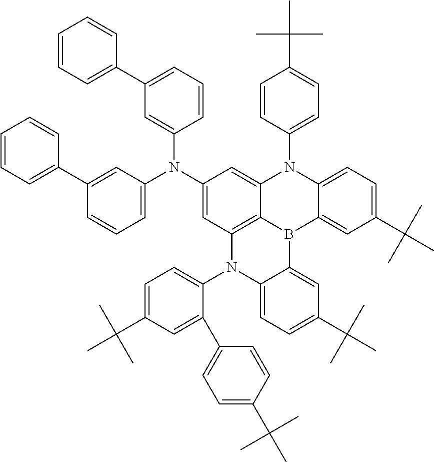 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5cccc(-c6ccccc6)c5)c5cccc(-c6ccccc6)c5)cc2c43)cc1]

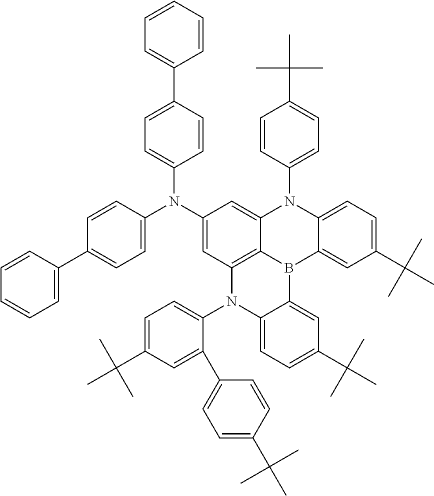 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc(-c6ccccc6)cc5)c5ccc(-c6ccccc6)cc5)cc2c43)cc1]

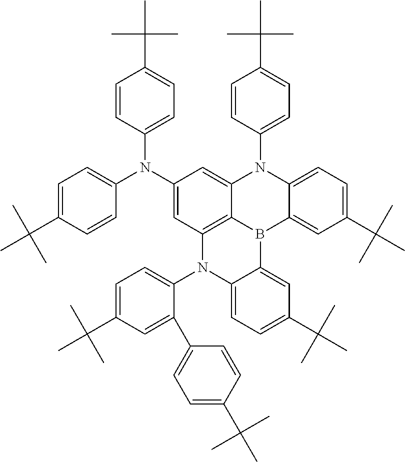 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc(C(C)(C)C)cc5)c5ccc(C(C)(C)C)cc5)cc2c43)cc1]

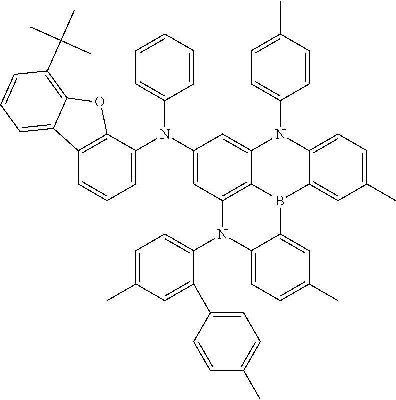 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5c(C(C)(C)C)cccc56)cc2c43)cc1]

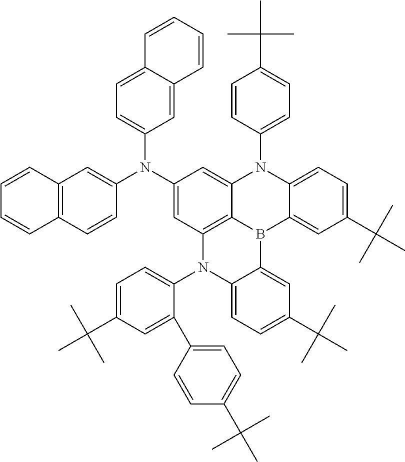 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5ccc6ccccc6c5)c5ccc6ccccc6c5)cc2c43)cc1]

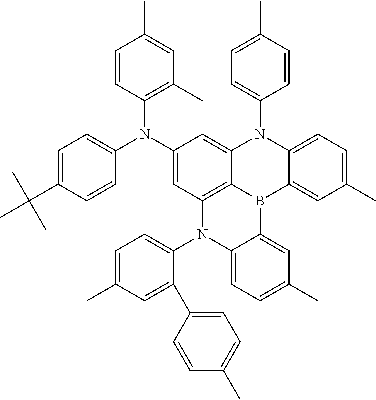 [SMILES: Cc1ccc(-c2cc(C)ccc2N2c3ccc(C)cc3B3c4cc(C)ccc4N(c4ccc(C)cc4)c4cc(N(c5ccc(C(C)(C)C)cc5)c5ccc(C)cc5C)cc2c43)cc1]

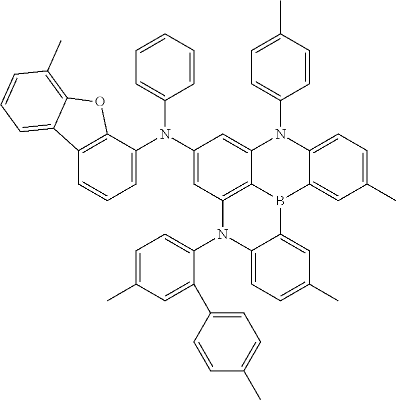 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5c(C)cccc56)cc2c43)cc1]

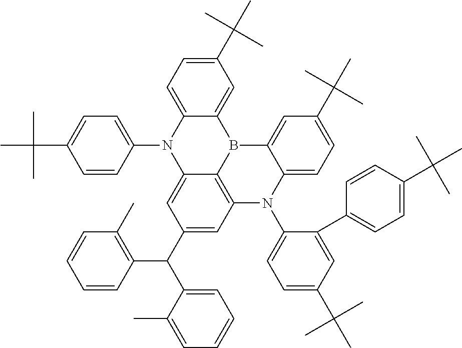 [SMILES: Cc1ccccc1C(c1cc2c3c(c1)N(c1ccc(C(C)(C)C)cc1-c1ccc(C(C)(C)C)cc1)c1ccc(C(C)(C)C)cc1B3c1cc(C(C)(C)C)ccc1N2c1ccc(C(C)(C)C)cc1)c1ccccc1C]

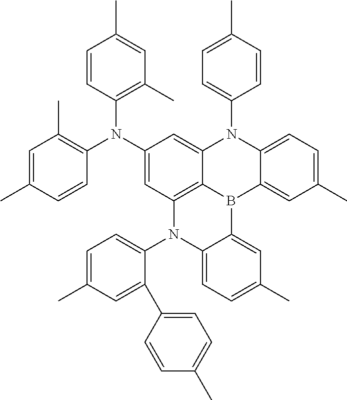

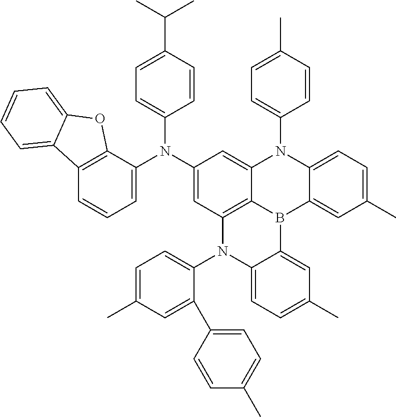 [SMILES: Cc1ccc(-c2cc(C)ccc2N2c3ccc(C)cc3B3c4cc(C)ccc4N(c4ccc(C)cc4)c4cc(N(c5ccc(C(C)C)cc5)c5cccc6c5oc5ccccc56)cc2c43)cc1]

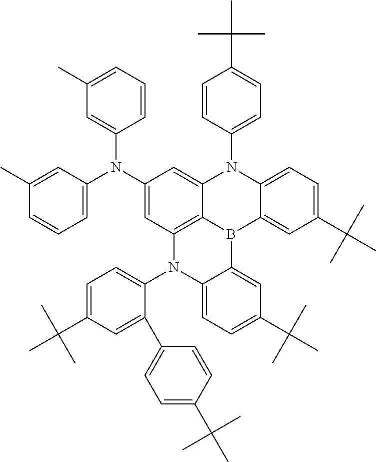 [SMILES: Cc1cccc(N(c2cccc(C)c2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)c1]

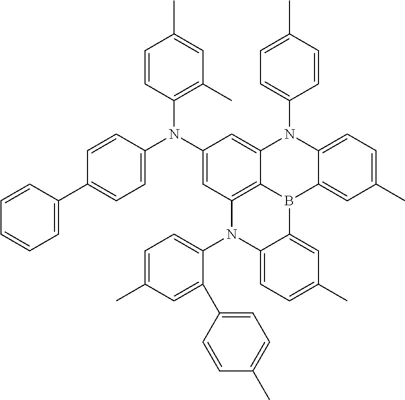 [SMILES: Cc1ccc(-c2cc(C)ccc2N2c3ccc(C)cc3B3c4cc(C)ccc4N(c4ccc(C)cc4)c4cc(N(c5ccc(-c6ccccc6)cc5)c5ccc(C)cc5C)cc2c43)cc1]

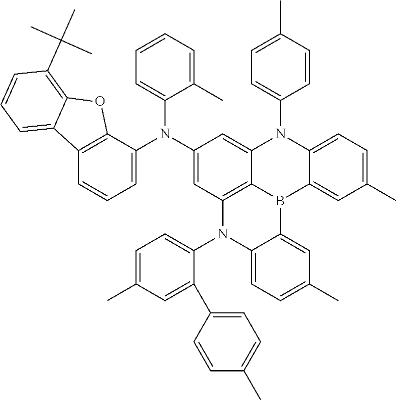 [SMILES: Cc1ccc(-c2cc(C)ccc2N2c3ccc(C)cc3B3c4cc(C)ccc4N(c4ccc(C)cc4)c4cc(N(c5ccccc5C)c5cccc6c5oc5c(C(C)(C)C)cccc56)cc2c43)cc1]

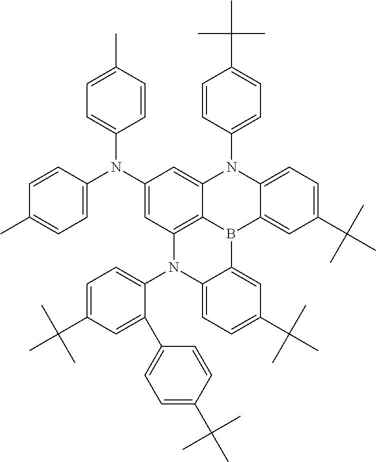 [SMILES: Cc1ccc(N(c2ccc(C)cc2)c2cc3c4c(c2)N(c2ccc(C(C)(C)C)cc2-c2ccc(C(C)(C)C)cc2)c2ccc(C(C)(C)C)cc2B4c2cc(C(C)(C)C)ccc2N3c2ccc(C(C)(C)C)cc2)cc1]

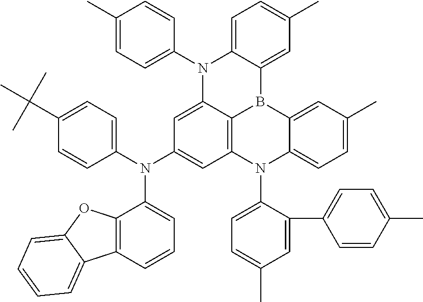 [SMILES: Cc1ccc(-c2cc(C)ccc2N2c3ccc(C)cc3B3c4cc(C)ccc4N(c4ccc(C)cc4)c4cc(N(c5ccc(C(C)(C)C)cc5)c5cccc6c5oc5ccccc56)cc2c43)cc1]

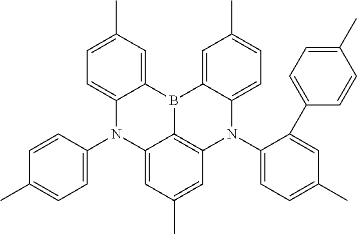

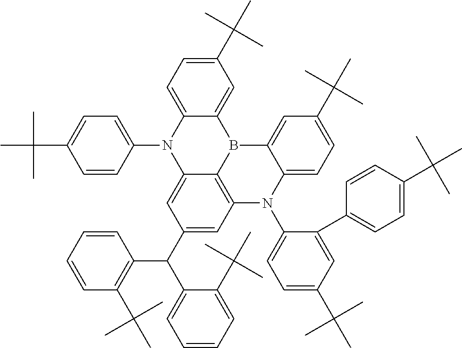 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(C(c5ccccc5C(C)(C)C)c5ccccc5C(C)(C)C)cc2c43)cc1]

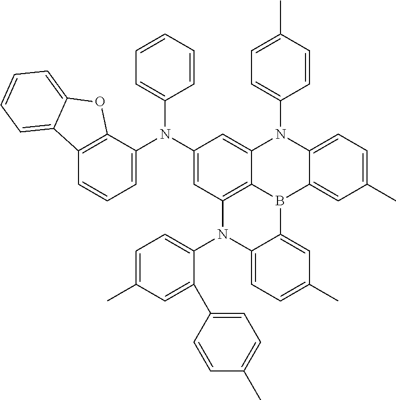 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5ccccc56)cc2c43)cc1]

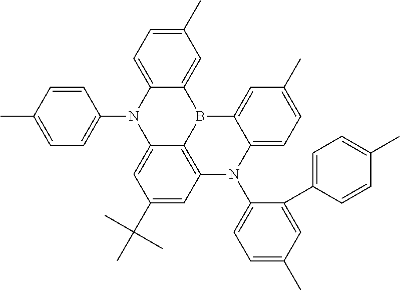

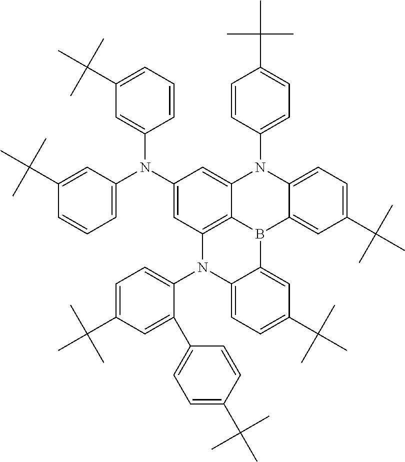 [SMILES: CC(C)(C)c1ccc(-c2cc(C(C)(C)C)ccc2N2c3ccc(C(C)(C)C)cc3B3c4cc(C(C)(C)C)ccc4N(c4ccc(C(C)(C)C)cc4)c4cc(N(c5cccc(C(C)(C)C)c5)c5cccc(C(C)(C)C)c5)cc2c43)cc1]

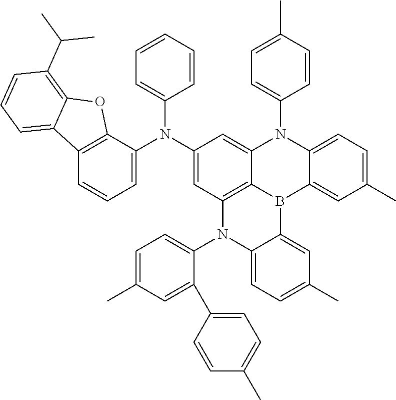 [SMILES: Cc1ccc(-c2cc(C)ccc2N2c3ccc(C)cc3B3c4cc(C)ccc4N(c4ccc(C)cc4)c4cc(N(c5ccccc5)c5cccc6c5oc5c(C(C)C)cccc56)cc2c43)cc1]

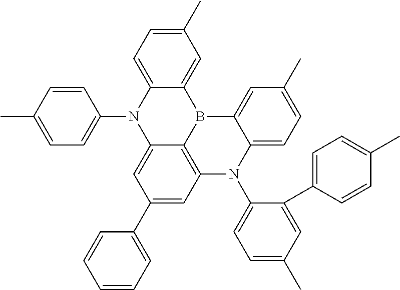

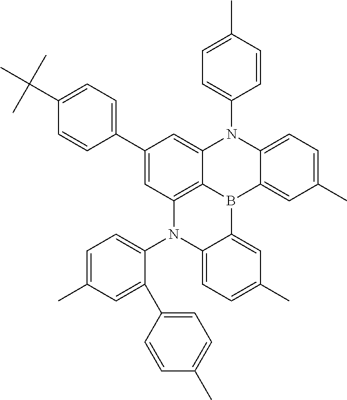 [SMILES: Cc1ccc(-c2cc(C)ccc2N2c3ccc(C)cc3B3c4cc(C)ccc4N(c4ccc(C)cc4)c4cc(-c5ccc(C(C)(C)C)cc5)cc2c43)cc1]

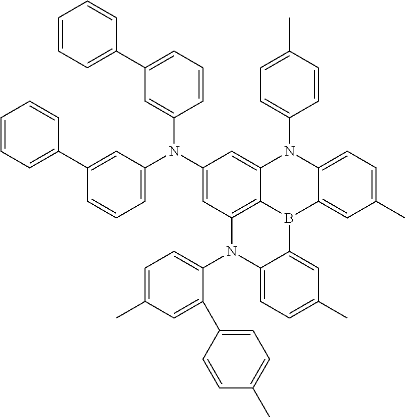 [SMILES: Cc1ccc(-c2cc(C)ccc2N2c3ccc(C)cc3B3c4cc(C)ccc4N(c4ccc(C)cc4)c4cc(N(c5cccc(-c6ccccc6)c5)c5cccc(-c6ccccc6)c5)cc2c43)cc1]

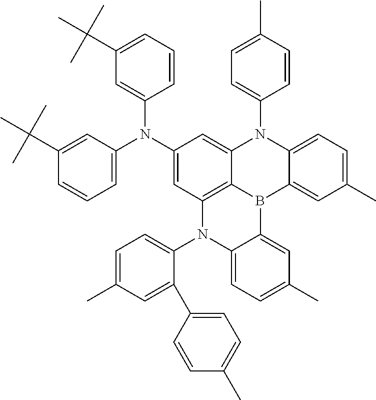 [SMILES: Cc1ccc(-c2cc(C)ccc2N2c3ccc(C)cc3B3c4cc(C)ccc4N(c4ccc(C)cc4)c4cc(N(c5cccc(C(C)(C)C)c5)c5cccc(C(C)(C)C)c5)cc2c43)cc1]

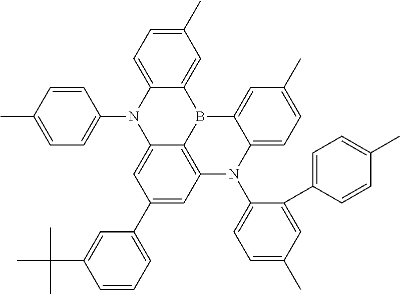

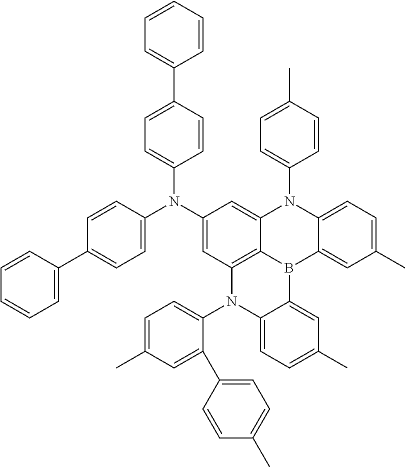 [SMILES: Cc1ccc(-c2cc(C)ccc2N2c3ccc(C)cc3B3c4cc(C)ccc4N(c4ccc(C)cc4)c4cc(N(c5ccc(-c6ccccc6)cc5)c5ccc(-c6ccccc6)cc5)cc2c43)cc1]

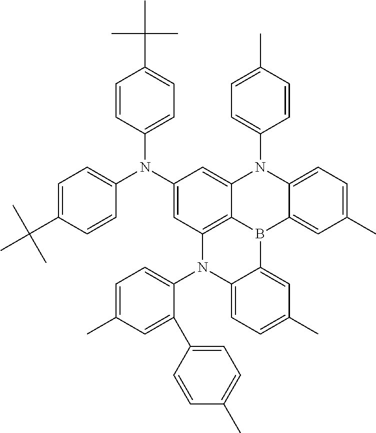 [SMILES: Cc1ccc(-c2cc(C)ccc2N2c3ccc(C)cc3B3c4cc(C)ccc4N(c4ccc(C)cc4)c4cc(N(c5ccc(C(C)(C)C)cc5)c5ccc(C(C)(C)C)cc5)cc2c43)cc1]

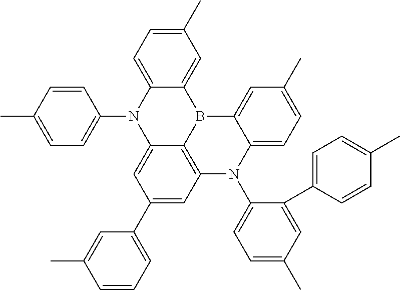

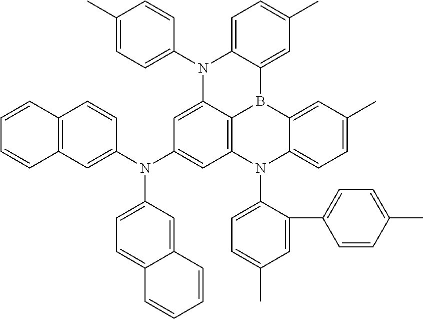 [SMILES: Cc1ccc(-c2cc(C)ccc2N2c3ccc(C)cc3B3c4cc(C)ccc4N(c4ccc(C)cc4)c4cc(N(c5ccc6ccccc6c5)c5ccc6ccccc6c5)cc2c43)cc1]

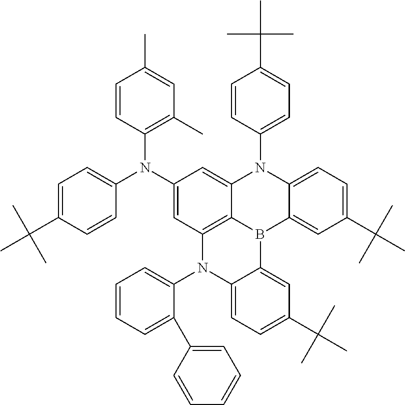 [SMILES: Cc1ccc(N(c2ccc(C(C)(C)C)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c(C)c1]

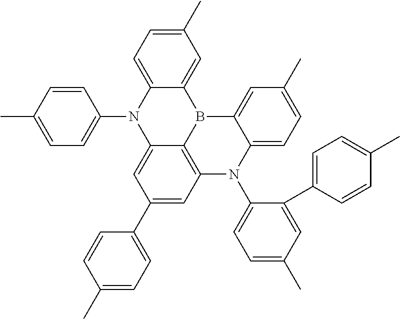

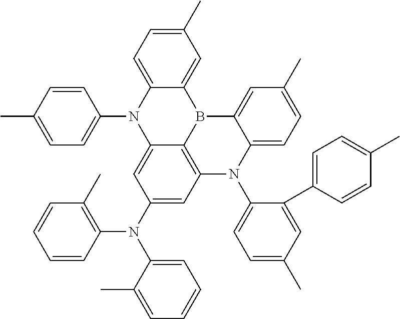

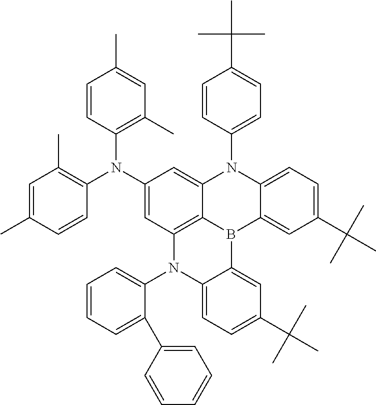 [SMILES: Cc1ccc(N(c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c2ccc(C)cc2C)c(C)c1]

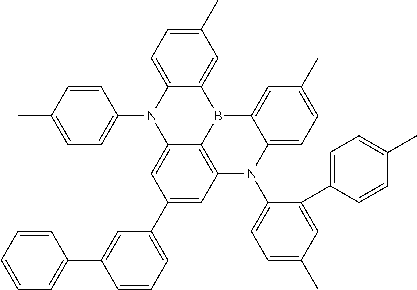 [SMILES: Cc1ccc(-c2cc(C)ccc2N2c3ccc(C)cc3B3c4cc(C)ccc4N(c4ccc(C)cc4)c4cc(-c5cccc(-c6ccccc6)c5)cc2c43)cc1]

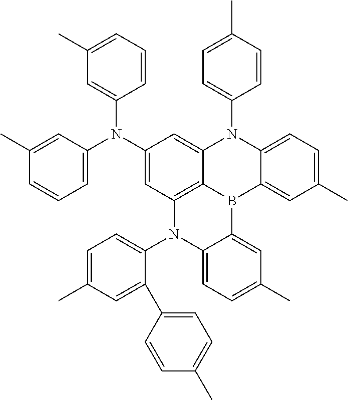

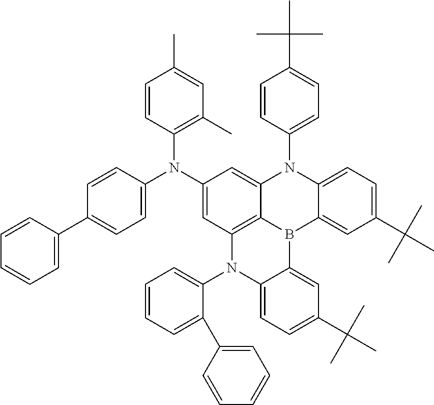 [SMILES: Cc1ccc(N(c2ccc(-c3ccccc3)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c(C)c1]

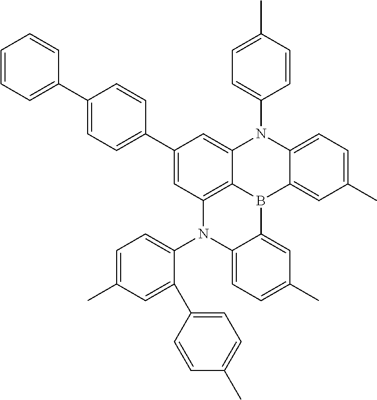 [SMILES: Cc1ccc(-c2cc(C)ccc2N2c3ccc(C)cc3B3c4cc(C)ccc4N(c4ccc(C)cc4)c4cc(-c5ccc(-c6ccccc6)cc5)cc2c43)cc1]

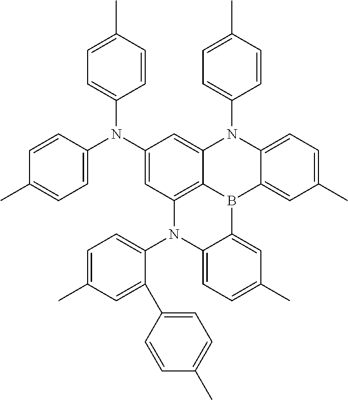

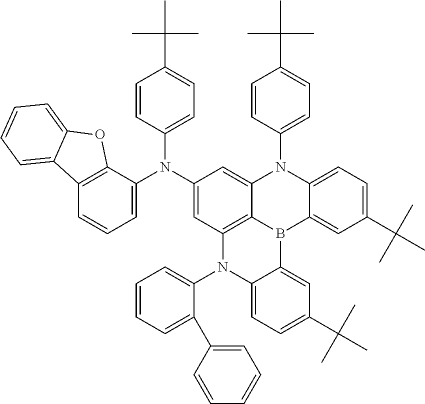 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccc(C(C)(C)C)cc5)c5cccc6c5oc5ccccc56)cc2c43)cc1]

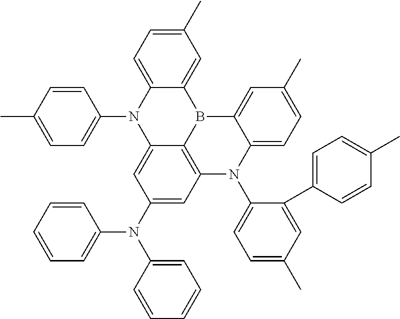

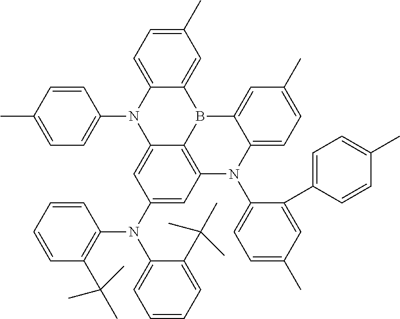

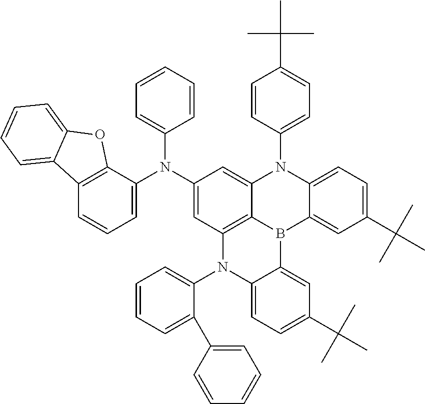 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5)c5cccc6c5oc5ccccc56)cc2c43)cc1]

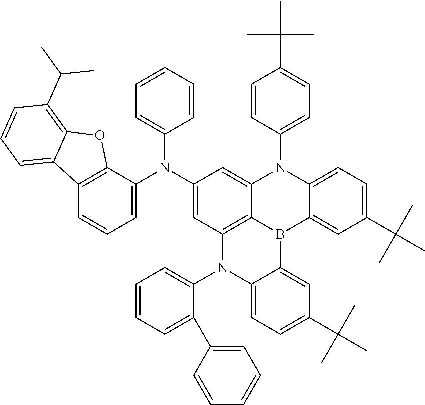 [SMILES: CC(C)c1cccc2c1oc1c(N(c3ccccc3)c3cc4c5c(c3)N(c3ccccc3-c3ccccc3)c3ccc(C(C)(C)C)cc3B5c3cc(C(C)(C)C)ccc3N4c3ccc(C(C)(C)C)cc3)cccc12]

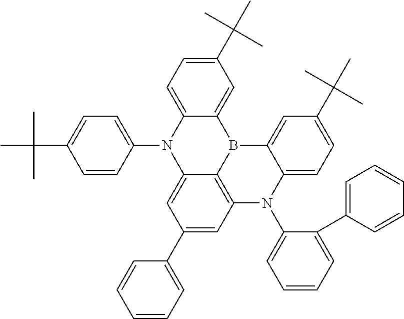 [SMILES: CC(C)(C)c1ccc(N2c3ccc(C(C)(C)C)cc3B3c4cc(C(C)(C)C)ccc4N(c4ccccc4-c4ccccc4)c4cc(-c5ccccc5)cc2c43)cc1]

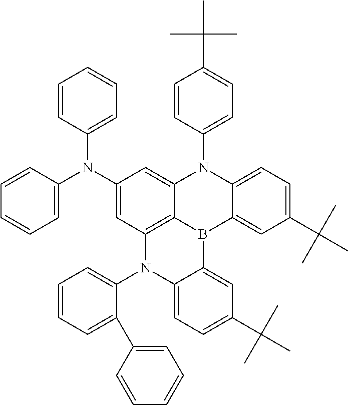 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5)c5ccccc5)cc2c43)cc1]

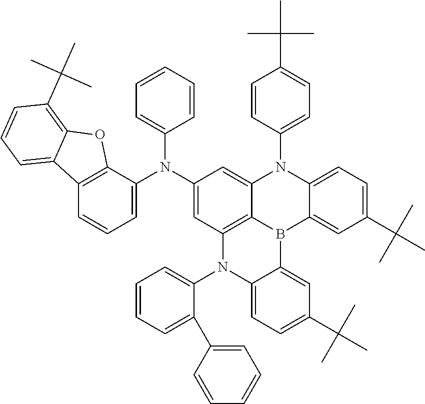 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5)c5cccc6c5oc5c(C(C)(C)C)cccc56)cc2c43)cc1]

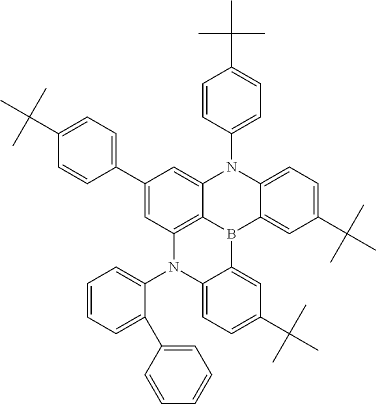 [SMILES: CC(C)(C)c1ccc(-c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

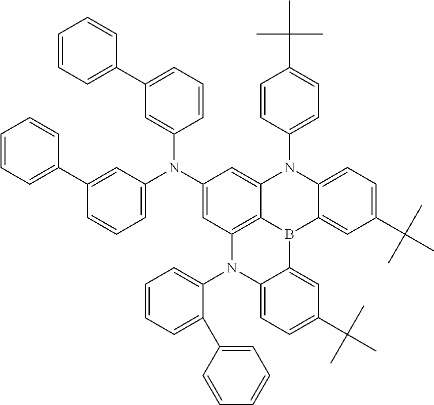 [SMILES: CC(C)(C)c1ccc(N2c3ccc(C(C)(C)C)cc3B3c4cc(C(C)(C)C)ccc4N(c4ccccc4-c4ccccc4)c4cc(N(c5cccc(-c6ccccc6)c5)c5cccc(-c6ccccc6)c5)cc2c43)cc1]

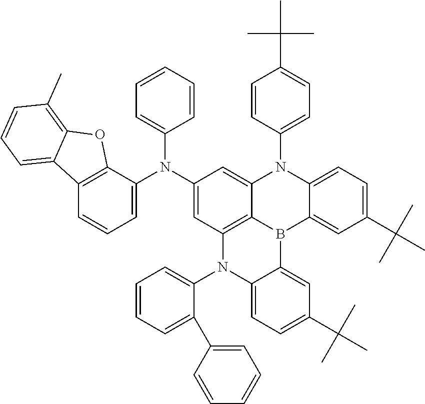 [SMILES: Cc1cccc2c1oc1c(N(c3ccccc3)c3cc4c5c(c3)N(c3ccccc3-c3ccccc3)c3ccc(C(C)(C)C)cc3B5c3cc(C(C)(C)C)ccc3N4c3ccc(C(C)(C)C)cc3)cccc12]

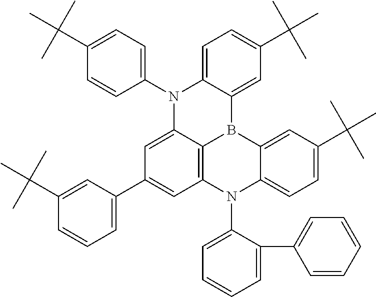 [SMILES: CC(C)(C)c1ccc(N2c3ccc(C(C)(C)C)cc3B3c4cc(C(C)(C)C)ccc4N(c4ccccc4-c4ccccc4)c4cc(-c5cccc(C(C)(C)C)c5)cc2c43)cc1]

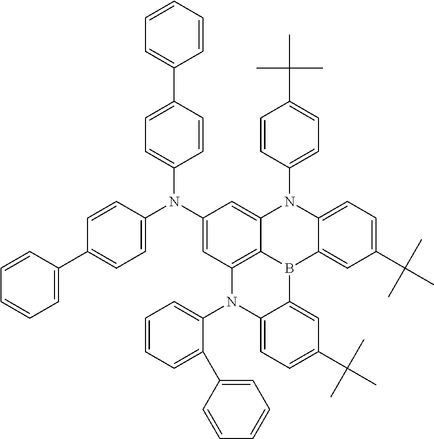 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccc(-c6ccccc6)cc5)c5ccc(-c6ccccc6)cc5)cc2c43)cc1]

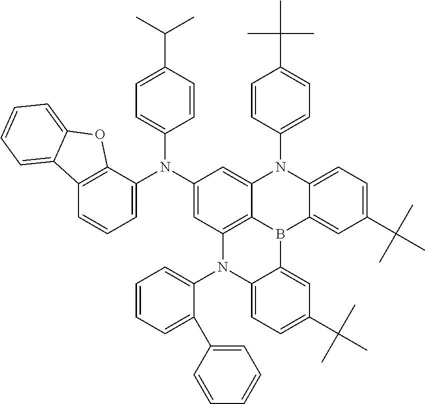 [SMILES: CC(C)c1ccc(N(c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c2cccc3c2oc2ccccc23)cc1]

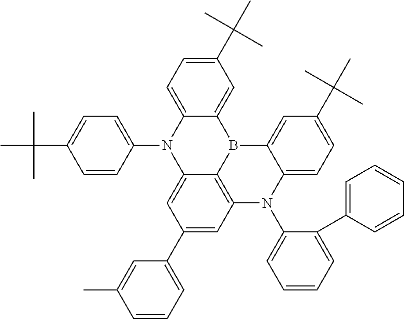 [SMILES: Cc1cccc(-c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c1]

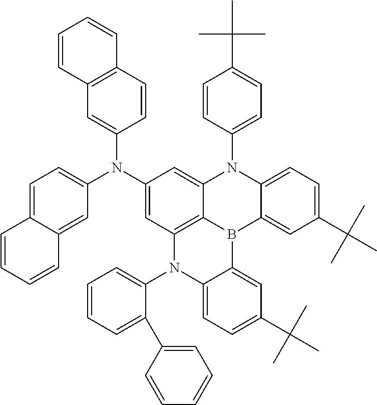 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccc6ccccc6c5)c5ccc6ccccc6c5)cc2c43)cc1]

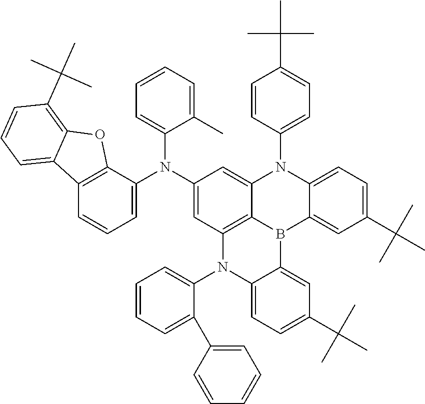 [SMILES: Cc1ccccc1N(c1cc2c3c(c1)N(c1ccccc1-c1ccccc1)c1ccc(C(C)(C)C)cc1B3c1cc(C(C)(C)C)ccc1N2c1ccc(C(C)(C)C)cc1)c1cccc2c1oc1c(C(C)(C)C)cccc12]

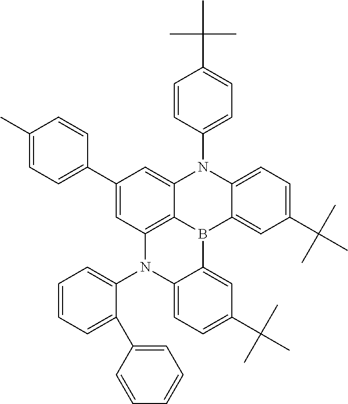 [SMILES: Cc1ccc(-c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

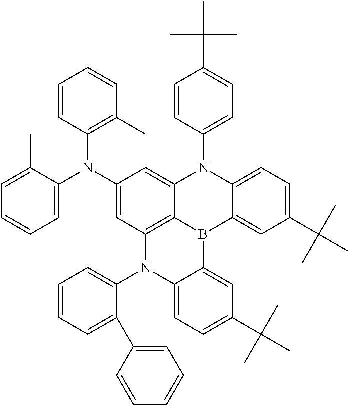 [SMILES: Cc1ccccc1N(c1cc2c3c(c1)N(c1ccccc1-c1ccccc1)c1ccc(C(C)(C)C)cc1B3c1cc(C(C)(C)C)ccc1N2c1ccc(C(C)(C)C)cc1)c1ccccc1C]

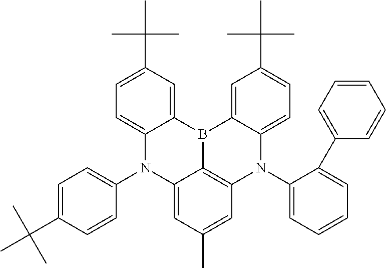 [SMILES: Cc1cc2c3c(c1)N(c1ccccc1-c1ccccc1)c1ccc(C(C)(C)C)cc1B3c1cc(C(C)(C)C)ccc1N2c1ccc(C(C)(C)C)cc1]

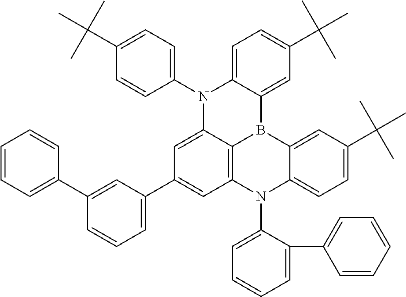 [SMILES: CC(C)(C)c1ccc(N2c3ccc(C(C)(C)C)cc3B3c4cc(C(C)(C)C)ccc4N(c4ccccc4-c4ccccc4)c4cc(-c5cccc(-c6ccccc6)c5)cc2c43)cc1]

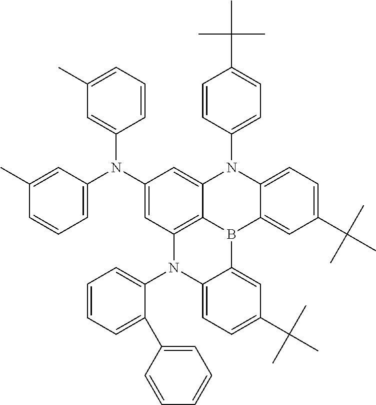 [SMILES: Cc1cccc(N(c2cccc(C)c2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)c1]

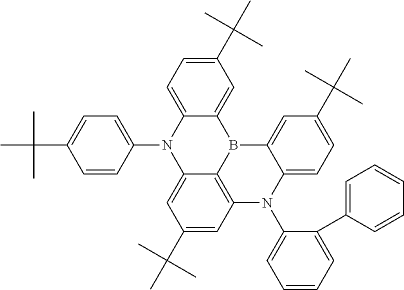 [SMILES: CC(C)(C)c1ccc(N2c3ccc(C(C)(C)C)cc3B3c4cc(C(C)(C)C)ccc4N(c4ccccc4-c4ccccc4)c4cc(C(C)(C)C)cc2c43)cc1]

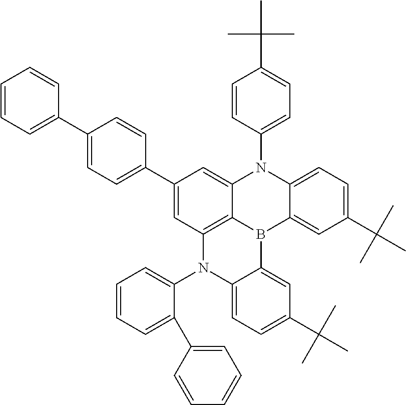 [SMILES: CC(C)(C)c1ccc(N2c3ccc(C(C)(C)C)cc3B3c4cc(C(C)(C)C)ccc4N(c4ccccc4-c4ccccc4)c4cc(-c5ccc(-c6ccccc6)cc5)cc2c43)cc1]

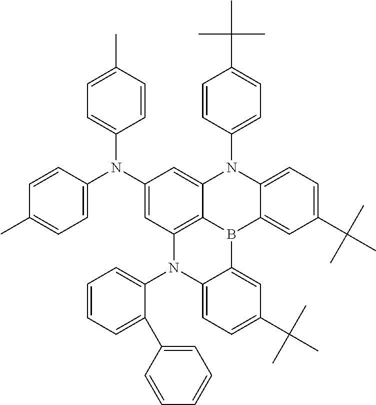 [SMILES: Cc1ccc(N(c2ccc(C)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

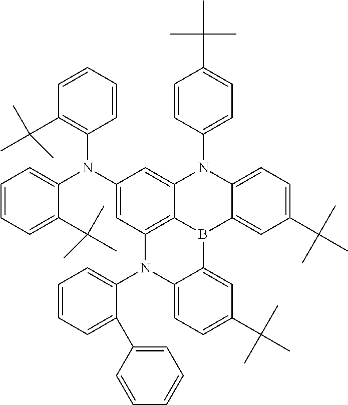 [SMILES: CC(C)(C)c1ccc(N2c3ccc(C(C)(C)C)cc3B3c4cc(C(C)(C)C)ccc4N(c4ccccc4-c4ccccc4)c4cc(N(c5ccccc5C(C)(C)C)c5ccccc5C(C)(C)C)cc2c43)cc1]

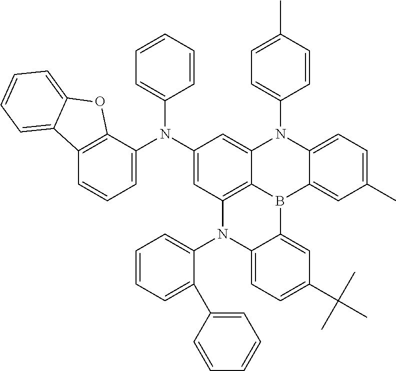 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5ccccc56)cc2c43)cc1]

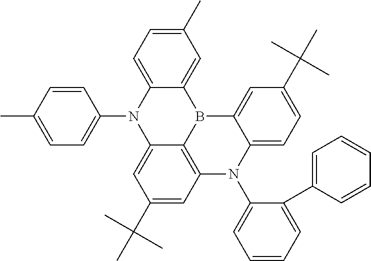 [SMILES: Cc1ccc(N2c3ccc(C)cc3B3c4cc(C(C)(C)C)ccc4N(c4ccccc4-c4ccccc4)c4cc(C(C)(C)C)cc2c43)cc1]

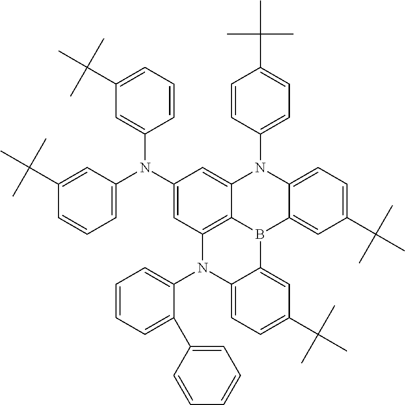 [SMILES: CC(C)(C)c1ccc(N2c3ccc(C(C)(C)C)cc3B3c4cc(C(C)(C)C)ccc4N(c4ccccc4-c4ccccc4)c4cc(N(c5cccc(C(C)(C)C)c5)c5cccc(C(C)(C)C)c5)cc2c43)cc1]

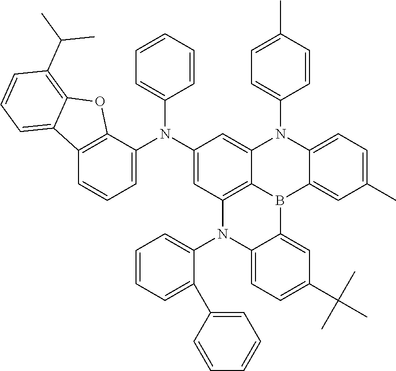 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5c(C(C)C)cccc56)cc2c43)cc1]

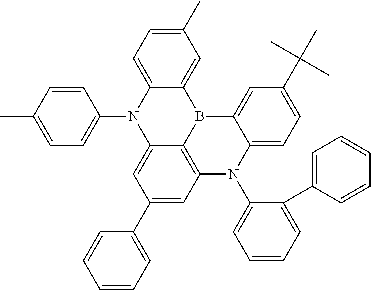 [SMILES: Cc1ccc(N2c3ccc(C)cc3B3c4cc(C(C)(C)C)ccc4N(c4ccccc4-c4ccccc4)c4cc(-c5ccccc5)cc2c43)cc1]

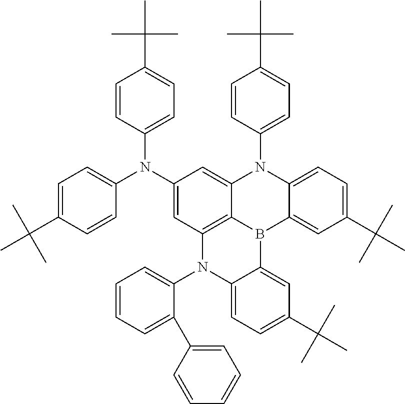 [SMILES: CC(C)(C)c1ccc(N(c2ccc(C(C)(C)C)cc2)c2cc3c4c(c2)N(c2ccccc2-c2ccccc2)c2ccc(C(C)(C)C)cc2B4c2cc(C(C)(C)C)ccc2N3c2ccc(C(C)(C)C)cc2)cc1]

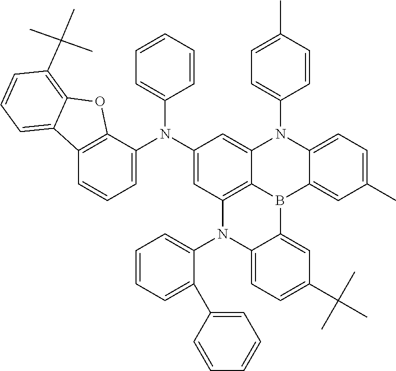 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5c(C(C)(C)C)cccc56)cc2c43)cc1]

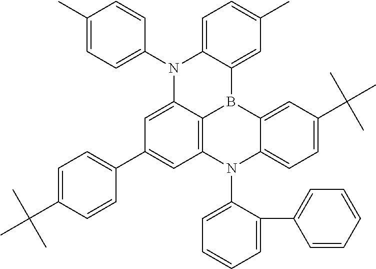 [SMILES: Cc1ccc(N2c3ccc(C)cc3B3c4cc(C(C)(C)C)ccc4N(c4ccccc4-c4ccccc4)c4cc(-c5ccc(C(C)(C)C)cc5)cc2c43)cc1]

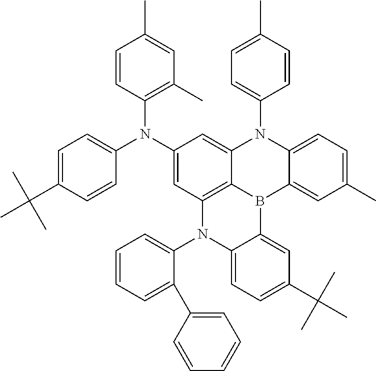 [SMILES: Cc1ccc(N2c3ccc(C)cc3B3c4cc(C(C)(C)C)ccc4N(c4ccccc4-c4ccccc4)c4cc(N(c5ccc(C(C)(C)C)cc5)c5ccc(C)cc5C)cc2c43)cc1]

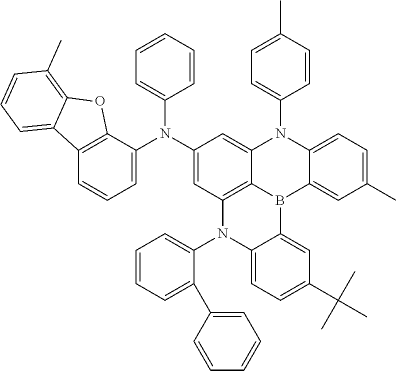 [SMILES: Cc1ccc(N2c3ccc(C)cc3B3c4cc(C(C)(C)C)ccc4N(c4ccccc4-c4ccccc4)c4cc(N(c5ccccc5)c5cccc6c5oc5c(C)cccc56)cc2c43)cc1]

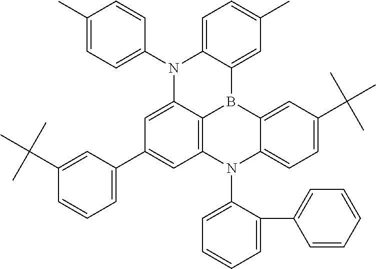 [SMILES: Cc1ccc(N2c3ccc(C)cc3B3c4cc(C(C)(C)C)ccc4N(c4ccccc4-c4ccccc4)c4cc(-c5cccc(C(C)(C)C)c5)cc2c43)cc1]

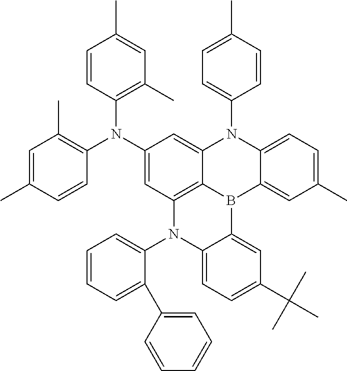

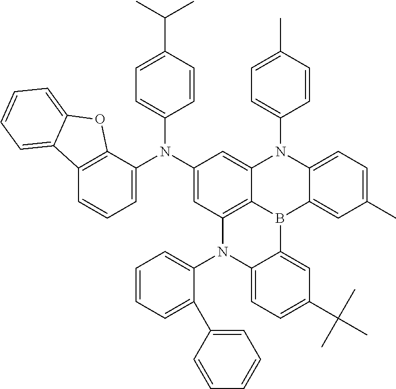 [SMILES: Cc1ccc(N2c3ccc(C)cc3B3c4cc(C(C)(C)C)ccc4N(c4ccccc4-c4ccccc4)c4cc(N(c5ccc(C(C)C)cc5)c5cccc6c5oc5ccccc56)cc2c43)cc1]

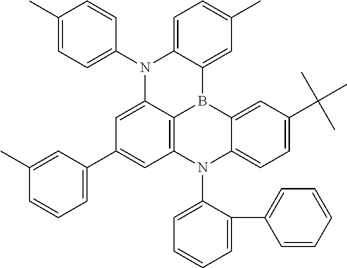 [SMILES: Cc1ccc(N2c3ccc(C)cc3B3c4cc(C(C)(C)C)ccc4N(c4ccccc4-c4ccccc4)c4cc(-c5cccc(C)c5)cc2c43)cc1]

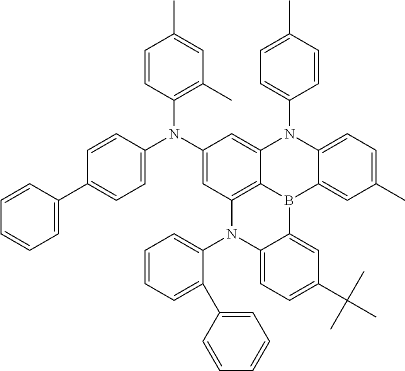 [SMILES: Cc1ccc(N2c3ccc(C)cc3B3c4cc(C(C)(C)C)ccc4N(c4ccccc4-c4ccccc4)c4cc(N(c5ccc(-c6ccccc6)cc5)c5ccc(C)cc5C)cc2c43)cc1]

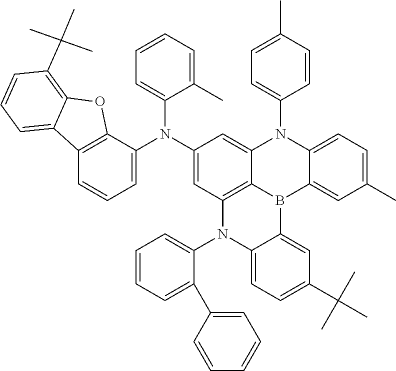 [SMILES: Cc1ccc(N2c3ccc(C)cc3B3c4cc(C(C)(C)C)ccc4N(c4ccccc4-c4ccccc4)c4cc(N(c5ccccc5C)c5cccc6c5oc5c(C(C)(C)C)cccc56)cc2c43)cc1]

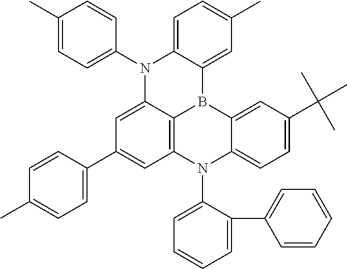 [SMILES: Cc1ccc(-c2cc3c4c(c2)N(c2ccccc2-c2ccccc2)c2ccc(C(C)(C)C)cc2B4c2cc(C)ccc2N3c2ccc(C)cc2)cc1]

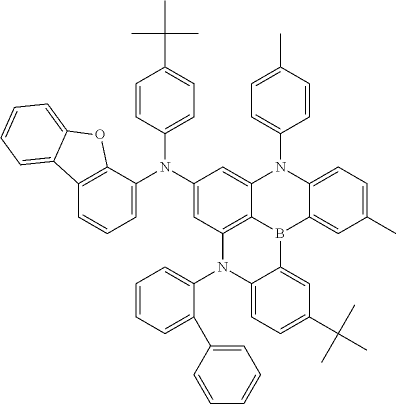 [SMILES: Cc1ccc(N2c3ccc(C)cc3B3c4cc(C(C)(C)C)ccc4N(c4ccccc4-c4ccccc4)c4cc(N(c5ccc(C(C)(C)C)cc5)c5cccc6c5oc5ccccc56)cc2c43)cc1]

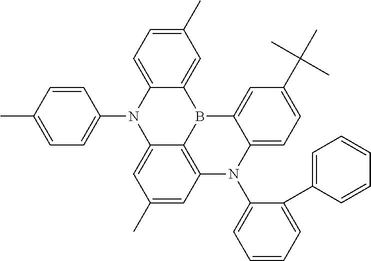 [SMILES: Cc1ccc(N2c3ccc(C)cc3B3c4cc(C(C)(C)C)ccc4N(c4ccccc4-c4ccccc4)c4cc(C)cc2c43)cc1]

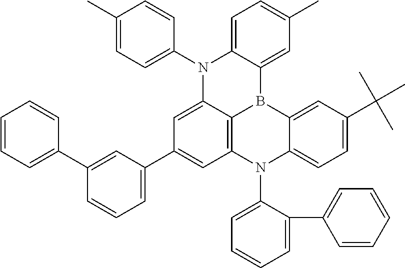 [SMILES: Cc1ccc(N2c3ccc(C)cc3B3c4cc(C(C)(C)C)ccc4N(c4ccccc4-c4ccccc4)c4cc(-c5cccc(-c6ccccc6)c5)cc2c43)cc1]

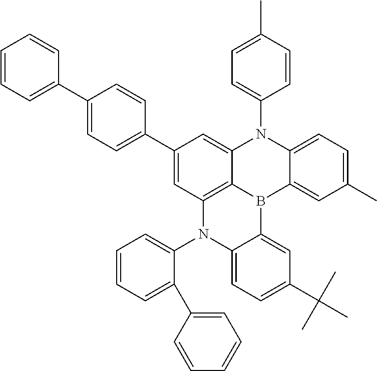 [SMILES: Cc1ccc(N2c3ccc(C)cc3B3c4cc(C(C)(C)C)ccc4N(c4ccccc4-c4ccccc4)c4cc(-c5ccc(-c6ccccc6)cc5)cc2c43)cc1]

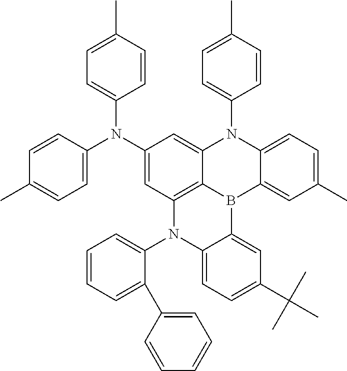

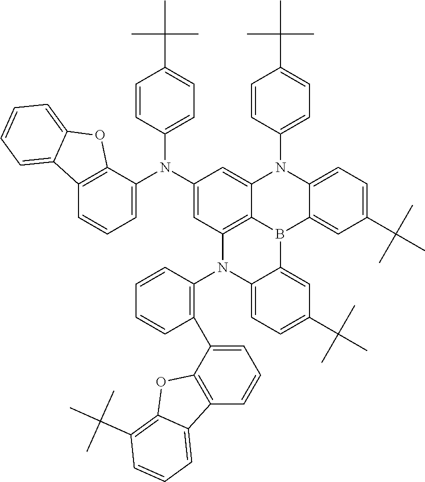 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccc(C(C)(C)C)cc5)c5cccc6c5oc5ccccc56)cc2c43)cc1]

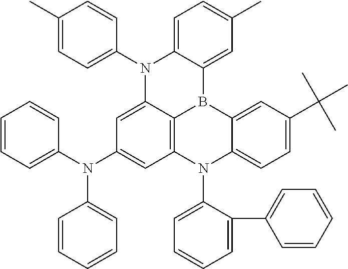 [SMILES: Cc1ccc(N2c3ccc(C)cc3B3c4cc(C(C)(C)C)ccc4N(c4ccccc4-c4ccccc4)c4cc(N(c5ccccc5)c5ccccc5)cc2c43)cc1]

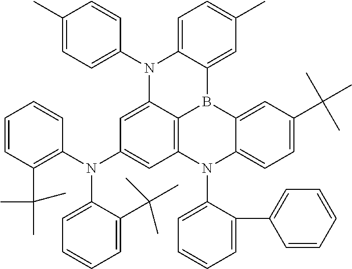 [SMILES: Cc1ccc(N2c3ccc(C)cc3B3c4cc(C(C)(C)C)ccc4N(c4ccccc4-c4ccccc4)c4cc(N(c5ccccc5C(C)(C)C)c5ccccc5C(C)(C)C)cc2c43)cc1]

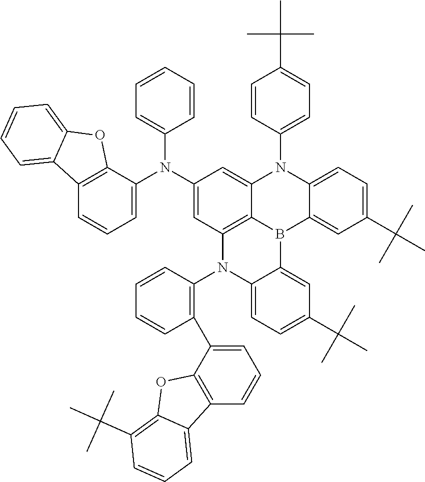 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5)c5cccc6c5oc5ccccc56)cc2c43)cc1]

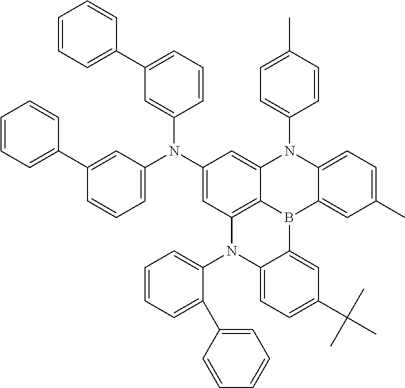 [SMILES: Cc1ccc(N2c3ccc(C)cc3B3c4cc(C(C)(C)C)ccc4N(c4ccccc4-c4ccccc4)c4cc(N(c5cccc(-c6ccccc6)c5)c5cccc(-c6ccccc6)c5)cc2c43)cc1]

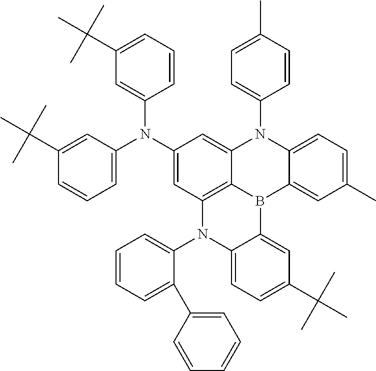 [SMILES: Cc1ccc(N2c3ccc(C)cc3B3c4cc(C(C)(C)C)ccc4N(c4ccccc4-c4ccccc4)c4cc(N(c5cccc(C(C)(C)C)c5)c5cccc(C(C)(C)C)c5)cc2c43)cc1]

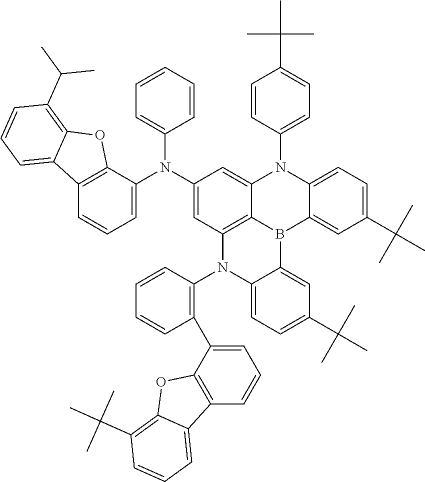 [SMILES: CC(C)c1cccc2c1oc1c(N(c3ccccc3)c3cc4c5c(c3)N(c3ccccc3-c3cccc6c3oc3c(C(C)(C)C)cccc36)c3ccc(C(C)(C)C)cc3B5c3cc(C(C)(C)C)ccc3N4c3ccc(C(C)(C)C)cc3)cccc12]

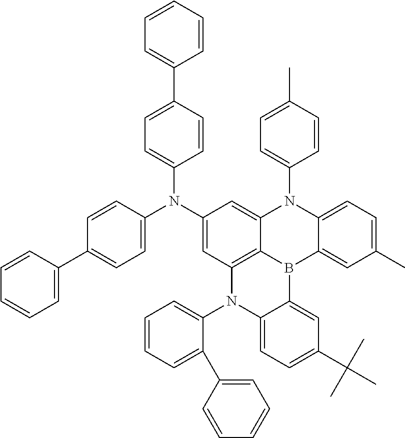 [SMILES: Cc1ccc(N2c3ccc(C)cc3B3c4cc(C(C)(C)C)ccc4N(c4ccccc4-c4ccccc4)c4cc(N(c5ccc(-c6ccccc6)cc5)c5ccc(-c6ccccc6)cc5)cc2c43)cc1]

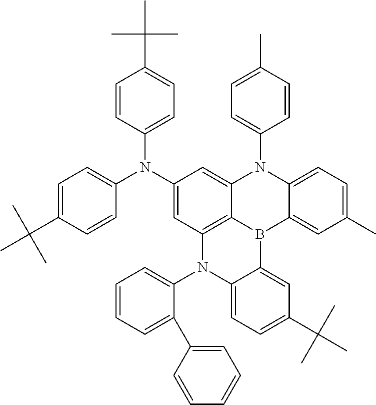 [SMILES: Cc1ccc(N2c3ccc(C)cc3B3c4cc(C(C)(C)C)ccc4N(c4ccccc4-c4ccccc4)c4cc(N(c5ccc(C(C)(C)C)cc5)c5ccc(C(C)(C)C)cc5)cc2c43)cc1]

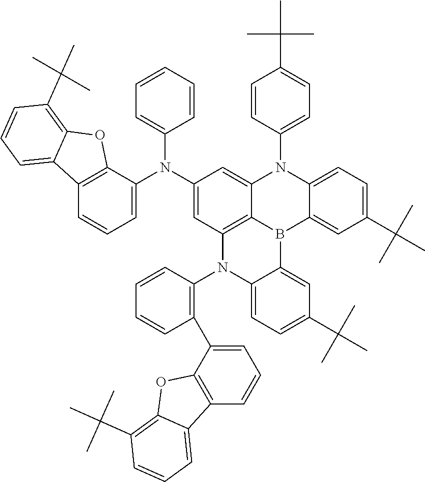 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5)c5cccc6c5oc5c(C(C)(C)C)cccc56)cc2c43)cc1]

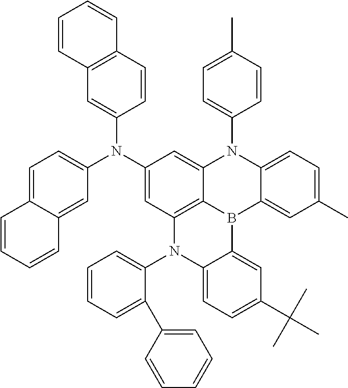 [SMILES: Cc1ccc(N2c3ccc(C)cc3B3c4cc(C(C)(C)C)ccc4N(c4ccccc4-c4ccccc4)c4cc(N(c5ccc6ccccc6c5)c5ccc6ccccc6c5)cc2c43)cc1]

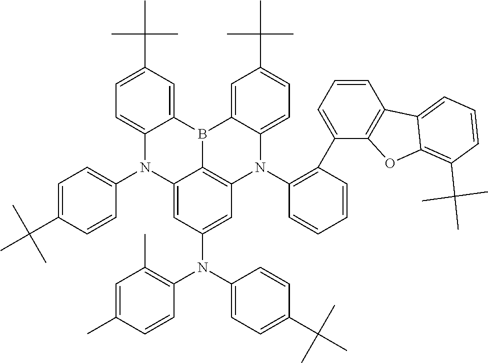 [SMILES: Cc1ccc(N(c2ccc(C(C)(C)C)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c(C)c1]

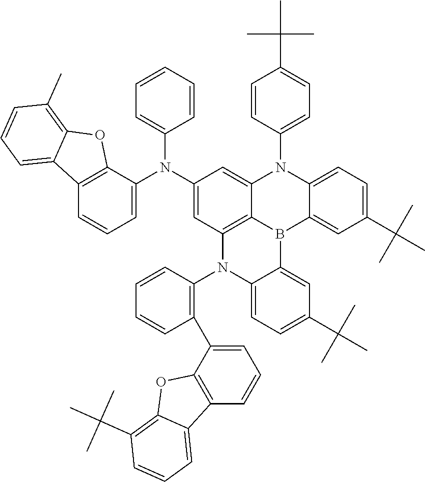 [SMILES: Cc1cccc2c1oc1c(N(c3ccccc3)c3cc4c5c(c3)N(c3ccccc3-c3cccc6c3oc3c(C(C)(C)C)cccc36)c3ccc(C(C)(C)C)cc3B5c3cc(C(C)(C)C)ccc3N4c3ccc(C(C)(C)C)cc3)cccc12]

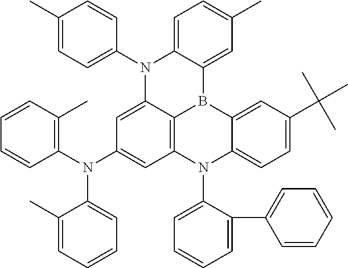 [SMILES: Cc1ccc(N2c3ccc(C)cc3B3c4cc(C(C)(C)C)ccc4N(c4ccccc4-c4ccccc4)c4cc(N(c5ccccc5C)c5ccccc5C)cc2c43)cc1]

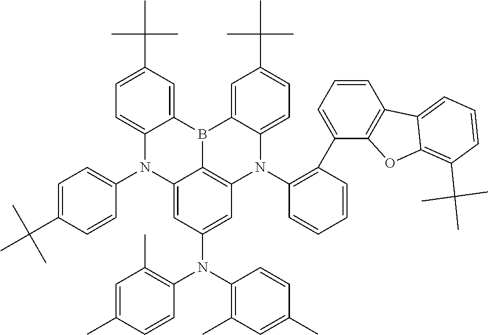 [SMILES: Cc1ccc(N(c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c2ccc(C)cc2C)c(C)c1]

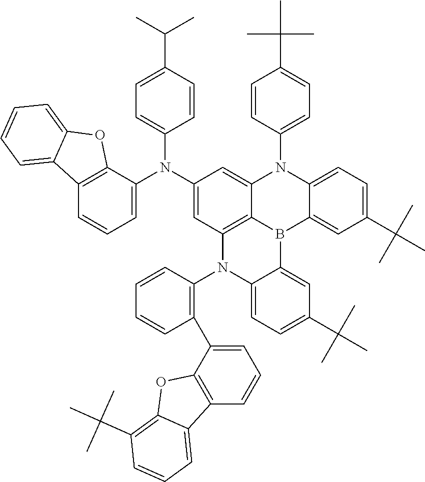 [SMILES: CC(C)c1ccc(N(c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c2cccc3c2oc2ccccc23)cc1]

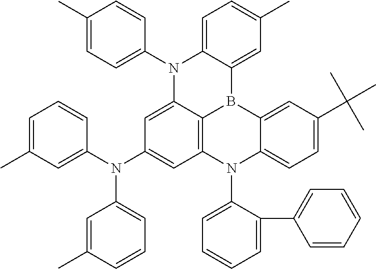 [SMILES: Cc1ccc(N2c3ccc(C)cc3B3c4cc(C(C)(C)C)ccc4N(c4ccccc4-c4ccccc4)c4cc(N(c5cccc(C)c5)c5cccc(C)c5)cc2c43)cc1]

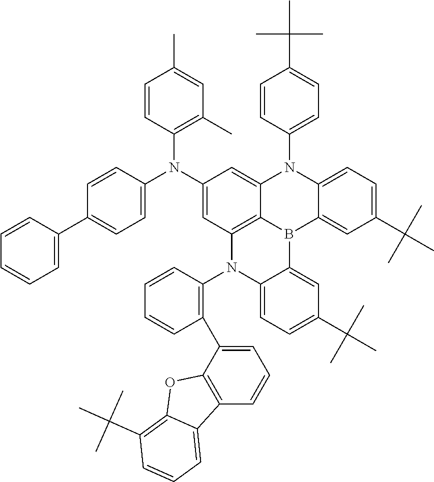 [SMILES: Cc1ccc(N(c2ccc(-c3ccccc3)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c(C)c1]

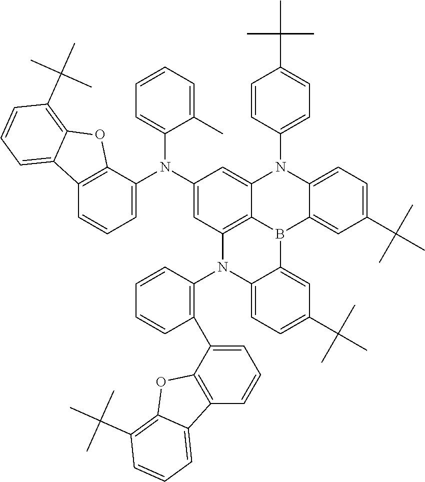 [SMILES: Cc1ccccc1N(c1cc2c3c(c1)N(c1ccccc1-c1cccc4c1oc1c(C(C)(C)C)cccc14)c1ccc(C(C)(C)C)cc1B3c1cc(C(C)(C)C)ccc1N2c1ccc(C(C)(C)C)cc1)c1cccc2c1oc1c(C(C)(C)C)cccc12]

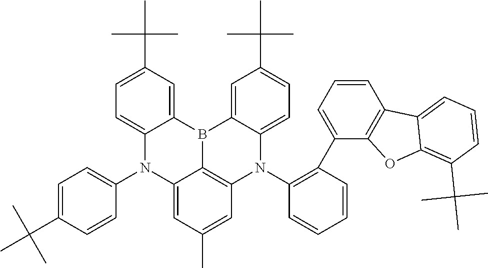 [SMILES: Cc1cc2c3c(c1)N(c1ccccc1-c1cccc4c1oc1c(C(C)(C)C)cccc14)c1ccc(C(C)(C)C)cc1B3c1cc(C(C)(C)C)ccc1N2c1ccc(C(C)(C)C)cc1]

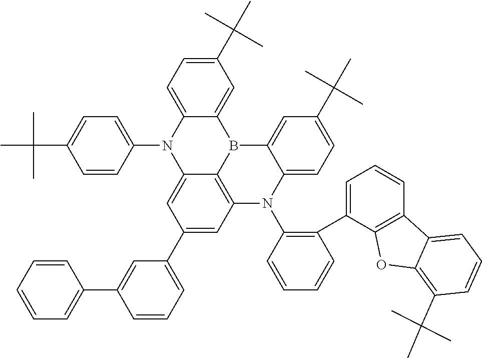 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5cccc(-c6ccccc6)c5)cc2c43)cc1]

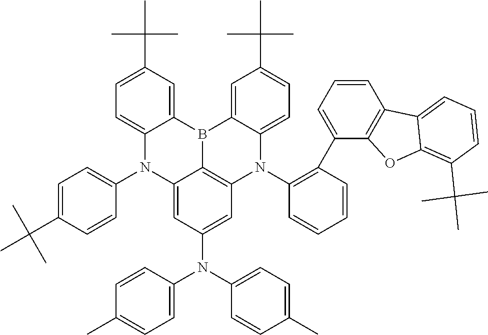 [SMILES: Cc1ccc(N(c2ccc(C)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

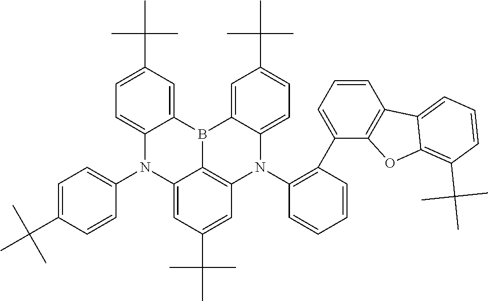 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(C(C)(C)C)cc2c43)cc1]

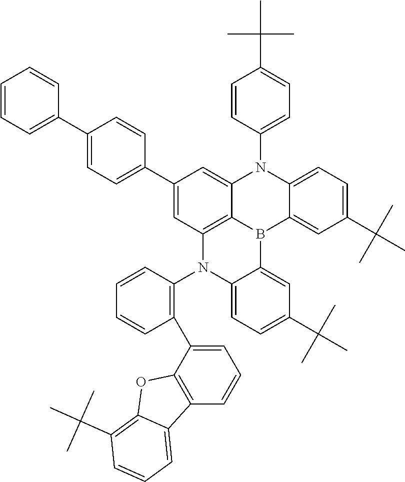 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5ccc(-c6ccccc6)cc5)cc2c43)cc1]

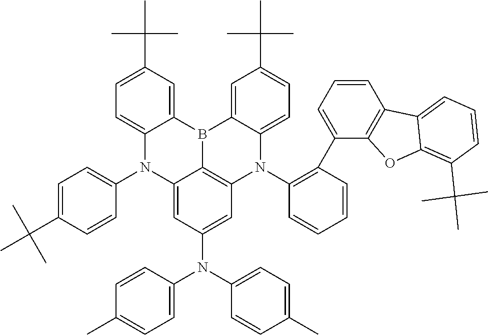 [SMILES: Cc1ccc(N(c2ccc(C)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

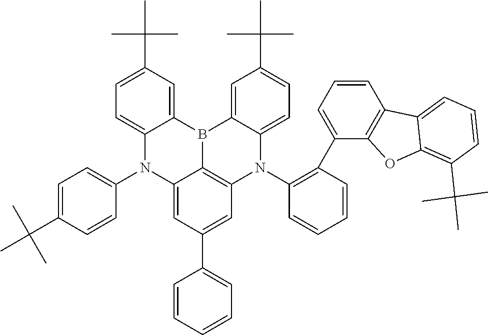 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5ccccc5)cc2c43)cc1]

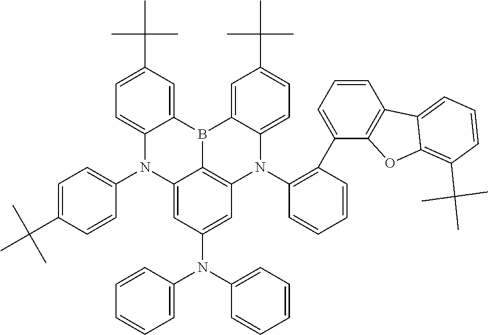 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5)c5ccccc5)cc2c43)cc1]

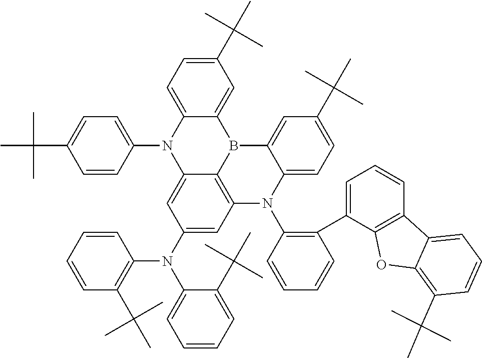 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccccc5C(C)(C)C)c5ccccc5C(C)(C)C)cc2c43)cc1]

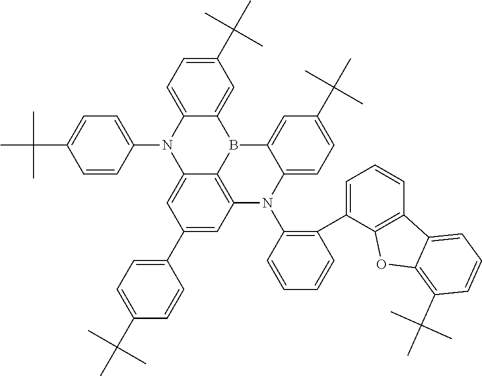 [SMILES: CC(C)(C)c1ccc(-c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

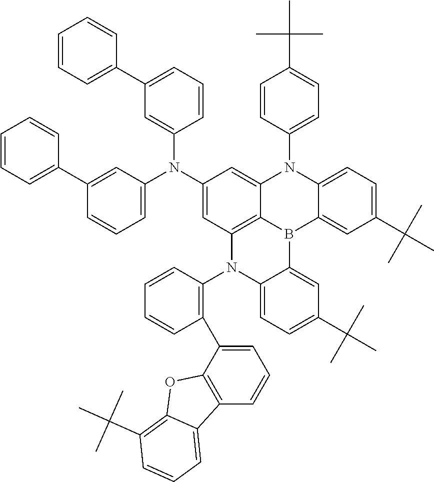 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5cccc(-c6ccccc6)c5)c5cccc(-c6ccccc6)c5)cc2c43)cc1]

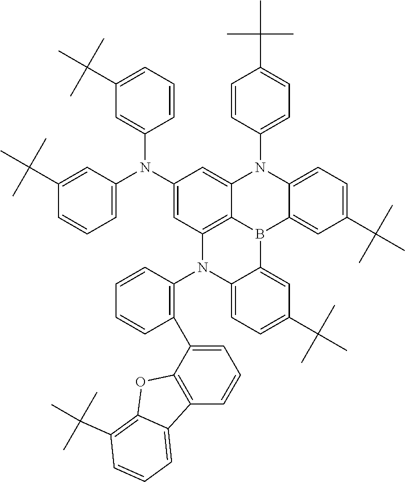 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5cccc(C(C)(C)C)c5)c5cccc(C(C)(C)C)c5)cc2c43)cc1]

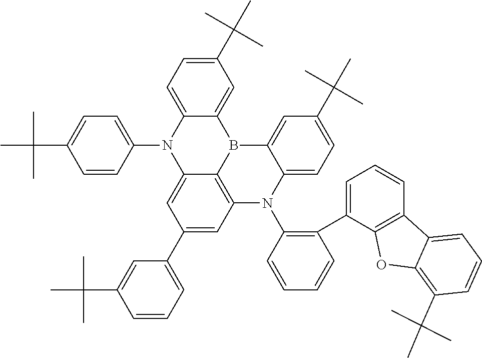 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(-c5cccc(C(C)(C)C)c5)cc2c43)cc1]

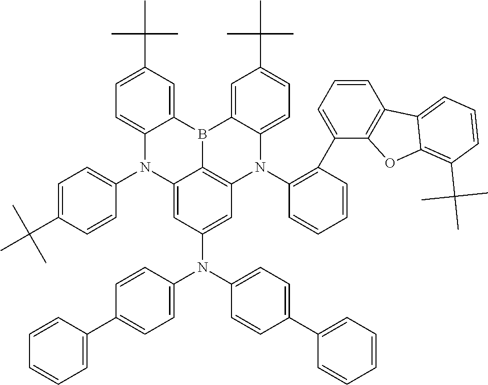 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccc(-c6ccccc6)cc5)c5ccc(-c6ccccc6)cc5)cc2c43)cc1]

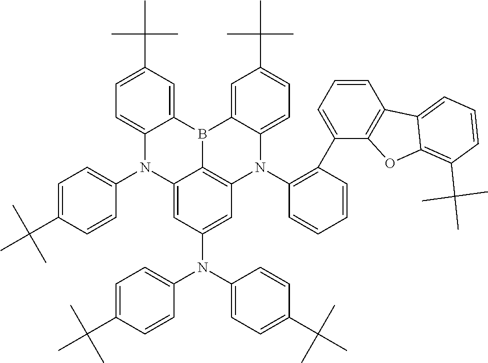 [SMILES: CC(C)(C)c1ccc(N(c2ccc(C(C)(C)C)cc2)c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

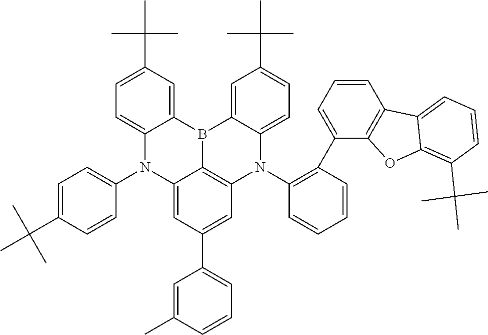 [SMILES: Cc1cccc(-c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)c1]

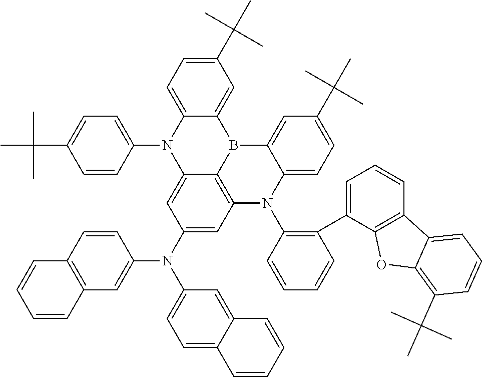 [SMILES: CC(C)(C)c1ccc(N2c3ccc(C(C)(C)C)cc3B3c4cc(C(C)(C)C)ccc4N(c4ccccc4-c4cccc5c4oc4c(C(C)(C)C)cccc45)c4cc(N(c5ccc6ccccc6c5)c5ccc6ccccc6c5)cc2c43)cc1]

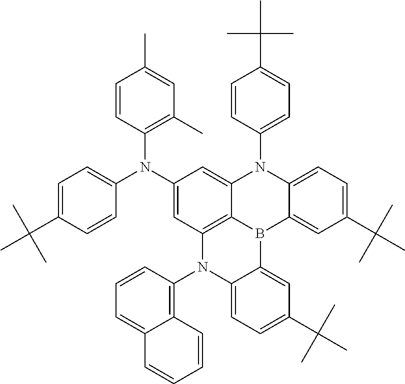 [SMILES: Cc1ccc(N(c2ccc(C(C)(C)C)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)c(C)c1]

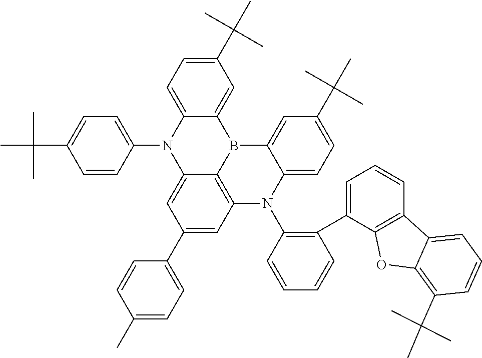 [SMILES: Cc1ccc(-c2cc3c4c(c2)N(c2ccccc2-c2cccc5c2oc2c(C(C)(C)C)cccc25)c2ccc(C(C)(C)C)cc2B4c2cc(C(C)(C)C)ccc2N3c2ccc(C(C)(C)C)cc2)cc1]

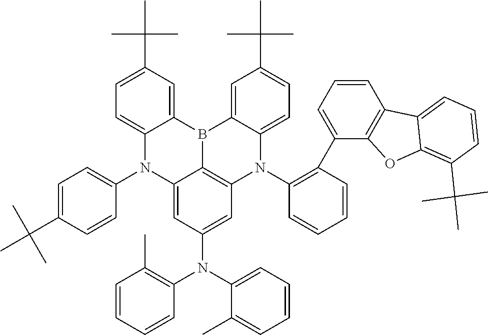 [SMILES: Cc1ccccc1N(c1cc2c3c(c1)N(c1ccccc1-c1cccc4c1oc1c(C(C)(C)C)cccc14)c1ccc(C(C)(C)C)cc1B3c1cc(C(C)(C)C)ccc1N2c1ccc(C(C)(C)C)cc1)c1ccccc1C]

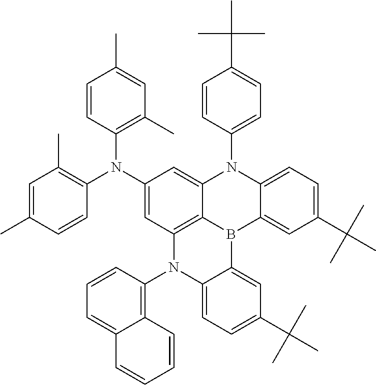 [SMILES: Cc1ccc(N(c2cc3c4c(c2)N(c2cccc5ccccc25)c2ccc(C(C)(C)C)cc2B4c2cc(C(C)(C)C)ccc2N3c2ccc(C(C)(C)C)cc2)c2ccc(C)cc2C)c(C)c1]

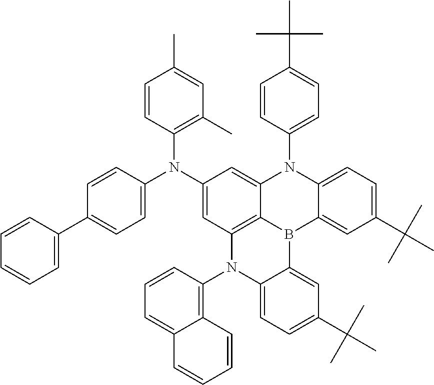 [SMILES: Cc1ccc(N(c2ccc(-c3ccccc3)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)c(C)c1]

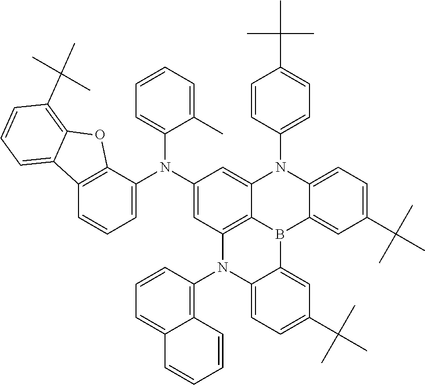 [SMILES: Cc1ccccc1N(c1cc2c3c(c1)N(c1cccc4ccccc14)c1ccc(C(C)(C)C)cc1B3c1cc(C(C)(C)C)ccc1N2c1ccc(C(C)(C)C)cc1)c1cccc2c1oc1c(C(C)(C)C)cccc12]

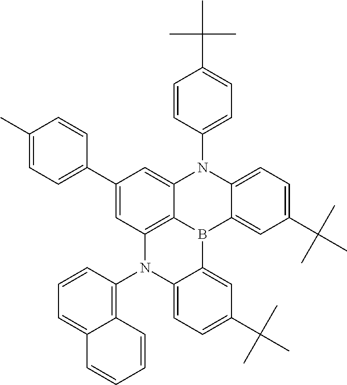 [SMILES: Cc1ccc(-c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

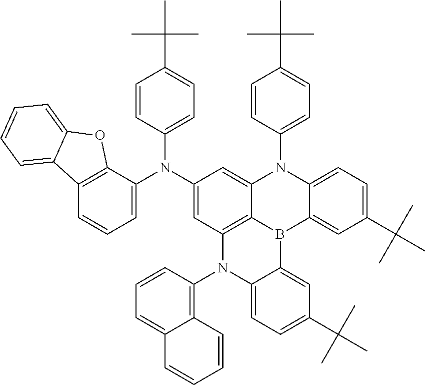 [SMILES: CC(C)(C)c1ccc(N2c3ccc(C(C)(C)C)cc3B3c4cc(C(C)(C)C)ccc4N(c4cccc5ccccc45)c4cc(N(c5ccc(C(C)(C)C)cc5)c5cccc6c5oc5ccccc56)cc2c43)cc1]

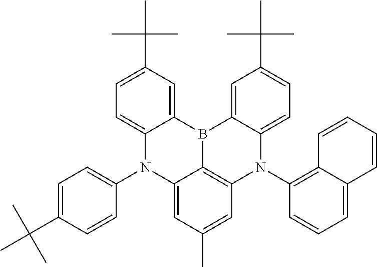 [SMILES: Cc1cc2c3c(c1)N(c1cccc4ccccc14)c1ccc(C(C)(C)C)cc1B3c1cc(C(C)(C)C)ccc1N2c1ccc(C(C)(C)C)cc1]

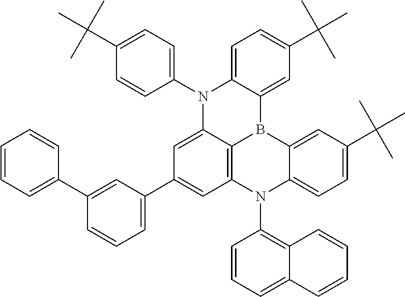 [SMILES: CC(C)(C)c1ccc(N2c3ccc(C(C)(C)C)cc3B3c4cc(C(C)(C)C)ccc4N(c4cccc5ccccc45)c4cc(-c5cccc(-c6ccccc6)c5)cc2c43)cc1]

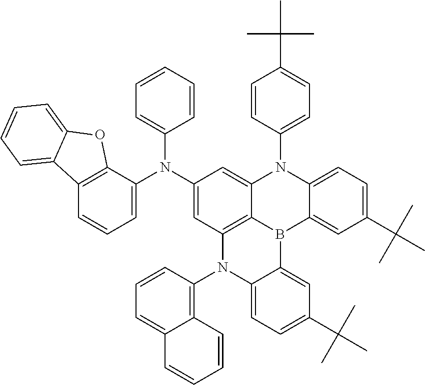 [SMILES: CC(C)(C)c1ccc(N2c3ccc(C(C)(C)C)cc3B3c4cc(C(C)(C)C)ccc4N(c4cccc5ccccc45)c4cc(N(c5ccccc5)c5cccc6c5oc5ccccc56)cc2c43)cc1]

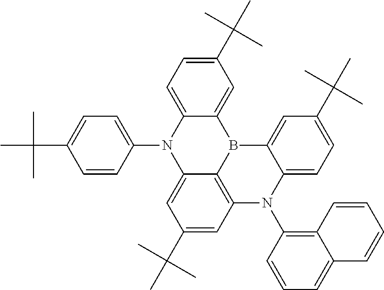 [SMILES: CC(C)(C)c1ccc(N2c3ccc(C(C)(C)C)cc3B3c4cc(C(C)(C)C)ccc4N(c4cccc5ccccc45)c4cc(C(C)(C)C)cc2c43)cc1]

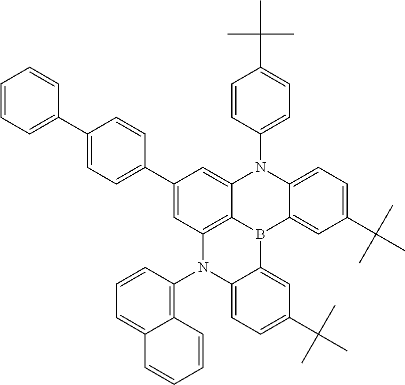 [SMILES: CC(C)(C)c1ccc(N2c3ccc(C(C)(C)C)cc3B3c4cc(C(C)(C)C)ccc4N(c4cccc5ccccc45)c4cc(-c5ccc(-c6ccccc6)cc5)cc2c43)cc1]

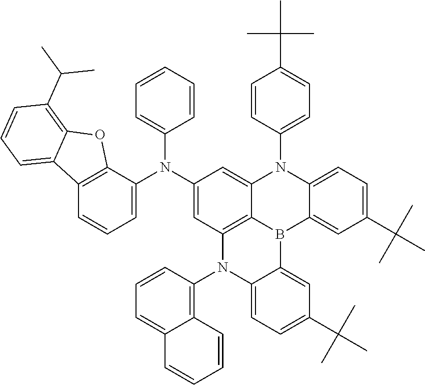 [SMILES: CC(C)c1cccc2c1oc1c(N(c3ccccc3)c3cc4c5c(c3)N(c3cccc6ccccc36)c3ccc(C(C)(C)C)cc3B5c3cc(C(C)(C)C)ccc3N4c3ccc(C(C)(C)C)cc3)cccc12]

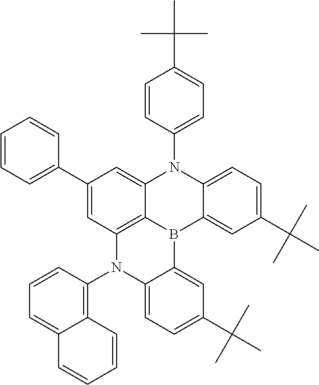 [SMILES: CC(C)(C)c1ccc(N2c3ccc(C(C)(C)C)cc3B3c4cc(C(C)(C)C)ccc4N(c4cccc5ccccc45)c4cc(-c5ccccc5)cc2c43)cc1]

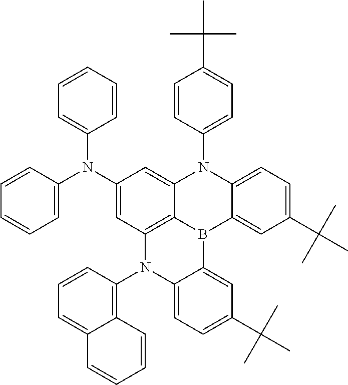 [SMILES: CC(C)(C)c1ccc(N2c3ccc(C(C)(C)C)cc3B3c4cc(C(C)(C)C)ccc4N(c4cccc5ccccc45)c4cc(N(c5ccccc5)c5ccccc5)cc2c43)cc1]

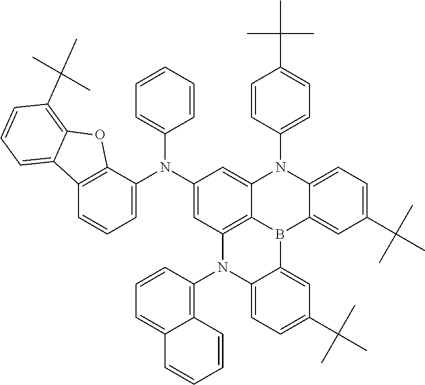 [SMILES: CC(C)(C)c1ccc(N2c3ccc(C(C)(C)C)cc3B3c4cc(C(C)(C)C)ccc4N(c4cccc5ccccc45)c4cc(N(c5ccccc5)c5cccc6c5oc5c(C(C)(C)C)cccc56)cc2c43)cc1]

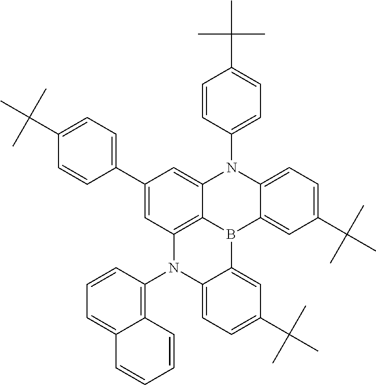 [SMILES: CC(C)(C)c1ccc(-c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

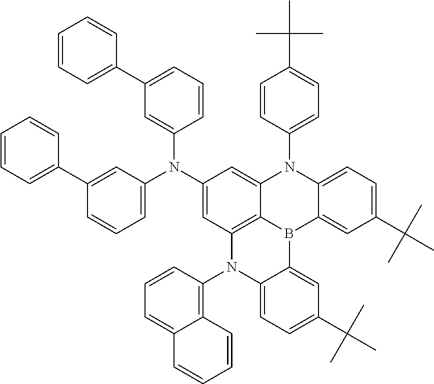 [SMILES: CC(C)(C)c1ccc(N2c3ccc(C(C)(C)C)cc3B3c4cc(C(C)(C)C)ccc4N(c4cccc5ccccc45)c4cc(N(c5cccc(-c6ccccc6)c5)c5cccc(-c6ccccc6)c5)cc2c43)cc1]

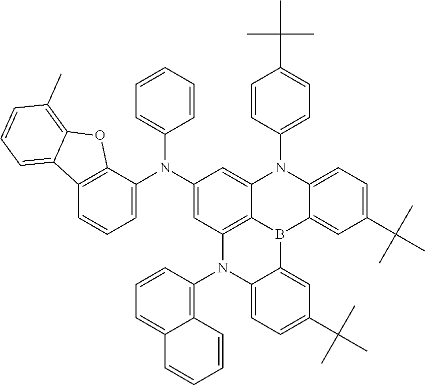 [SMILES: Cc1cccc2c1oc1c(N(c3ccccc3)c3cc4c5c(c3)N(c3cccc6ccccc36)c3ccc(C(C)(C)C)cc3B5c3cc(C(C)(C)C)ccc3N4c3ccc(C(C)(C)C)cc3)cccc12]

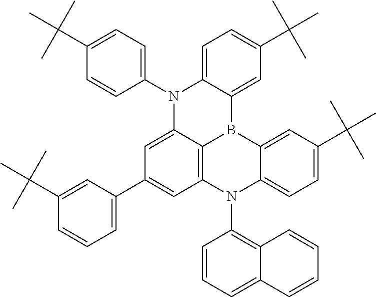 [SMILES: CC(C)(C)c1ccc(N2c3ccc(C(C)(C)C)cc3B3c4cc(C(C)(C)C)ccc4N(c4cccc5ccccc45)c4cc(-c5cccc(C(C)(C)C)c5)cc2c43)cc1]

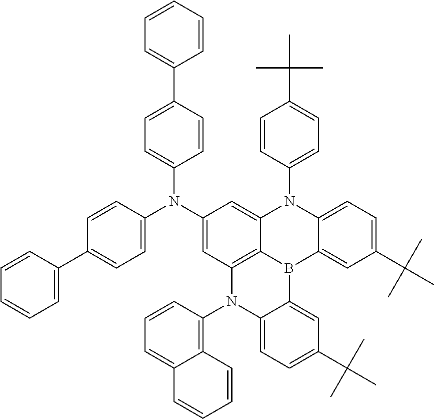 [SMILES: CC(C)(C)c1ccc(N2c3ccc(C(C)(C)C)cc3B3c4cc(C(C)(C)C)ccc4N(c4cccc5ccccc45)c4cc(N(c5ccc(-c6ccccc6)cc5)c5ccc(-c6ccccc6)cc5)cc2c43)cc1]

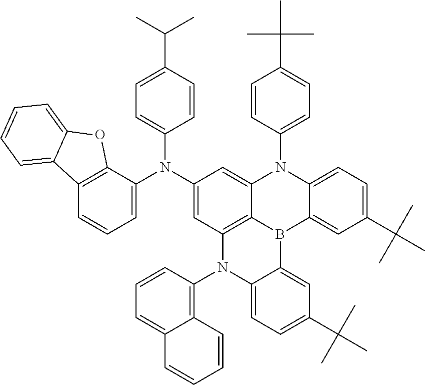 [SMILES: CC(C)c1ccc(N(c2cc3c4c(c2)N(c2cccc5ccccc25)c2ccc(C(C)(C)C)cc2B4c2cc(C(C)(C)C)ccc2N3c2ccc(C(C)(C)C)cc2)c2cccc3c2oc2ccccc23)cc1]

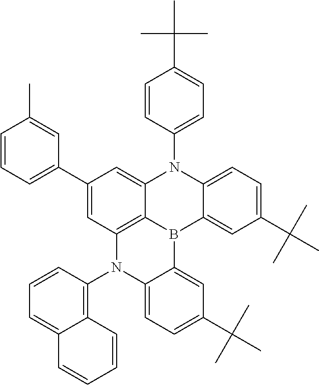 [SMILES: Cc1cccc(-c2cc3c4c(c2)N(c2cccc5ccccc25)c2ccc(C(C)(C)C)cc2B4c2cc(C(C)(C)C)ccc2N3c2ccc(C(C)(C)C)cc2)c1]

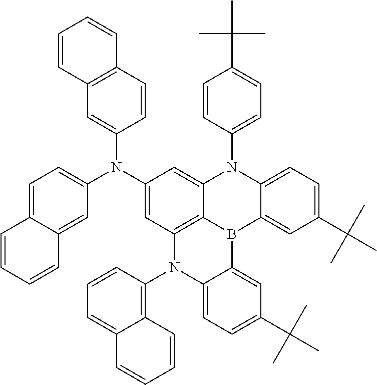 [SMILES: CC(C)(C)c1ccc(N2c3ccc(C(C)(C)C)cc3B3c4cc(C(C)(C)C)ccc4N(c4cccc5ccccc45)c4cc(N(c5ccc6ccccc6c5)c5ccc6ccccc6c5)cc2c43)cc1]

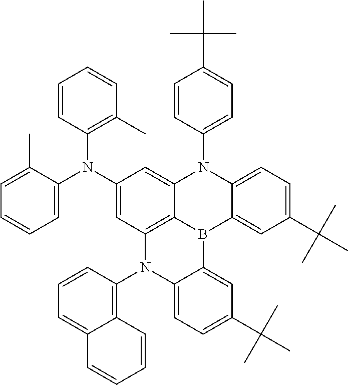 [SMILES: Cc1ccccc1N(c1cc2c3c(c1)N(c1cccc4ccccc14)c1ccc(C(C)(C)C)cc1B3c1cc(C(C)(C)C)ccc1N2c1ccc(C(C)(C)C)cc1)c1ccccc1C]

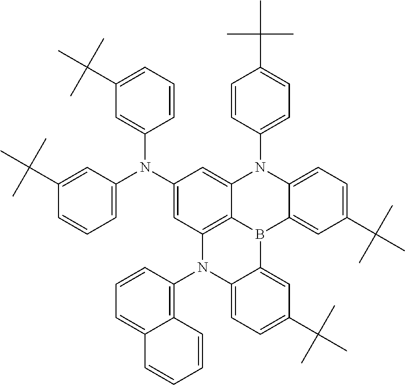 [SMILES: CC(C)(C)c1ccc(N2c3ccc(C(C)(C)C)cc3B3c4cc(C(C)(C)C)ccc4N(c4cccc5ccccc45)c4cc(N(c5cccc(C(C)(C)C)c5)c5cccc(C(C)(C)C)c5)cc2c43)cc1]

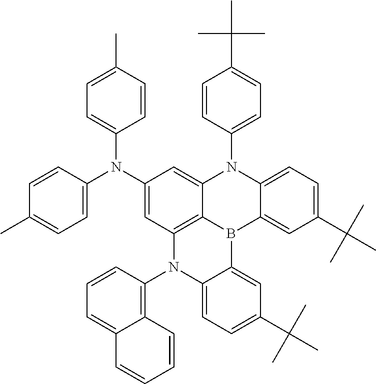 [SMILES: Cc1ccc(N(c2ccc(C)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

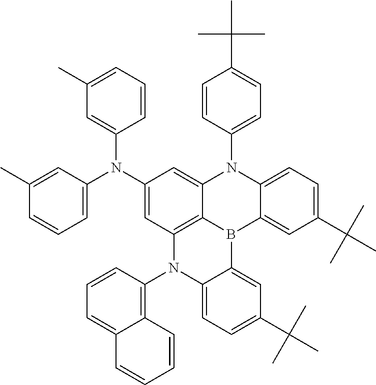 [SMILES: Cc1cccc(N(c2cccc(C)c2)c2cc3c4c(c2)N(c2cccc5ccccc25)c2ccc(C(C)(C)C)cc2B4c2cc(C(C)(C)C)ccc2N3c2ccc(C(C)(C)C)cc2)c1]

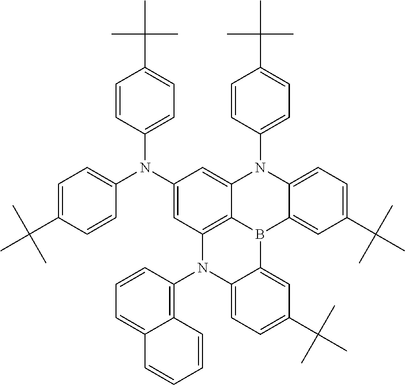 [SMILES: CC(C)(C)c1ccc(N(c2ccc(C(C)(C)C)cc2)c2cc3c4c(c2)N(c2cccc5ccccc25)c2ccc(C(C)(C)C)cc2B4c2cc(C(C)(C)C)ccc2N3c2ccc(C(C)(C)C)cc2)cc1]

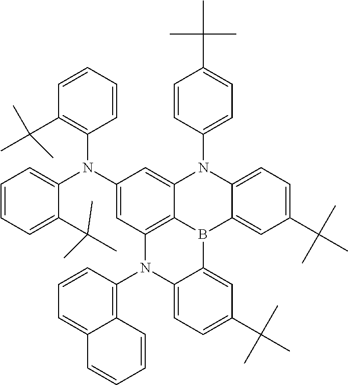 [SMILES: CC(C)(C)c1ccc(N2c3ccc(C(C)(C)C)cc3B3c4cc(C(C)(C)C)ccc4N(c4cccc5ccccc45)c4cc(N(c5ccccc5C(C)(C)C)c5ccccc5C(C)(C)C)cc2c43)cc1]

Preferably, A in the compound of the formula (E-1) is

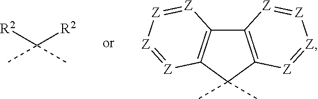

where the dotted bonds indicate the bonds from A to the rest of the formula. More preferably, A is

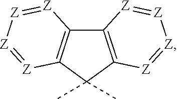

where the dotted bonds indicate the bonds of A to the rest of the formula.

Preferably, Z is CR¹ when no

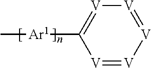

group is bonded thereto.

Preferably, two or three V groups in the ring in formula (E-1) are N, and the remaining V groups are CR⁴. More preferably, three V groups in the ring in formula (E-1) are N, and the remaining V groups are CR⁴. It is further preferable that V groups that are N are not adjacent to one another in the ring. What is meant here by “adjacent to one another in the ring” is that the V groups in question are bonded to one another.

Preferred

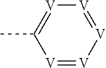

groups are the following groups:

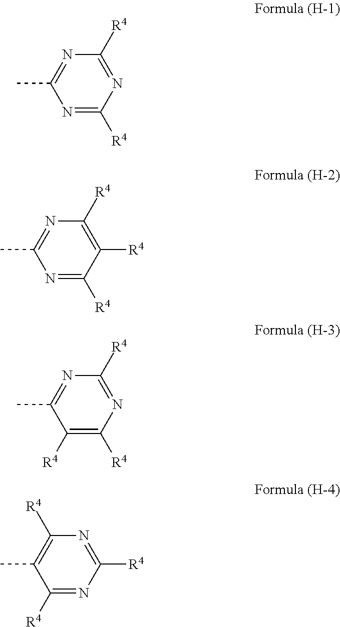

where the dotted line represents the bond to the rest of the formula. R⁴ here is preferably selected from H, aromatic ring systems which have 6 to 40 aromatic ring atoms and are substituted by R⁵ radicals, and heteroaromatic ring systems which have 5 to 40 aromatic ring atoms and are substituted by R⁵ radicals; more preferably from H and aromatic ring systems which have 6 to 40 aromatic ring atoms and are substituted by R⁵ radicals; most preferably from H and phenyl substituted by R⁵ radicals.

Among the formulae (H-1) to (H-4), particular preference is given to the formulae (H-1) to (H-3). Very particular preference is given to the formula (H-1).

Preferred embodiments of the formulae (H-2) and (H-3) are shown below:

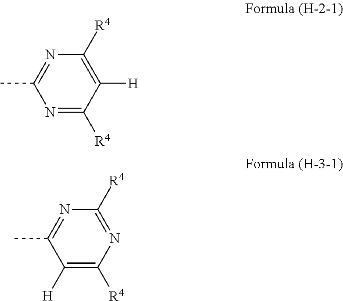

where the dotted line represents the bond to the rest of the formula. R⁴ here is preferably selected from aromatic ring systems which have 6 to 40 aromatic ring atoms and are substituted by R⁵ radicals, and from heteroaromatic ring systems which have 5 to 40 aromatic ring atoms and are substituted by R⁵ radicals; more preferably from aromatic ring systems which have 6 to 40 aromatic ring atoms and are substituted by R⁵ radicals; most preferably from phenyl substituted by R⁵ radicals.

Ar¹ is preferably the same or different and is selected from divalent groups derived from benzene, biphenyl, terphenyl, naphthalene, fluorene, indenofluorene, indenocarbazole, spirobifluorene, dibenzofuran, dibenzothiophene, and carbazole, each of which may be substituted by one or more R³ radicals. Most preferably, Ar¹ is a divalent group derived from benzene that may be substituted in each case by one or more R³ radicals.

In a preferred embodiment, the index n is 0. In an alternative preferred embodiment, the index n is 1, 2 or 3, preferably 1 or 2, more preferably 1.

Preferred —(Ar¹)ₙ- groups conform to the following formulae:

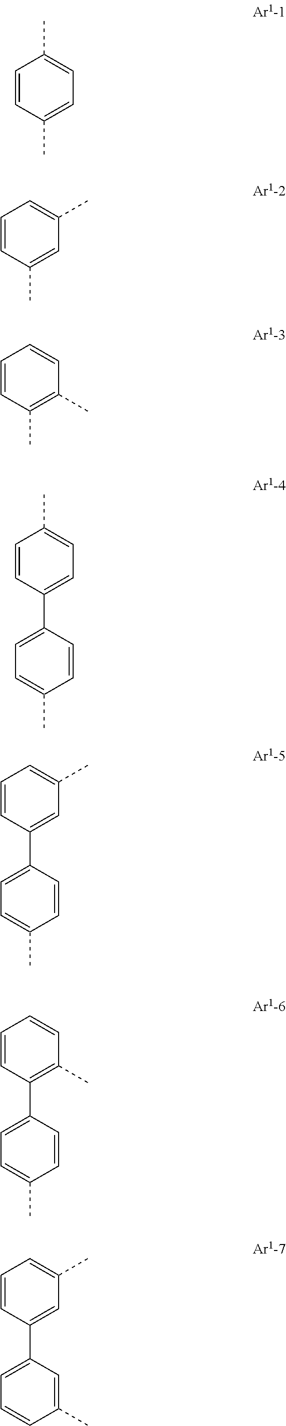

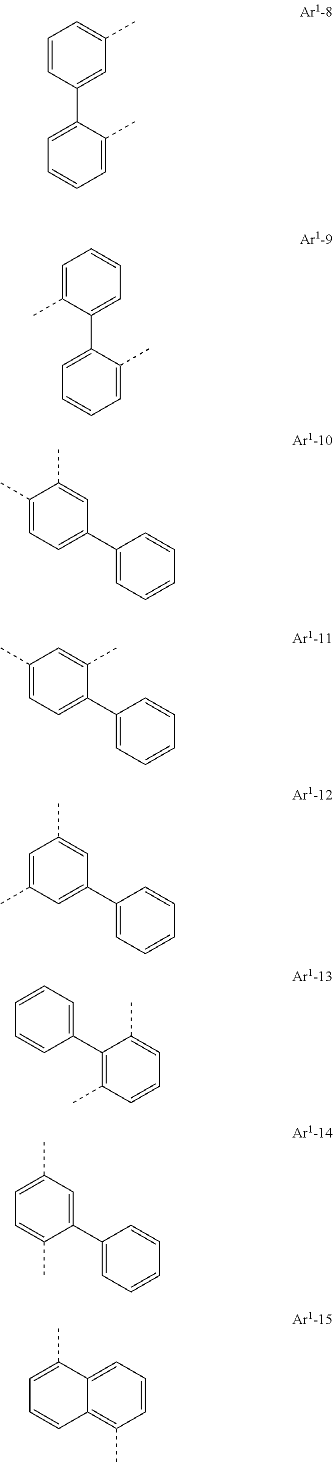

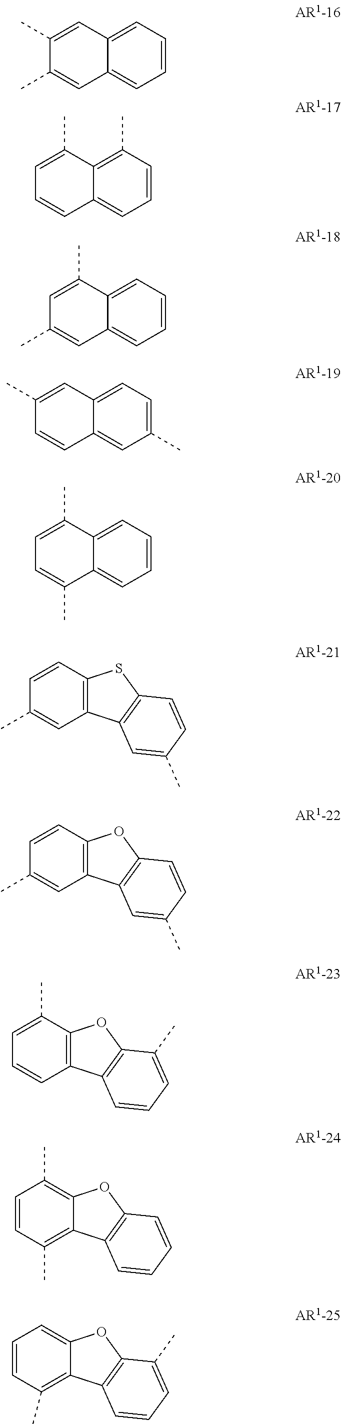

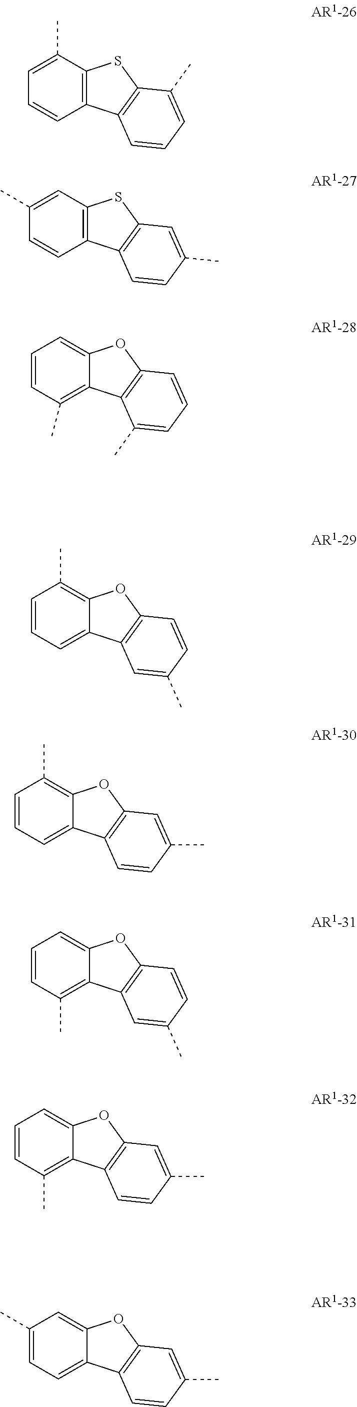

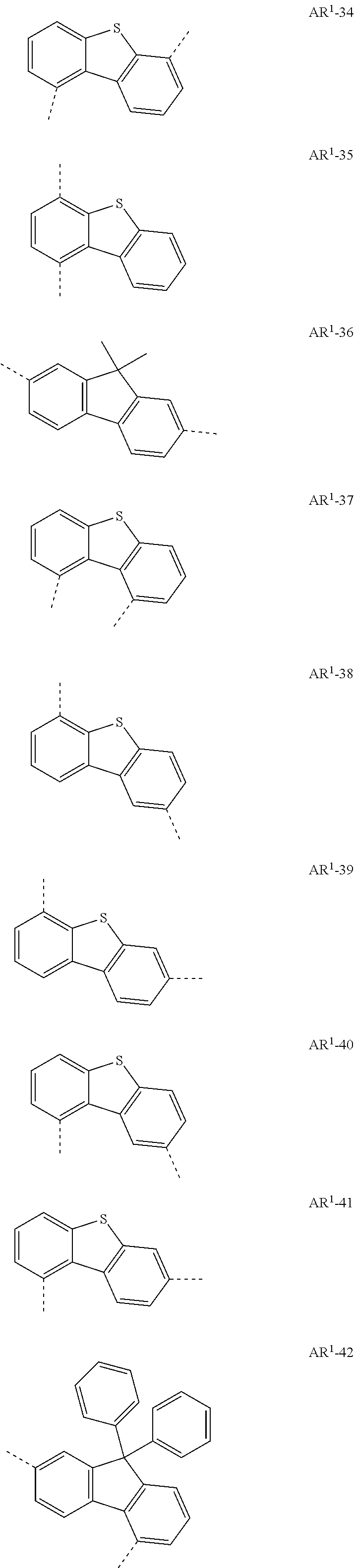

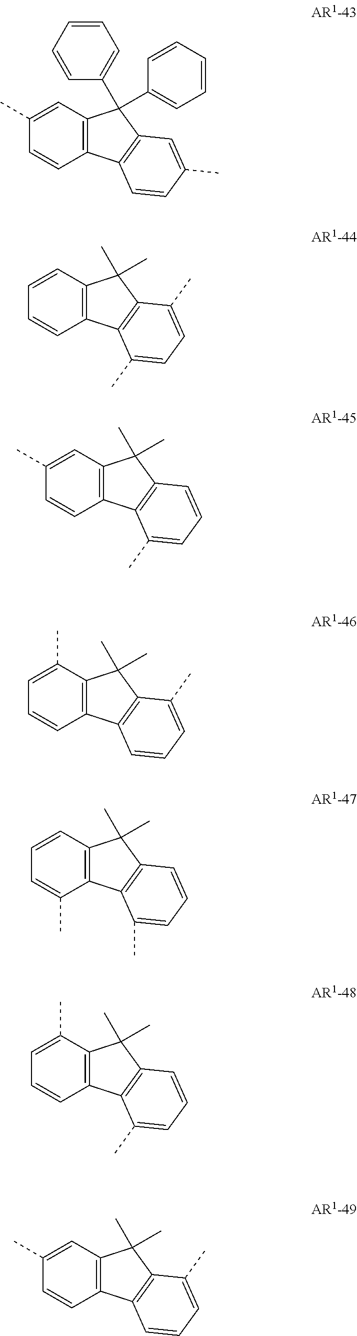

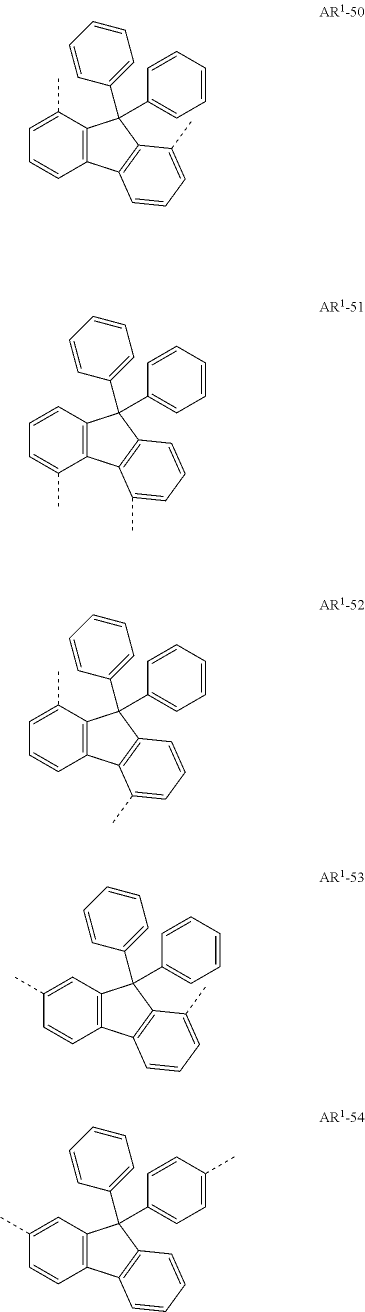

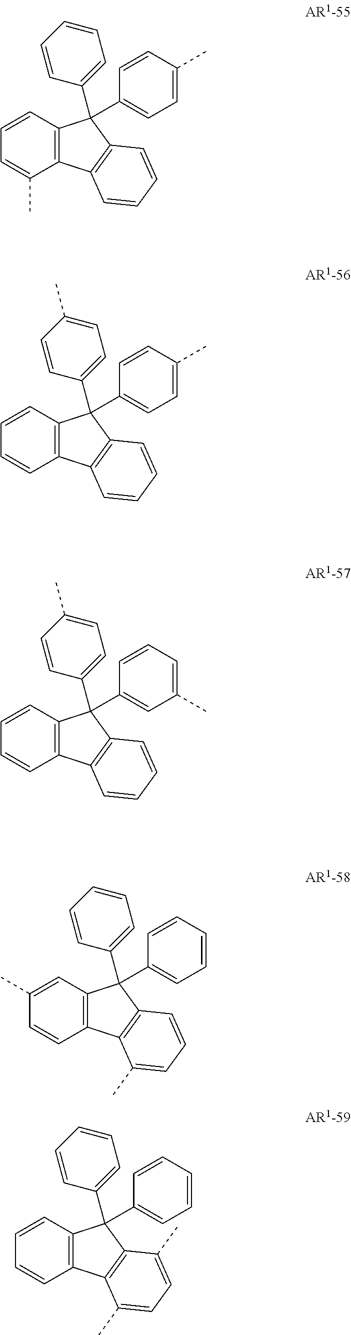

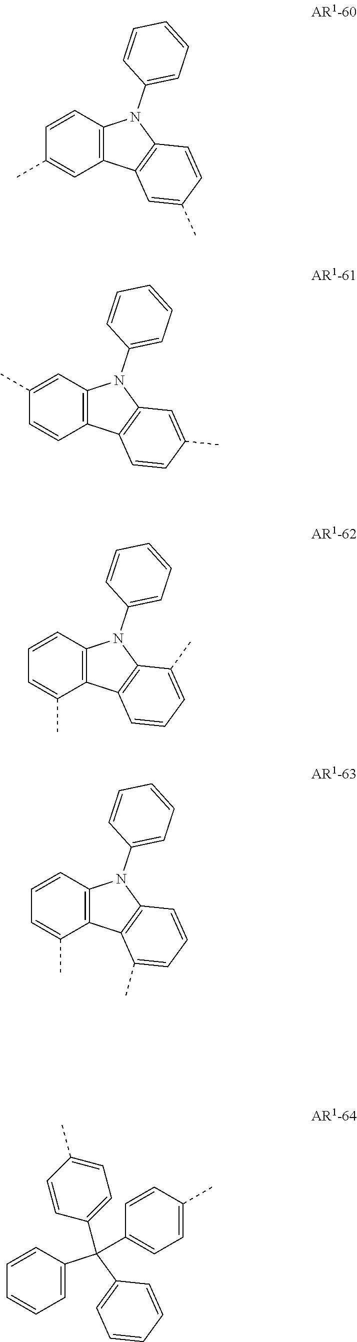

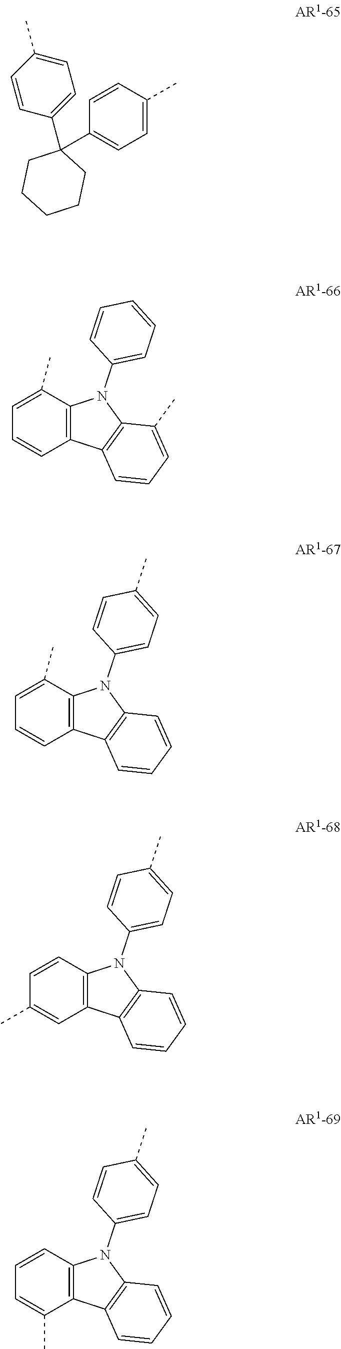

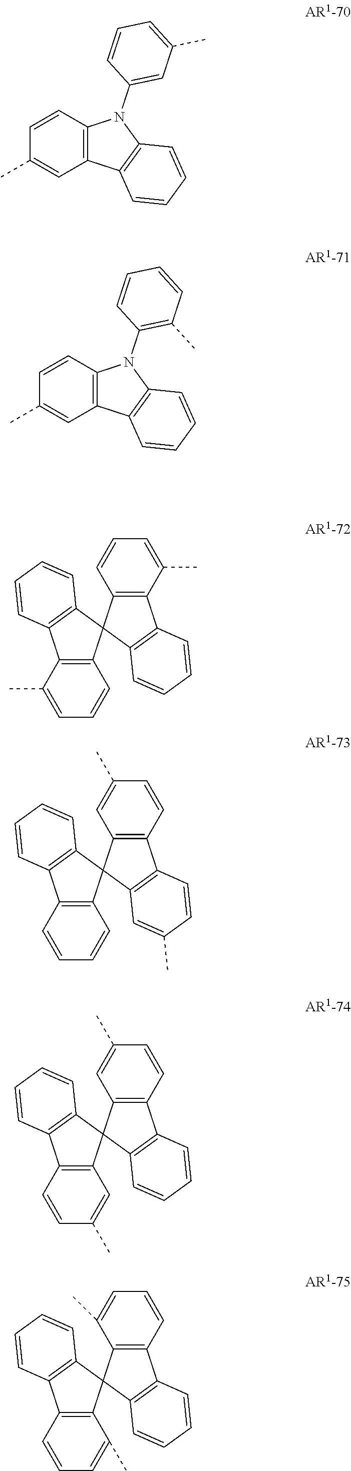

where the dotted lines represent the bonds to the rest of the formula.

Preferably, R¹ is the same or different at each instance and is selected from H, D, F, CN, Si(R⁵)₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁵ radicals; and where one or more CH₂ groups in the alkyl or alkoxy groups mentioned may be replaced by —C═C—, —R⁵C═CR⁵—, Si(R⁵)₂, C═O, C═NR⁵, —NR⁵—, —O—, —S—, —C(═O)O— or —C(═O)NR⁵—. More preferably, R¹ is the same or different at each instance and is selected from H, F, aromatic ring systems having 6 to 40 aromatic ring atoms, and heteroaromatic ring systems having 5 to 40 aromatic ring atoms; where the aromatic ring systems and the heteroaromatic ring systems are each substituted by R⁵ radicals. Even more preferably, R¹ is H.

Preferably, R² is the same or different at each instance and is selected from H, D, F, CN, Si(R⁵)₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁵ radicals; and where one or more CH₂ groups in the alkyl or alkoxy groups mentioned may be replaced by —C═C—, —R⁵C═CR⁵—, Si(R⁵)₂, C═O, C═NR⁵, —NR⁵—, —O—, —S—, —C(═O)O— or —C(═O)NR⁵—. More preferably, R² is the same or different at each instance and is selected from straight-chain alkyl groups having 1 to 20 carbon atoms, branched alkyl groups having 3 to 20 carbon atoms, aromatic ring systems having 6 to 40 aromatic ring atoms and heteroaromatic ring systems having 5 to 40 aromatic ring atoms, where said alkyl groups, said aromatic ring systems and said heteroaromatic ring systems are each substituted by R⁵ radicals.

Most preferably, R² is the same or different at each instance, preferably the same, and is selected from alkyl groups having 1 to 10 atoms, preferably methyl, and aromatic ring atoms having 6 to 40 aromatic ring atoms, preferably phenyl.

Preferably, R³ is the same or different at each instance and is selected from H, D, F, CN, Si(R⁵)₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁵ radicals; and where one or more CH₂ groups in the alkyl or alkoxy groups mentioned may be replaced by —C≡C—, —R⁵C═CR⁵—, Si(R⁵)₂, C═O, C═NR⁵, —NR⁵—, —O—, —S—, —C(═O)O— or —C(═O)NR⁵—.

Preferably, R⁴ is the same or different at each instance and is selected from H, D, F, CN, Si(R⁵)₃, straight-chain alkyl groups having 1 to 20 carbon atoms, branched or cyclic alkyl groups having 3 to 20 carbon atoms, aromatic ring systems having 6 to 40 aromatic ring atoms and heteroaromatic ring systems having 5 to 40 aromatic ring atoms, where said alkyl groups, said aromatic ring systems and said heteroaromatic ring systems are each substituted by R⁵ radicals. More preferably, R⁴ is the same or different at each instance and is selected from H and aromatic ring systems which have 6 to 40 aromatic ring atoms and are substituted by R⁵ radicals. Most preferably, R⁴ is the same or different at each instance and is selected from H and phenyl substituted by R⁵ radicals.

Preferably, R⁵ is the same or different at each instance and is selected from H, D, F, CN, Si(R⁶)₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁶ radicals; and where one or more CH₂ groups in the alkyl or alkoxy groups mentioned may be replaced by —C≡C—, —R⁶C═CR⁶—, Si(R⁶)₂, C═O, C═NR⁶, —NR⁶—, —O—, —S—, —C(═O)O— or —C(═O)NR⁶—.

The compound of the formula (E-1) preferably conforms to one of the following formula:

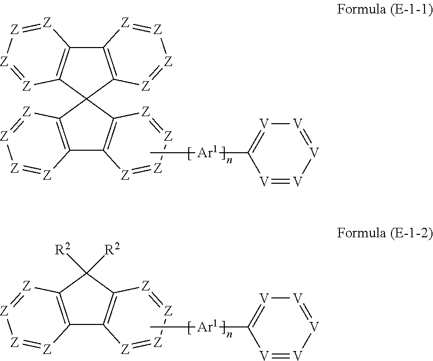

where the symbols and indices that occur are as defined above, and preferably correspond to their above-specified preferred embodiments. In particular, it is preferred for the formula that Z is CR¹ when no

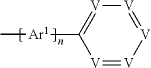

group is bonded thereto.

Formulae (E-1-1) and (E-1-2) may conform to the following embodiments:

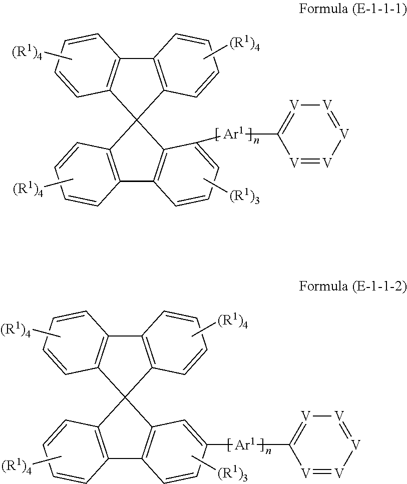

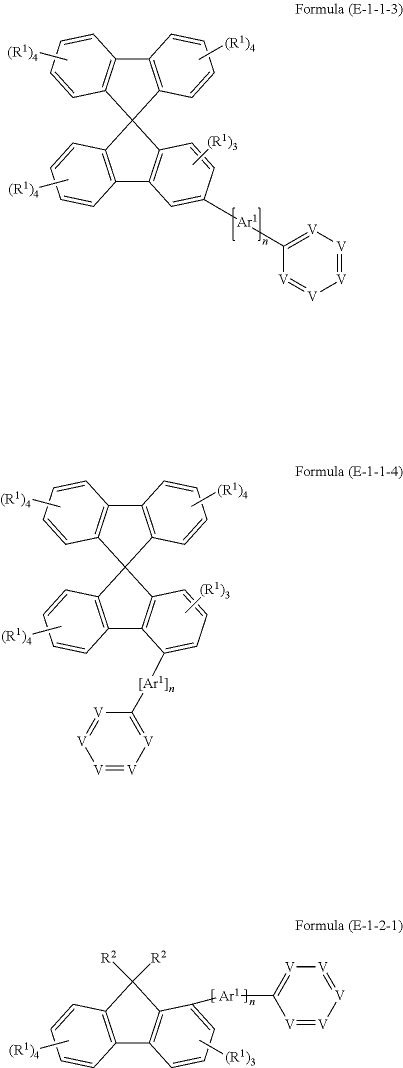

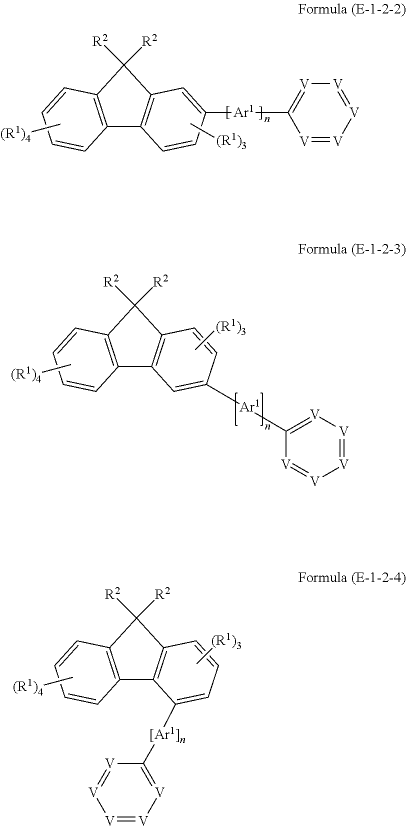

where the symbols and indices that occur are as defined above, and preferably correspond to their above-specified preferred embodiments.

What is meant here by the representation —(R¹)₃ or —(R¹)₄ is that there are three or four R¹ groups on the benzene ring in question, i.e. one R¹ group on each unoccupied position on the benzene ring in question. Preferably, for the formulae, the abovementioned preferred embodiments of the V, Ar¹, R¹ and R² groups, and of index n, are applicable. It is especially preferable for the formulae that
two or three nonadjacent V groups are N, and the remaining V groups are CR⁴;
index n is 0 or 1;
Ar¹ is selected from divalent groups derived from benzene, biphenyl, terphenyl, naphthalene, fluorene, indenofluorene, indenocarbazole, spirobifluorene, dibenzofuran, dibenzothiophene, and carbazole, each of which may be substituted by one or more R³ radicals;
R¹ is the same or different at each instance and is selected from H, F, aromatic ring systems having 6 to 40 aromatic ring atoms, and heteroaromatic ring systems having 5 to 40 aromatic ring atoms; where the aromatic ring systems and the heteroaromatic ring systems are each substituted by R⁵ radicals;
R² is the same or different at each instance and is selected from straight-chain alkyl groups having 1 to 20 carbon atoms, branched alkyl groups having 3 to 20 carbon atoms, aromatic ring systems having 6 to 40 aromatic ring atoms and heteroaromatic ring systems having 5 to 40 aromatic ring atoms, where said alkyl groups, said aromatic ring systems and said heteroaromatic ring systems are each substituted by R⁵ radicals.

Among the formulae, preference is given to the formulae (E-1-1-1) to (E-1-1-4). Among the formulae, preference is further given to the formulae (E-1-1-2), (E-1-1-4), (E-1-2-2) and (E-1-2-4), especially the formulae (E-1-1-2) and (E-1-1-4).

Preferred embodiments of the formulae (E-1-1-1) to (E-1-1-4) and (E-1-2-1) to (E-1-2-4) conform to the following formulae:

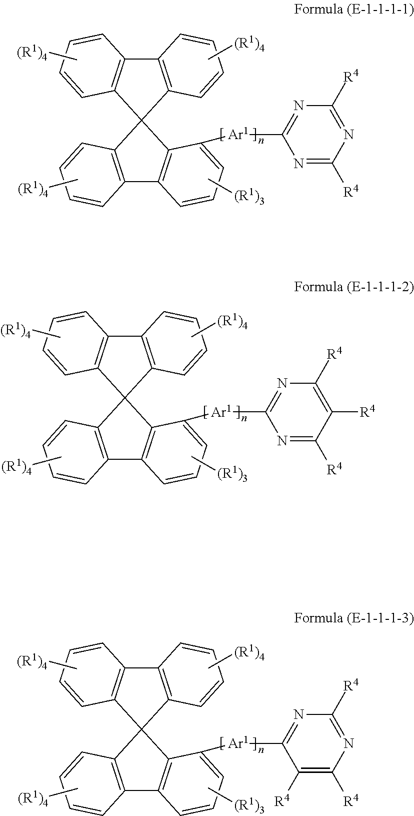

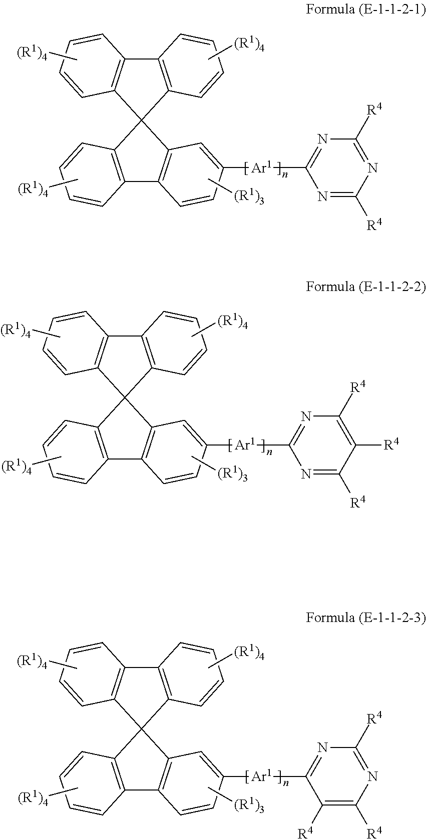

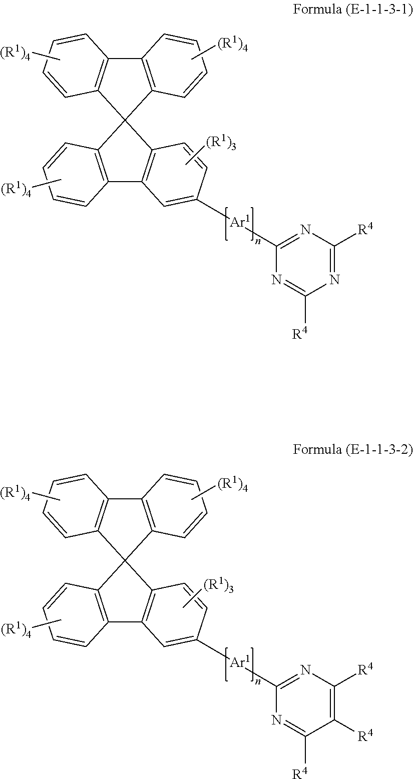

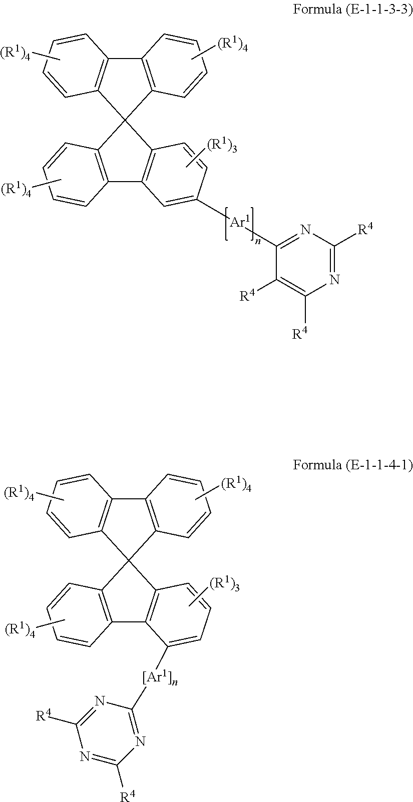

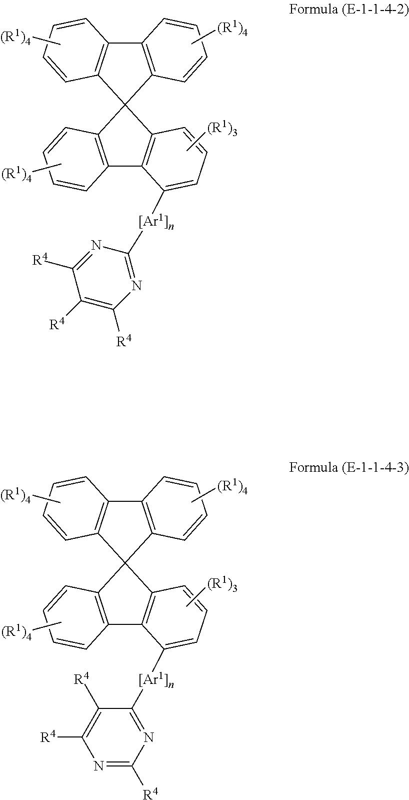

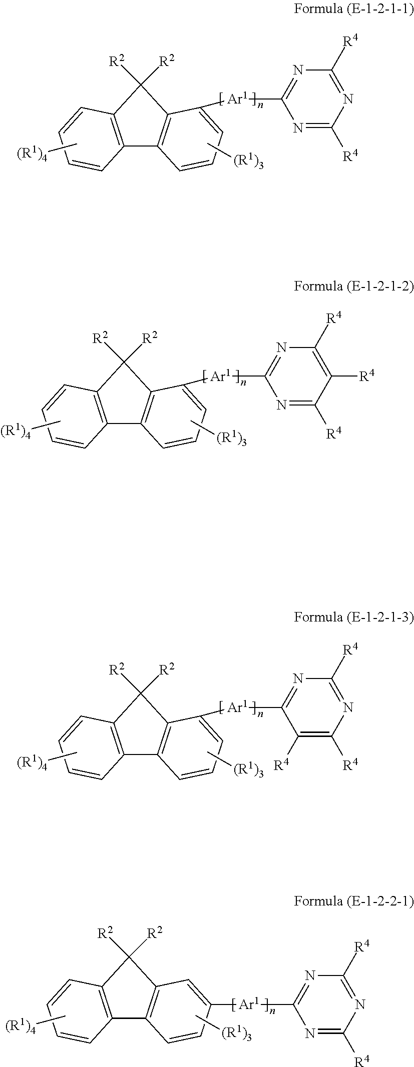

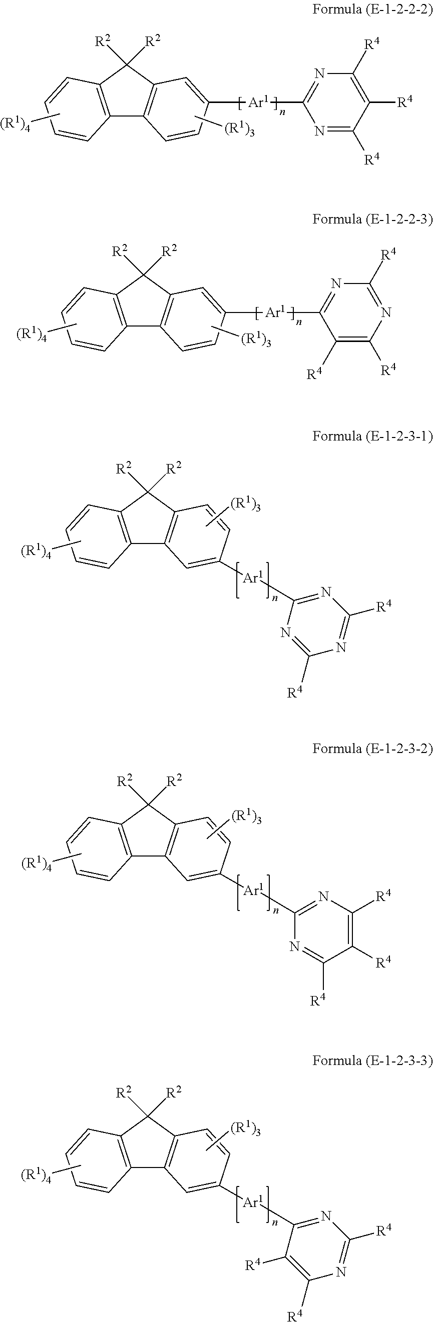

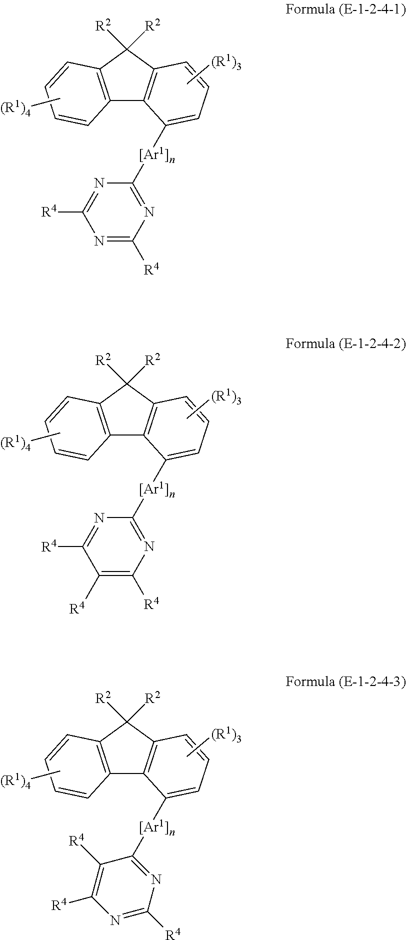

where the symbols and indices that occur are as defined above, and preferably correspond to their above-specified preferred embodiments. What is meant here by the representation —(R¹)₃ or —(R¹)₄ is that there are three or four R¹ groups on the benzene ring in question, i.e. one R¹ group on each unoccupied position on the benzene ring in question. Preferably, for the formulae, the abovementioned preferred embodiments of the Ar¹, R¹, R², R⁴ groups, and of index n, are applicable.

It is especially preferable for the formulae that
index n is 0 or 1;
Ar¹ is selected from divalent groups derived from benzene, biphenyl, terphenyl, naphthalene, fluorene, indenofluorene, indenocarbazole, spirobifluorene, dibenzofuran, dibenzothiophene, and carbazole, each of which may be substituted by one or more R³ radicals;
R¹ is the same or different at each instance and is selected from H, F, aromatic ring systems having 6 to 40 aromatic ring atoms, and heteroaromatic ring systems having 5 to 40 aromatic ring atoms; where the aromatic ring systems and the heteroaromatic ring systems are each substituted by R⁵ radicals;
R² is the same or different at each instance and is selected from straight-chain alkyl groups having 1 to 20 carbon atoms, branched alkyl groups having 3 to 20 carbon atoms, aromatic ring systems having 6 to 40 aromatic ring atoms and heteroaromatic ring systems having 5 to 40 aromatic ring atoms, where said alkyl groups, said aromatic ring systems and said heteroaromatic ring systems are each substituted by R⁵ radicals;
R⁴ is the same or different at each instance and is selected from H and aromatic ring systems which have 6 to 40 aromatic ring atoms and are substituted by R⁵ radicals.

Among the formulae, preference is given to the formulae (E-1-1-1-1) to (E-1-1-4-3). In addition, among the formulae, preference is given to the formulae (E-1-1-2-1), (E-1-1-2-2), (E-1-1-2-3), (E-1-1-4-1), (E-1-1-4-2), (E-1-1-4-3), (E-1-2-2-1), (E-1-2-2-2), (E-1-2-2-3), (E-1-2-4-1), (E-1-2-4-2) and (E-1-2-4-3), especially the formulae (E-1-1-2-1), (E-1-1-2-2), (E-1-1-2-3), (E-1-1-4-1), (E-1-1-4-2) and (E-1-1-4-3), most preferably the formulae (E-1-1-2-1) and (E-1-1-4-1).

Preferred compounds of formula (E-1) are shown in the following table:

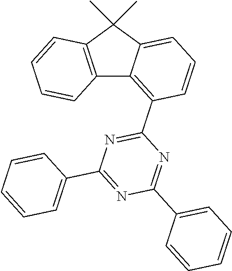 [SMILES: CC1(C)c2ccccc2-c2c(-c3nc(-c4ccccc4)nc(-c4ccccc4)n3)cccc21]

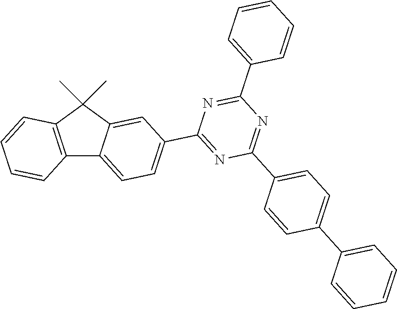 [SMILES: CC1(C)c2ccccc2-c2ccc(-c3nc(-c4ccccc4)nc(-c4ccc(-c5ccccc5)cc4)n3)cc21]

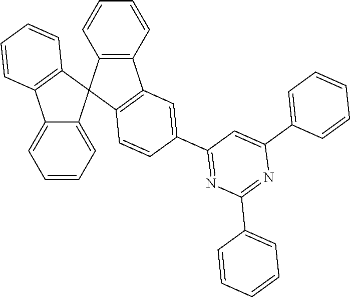 [SMILES: c1ccc(-c2cc(-c3ccc4c(c3)-c3ccccc3C43c4ccccc4-c4ccccc43)nc(-c3ccccc3)n2)cc1]

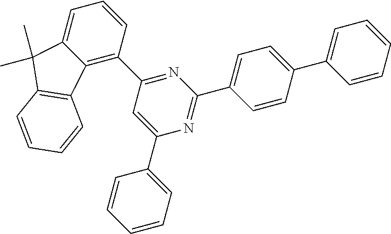 [SMILES: CC1(C)c2ccccc2-c2c(-c3cc(-c4ccccc4)nc(-c4ccc(-c5ccccc5)cc4)n3)cccc21]

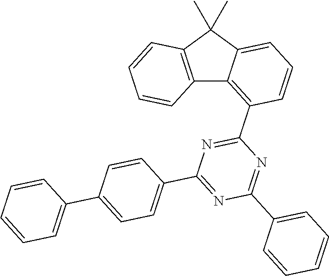 [SMILES: CC1(C)c2ccccc2-c2c(-c3nc(-c4ccccc4)nc(-c4ccc(-c5ccccc5)cc4)n3)cccc21]

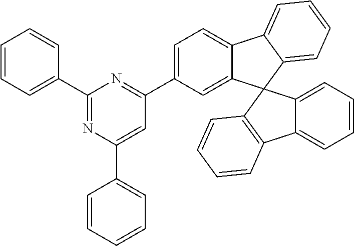 [SMILES: c1ccc(-c2cc(-c3ccc4c(c3)C3(c5ccccc5-c5ccccc53)c3ccccc3-4)nc(-c3ccccc3)n2)cc1]

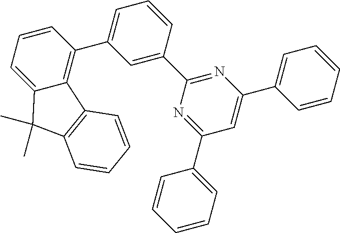 [SMILES: CC1(C)c2ccccc2-c2c(-c3cccc(-c4nc(-c5ccccc5)cc(-c5ccccc5)n4)c3)cccc21]

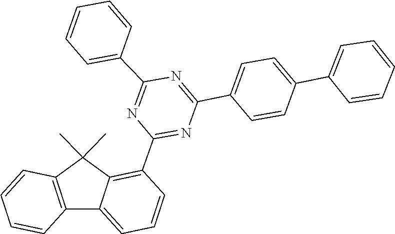 [SMILES: CC1(C)c2ccccc2-c2cccc(-c3nc(-c4ccccc4)nc(-c4ccc(-c5ccccc5)cc4)n3)c21]

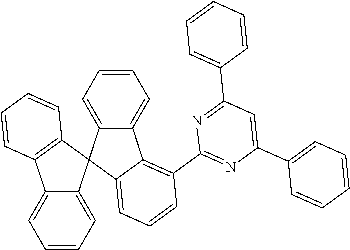 [SMILES: c1ccc(-c2cc(-c3ccccc3)nc(-c3cccc4c3-c3ccccc3C43c4ccccc4-c4ccccc43)n2)cc1]

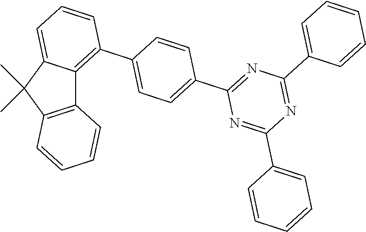 [SMILES: CC1(C)c2ccccc2-c2c(-c3ccc(-c4nc(-c5ccccc5)nc(-c5ccccc5)n4)cc3)cccc21]

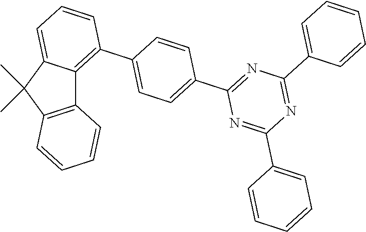 [SMILES: CC1(C)c2ccccc2-c2c(-c3ccc(-c4nc(-c5ccccc5)nc(-c5ccccc5)n4)cc3)cccc21]

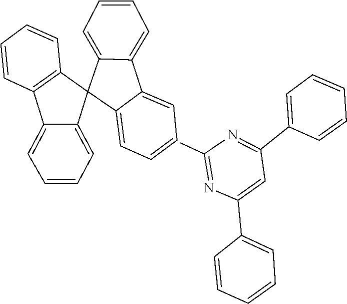

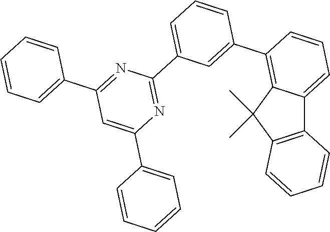 [SMILES: CC1(C)c2ccccc2-c2cccc(-c3cccc(-c4nc(-c5ccccc5)cc(-c5ccccc5)n4)c3)c21]

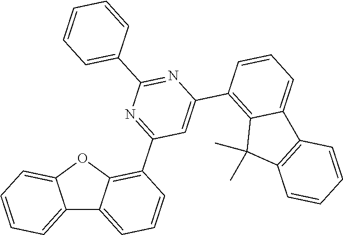 [SMILES: CC1(C)c2ccccc2-c2cccc(-c3cc(-c4cccc5c4oc4ccccc45)nc(-c4ccccc4)n3)c21]

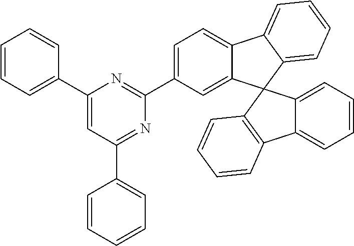 [SMILES: c1ccc(-c2cc(-c3ccccc3)nc(-c3ccc4c(c3)C3(c5ccccc5-c5ccccc53)c3ccccc3-4)n2)cc1]

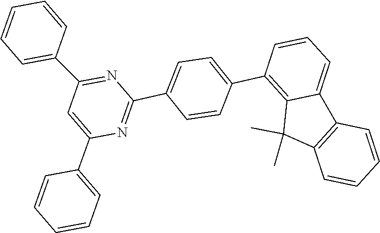 [SMILES: CC1(C)c2ccccc2-c2cccc(-c3ccc(-c4nc(-c5ccccc5)cc(-c5ccccc5)n4)cc3)c21]

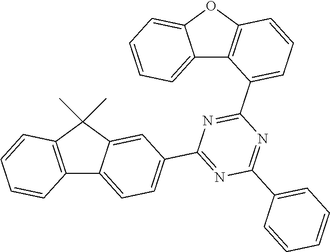 [SMILES: CC1(C)c2ccccc2-c2ccc(-c3nc(-c4ccccc4)nc(-c4cccc5oc6ccccc6c45)n3)cc21]

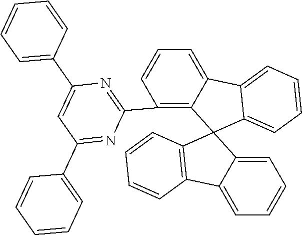 [SMILES: c1ccc(-c2cc(-c3ccccc3)nc(-c3cccc4c3C3(c5ccccc5-c5ccccc53)c3ccccc3-4)n2)cc1]

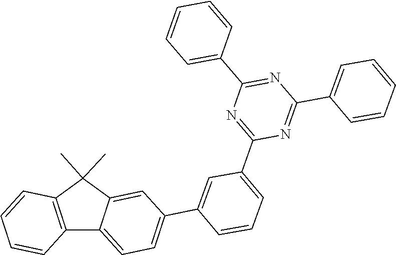 [SMILES: CC1(C)c2ccccc2-c2ccc(-c3cccc(-c4nc(-c5ccccc5)nc(-c5ccccc5)n4)c3)cc21]

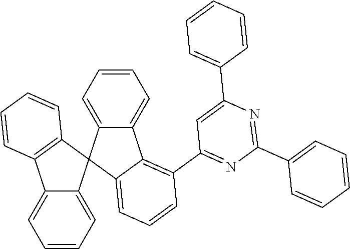 [SMILES: c1ccc(-c2cc(-c3cccc4c3-c3ccccc3C43c4ccccc4-c4ccccc43)nc(-c3ccccc3)n2)cc1]

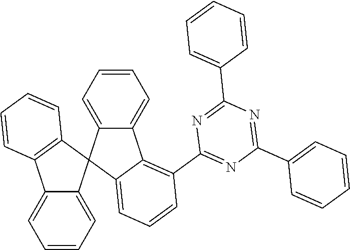 [SMILES: c1ccc(-c2nc(-c3ccccc3)nc(-c3cccc4c3-c3ccccc3C43c4ccccc4-c4ccccc43)n2)cc1]

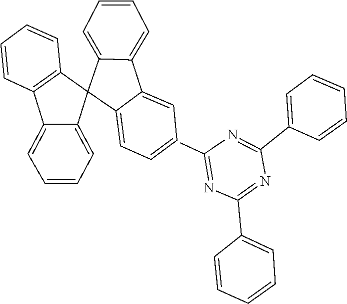

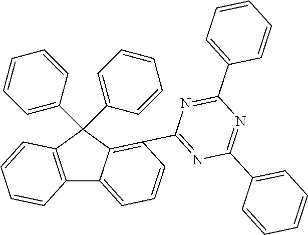 [SMILES: c1ccc(-c2nc(-c3ccccc3)nc(-c3cccc4c3C(c3ccccc3)(c3ccccc3)c3ccccc3-4)n2)cc1]

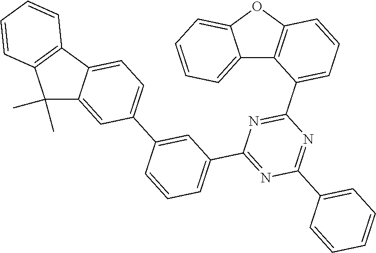 [SMILES: CC1(C)c2ccccc2-c2ccc(-c3cccc(-c4nc(-c5ccccc5)nc(-c5cccc6oc7ccccc7c56)n4)c3)cc21]

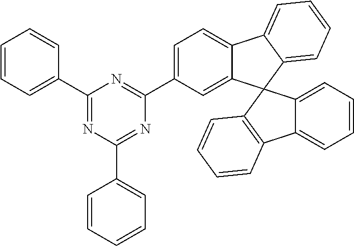 [SMILES: c1ccc(-c2nc(-c3ccccc3)nc(-c3ccc4c(c3)C3(c5ccccc5-c5ccccc53)c3ccccc3-4)n2)cc1]

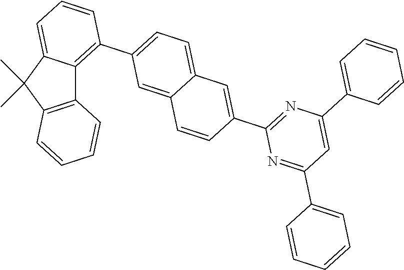 [SMILES: CC1(C)c2ccccc2-c2c(-c3ccc4cc(-c5nc(-c6ccccc6)cc(-c6ccccc6)n5)ccc4c3)cccc21]

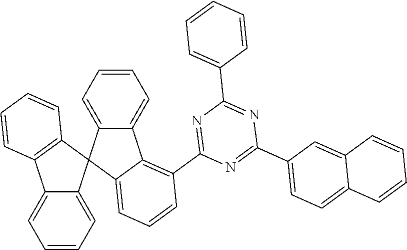 [SMILES: c1ccc(-c2nc(-c3ccc4ccccc4c3)nc(-c3cccc4c3-c3ccccc3C43c4ccccc4-c4ccccc43)n2)cc1]

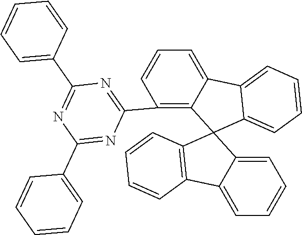 [SMILES: c1ccc(-c2nc(-c3ccccc3)nc(-c3cccc4c3C3(c5ccccc5-c5ccccc53)c3ccccc3-4)n2)cc1]

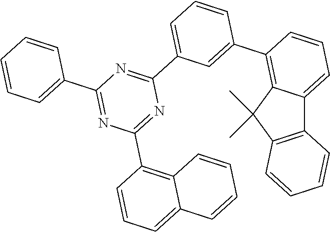 [SMILES: CC1(C)c2ccccc2-c2cccc(-c3cccc(-c4nc(-c5ccccc5)nc(-c5cccc6ccccc56)n4)c3)c21]

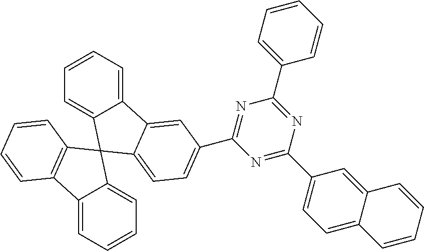 [SMILES: c1ccc(-c2nc(-c3ccc4c(c3)-c3ccccc3C43c4ccccc4-c4ccccc43)nc(-c3ccc4ccccc4c3)n2)cc1]

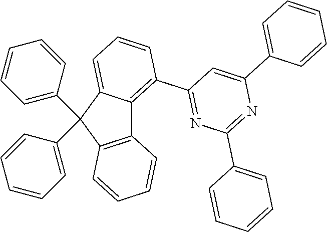 [SMILES: c1ccc(-c2cc(-c3cccc4c3-c3ccccc3C4(c3ccccc3)c3ccccc3)nc(-c3ccccc3)n2)cc1]

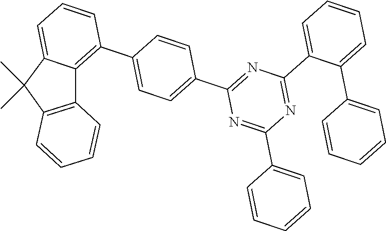 [SMILES: CC1(C)c2ccccc2-c2c(-c3ccc(-c4nc(-c5ccccc5)nc(-c5ccccc5-c5ccccc5)n4)cc3)cccc21]

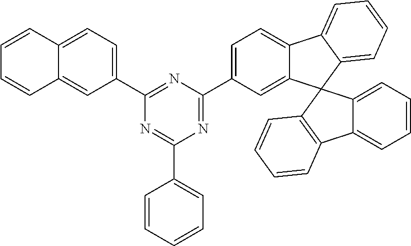 [SMILES: c1ccc(-c2nc(-c3ccc4c(c3)C3(c5ccccc5-c5ccccc53)c3ccccc3-4)nc(-c3ccc4ccccc4c3)n2)cc1]

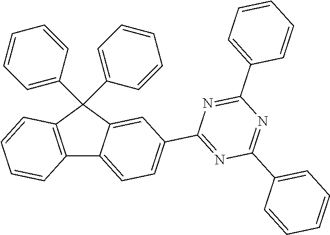 [SMILES: c1ccc(-c2nc(-c3ccccc3)nc(-c3ccc4c(c3)C(c3ccccc3)(c3ccccc3)c3ccccc3-4)n2)cc1]

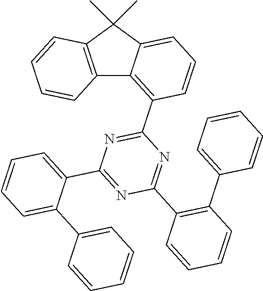 [SMILES: CC1(C)c2ccccc2-c2c(-c3nc(-c4ccccc4-c4ccccc4)nc(-c4ccccc4-c4ccccc4)n3)cccc21]

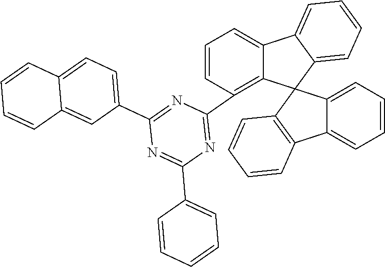 [SMILES: c1ccc(-c2nc(-c3ccc4ccccc4c3)nc(-c3cccc4c3C3(c5ccccc5-c5ccccc53)c3ccccc3-4)n2)cc1]

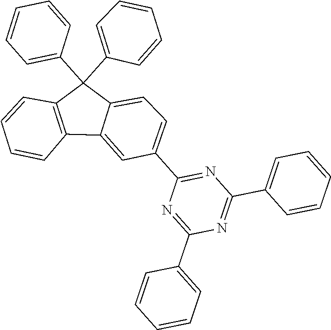 [SMILES: c1ccc(-c2nc(-c3ccccc3)nc(-c3ccc4c(c3)-c3ccccc3C4(c3ccccc3)c3ccccc3)n2)cc1]

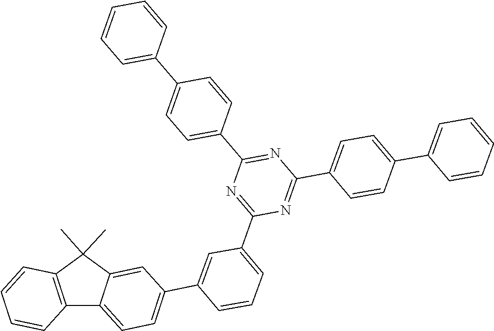 [SMILES: CC1(C)c2ccccc2-c2ccc(-c3cccc(-c4nc(-c5ccc(-c6ccccc6)cc5)nc(-c5ccc(-c6ccccc6)cc5)n4)c3)cc21]

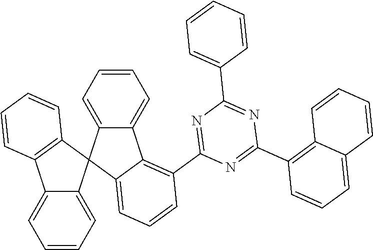 [SMILES: c1ccc(-c2nc(-c3cccc4c3-c3ccccc3C43c4ccccc4-c4ccccc43)nc(-c3cccc4ccccc34)n2)cc1]

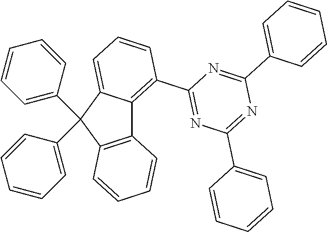 [SMILES: c1ccc(-c2nc(-c3ccccc3)nc(-c3cccc4c3-c3ccccc3C4(c3ccccc3)c3ccccc3)n2)cc1]

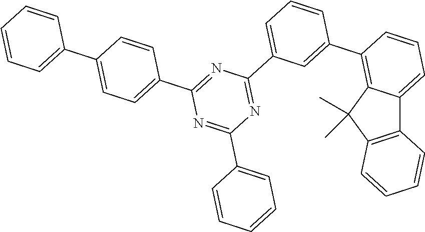 [SMILES: CC1(C)c2ccccc2-c2cccc(-c3cccc(-c4nc(-c5ccccc5)nc(-c5ccc(-c6ccccc6)cc5)n4)c3)c21]

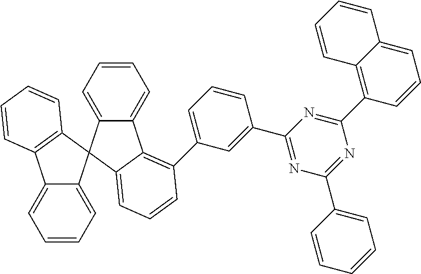 [SMILES: c1ccc(-c2nc(-c3cccc(-c4cccc5c4-c4ccccc4C54c5ccccc5-c5ccccc54)c3)nc(-c3cccc4ccccc34)n2)cc1]

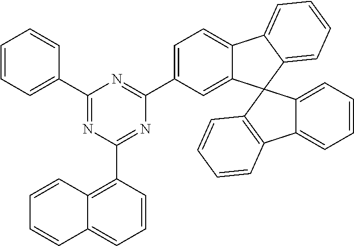 [SMILES: c1ccc(-c2nc(-c3ccc4c(c3)C3(c5ccccc5-c5ccccc53)c3ccccc3-4)nc(-c3cccc4ccccc34)n2)cc1]

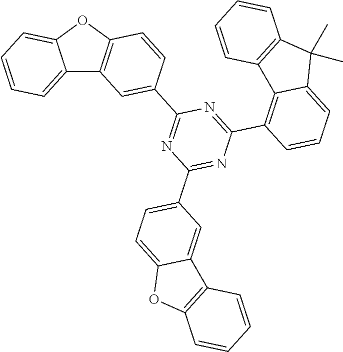 [SMILES: CC1(C)c2ccccc2-c2c(-c3nc(-c4ccc5oc6ccccc6c5c4)nc(-c4ccc5oc6ccccc6c5c4)n3)cccc21]

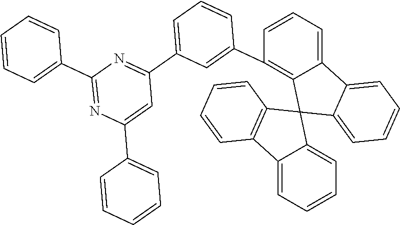 [SMILES: c1ccc(-c2cc(-c3cccc(-c4cccc5c4C4(c6ccccc6-c6ccccc64)c4ccccc4-5)c3)nc(-c3ccccc3)n2)cc1]

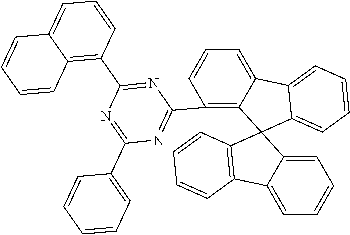 [SMILES: c1ccc(-c2nc(-c3cccc4c3C3(c5ccccc5-c5ccccc53)c3ccccc3-4)nc(-c3cccc4ccccc34)n2)cc1]

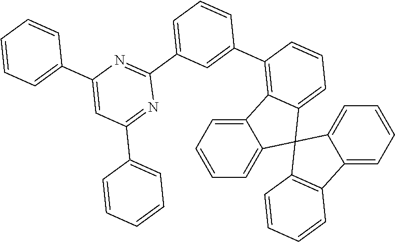 [SMILES: c1ccc(-c2cc(-c3ccccc3)nc(-c3cccc(-c4cccc5c4-c4ccccc4C54c5ccccc5-c5ccccc54)c3)n2)cc1]

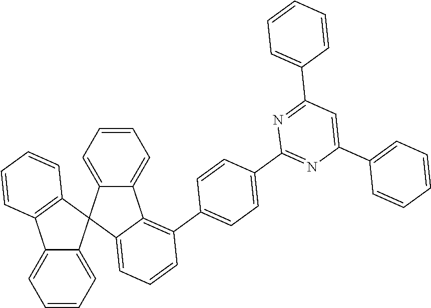 [SMILES: c1ccc(-c2cc(-c3ccccc3)nc(-c3ccc(-c4cccc5c4-c4ccccc4C54c5ccccc5-c5ccccc54)cc3)n2)cc1]

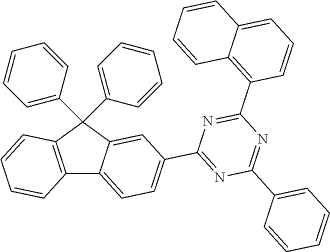 [SMILES: c1ccc(-c2nc(-c3ccc4c(c3)C(c3ccccc3)(c3ccccc3)c3ccccc3-4)nc(-c3cccc4ccccc34)n2)cc1]

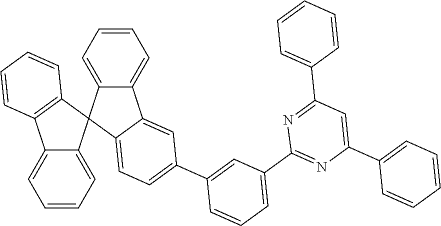 [SMILES: c1ccc(-c2cc(-c3ccccc3)nc(-c3cccc(-c4ccc5c(c4)-c4ccccc4C54c5ccccc5-c5ccccc54)c3)n2)cc1]

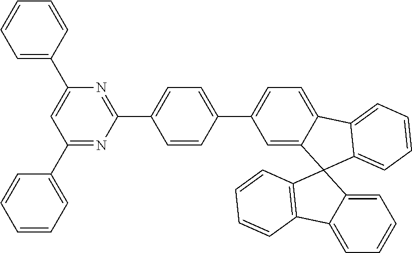 [SMILES: c1ccc(-c2cc(-c3ccccc3)nc(-c3ccc(-c4ccc5c(c4)C4(c6ccccc6-c6ccccc64)c4ccccc4-5)cc3)n2)cc1]

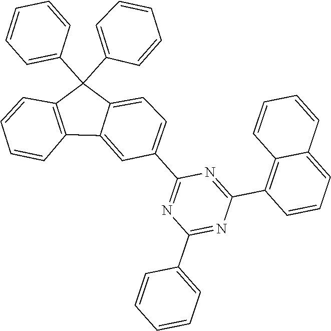 [SMILES: c1ccc(-c2nc(-c3ccc4c(c3)-c3ccccc3C4(c3ccccc3)c3ccccc3)nc(-c3cccc4ccccc34)n2)cc1]

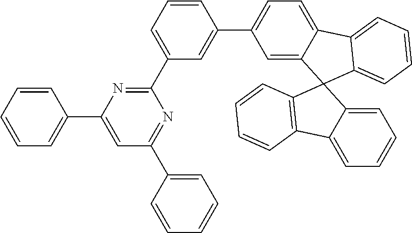 [SMILES: c1ccc(-c2cc(-c3ccccc3)nc(-c3cccc(-c4ccc5c(c4)C4(c6ccccc6-c6ccccc64)c4ccccc4-5)c3)n2)cc1]

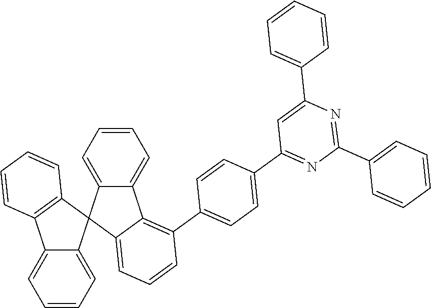 [SMILES: c1ccc(-c2cc(-c3ccc(-c4cccc5c4-c4ccccc4C54c5ccccc5-c5ccccc54)cc3)nc(-c3ccccc3)n2)cc1]

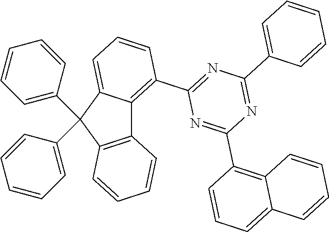 [SMILES: c1ccc(-c2nc(-c3cccc4c3-c3ccccc3C4(c3ccccc3)c3ccccc3)nc(-c3cccc4ccccc34)n2)cc1]

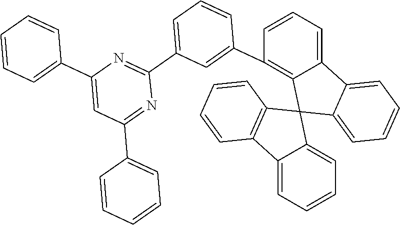 [SMILES: c1ccc(-c2cc(-c3ccccc3)nc(-c3cccc(-c4cccc5c4C4(c6ccccc6-c6ccccc64)c4ccccc4-5)c3)n2)cc1]

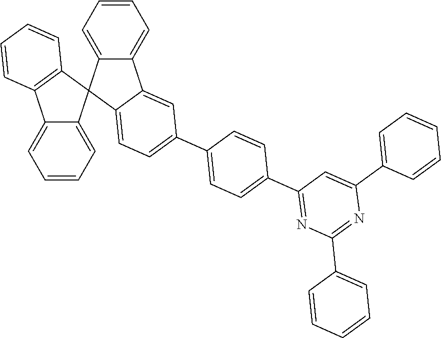 [SMILES: c1ccc(-c2cc(-c3ccc(-c4ccc5c(c4)-c4ccccc4C54c5ccccc5-c5ccccc54)cc3)nc(-c3ccccc3)n2)cc1]

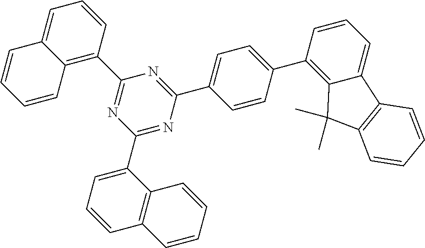 [SMILES: CC1(C)c2ccccc2-c2cccc(-c3ccc(-c4nc(-c5cccc6ccccc56)nc(-c5cccc6ccccc56)n4)cc3)c21]

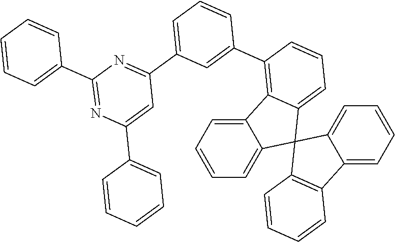 [SMILES: c1ccc(-c2cc(-c3cccc(-c4cccc5c4-c4ccccc4C54c5ccccc5-c5ccccc54)c3)nc(-c3ccccc3)n2)cc1]

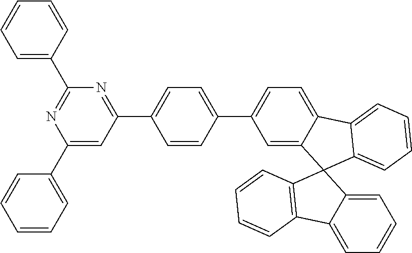 [SMILES: c1ccc(-c2cc(-c3ccc(-c4ccc5c(c4)C4(c6ccccc6-c6ccccc64)c4ccccc4-5)cc3)nc(-c3ccccc3)n2)cc1]

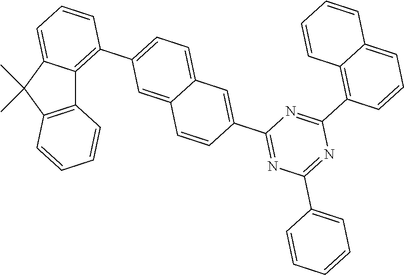 [SMILES: CC1(C)c2ccccc2-c2c(-c3ccc4cc(-c5nc(-c6ccccc6)nc(-c6cccc7ccccc67)n5)ccc4c3)cccc21]

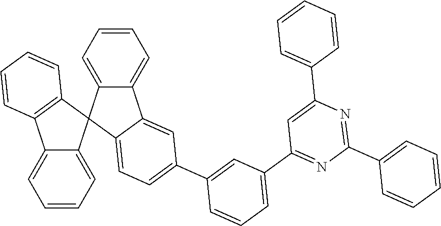 [SMILES: c1ccc(-c2cc(-c3cccc(-c4ccc5c(c4)-c4ccccc4C54c5ccccc5-c5ccccc54)c3)nc(-c3ccccc3)n2)cc1]

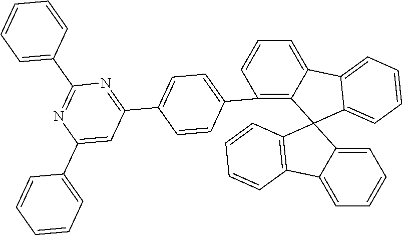 [SMILES: c1ccc(-c2cc(-c3ccc(-c4cccc5c4C4(c6ccccc6-c6ccccc64)c4ccccc4-5)cc3)nc(-c3ccccc3)n2)cc1]

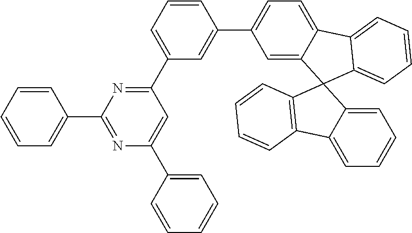 [SMILES: c1ccc(-c2cc(-c3cccc(-c4ccc5c(c4)C4(c6ccccc6-c6ccccc64)c4ccccc4-5)c3)nc(-c3ccccc3)n2)cc1]

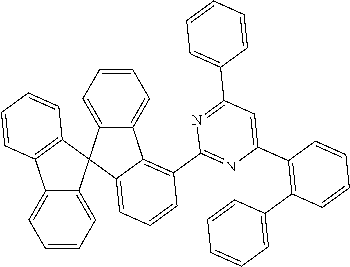 [SMILES: c1ccc(-c2cc(-c3ccccc3-c3ccccc3)nc(-c3cccc4c3-c3ccccc3C43c4ccccc4-c4ccccc43)n2)cc1]

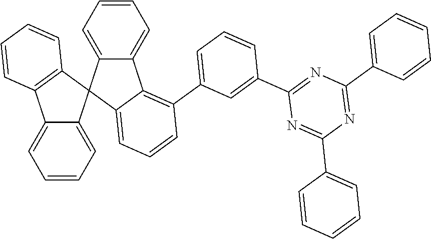 [SMILES: c1ccc(-c2nc(-c3ccccc3)nc(-c3cccc(-c4cccc5c4-c4ccccc4C54c5ccccc5-c5ccccc54)c3)n2)cc1]

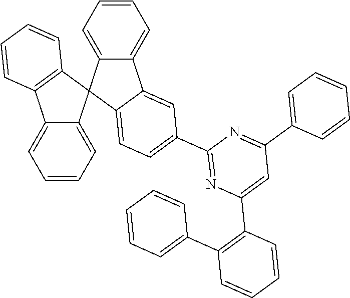 [SMILES: c1ccc(-c2cc(-c3ccccc3-c3ccccc3)nc(-c3ccc4c(c3)-c3ccccc3C43c4ccccc4-c4ccccc43)n2)cc1]

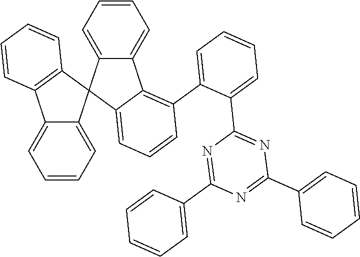 [SMILES: c1ccc(-c2nc(-c3ccccc3)nc(-c3ccccc3-c3cccc4c3-c3ccccc3C43c4ccccc4-c4ccccc43)n2)cc1]

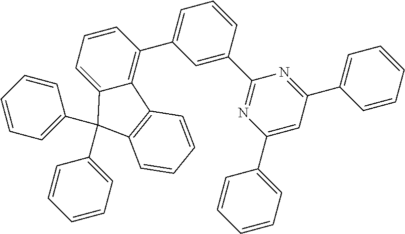 [SMILES: c1ccc(-c2cc(-c3ccccc3)nc(-c3cccc(-c4cccc5c4-c4ccccc4C5(c4ccccc4)c4ccccc4)c3)n2)cc1]

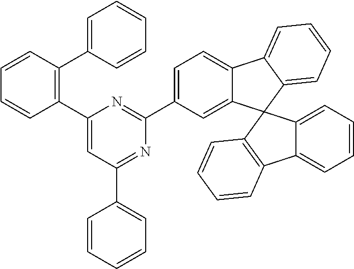 [SMILES: c1ccc(-c2cc(-c3ccccc3-c3ccccc3)nc(-c3ccc4c(c3)C3(c5ccccc5-c5ccccc53)c3ccccc3-4)n2)cc1]

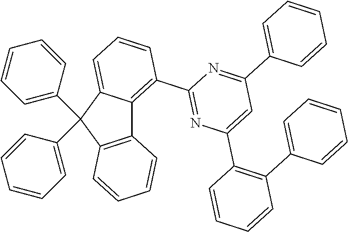 [SMILES: c1ccc(-c2cc(-c3ccccc3-c3ccccc3)nc(-c3cccc4c3-c3ccccc3C4(c3ccccc3)c3ccccc3)n2)cc1]

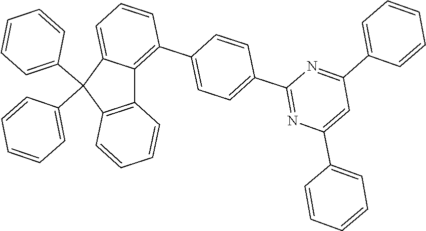 [SMILES: c1ccc(-c2cc(-c3ccccc3)nc(-c3ccc(-c4cccc5c4-c4ccccc4C5(c4ccccc4)c4ccccc4)cc3)n2)cc1]

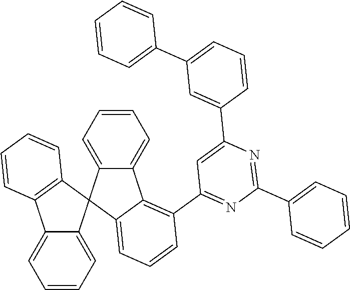 [SMILES: c1ccc(-c2cccc(-c3cc(-c4cccc5c4-c4ccccc4C54c5ccccc5-c5ccccc54)nc(-c4ccccc4)n3)c2)cc1]

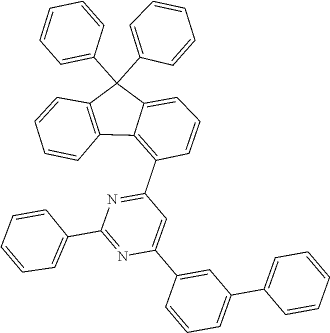 [SMILES: c1ccc(-c2cccc(-c3cc(-c4cccc5c4-c4ccccc4C5(c4ccccc4)c4ccccc4)nc(-c4ccccc4)n3)c2)cc1]

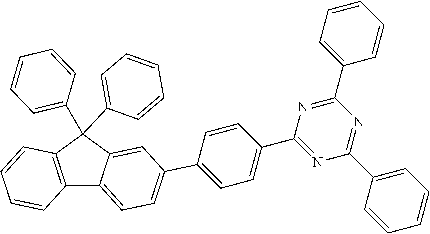 [SMILES: c1ccc(-c2nc(-c3ccccc3)nc(-c3ccc(-c4ccc5c(c4)C(c4ccccc4)(c4ccccc4)c4ccccc4-5)cc3)n2)cc1]

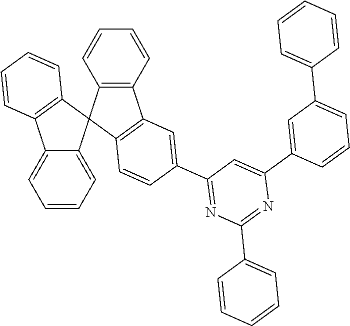 [SMILES: c1ccc(-c2cccc(-c3cc(-c4ccc5c(c4)-c4ccccc4C54c5ccccc5-c5ccccc54)nc(-c4ccccc4)n3)c2)cc1]

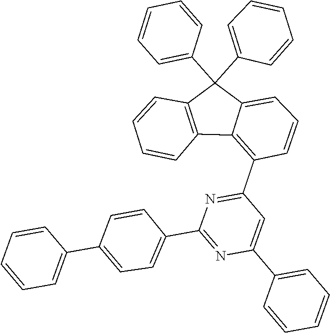 [SMILES: c1ccc(-c2ccc(-c3nc(-c4ccccc4)cc(-c4cccc5c4-c4ccccc4C5(c4ccccc4)c4ccccc4)n3)cc2)cc1]

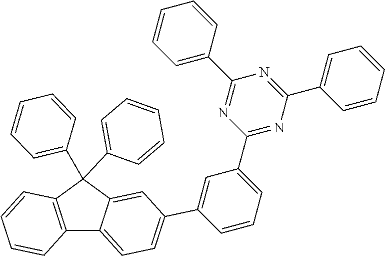 [SMILES: c1ccc(-c2nc(-c3ccccc3)nc(-c3cccc(-c4ccc5c(c4)C(c4ccccc4)(c4ccccc4)c4ccccc4-5)c3)n2)cc1]

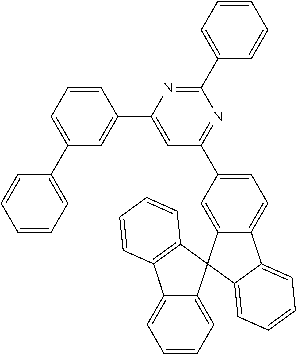 [SMILES: c1ccc(-c2cccc(-c3cc(-c4ccc5c(c4)C4(c6ccccc6-c6ccccc64)c4ccccc4-5)nc(-c4ccccc4)n3)c2)cc1]

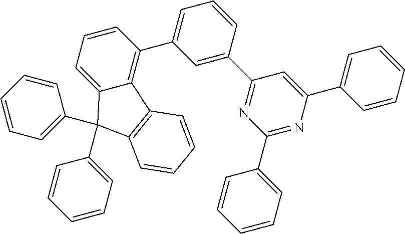 [SMILES: c1ccc(-c2cc(-c3cccc(-c4cccc5c4-c4ccccc4C5(c4ccccc4)c4ccccc4)c3)nc(-c3ccccc3)n2)cc1]

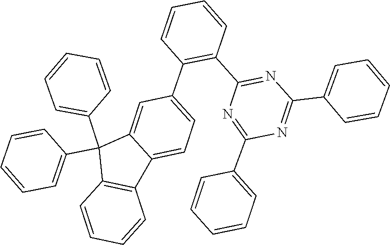 [SMILES: c1ccc(-c2nc(-c3ccccc3)nc(-c3ccccc3-c3ccc4c(c3)C(c3ccccc3)(c3ccccc3)c3ccccc3-4)n2)cc1]

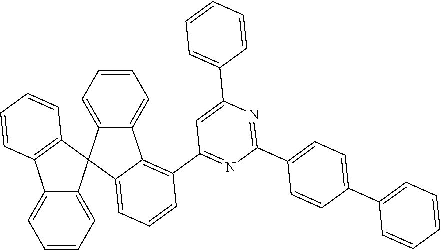 [SMILES: c1ccc(-c2ccc(-c3nc(-c4ccccc4)cc(-c4cccc5c4-c4ccccc4C54c5ccccc5-c5ccccc54)n3)cc2)cc1]

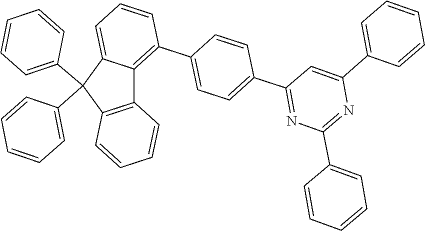 [SMILES: c1ccc(-c2cc(-c3ccc(-c4cccc5c4-c4ccccc4C5(c4ccccc4)c4ccccc4)cc3)nc(-c3ccccc3)n2)cc1]

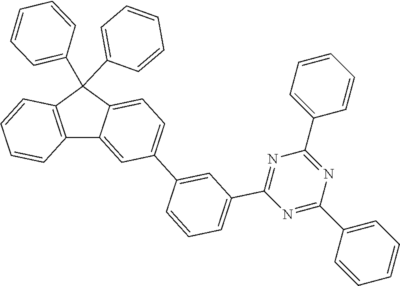 [SMILES: c1ccc(-c2nc(-c3ccccc3)nc(-c3cccc(-c4ccc5c(c4)-c4ccccc4C5(c4ccccc4)c4ccccc4)c3)n2)cc1]

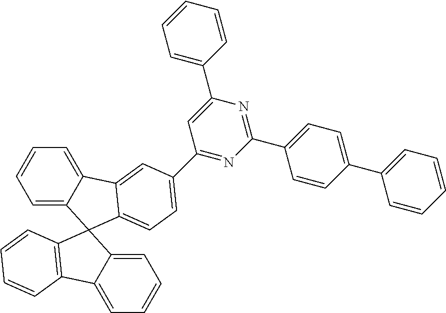 [SMILES: c1ccc(-c2ccc(-c3nc(-c4ccccc4)cc(-c4ccc5c(c4)-c4ccccc4C54c5ccccc5-c5ccccc54)n3)cc2)cc1]

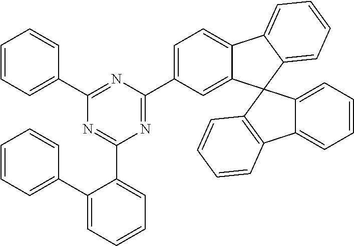 [SMILES: c1ccc(-c2nc(-c3ccc4c(c3)C3(c5ccccc5-c5ccccc53)c3ccccc3-4)nc(-c3ccccc3-c3ccccc3)n2)cc1]

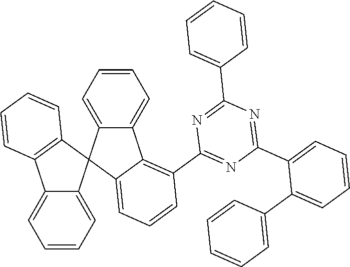 [SMILES: c1ccc(-c2nc(-c3ccccc3-c3ccccc3)nc(-c3cccc4c3-c3ccccc3C43c4ccccc4-c4ccccc43)n2)cc1]

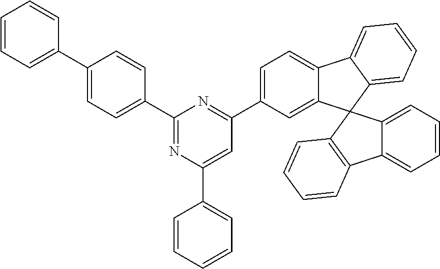 [SMILES: c1ccc(-c2ccc(-c3nc(-c4ccccc4)cc(-c4ccc5c(c4)C4(c6ccccc6-c6ccccc64)c4ccccc4-5)n3)cc2)cc1]

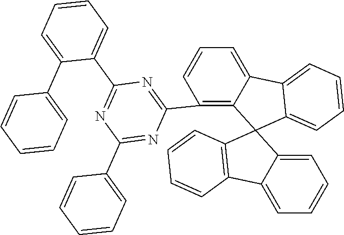 [SMILES: c1ccc(-c2nc(-c3ccccc3-c3ccccc3)nc(-c3cccc4c3C3(c5ccccc5-c5ccccc53)c3ccccc3-4)n2)cc1]

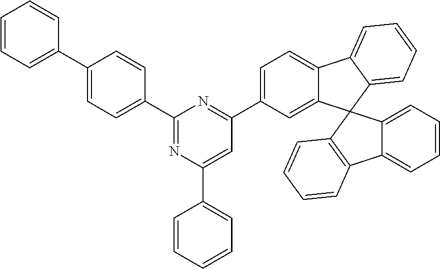 [SMILES: c1ccc(-c2ccc(-c3nc(-c4ccccc4)cc(-c4ccc5c(c4)C4(c6ccccc6-c6ccccc64)c4ccccc4-5)n3)cc2)cc1]

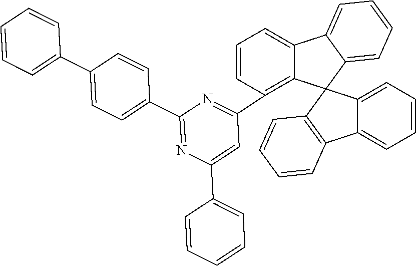 [SMILES: c1ccc(-c2ccc(-c3nc(-c4ccccc4)cc(-c4cccc5c4C4(c6ccccc6-c6ccccc64)c4ccccc4-5)n3)cc2)cc1]

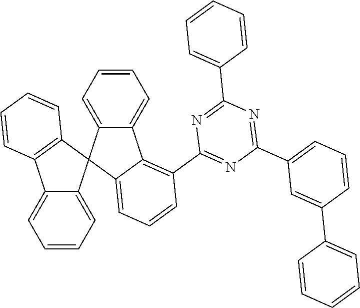 [SMILES: c1ccc(-c2cccc(-c3nc(-c4ccccc4)nc(-c4cccc5c4-c4ccccc4C54c5ccccc5-c5ccccc54)n3)c2)cc1]

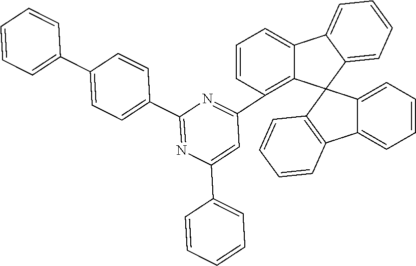 [SMILES: c1ccc(-c2ccc(-c3nc(-c4ccccc4)cc(-c4cccc5c4C4(c6ccccc6-c6ccccc64)c4ccccc4-5)n3)cc2)cc1]

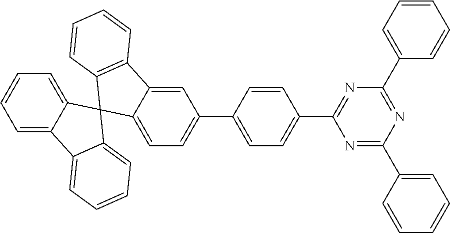 [SMILES: c1ccc(-c2nc(-c3ccccc3)nc(-c3ccc(-c4ccc5c(c4)-c4ccccc4C54c5ccccc5-c5ccccc54)cc3)n2)cc1]

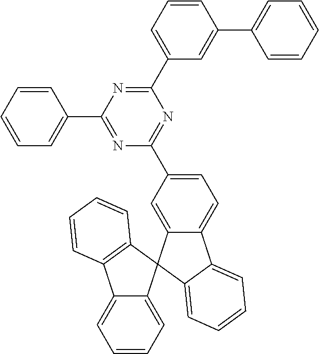 [SMILES: c1ccc(-c2cccc(-c3nc(-c4ccccc4)nc(-c4ccc5c(c4)C4(c6ccccc6-c6ccccc64)c4ccccc4-5)n3)c2)cc1]

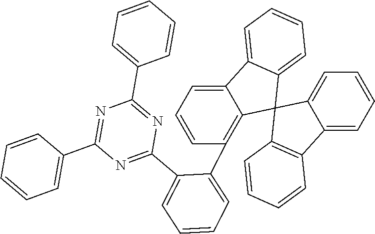 [SMILES: c1ccc(-c2nc(-c3ccccc3)nc(-c3ccccc3-c3cccc4c3C3(c5ccccc5-c5ccccc53)c3ccccc3-4)n2)cc1]

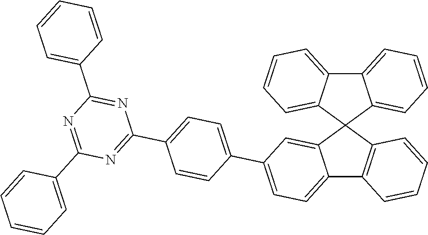 [SMILES: c1ccc(-c2nc(-c3ccccc3)nc(-c3ccc(-c4ccc5c(c4)C4(c6ccccc6-c6ccccc64)c4ccccc4-5)cc3)n2)cc1]

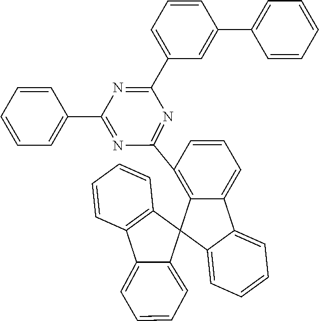 [SMILES: c1ccc(-c2cccc(-c3nc(-c4ccccc4)nc(-c4cccc5c4C4(c6ccccc6-c6ccccc64)c4ccccc4-5)n3)c2)cc1]

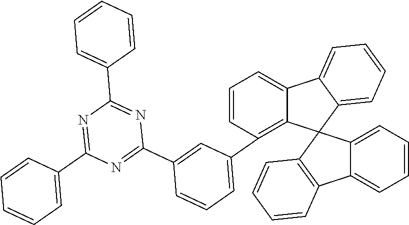 [SMILES: c1ccc(-c2nc(-c3ccccc3)nc(-c3cccc(-c4cccc5c4C4(c6ccccc6-c6ccccc64)c4ccccc4-5)c3)n2)cc1]

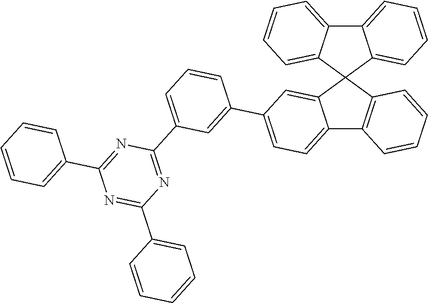 [SMILES: c1ccc(-c2nc(-c3ccccc3)nc(-c3cccc(-c4ccc5c(c4)C4(c6ccccc6-c6ccccc64)c4ccccc4-5)c3)n2)cc1]

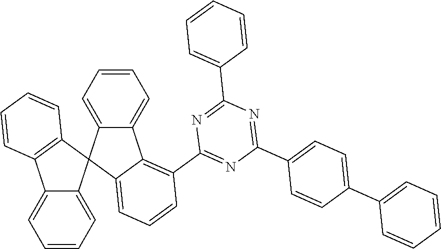 [SMILES: c1ccc(-c2ccc(-c3nc(-c4ccccc4)nc(-c4cccc5c4-c4ccccc4C54c5ccccc5-c5ccccc54)n3)cc2)cc1]

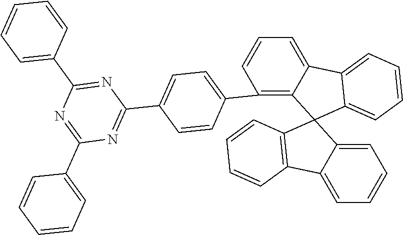 [SMILES: c1ccc(-c2nc(-c3ccccc3)nc(-c3ccc(-c4cccc5c4C4(c6ccccc6-c6ccccc64)c4ccccc4-5)cc3)n2)cc1]

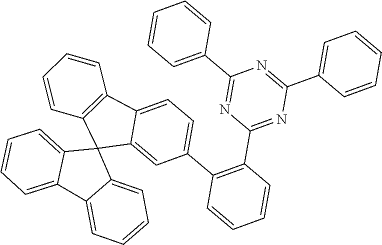 [SMILES: c1ccc(-c2nc(-c3ccccc3)nc(-c3ccccc3-c3ccc4c(c3)C3(c5ccccc5-c5ccccc53)c3ccccc3-4)n2)cc1]

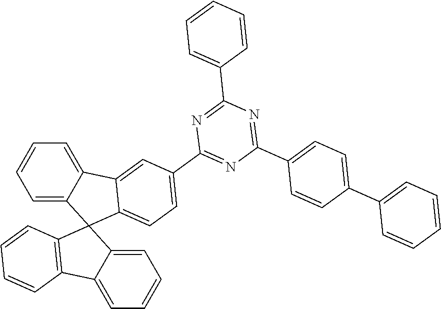 [SMILES: c1ccc(-c2ccc(-c3nc(-c4ccccc4)nc(-c4ccc5c(c4)-c4ccccc4C54c5ccccc5-c5ccccc54)n3)cc2)cc1]

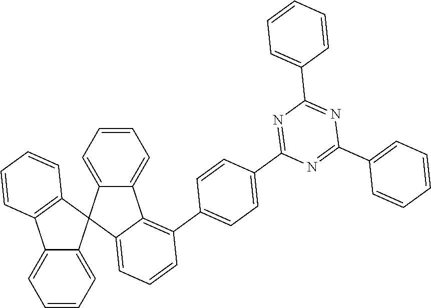 [SMILES: c1ccc(-c2nc(-c3ccccc3)nc(-c3ccc(-c4cccc5c4-c4ccccc4C54c5ccccc5-c5ccccc54)cc3)n2)cc1]

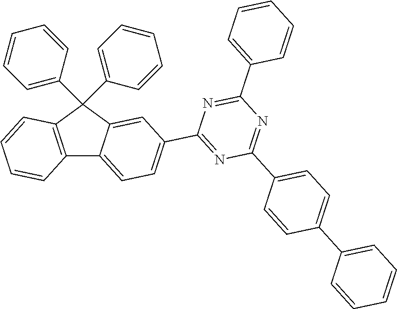 [SMILES: c1ccc(-c2ccc(-c3nc(-c4ccccc4)nc(-c4ccc5c(c4)C(c4ccccc4)(c4ccccc4)c4ccccc4-5)n3)cc2)cc1]

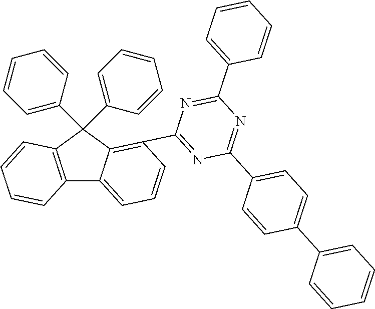 [SMILES: c1ccc(-c2ccc(-c3nc(-c4ccccc4)nc(-c4cccc5c4C(c4ccccc4)(c4ccccc4)c4ccccc4-5)n3)cc2)cc1]

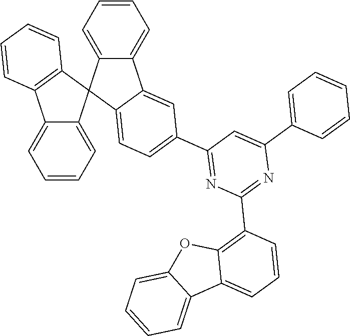 [SMILES: c1ccc(-c2cc(-c3ccc4c(c3)-c3ccccc3C43c4ccccc4-c4ccccc43)nc(-c3cccc4c3oc3ccccc34)n2)cc1]

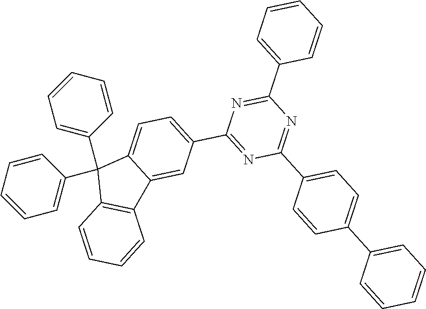 [SMILES: c1ccc(-c2ccc(-c3nc(-c4ccccc4)nc(-c4ccc5c(c4)-c4ccccc4C5(c4ccccc4)c4ccccc4)n3)cc2)cc1]

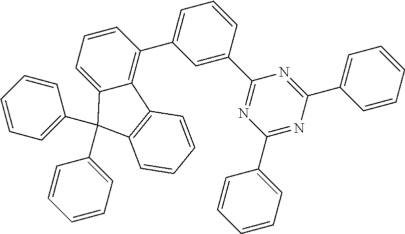 [SMILES: c1ccc(-c2nc(-c3ccccc3)nc(-c3cccc(-c4cccc5c4-c4ccccc4C5(c4ccccc4)c4ccccc4)c3)n2)cc1]

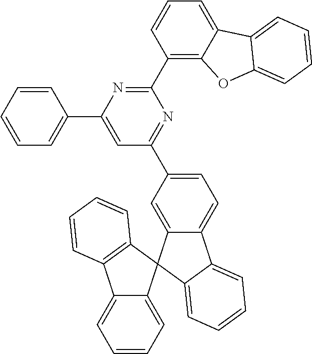 [SMILES: c1ccc(-c2cc(-c3ccc4c(c3)C3(c5ccccc5-c5ccccc53)c3ccccc3-4)nc(-c3cccc4c3oc3ccccc34)n2)cc1]

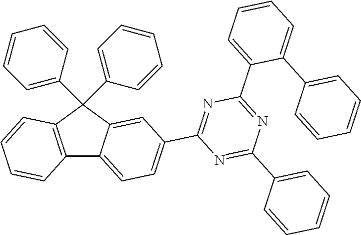 [SMILES: c1ccc(-c2nc(-c3ccc4c(c3)C(c3ccccc3)(c3ccccc3)c3ccccc3-4)nc(-c3ccccc3-c3ccccc3)n2)cc1]

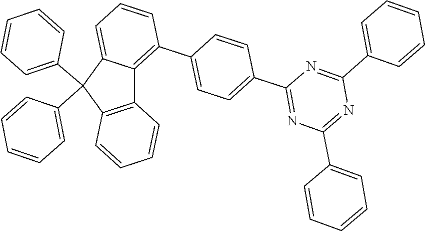 [SMILES: c1ccc(-c2nc(-c3ccccc3)nc(-c3ccc(-c4cccc5c4-c4ccccc4C5(c4ccccc4)c4ccccc4)cc3)n2)cc1]

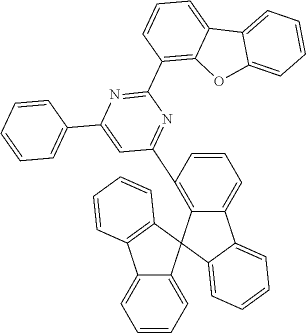 [SMILES: c1ccc(-c2cc(-c3cccc4c3C3(c5ccccc5-c5ccccc53)c3ccccc3-4)nc(-c3cccc4c3oc3ccccc34)n2)cc1]

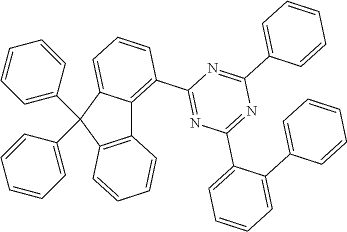 [SMILES: c1ccc(-c2nc(-c3ccccc3-c3ccccc3)nc(-c3cccc4c3-c3ccccc3C4(c3ccccc3)c3ccccc3)n2)cc1]

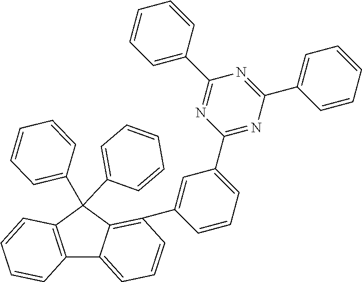 [SMILES: c1ccc(-c2nc(-c3ccccc3)nc(-c3cccc(-c4cccc5c4C(c4ccccc4)(c4ccccc4)c4ccccc4-5)c3)n2)cc1]

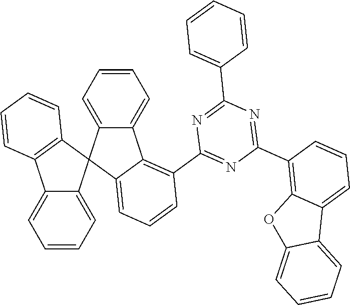 [SMILES: c1ccc(-c2nc(-c3cccc4c3-c3ccccc3C43c4ccccc4-c4ccccc43)nc(-c3cccc4c3oc3ccccc34)n2)cc1]

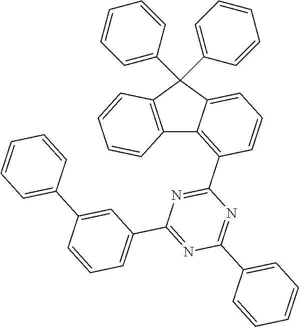 [SMILES: c1ccc(-c2cccc(-c3nc(-c4ccccc4)nc(-c4cccc5c4-c4ccccc4C5(c4ccccc4)c4ccccc4)n3)c2)cc1]

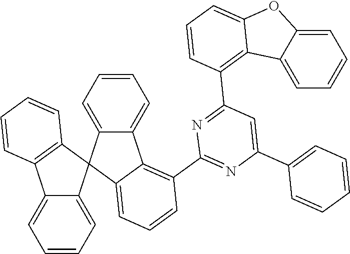 [SMILES: c1ccc(-c2cc(-c3cccc4oc5ccccc5c34)nc(-c3cccc4c3-c3ccccc3C43c4ccccc4-c4ccccc43)n2)cc1]

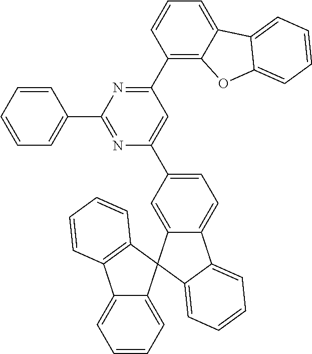 [SMILES: c1ccc(-c2nc(-c3ccc4c(c3)C3(c5ccccc5-c5ccccc53)c3ccccc3-4)cc(-c3cccc4c3oc3ccccc34)n2)cc1]

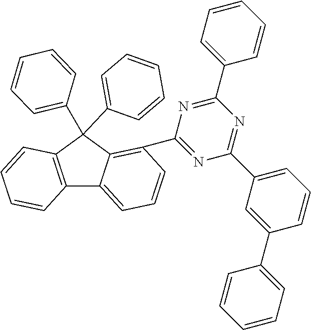 [SMILES: c1ccc(-c2cccc(-c3nc(-c4ccccc4)nc(-c4cccc5c4C(c4ccccc4)(c4ccccc4)c4ccccc4-5)n3)c2)cc1]

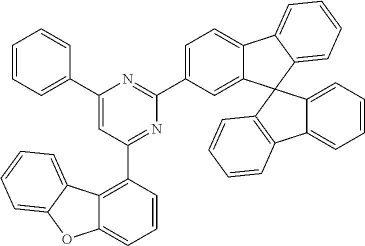 [SMILES: c1ccc(-c2cc(-c3cccc4oc5ccccc5c34)nc(-c3ccc4c(c3)C3(c5ccccc5-c5ccccc53)c3ccccc3-4)n2)cc1]

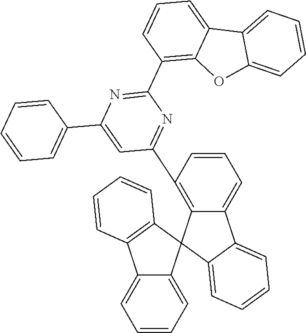 [SMILES: c1ccc(-c2cc(-c3cccc4c3C3(c5ccccc5-c5ccccc53)c3ccccc3-4)nc(-c3cccc4c3oc3ccccc34)n2)cc1]

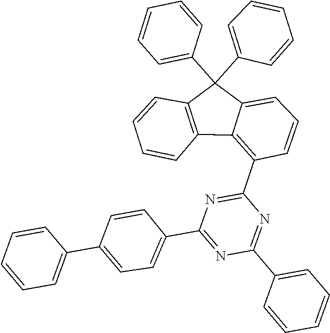 [SMILES: c1ccc(-c2ccc(-c3nc(-c4ccccc4)nc(-c4cccc5c4-c4ccccc4C5(c4ccccc4)c4ccccc4)n3)cc2)cc1]

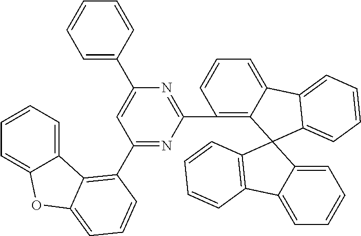 [SMILES: c1ccc(-c2cc(-c3cccc4oc5ccccc5c34)nc(-c3cccc4c3C3(c5ccccc5-c5ccccc53)c3ccccc3-4)n2)cc1]

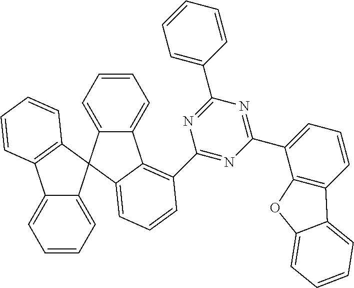 [SMILES: c1ccc(-c2nc(-c3cccc4c3-c3ccccc3C43c4ccccc4-c4ccccc43)nc(-c3cccc4c3oc3ccccc34)n2)cc1]

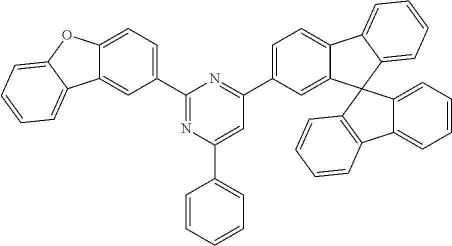 [SMILES: c1ccc(-c2cc(-c3ccc4c(c3)C3(c5ccccc5-c5ccccc53)c3ccccc3-4)nc(-c3ccc4oc5ccccc5c4c3)n2)cc1]

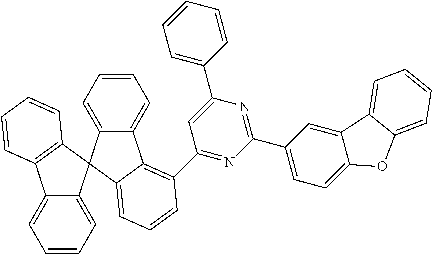 [SMILES: c1ccc(-c2cc(-c3cccc4c3-c3ccccc3C43c4ccccc4-c4ccccc43)nc(-c3ccc4oc5ccccc5c4c3)n2)cc1]

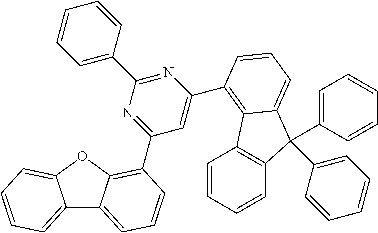 [SMILES: c1ccc(-c2nc(-c3cccc4c3-c3ccccc3C4(c3ccccc3)c3ccccc3)cc(-c3cccc4c3oc3ccccc34)n2)cc1]

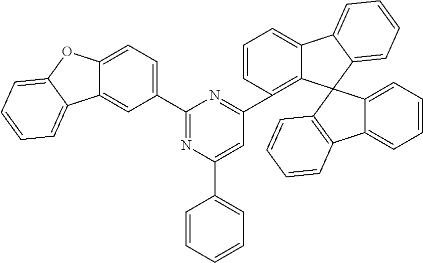 [SMILES: c1ccc(-c2cc(-c3cccc4c3C3(c5ccccc5-c5ccccc53)c3ccccc3-4)nc(-c3ccc4oc5ccccc5c4c3)n2)cc1]

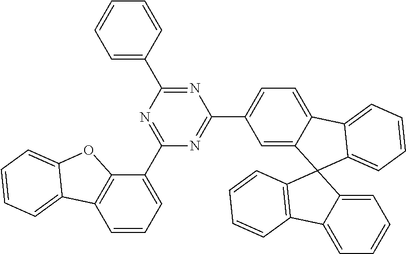 [SMILES: c1ccc(-c2nc(-c3ccc4c(c3)C3(c5ccccc5-c5ccccc53)c3ccccc3-4)nc(-c3cccc4c3oc3ccccc34)n2)cc1]

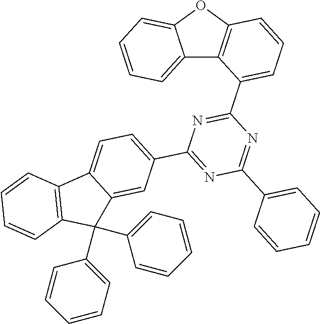 [SMILES: c1ccc(-c2nc(-c3ccc4c(c3)C(c3ccccc3)(c3ccccc3)c3ccccc3-4)nc(-c3cccc4oc5ccccc5c34)n2)cc1]

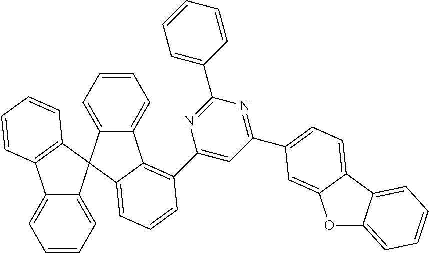 [SMILES: c1ccc(-c2nc(-c3ccc4c(c3)oc3ccccc34)cc(-c3cccc4c3-c3ccccc3C43c4ccccc4-c4ccccc43)n2)cc1]

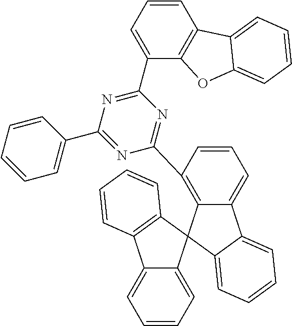 [SMILES: c1ccc(-c2nc(-c3cccc4c3C3(c5ccccc5-c5ccccc53)c3ccccc3-4)nc(-c3cccc4c3oc3ccccc34)n2)cc1]

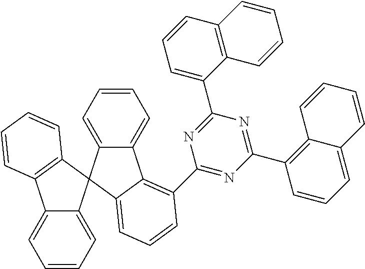 [SMILES: c1ccc2c(c1)-c1ccccc1C21c2ccccc2-c2c(-c3nc(-c4cccc5ccccc45)nc(-c4cccc5ccccc45)n3)cccc21]

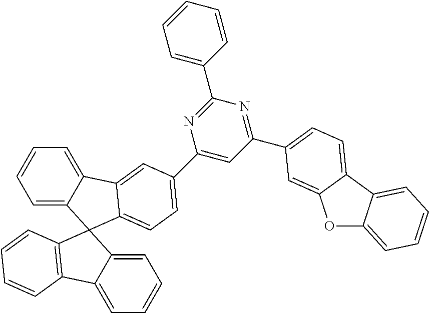 [SMILES: c1ccc(-c2nc(-c3ccc4c(c3)-c3ccccc3C43c4ccccc4-c4ccccc43)cc(-c3ccc4c(c3)oc3ccccc34)n2)cc1]

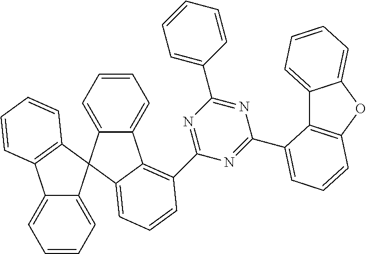 [SMILES: c1ccc(-c2nc(-c3cccc4c3-c3ccccc3C43c4ccccc4-c4ccccc43)nc(-c3cccc4oc5ccccc5c34)n2)cc1]

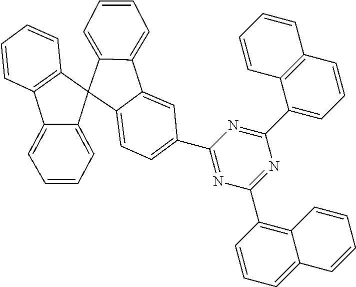 [SMILES: c1ccc2c(c1)-c1ccccc1C21c2ccccc2-c2cc(-c3nc(-c4cccc5ccccc45)nc(-c4cccc5ccccc45)n3)ccc21]

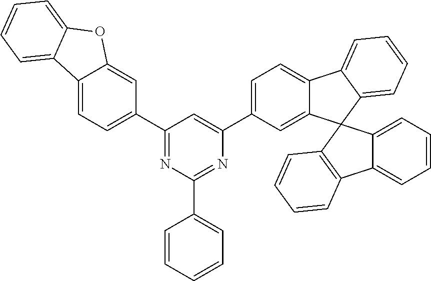 [SMILES: c1ccc(-c2nc(-c3ccc4c(c3)C3(c5ccccc5-c5ccccc53)c3ccccc3-4)cc(-c3ccc4c(c3)oc3ccccc34)n2)cc1]

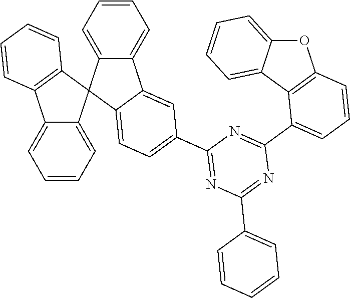 [SMILES: c1ccc(-c2nc(-c3ccc4c(c3)-c3ccccc3C43c4ccccc4-c4ccccc43)nc(-c3cccc4oc5ccccc5c34)n2)cc1]

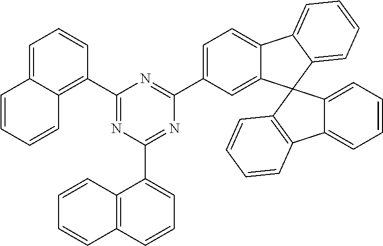 [SMILES: c1ccc2c(c1)-c1ccccc1C21c2ccccc2-c2ccc(-c3nc(-c4cccc5ccccc45)nc(-c4cccc5ccccc45)n3)cc21]

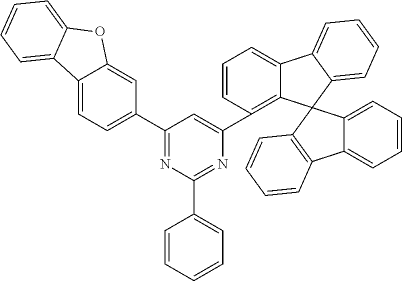 [SMILES: c1ccc(-c2nc(-c3ccc4c(c3)oc3ccccc34)cc(-c3cccc4c3C3(c5ccccc5-c5ccccc53)c3ccccc3-4)n2)cc1]

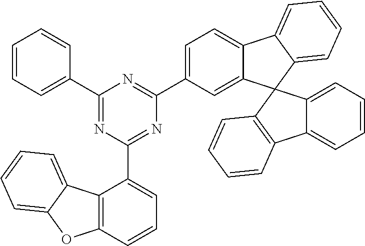 [SMILES: c1ccc(-c2nc(-c3ccc4c(c3)C3(c5ccccc5-c5ccccc53)c3ccccc3-4)nc(-c3cccc4oc5ccccc5c34)n2)cc1]

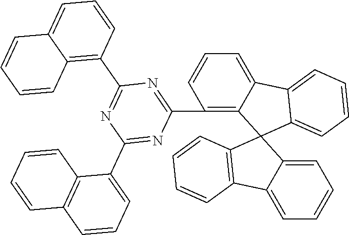 [SMILES: c1ccc2c(c1)-c1ccccc1C21c2ccccc2-c2cccc(-c3nc(-c4cccc5ccccc45)nc(-c4cccc5ccccc45)n3)c21]

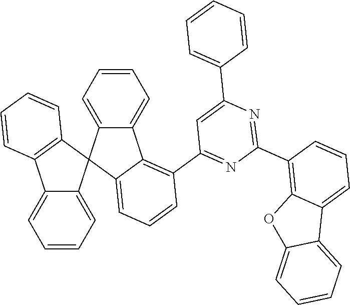 [SMILES: c1ccc(-c2cc(-c3cccc4c3-c3ccccc3C43c4ccccc4-c4ccccc43)nc(-c3cccc4c3oc3ccccc34)n2)cc1]

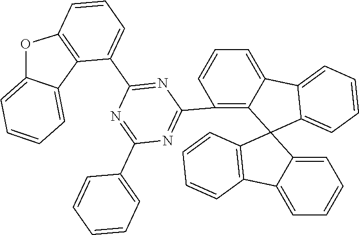 [SMILES: c1ccc(-c2nc(-c3cccc4c3C3(c5ccccc5-c5ccccc53)c3ccccc3-4)nc(-c3cccc4oc5ccccc5c34)n2)cc1]

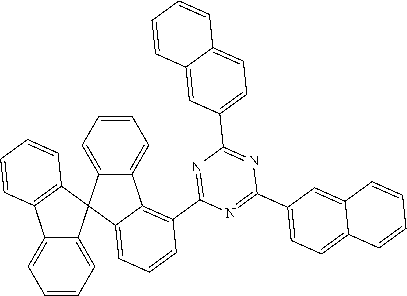 [SMILES: c1ccc2c(c1)-c1ccccc1C21c2ccccc2-c2c(-c3nc(-c4ccc5ccccc5c4)nc(-c4ccc5ccccc5c4)n3)cccc21]

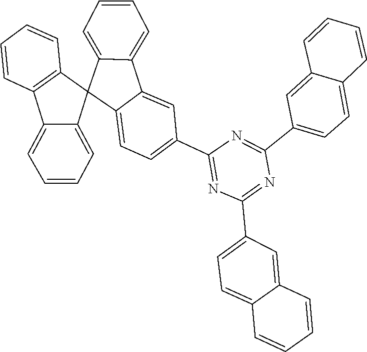 [SMILES: c1ccc2c(c1)-c1ccccc1C21c2ccccc2-c2cc(-c3nc(-c4ccc5ccccc5c4)nc(-c4ccc5ccccc5c4)n3)ccc21]

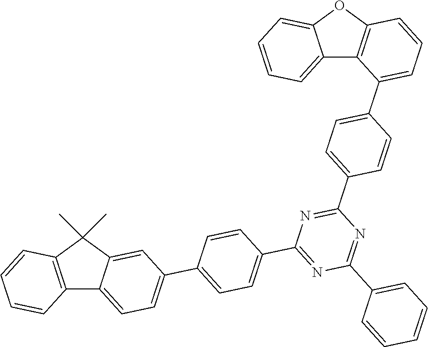 [SMILES: CC1(C)c2ccccc2-c2ccc(-c3ccc(-c4nc(-c5ccccc5)nc(-c5ccc(-c6cccc7oc8ccccc8c67)cc5)n4)cc3)cc21]

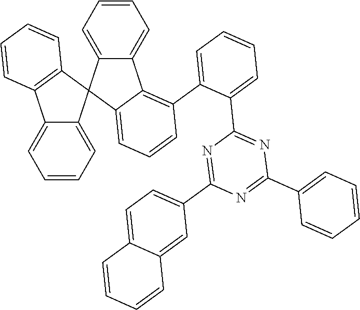 [SMILES: c1ccc(-c2nc(-c3ccc4ccccc4c3)nc(-c3ccccc3-c3cccc4c3-c3ccccc3C43c4ccccc4-c4ccccc43)n2)cc1]

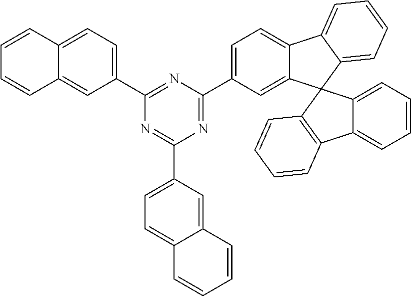 [SMILES: c1ccc2c(c1)-c1ccccc1C21c2ccccc2-c2ccc(-c3nc(-c4ccc5ccccc5c4)nc(-c4ccc5ccccc5c4)n3)cc21]

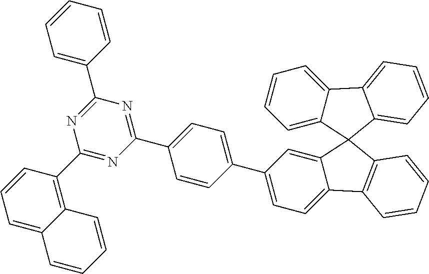 [SMILES: c1ccc(-c2nc(-c3ccc(-c4ccc5c(c4)C4(c6ccccc6-c6ccccc64)c4ccccc4-5)cc3)nc(-c3cccc4ccccc34)n2)cc1]

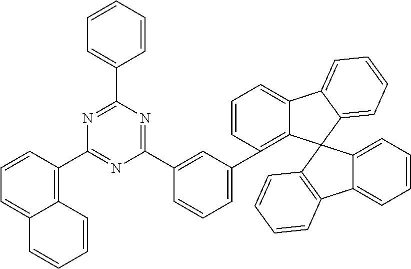 [SMILES: c1ccc(-c2nc(-c3cccc(-c4cccc5c4C4(c6ccccc6-c6ccccc64)c4ccccc4-5)c3)nc(-c3cccc4ccccc34)n2)cc1]

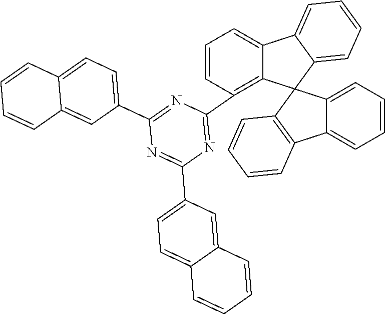 [SMILES: c1ccc2c(c1)-c1ccccc1C21c2ccccc2-c2cccc(-c3nc(-c4ccc5ccccc5c4)nc(-c4ccc5ccccc5c4)n3)c21]

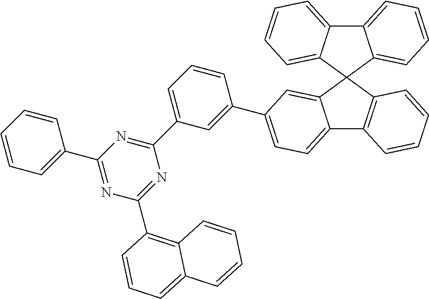 [SMILES: c1ccc(-c2nc(-c3cccc(-c4ccc5c(c4)C4(c6ccccc6-c6ccccc64)c4ccccc4-5)c3)nc(-c3cccc4ccccc34)n2)cc1]

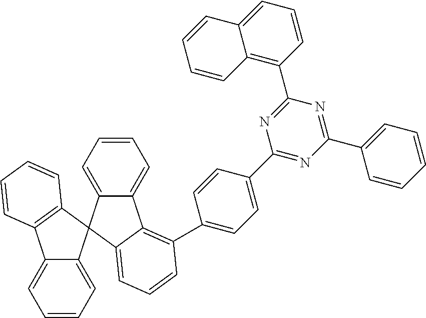 [SMILES: c1ccc(-c2nc(-c3ccc(-c4cccc5c4-c4ccccc4C54c5ccccc5-c5ccccc54)cc3)nc(-c3cccc4ccccc34)n2)cc1]

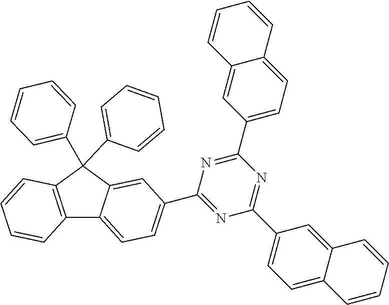 [SMILES: c1ccc(C2(c3ccccc3)c3ccccc3-c3ccc(-c4nc(-c5ccc6ccccc6c5)nc(-c5ccc6ccccc6c5)n4)cc32)cc1]

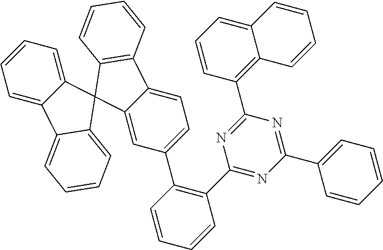 [SMILES: c1ccc(-c2nc(-c3ccccc3-c3ccc4c(c3)C3(c5ccccc5-c5ccccc53)c3ccccc3-4)nc(-c3cccc4ccccc34)n2)cc1]

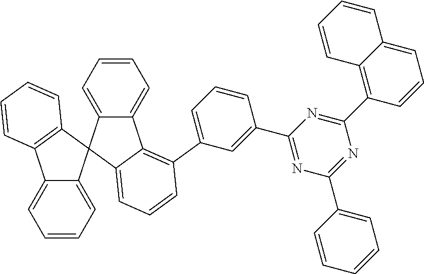 [SMILES: c1ccc(-c2nc(-c3cccc(-c4cccc5c4-c4ccccc4C54c5ccccc5-c5ccccc54)c3)nc(-c3cccc4ccccc34)n2)cc1]

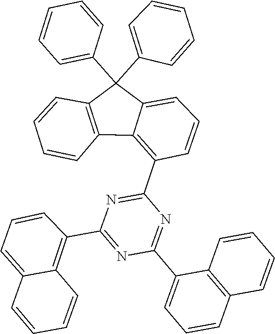 [SMILES: c1ccc(C2(c3ccccc3)c3ccccc3-c3c(-c4nc(-c5cccc6ccccc56)nc(-c5cccc6ccccc56)n4)cccc32)cc1]

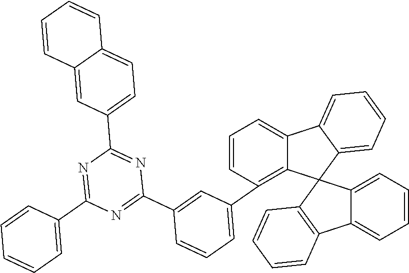 [SMILES: c1ccc(-c2nc(-c3cccc(-c4cccc5c4C4(c6ccccc6-c6ccccc64)c4ccccc4-5)c3)nc(-c3ccc4ccccc4c3)n2)cc1]

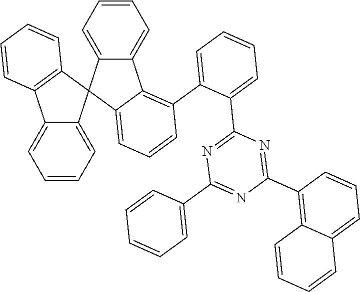 [SMILES: c1ccc(-c2nc(-c3ccccc3-c3cccc4c3-c3ccccc3C43c4ccccc4-c4ccccc43)nc(-c3cccc4ccccc34)n2)cc1]

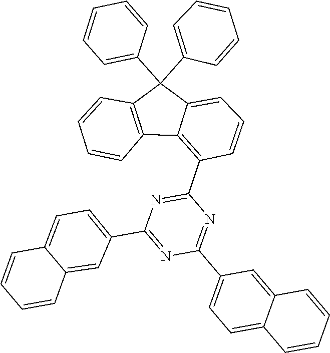 [SMILES: c1ccc(C2(c3ccccc3)c3ccccc3-c3c(-c4nc(-c5ccc6ccccc6c5)nc(-c5ccc6ccccc6c5)n4)cccc32)cc1]

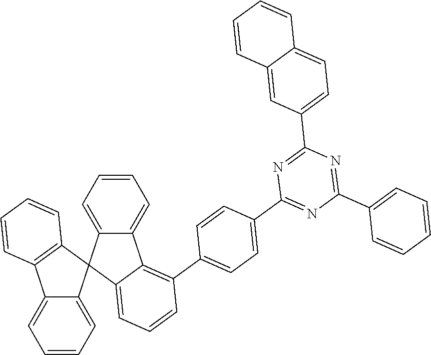 [SMILES: c1ccc(-c2nc(-c3ccc(-c4cccc5c4-c4ccccc4C54c5ccccc5-c5ccccc54)cc3)nc(-c3ccc4ccccc4c3)n2)cc1]

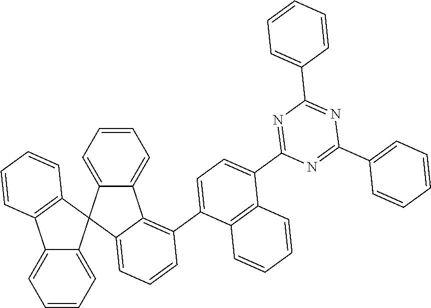 [SMILES: c1ccc(-c2nc(-c3ccccc3)nc(-c3ccc(-c4cccc5c4-c4ccccc4C54c5ccccc5-c5ccccc54)c4ccccc34)n2)cc1]

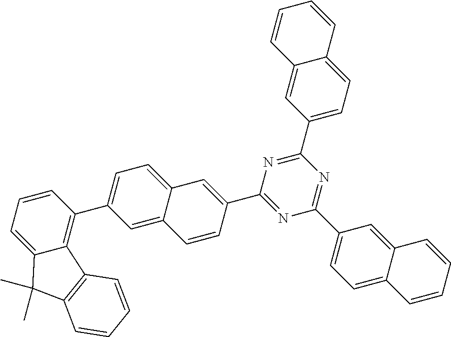 [SMILES: CC1(C)c2ccccc2-c2c(-c3ccc4cc(-c5nc(-c6ccc7ccccc7c6)nc(-c6ccc7ccccc7c6)n5)ccc4c3)cccc21]

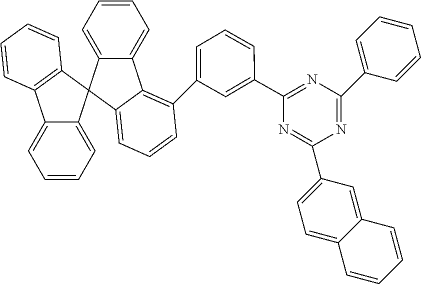 [SMILES: c1ccc(-c2nc(-c3cccc(-c4cccc5c4-c4ccccc4C54c5ccccc5-c5ccccc54)c3)nc(-c3ccc4ccccc4c3)n2)cc1]

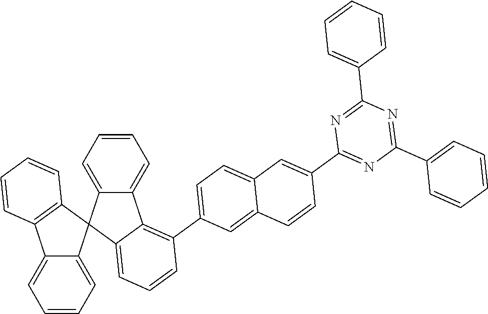 [SMILES: c1ccc(-c2nc(-c3ccccc3)nc(-c3ccc4cc(-c5cccc6c5-c5ccccc5C65c6ccccc6-c6ccccc65)ccc4c3)n2)cc1]

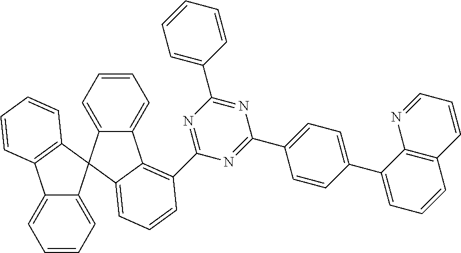 [SMILES: c1ccc(-c2nc(-c3ccc(-c4cccc5cccnc45)cc3)nc(-c3cccc4c3-c3ccccc3C43c4ccccc4-c4ccccc43)n2)cc1]

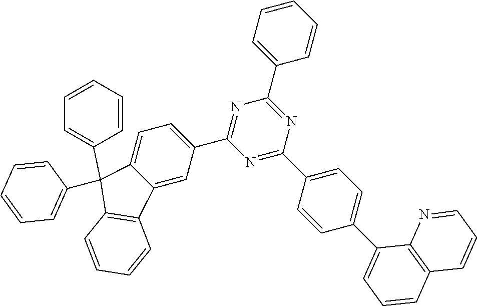 [SMILES: c1ccc(-c2nc(-c3ccc(-c4cccc5cccnc45)cc3)nc(-c3ccc4c(c3)-c3ccccc3C4(c3ccccc3)c3ccccc3)n2)cc1]

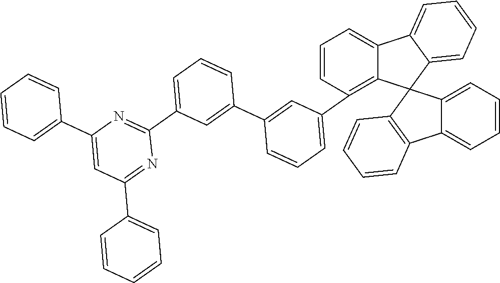 [SMILES: c1ccc(-c2cc(-c3ccccc3)nc(-c3cccc(-c4cccc(-c5cccc6c5C5(c7ccccc7-c7ccccc75)c5ccccc5-6)c4)c3)n2)cc1]

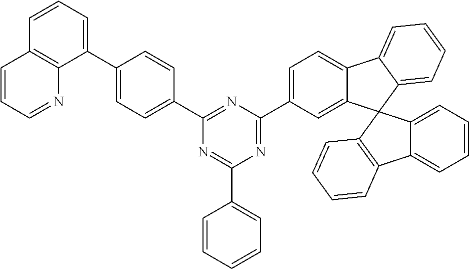 [SMILES: c1ccc(-c2nc(-c3ccc(-c4cccc5cccnc45)cc3)nc(-c3ccc4c(c3)C3(c5ccccc5-c5ccccc53)c3ccccc3-4)n2)cc1]

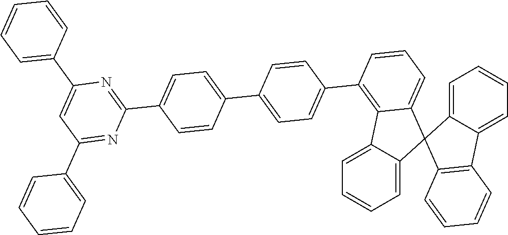 [SMILES: c1ccc(-c2cc(-c3ccccc3)nc(-c3ccc(-c4ccc(-c5cccc6c5-c5ccccc5C65c6ccccc6-c6ccccc65)cc4)cc3)n2)cc1]

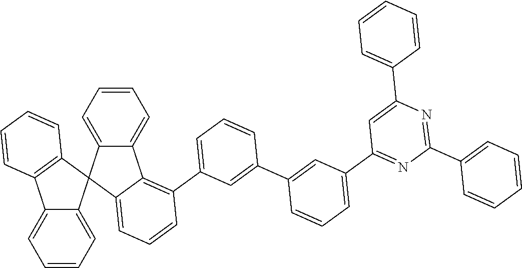 [SMILES: c1ccc(-c2cc(-c3cccc(-c4cccc(-c5cccc6c5-c5ccccc5C65c6ccccc6-c6ccccc65)c4)c3)nc(-c3ccccc3)n2)cc1]

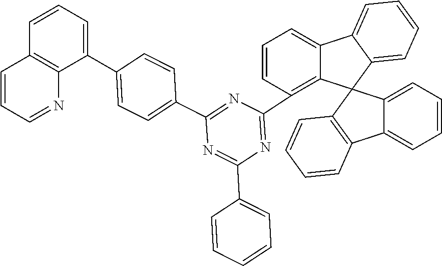 [SMILES: c1ccc(-c2nc(-c3ccc(-c4cccc5cccnc45)cc3)nc(-c3cccc4c3C3(c5ccccc5-c5ccccc53)c3ccccc3-4)n2)cc1]

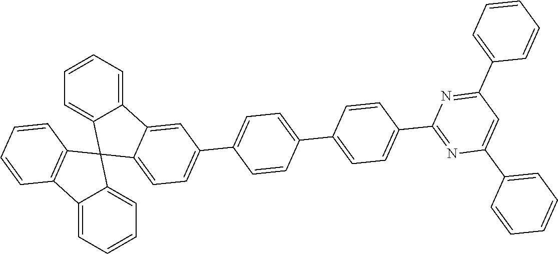 [SMILES: c1ccc(-c2cc(-c3ccccc3)nc(-c3ccc(-c4ccc(-c5ccc6c(c5)-c5ccccc5C65c6ccccc6-c6ccccc65)cc4)cc3)n2)cc1]

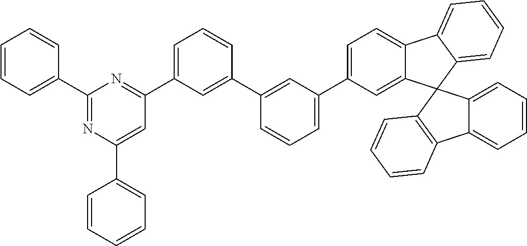 [SMILES: c1ccc(-c2cc(-c3cccc(-c4cccc(-c5ccc6c(c5)C5(c7ccccc7-c7ccccc75)c5ccccc5-6)c4)c3)nc(-c3ccccc3)n2)cc1]

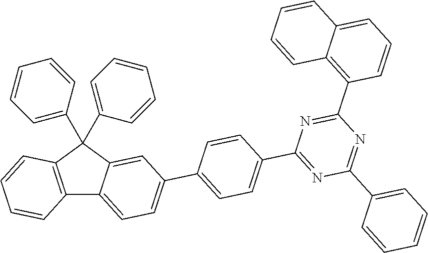 [SMILES: c1ccc(-c2nc(-c3ccc(-c4ccc5c(c4)C(c4ccccc4)(c4ccccc4)c4ccccc4-5)cc3)nc(-c3cccc4ccccc34)n2)cc1]

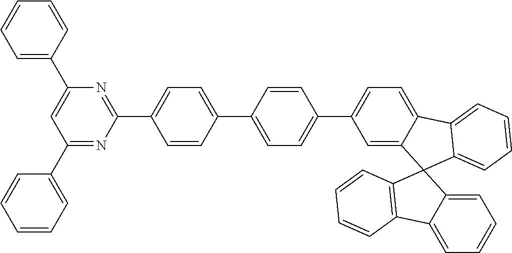 [SMILES: c1ccc(-c2cc(-c3ccccc3)nc(-c3ccc(-c4ccc(-c5ccc6c(c5)C5(c7ccccc7-c7ccccc75)c5ccccc5-6)cc4)cc3)n2)cc1]

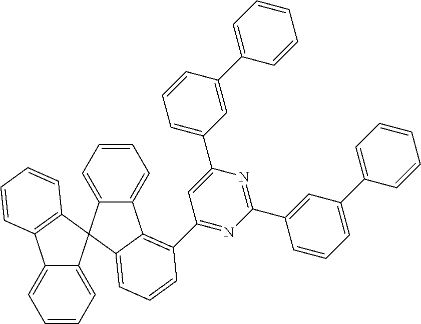 [SMILES: c1ccc(-c2cccc(-c3cc(-c4cccc5c4-c4ccccc4C54c5ccccc5-c5ccccc54)nc(-c4cccc(-c5ccccc5)c4)n3)c2)cc1]

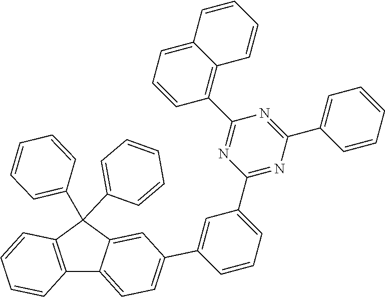 [SMILES: c1ccc(-c2nc(-c3cccc(-c4ccc5c(c4)C(c4ccccc4)(c4ccccc4)c4ccccc4-5)c3)nc(-c3cccc4ccccc34)n2)cc1]

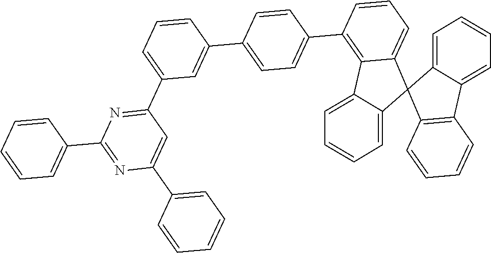 [SMILES: c1ccc(-c2cc(-c3cccc(-c4ccc(-c5cccc6c5-c5ccccc5C65c6ccccc6-c6ccccc65)cc4)c3)nc(-c3ccccc3)n2)cc1]

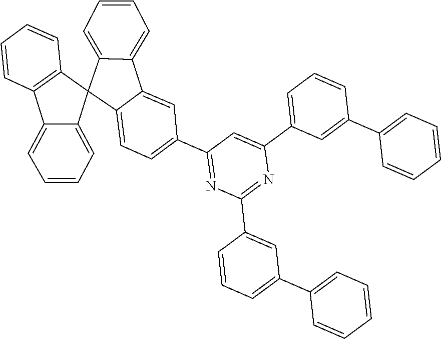 [SMILES: c1ccc(-c2cccc(-c3cc(-c4ccc5c(c4)-c4ccccc4C54c5ccccc5-c5ccccc54)nc(-c4cccc(-c5ccccc5)c4)n3)c2)cc1]

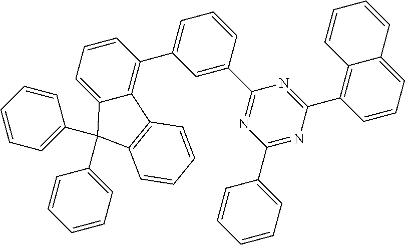 [SMILES: c1ccc(-c2nc(-c3cccc(-c4cccc5c4-c4ccccc4C5(c4ccccc4)c4ccccc4)c3)nc(-c3cccc4ccccc34)n2)cc1]

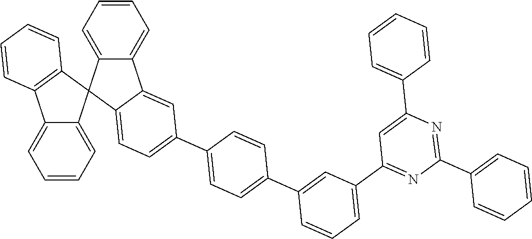 [SMILES: c1ccc(-c2cc(-c3cccc(-c4ccc(-c5ccc6c(c5)-c5ccccc5C65c6ccccc6-c6ccccc65)cc4)c3)nc(-c3ccccc3)n2)cc1]

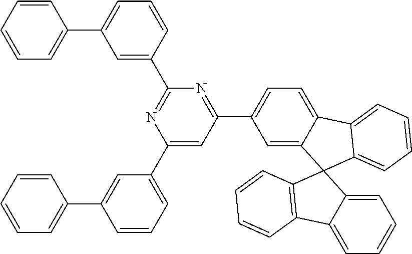 [SMILES: c1ccc(-c2cccc(-c3cc(-c4ccc5c(c4)C4(c6ccccc6-c6ccccc64)c4ccccc4-5)nc(-c4cccc(-c5ccccc5)c4)n3)c2)cc1]

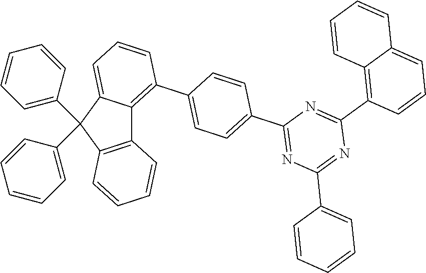 [SMILES: c1ccc(-c2nc(-c3ccc(-c4cccc5c4-c4ccccc4C5(c4ccccc4)c4ccccc4)cc3)nc(-c3cccc4ccccc34)n2)cc1]

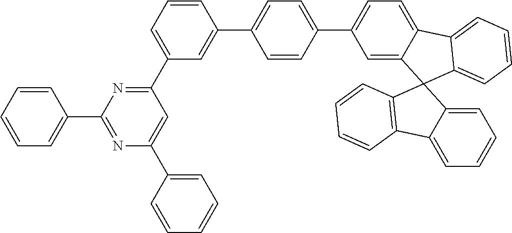 [SMILES: c1ccc(-c2cc(-c3cccc(-c4ccc(-c5ccc6c(c5)C5(c7ccccc7-c7ccccc75)c5ccccc5-6)cc4)c3)nc(-c3ccccc3)n2)cc1]

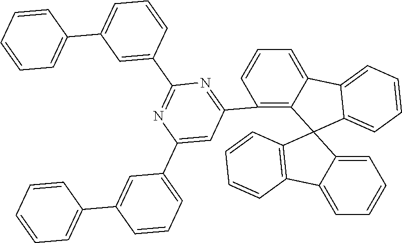 [SMILES: c1ccc(-c2cccc(-c3cc(-c4cccc5c4C4(c6ccccc6-c6ccccc64)c4ccccc4-5)nc(-c4cccc(-c5ccccc5)c4)n3)c2)cc1]

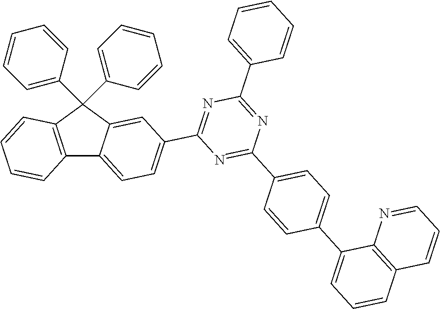 [SMILES: c1ccc(-c2nc(-c3ccc(-c4cccc5cccnc45)cc3)nc(-c3ccc4c(c3)C(c3ccccc3)(c3ccccc3)c3ccccc3-4)n2)cc1]

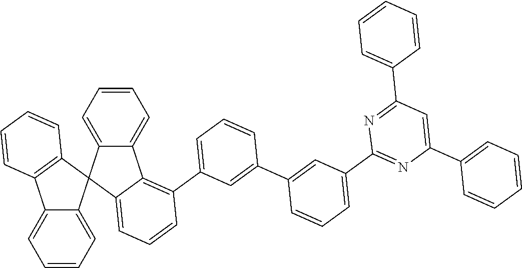 [SMILES: c1ccc(-c2cc(-c3ccccc3)nc(-c3cccc(-c4cccc(-c5cccc6c5-c5ccccc5C65c6ccccc6-c6ccccc65)c4)c3)n2)cc1]

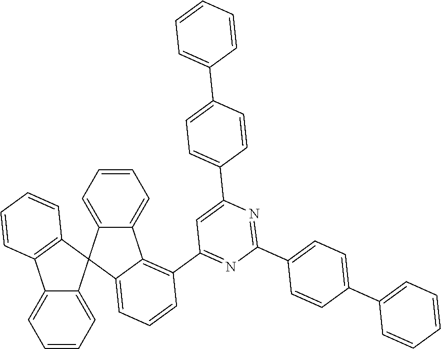 [SMILES: c1ccc(-c2ccc(-c3cc(-c4cccc5c4-c4ccccc4C54c5ccccc5-c5ccccc54)nc(-c4ccc(-c5ccccc5)cc4)n3)cc2)cc1]

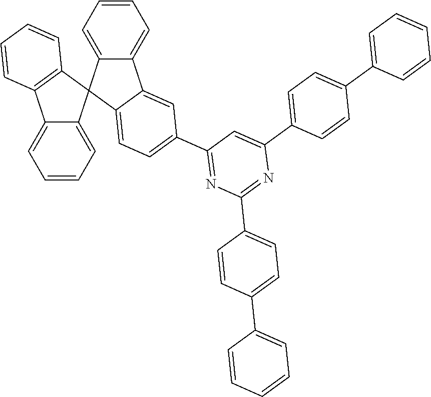 [SMILES: c1ccc(-c2ccc(-c3cc(-c4ccc5c(c4)-c4ccccc4C54c5ccccc5-c5ccccc54)nc(-c4ccc(-c5ccccc5)cc4)n3)cc2)cc1]

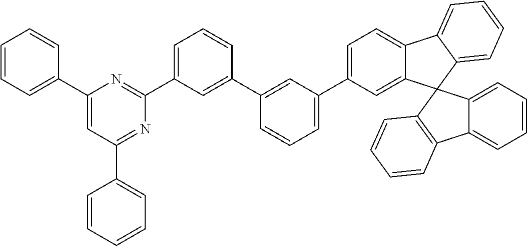 [SMILES: c1ccc(-c2cc(-c3ccccc3)nc(-c3cccc(-c4cccc(-c5ccc6c(c5)C5(c7ccccc7-c7ccccc75)c5ccccc5-6)c4)c3)n2)cc1]

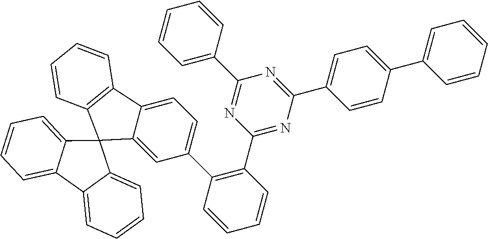 [SMILES: c1ccc(-c2ccc(-c3nc(-c4ccccc4)nc(-c4ccccc4-c4ccc5c(c4)C4(c6ccccc6-c6ccccc64)c4ccccc4-5)n3)cc2)cc1]

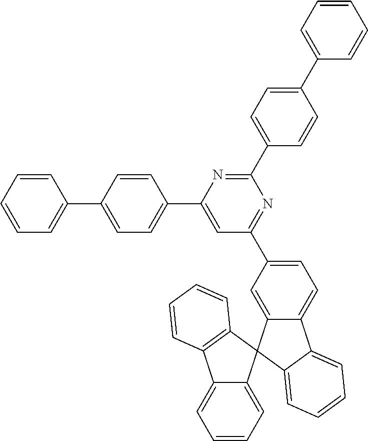 [SMILES: c1ccc(-c2ccc(-c3cc(-c4ccc5c(c4)C4(c6ccccc6-c6ccccc64)c4ccccc4-5)nc(-c4ccc(-c5ccccc5)cc4)n3)cc2)cc1]

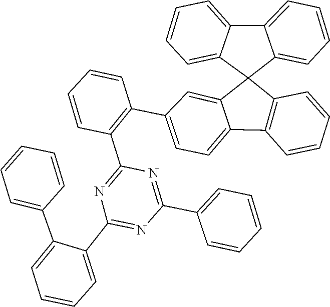 [SMILES: c1ccc(-c2nc(-c3ccccc3-c3ccccc3)nc(-c3ccccc3-c3ccc4c(c3)C3(c5ccccc5-c5ccccc53)c3ccccc3-4)n2)cc1]

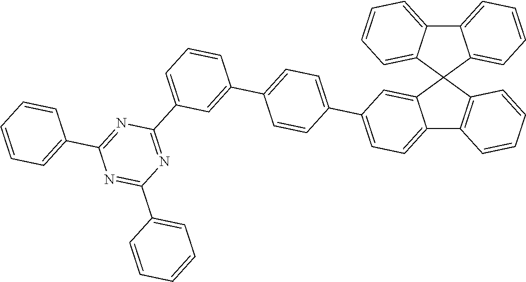 [SMILES: c1ccc(-c2nc(-c3ccccc3)nc(-c3cccc(-c4ccc(-c5ccc6c(c5)C5(c7ccccc7-c7ccccc75)c5ccccc5-6)cc4)c3)n2)cc1]

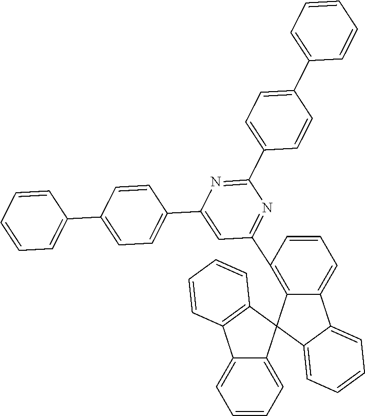 [SMILES: c1ccc(-c2ccc(-c3cc(-c4cccc5c4C4(c6ccccc6-c6ccccc64)c4ccccc4-5)nc(-c4ccc(-c5ccccc5)cc4)n3)cc2)cc1]

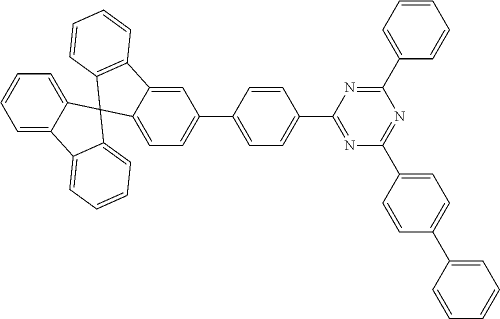 [SMILES: c1ccc(-c2ccc(-c3nc(-c4ccccc4)nc(-c4ccc(-c5ccc6c(c5)-c5ccccc5C65c6ccccc6-c6ccccc65)cc4)n3)cc2)cc1]

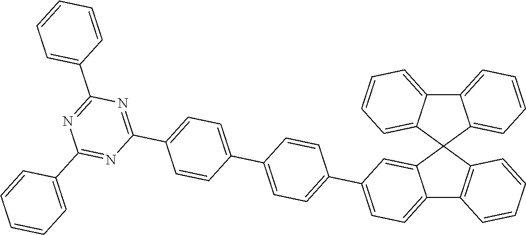 [SMILES: c1ccc(-c2nc(-c3ccccc3)nc(-c3ccc(-c4ccc(-c5ccc6c(c5)C5(c7ccccc7-c7ccccc75)c5ccccc5-6)cc4)cc3)n2)cc1]

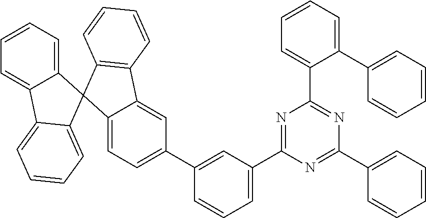 [SMILES: c1ccc(-c2nc(-c3cccc(-c4ccc5c(c4)-c4ccccc4C54c5ccccc5-c5ccccc54)c3)nc(-c3ccccc3-c3ccccc3)n2)cc1]

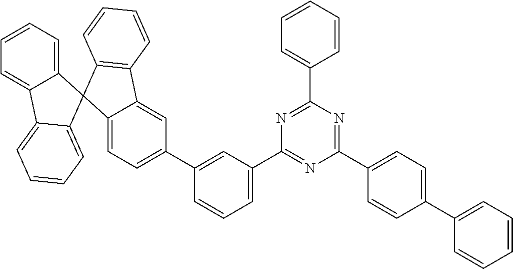 [SMILES: c1ccc(-c2ccc(-c3nc(-c4ccccc4)nc(-c4cccc(-c5ccc6c(c5)-c5ccccc5C65c6ccccc6-c6ccccc65)c4)n3)cc2)cc1]

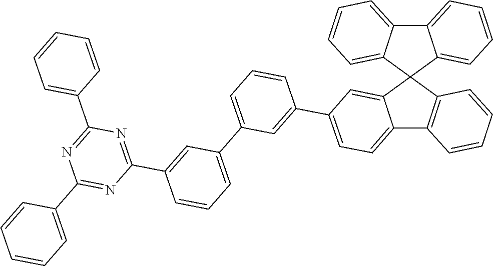 [SMILES: c1ccc(-c2nc(-c3ccccc3)nc(-c3cccc(-c4cccc(-c5ccc6c(c5)C5(c7ccccc7-c7ccccc75)c5ccccc5-6)c4)c3)n2)cc1]

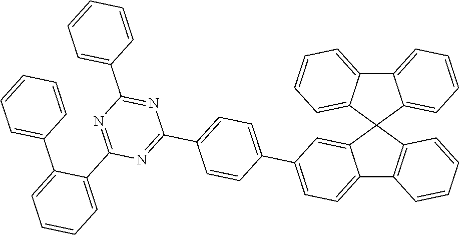 [SMILES: c1ccc(-c2nc(-c3ccc(-c4ccc5c(c4)C4(c6ccccc6-c6ccccc64)c4ccccc4-5)cc3)nc(-c3ccccc3-c3ccccc3)n2)cc1]

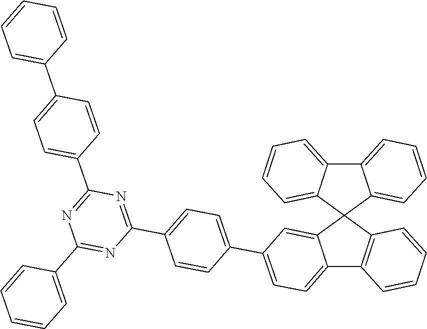 [SMILES: c1ccc(-c2ccc(-c3nc(-c4ccccc4)nc(-c4ccc(-c5ccc6c(c5)C5(c7ccccc7-c7ccccc75)c5ccccc5-6)cc4)n3)cc2)cc1]

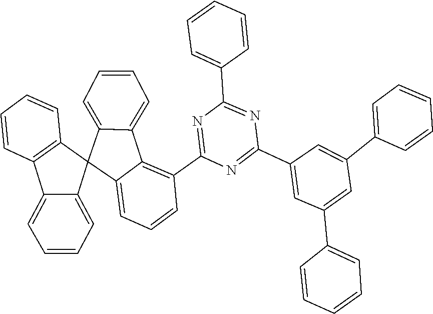 [SMILES: c1ccc(-c2cc(-c3ccccc3)cc(-c3nc(-c4ccccc4)nc(-c4cccc5c4-c4ccccc4C54c5ccccc5-c5ccccc54)n3)c2)cc1]

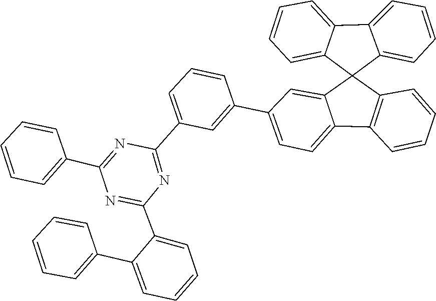 [SMILES: c1ccc(-c2nc(-c3cccc(-c4ccc5c(c4)C4(c6ccccc6-c6ccccc64)c4ccccc4-5)c3)nc(-c3ccccc3-c3ccccc3)n2)cc1]

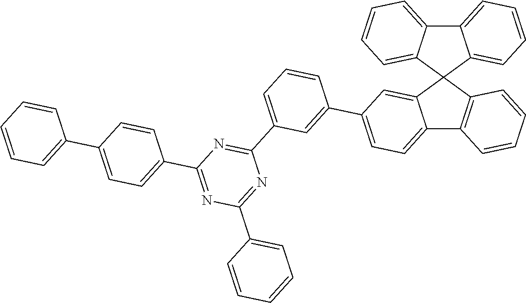 [SMILES: c1ccc(-c2ccc(-c3nc(-c4ccccc4)nc(-c4cccc(-c5ccc6c(c5)C5(c7ccccc7-c7ccccc75)c5ccccc5-6)c4)n3)cc2)cc1]

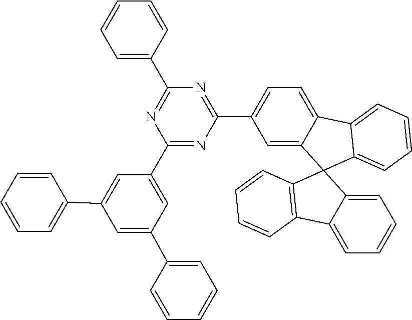 [SMILES: c1ccc(-c2cc(-c3ccccc3)cc(-c3nc(-c4ccccc4)nc(-c4ccc5c(c4)C4(c6ccccc6-c6ccccc64)c4ccccc4-5)n3)c2)cc1]

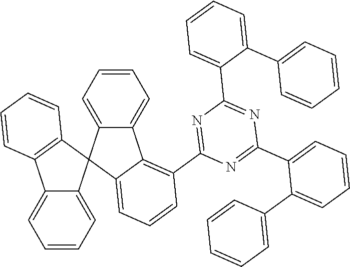 [SMILES: c1ccc(-c2ccccc2-c2nc(-c3ccccc3-c3ccccc3)nc(-c3cccc4c3-c3ccccc3C43c4ccccc4-c4ccccc43)n2)cc1]

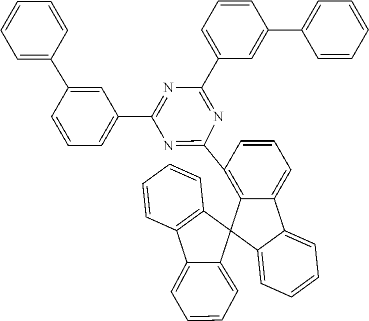 [SMILES: c1ccc(-c2cccc(-c3nc(-c4cccc(-c5ccccc5)c4)nc(-c4cccc5c4C4(c6ccccc6-c6ccccc64)c4ccccc4-5)n3)c2)cc1]

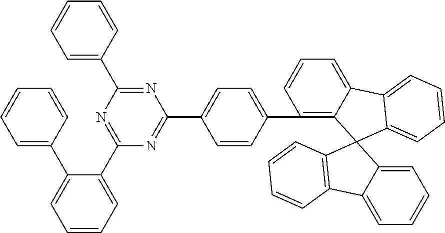 [SMILES: c1ccc(-c2nc(-c3ccc(-c4cccc5c4C4(c6ccccc6-c6ccccc64)c4ccccc4-5)cc3)nc(-c3ccccc3-c3ccccc3)n2)cc1]

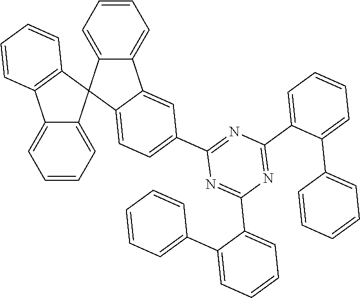 [SMILES: c1ccc(-c2ccccc2-c2nc(-c3ccc4c(c3)-c3ccccc3C43c4ccccc4-c4ccccc43)nc(-c3ccccc3-c3ccccc3)n2)cc1]

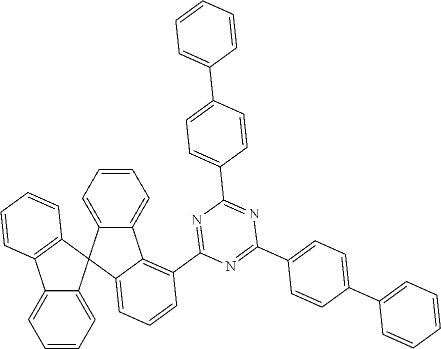 [SMILES: c1ccc(-c2ccc(-c3nc(-c4ccc(-c5ccccc5)cc4)nc(-c4cccc5c4-c4ccccc4C54c5ccccc5-c5ccccc54)n3)cc2)cc1]

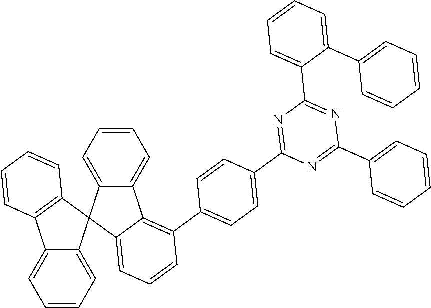 [SMILES: c1ccc(-c2nc(-c3ccc(-c4cccc5c4-c4ccccc4C54c5ccccc5-c5ccccc54)cc3)nc(-c3ccccc3-c3ccccc3)n2)cc1]

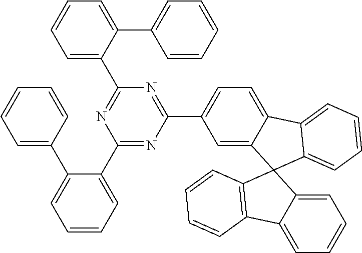 [SMILES: c1ccc(-c2ccccc2-c2nc(-c3ccc4c(c3)C3(c5ccccc5-c5ccccc53)c3ccccc3-4)nc(-c3ccccc3-c3ccccc3)n2)cc1]

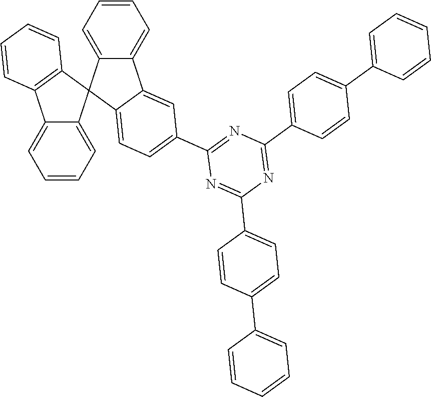 [SMILES: c1ccc(-c2ccc(-c3nc(-c4ccc(-c5ccccc5)cc4)nc(-c4ccc5c(c4)-c4ccccc4C54c5ccccc5-c5ccccc54)n3)cc2)cc1]

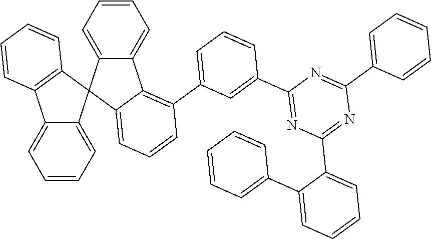 [SMILES: c1ccc(-c2nc(-c3cccc(-c4cccc5c4-c4ccccc4C54c5ccccc5-c5ccccc54)c3)nc(-c3ccccc3-c3ccccc3)n2)cc1]

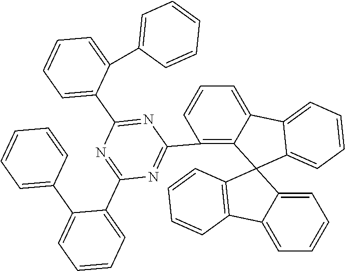 [SMILES: c1ccc(-c2ccccc2-c2nc(-c3ccccc3-c3ccccc3)nc(-c3cccc4c3C3(c5ccccc5-c5ccccc53)c3ccccc3-4)n2)cc1]

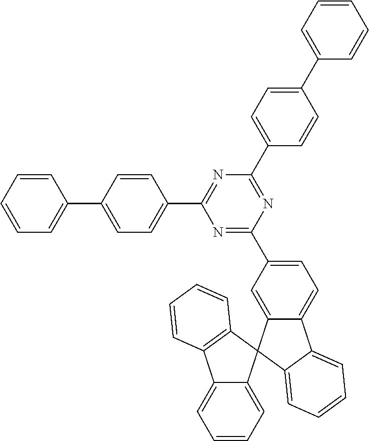 [SMILES: c1ccc(-c2ccc(-c3nc(-c4ccc(-c5ccccc5)cc4)nc(-c4ccc5c(c4)C4(c6ccccc6-c6ccccc64)c4ccccc4-5)n3)cc2)cc1]

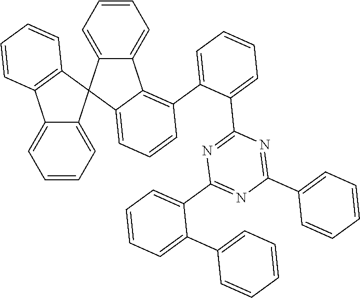 [SMILES: c1ccc(-c2nc(-c3ccccc3-c3ccccc3)nc(-c3ccccc3-c3cccc4c3-c3ccccc3C43c4ccccc4-c4ccccc43)n2)cc1]

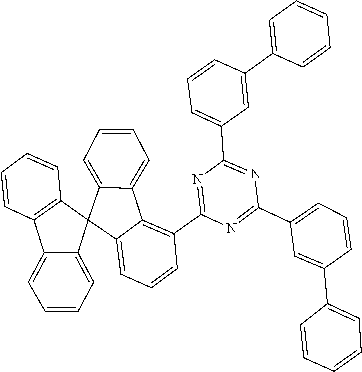 [SMILES: c1ccc(-c2cccc(-c3nc(-c4cccc(-c5ccccc5)c4)nc(-c4cccc5c4-c4ccccc4C54c5ccccc5-c5ccccc54)n3)c2)cc1]

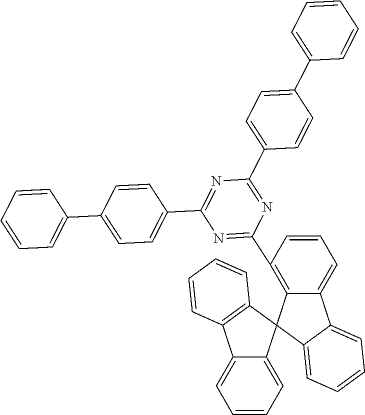 [SMILES: c1ccc(-c2ccc(-c3nc(-c4ccc(-c5ccccc5)cc4)nc(-c4cccc5c4C4(c6ccccc6-c6ccccc64)c4ccccc4-5)n3)cc2)cc1]

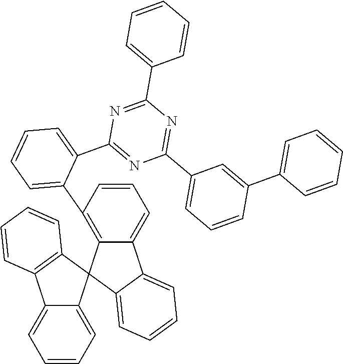 [SMILES: c1ccc(-c2cccc(-c3nc(-c4ccccc4)nc(-c4ccccc4-c4cccc5c4C4(c6ccccc6-c6ccccc64)c4ccccc4-5)n3)c2)cc1]

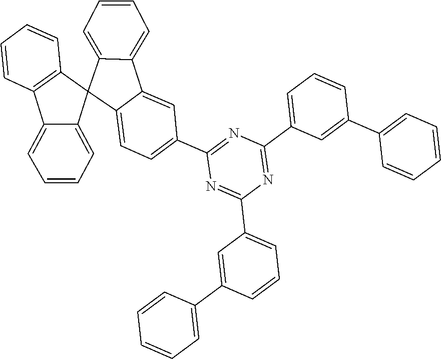 [SMILES: c1ccc(-c2cccc(-c3nc(-c4cccc(-c5ccccc5)c4)nc(-c4ccc5c(c4)-c4ccccc4C54c5ccccc5-c5ccccc54)n3)c2)cc1]

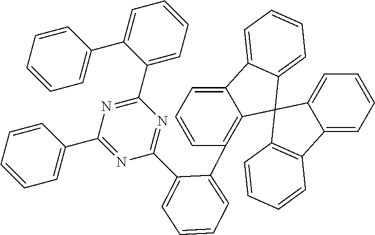 [SMILES: c1ccc(-c2nc(-c3ccccc3-c3ccccc3)nc(-c3ccccc3-c3cccc4c3C3(c5ccccc5-c5ccccc53)c3ccccc3-4)n2)cc1]

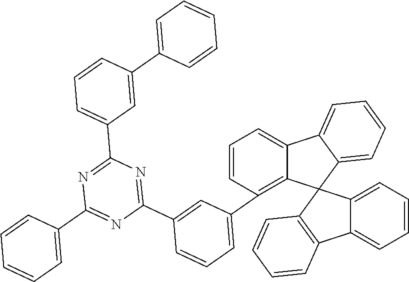 [SMILES: c1ccc(-c2cccc(-c3nc(-c4ccccc4)nc(-c4cccc(-c5cccc6c5C5(c7ccccc7-c7ccccc75)c5ccccc5-6)c4)n3)c2)cc1]

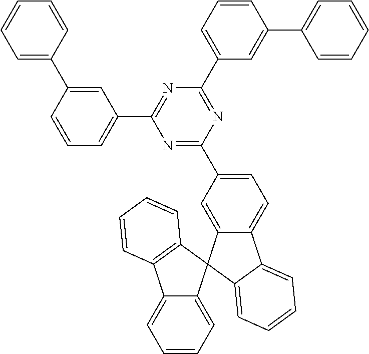 [SMILES: c1ccc(-c2cccc(-c3nc(-c4cccc(-c5ccccc5)c4)nc(-c4ccc5c(c4)C4(c6ccccc6-c6ccccc64)c4ccccc4-5)n3)c2)cc1]

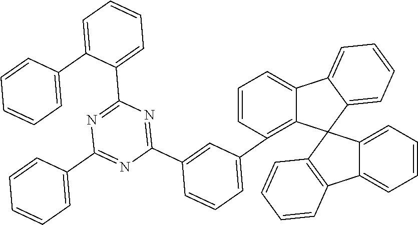 [SMILES: c1ccc(-c2nc(-c3cccc(-c4cccc5c4C4(c6ccccc6-c6ccccc64)c4ccccc4-5)c3)nc(-c3ccccc3-c3ccccc3)n2)cc1]

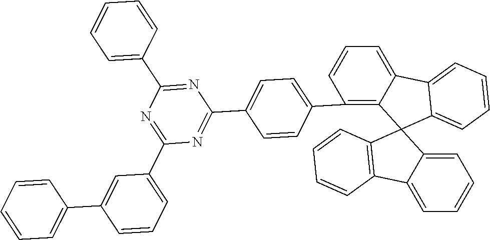 [SMILES: c1ccc(-c2cccc(-c3nc(-c4ccccc4)nc(-c4ccc(-c5cccc6c5C5(c7ccccc7-c7ccccc75)c5ccccc5-6)cc4)n3)c2)cc1]

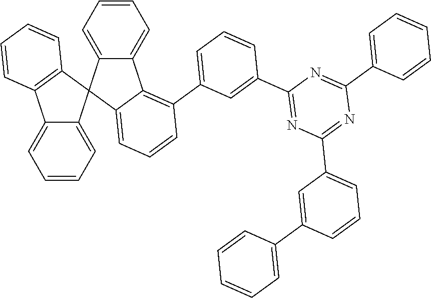 [SMILES: c1ccc(-c2cccc(-c3nc(-c4ccccc4)nc(-c4cccc(-c5cccc6c5-c5ccccc5C65c6ccccc6-c6ccccc65)c4)n3)c2)cc1]

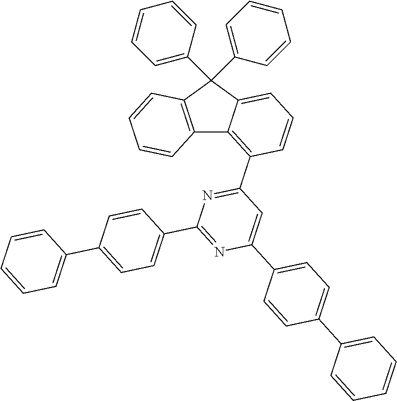 [SMILES: c1ccc(-c2ccc(-c3cc(-c4cccc5c4-c4ccccc4C5(c4ccccc4)c4ccccc4)nc(-c4ccc(-c5ccccc5)cc4)n3)cc2)cc1]

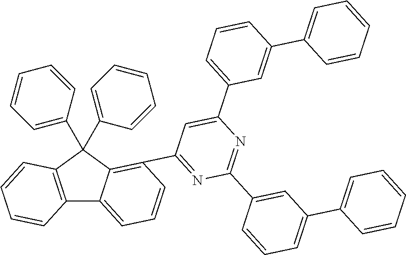 [SMILES: c1ccc(-c2cccc(-c3cc(-c4cccc5c4C(c4ccccc4)(c4ccccc4)c4ccccc4-5)nc(-c4cccc(-c5ccccc5)c4)n3)c2)cc1]

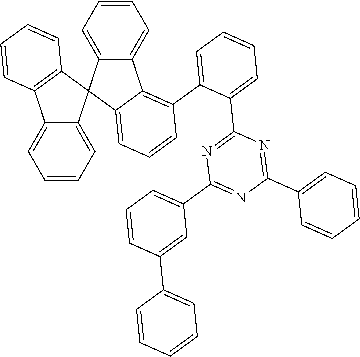 [SMILES: c1ccc(-c2cccc(-c3nc(-c4ccccc4)nc(-c4ccccc4-c4cccc5c4-c4ccccc4C54c5ccccc5-c5ccccc54)n3)c2)cc1]

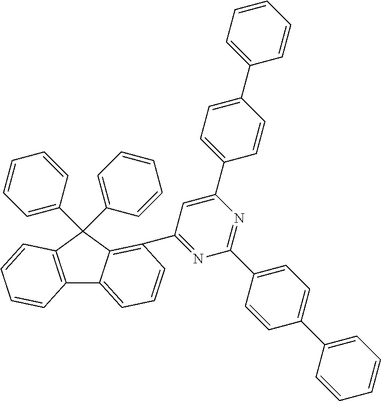 [SMILES: c1ccc(-c2ccc(-c3cc(-c4cccc5c4C(c4ccccc4)(c4ccccc4)c4ccccc4-5)nc(-c4ccc(-c5ccccc5)cc4)n3)cc2)cc1]

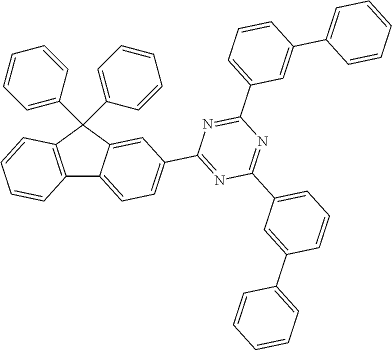 [SMILES: c1ccc(-c2cccc(-c3nc(-c4cccc(-c5ccccc5)c4)nc(-c4ccc5c(c4)C(c4ccccc4)(c4ccccc4)c4ccccc4-5)n3)c2)cc1]

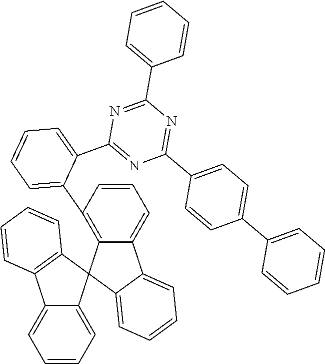 [SMILES: c1ccc(-c2ccc(-c3nc(-c4ccccc4)nc(-c4ccccc4-c4cccc5c4C4(c6ccccc6-c6ccccc64)c4ccccc4-5)n3)cc2)cc1]

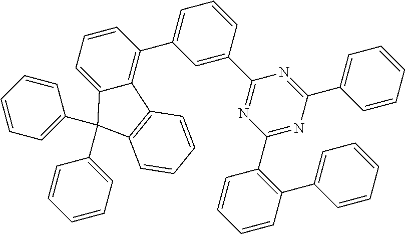 [SMILES: c1ccc(-c2nc(-c3cccc(-c4cccc5c4-c4ccccc4C5(c4ccccc4)c4ccccc4)c3)nc(-c3ccccc3-c3ccccc3)n2)cc1]

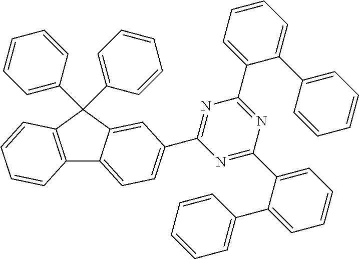 [SMILES: c1ccc(-c2ccccc2-c2nc(-c3ccc4c(c3)C(c3ccccc3)(c3ccccc3)c3ccccc3-4)nc(-c3ccccc3-c3ccccc3)n2)cc1]

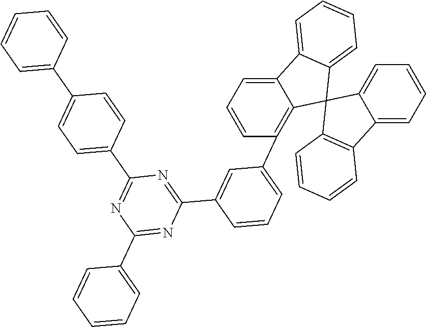 [SMILES: c1ccc(-c2ccc(-c3nc(-c4ccccc4)nc(-c4cccc(-c5cccc6c5C5(c7ccccc7-c7ccccc75)c5ccccc5-6)c4)n3)cc2)cc1]

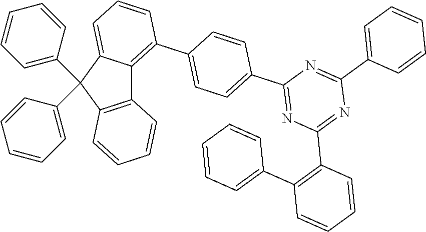 [SMILES: c1ccc(-c2nc(-c3ccc(-c4cccc5c4-c4ccccc4C5(c4ccccc4)c4ccccc4)cc3)nc(-c3ccccc3-c3ccccc3)n2)cc1]

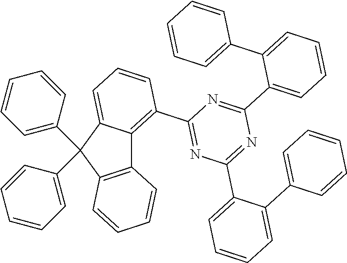 [SMILES: c1ccc(-c2ccccc2-c2nc(-c3ccccc3-c3ccccc3)nc(-c3cccc4c3-c3ccccc3C4(c3ccccc3)c3ccccc3)n2)cc1]

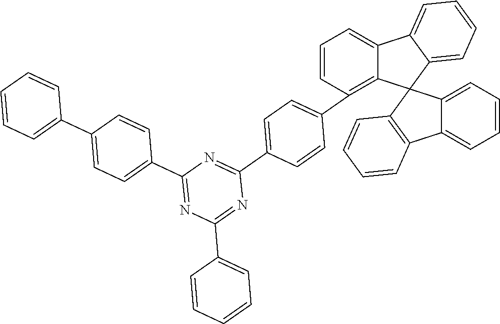 [SMILES: c1ccc(-c2ccc(-c3nc(-c4ccccc4)nc(-c4ccc(-c5cccc6c5C5(c7ccccc7-c7ccccc75)c5ccccc5-6)cc4)n3)cc2)cc1]

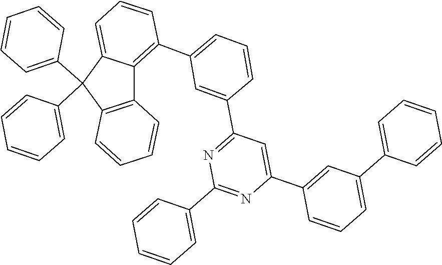 [SMILES: c1ccc(-c2cccc(-c3cc(-c4cccc(-c5cccc6c5-c5ccccc5C6(c5ccccc5)c5ccccc5)c4)nc(-c4ccccc4)n3)c2)cc1]

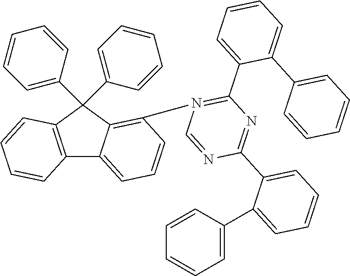

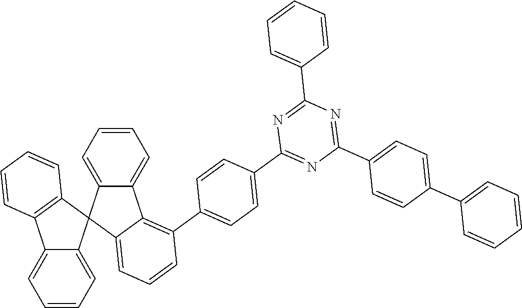 [SMILES: c1ccc(-c2ccc(-c3nc(-c4ccccc4)nc(-c4ccc(-c5cccc6c5-c5ccccc5C65c6ccccc6-c6ccccc65)cc4)n3)cc2)cc1]

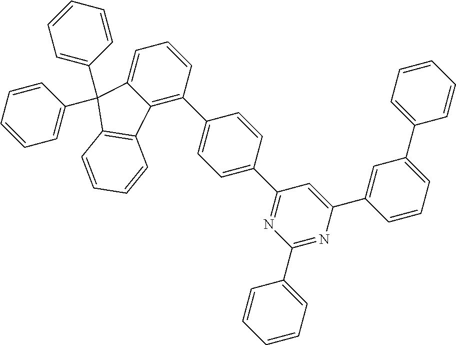 [SMILES: c1ccc(-c2cccc(-c3cc(-c4ccc(-c5cccc6c5-c5ccccc5C6(c5ccccc5)c5ccccc5)cc4)nc(-c4ccccc4)n3)c2)cc1]

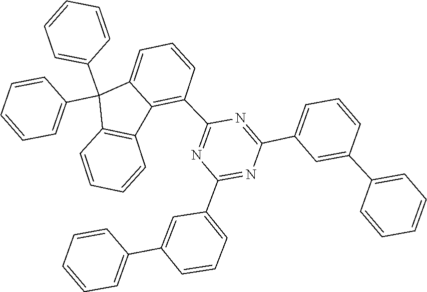 [SMILES: c1ccc(-c2cccc(-c3nc(-c4cccc(-c5ccccc5)c4)nc(-c4cccc5c4-c4ccccc4C5(c4ccccc4)c4ccccc4)n3)c2)cc1]

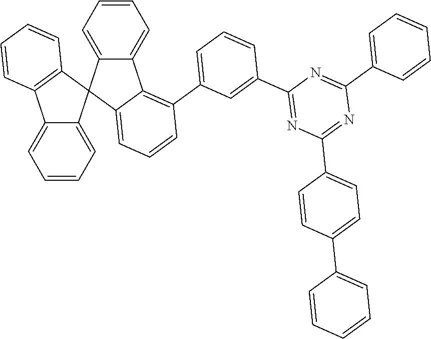 [SMILES: c1ccc(-c2ccc(-c3nc(-c4ccccc4)nc(-c4cccc(-c5cccc6c5-c5ccccc5C65c6ccccc6-c6ccccc65)c4)n3)cc2)cc1]

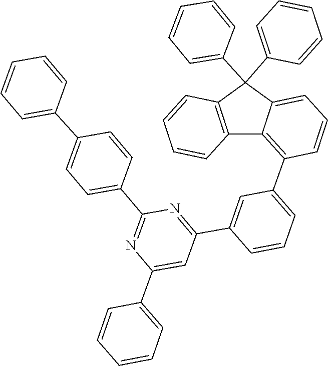 [SMILES: c1ccc(-c2ccc(-c3nc(-c4ccccc4)cc(-c4cccc(-c5cccc6c5-c5ccccc5C6(c5ccccc5)c5ccccc5)c4)n3)cc2)cc1]

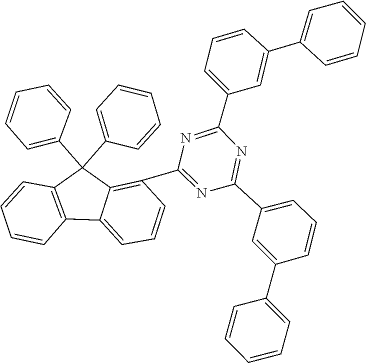 [SMILES: c1ccc(-c2cccc(-c3nc(-c4cccc(-c5ccccc5)c4)nc(-c4cccc5c4C(c4ccccc4)(c4ccccc4)c4ccccc4-5)n3)c2)cc1]

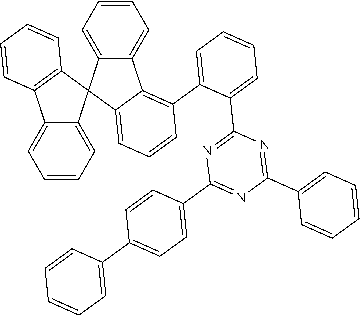 [SMILES: c1ccc(-c2ccc(-c3nc(-c4ccccc4)nc(-c4ccccc4-c4cccc5c4-c4ccccc4C54c5ccccc5-c5ccccc54)n3)cc2)cc1]

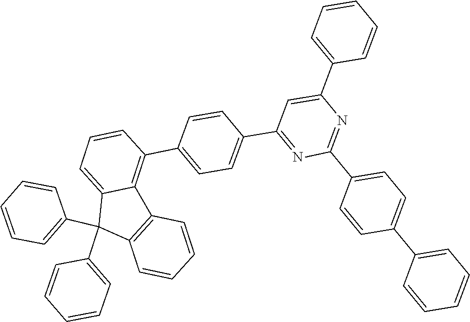 [SMILES: c1ccc(-c2ccc(-c3nc(-c4ccccc4)cc(-c4ccc(-c5cccc6c5-c5ccccc5C6(c5ccccc5)c5ccccc5)cc4)n3)cc2)cc1]

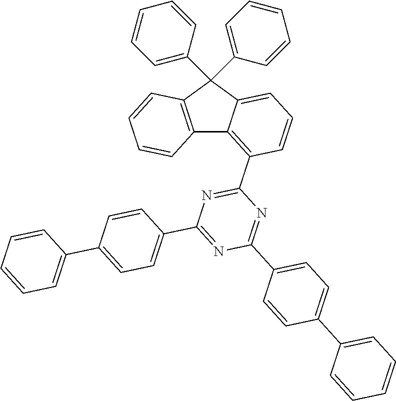 [SMILES: c1ccc(-c2ccc(-c3nc(-c4ccc(-c5ccccc5)cc4)nc(-c4cccc5c4-c4ccccc4C5(c4ccccc4)c4ccccc4)n3)cc2)cc1]

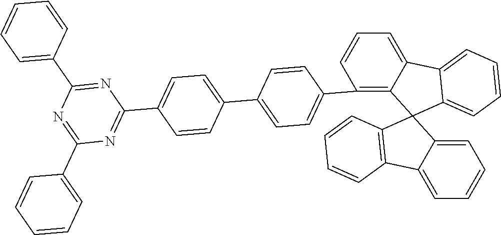 [SMILES: c1ccc(-c2nc(-c3ccccc3)nc(-c3ccc(-c4ccc(-c5cccc6c5C5(c7ccccc7-c7ccccc75)c5ccccc5-6)cc4)cc3)n2)cc1]

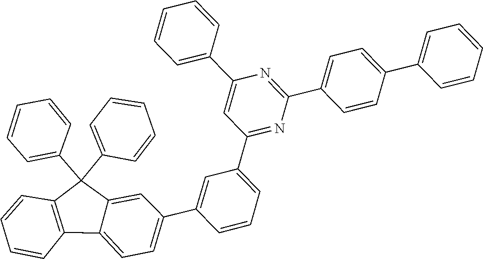 [SMILES: c1ccc(-c2ccc(-c3nc(-c4ccccc4)cc(-c4cccc(-c5ccc6c(c5)C(c5ccccc5)(c5ccccc5)c5ccccc5-6)c4)n3)cc2)cc1]

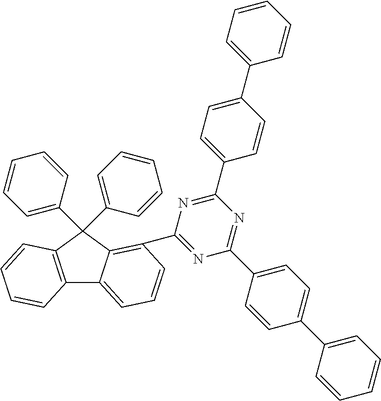 [SMILES: c1ccc(-c2ccc(-c3nc(-c4ccc(-c5ccccc5)cc4)nc(-c4cccc5c4C(c4ccccc4)(c4ccccc4)c4ccccc4-5)n3)cc2)cc1]

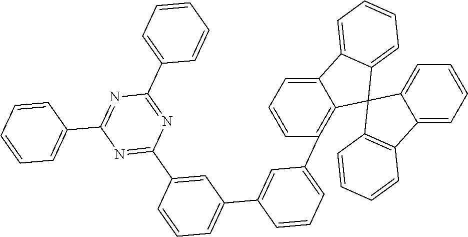 [SMILES: c1ccc(-c2nc(-c3ccccc3)nc(-c3cccc(-c4cccc(-c5cccc6c5C5(c7ccccc7-c7ccccc75)c5ccccc5-6)c4)c3)n2)cc1]

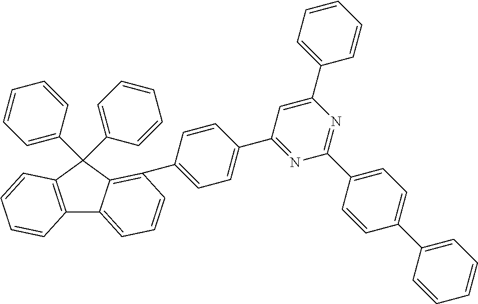 [SMILES: c1ccc(-c2ccc(-c3nc(-c4ccccc4)cc(-c4ccc(-c5cccc6c5C(c5ccccc5)(c5ccccc5)c5ccccc5-6)cc4)n3)cc2)cc1]

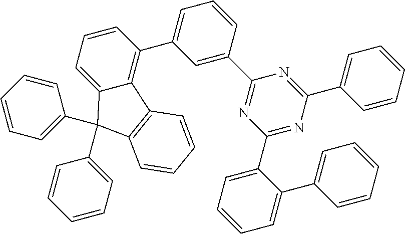 [SMILES: c1ccc(-c2nc(-c3cccc(-c4cccc5c4-c4ccccc4C5(c4ccccc4)c4ccccc4)c3)nc(-c3ccccc3-c3ccccc3)n2)cc1]

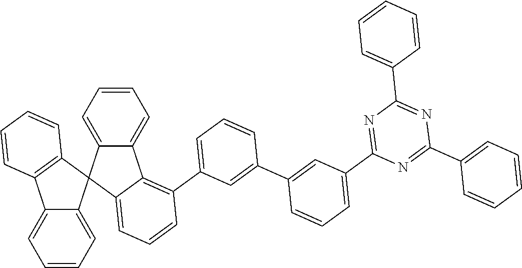 [SMILES: c1ccc(-c2nc(-c3ccccc3)nc(-c3cccc(-c4cccc(-c5cccc6c5-c5ccccc5C65c6ccccc6-c6ccccc65)c4)c3)n2)cc1]

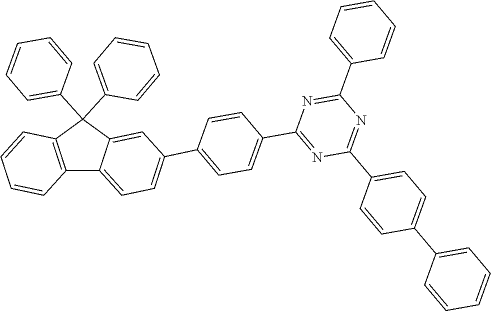 [SMILES: c1ccc(-c2ccc(-c3nc(-c4ccccc4)nc(-c4ccc(-c5ccc6c(c5)C(c5ccccc5)(c5ccccc5)c5ccccc5-6)cc4)n3)cc2)cc1]

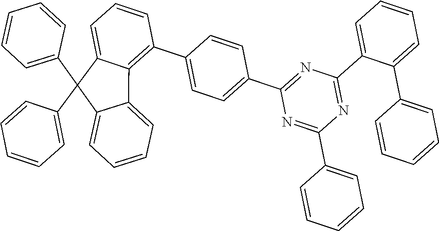 [SMILES: c1ccc(-c2nc(-c3ccc(-c4cccc5c4-c4ccccc4C5(c4ccccc4)c4ccccc4)cc3)nc(-c3ccccc3-c3ccccc3)n2)cc1]

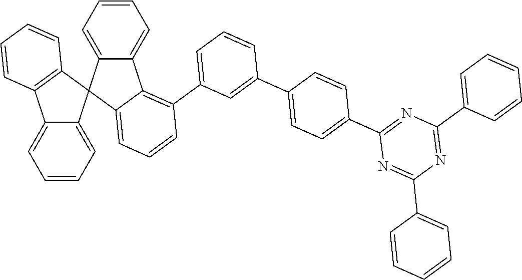 [SMILES: c1ccc(-c2nc(-c3ccccc3)nc(-c3ccc(-c4cccc(-c5cccc6c5-c5ccccc5C65c6ccccc6-c6ccccc65)c4)cc3)n2)cc1]

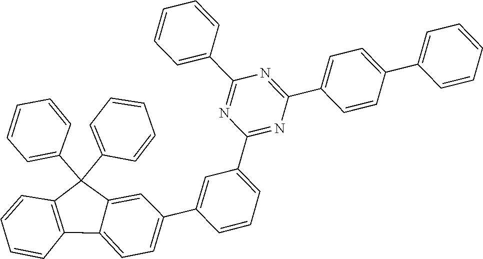 [SMILES: c1ccc(-c2ccc(-c3nc(-c4ccccc4)nc(-c4cccc(-c5ccc6c(c5)C(c5ccccc5)(c5ccccc5)c5ccccc5-6)c4)n3)cc2)cc1]

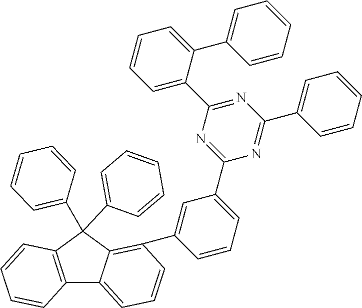 [SMILES: c1ccc(-c2nc(-c3cccc(-c4cccc5c4C(c4ccccc4)(c4ccccc4)c4ccccc4-5)c3)nc(-c3ccccc3-c3ccccc3)n2)cc1]

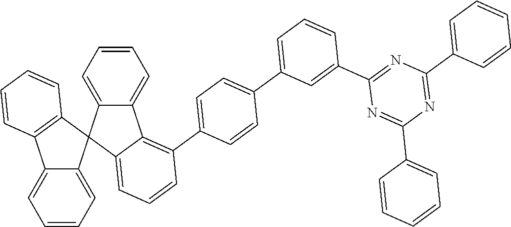 [SMILES: c1ccc(-c2nc(-c3ccccc3)nc(-c3cccc(-c4ccc(-c5cccc6c5-c5ccccc5C65c6ccccc6-c6ccccc65)cc4)c3)n2)cc1]

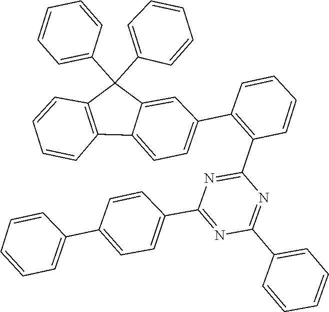 [SMILES: c1ccc(-c2ccc(-c3nc(-c4ccccc4)nc(-c4ccccc4-c4ccc5c(c4)C(c4ccccc4)(c4ccccc4)c4ccccc4-5)n3)cc2)cc1]

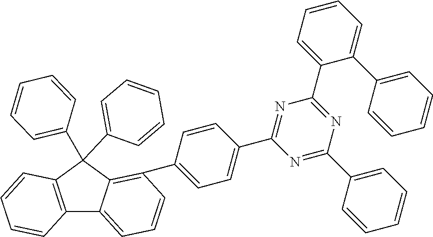 [SMILES: c1ccc(-c2nc(-c3ccc(-c4cccc5c4C(c4ccccc4)(c4ccccc4)c4ccccc4-5)cc3)nc(-c3ccccc3-c3ccccc3)n2)cc1]

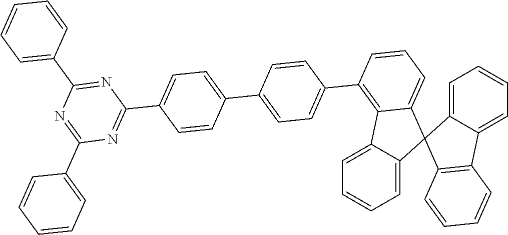 [SMILES: c1ccc(-c2nc(-c3ccccc3)nc(-c3ccc(-c4ccc(-c5cccc6c5-c5ccccc5C65c6ccccc6-c6ccccc65)cc4)cc3)n2)cc1]

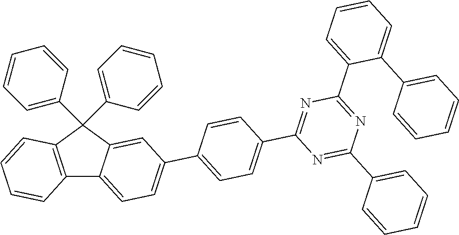 [SMILES: c1ccc(-c2nc(-c3ccc(-c4ccc5c(c4)C(c4ccccc4)(c4ccccc4)c4ccccc4-5)cc3)nc(-c3ccccc3-c3ccccc3)n2)cc1]

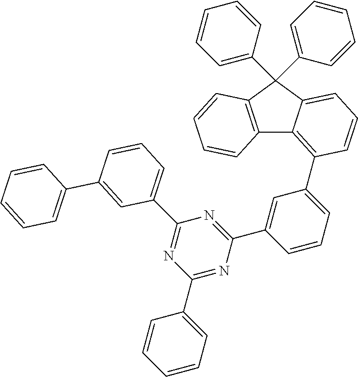 [SMILES: c1ccc(-c2cccc(-c3nc(-c4ccccc4)nc(-c4cccc(-c5cccc6c5-c5ccccc5C6(c5ccccc5)c5ccccc5)c4)n3)c2)cc1]

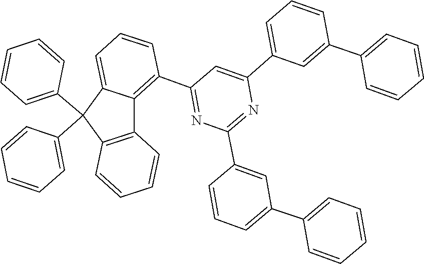 [SMILES: c1ccc(-c2cccc(-c3cc(-c4cccc5c4-c4ccccc4C5(c4ccccc4)c4ccccc4)nc(-c4cccc(-c5ccccc5)c4)n3)c2)cc1]

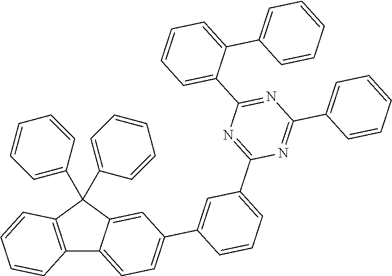 [SMILES: c1ccc(-c2nc(-c3cccc(-c4ccc5c(c4)C(c4ccccc4)(c4ccccc4)c4ccccc4-5)c3)nc(-c3ccccc3-c3ccccc3)n2)cc1]

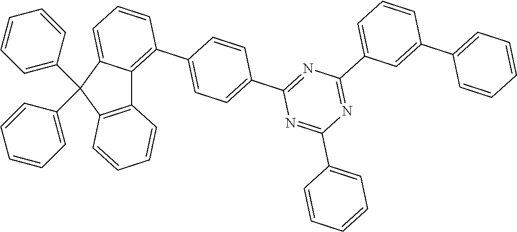 [SMILES: c1ccc(-c2cccc(-c3nc(-c4ccccc4)nc(-c4ccc(-c5cccc6c5-c5ccccc5C6(c5ccccc5)c5ccccc5)cc4)n3)c2)cc1]

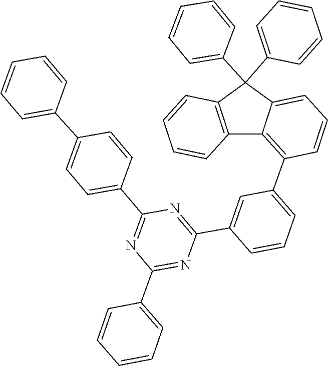 [SMILES: c1ccc(-c2ccc(-c3nc(-c4ccccc4)nc(-c4cccc(-c5cccc6c5-c5ccccc5C6(c5ccccc5)c5ccccc5)c4)n3)cc2)cc1]

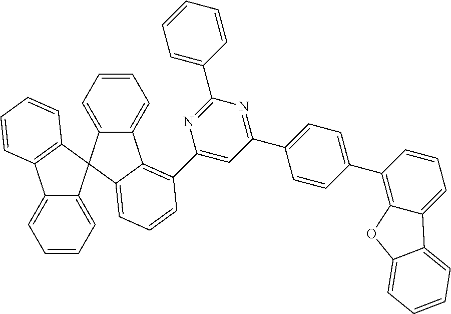 [SMILES: c1ccc(-c2nc(-c3ccc(-c4cccc5c4oc4ccccc45)cc3)cc(-c3cccc4c3-c3ccccc3C43c4ccccc4-c4ccccc43)n2)cc1]

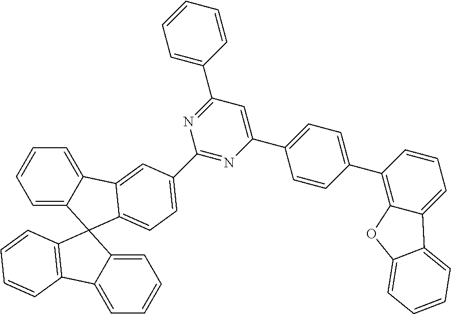 [SMILES: c1ccc(-c2cc(-c3ccc(-c4cccc5c4oc4ccccc45)cc3)nc(-c3ccc4c(c3)-c3ccccc3C43c4ccccc4-c4ccccc43)n2)cc1]

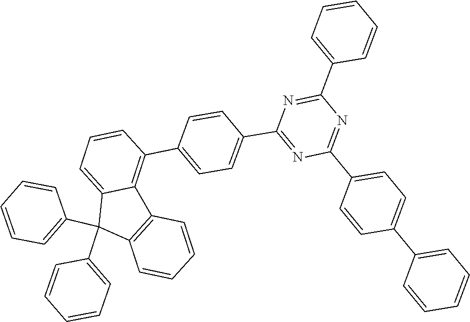 [SMILES: c1ccc(-c2ccc(-c3nc(-c4ccccc4)nc(-c4ccc(-c5cccc6c5-c5ccccc5C6(c5ccccc5)c5ccccc5)cc4)n3)cc2)cc1]

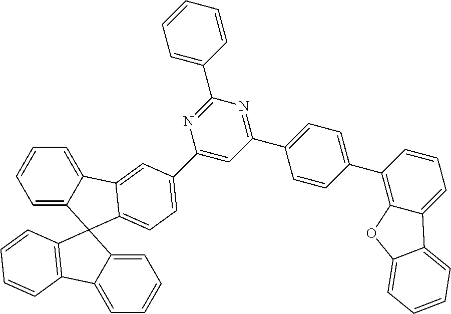 [SMILES: c1ccc(-c2nc(-c3ccc(-c4cccc5c4oc4ccccc45)cc3)cc(-c3ccc4c(c3)-c3ccccc3C43c4ccccc4-c4ccccc43)n2)cc1]

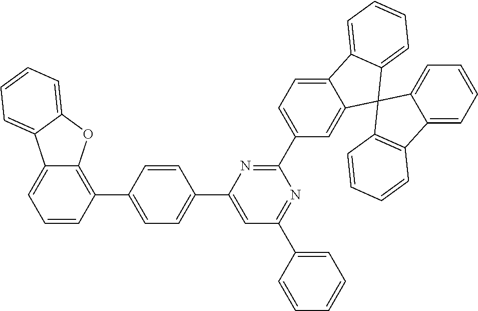 [SMILES: c1ccc(-c2cc(-c3ccc(-c4cccc5c4oc4ccccc45)cc3)nc(-c3ccc4c(c3)C3(c5ccccc5-c5ccccc53)c3ccccc3-4)n2)cc1]

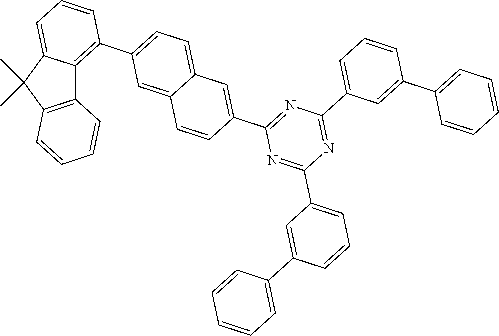 [SMILES: CC1(C)c2ccccc2-c2c(-c3ccc4cc(-c5nc(-c6cccc(-c7ccccc7)c6)nc(-c6cccc(-c7ccccc7)c6)n5)ccc4c3)cccc21]

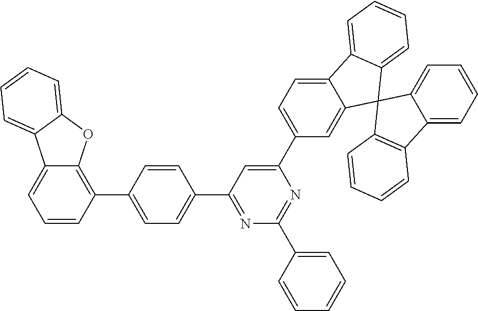 [SMILES: c1ccc(-c2nc(-c3ccc(-c4cccc5c4oc4ccccc45)cc3)cc(-c3ccc4c(c3)C3(c5ccccc5-c5ccccc53)c3ccccc3-4)n2)cc1]

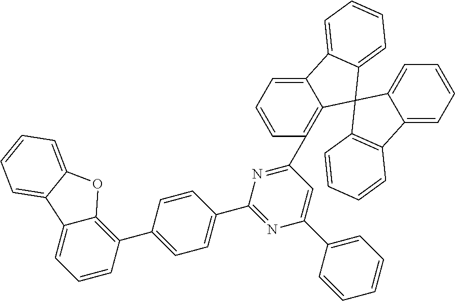 [SMILES: c1ccc(-c2cc(-c3cccc4c3C3(c5ccccc5-c5ccccc53)c3ccccc3-4)nc(-c3ccc(-c4cccc5c4oc4ccccc45)cc3)n2)cc1]

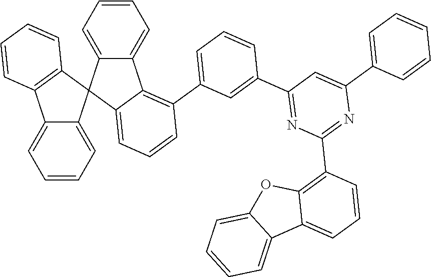 [SMILES: c1ccc(-c2cc(-c3cccc(-c4cccc5c4-c4ccccc4C54c5ccccc5-c5ccccc54)c3)nc(-c3cccc4c3oc3ccccc34)n2)cc1]

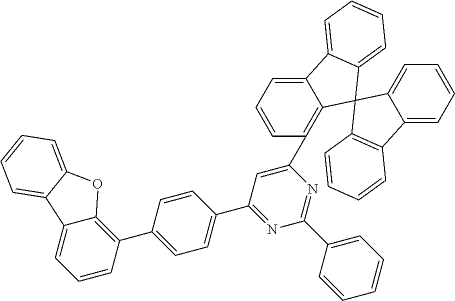 [SMILES: c1ccc(-c2nc(-c3ccc(-c4cccc5c4oc4ccccc45)cc3)cc(-c3cccc4c3C3(c5ccccc5-c5ccccc53)c3ccccc3-4)n2)cc1]

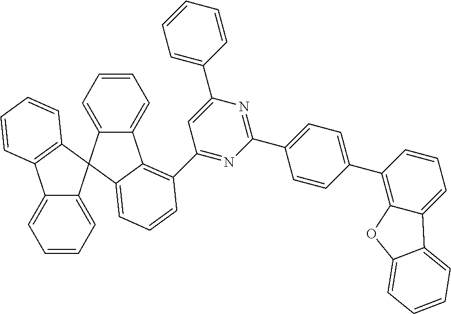 [SMILES: c1ccc(-c2cc(-c3cccc4c3-c3ccccc3C43c4ccccc4-c4ccccc43)nc(-c3ccc(-c4cccc5c4oc4ccccc45)cc3)n2)cc1]

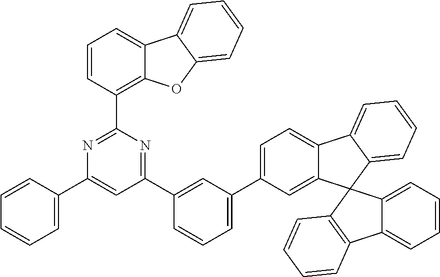 [SMILES: c1ccc(-c2cc(-c3cccc(-c4ccc5c(c4)C4(c6ccccc6-c6ccccc64)c4ccccc4-5)c3)nc(-c3cccc4c3oc3ccccc34)n2)cc1]

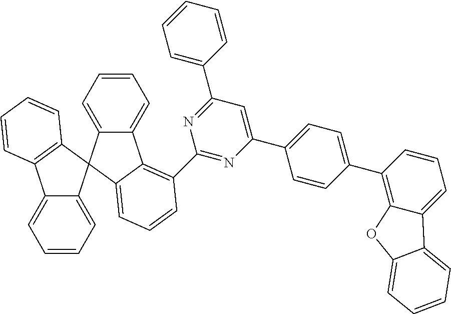 [SMILES: c1ccc(-c2cc(-c3ccc(-c4cccc5c4oc4ccccc45)cc3)nc(-c3cccc4c3-c3ccccc3C43c4ccccc4-c4ccccc43)n2)cc1]

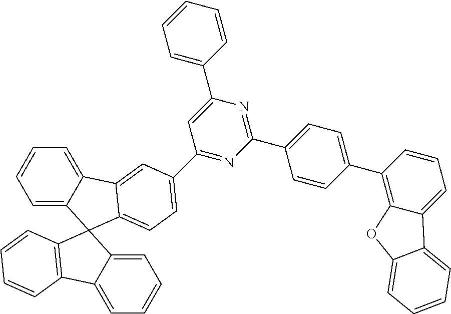 [SMILES: c1ccc(-c2cc(-c3ccc4c(c3)-c3ccccc3C43c4ccccc4-c4ccccc43)nc(-c3ccc(-c4cccc5c4oc4ccccc45)cc3)n2)cc1]

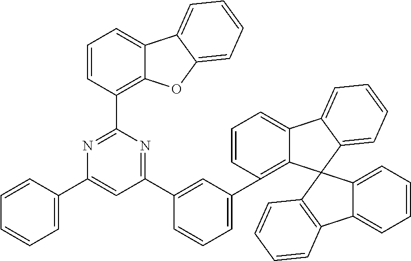 [SMILES: c1ccc(-c2cc(-c3cccc(-c4cccc5c4C4(c6ccccc6-c6ccccc64)c4ccccc4-5)c3)nc(-c3cccc4c3oc3ccccc34)n2)cc1]

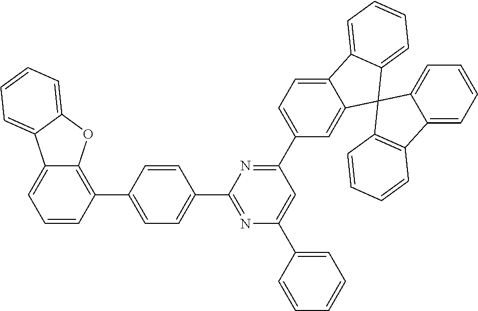 [SMILES: c1ccc(-c2cc(-c3ccc4c(c3)C3(c5ccccc5-c5ccccc53)c3ccccc3-4)nc(-c3ccc(-c4cccc5c4oc4ccccc45)cc3)n2)cc1]

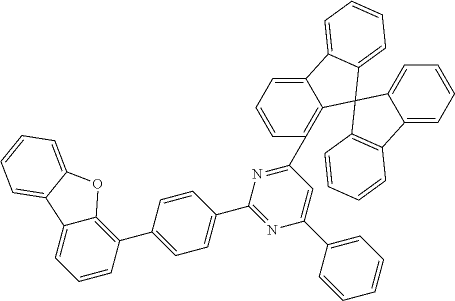 [SMILES: c1ccc(-c2cc(-c3cccc4c3C3(c5ccccc5-c5ccccc53)c3ccccc3-4)nc(-c3ccc(-c4cccc5c4oc4ccccc45)cc3)n2)cc1]

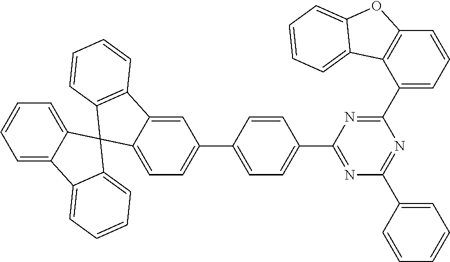 [SMILES: c1ccc(-c2nc(-c3ccc(-c4ccc5c(c4)-c4ccccc4C54c5ccccc5-c5ccccc54)cc3)nc(-c3cccc4oc5ccccc5c34)n2)cc1]

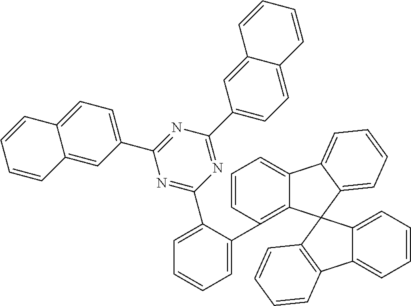 [SMILES: c1ccc(-c2cccc3c2C2(c4ccccc4-c4ccccc42)c2ccccc2-3)c(-c2nc(-c3ccc4ccccc4c3)nc(-c3ccc4ccccc4c3)n2)c1]

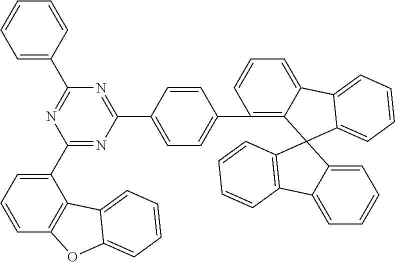 [SMILES: c1ccc(-c2nc(-c3ccc(-c4cccc5c4C4(c6ccccc6-c6ccccc64)c4ccccc4-5)cc3)nc(-c3cccc4oc5ccccc5c34)n2)cc1]

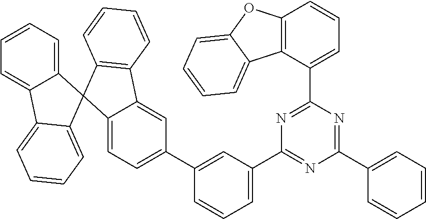 [SMILES: c1ccc(-c2nc(-c3cccc(-c4ccc5c(c4)-c4ccccc4C54c5ccccc5-c5ccccc54)c3)nc(-c3cccc4oc5ccccc5c34)n2)cc1]

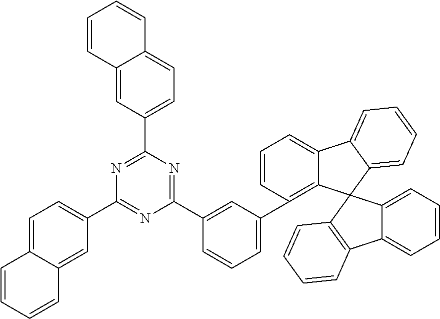 [SMILES: c1cc(-c2nc(-c3ccc4ccccc4c3)nc(-c3ccc4ccccc4c3)n2)cc(-c2cccc3c2C2(c4ccccc4-c4ccccc42)c2ccccc2-3)c1]

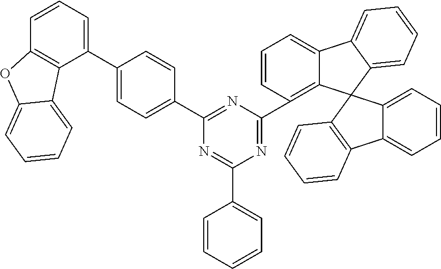 [SMILES: c1ccc(-c2nc(-c3ccc(-c4cccc5oc6ccccc6c45)cc3)nc(-c3cccc4c3C3(c5ccccc5-c5ccccc53)c3ccccc3-4)n2)cc1]

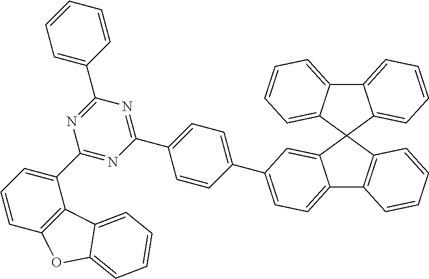 [SMILES: c1ccc(-c2nc(-c3ccc(-c4ccc5c(c4)C4(c6ccccc6-c6ccccc64)c4ccccc4-5)cc3)nc(-c3cccc4oc5ccccc5c34)n2)cc1]

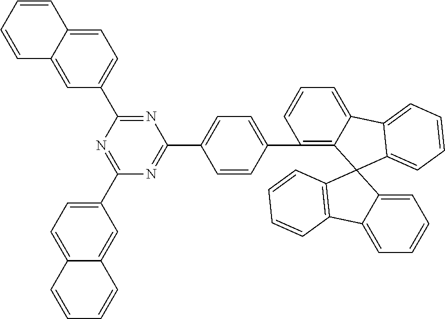 [SMILES: c1ccc2c(c1)-c1ccccc1C21c2ccccc2-c2cccc(-c3ccc(-c4nc(-c5ccc6ccccc6c5)nc(-c5ccc6ccccc6c5)n4)cc3)c21]

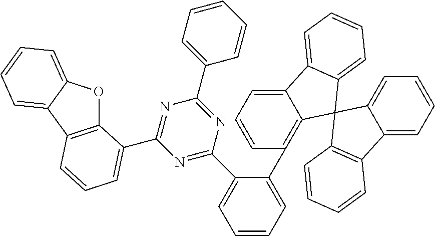 [SMILES: c1ccc(-c2nc(-c3ccccc3-c3cccc4c3C3(c5ccccc5-c5ccccc53)c3ccccc3-4)nc(-c3cccc4c3oc3ccccc34)n2)cc1]

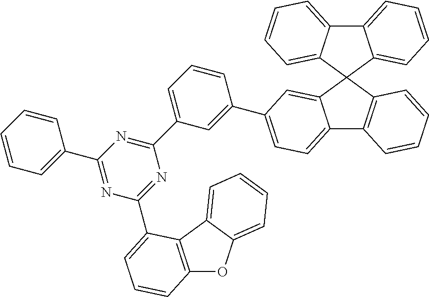 [SMILES: c1ccc(-c2nc(-c3cccc(-c4ccc5c(c4)C4(c6ccccc6-c6ccccc64)c4ccccc4-5)c3)nc(-c3cccc4oc5ccccc5c34)n2)cc1]

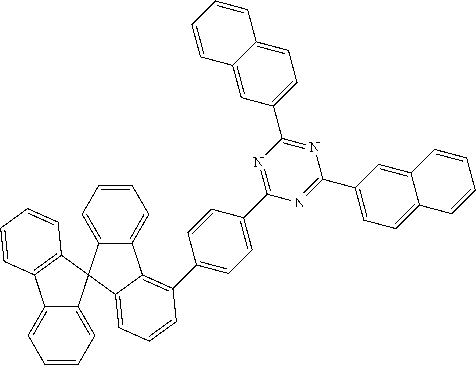 [SMILES: c1ccc2c(c1)-c1ccccc1C21c2ccccc2-c2c(-c3ccc(-c4nc(-c5ccc6ccccc6c5)nc(-c5ccc6ccccc6c5)n4)cc3)cccc21]

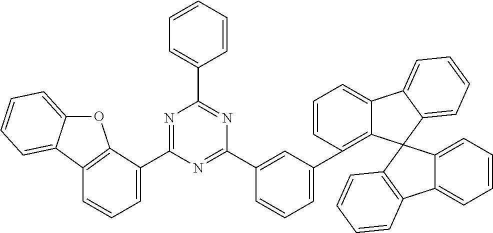 [SMILES: c1ccc(-c2nc(-c3cccc(-c4cccc5c4C4(c6ccccc6-c6ccccc64)c4ccccc4-5)c3)nc(-c3cccc4c3oc3ccccc34)n2)cc1]

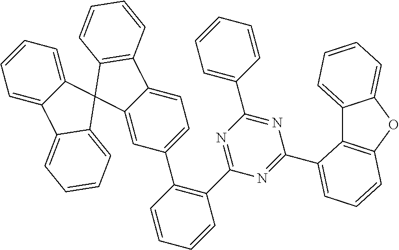 [SMILES: c1ccc(-c2nc(-c3ccccc3-c3ccc4c(c3)C3(c5ccccc5-c5ccccc53)c3ccccc3-4)nc(-c3cccc4oc5ccccc5c34)n2)cc1]

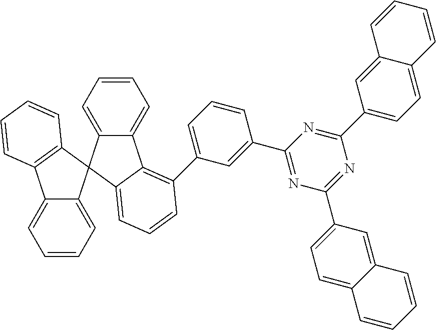 [SMILES: c1cc(-c2nc(-c3ccc4ccccc4c3)nc(-c3ccc4ccccc4c3)n2)cc(-c2cccc3c2-c2ccccc2C32c3ccccc3-c3ccccc32)c1]

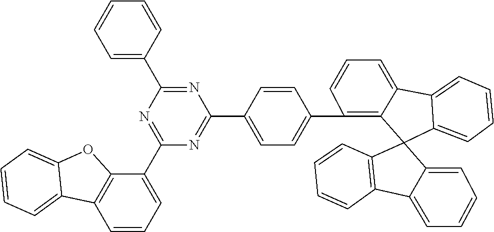 [SMILES: c1ccc(-c2nc(-c3ccc(-c4cccc5c4C4(c6ccccc6-c6ccccc64)c4ccccc4-5)cc3)nc(-c3cccc4c3oc3ccccc34)n2)cc1]

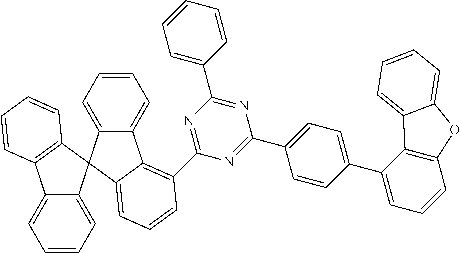 [SMILES: c1ccc(-c2nc(-c3ccc(-c4cccc5oc6ccccc6c45)cc3)nc(-c3cccc4c3-c3ccccc3C43c4ccccc4-c4ccccc43)n2)cc1]

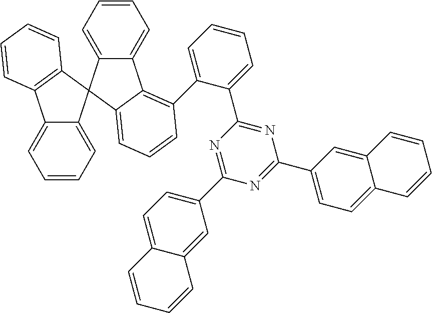 [SMILES: c1ccc(-c2cccc3c2-c2ccccc2C32c3ccccc3-c3ccccc32)c(-c2nc(-c3ccc4ccccc4c3)nc(-c3ccc4ccccc4c3)n2)c1]

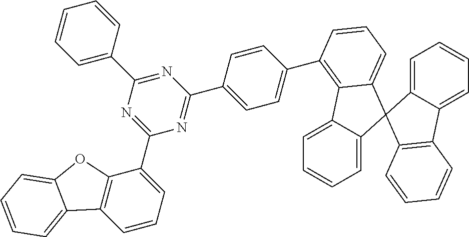 [SMILES: c1ccc(-c2nc(-c3ccc(-c4cccc5c4-c4ccccc4C54c5ccccc5-c5ccccc54)cc3)nc(-c3cccc4c3oc3ccccc34)n2)cc1]

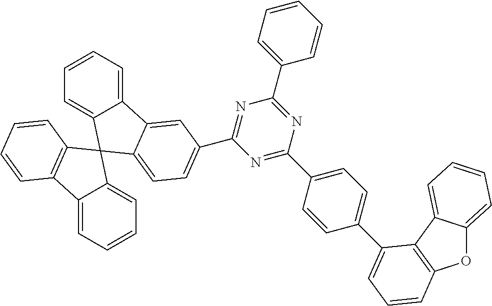 [SMILES: c1ccc(-c2nc(-c3ccc(-c4cccc5oc6ccccc6c45)cc3)nc(-c3ccc4c(c3)-c3ccccc3C43c4ccccc4-c4ccccc43)n2)cc1]

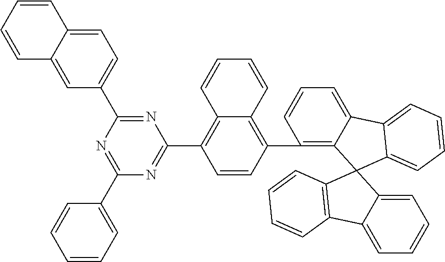 [SMILES: c1ccc(-c2nc(-c3ccc4ccccc4c3)nc(-c3ccc(-c4cccc5c4C4(c6ccccc6-c6ccccc64)c4ccccc4-5)c4ccccc34)n2)cc1]

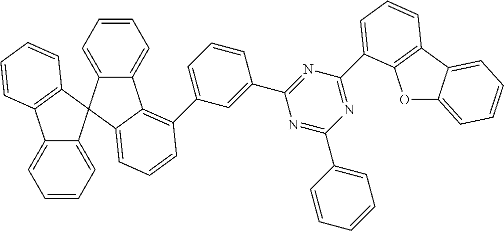 [SMILES: c1ccc(-c2nc(-c3cccc(-c4cccc5c4-c4ccccc4C54c5ccccc5-c5ccccc54)c3)nc(-c3cccc4c3oc3ccccc34)n2)cc1]

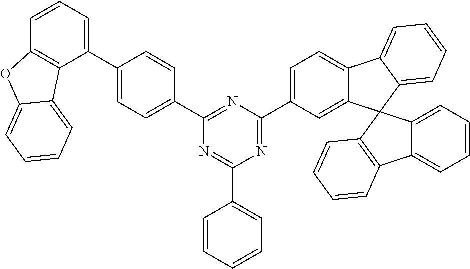 [SMILES: c1ccc(-c2nc(-c3ccc(-c4cccc5oc6ccccc6c45)cc3)nc(-c3ccc4c(c3)C3(c5ccccc5-c5ccccc53)c3ccccc3-4)n2)cc1]

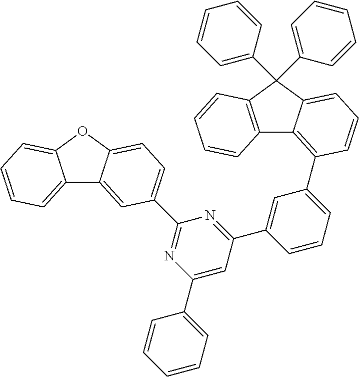 [SMILES: c1ccc(-c2cc(-c3cccc(-c4cccc5c4-c4ccccc4C5(c4ccccc4)c4ccccc4)c3)nc(-c3ccc4oc5ccccc5c4c3)n2)cc1]

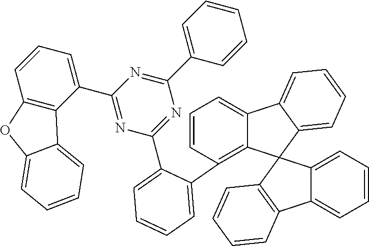 [SMILES: c1ccc(-c2nc(-c3ccccc3-c3cccc4c3C3(c5ccccc5-c5ccccc53)c3ccccc3-4)nc(-c3cccc4oc5ccccc5c34)n2)cc1]

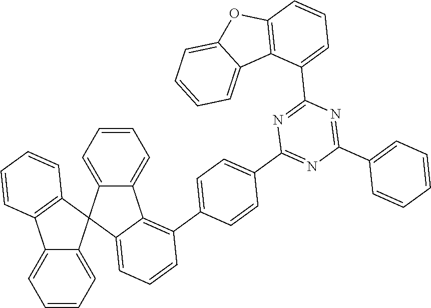 [SMILES: c1ccc(-c2nc(-c3ccc(-c4cccc5c4-c4ccccc4C54c5ccccc5-c5ccccc54)cc3)nc(-c3cccc4oc5ccccc5c34)n2)cc1]

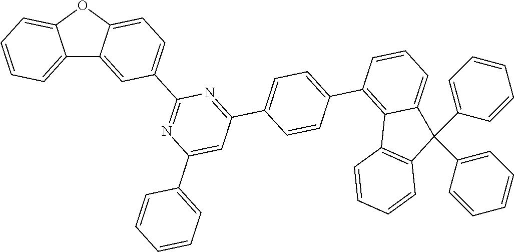 [SMILES: c1ccc(-c2cc(-c3ccc(-c4cccc5c4-c4ccccc4C5(c4ccccc4)c4ccccc4)cc3)nc(-c3ccc4oc5ccccc5c4c3)n2)cc1]

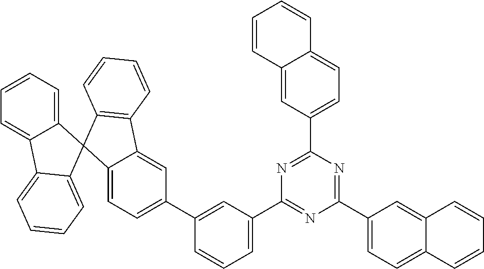 [SMILES: c1cc(-c2ccc3c(c2)-c2ccccc2C32c3ccccc3-c3ccccc32)cc(-c2nc(-c3ccc4ccccc4c3)nc(-c3ccc4ccccc4c3)n2)c1]

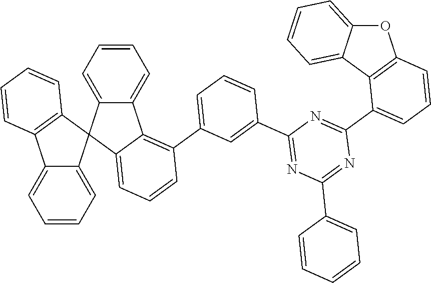 [SMILES: c1ccc(-c2nc(-c3cccc(-c4cccc5c4-c4ccccc4C54c5ccccc5-c5ccccc54)c3)nc(-c3cccc4oc5ccccc5c34)n2)cc1]

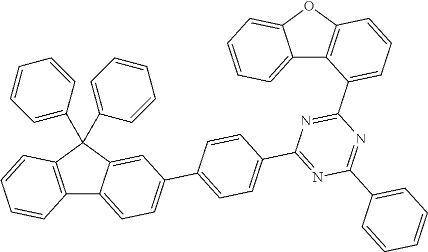 [SMILES: c1ccc(-c2nc(-c3ccc(-c4ccc5c(c4)C(c4ccccc4)(c4ccccc4)c4ccccc4-5)cc3)nc(-c3cccc4oc5ccccc5c34)n2)cc1]

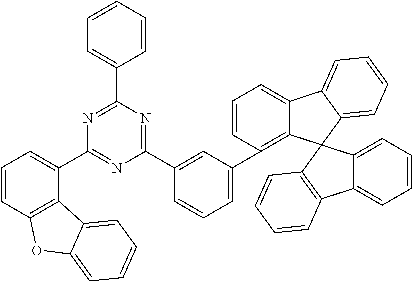 [SMILES: c1ccc(-c2nc(-c3cccc(-c4cccc5c4C4(c6ccccc6-c6ccccc64)c4ccccc4-5)c3)nc(-c3cccc4oc5ccccc5c34)n2)cc1]

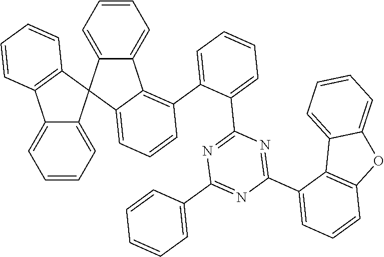 [SMILES: c1ccc(-c2nc(-c3ccccc3-c3cccc4c3-c3ccccc3C43c4ccccc4-c4ccccc43)nc(-c3cccc4oc5ccccc5c34)n2)cc1]

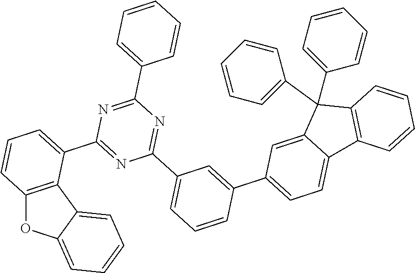 [SMILES: c1ccc(-c2nc(-c3cccc(-c4ccc5c(c4)C(c4ccccc4)(c4ccccc4)c4ccccc4-5)c3)nc(-c3cccc4oc5ccccc5c34)n2)cc1]

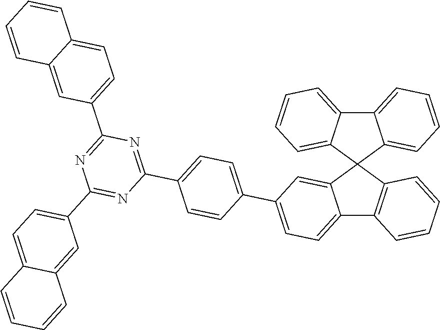 [SMILES: c1ccc2c(c1)-c1ccccc1C21c2ccccc2-c2ccc(-c3ccc(-c4nc(-c5ccc6ccccc6c5)nc(-c5ccc6ccccc6c5)n4)cc3)cc21]

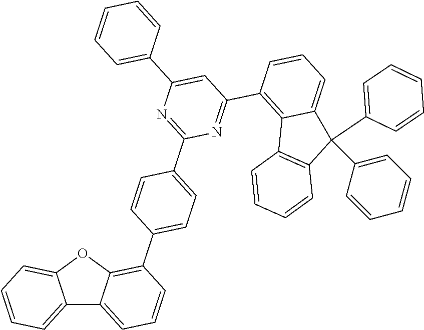 [SMILES: c1ccc(-c2cc(-c3cccc4c3-c3ccccc3C4(c3ccccc3)c3ccccc3)nc(-c3ccc(-c4cccc5c4oc4ccccc45)cc3)n2)cc1]

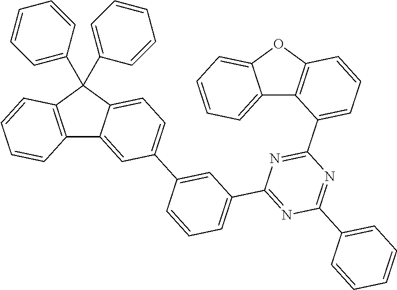 [SMILES: c1ccc(-c2nc(-c3cccc(-c4ccc5c(c4)-c4ccccc4C5(c4ccccc4)c4ccccc4)c3)nc(-c3cccc4oc5ccccc5c34)n2)cc1]

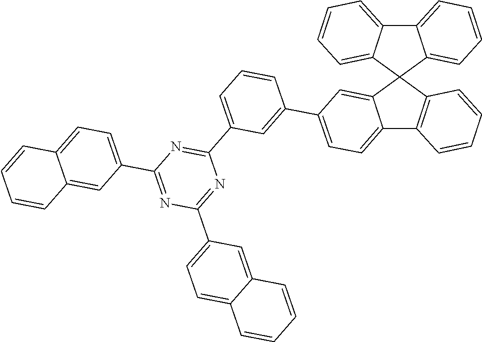 [SMILES: c1cc(-c2ccc3c(c2)C2(c4ccccc4-c4ccccc42)c2ccccc2-3)cc(-c2nc(-c3ccc4ccccc4c3)nc(-c3ccc4ccccc4c3)n2)c1]

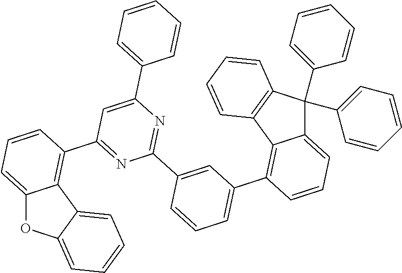 [SMILES: c1ccc(-c2cc(-c3cccc4oc5ccccc5c34)nc(-c3cccc(-c4cccc5c4-c4ccccc4C5(c4ccccc4)c4ccccc4)c3)n2)cc1]

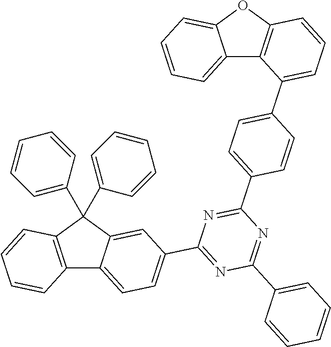 [SMILES: c1ccc(-c2nc(-c3ccc(-c4cccc5oc6ccccc6c45)cc3)nc(-c3ccc4c(c3)C(c3ccccc3)(c3ccccc3)c3ccccc3-4)n2)cc1]

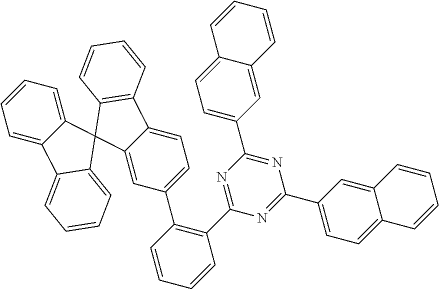 [SMILES: c1ccc(-c2nc(-c3ccc4ccccc4c3)nc(-c3ccc4ccccc4c3)n2)c(-c2ccc3c(c2)C2(c4ccccc4-c4ccccc42)c2ccccc2-3)c1]

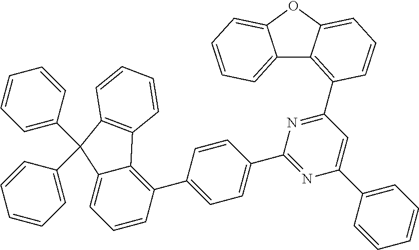 [SMILES: c1ccc(-c2cc(-c3cccc4oc5ccccc5c34)nc(-c3ccc(-c4cccc5c4-c4ccccc4C5(c4ccccc4)c4ccccc4)cc3)n2)cc1]

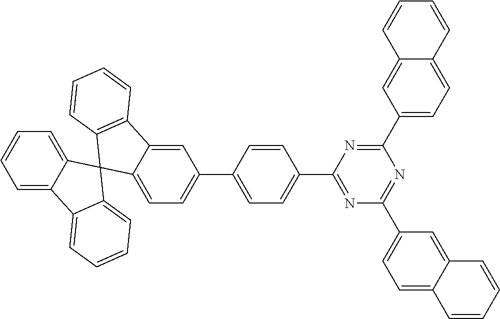 [SMILES: c1ccc2c(c1)-c1ccccc1C21c2ccccc2-c2cc(-c3ccc(-c4nc(-c5ccc6ccccc6c5)nc(-c5ccc6ccccc6c5)n4)cc3)ccc21]

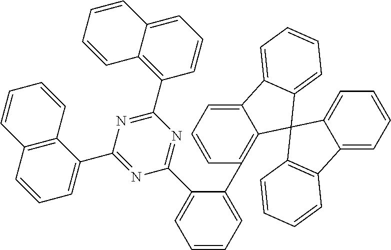 [SMILES: c1ccc(-c2cccc3c2C2(c4ccccc4-c4ccccc42)c2ccccc2-3)c(-c2nc(-c3cccc4ccccc34)nc(-c3cccc4ccccc34)n2)c1]

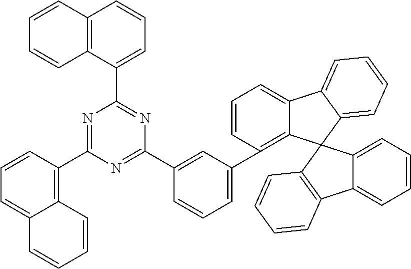 [SMILES: c1cc(-c2nc(-c3cccc4ccccc34)nc(-c3cccc4ccccc34)n2)cc(-c2cccc3c2C2(c4ccccc4-c4ccccc42)c2ccccc2-3)c1]

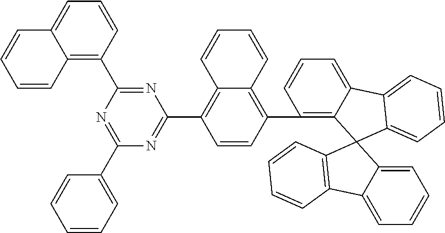 [SMILES: c1ccc(-c2nc(-c3cccc4ccccc34)nc(-c3ccc(-c4cccc5c4C4(c6ccccc6-c6ccccc64)c4ccccc4-5)c4ccccc34)n2)cc1]

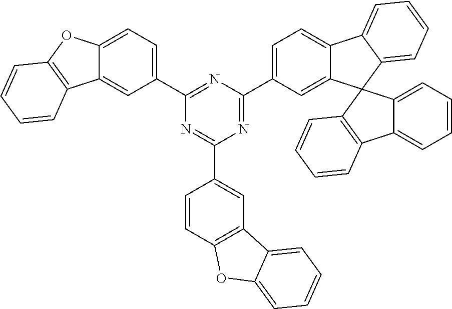 [SMILES: c1ccc2c(c1)-c1ccccc1C21c2ccccc2-c2ccc(-c3nc(-c4ccc5oc6ccccc6c5c4)nc(-c4ccc5oc6ccccc6c5c4)n3)cc21]

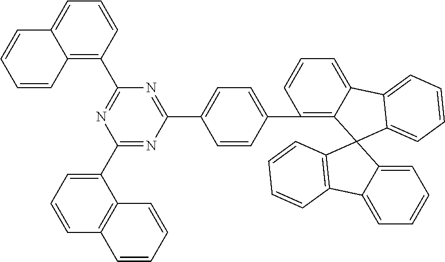 [SMILES: c1ccc2c(c1)-c1ccccc1C21c2ccccc2-c2cccc(-c3ccc(-c4nc(-c5cccc6ccccc56)nc(-c5cccc6ccccc56)n4)cc3)c21]

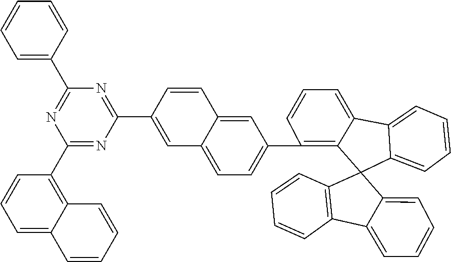 [SMILES: c1ccc(-c2nc(-c3ccc4cc(-c5cccc6c5C5(c7ccccc7-c7ccccc75)c5ccccc5-6)ccc4c3)nc(-c3cccc4ccccc34)n2)cc1]

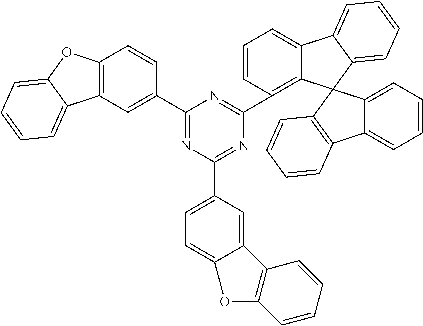 [SMILES: c1ccc2c(c1)-c1ccccc1C21c2ccccc2-c2cccc(-c3nc(-c4ccc5oc6ccccc6c5c4)nc(-c4ccc5oc6ccccc6c5c4)n3)c21]

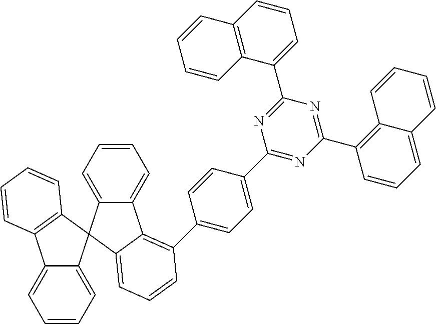 [SMILES: c1ccc2c(c1)-c1ccccc1C21c2ccccc2-c2c(-c3ccc(-c4nc(-c5cccc6ccccc56)nc(-c5cccc6ccccc56)n4)cc3)cccc21]

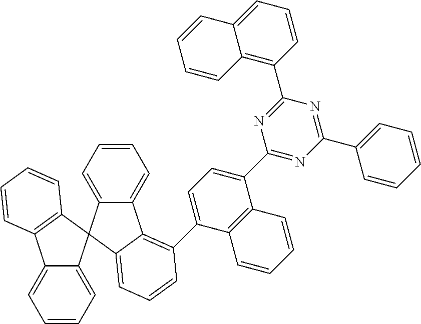 [SMILES: c1ccc(-c2nc(-c3cccc4ccccc34)nc(-c3ccc(-c4cccc5c4-c4ccccc4C54c5ccccc5-c5ccccc54)c4ccccc34)n2)cc1]

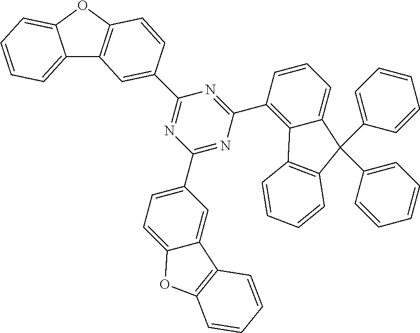 [SMILES: c1ccc(C2(c3ccccc3)c3ccccc3-c3c(-c4nc(-c5ccc6oc7ccccc7c6c5)nc(-c5ccc6oc7ccccc7c6c5)n4)cccc32)cc1]

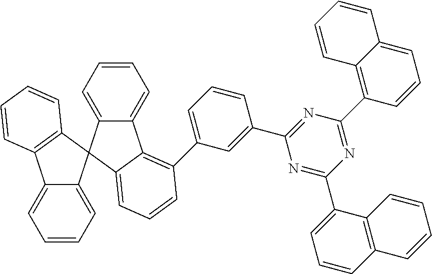 [SMILES: c1cc(-c2nc(-c3cccc4ccccc34)nc(-c3cccc4ccccc34)n2)cc(-c2cccc3c2-c2ccccc2C32c3ccccc3-c3ccccc32)c1]

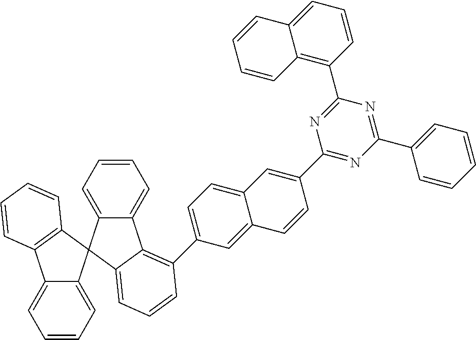 [SMILES: c1ccc(-c2nc(-c3ccc4cc(-c5cccc6c5-c5ccccc5C65c6ccccc6-c6ccccc65)ccc4c3)nc(-c3cccc4ccccc34)n2)cc1]

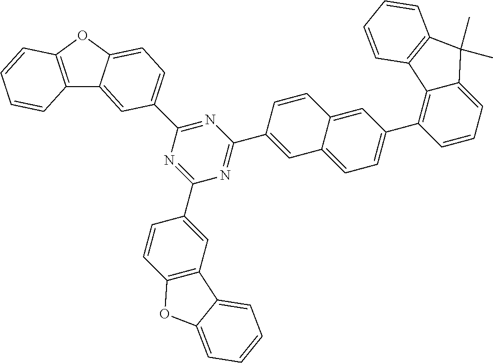 [SMILES: CC1(C)c2ccccc2-c2c(-c3ccc4cc(-c5nc(-c6ccc7oc8ccccc8c7c6)nc(-c6ccc7oc8ccccc8c7c6)n5)ccc4c3)cccc21]

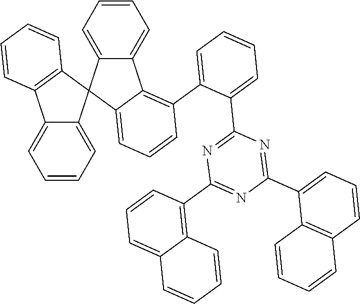 [SMILES: c1ccc(-c2cccc3c2-c2ccccc2C32c3ccccc3-c3ccccc32)c(-c2nc(-c3cccc4ccccc34)nc(-c3cccc4ccccc34)n2)c1]

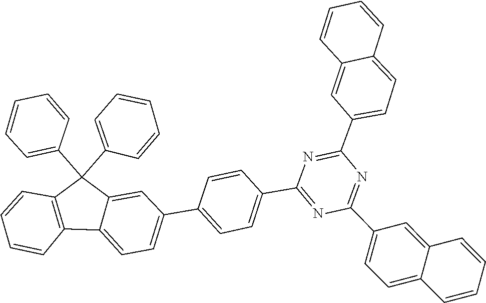 [SMILES: c1ccc(C2(c3ccccc3)c3ccccc3-c3ccc(-c4ccc(-c5nc(-c6ccc7ccccc7c6)nc(-c6ccc7ccccc7c6)n5)cc4)cc32)cc1]

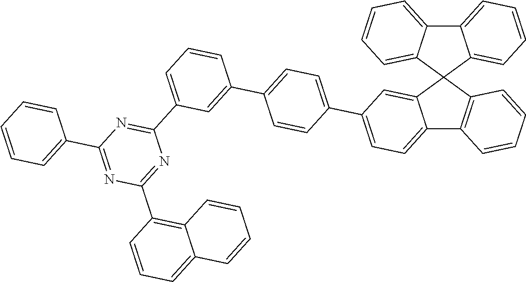 [SMILES: c1ccc(-c2nc(-c3cccc(-c4ccc(-c5ccc6c(c5)C5(c7ccccc7-c7ccccc75)c5ccccc5-6)cc4)c3)nc(-c3cccc4ccccc34)n2)cc1]

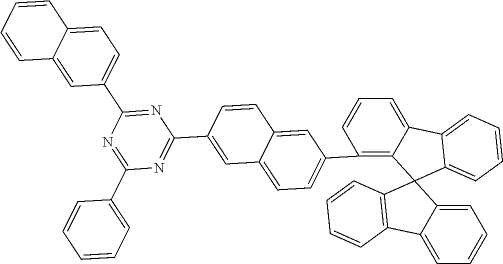 [SMILES: c1ccc(-c2nc(-c3ccc4ccccc4c3)nc(-c3ccc4cc(-c5cccc6c5C5(c7ccccc7-c7ccccc75)c5ccccc5-6)ccc4c3)n2)cc1]

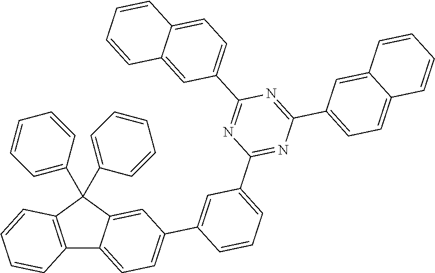 [SMILES: c1ccc(C2(c3ccccc3)c3ccccc3-c3ccc(-c4cccc(-c5nc(-c6ccc7ccccc7c6)nc(-c6ccc7ccccc7c6)n5)c4)cc32)cc1]

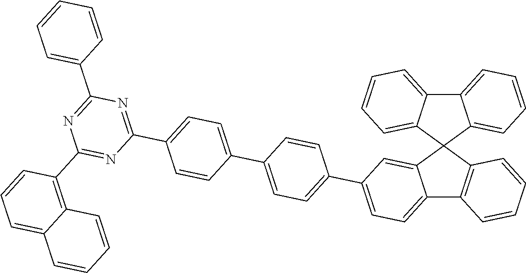 [SMILES: c1ccc(-c2nc(-c3ccc(-c4ccc(-c5ccc6c(c5)C5(c7ccccc7-c7ccccc75)c5ccccc5-6)cc4)cc3)nc(-c3cccc4ccccc34)n2)cc1]

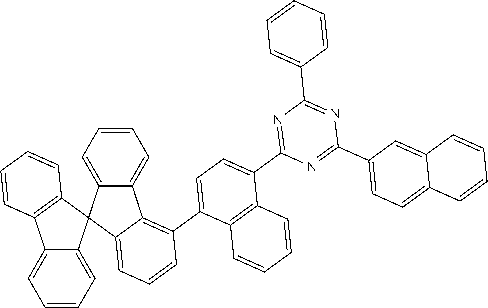 [SMILES: c1ccc(-c2nc(-c3ccc4ccccc4c3)nc(-c3ccc(-c4cccc5c4-c4ccccc4C54c5ccccc5-c5ccccc54)c4ccccc34)n2)cc1]

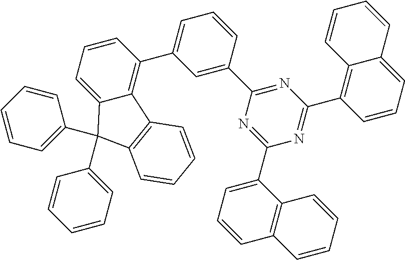 [SMILES: c1ccc(C2(c3ccccc3)c3ccccc3-c3c(-c4cccc(-c5nc(-c6cccc7ccccc67)nc(-c6cccc7ccccc67)n5)c4)cccc32)cc1]

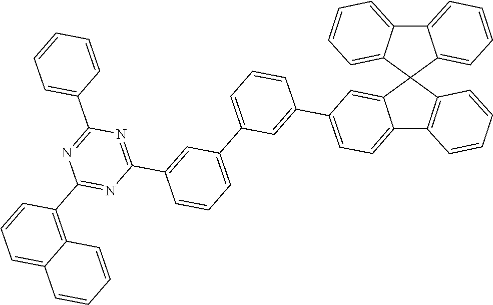 [SMILES: c1ccc(-c2nc(-c3cccc(-c4cccc(-c5ccc6c(c5)C5(c7ccccc7-c7ccccc75)c5ccccc5-6)c4)c3)nc(-c3cccc4ccccc34)n2)cc1]

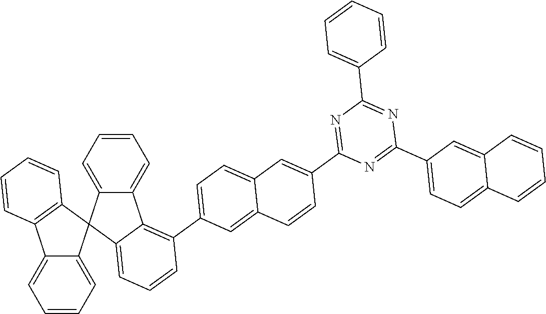 [SMILES: c1ccc(-c2nc(-c3ccc4ccccc4c3)nc(-c3ccc4cc(-c5cccc6c5-c5ccccc5C65c6ccccc6-c6ccccc65)ccc4c3)n2)cc1]

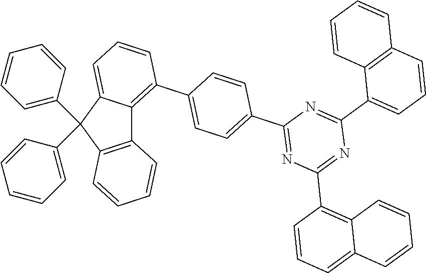 [SMILES: c1ccc(C2(c3ccccc3)c3ccccc3-c3c(-c4ccc(-c5nc(-c6cccc7ccccc67)nc(-c6cccc7ccccc67)n5)cc4)cccc32)cc1]

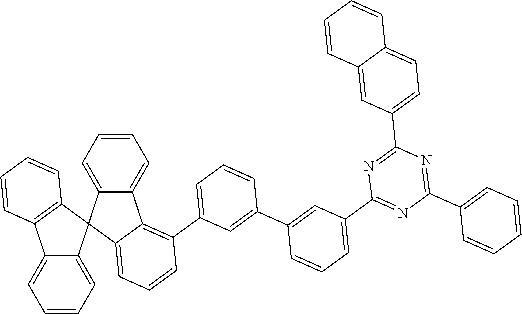 [SMILES: c1ccc(-c2nc(-c3cccc(-c4cccc(-c5cccc6c5-c5ccccc5C65c6ccccc6-c6ccccc65)c4)c3)nc(-c3ccc4ccccc4c3)n2)cc1]

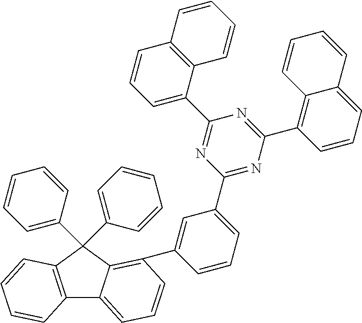 [SMILES: c1ccc(C2(c3ccccc3)c3ccccc3-c3cccc(-c4cccc(-c5nc(-c6cccc7ccccc67)nc(-c6cccc7ccccc67)n5)c4)c32)cc1]

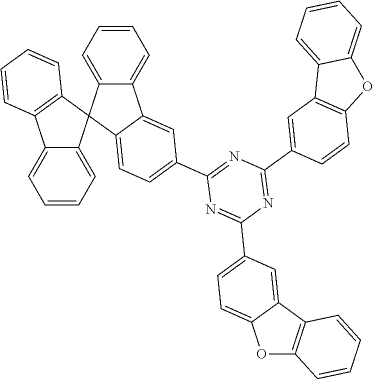 [SMILES: c1ccc2c(c1)-c1ccccc1C21c2ccccc2-c2cc(-c3nc(-c4ccc5oc6ccccc6c5c4)nc(-c4ccc5oc6ccccc6c5c4)n3)ccc21]

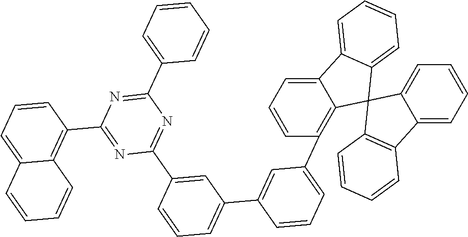 [SMILES: c1ccc(-c2nc(-c3cccc(-c4cccc(-c5cccc6c5C5(c7ccccc7-c7ccccc75)c5ccccc5-6)c4)c3)nc(-c3cccc4ccccc34)n2)cc1]

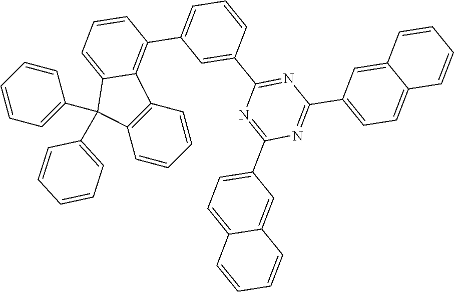 [SMILES: c1ccc(C2(c3ccccc3)c3ccccc3-c3c(-c4cccc(-c5nc(-c6ccc7ccccc7c6)nc(-c6ccc7ccccc7c6)n5)c4)cccc32)cc1]

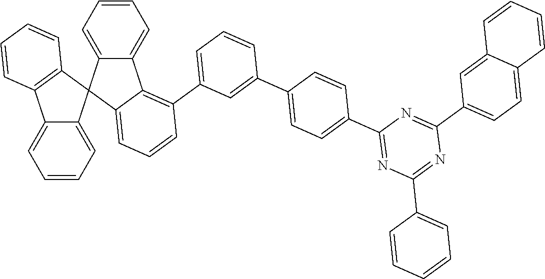 [SMILES: c1ccc(-c2nc(-c3ccc(-c4cccc(-c5cccc6c5-c5ccccc5C65c6ccccc6-c6ccccc65)c4)cc3)nc(-c3ccc4ccccc4c3)n2)cc1]

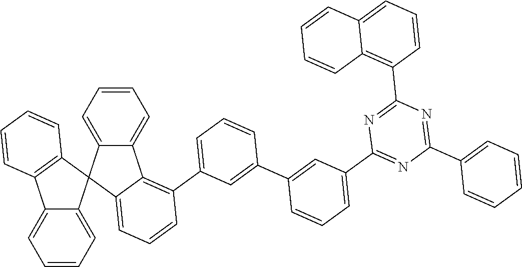 [SMILES: c1ccc(-c2nc(-c3cccc(-c4cccc(-c5cccc6c5-c5ccccc5C65c6ccccc6-c6ccccc65)c4)c3)nc(-c3cccc4ccccc34)n2)cc1]

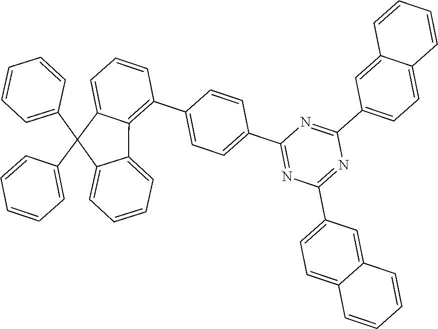 [SMILES: c1ccc(C2(c3ccccc3)c3ccccc3-c3c(-c4ccc(-c5nc(-c6ccc7ccccc7c6)nc(-c6ccc7ccccc7c6)n5)cc4)cccc32)cc1]

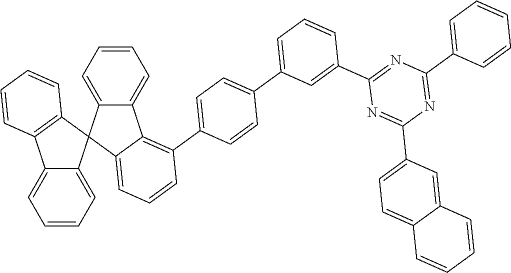 [SMILES: c1ccc(-c2nc(-c3cccc(-c4ccc(-c5cccc6c5-c5ccccc5C65c6ccccc6-c6ccccc65)cc4)c3)nc(-c3ccc4ccccc4c3)n2)cc1]

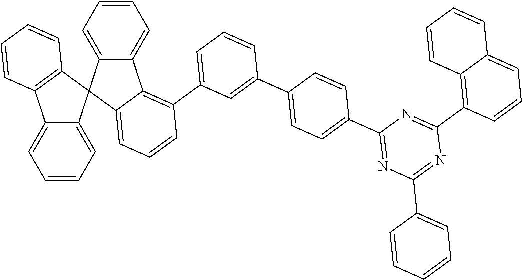 [SMILES: c1ccc(-c2nc(-c3ccc(-c4cccc(-c5cccc6c5-c5ccccc5C65c6ccccc6-c6ccccc65)c4)cc3)nc(-c3cccc4ccccc34)n2)cc1]

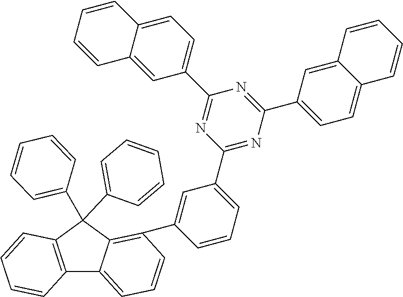 [SMILES: c1ccc(C2(c3ccccc3)c3ccccc3-c3cccc(-c4cccc(-c5nc(-c6ccc7ccccc7c6)nc(-c6ccc7ccccc7c6)n5)c4)c32)cc1]

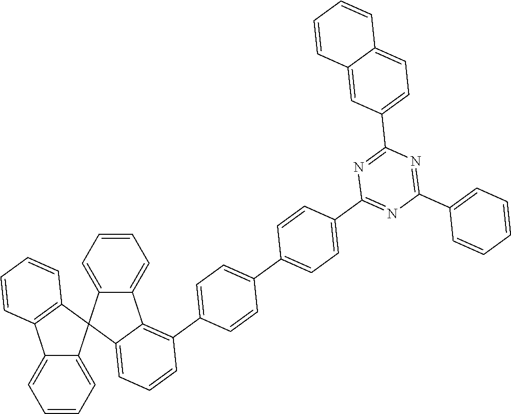 [SMILES: c1ccc(-c2nc(-c3ccc(-c4ccc(-c5cccc6c5-c5ccccc5C65c6ccccc6-c6ccccc65)cc4)cc3)nc(-c3ccc4ccccc4c3)n2)cc1]

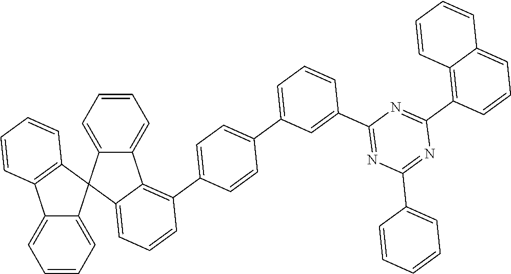 [SMILES: c1ccc(-c2nc(-c3cccc(-c4ccc(-c5cccc6c5-c5ccccc5C65c6ccccc6-c6ccccc65)cc4)c3)nc(-c3cccc4ccccc34)n2)cc1]

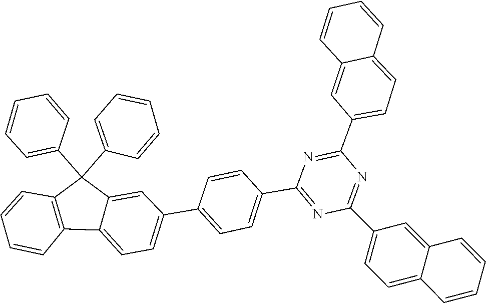 [SMILES: c1ccc(C2(c3ccccc3)c3ccccc3-c3ccc(-c4ccc(-c5nc(-c6ccc7ccccc7c6)nc(-c6ccc7ccccc7c6)n5)cc4)cc32)cc1]

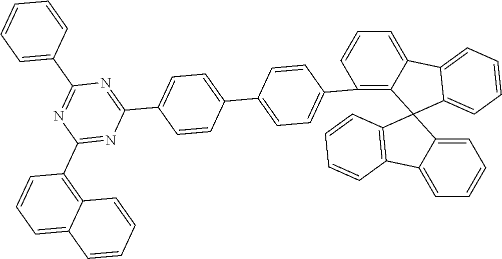 [SMILES: c1ccc(-c2nc(-c3ccc(-c4ccc(-c5cccc6c5C5(c7ccccc7-c7ccccc75)c5ccccc5-6)cc4)cc3)nc(-c3cccc4ccccc34)n2)cc1]

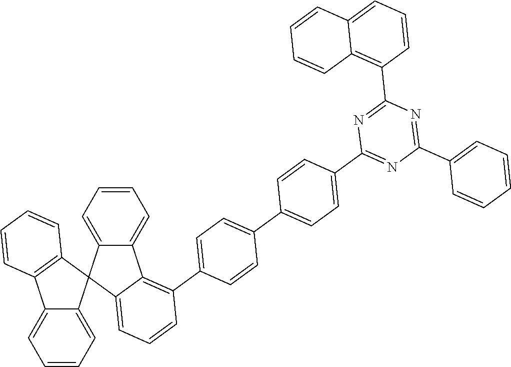 [SMILES: c1ccc(-c2nc(-c3ccc(-c4ccc(-c5cccc6c5-c5ccccc5C65c6ccccc6-c6ccccc65)cc4)cc3)nc(-c3cccc4ccccc34)n2)cc1]

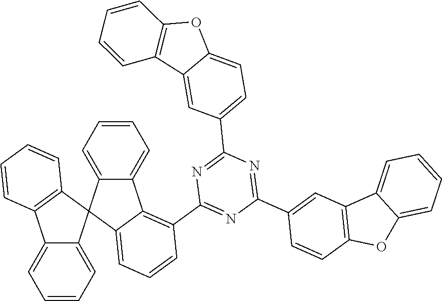 [SMILES: c1ccc2c(c1)-c1ccccc1C21c2ccccc2-c2c(-c3nc(-c4ccc5oc6ccccc6c5c4)nc(-c4ccc5oc6ccccc6c5c4)n3)cccc21]

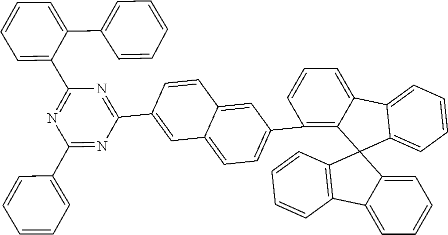 [SMILES: c1ccc(-c2nc(-c3ccc4cc(-c5cccc6c5C5(c7ccccc7-c7ccccc75)c5ccccc5-6)ccc4c3)nc(-c3ccccc3-c3ccccc3)n2)cc1]

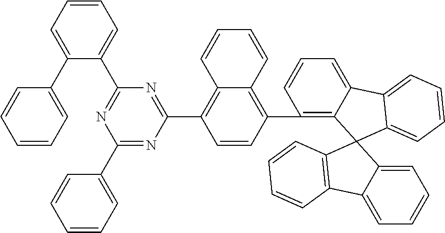 [SMILES: c1ccc(-c2nc(-c3ccccc3-c3ccccc3)nc(-c3ccc(-c4cccc5c4C4(c6ccccc6-c6ccccc64)c4ccccc4-5)c4ccccc34)n2)cc1]

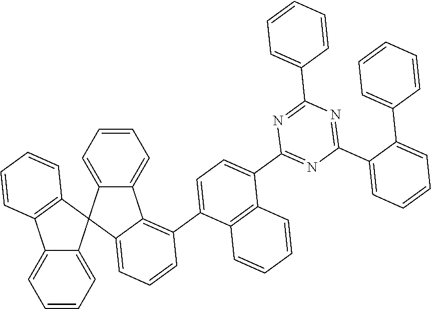 [SMILES: c1ccc(-c2nc(-c3ccccc3-c3ccccc3)nc(-c3ccc(-c4cccc5c4-c4ccccc4C54c5ccccc5-c5ccccc54)c4ccccc34)n2)cc1]

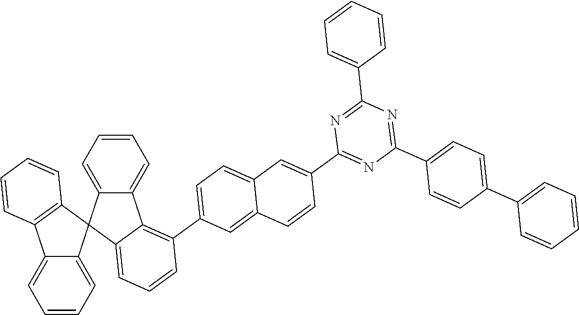 [SMILES: c1ccc(-c2ccc(-c3nc(-c4ccccc4)nc(-c4ccc5cc(-c6cccc7c6-c6ccccc6C76c7ccccc7-c7ccccc76)ccc5c4)n3)cc2)cc1]

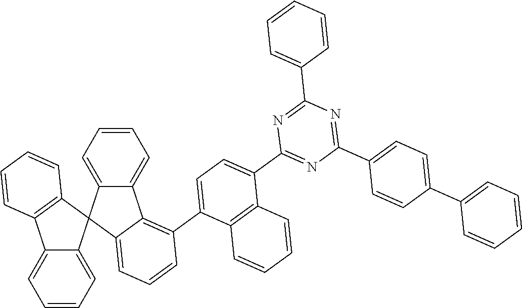 [SMILES: c1ccc(-c2ccc(-c3nc(-c4ccccc4)nc(-c4ccc(-c5cccc6c5-c5ccccc5C65c6ccccc6-c6ccccc65)c5ccccc45)n3)cc2)cc1]

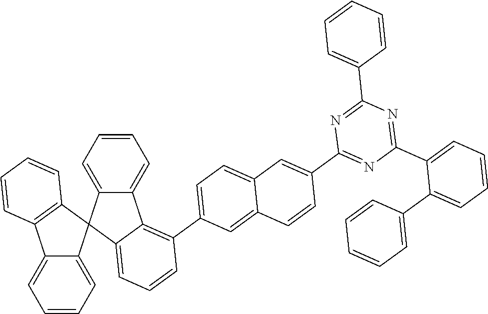 [SMILES: c1ccc(-c2nc(-c3ccc4cc(-c5cccc6c5-c5ccccc5C65c6ccccc6-c6ccccc65)ccc4c3)nc(-c3ccccc3-c3ccccc3)n2)cc1]

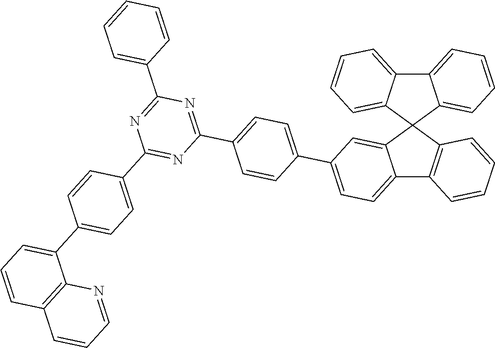 [SMILES: c1ccc(-c2nc(-c3ccc(-c4ccc5c(c4)C4(c6ccccc6-c6ccccc64)c4ccccc4-5)cc3)nc(-c3ccc(-c4cccc5cccnc45)cc3)n2)cc1]

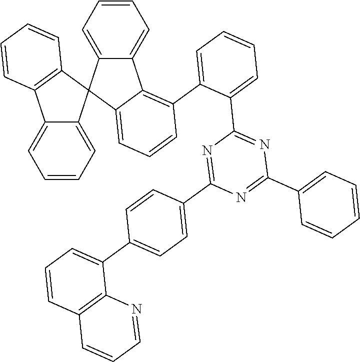 [SMILES: c1ccc(-c2nc(-c3ccc(-c4cccc5cccnc45)cc3)nc(-c3ccccc3-c3cccc4c3-c3ccccc3C43c4ccccc4-c4ccccc43)n2)cc1]

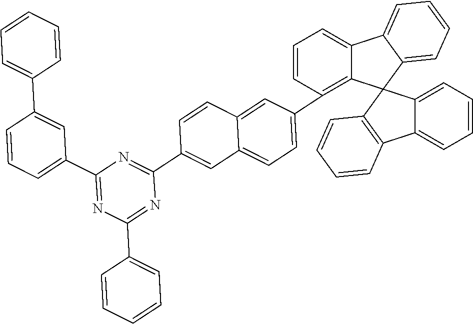 [SMILES: c1ccc(-c2cccc(-c3nc(-c4ccccc4)nc(-c4ccc5cc(-c6cccc7c6C6(c8ccccc8-c8ccccc86)c6ccccc6-7)ccc5c4)n3)c2)cc1]

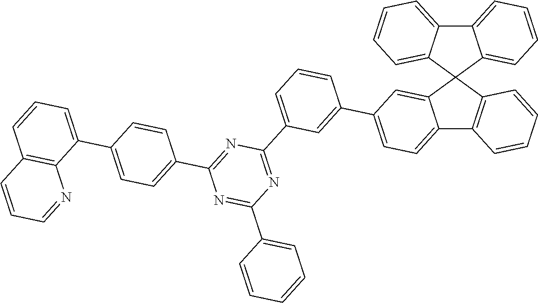 [SMILES: c1ccc(-c2nc(-c3ccc(-c4cccc5cccnc45)cc3)nc(-c3cccc(-c4ccc5c(c4)C4(c6ccccc6-c6ccccc64)c4ccccc4-5)c3)n2)cc1]

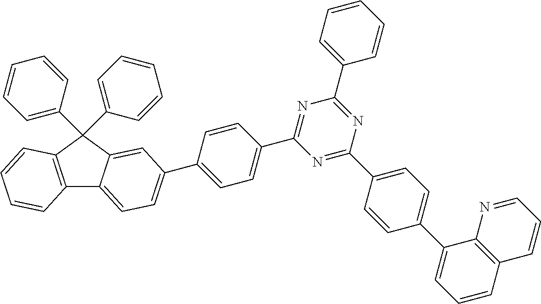 [SMILES: c1ccc(-c2nc(-c3ccc(-c4ccc5c(c4)C(c4ccccc4)(c4ccccc4)c4ccccc4-5)cc3)nc(-c3ccc(-c4cccc5cccnc45)cc3)n2)cc1]

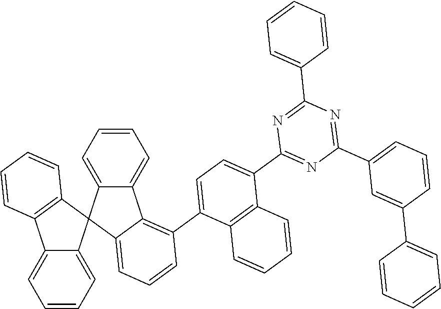 [SMILES: c1ccc(-c2cccc(-c3nc(-c4ccccc4)nc(-c4ccc(-c5cccc6c5-c5ccccc5C65c6ccccc6-c6ccccc65)c5ccccc45)n3)c2)cc1]

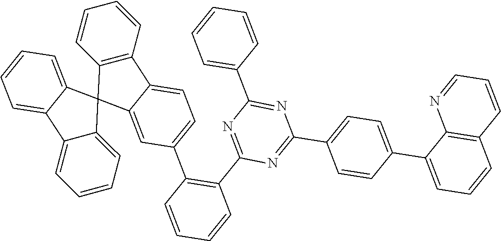 [SMILES: c1ccc(-c2nc(-c3ccc(-c4cccc5cccnc45)cc3)nc(-c3ccccc3-c3ccc4c(c3)C3(c5ccccc5-c5ccccc53)c3ccccc3-4)n2)cc1]

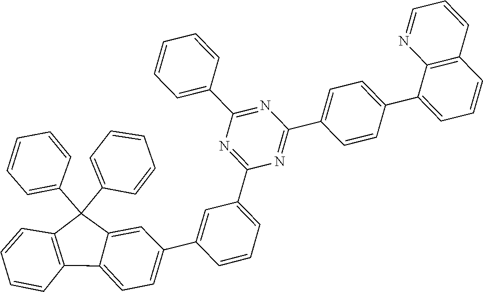 [SMILES: c1ccc(-c2nc(-c3ccc(-c4cccc5cccnc45)cc3)nc(-c3cccc(-c4ccc5c(c4)C(c4ccccc4)(c4ccccc4)c4ccccc4-5)c3)n2)cc1]

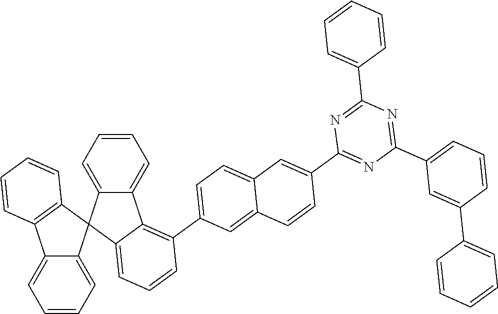 [SMILES: c1ccc(-c2cccc(-c3nc(-c4ccccc4)nc(-c4ccc5cc(-c6cccc7c6-c6ccccc6C76c7ccccc7-c7ccccc76)ccc5c4)n3)c2)cc1]

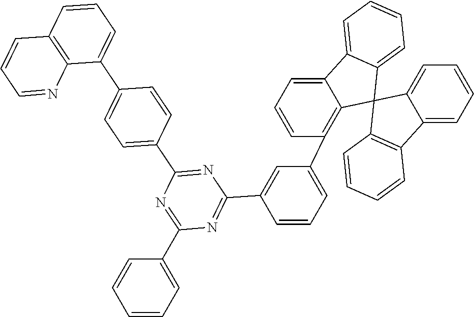 [SMILES: c1ccc(-c2nc(-c3ccc(-c4cccc5cccnc45)cc3)nc(-c3cccc(-c4cccc5c4C4(c6ccccc6-c6ccccc64)c4ccccc4-5)c3)n2)cc1]

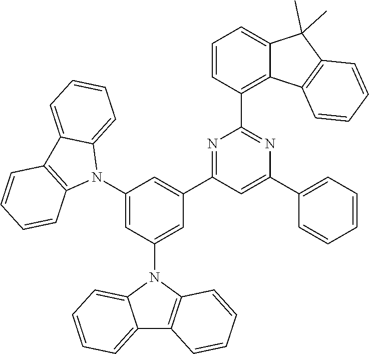 [SMILES: CC1(C)c2ccccc2-c2c(-c3nc(-c4ccccc4)cc(-c4cc(-n5c6ccccc6c6ccccc65)cc(-n5c6ccccc6c6ccccc65)c4)n3)cccc21]

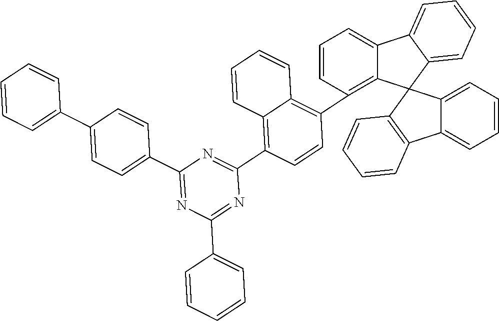 [SMILES: c1ccc(-c2ccc(-c3nc(-c4ccccc4)nc(-c4ccc(-c5cccc6c5C5(c7ccccc7-c7ccccc75)c5ccccc5-6)c5ccccc45)n3)cc2)cc1]

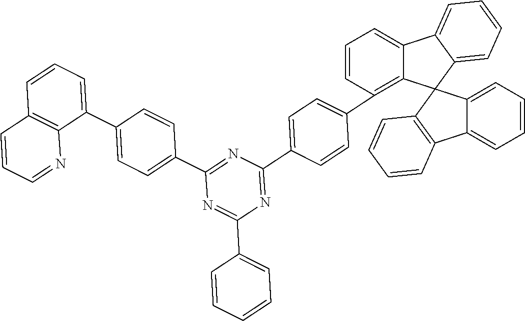 [SMILES: c1ccc(-c2nc(-c3ccc(-c4cccc5c4C4(c6ccccc6-c6ccccc64)c4ccccc4-5)cc3)nc(-c3ccc(-c4cccc5cccnc45)cc3)n2)cc1]

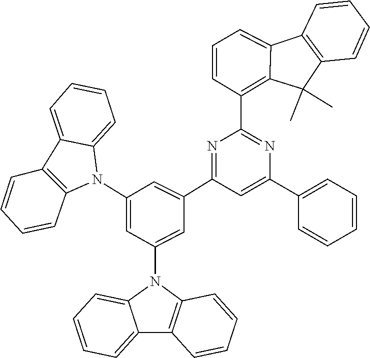 [SMILES: CC1(C)c2ccccc2-c2cccc(-c3nc(-c4ccccc4)cc(-c4cc(-n5c6ccccc6c6ccccc65)cc(-n5c6ccccc6c6ccccc65)c4)n3)c21]

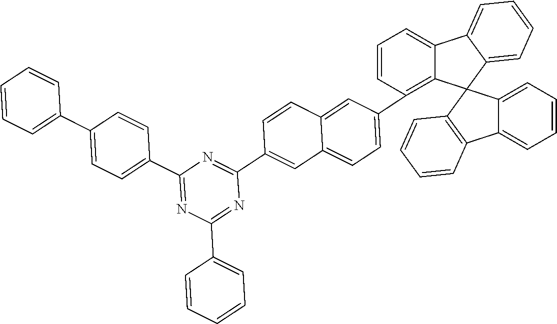 [SMILES: c1ccc(-c2ccc(-c3nc(-c4ccccc4)nc(-c4ccc5cc(-c6cccc7c6C6(c8ccccc8-c8ccccc86)c6ccccc6-7)ccc5c4)n3)cc2)cc1]

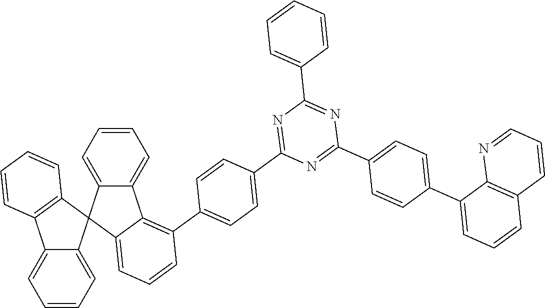 [SMILES: c1ccc(-c2nc(-c3ccc(-c4cccc5c4-c4ccccc4C54c5ccccc5-c5ccccc54)cc3)nc(-c3ccc(-c4cccc5cccnc45)cc3)n2)cc1]

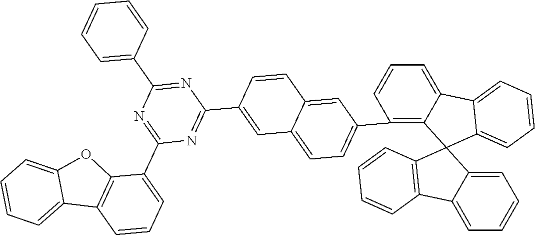 [SMILES: c1ccc(-c2nc(-c3ccc4cc(-c5cccc6c5C5(c7ccccc7-c7ccccc75)c5ccccc5-6)ccc4c3)nc(-c3cccc4c3oc3ccccc34)n2)cc1]

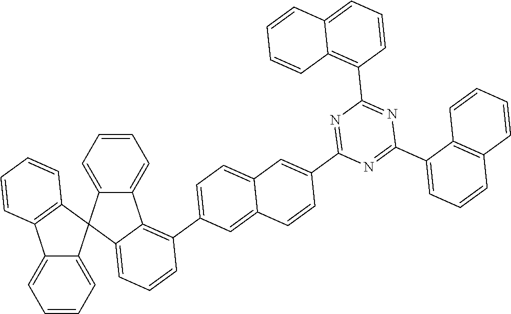 [SMILES: c1ccc2c(c1)-c1ccccc1C21c2ccccc2-c2c(-c3ccc4cc(-c5nc(-c6cccc7ccccc67)nc(-c6cccc7ccccc67)n5)ccc4c3)cccc21]

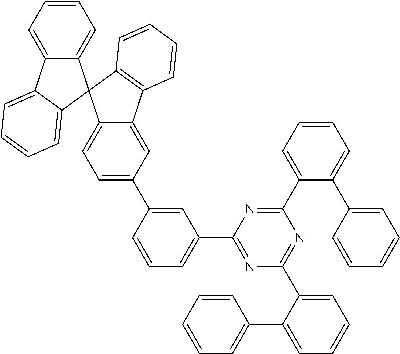 [SMILES: c1ccc(-c2ccccc2-c2nc(-c3cccc(-c4ccc5c(c4)-c4ccccc4C54c5ccccc5-c5ccccc54)c3)nc(-c3ccccc3-c3ccccc3)n2)cc1]

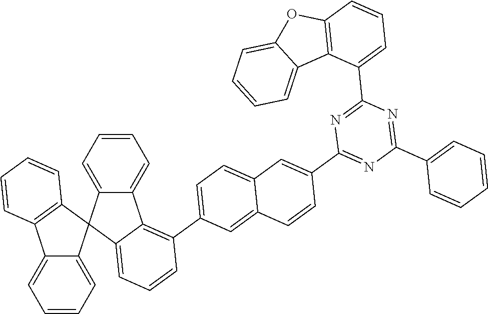 [SMILES: c1ccc(-c2nc(-c3ccc4cc(-c5cccc6c5-c5ccccc5C65c6ccccc6-c6ccccc65)ccc4c3)nc(-c3cccc4oc5ccccc5c34)n2)cc1]

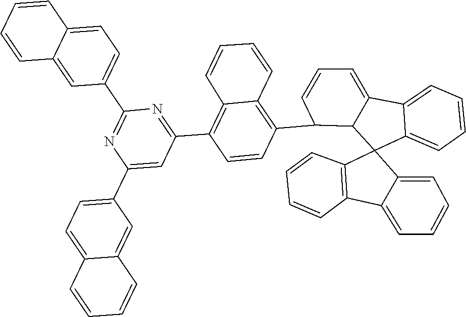 [SMILES: C1=CC(c2ccc(-c3cc(-c4ccc5ccccc5c4)nc(-c4ccc5ccccc5c4)n3)c3ccccc23)C2C(=C1)c1ccccc1C21c2ccccc2-c2ccccc21]

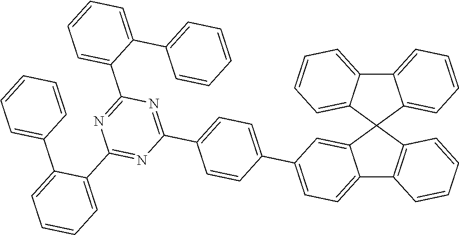 [SMILES: c1ccc(-c2ccccc2-c2nc(-c3ccc(-c4ccc5c(c4)C4(c6ccccc6-c6ccccc64)c4ccccc4-5)cc3)nc(-c3ccccc3-c3ccccc3)n2)cc1]

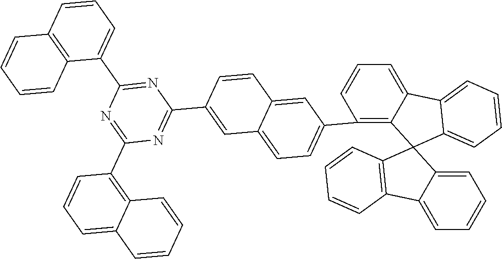 [SMILES: c1ccc2c(c1)-c1ccccc1C21c2ccccc2-c2cccc(-c3ccc4cc(-c5nc(-c6cccc7ccccc67)nc(-c6cccc7ccccc67)n5)ccc4c3)c21]

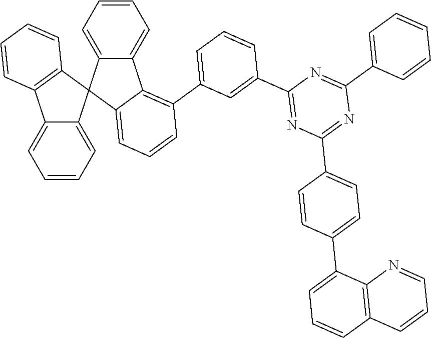 [SMILES: c1ccc(-c2nc(-c3ccc(-c4cccc5cccnc45)cc3)nc(-c3cccc(-c4cccc5c4-c4ccccc4C54c5ccccc5-c5ccccc54)c3)n2)cc1]

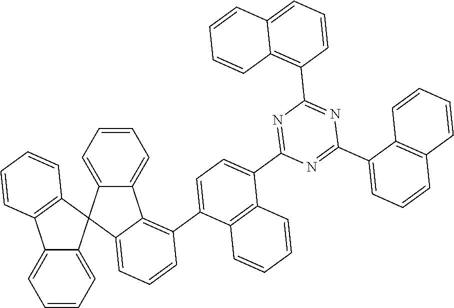 [SMILES: c1ccc2c(c1)-c1ccccc1C21c2ccccc2-c2c(-c3ccc(-c4nc(-c5cccc6ccccc56)nc(-c5cccc6ccccc56)n4)c4ccccc34)cccc21]

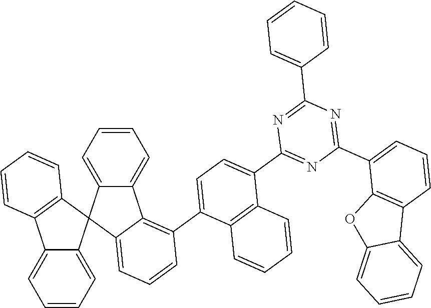 [SMILES: c1ccc(-c2nc(-c3ccc(-c4cccc5c4-c4ccccc4C54c5ccccc5-c5ccccc54)c4ccccc34)nc(-c3cccc4c3oc3ccccc34)n2)cc1]

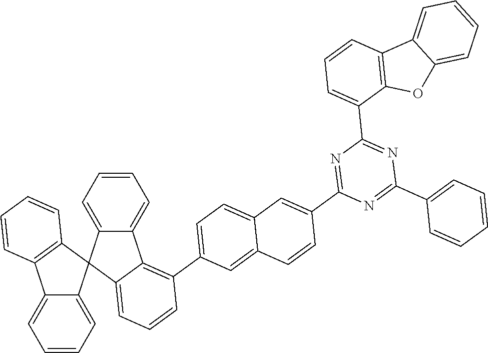 [SMILES: c1ccc(-c2nc(-c3ccc4cc(-c5cccc6c5-c5ccccc5C65c6ccccc6-c6ccccc65)ccc4c3)nc(-c3cccc4c3oc3ccccc34)n2)cc1]

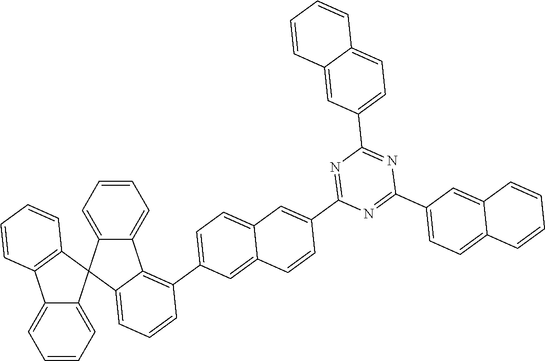 [SMILES: c1ccc2c(c1)-c1ccccc1C21c2ccccc2-c2c(-c3ccc4cc(-c5nc(-c6ccc7ccccc7c6)nc(-c6ccc7ccccc7c6)n5)ccc4c3)cccc21]

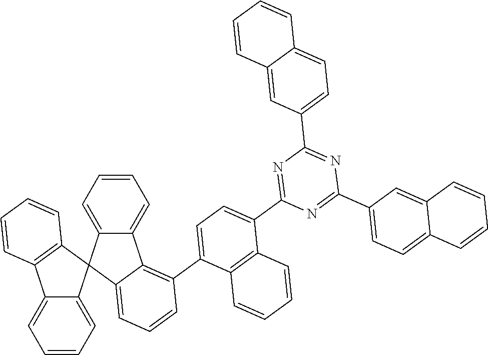 [SMILES: c1ccc2c(c1)-c1ccccc1C21c2ccccc2-c2c(-c3ccc(-c4nc(-c5ccc6ccccc6c5)nc(-c5ccc6ccccc6c5)n4)c4ccccc34)cccc21]

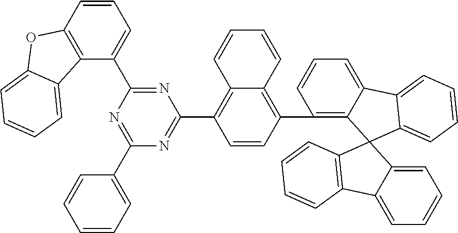 [SMILES: c1ccc(-c2nc(-c3ccc(-c4cccc5c4C4(c6ccccc6-c6ccccc64)c4ccccc4-5)c4ccccc34)nc(-c3cccc4oc5ccccc5c34)n2)cc1]

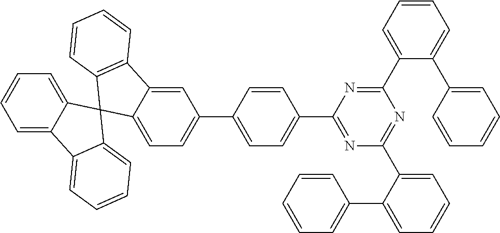 [SMILES: c1ccc(-c2ccccc2-c2nc(-c3ccc(-c4ccc5c(c4)-c4ccccc4C54c5ccccc5-c5ccccc54)cc3)nc(-c3ccccc3-c3ccccc3)n2)cc1]

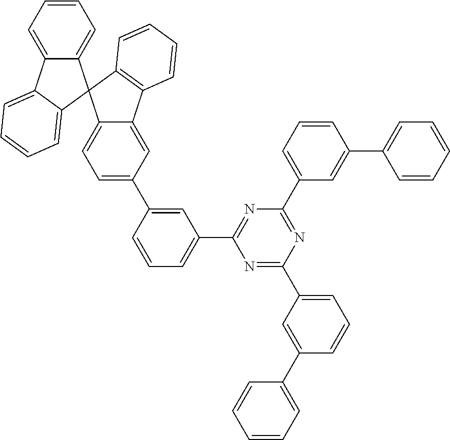 [SMILES: c1ccc(-c2cccc(-c3nc(-c4cccc(-c5ccccc5)c4)nc(-c4cccc(-c5ccc6c(c5)-c5ccccc5C65c6ccccc6-c6ccccc65)c4)n3)c2)cc1]

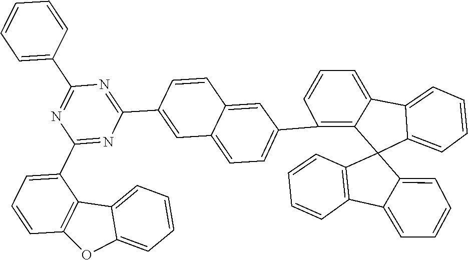 [SMILES: c1ccc(-c2nc(-c3ccc4cc(-c5cccc6c5C5(c7ccccc7-c7ccccc75)c5ccccc5-6)ccc4c3)nc(-c3cccc4oc5ccccc5c34)n2)cc1]

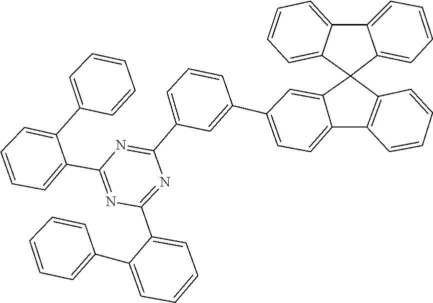 [SMILES: c1ccc(-c2ccccc2-c2nc(-c3cccc(-c4ccc5c(c4)C4(c6ccccc6-c6ccccc64)c4ccccc4-5)c3)nc(-c3ccccc3-c3ccccc3)n2)cc1]

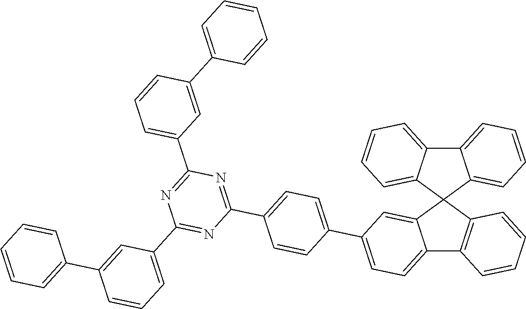 [SMILES: c1ccc(-c2cccc(-c3nc(-c4ccc(-c5ccc6c(c5)C5(c7ccccc7-c7ccccc75)c5ccccc5-6)cc4)nc(-c4cccc(-c5ccccc5)c4)n3)c2)cc1]

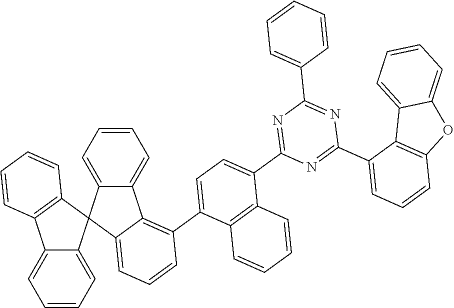 [SMILES: c1ccc(-c2nc(-c3ccc(-c4cccc5c4-c4ccccc4C54c5ccccc5-c5ccccc54)c4ccccc34)nc(-c3cccc4oc5ccccc5c34)n2)cc1]

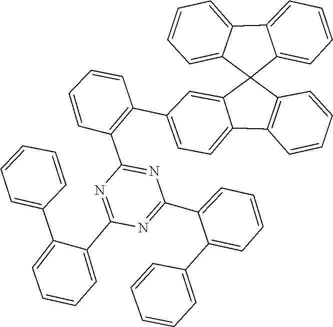 [SMILES: c1ccc(-c2ccccc2-c2nc(-c3ccccc3-c3ccccc3)nc(-c3ccccc3-c3ccc4c(c3)C3(c5ccccc5-c5ccccc53)c3ccccc3-4)n2)cc1]

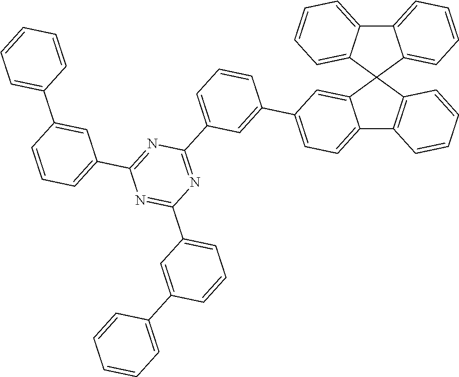 [SMILES: c1ccc(-c2cccc(-c3nc(-c4cccc(-c5ccccc5)c4)nc(-c4cccc(-c5ccc6c(c5)C5(c7ccccc7-c7ccccc75)c5ccccc5-6)c4)n3)c2)cc1]

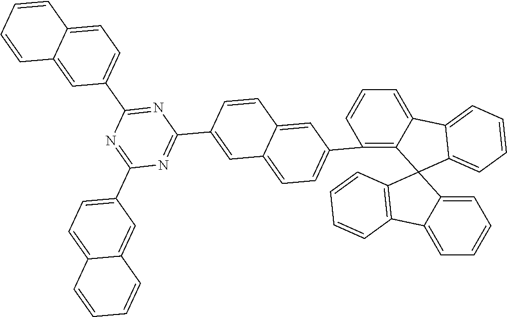 [SMILES: c1ccc2c(c1)-c1ccccc1C21c2ccccc2-c2cccc(-c3ccc4cc(-c5nc(-c6ccc7ccccc7c6)nc(-c6ccc7ccccc7c6)n5)ccc4c3)c21]

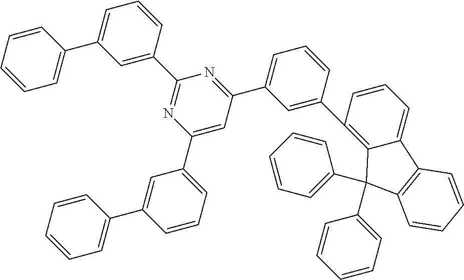 [SMILES: c1ccc(-c2cccc(-c3cc(-c4cccc(-c5cccc6c5C(c5ccccc5)(c5ccccc5)c5ccccc5-6)c4)nc(-c4cccc(-c5ccccc5)c4)n3)c2)cc1]

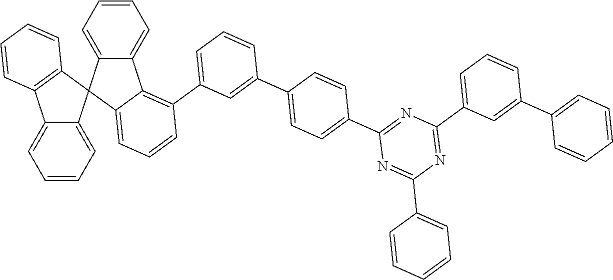 [SMILES: c1ccc(-c2cccc(-c3nc(-c4ccccc4)nc(-c4ccc(-c5cccc(-c6cccc7c6-c6ccccc6C76c7ccccc7-c7ccccc76)c5)cc4)n3)c2)cc1]

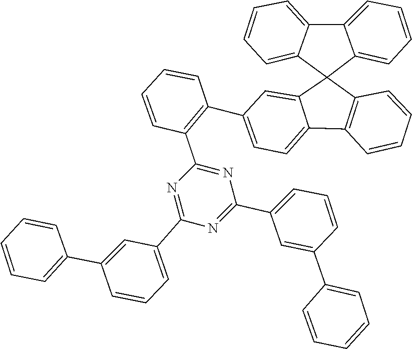 [SMILES: c1ccc(-c2cccc(-c3nc(-c4cccc(-c5ccccc5)c4)nc(-c4ccccc4-c4ccc5c(c4)C4(c6ccccc6-c6ccccc64)c4ccccc4-5)n3)c2)cc1]

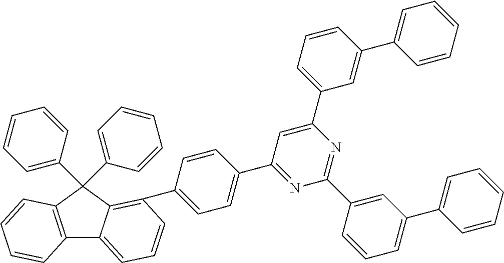 [SMILES: c1ccc(-c2cccc(-c3cc(-c4ccc(-c5cccc6c5C(c5ccccc5)(c5ccccc5)c5ccccc5-6)cc4)nc(-c4cccc(-c5ccccc5)c4)n3)c2)cc1]

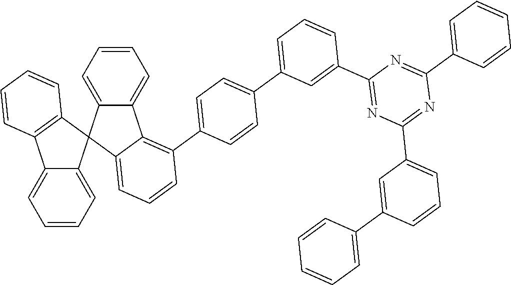 [SMILES: c1ccc(-c2cccc(-c3nc(-c4ccccc4)nc(-c4cccc(-c5ccc(-c6cccc7c6-c6ccccc6C76c7ccccc7-c7ccccc76)cc5)c4)n3)c2)cc1]

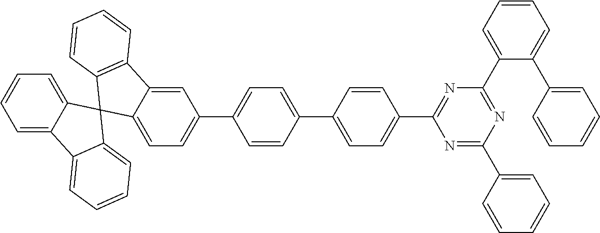 [SMILES: c1ccc(-c2nc(-c3ccc(-c4ccc(-c5ccc6c(c5)-c5ccccc5C65c6ccccc6-c6ccccc65)cc4)cc3)nc(-c3ccccc3-c3ccccc3)n2)cc1]

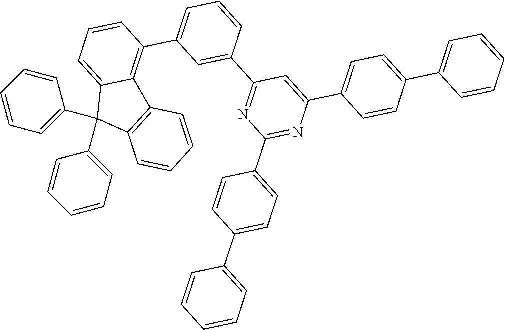 [SMILES: c1ccc(-c2ccc(-c3cc(-c4cccc(-c5cccc6c5-c5ccccc5C6(c5ccccc5)c5ccccc5)c4)nc(-c4ccc(-c5ccccc5)cc4)n3)cc2)cc1]

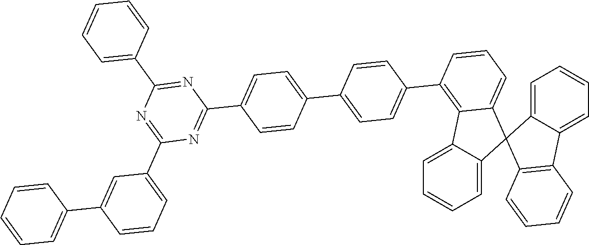 [SMILES: c1ccc(-c2cccc(-c3nc(-c4ccccc4)nc(-c4ccc(-c5ccc(-c6cccc7c6-c6ccccc6C76c7ccccc7-c7ccccc76)cc5)cc4)n3)c2)cc1]

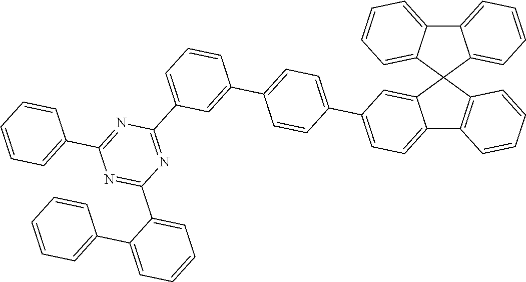 [SMILES: c1ccc(-c2nc(-c3cccc(-c4ccc(-c5ccc6c(c5)C5(c7ccccc7-c7ccccc75)c5ccccc5-6)cc4)c3)nc(-c3ccccc3-c3ccccc3)n2)cc1]

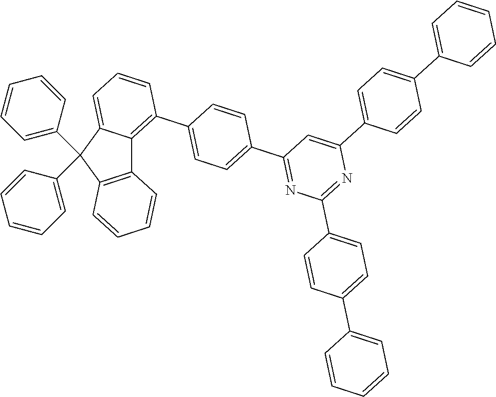 [SMILES: c1ccc(-c2ccc(-c3cc(-c4ccc(-c5cccc6c5-c5ccccc5C6(c5ccccc5)c5ccccc5)cc4)nc(-c4ccc(-c5ccccc5)cc4)n3)cc2)cc1]

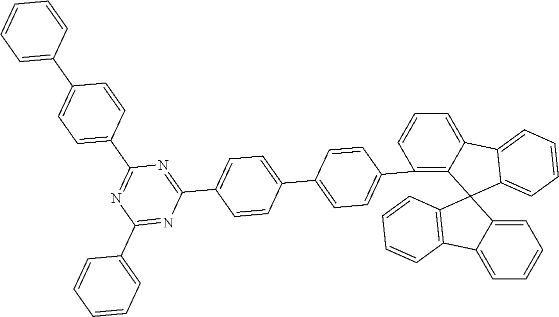 [SMILES: c1ccc(-c2ccc(-c3nc(-c4ccccc4)nc(-c4ccc(-c5ccc(-c6cccc7c6C6(c8ccccc8-c8ccccc86)c6ccccc6-7)cc5)cc4)n3)cc2)cc1]

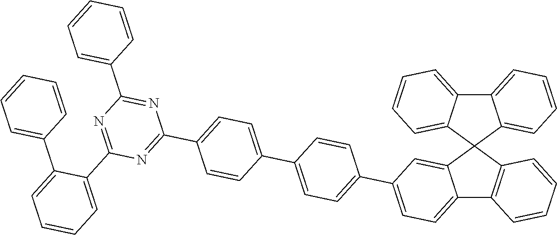 [SMILES: c1ccc(-c2nc(-c3ccc(-c4ccc(-c5ccc6c(c5)C5(c7ccccc7-c7ccccc75)c5ccccc5-6)cc4)cc3)nc(-c3ccccc3-c3ccccc3)n2)cc1]

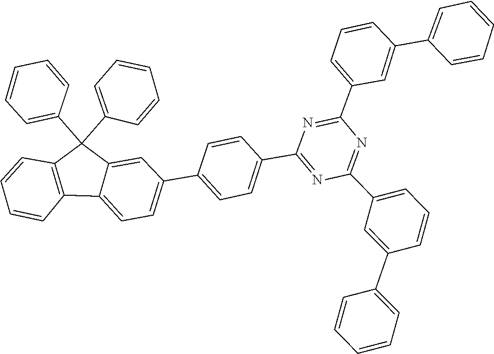 [SMILES: c1ccc(-c2cccc(-c3nc(-c4ccc(-c5ccc6c(c5)C(c5ccccc5)(c5ccccc5)c5ccccc5-6)cc4)nc(-c4cccc(-c5ccccc5)c4)n3)c2)cc1]

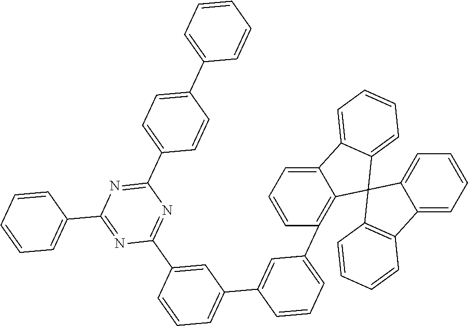 [SMILES: c1ccc(-c2ccc(-c3nc(-c4ccccc4)nc(-c4cccc(-c5cccc(-c6cccc7c6C6(c8ccccc8-c8ccccc86)c6ccccc6-7)c5)c4)n3)cc2)cc1]

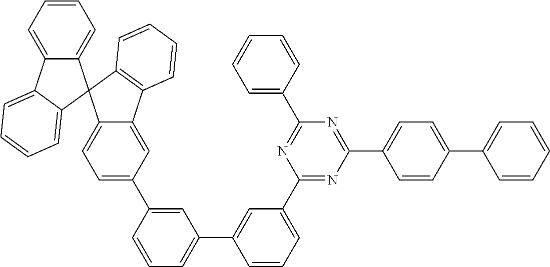 [SMILES: c1ccc(-c2ccc(-c3nc(-c4ccccc4)nc(-c4cccc(-c5cccc(-c6ccc7c(c6)-c6ccccc6C76c7ccccc7-c7ccccc76)c5)c4)n3)cc2)cc1]

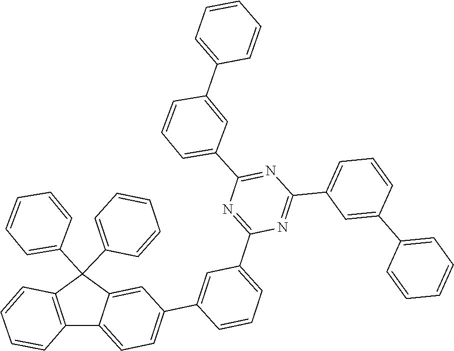 [SMILES: c1ccc(-c2cccc(-c3nc(-c4cccc(-c5ccccc5)c4)nc(-c4cccc(-c5ccc6c(c5)C(c5ccccc5)(c5ccccc5)c5ccccc5-6)c4)n3)c2)cc1]

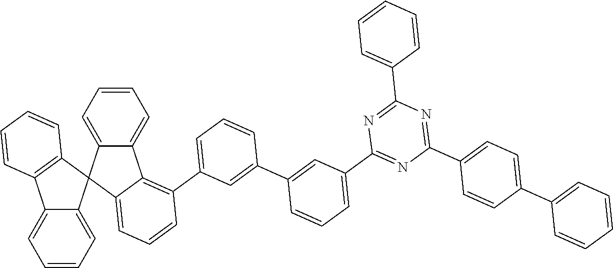 [SMILES: c1ccc(-c2ccc(-c3nc(-c4ccccc4)nc(-c4cccc(-c5cccc(-c6cccc7c6-c6ccccc6C76c7ccccc7-c7ccccc76)c5)c4)n3)cc2)cc1]

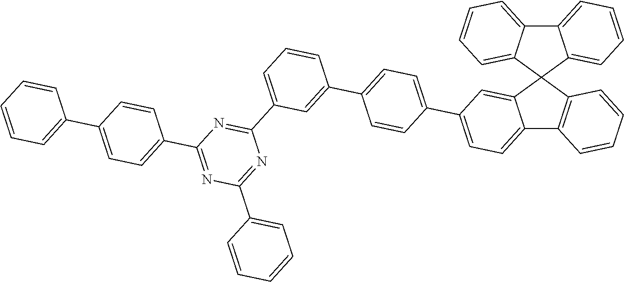 [SMILES: c1ccc(-c2ccc(-c3nc(-c4ccccc4)nc(-c4cccc(-c5ccc(-c6ccc7c(c6)C6(c8ccccc8-c8ccccc86)c6ccccc6-7)cc5)c4)n3)cc2)cc1]

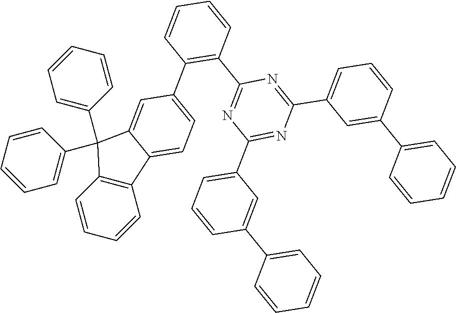 [SMILES: c1ccc(-c2cccc(-c3nc(-c4cccc(-c5ccccc5)c4)nc(-c4ccccc4-c4ccc5c(c4)C(c4ccccc4)(c4ccccc4)c4ccccc4-5)n3)c2)cc1]

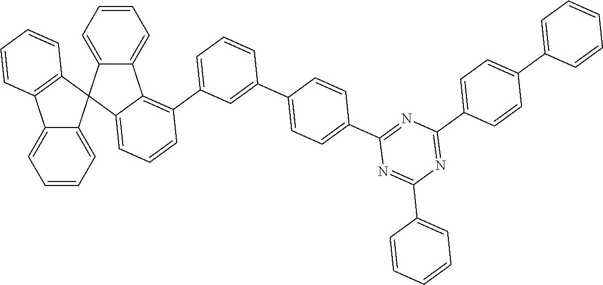 [SMILES: c1ccc(-c2ccc(-c3nc(-c4ccccc4)nc(-c4ccc(-c5cccc(-c6cccc7c6-c6ccccc6C76c7ccccc7-c7ccccc76)c5)cc4)n3)cc2)cc1]

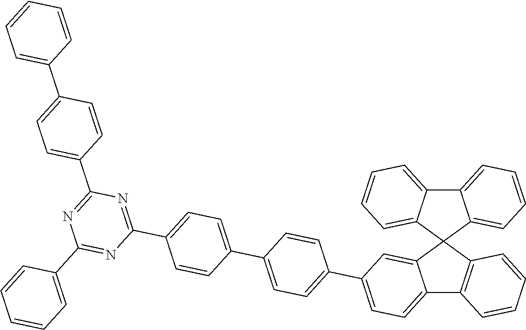 [SMILES: c1ccc(-c2ccc(-c3nc(-c4ccccc4)nc(-c4ccc(-c5ccc(-c6ccc7c(c6)C6(c8ccccc8-c8ccccc86)c6ccccc6-7)cc5)cc4)n3)cc2)cc1]

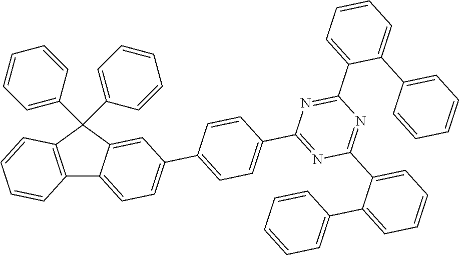 [SMILES: c1ccc(-c2ccccc2-c2nc(-c3ccc(-c4ccc5c(c4)C(c4ccccc4)(c4ccccc4)c4ccccc4-5)cc3)nc(-c3ccccc3-c3ccccc3)n2)cc1]

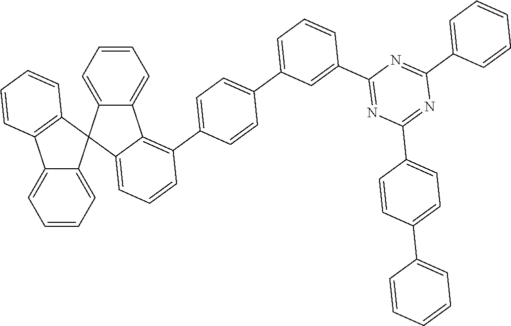 [SMILES: c1ccc(-c2ccc(-c3nc(-c4ccccc4)nc(-c4cccc(-c5ccc(-c6cccc7c6-c6ccccc6C76c7ccccc7-c7ccccc76)cc5)c4)n3)cc2)cc1]

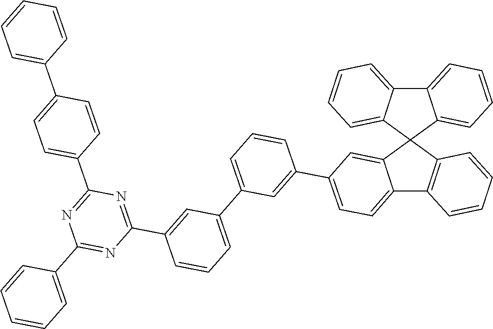 [SMILES: c1ccc(-c2ccc(-c3nc(-c4ccccc4)nc(-c4cccc(-c5cccc(-c6ccc7c(c6)C6(c8ccccc8-c8ccccc86)c6ccccc6-7)c5)c4)n3)cc2)cc1]

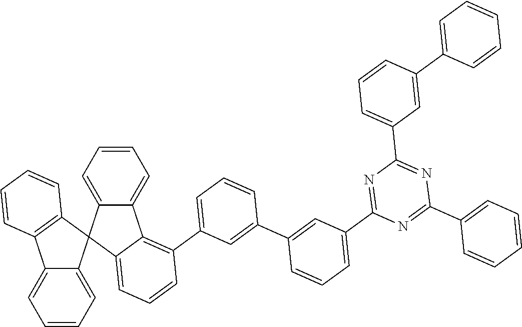 [SMILES: c1ccc(-c2cccc(-c3nc(-c4ccccc4)nc(-c4cccc(-c5cccc(-c6cccc7c6-c6ccccc6C76c7ccccc7-c7ccccc76)c5)c4)n3)c2)cc1]

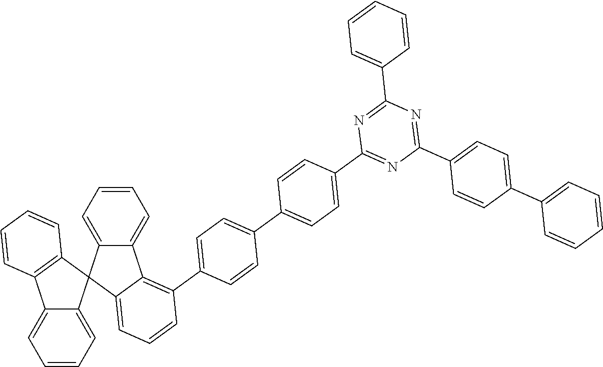 [SMILES: c1ccc(-c2ccc(-c3nc(-c4ccccc4)nc(-c4ccc(-c5ccc(-c6cccc7c6-c6ccccc6C76c7ccccc7-c7ccccc76)cc5)cc4)n3)cc2)cc1]

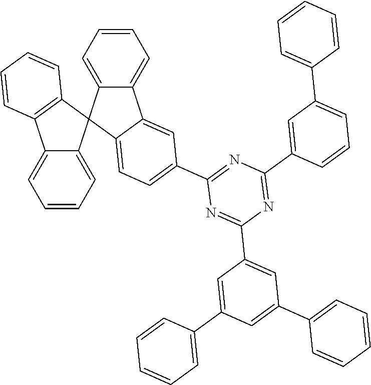 [SMILES: c1ccc(-c2cccc(-c3nc(-c4cc(-c5ccccc5)cc(-c5ccccc5)c4)nc(-c4ccc5c(c4)-c4ccccc4C54c5ccccc5-c5ccccc54)n3)c2)cc1]

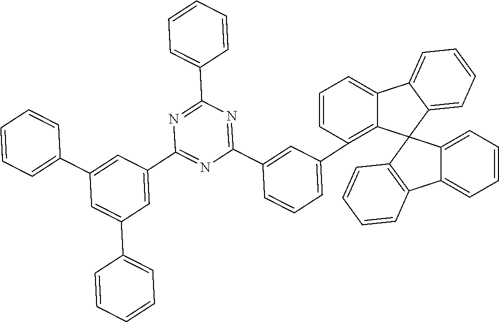 [SMILES: c1ccc(-c2cc(-c3ccccc3)cc(-c3nc(-c4ccccc4)nc(-c4cccc(-c5cccc6c5C5(c7ccccc7-c7ccccc75)c5ccccc5-6)c4)n3)c2)cc1]

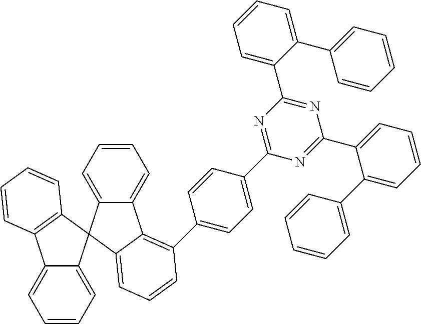 [SMILES: c1ccc(-c2ccccc2-c2nc(-c3ccc(-c4cccc5c4-c4ccccc4C54c5ccccc5-c5ccccc54)cc3)nc(-c3ccccc3-c3ccccc3)n2)cc1]

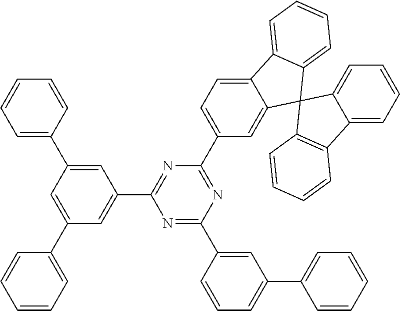 [SMILES: c1ccc(-c2cccc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

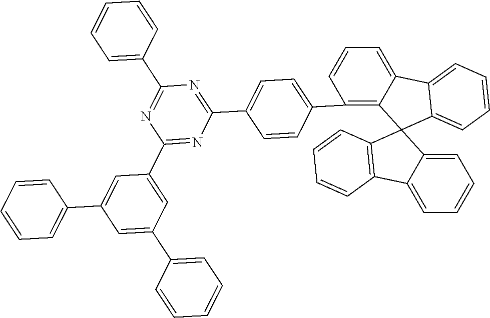 [SMILES: c1ccc(-c2cc(-c3ccccc3)cc(-c3nc(-c4ccccc4)nc(-c4ccc(-c5cccc6c5C5(c7ccccc7-c7ccccc75)c5ccccc5-6)cc4)n3)c2)cc1]

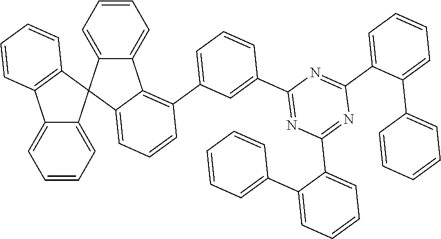 [SMILES: c1ccc(-c2ccccc2-c2nc(-c3cccc(-c4cccc5c4-c4ccccc4C54c5ccccc5-c5ccccc54)c3)nc(-c3ccccc3-c3ccccc3)n2)cc1]

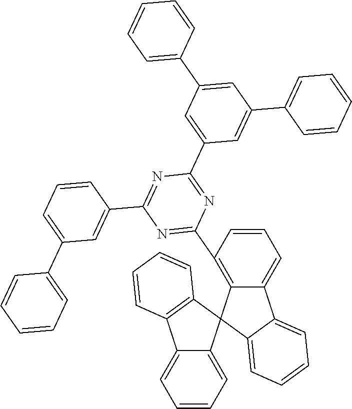 [SMILES: c1ccc(-c2cccc(-c3nc(-c4cc(-c5ccccc5)cc(-c5ccccc5)c4)nc(-c4cccc5c4C4(c6ccccc6-c6ccccc64)c4ccccc4-5)n3)c2)cc1]

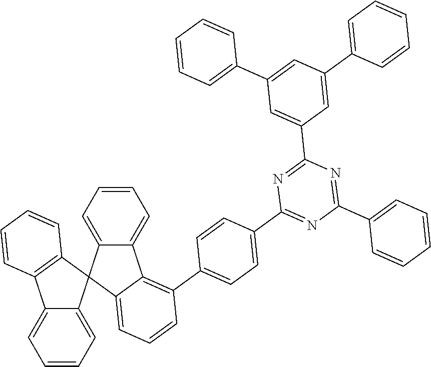 [SMILES: c1ccc(-c2cc(-c3ccccc3)cc(-c3nc(-c4ccccc4)nc(-c4ccc(-c5cccc6c5-c5ccccc5C65c6ccccc6-c6ccccc65)cc4)n3)c2)cc1]

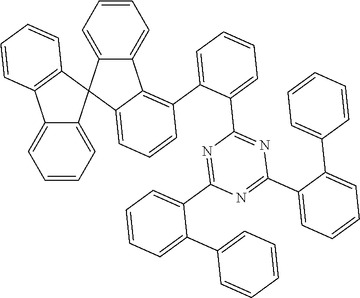 [SMILES: c1ccc(-c2ccccc2-c2nc(-c3ccccc3-c3ccccc3)nc(-c3ccccc3-c3cccc4c3-c3ccccc3C43c4ccccc4-c4ccccc43)n2)cc1]

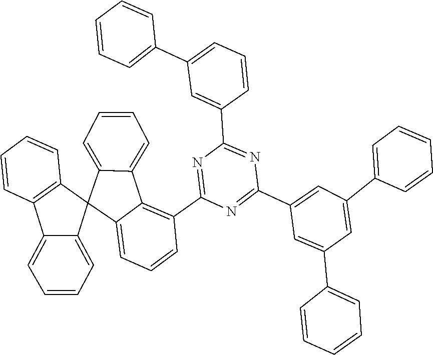 [SMILES: c1ccc(-c2cccc(-c3nc(-c4cc(-c5ccccc5)cc(-c5ccccc5)c4)nc(-c4cccc5c4-c4ccccc4C54c5ccccc5-c5ccccc54)n3)c2)cc1]

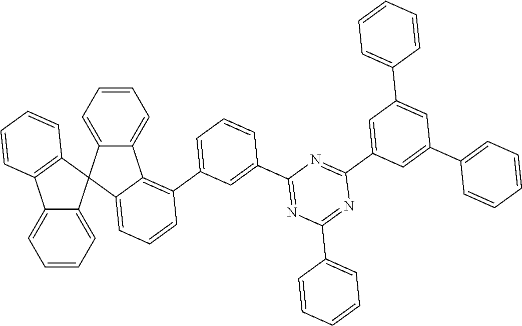 [SMILES: c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1]

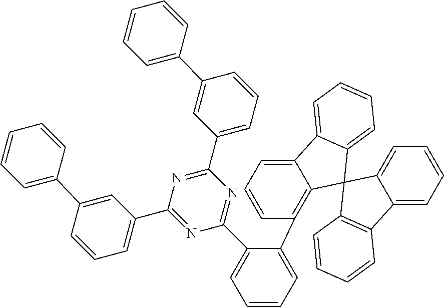 [SMILES: c1ccc(-c2cccc(-c3nc(-c4cccc(-c5ccccc5)c4)nc(-c4ccccc4-c4cccc5c4C4(c6ccccc6-c6ccccc64)c4ccccc4-5)n3)c2)cc1]

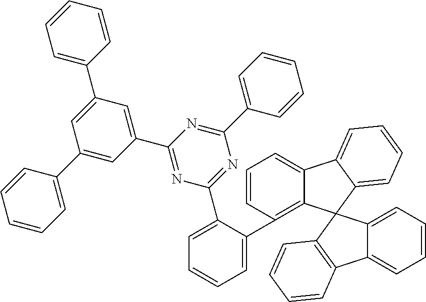 [SMILES: c1ccc(-c2cc(-c3ccccc3)cc(-c3nc(-c4ccccc4)nc(-c4ccccc4-c4cccc5c4C4(c6ccccc6-c6ccccc64)c4ccccc4-5)n3)c2)cc1]

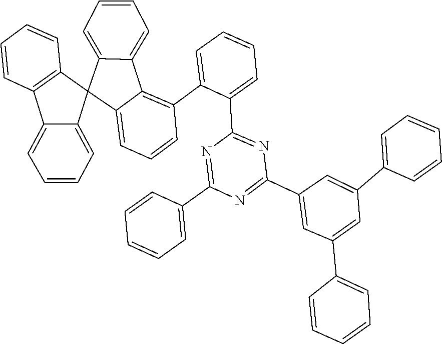 [SMILES: c1ccc(-c2cc(-c3ccccc3)cc(-c3nc(-c4ccccc4)nc(-c4ccccc4-c4cccc5c4-c4ccccc4C54c5ccccc5-c5ccccc54)n3)c2)cc1]

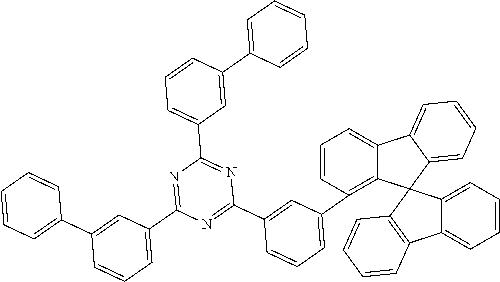 [SMILES: c1ccc(-c2cccc(-c3nc(-c4cccc(-c5ccccc5)c4)nc(-c4cccc(-c5cccc6c5C5(c7ccccc7-c7ccccc75)c5ccccc5-6)c4)n3)c2)cc1]

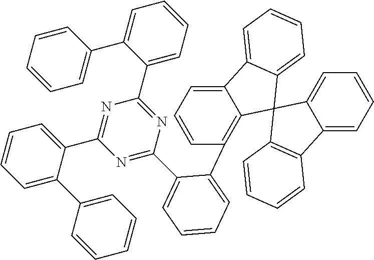 [SMILES: c1ccc(-c2ccccc2-c2nc(-c3ccccc3-c3ccccc3)nc(-c3ccccc3-c3cccc4c3C3(c5ccccc5-c5ccccc53)c3ccccc3-4)n2)cc1]

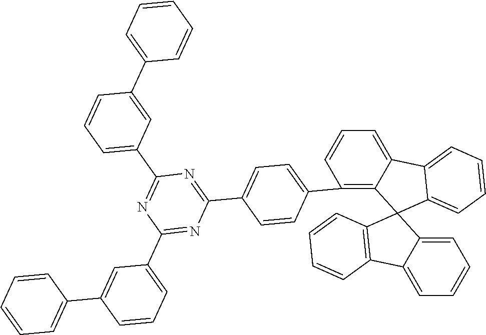 [SMILES: c1ccc(-c2cccc(-c3nc(-c4ccc(-c5cccc6c5C5(c7ccccc7-c7ccccc75)c5ccccc5-6)cc4)nc(-c4cccc(-c5ccccc5)c4)n3)c2)cc1]

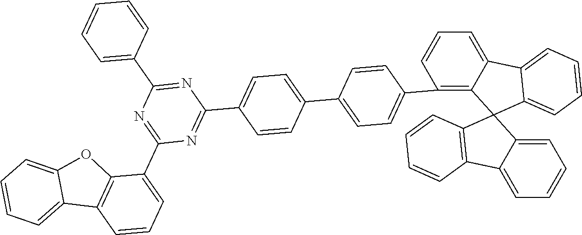 [SMILES: c1ccc(-c2nc(-c3ccc(-c4ccc(-c5cccc6c5C5(c7ccccc7-c7ccccc75)c5ccccc5-6)cc4)cc3)nc(-c3cccc4c3oc3ccccc34)n2)cc1]

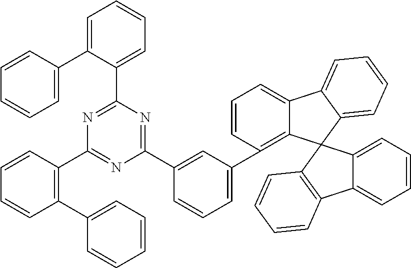 [SMILES: c1ccc(-c2ccccc2-c2nc(-c3cccc(-c4cccc5c4C4(c6ccccc6-c6ccccc64)c4ccccc4-5)c3)nc(-c3ccccc3-c3ccccc3)n2)cc1]

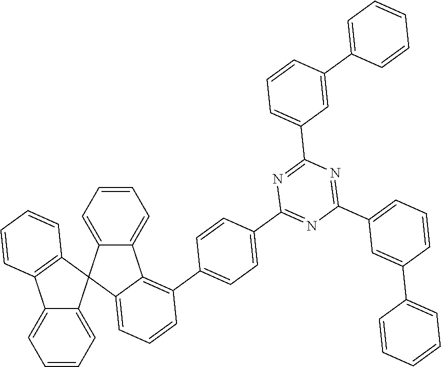 [SMILES: c1ccc(-c2cccc(-c3nc(-c4ccc(-c5cccc6c5-c5ccccc5C65c6ccccc6-c6ccccc65)cc4)nc(-c4cccc(-c5ccccc5)c4)n3)c2)cc1]

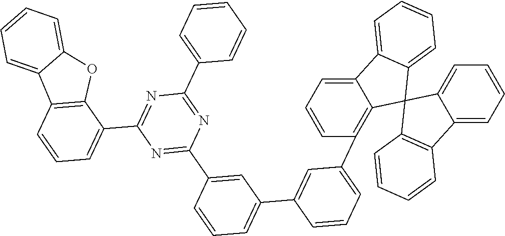 [SMILES: c1ccc(-c2nc(-c3cccc(-c4cccc(-c5cccc6c5C5(c7ccccc7-c7ccccc75)c5ccccc5-6)c4)c3)nc(-c3cccc4c3oc3ccccc34)n2)cc1]

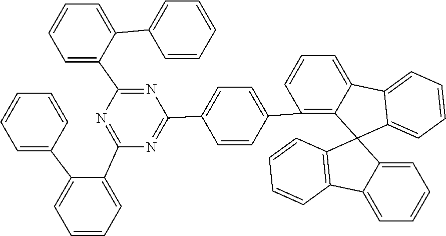 [SMILES: c1ccc(-c2ccccc2-c2nc(-c3ccc(-c4cccc5c4C4(c6ccccc6-c6ccccc64)c4ccccc4-5)cc3)nc(-c3ccccc3-c3ccccc3)n2)cc1]

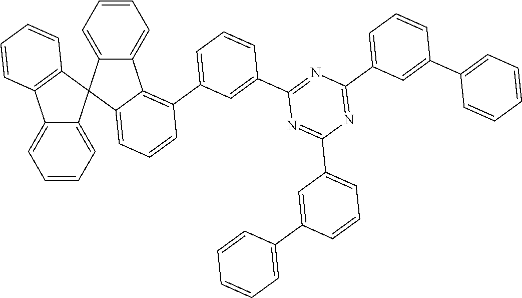 [SMILES: c1ccc(-c2cccc(-c3nc(-c4cccc(-c5ccccc5)c4)nc(-c4cccc(-c5cccc6c5-c5ccccc5C65c6ccccc6-c6ccccc65)c4)n3)c2)cc1]

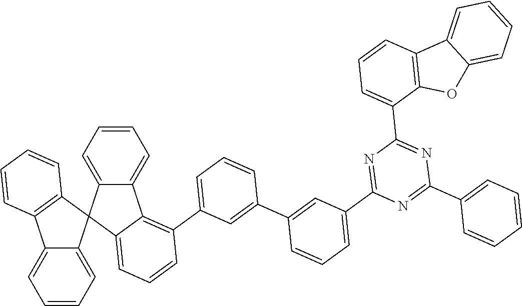 [SMILES: c1ccc(-c2nc(-c3cccc(-c4cccc(-c5cccc6c5-c5ccccc5C65c6ccccc6-c6ccccc65)c4)c3)nc(-c3cccc4c3oc3ccccc34)n2)cc1]

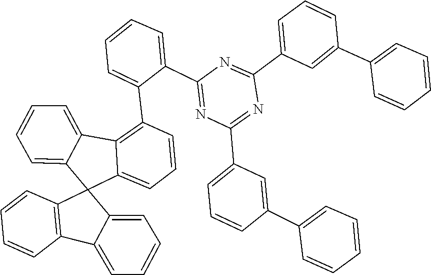 [SMILES: c1ccc(-c2cccc(-c3nc(-c4cccc(-c5ccccc5)c4)nc(-c4ccccc4-c4cccc5c4-c4ccccc4C54c5ccccc5-c5ccccc54)n3)c2)cc1]

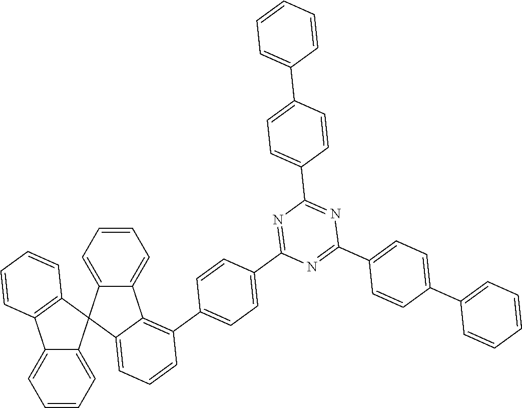 [SMILES: c1ccc(-c2ccc(-c3nc(-c4ccc(-c5ccccc5)cc4)nc(-c4ccc(-c5cccc6c5-c5ccccc5C65c6ccccc6-c6ccccc65)cc4)n3)cc2)cc1]

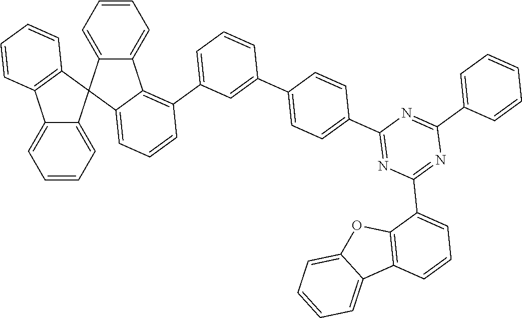 [SMILES: c1ccc(-c2nc(-c3ccc(-c4cccc(-c5cccc6c5-c5ccccc5C65c6ccccc6-c6ccccc65)c4)cc3)nc(-c3cccc4c3oc3ccccc34)n2)cc1]

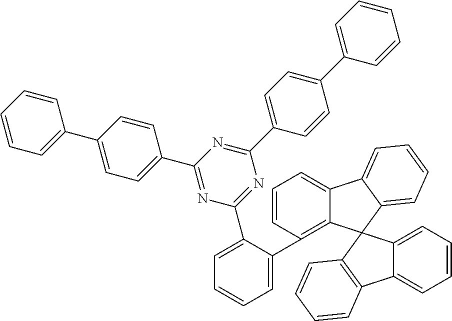 [SMILES: c1ccc(-c2ccc(-c3nc(-c4ccc(-c5ccccc5)cc4)nc(-c4ccccc4-c4cccc5c4C4(c6ccccc6-c6ccccc64)c4ccccc4-5)n3)cc2)cc1]

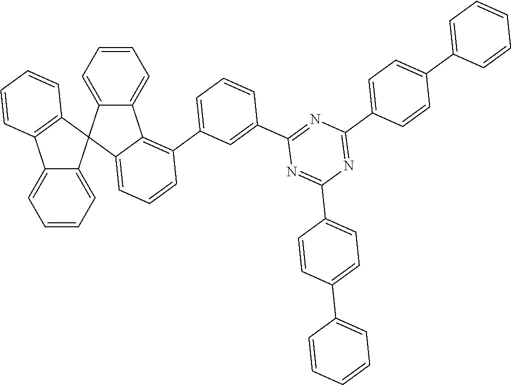 [SMILES: c1ccc(-c2ccc(-c3nc(-c4ccc(-c5ccccc5)cc4)nc(-c4cccc(-c5cccc6c5-c5ccccc5C65c6ccccc6-c6ccccc65)c4)n3)cc2)cc1]

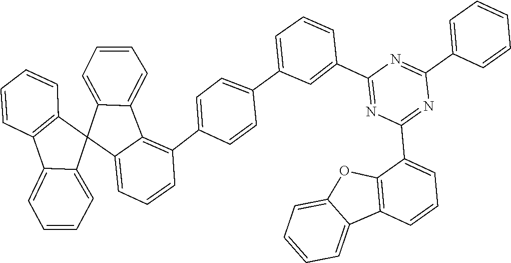 [SMILES: c1ccc(-c2nc(-c3cccc(-c4ccc(-c5cccc6c5-c5ccccc5C65c6ccccc6-c6ccccc65)cc4)c3)nc(-c3cccc4c3oc3ccccc34)n2)cc1]

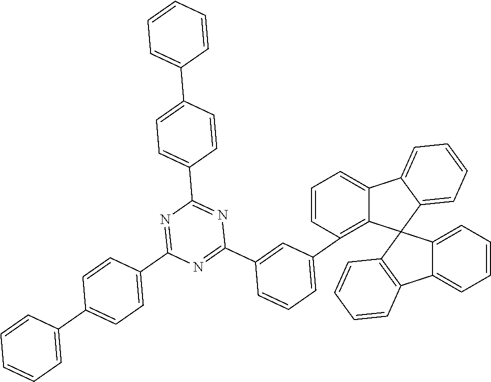 [SMILES: c1ccc(-c2ccc(-c3nc(-c4ccc(-c5ccccc5)cc4)nc(-c4cccc(-c5cccc6c5C5(c7ccccc7-c7ccccc75)c5ccccc5-6)c4)n3)cc2)cc1]

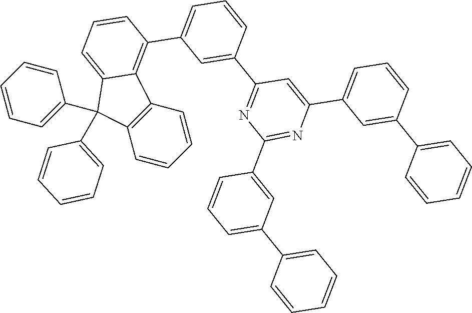 [SMILES: c1ccc(-c2cccc(-c3cc(-c4cccc(-c5cccc6c5-c5ccccc5C6(c5ccccc5)c5ccccc5)c4)nc(-c4cccc(-c5ccccc5)c4)n3)c2)cc1]

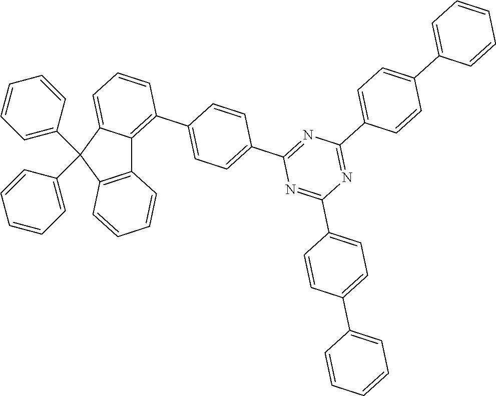 [SMILES: c1ccc(-c2ccc(-c3nc(-c4ccc(-c5ccccc5)cc4)nc(-c4ccc(-c5cccc6c5-c5ccccc5C6(c5ccccc5)c5ccccc5)cc4)n3)cc2)cc1]

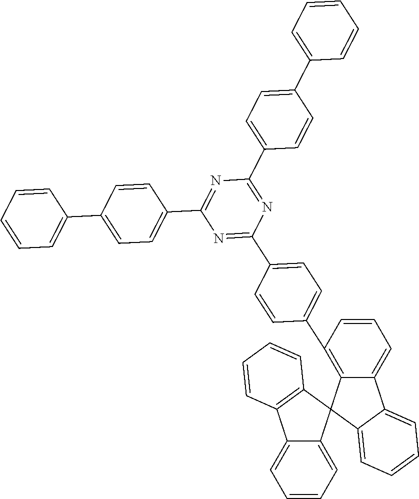 [SMILES: c1ccc(-c2ccc(-c3nc(-c4ccc(-c5ccccc5)cc4)nc(-c4ccc(-c5cccc6c5C5(c7ccccc7-c7ccccc75)c5ccccc5-6)cc4)n3)cc2)cc1]

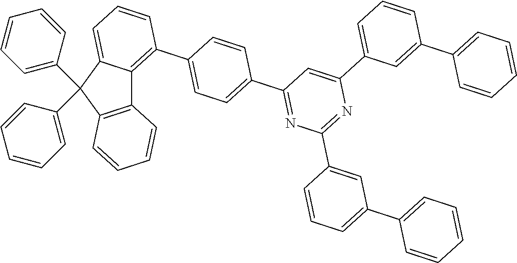 [SMILES: c1ccc(-c2cccc(-c3cc(-c4ccc(-c5cccc6c5-c5ccccc5C6(c5ccccc5)c5ccccc5)cc4)nc(-c4cccc(-c5ccccc5)c4)n3)c2)cc1]

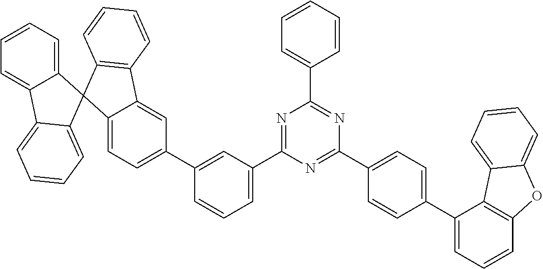 [SMILES: c1ccc(-c2nc(-c3ccc(-c4cccc5oc6ccccc6c45)cc3)nc(-c3cccc(-c4ccc5c(c4)-c4ccccc4C54c5ccccc5-c5ccccc54)c3)n2)cc1]

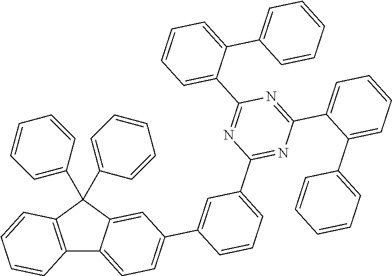 [SMILES: c1ccc(-c2ccccc2-c2nc(-c3cccc(-c4ccc5c(c4)C(c4ccccc4)(c4ccccc4)c4ccccc4-5)c3)nc(-c3ccccc3-c3ccccc3)n2)cc1]

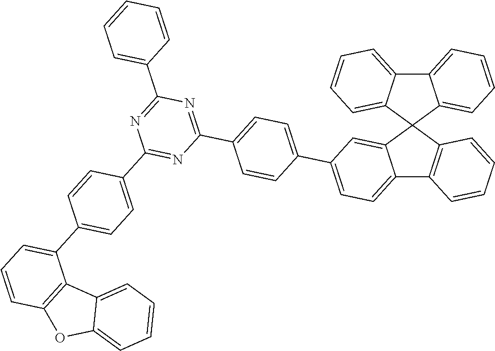 [SMILES: c1ccc(-c2nc(-c3ccc(-c4ccc5c(c4)C4(c6ccccc6-c6ccccc64)c4ccccc4-5)cc3)nc(-c3ccc(-c4cccc5oc6ccccc6c45)cc3)n2)cc1]

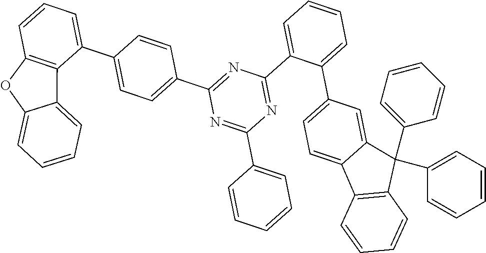 [SMILES: c1ccc(-c2nc(-c3ccc(-c4cccc5oc6ccccc6c45)cc3)nc(-c3ccccc3-c3ccc4c(c3)C(c3ccccc3)(c3ccccc3)c3ccccc3-4)n2)cc1]

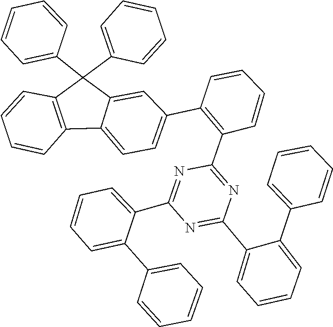 [SMILES: c1ccc(-c2ccccc2-c2nc(-c3ccccc3-c3ccccc3)nc(-c3ccccc3-c3ccc4c(c3)C(c3ccccc3)(c3ccccc3)c3ccccc3-4)n2)cc1]

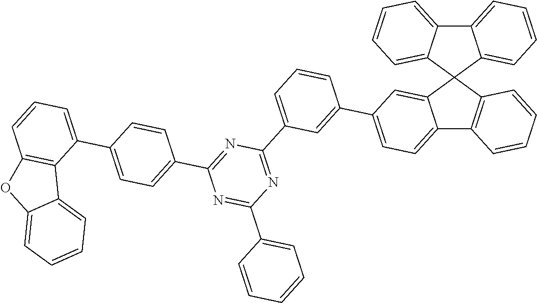 [SMILES: c1ccc(-c2nc(-c3ccc(-c4cccc5oc6ccccc6c45)cc3)nc(-c3cccc(-c4ccc5c(c4)C4(c6ccccc6-c6ccccc64)c4ccccc4-5)c3)n2)cc1]

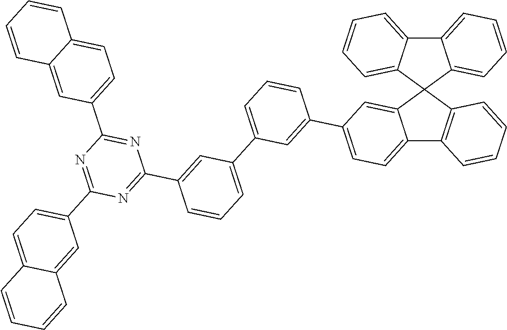 [SMILES: c1cc(-c2cccc(-c3nc(-c4ccc5ccccc5c4)nc(-c4ccc5ccccc5c4)n3)c2)cc(-c2ccc3c(c2)C2(c4ccccc4-c4ccccc42)c2ccccc2-3)c1]

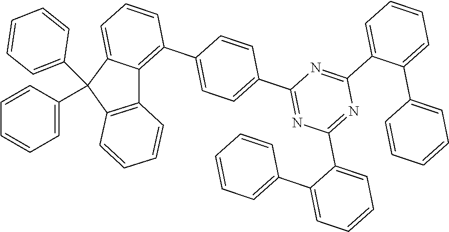 [SMILES: c1ccc(-c2ccccc2-c2nc(-c3ccc(-c4cccc5c4-c4ccccc4C5(c4ccccc4)c4ccccc4)cc3)nc(-c3ccccc3-c3ccccc3)n2)cc1]

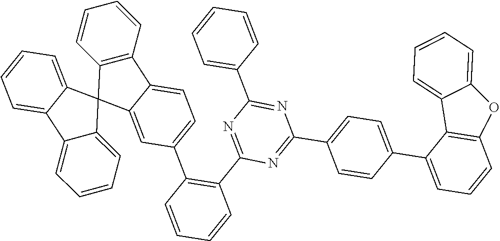 [SMILES: c1ccc(-c2nc(-c3ccc(-c4cccc5oc6ccccc6c45)cc3)nc(-c3ccccc3-c3ccc4c(c3)C3(c5ccccc5-c5ccccc53)c3ccccc3-4)n2)cc1]

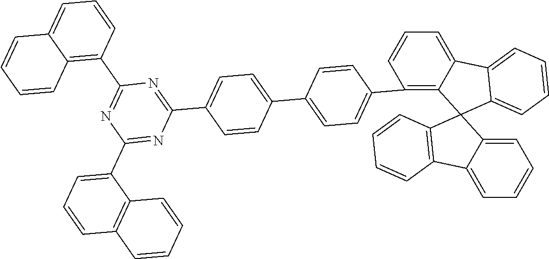 [SMILES: c1ccc2c(c1)-c1ccccc1C21c2ccccc2-c2cccc(-c3ccc(-c4ccc(-c5nc(-c6cccc7ccccc67)nc(-c6cccc7ccccc67)n5)cc4)cc3)c21]

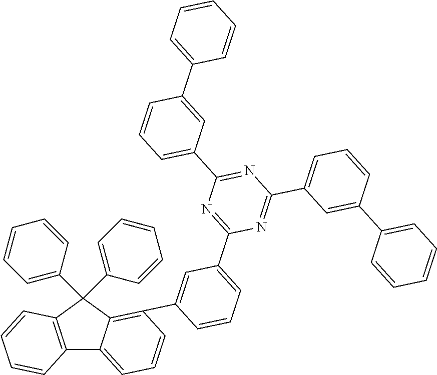 [SMILES: c1ccc(-c2cccc(-c3nc(-c4cccc(-c5ccccc5)c4)nc(-c4cccc(-c5cccc6c5C(c5ccccc5)(c5ccccc5)c5ccccc5-6)c4)n3)c2)cc1]

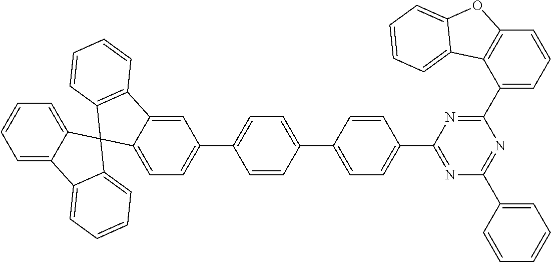 [SMILES: c1ccc(-c2nc(-c3ccc(-c4ccc(-c5ccc6c(c5)-c5ccccc5C65c6ccccc6-c6ccccc65)cc4)cc3)nc(-c3cccc4oc5ccccc5c34)n2)cc1]

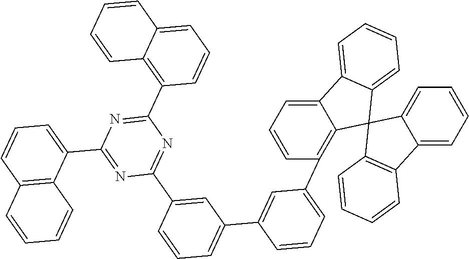 [SMILES: c1cc(-c2cccc(-c3cccc4c3C3(c5ccccc5-c5ccccc53)c3ccccc3-4)c2)cc(-c2nc(-c3cccc4ccccc34)nc(-c3cccc4ccccc34)n2)c1]

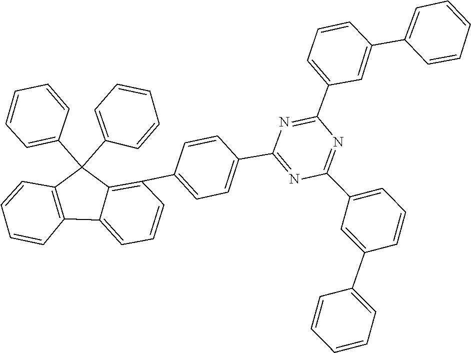 [SMILES: c1ccc(-c2cccc(-c3nc(-c4ccc(-c5cccc6c5C(c5ccccc5)(c5ccccc5)c5ccccc5-6)cc4)nc(-c4cccc(-c5ccccc5)c4)n3)c2)cc1]

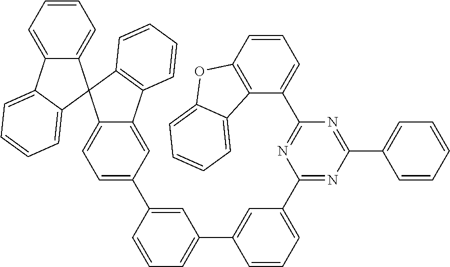 [SMILES: c1ccc(-c2nc(-c3cccc(-c4cccc(-c5ccc6c(c5)-c5ccccc5C65c6ccccc6-c6ccccc65)c4)c3)nc(-c3cccc4oc5ccccc5c34)n2)cc1]

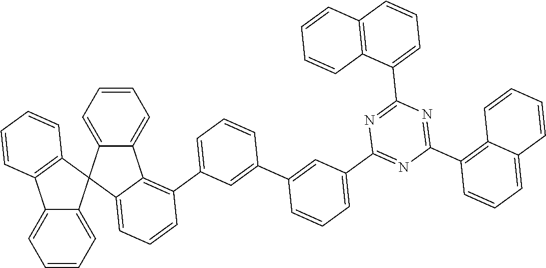 [SMILES: c1cc(-c2cccc(-c3cccc4c3-c3ccccc3C43c4ccccc4-c4ccccc43)c2)cc(-c2nc(-c3cccc4ccccc34)nc(-c3cccc4ccccc34)n2)c1]

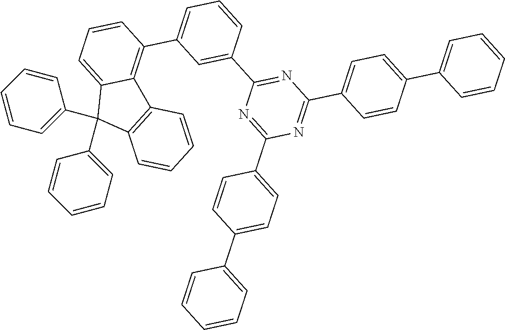 [SMILES: c1ccc(-c2ccc(-c3nc(-c4ccc(-c5ccccc5)cc4)nc(-c4cccc(-c5cccc6c5-c5ccccc5C6(c5ccccc5)c5ccccc5)c4)n3)cc2)cc1]

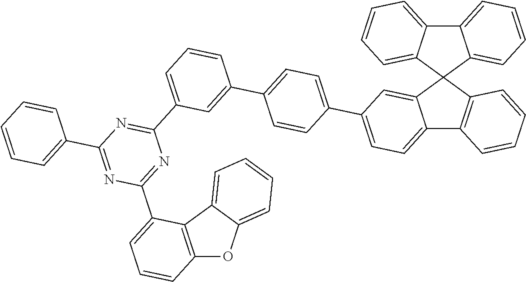 [SMILES: c1ccc(-c2nc(-c3cccc(-c4ccc(-c5ccc6c(c5)C5(c7ccccc7-c7ccccc75)c5ccccc5-6)cc4)c3)nc(-c3cccc4oc5ccccc5c34)n2)cc1]

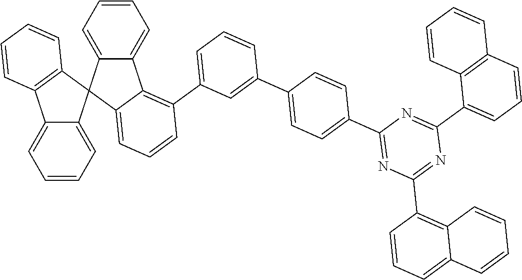 [SMILES: c1cc(-c2ccc(-c3nc(-c4cccc5ccccc45)nc(-c4cccc5ccccc45)n3)cc2)cc(-c2cccc3c2-c2ccccc2C32c3ccccc3-c3ccccc32)c1]

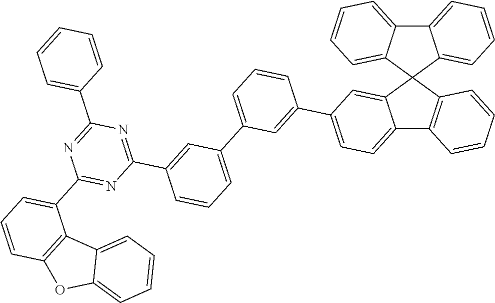 [SMILES: c1ccc(-c2nc(-c3cccc(-c4cccc(-c5ccc6c(c5)C5(c7ccccc7-c7ccccc75)c5ccccc5-6)c4)c3)nc(-c3cccc4oc5ccccc5c34)n2)cc1]

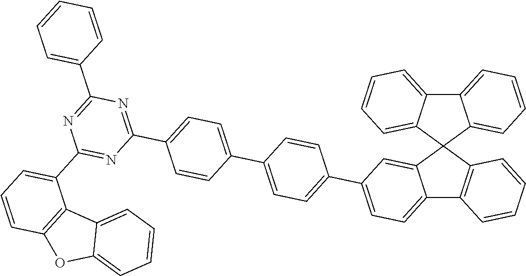 [SMILES: c1ccc(-c2nc(-c3ccc(-c4ccc(-c5ccc6c(c5)C5(c7ccccc7-c7ccccc75)c5ccccc5-6)cc4)cc3)nc(-c3cccc4oc5ccccc5c34)n2)cc1]

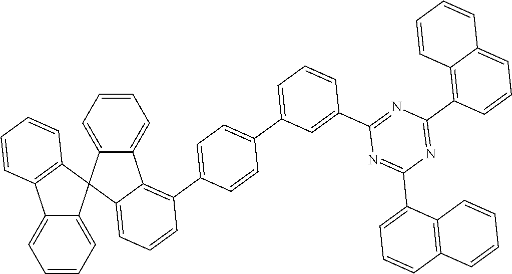 [SMILES: c1cc(-c2ccc(-c3cccc4c3-c3ccccc3C43c4ccccc4-c4ccccc43)cc2)cc(-c2nc(-c3cccc4ccccc34)nc(-c3cccc4ccccc34)n2)c1]

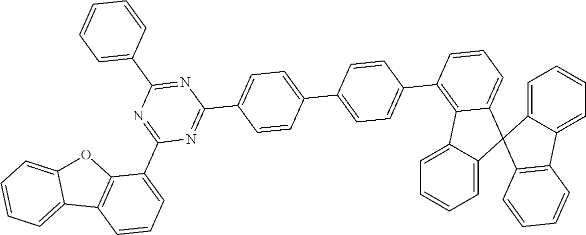 [SMILES: c1ccc(-c2nc(-c3ccc(-c4ccc(-c5cccc6c5-c5ccccc5C65c6ccccc6-c6ccccc65)cc4)cc3)nc(-c3cccc4c3oc3ccccc34)n2)cc1]

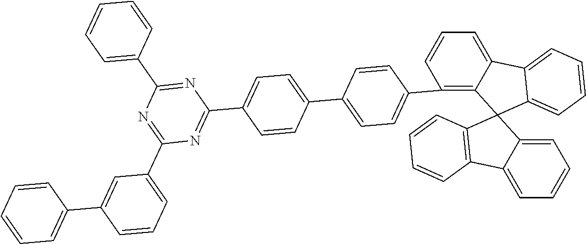 [SMILES: c1ccc(-c2cccc(-c3nc(-c4ccccc4)nc(-c4ccc(-c5ccc(-c6cccc7c6C6(c8ccccc8-c8ccccc86)c6ccccc6-7)cc5)cc4)n3)c2)cc1]

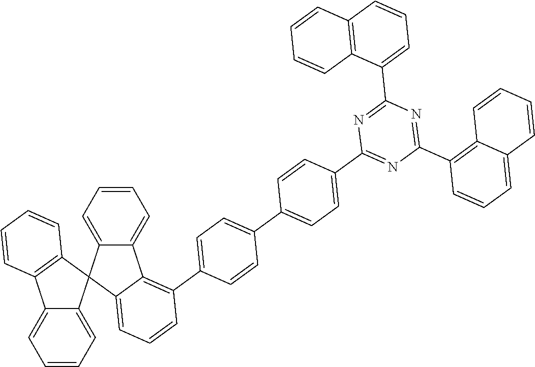 [SMILES: c1ccc2c(c1)-c1ccccc1C21c2ccccc2-c2c(-c3ccc(-c4ccc(-c5nc(-c6cccc7ccccc67)nc(-c6cccc7ccccc67)n5)cc4)cc3)cccc21]

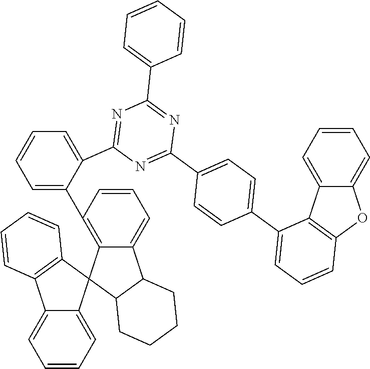 [SMILES: c1ccc(-c2nc(-c3ccc(-c4cccc5oc6ccccc6c45)cc3)nc(-c3ccccc3-c3cccc4c3C3(c5ccccc5-c5ccccc53)C3CCCCC43)n2)cc1]

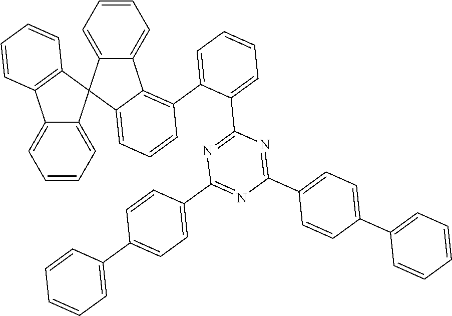 [SMILES: c1ccc(-c2ccc(-c3nc(-c4ccc(-c5ccccc5)cc4)nc(-c4ccccc4-c4cccc5c4-c4ccccc4C54c5ccccc5-c5ccccc54)n3)cc2)cc1]

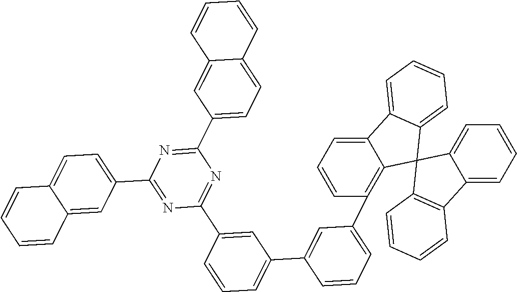 [SMILES: c1cc(-c2cccc(-c3cccc4c3C3(c5ccccc5-c5ccccc53)c3ccccc3-4)c2)cc(-c2nc(-c3ccc4ccccc4c3)nc(-c3ccc4ccccc4c3)n2)c1]

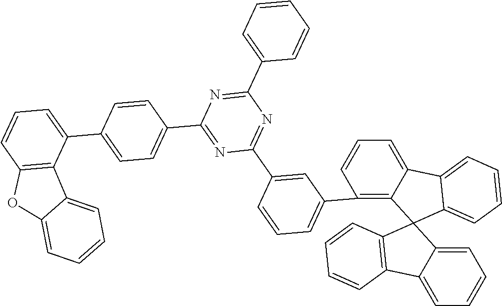 [SMILES: c1ccc(-c2nc(-c3ccc(-c4cccc5oc6ccccc6c45)cc3)nc(-c3cccc(-c4cccc5c4C4(c6ccccc6-c6ccccc64)c4ccccc4-5)c3)n2)cc1]

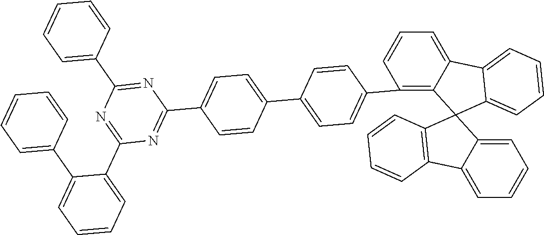 [SMILES: c1ccc(-c2nc(-c3ccc(-c4ccc(-c5cccc6c5C5(c7ccccc7-c7ccccc75)c5ccccc5-6)cc4)cc3)nc(-c3ccccc3-c3ccccc3)n2)cc1]

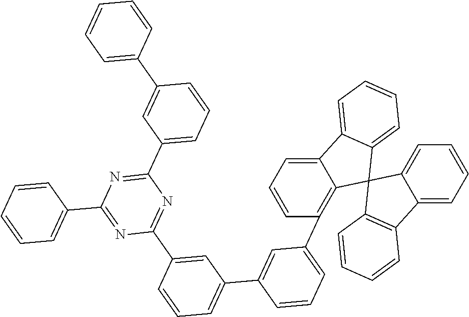 [SMILES: c1ccc(-c2cccc(-c3nc(-c4ccccc4)nc(-c4cccc(-c5cccc(-c6cccc7c6C6(c8ccccc8-c8ccccc86)c6ccccc6-7)c5)c4)n3)c2)cc1]

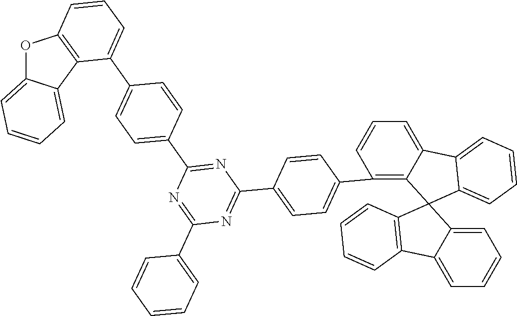 [SMILES: c1ccc(-c2nc(-c3ccc(-c4cccc5c4C4(c6ccccc6-c6ccccc64)c4ccccc4-5)cc3)nc(-c3ccc(-c4cccc5oc6ccccc6c45)cc3)n2)cc1]

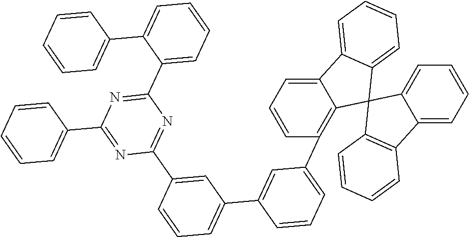 [SMILES: c1ccc(-c2nc(-c3cccc(-c4cccc(-c5cccc6c5C5(c7ccccc7-c7ccccc75)c5ccccc5-6)c4)c3)nc(-c3ccccc3-c3ccccc3)n2)cc1]

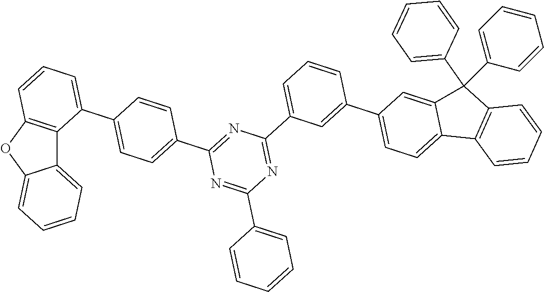 [SMILES: c1ccc(-c2nc(-c3ccc(-c4cccc5oc6ccccc6c45)cc3)nc(-c3cccc(-c4ccc5c(c4)C(c4ccccc4)(c4ccccc4)c4ccccc4-5)c3)n2)cc1]

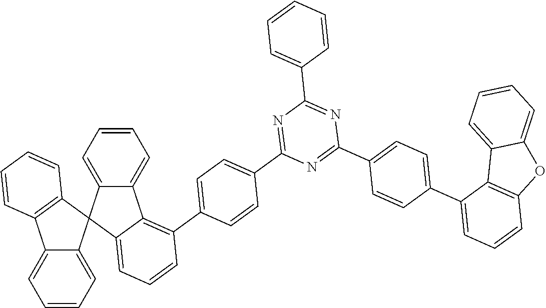 [SMILES: c1ccc(-c2nc(-c3ccc(-c4cccc5c4-c4ccccc4C54c5ccccc5-c5ccccc54)cc3)nc(-c3ccc(-c4cccc5oc6ccccc6c45)cc3)n2)cc1]

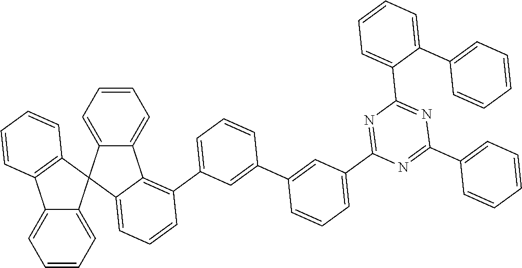 [SMILES: c1ccc(-c2nc(-c3cccc(-c4cccc(-c5cccc6c5-c5ccccc5C65c6ccccc6-c6ccccc65)c4)c3)nc(-c3ccccc3-c3ccccc3)n2)cc1]

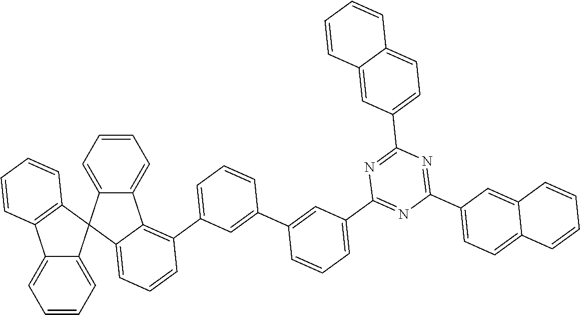 [SMILES: c1cc(-c2cccc(-c3cccc4c3-c3ccccc3C43c4ccccc4-c4ccccc43)c2)cc(-c2nc(-c3ccc4ccccc4c3)nc(-c3ccc4ccccc4c3)n2)c1]

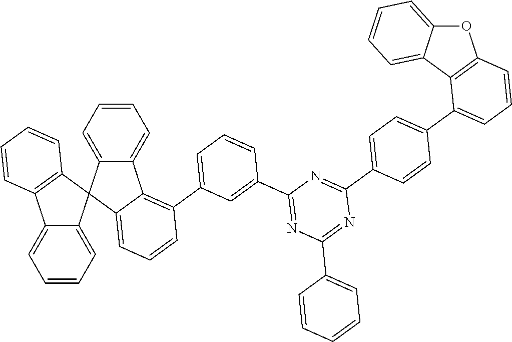 [SMILES: c1ccc(-c2nc(-c3ccc(-c4cccc5oc6ccccc6c45)cc3)nc(-c3cccc(-c4cccc5c4-c4ccccc4C54c5ccccc5-c5ccccc54)c3)n2)cc1]

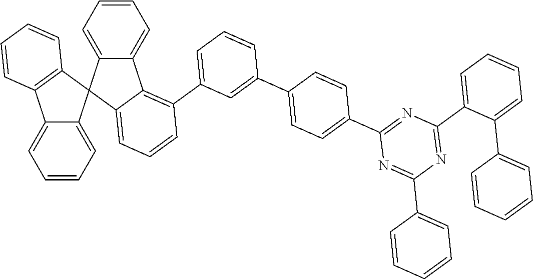 [SMILES: c1ccc(-c2nc(-c3ccc(-c4cccc(-c5cccc6c5-c5ccccc5C65c6ccccc6-c6ccccc65)c4)cc3)nc(-c3ccccc3-c3ccccc3)n2)cc1]

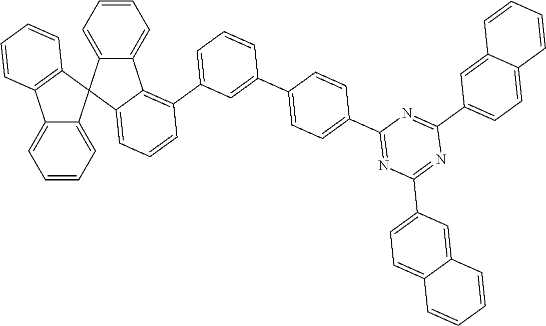 [SMILES: c1cc(-c2ccc(-c3nc(-c4ccc5ccccc5c4)nc(-c4ccc5ccccc5c4)n3)cc2)cc(-c2cccc3c2-c2ccccc2C32c3ccccc3-c3ccccc32)c1]

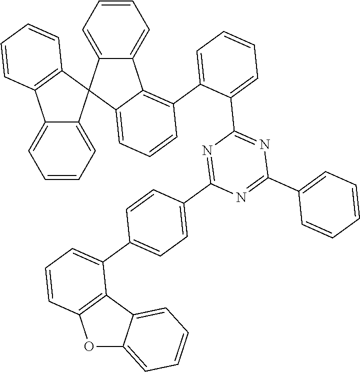 [SMILES: c1ccc(-c2nc(-c3ccc(-c4cccc5oc6ccccc6c45)cc3)nc(-c3ccccc3-c3cccc4c3-c3ccccc3C43c4ccccc4-c4ccccc43)n2)cc1]

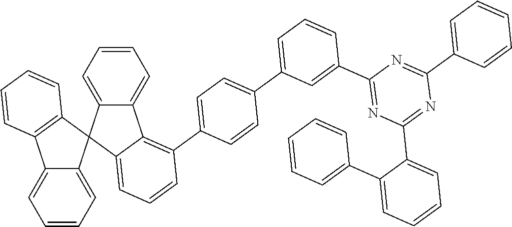 [SMILES: c1ccc(-c2nc(-c3cccc(-c4ccc(-c5cccc6c5-c5ccccc5C65c6ccccc6-c6ccccc65)cc4)c3)nc(-c3ccccc3-c3ccccc3)n2)cc1]

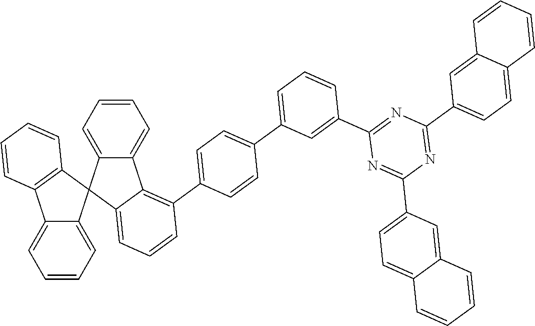 [SMILES: c1cc(-c2ccc(-c3cccc4c3-c3ccccc3C43c4ccccc4-c4ccccc43)cc2)cc(-c2nc(-c3ccc4ccccc4c3)nc(-c3ccc4ccccc4c3)n2)c1]

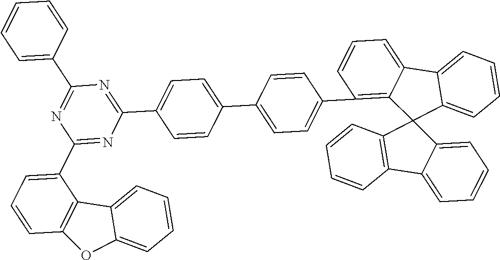 [SMILES: c1ccc(-c2nc(-c3ccc(-c4ccc(-c5cccc6c5C5(c7ccccc7-c7ccccc75)c5ccccc5-6)cc4)cc3)nc(-c3cccc4oc5ccccc5c34)n2)cc1]

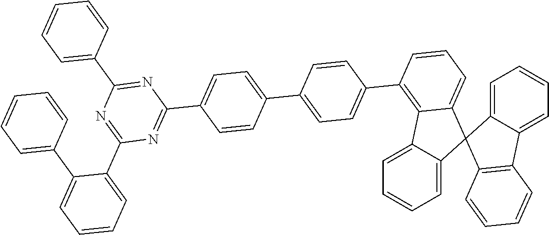 [SMILES: c1ccc(-c2nc(-c3ccc(-c4ccc(-c5cccc6c5-c5ccccc5C65c6ccccc6-c6ccccc65)cc4)cc3)nc(-c3ccccc3-c3ccccc3)n2)cc1]

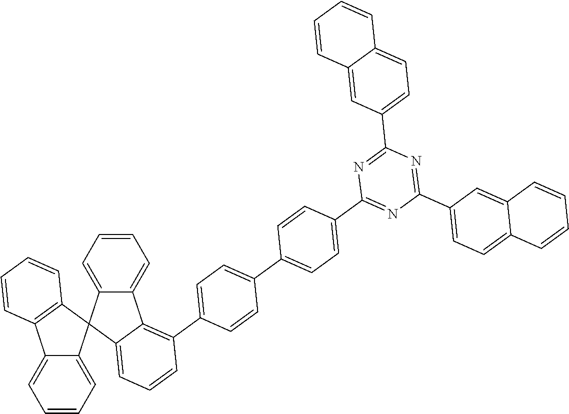 [SMILES: c1ccc2c(c1)-c1ccccc1C21c2ccccc2-c2c(-c3ccc(-c4ccc(-c5nc(-c6ccc7ccccc7c6)nc(-c6ccc7ccccc7c6)n5)cc4)cc3)cccc21]

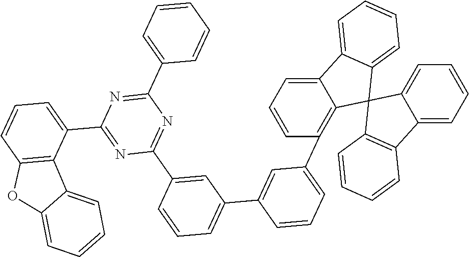 [SMILES: c1ccc(-c2nc(-c3cccc(-c4cccc(-c5cccc6c5C5(c7ccccc7-c7ccccc75)c5ccccc5-6)c4)c3)nc(-c3cccc4oc5ccccc5c34)n2)cc1]

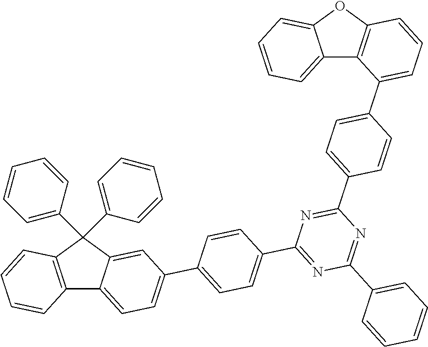 [SMILES: c1ccc(-c2nc(-c3ccc(-c4ccc5c(c4)C(c4ccccc4)(c4ccccc4)c4ccccc4-5)cc3)nc(-c3ccc(-c4cccc5oc6ccccc6c45)cc3)n2)cc1]

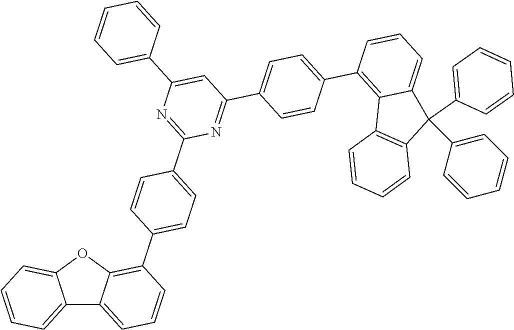 [SMILES: c1ccc(-c2cc(-c3ccc(-c4cccc5c4-c4ccccc4C5(c4ccccc4)c4ccccc4)cc3)nc(-c3ccc(-c4cccc5c4oc4ccccc45)cc3)n2)cc1]

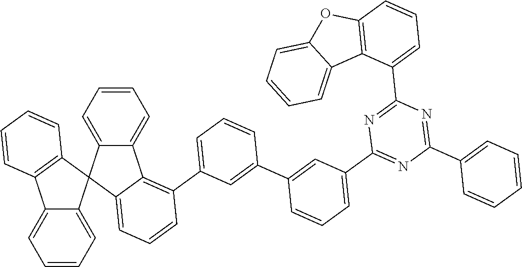 [SMILES: c1ccc(-c2nc(-c3cccc(-c4cccc(-c5cccc6c5-c5ccccc5C65c6ccccc6-c6ccccc65)c4)c3)nc(-c3cccc4oc5ccccc5c34)n2)cc1]

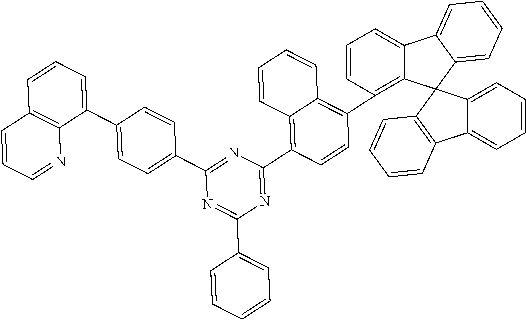 [SMILES: c1ccc(-c2nc(-c3ccc(-c4cccc5cccnc45)cc3)nc(-c3ccc(-c4cccc5c4C4(c6ccccc6-c6ccccc64)c4ccccc4-5)c4ccccc34)n2)cc1]

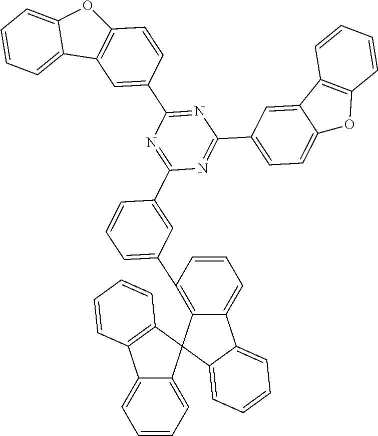 [SMILES: c1cc(-c2nc(-c3ccc4oc5ccccc5c4c3)nc(-c3ccc4oc5ccccc5c4c3)n2)cc(-c2cccc3c2C2(c4ccccc4-c4ccccc42)c2ccccc2-3)c1]

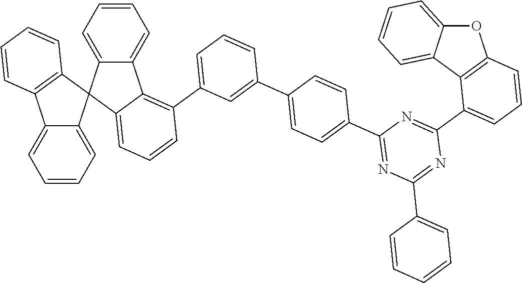 [SMILES: c1ccc(-c2nc(-c3ccc(-c4cccc(-c5cccc6c5-c5ccccc5C65c6ccccc6-c6ccccc65)c4)cc3)nc(-c3cccc4oc5ccccc5c34)n2)cc1]

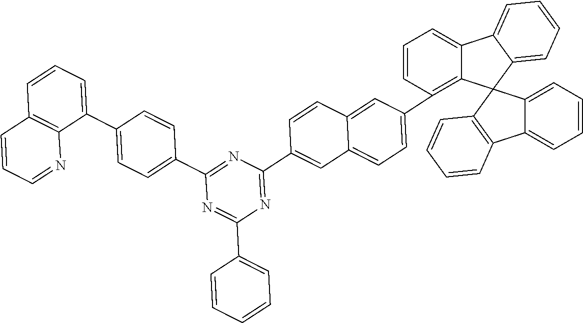 [SMILES: c1ccc(-c2nc(-c3ccc(-c4cccc5cccnc45)cc3)nc(-c3ccc4cc(-c5cccc6c5C5(c7ccccc7-c7ccccc75)c5ccccc5-6)ccc4c3)n2)cc1]

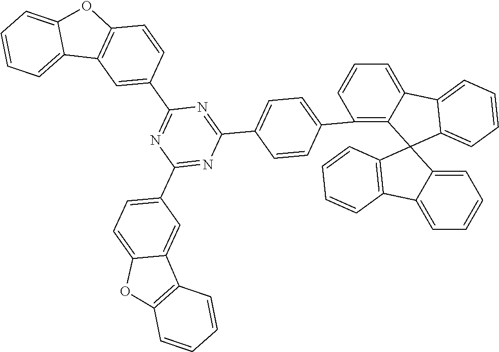 [SMILES: c1ccc2c(c1)-c1ccccc1C21c2ccccc2-c2cccc(-c3ccc(-c4nc(-c5ccc6oc7ccccc7c6c5)nc(-c5ccc6oc7ccccc7c6c5)n4)cc3)c21]

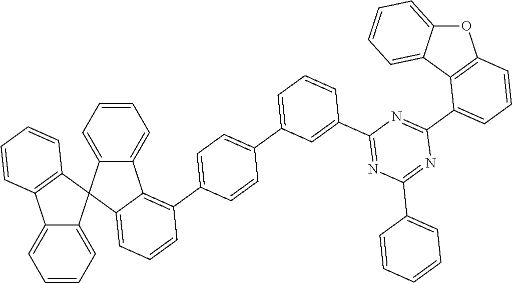 [SMILES: c1ccc(-c2nc(-c3cccc(-c4ccc(-c5cccc6c5-c5ccccc5C65c6ccccc6-c6ccccc65)cc4)c3)nc(-c3cccc4oc5ccccc5c34)n2)cc1]

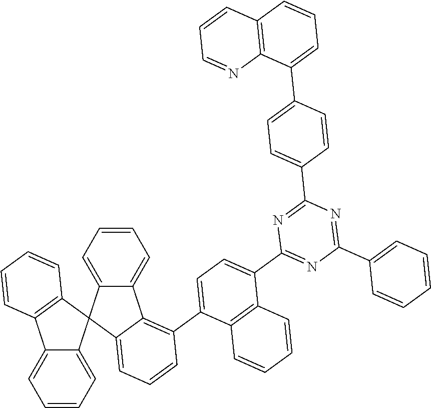 [SMILES: c1ccc(-c2nc(-c3ccc(-c4cccc5cccnc45)cc3)nc(-c3ccc(-c4cccc5c4-c4ccccc4C54c5ccccc5-c5ccccc54)c4ccccc34)n2)cc1]

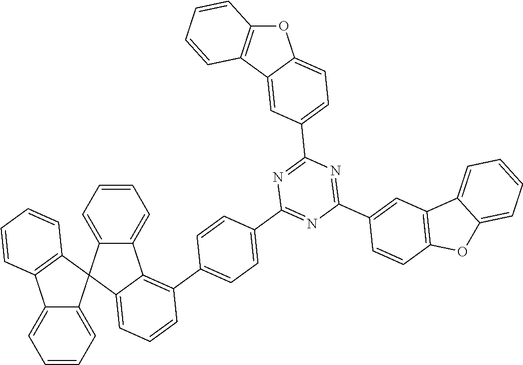 [SMILES: c1ccc2c(c1)-c1ccccc1C21c2ccccc2-c2c(-c3ccc(-c4nc(-c5ccc6oc7ccccc7c6c5)nc(-c5ccc6oc7ccccc7c6c5)n4)cc3)cccc21]

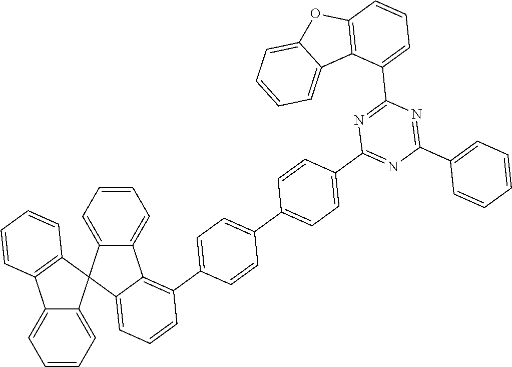 [SMILES: c1ccc(-c2nc(-c3ccc(-c4ccc(-c5cccc6c5-c5ccccc5C65c6ccccc6-c6ccccc65)cc4)cc3)nc(-c3cccc4oc5ccccc5c34)n2)cc1]

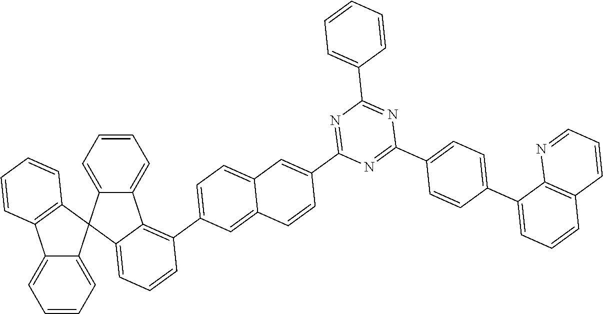 [SMILES: c1ccc(-c2nc(-c3ccc(-c4cccc5cccnc45)cc3)nc(-c3ccc4cc(-c5cccc6c5-c5ccccc5C65c6ccccc6-c6ccccc65)ccc4c3)n2)cc1]

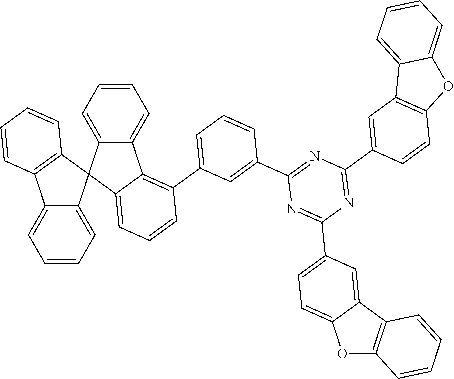 [SMILES: c1cc(-c2nc(-c3ccc4oc5ccccc5c4c3)nc(-c3ccc4oc5ccccc5c4c3)n2)cc(-c2cccc3c2-c2ccccc2C32c3ccccc3-c3ccccc32)c1]

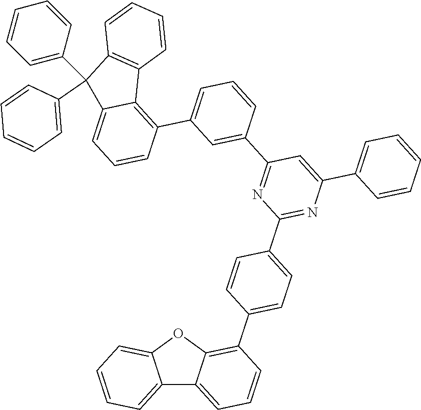 [SMILES: c1ccc(-c2cc(-c3cccc(-c4cccc5c4-c4ccccc4C5(c4ccccc4)c4ccccc4)c3)nc(-c3ccc(-c4cccc5c4oc4ccccc45)cc3)n2)cc1]

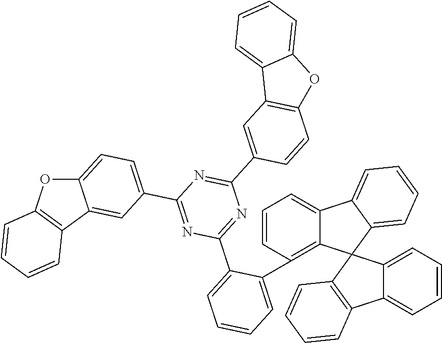 [SMILES: c1ccc(-c2cccc3c2C2(c4ccccc4-c4ccccc42)c2ccccc2-3)c(-c2nc(-c3ccc4oc5ccccc5c4c3)nc(-c3ccc4oc5ccccc5c4c3)n2)c1]

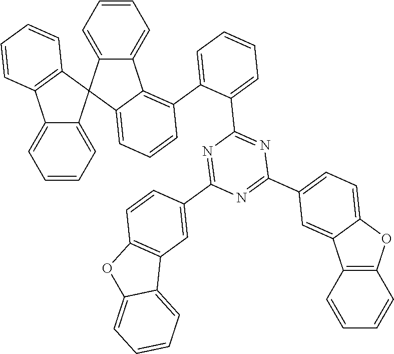 [SMILES: c1ccc(-c2cccc3c2-c2ccccc2C32c3ccccc3-c3ccccc32)c(-c2nc(-c3ccc4oc5ccccc5c4c3)nc(-c3ccc4oc5ccccc5c4c3)n2)c1]

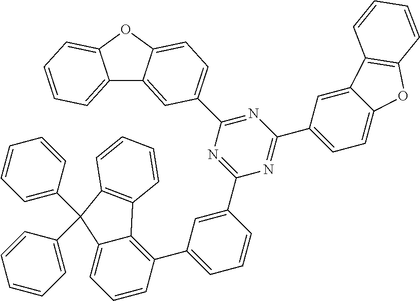 [SMILES: c1ccc(C2(c3ccccc3)c3ccccc3-c3c(-c4cccc(-c5nc(-c6ccc7oc8ccccc8c7c6)nc(-c6ccc7oc8ccccc8c7c6)n5)c4)cccc32)cc1]

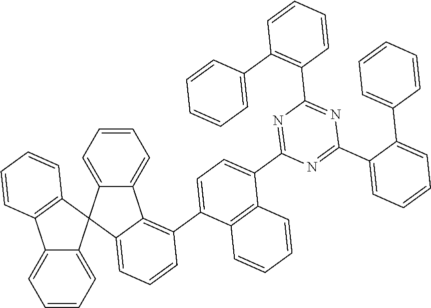 [SMILES: c1ccc(-c2ccccc2-c2nc(-c3ccccc3-c3ccccc3)nc(-c3ccc(-c4cccc5c4-c4ccccc4C54c5ccccc5-c5ccccc54)c4ccccc34)n2)cc1]

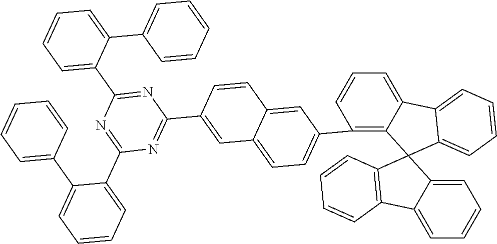 [SMILES: c1ccc(-c2ccccc2-c2nc(-c3ccc4cc(-c5cccc6c5C5(c7ccccc7-c7ccccc75)c5ccccc5-6)ccc4c3)nc(-c3ccccc3-c3ccccc3)n2)cc1]

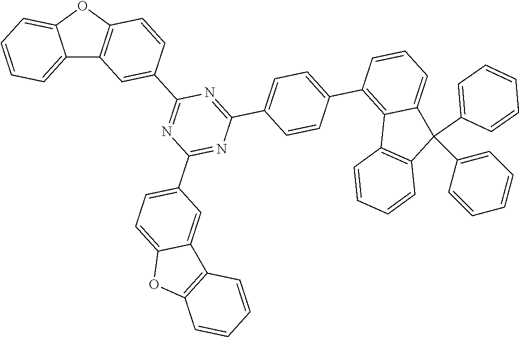 [SMILES: c1ccc(C2(c3ccccc3)c3ccccc3-c3c(-c4ccc(-c5nc(-c6ccc7oc8ccccc8c7c6)nc(-c6ccc7oc8ccccc8c7c6)n5)cc4)cccc32)cc1]

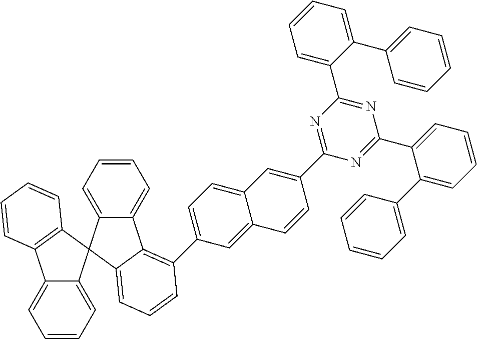 [SMILES: c1ccc(-c2ccccc2-c2nc(-c3ccc4cc(-c5cccc6c5-c5ccccc5C65c6ccccc6-c6ccccc65)ccc4c3)nc(-c3ccccc3-c3ccccc3)n2)cc1]

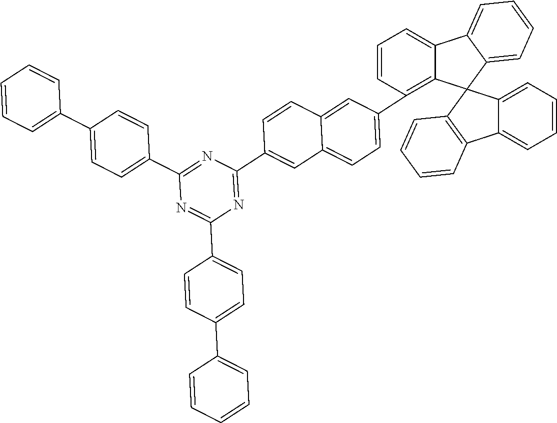 [SMILES: c1ccc(-c2ccc(-c3nc(-c4ccc(-c5ccccc5)cc4)nc(-c4ccc5cc(-c6cccc7c6C6(c8ccccc8-c8ccccc86)c6ccccc6-7)ccc5c4)n3)cc2)cc1]

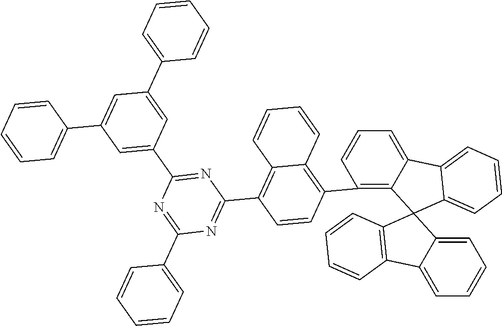 [SMILES: c1ccc(-c2cc(-c3ccccc3)cc(-c3nc(-c4ccccc4)nc(-c4ccc(-c5cccc6c5C5(c7ccccc7-c7ccccc75)c5ccccc5-6)c5ccccc45)n3)c2)cc1]

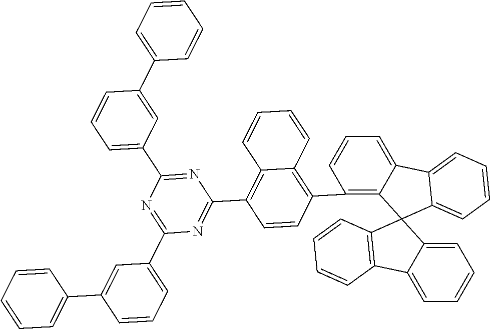 [SMILES: c1ccc(-c2cccc(-c3nc(-c4cccc(-c5ccccc5)c4)nc(-c4ccc(-c5cccc6c5C5(c7ccccc7-c7ccccc75)c5ccccc5-6)c5ccccc45)n3)c2)cc1]

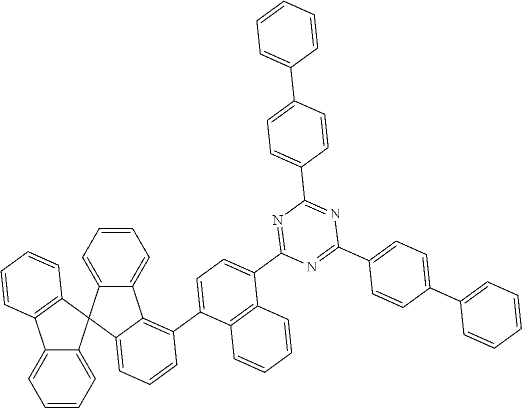 [SMILES: c1ccc(-c2ccc(-c3nc(-c4ccc(-c5ccccc5)cc4)nc(-c4ccc(-c5cccc6c5-c5ccccc5C65c6ccccc6-c6ccccc65)c5ccccc45)n3)cc2)cc1]

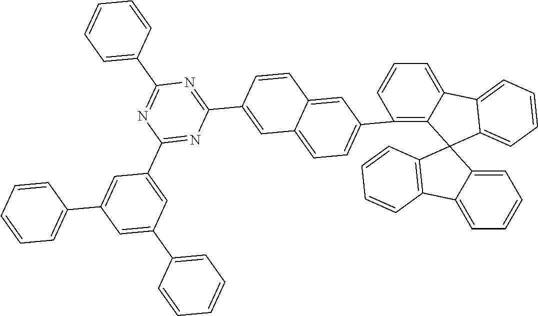 [SMILES: c1ccc(-c2cc(-c3ccccc3)cc(-c3nc(-c4ccccc4)nc(-c4ccc5cc(-c6cccc7c6C6(c8ccccc8-c8ccccc86)c6ccccc6-7)ccc5c4)n3)c2)cc1]

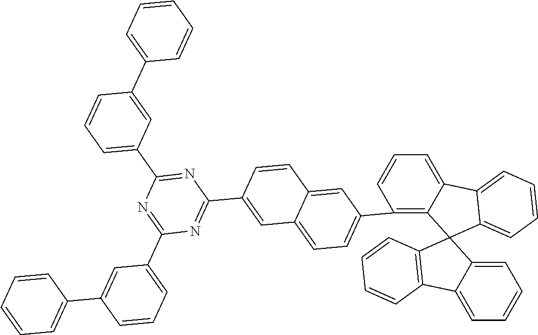 [SMILES: c1ccc(-c2cccc(-c3nc(-c4cccc(-c5ccccc5)c4)nc(-c4ccc5cc(-c6cccc7c6C6(c8ccccc8-c8ccccc86)c6ccccc6-7)ccc5c4)n3)c2)cc1]

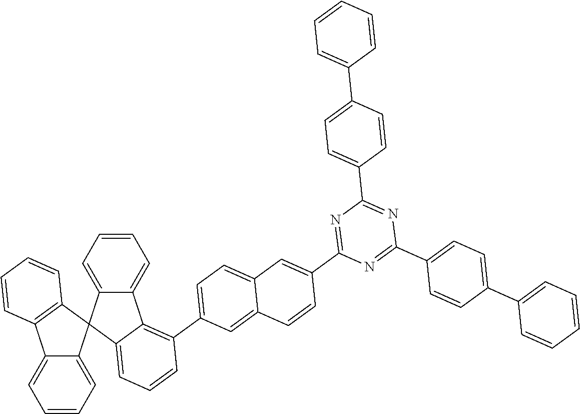 [SMILES: c1ccc(-c2ccc(-c3nc(-c4ccc(-c5ccccc5)cc4)nc(-c4ccc5cc(-c6cccc7c6-c6ccccc6C76c7ccccc7-c7ccccc76)ccc5c4)n3)cc2)cc1]

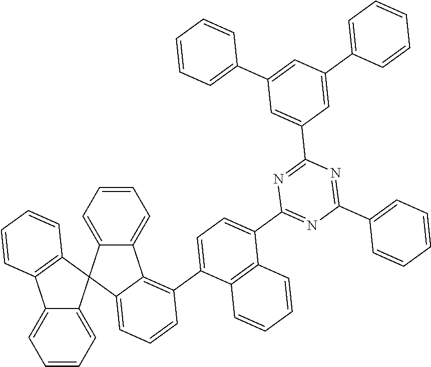 [SMILES: c1ccc(-c2cc(-c3ccccc3)cc(-c3nc(-c4ccccc4)nc(-c4ccc(-c5cccc6c5-c5ccccc5C65c6ccccc6-c6ccccc65)c5ccccc45)n3)c2)cc1]

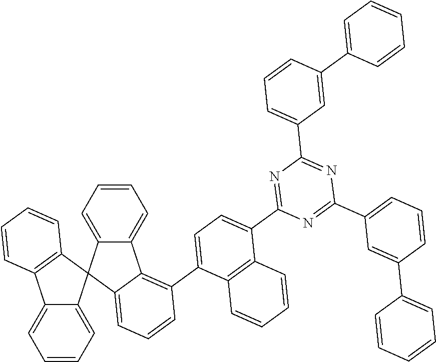 [SMILES: c1ccc(-c2cccc(-c3nc(-c4cccc(-c5ccccc5)c4)nc(-c4ccc(-c5cccc6c5-c5ccccc5C65c6ccccc6-c6ccccc65)c5ccccc45)n3)c2)cc1]

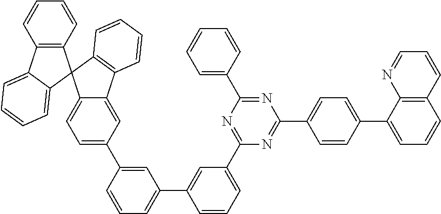 [SMILES: c1ccc(-c2nc(-c3ccc(-c4cccc5cccnc45)cc3)nc(-c3cccc(-c4cccc(-c5ccc6c(c5)-c5ccccc5C65c6ccccc6-c6ccccc65)c4)c3)n2)cc1]

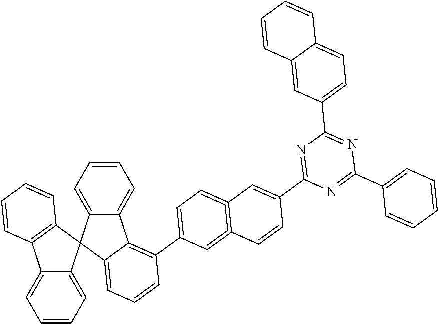

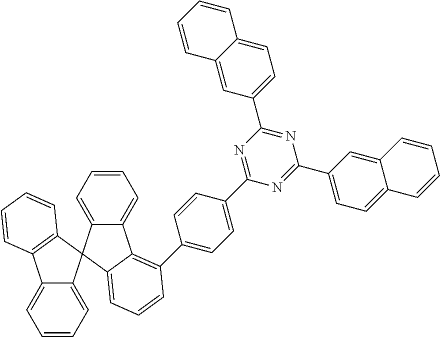 [SMILES: c1ccc2c(c1)-c1ccccc1C21c2ccccc2-c2c(-c3ccc(-c4nc(-c5ccc6ccccc6c5)nc(-c5ccc6ccccc6c5)n4)cc3)cccc21]

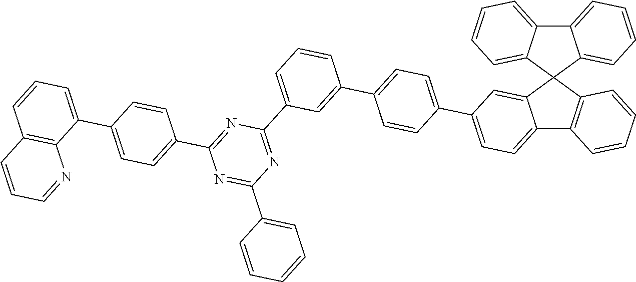 [SMILES: c1ccc(-c2nc(-c3ccc(-c4cccc5cccnc45)cc3)nc(-c3cccc(-c4ccc(-c5ccc6c(c5)C5(c7ccccc7-c7ccccc75)c5ccccc5-6)cc4)c3)n2)cc1]

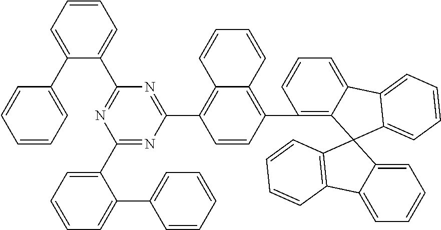 [SMILES: c1ccc(-c2ccccc2-c2nc(-c3ccccc3-c3ccccc3)nc(-c3ccc(-c4cccc5c4C4(c6ccccc6-c6ccccc64)c4ccccc4-5)c4ccccc34)n2)cc1]

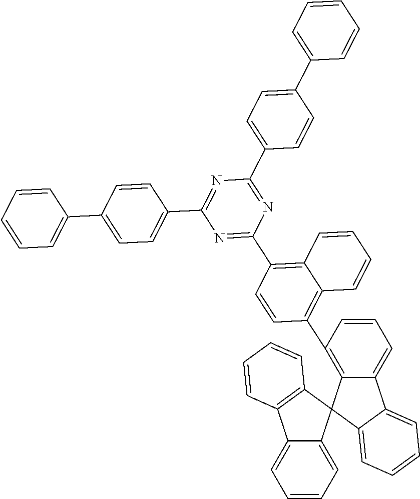 [SMILES: c1ccc(-c2ccc(-c3nc(-c4ccc(-c5ccccc5)cc4)nc(-c4ccc(-c5cccc6c5C5(c7ccccc7-c7ccccc75)c5ccccc5-6)c5ccccc45)n3)cc2)cc1]

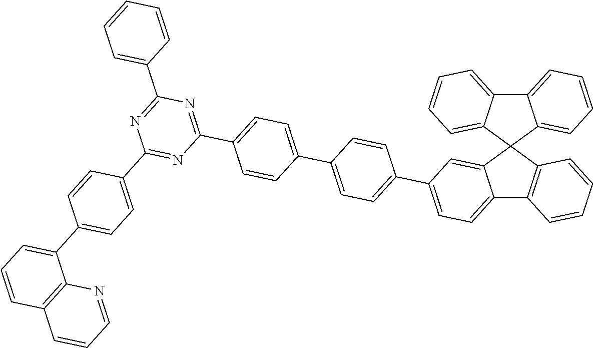 [SMILES: c1ccc(-c2nc(-c3ccc(-c4ccc(-c5ccc6c(c5)C5(c7ccccc7-c7ccccc75)c5ccccc5-6)cc4)cc3)nc(-c3ccc(-c4cccc5cccnc45)cc3)n2)cc1]

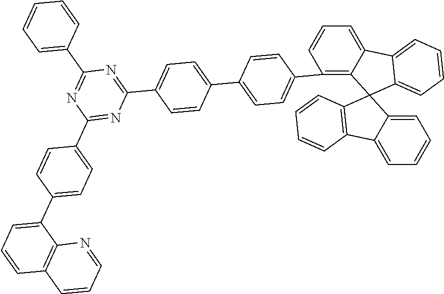 [SMILES: c1ccc(-c2nc(-c3ccc(-c4ccc(-c5cccc6c5C5(c7ccccc7-c7ccccc75)c5ccccc5-6)cc4)cc3)nc(-c3ccc(-c4cccc5cccnc45)cc3)n2)cc1]

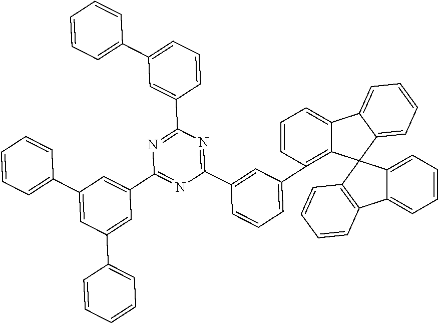 [SMILES: c1ccc(-c2cccc(-c3nc(-c4cc(-c5ccccc5)cc(-c5ccccc5)c4)nc(-c4cccc(-c5cccc6c5C5(c7ccccc7-c7ccccc75)c5ccccc5-6)c4)n3)c2)cc1]

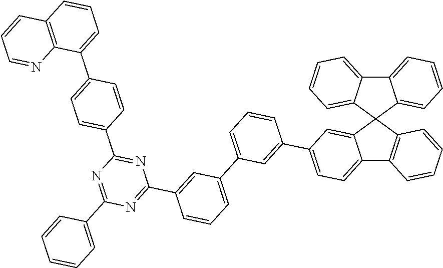 [SMILES: c1ccc(-c2nc(-c3ccc(-c4cccc5cccnc45)cc3)nc(-c3cccc(-c4cccc(-c5ccc6c(c5)C5(c7ccccc7-c7ccccc75)c5ccccc5-6)c4)c3)n2)cc1]

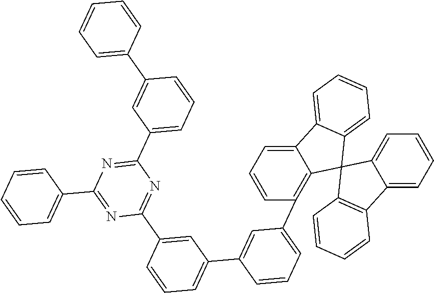 [SMILES: c1ccc(-c2cccc(-c3nc(-c4ccccc4)nc(-c4cccc(-c5cccc(-c6cccc7c6C6(c8ccccc8-c8ccccc86)c6ccccc6-7)c5)c4)n3)c2)cc1]

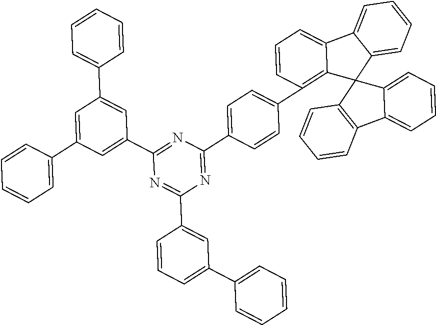 [SMILES: c1ccc(-c2cccc(-c3nc(-c4ccc(-c5cccc6c5C5(c7ccccc7-c7ccccc75)c5ccccc5-6)cc4)nc(-c4cc(-c5ccccc5)cc(-c5ccccc5)c4)n3)c2)cc1]

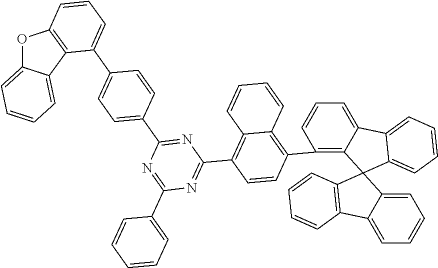 [SMILES: c1ccc(-c2nc(-c3ccc(-c4cccc5oc6ccccc6c45)cc3)nc(-c3ccc(-c4cccc5c4C4(c6ccccc6-c6ccccc64)c4ccccc4-5)c4ccccc34)n2)cc1]

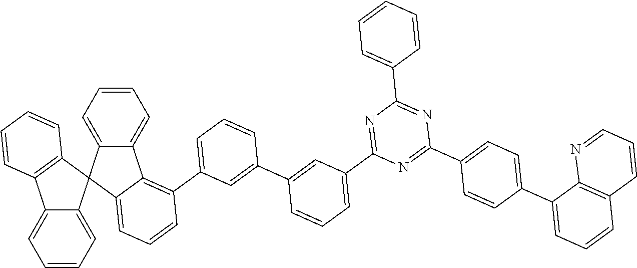 [SMILES: c1ccc(-c2nc(-c3ccc(-c4cccc5cccnc45)cc3)nc(-c3cccc(-c4cccc(-c5cccc6c5-c5ccccc5C65c6ccccc6-c6ccccc65)c4)c3)n2)cc1]

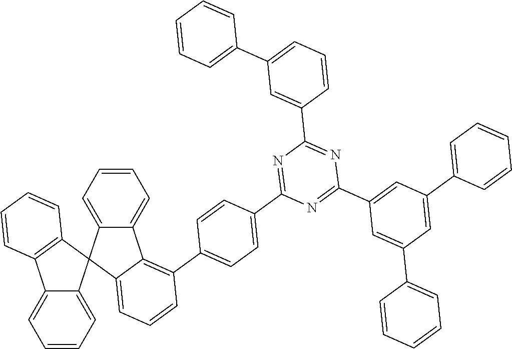 [SMILES: c1ccc(-c2cccc(-c3nc(-c4ccc(-c5cccc6c5-c5ccccc5C65c6ccccc6-c6ccccc65)cc4)nc(-c4cc(-c5ccccc5)cc(-c5ccccc5)c4)n3)c2)cc1]

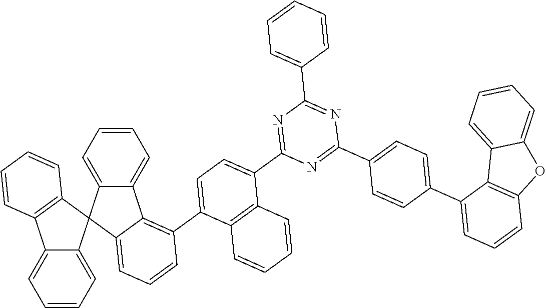 [SMILES: c1ccc(-c2nc(-c3ccc(-c4cccc5oc6ccccc6c45)cc3)nc(-c3ccc(-c4cccc5c4-c4ccccc4C54c5ccccc5-c5ccccc54)c4ccccc34)n2)cc1]

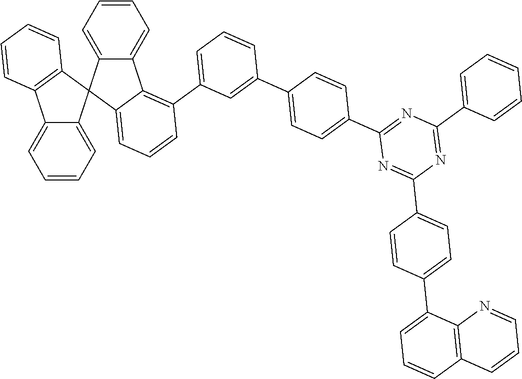 [SMILES: c1ccc(-c2nc(-c3ccc(-c4cccc(-c5cccc6c5-c5ccccc5C65c6ccccc6-c6ccccc65)c4)cc3)nc(-c3ccc(-c4cccc5cccnc45)cc3)n2)cc1]

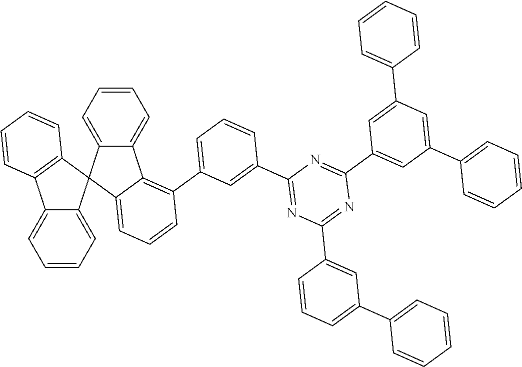 [SMILES: c1ccc(-c2cccc(-c3nc(-c4cc(-c5ccccc5)cc(-c5ccccc5)c4)nc(-c4cccc(-c5cccc6c5-c5ccccc5C65c6ccccc6-c6ccccc65)c4)n3)c2)cc1]

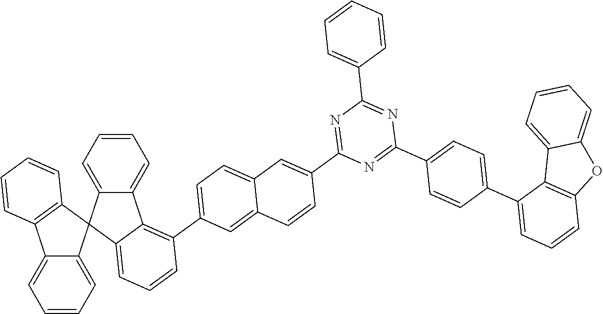 [SMILES: c1ccc(-c2nc(-c3ccc(-c4cccc5oc6ccccc6c45)cc3)nc(-c3ccc4cc(-c5cccc6c5-c5ccccc5C65c6ccccc6-c6ccccc65)ccc4c3)n2)cc1]

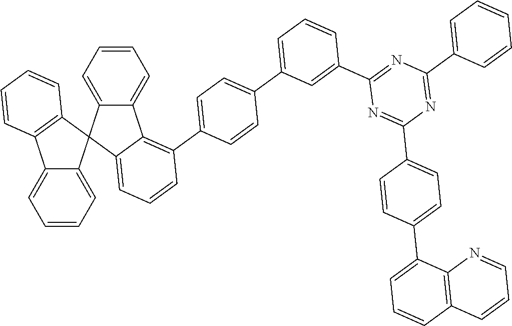 [SMILES: c1ccc(-c2nc(-c3ccc(-c4cccc5cccnc45)cc3)nc(-c3cccc(-c4ccc(-c5cccc6c5-c5ccccc5C65c6ccccc6-c6ccccc65)cc4)c3)n2)cc1]

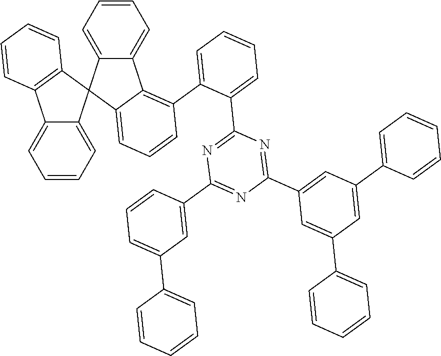 [SMILES: c1ccc(-c2cccc(-c3nc(-c4cc(-c5ccccc5)cc(-c5ccccc5)c4)nc(-c4ccccc4-c4cccc5c4-c4ccccc4C54c5ccccc5-c5ccccc54)n3)c2)cc1]

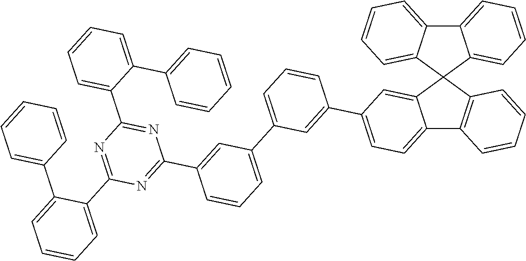 [SMILES: c1ccc(-c2ccccc2-c2nc(-c3cccc(-c4cccc(-c5ccc6c(c5)C5(c7ccccc7-c7ccccc75)c5ccccc5-6)c4)c3)nc(-c3ccccc3-c3ccccc3)n2)cc1]

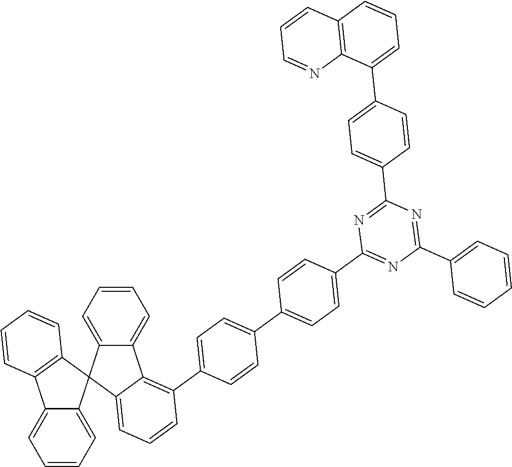 [SMILES: c1ccc(-c2nc(-c3ccc(-c4ccc(-c5cccc6c5-c5ccccc5C65c6ccccc6-c6ccccc65)cc4)cc3)nc(-c3ccc(-c4cccc5cccnc45)cc3)n2)cc1]

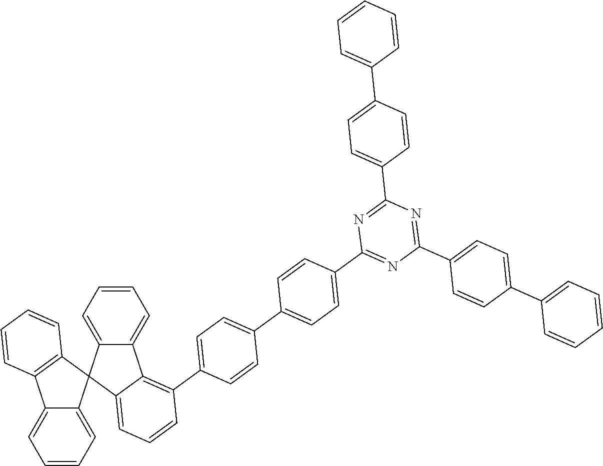 [SMILES: c1ccc(-c2ccc(-c3nc(-c4ccc(-c5ccccc5)cc4)nc(-c4ccc(-c5ccc(-c6cccc7c6-c6ccccc6C76c7ccccc7-c7ccccc76)cc5)cc4)n3)cc2)cc1]

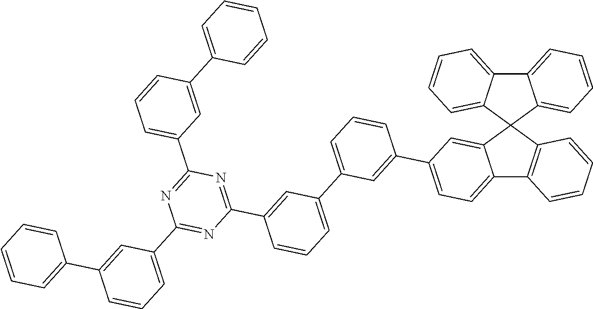 [SMILES: c1ccc(-c2cccc(-c3nc(-c4cccc(-c5ccccc5)c4)nc(-c4cccc(-c5cccc(-c6ccc7c(c6)C6(c8ccccc8-c8ccccc86)c6ccccc6-7)c5)c4)n3)c2)cc1]

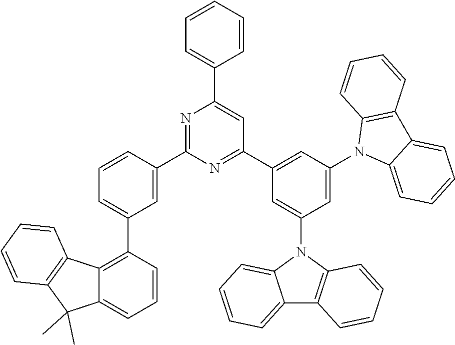 [SMILES: CC1(C)c2ccccc2-c2c(-c3cccc(-c4nc(-c5ccccc5)cc(-c5cc(-n6c7ccccc7c7ccccc76)cc(-n6c7ccccc7c7ccccc76)c5)n4)c3)cccc21]

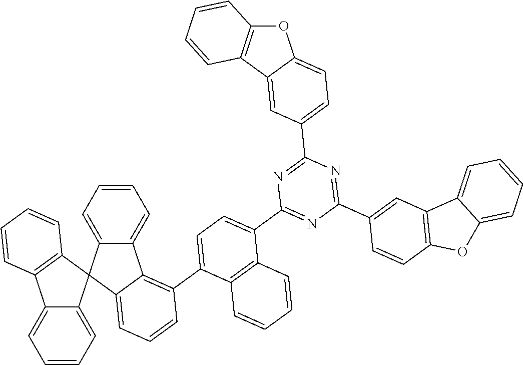 [SMILES: c1ccc2c(c1)-c1ccccc1C21c2ccccc2-c2c(-c3ccc(-c4nc(-c5ccc6oc7ccccc7c6c5)nc(-c5ccc6oc7ccccc7c6c5)n4)c4ccccc34)cccc21]

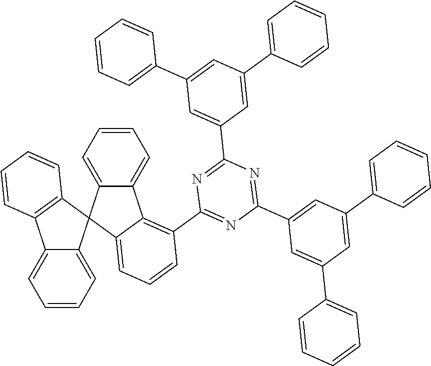 [SMILES: c1ccc(-c2cc(-c3ccccc3)cc(-c3nc(-c4cc(-c5ccccc5)cc(-c5ccccc5)c4)nc(-c4cccc5c4-c4ccccc4C54c5ccccc5-c5ccccc54)n3)c2)cc1]

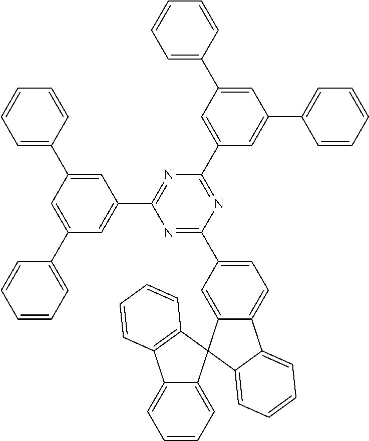 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

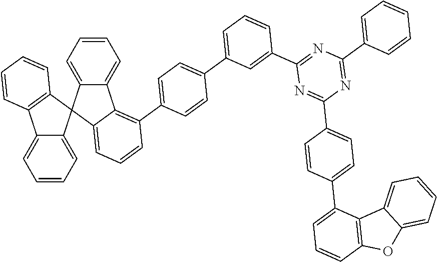 [SMILES: c1ccc(-c2nc(-c3ccc(-c4cccc5oc6ccccc6c45)cc3)nc(-c3cccc(-c4ccc(-c5cccc6c5-c5ccccc5C65c6ccccc6-c6ccccc65)cc4)c3)n2)cc1]

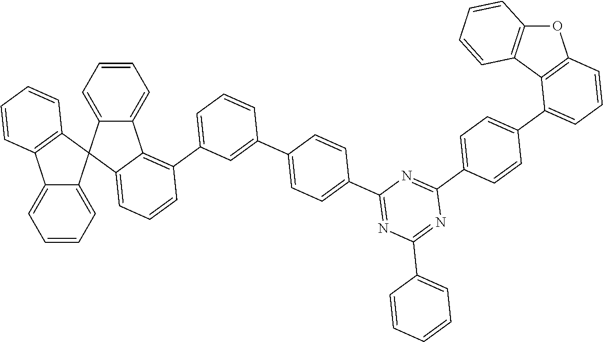 [SMILES: c1ccc(-c2nc(-c3ccc(-c4cccc(-c5cccc6c5-c5ccccc5C65c6ccccc6-c6ccccc65)c4)cc3)nc(-c3ccc(-c4cccc5oc6ccccc6c45)cc3)n2)cc1]

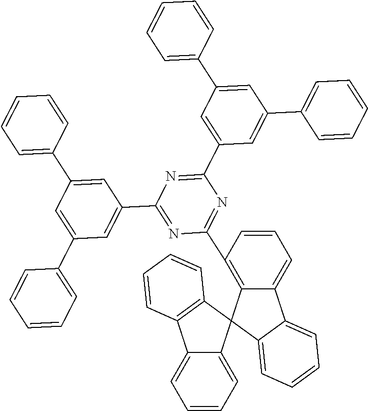 [SMILES: c1ccc(-c2cc(-c3ccccc3)cc(-c3nc(-c4cc(-c5ccccc5)cc(-c5ccccc5)c4)nc(-c4cccc5c4C4(c6ccccc6-c6ccccc64)c4ccccc4-5)n3)c2)cc1]

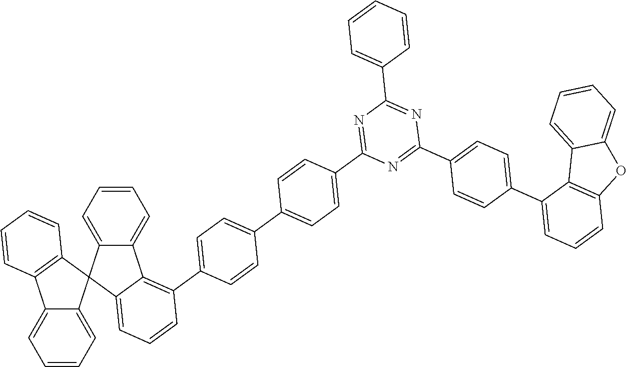 [SMILES: c1ccc(-c2nc(-c3ccc(-c4ccc(-c5cccc6c5-c5ccccc5C65c6ccccc6-c6ccccc65)cc4)cc3)nc(-c3ccc(-c4cccc5oc6ccccc6c45)cc3)n2)cc1]

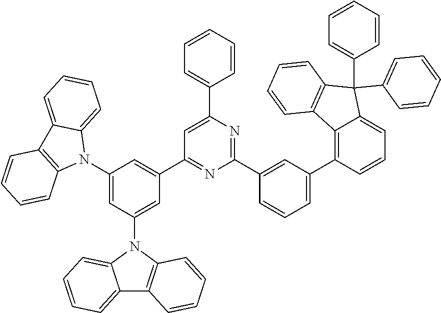 [SMILES: c1ccc(-c2cc(-c3cc(-n4c5ccccc5c5ccccc54)cc(-n4c5ccccc5c5ccccc54)c3)nc(-c3cccc(-c4cccc5c4-c4ccccc4C5(c4ccccc4)c4ccccc4)c3)n2)cc1]

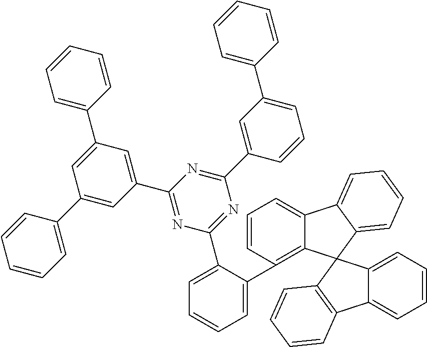 [SMILES: c1ccc(-c2cccc(-c3nc(-c4cc(-c5ccccc5)cc(-c5ccccc5)c4)nc(-c4ccccc4-c4cccc5c4C4(c6ccccc6-c6ccccc64)c4ccccc4-5)n3)c2)cc1]

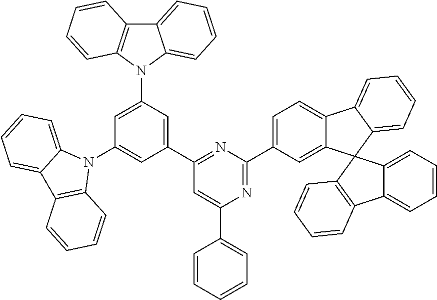 [SMILES: c1ccc(-c2cc(-c3cc(-n4c5ccccc5c5ccccc54)cc(-n4c5ccccc5c5ccccc54)c3)nc(-c3ccc4c(c3)C3(c5ccccc5-c5ccccc53)c3ccccc3-4)n2)cc1]

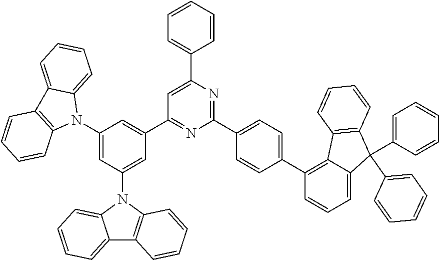 [SMILES: c1ccc(-c2cc(-c3cc(-n4c5ccccc5c5ccccc54)cc(-n4c5ccccc5c5ccccc54)c3)nc(-c3ccc(-c4cccc5c4-c4ccccc4C5(c4ccccc4)c4ccccc4)cc3)n2)cc1]

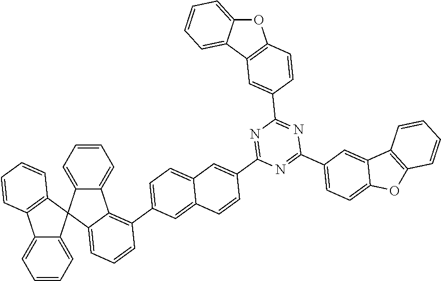 [SMILES: c1ccc2c(c1)-c1ccccc1C21c2ccccc2-c2c(-c3ccc4cc(-c5nc(-c6ccc7oc8ccccc8c7c6)nc(-c6ccc7oc8ccccc8c7c6)n5)ccc4c3)cccc21]

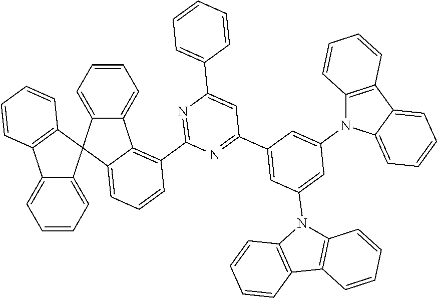 [SMILES: c1ccc(-c2cc(-c3cc(-n4c5ccccc5c5ccccc54)cc(-n4c5ccccc5c5ccccc54)c3)nc(-c3cccc4c3-c3ccccc3C43c4ccccc4-c4ccccc43)n2)cc1]

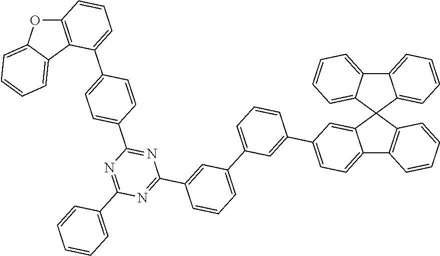 [SMILES: c1ccc(-c2nc(-c3ccc(-c4cccc5oc6ccccc6c45)cc3)nc(-c3cccc(-c4cccc(-c5ccc6c(c5)C5(c7ccccc7-c7ccccc75)c5ccccc5-6)c4)c3)n2)cc1]

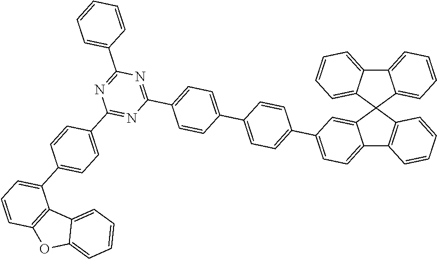 [SMILES: c1ccc(-c2nc(-c3ccc(-c4ccc(-c5ccc6c(c5)C5(c7ccccc7-c7ccccc75)c5ccccc5-6)cc4)cc3)nc(-c3ccc(-c4cccc5oc6ccccc6c45)cc3)n2)cc1]

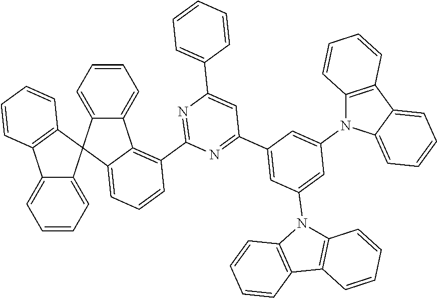 [SMILES: c1ccc(-c2cc(-c3cc(-n4c5ccccc5c5ccccc54)cc(-n4c5ccccc5c5ccccc54)c3)nc(-c3cccc4c3-c3ccccc3C43c4ccccc4-c4ccccc43)n2)cc1]

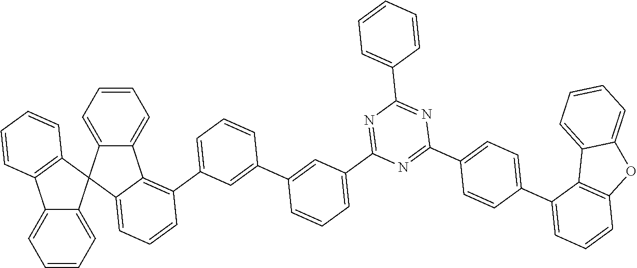 [SMILES: c1ccc(-c2nc(-c3ccc(-c4cccc5oc6ccccc6c45)cc3)nc(-c3cccc(-c4cccc(-c5cccc6c5-c5ccccc5C65c6ccccc6-c6ccccc65)c4)c3)n2)cc1]

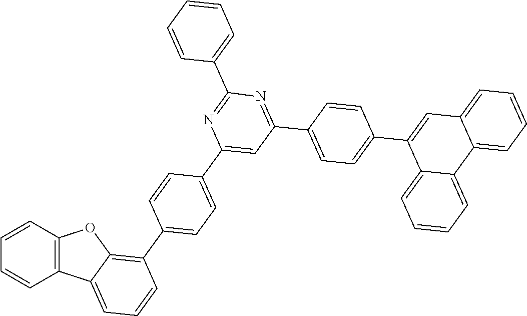 [SMILES: c1ccc(-c2nc(-c3ccc(-c4cc5ccccc5c5ccccc45)cc3)cc(-c3ccc(-c4cccc5c4oc4ccccc45)cc3)n2)cc1]

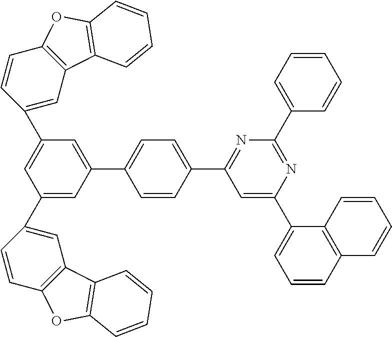 [SMILES: c1ccc(-c2nc(-c3ccc(-c4cc(-c5ccc6oc7ccccc7c6c5)cc(-c5ccc6oc7ccccc7c6c5)c4)cc3)cc(-c3cccc4ccccc34)n2)cc1]

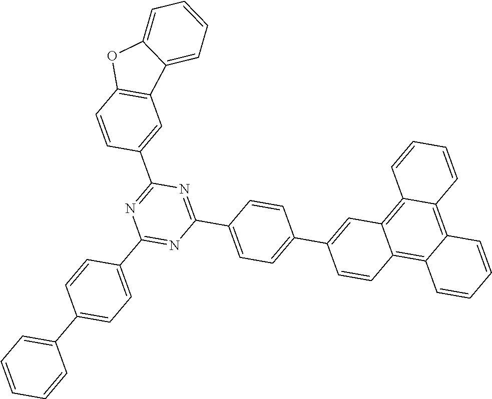 [SMILES: c1ccc(-c2ccc(-c3nc(-c4ccc(-c5ccc6c7ccccc7c7ccccc7c6c5)cc4)nc(-c4ccc5oc6ccccc6c5c4)n3)cc2)cc1]

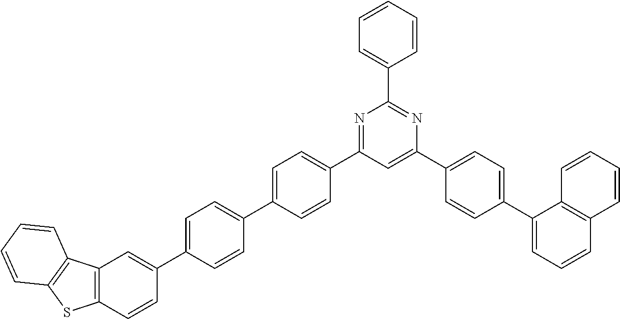 [SMILES: c1ccc(-c2nc(-c3ccc(-c4ccc(-c5ccc6sc7ccccc7c6c5)cc4)cc3)cc(-c3ccc(-c4cccc5ccccc45)cc3)n2)cc1]

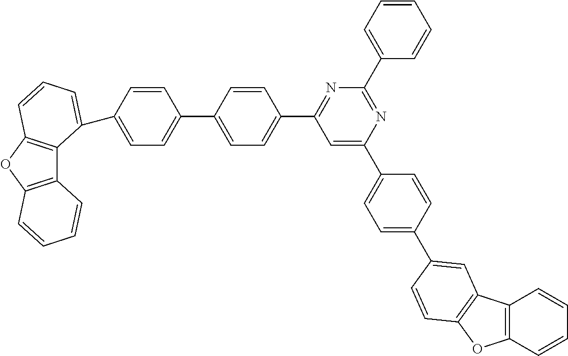 [SMILES: c1ccc(-c2nc(-c3ccc(-c4ccc(-c5cccc6oc7ccccc7c56)cc4)cc3)cc(-c3ccc(-c4ccc5oc6ccccc6c5c4)cc3)n2)cc1]

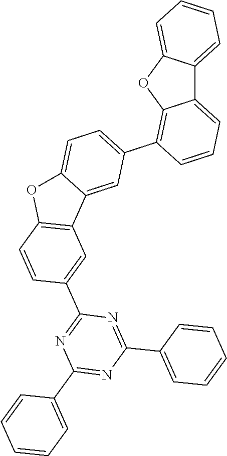 [SMILES: c1ccc(-c2nc(-c3ccccc3)nc(-c3ccc4oc5ccc(-c6cccc7c6oc6ccccc67)cc5c4c3)n2)cc1]

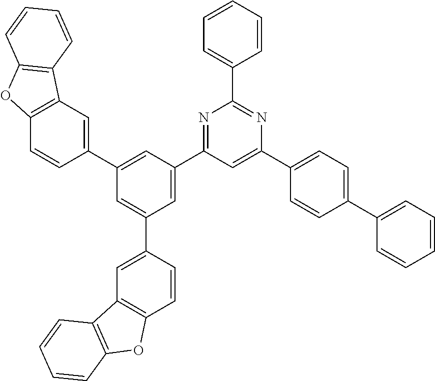 [SMILES: c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

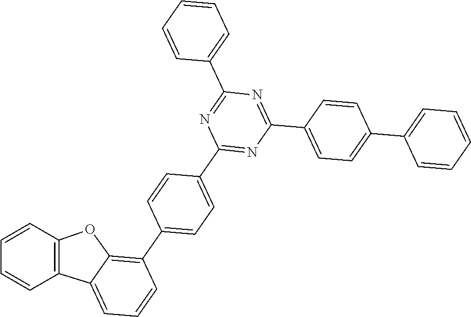 [SMILES: c1ccc(-c2ccc(-c3nc(-c4ccccc4)nc(-c4ccc(-c5cccc6c5oc5ccccc56)cc4)n3)cc2)cc1]

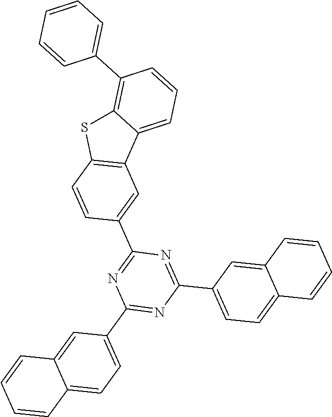 [SMILES: c1ccc(-c2cccc3c2sc2ccc(-c4nc(-c5ccc6ccccc6c5)nc(-c5ccc6ccccc6c5)n4)cc23)cc1]

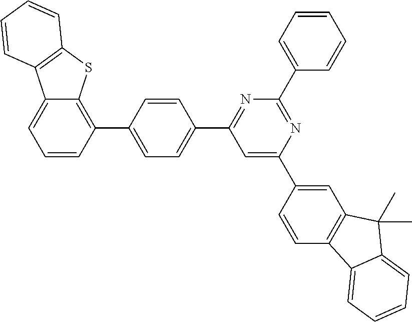 [SMILES: CC1(C)c2ccccc2-c2ccc(-c3cc(-c4ccc(-c5cccc6c5sc5ccccc56)cc4)nc(-c4ccccc4)n3)cc21]

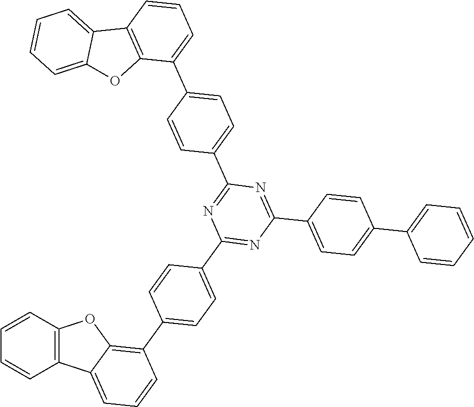 [SMILES: c1ccc(-c2ccc(-c3nc(-c4ccc(-c5cccc6c5oc5ccccc56)cc4)nc(-c4ccc(-c5cccc6c5oc5ccccc56)cc4)n3)cc2)cc1]

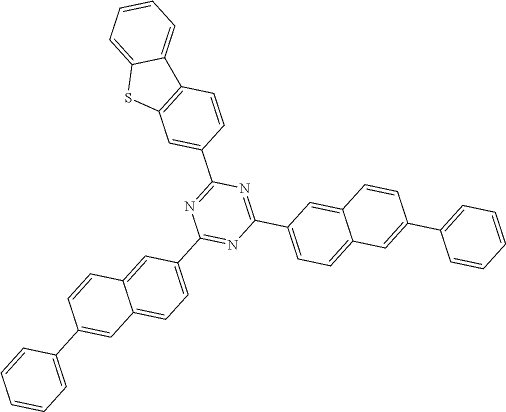 [SMILES: c1ccc(-c2ccc3cc(-c4nc(-c5ccc6cc(-c7ccccc7)ccc6c5)nc(-c5ccc6c(c5)sc5ccccc56)n4)ccc3c2)cc1]

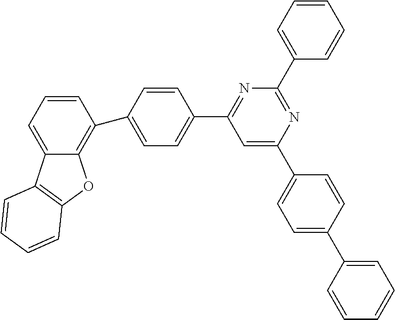 [SMILES: c1ccc(-c2ccc(-c3cc(-c4ccc(-c5cccc6c5oc5ccccc56)cc4)nc(-c4ccccc4)n3)cc2)cc1]

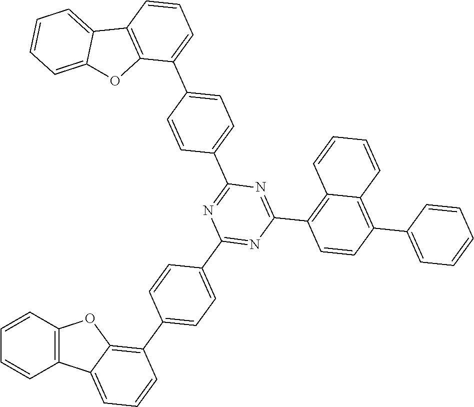 [SMILES: c1ccc(-c2ccc(-c3nc(-c4ccc(-c5cccc6c5oc5ccccc56)cc4)nc(-c4ccc(-c5cccc6c5oc5ccccc56)cc4)n3)c3ccccc23)cc1]

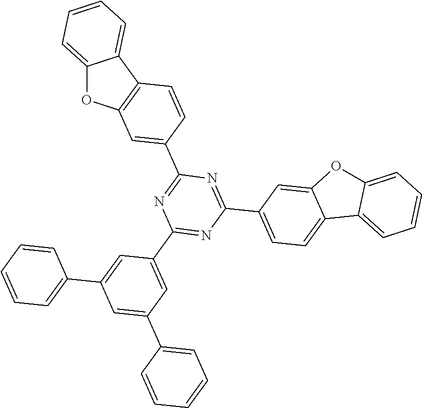 [SMILES: c1ccc(-c2cc(-c3ccccc3)cc(-c3nc(-c4ccc5c(c4)oc4ccccc45)nc(-c4ccc5c(c4)oc4ccccc45)n3)c2)cc1]

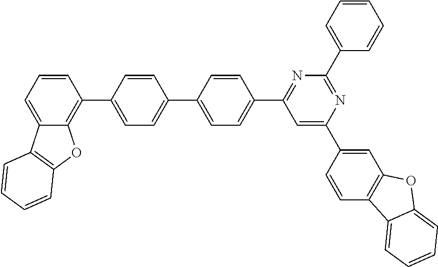 [SMILES: c1ccc(-c2nc(-c3ccc(-c4ccc(-c5cccc6c5oc5ccccc56)cc4)cc3)cc(-c3ccc4c(c3)oc3ccccc34)n2)cc1]

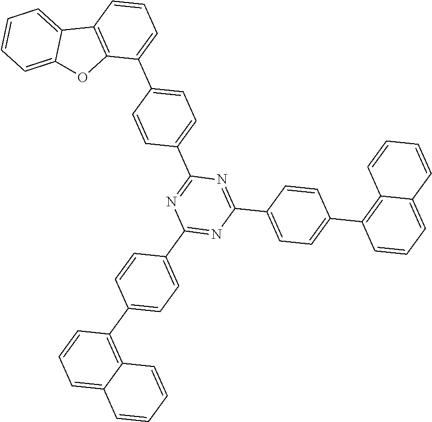 [SMILES: c1ccc2c(-c3ccc(-c4nc(-c5ccc(-c6cccc7ccccc67)cc5)nc(-c5ccc(-c6cccc7c6oc6ccccc67)cc5)n4)cc3)cccc2c1]

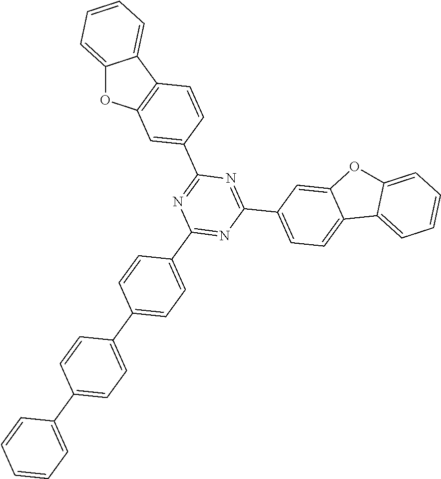 [SMILES: c1ccc(-c2ccc(-c3ccc(-c4nc(-c5ccc6c(c5)oc5ccccc56)nc(-c5ccc6c(c5)oc5ccccc56)n4)cc3)cc2)cc1]

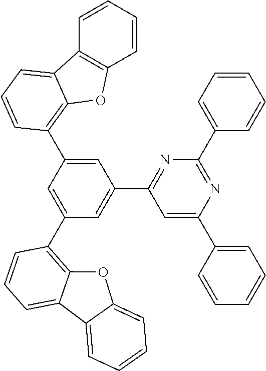 [SMILES: c1ccc(-c2cc(-c3cc(-c4cccc5c4oc4ccccc45)cc(-c4cccc5c4oc4ccccc45)c3)nc(-c3ccccc3)n2)cc1]

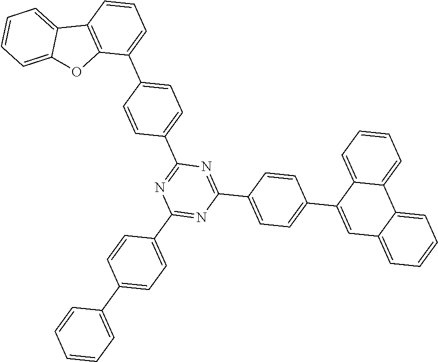 [SMILES: c1ccc(-c2ccc(-c3nc(-c4ccc(-c5cc6ccccc6c6ccccc56)cc4)nc(-c4ccc(-c5cccc6c5oc5ccccc56)cc4)n3)cc2)cc1]

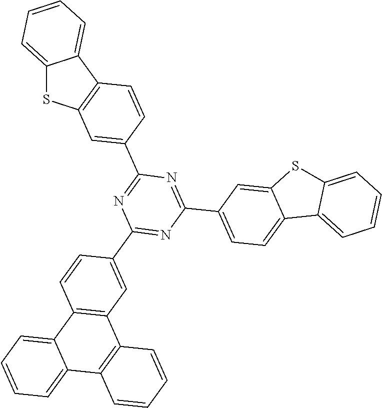 [SMILES: c1ccc2c(c1)sc1cc(-c3nc(-c4ccc5c(c4)sc4ccccc45)nc(-c4ccc5c6ccccc6c6ccccc6c5c4)n3)ccc12]

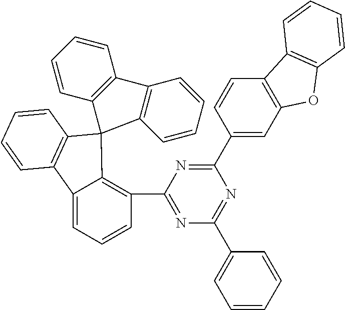 [SMILES: c1ccc(-c2nc(-c3ccc4c(c3)oc3ccccc34)nc(-c3cccc4c3C3(c5ccccc5-c5ccccc53)c3ccccc3-4)n2)cc1]

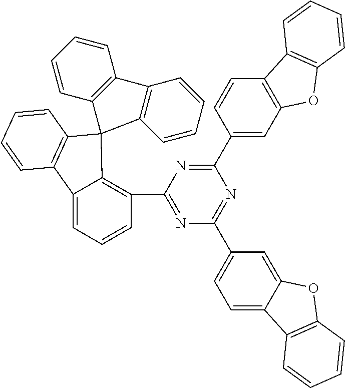 [SMILES: c1ccc2c(c1)-c1ccccc1C21c2ccccc2-c2cccc(-c3nc(-c4ccc5c(c4)oc4ccccc45)nc(-c4ccc5c(c4)oc4ccccc45)n3)c21]

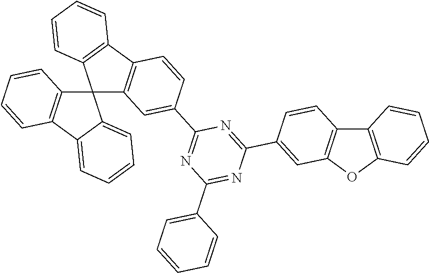 [SMILES: c1ccc(-c2nc(-c3ccc4c(c3)C3(c5ccccc5-c5ccccc53)c3ccccc3-4)nc(-c3ccc4c(c3)oc3ccccc34)n2)cc1]

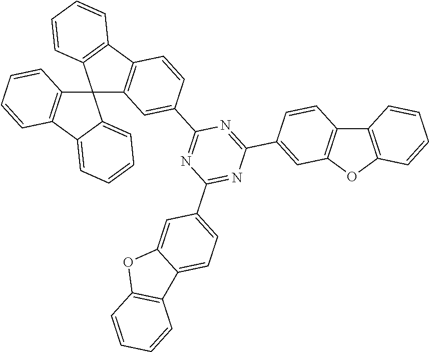 [SMILES: c1ccc2c(c1)-c1ccccc1C21c2ccccc2-c2ccc(-c3nc(-c4ccc5c(c4)oc4ccccc45)nc(-c4ccc5c(c4)oc4ccccc45)n3)cc21]

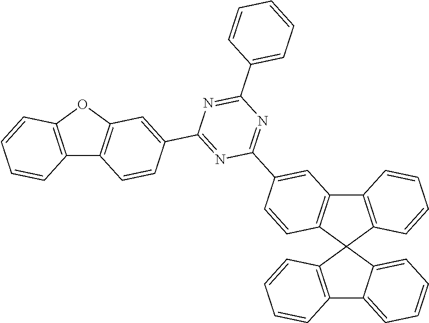 [SMILES: c1ccc(-c2nc(-c3ccc4c(c3)-c3ccccc3C43c4ccccc4-c4ccccc43)nc(-c3ccc4c(c3)oc3ccccc34)n2)cc1]

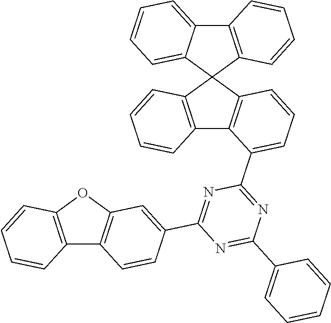 [SMILES: c1ccc(-c2nc(-c3ccc4c(c3)oc3ccccc34)nc(-c3cccc4c3-c3ccccc3C43c4ccccc4-c4ccccc43)n2)cc1]

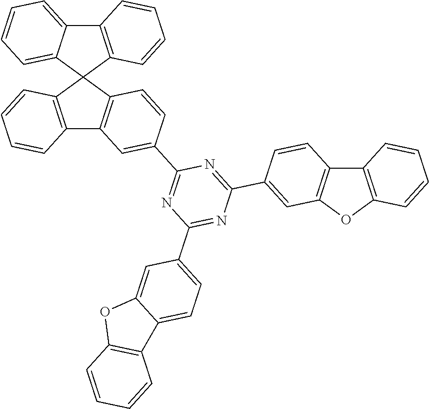 [SMILES: c1ccc2c(c1)-c1ccccc1C21c2ccccc2-c2cc(-c3nc(-c4ccc5c(c4)oc4ccccc45)nc(-c4ccc5c(c4)oc4ccccc45)n3)ccc21]

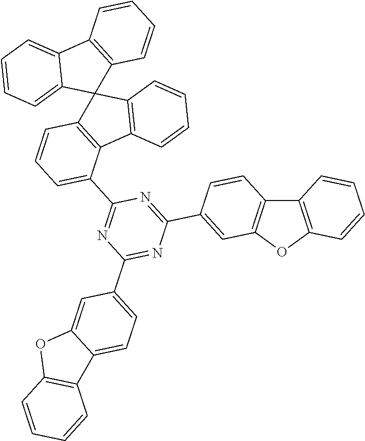 [SMILES: c1ccc2c(c1)-c1ccccc1C21c2ccccc2-c2c(-c3nc(-c4ccc5c(c4)oc4ccccc45)nc(-c4ccc5c(c4)oc4ccccc45)n3)cccc21]

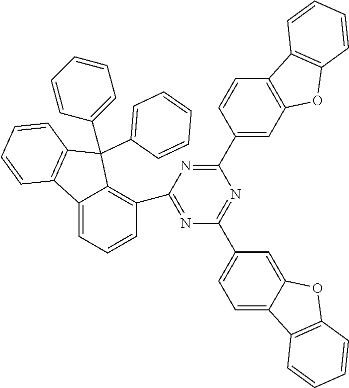 [SMILES: c1ccc(C2(c3ccccc3)c3ccccc3-c3cccc(-c4nc(-c5ccc6c(c5)oc5ccccc56)nc(-c5ccc6c(c5)oc5ccccc56)n4)c32)cc1]

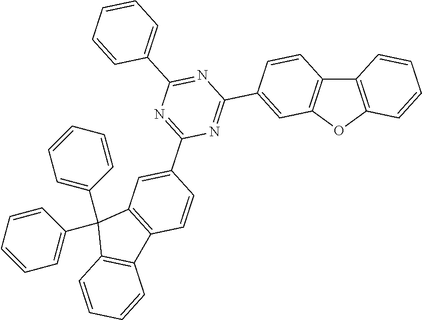 [SMILES: c1ccc(-c2nc(-c3ccc4c(c3)C(c3ccccc3)(c3ccccc3)c3ccccc3-4)nc(-c3ccc4c(c3)oc3ccccc34)n2)cc1]

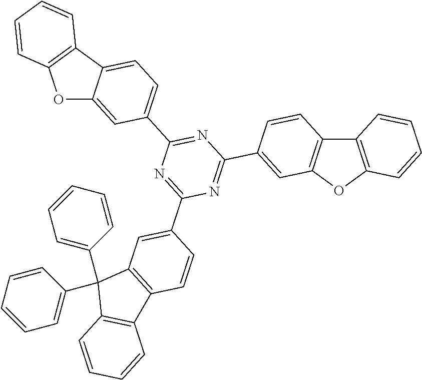 [SMILES: c1ccc(C2(c3ccccc3)c3ccccc3-c3ccc(-c4nc(-c5ccc6c(c5)oc5ccccc56)nc(-c5ccc6c(c5)oc5ccccc56)n4)cc32)cc1]

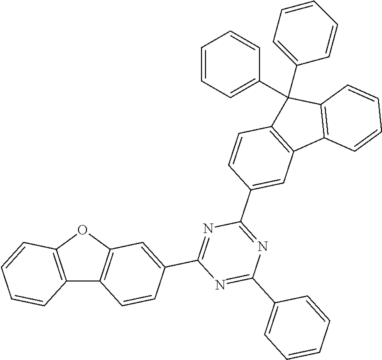 [SMILES: c1ccc(-c2nc(-c3ccc4c(c3)-c3ccccc3C4(c3ccccc3)c3ccccc3)nc(-c3ccc4c(c3)oc3ccccc34)n2)cc1]

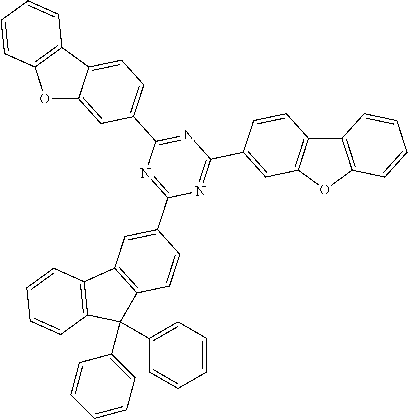 [SMILES: c1ccc(C2(c3ccccc3)c3ccccc3-c3cc(-c4nc(-c5ccc6c(c5)oc5ccccc56)nc(-c5ccc6c(c5)oc5ccccc56)n4)ccc32)cc1]

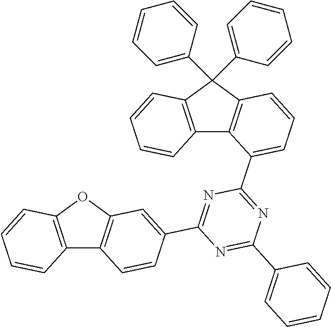 [SMILES: c1ccc(-c2nc(-c3ccc4c(c3)oc3ccccc34)nc(-c3cccc4c3-c3ccccc3C4(c3ccccc3)c3ccccc3)n2)cc1]

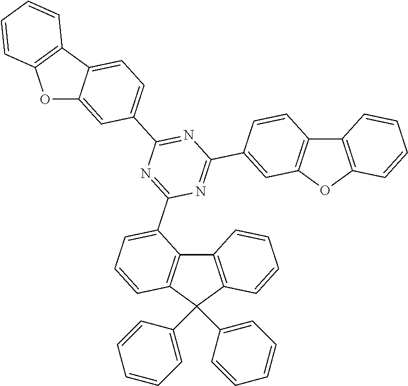 [SMILES: c1ccc(C2(c3ccccc3)c3ccccc3-c3c(-c4nc(-c5ccc6c(c5)oc5ccccc56)nc(-c5ccc6c(c5)oc5ccccc56)n4)cccc32)cc1]

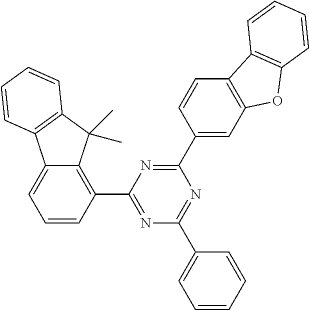 [SMILES: CC1(C)c2ccccc2-c2cccc(-c3nc(-c4ccccc4)nc(-c4ccc5c(c4)oc4ccccc45)n3)c21]

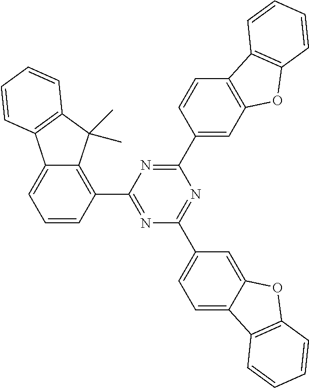 [SMILES: CC1(C)c2ccccc2-c2cccc(-c3nc(-c4ccc5c(c4)oc4ccccc45)nc(-c4ccc5c(c4)oc4ccccc45)n3)c21]

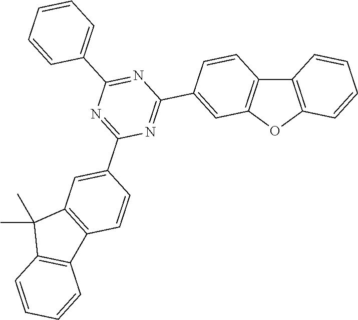 [SMILES: CC1(C)c2ccccc2-c2ccc(-c3nc(-c4ccccc4)nc(-c4ccc5c(c4)oc4ccccc45)n3)cc21]

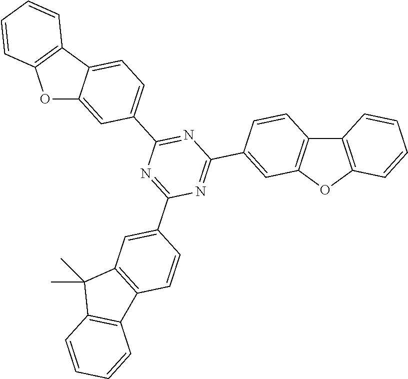 [SMILES: CC1(C)c2ccccc2-c2ccc(-c3nc(-c4ccc5c(c4)oc4ccccc45)nc(-c4ccc5c(c4)oc4ccccc45)n3)cc21]

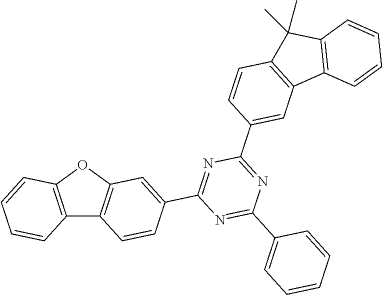 [SMILES: CC1(C)c2ccccc2-c2cc(-c3nc(-c4ccccc4)nc(-c4ccc5c(c4)oc4ccccc45)n3)ccc21]

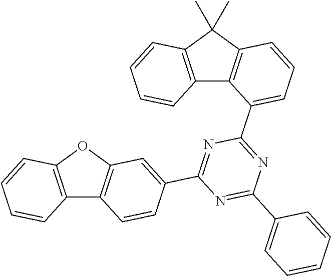 [SMILES: CC1(C)c2ccccc2-c2c(-c3nc(-c4ccccc4)nc(-c4ccc5c(c4)oc4ccccc45)n3)cccc21]

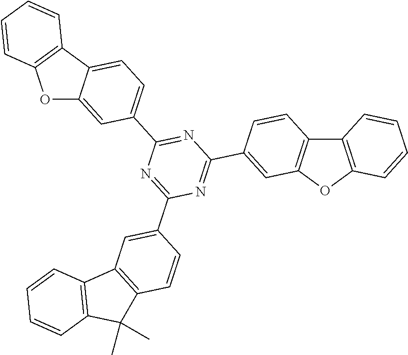 [SMILES: CC1(C)c2ccccc2-c2cc(-c3nc(-c4ccc5c(c4)oc4ccccc45)nc(-c4ccc5c(c4)oc4ccccc45)n3)ccc21]

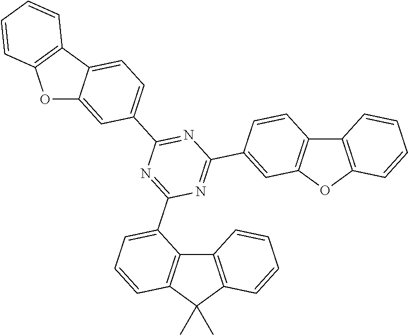 [SMILES: CC1(C)c2ccccc2-c2c(-c3nc(-c4ccc5c(c4)oc4ccccc45)nc(-c4ccc5c(c4)oc4ccccc45)n3)cccc21]

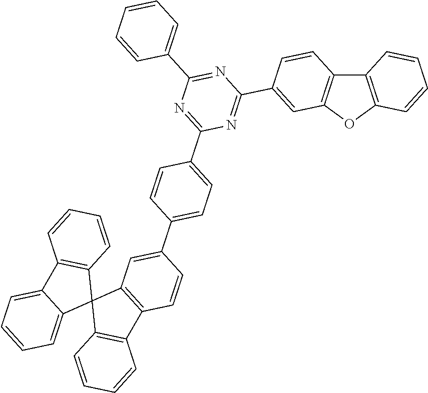 [SMILES: c1ccc(-c2nc(-c3ccc(-c4ccc5c(c4)C4(c6ccccc6-c6ccccc64)c4ccccc4-5)cc3)nc(-c3ccc4c(c3)oc3ccccc34)n2)cc1]

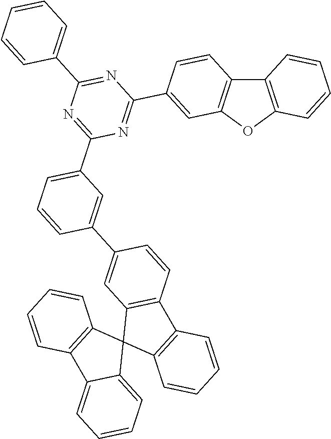 [SMILES: c1ccc(-c2nc(-c3cccc(-c4ccc5c(c4)C4(c6ccccc6-c6ccccc64)c4ccccc4-5)c3)nc(-c3ccc4c(c3)oc3ccccc34)n2)cc1]

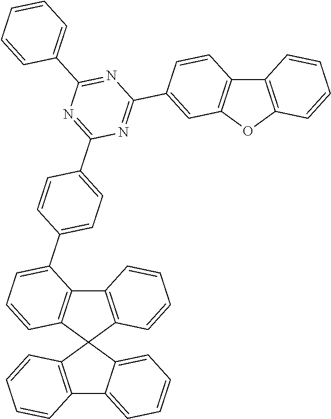 [SMILES: c1ccc(-c2nc(-c3ccc(-c4cccc5c4-c4ccccc4C54c5ccccc5-c5ccccc54)cc3)nc(-c3ccc4c(c3)oc3ccccc34)n2)cc1]

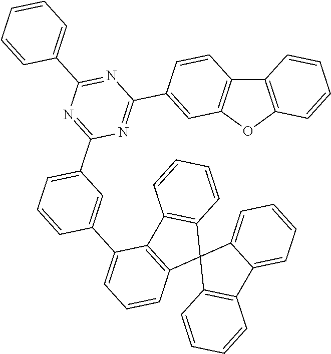 [SMILES: c1ccc(-c2nc(-c3cccc(-c4cccc5c4-c4ccccc4C54c5ccccc5-c5ccccc54)c3)nc(-c3ccc4c(c3)oc3ccccc34)n2)cc1]

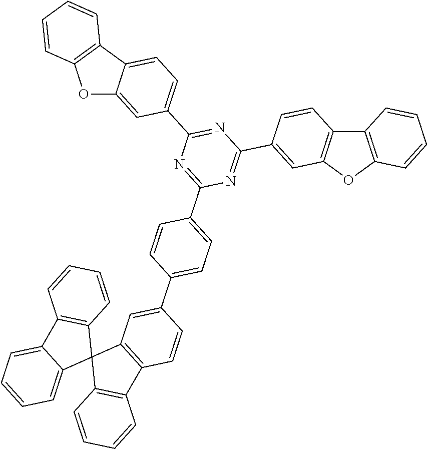 [SMILES: c1ccc2c(c1)-c1ccccc1C21c2ccccc2-c2ccc(-c3ccc(-c4nc(-c5ccc6c(c5)oc5ccccc56)nc(-c5ccc6c(c5)oc5ccccc56)n4)cc3)cc21]

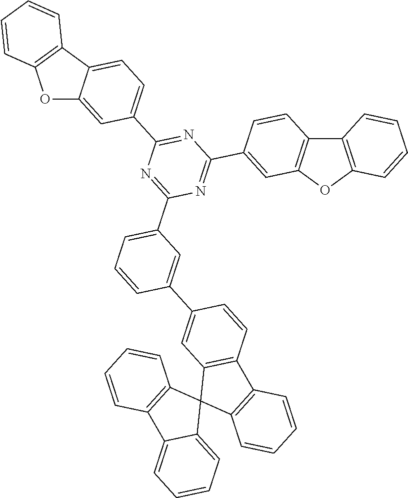 [SMILES: c1cc(-c2ccc3c(c2)C2(c4ccccc4-c4ccccc42)c2ccccc2-3)cc(-c2nc(-c3ccc4c(c3)oc3ccccc34)nc(-c3ccc4c(c3)oc3ccccc34)n2)c1]

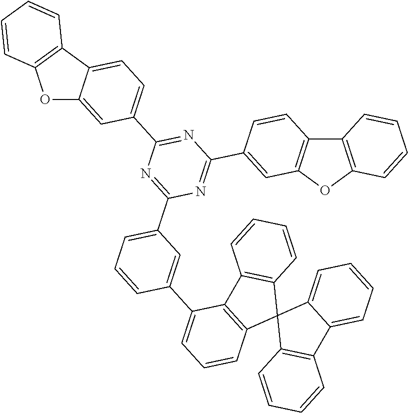 [SMILES: c1cc(-c2nc(-c3ccc4c(c3)oc3ccccc34)nc(-c3ccc4c(c3)oc3ccccc34)n2)cc(-c2cccc3c2-c2ccccc2C32c3ccccc3-c3ccccc32)c1]

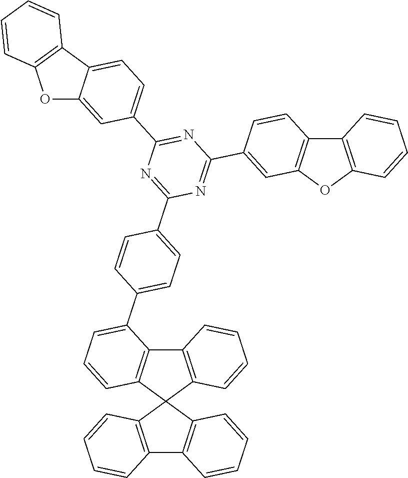 [SMILES: c1ccc2c(c1)-c1ccccc1C21c2ccccc2-c2c(-c3ccc(-c4nc(-c5ccc6c(c5)oc5ccccc56)nc(-c5ccc6c(c5)oc5ccccc56)n4)cc3)cccc21]

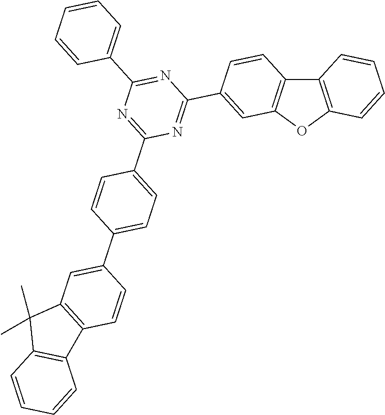 [SMILES: CC1(C)c2ccccc2-c2ccc(-c3ccc(-c4nc(-c5ccccc5)nc(-c5ccc6c(c5)oc5ccccc56)n4)cc3)cc21]

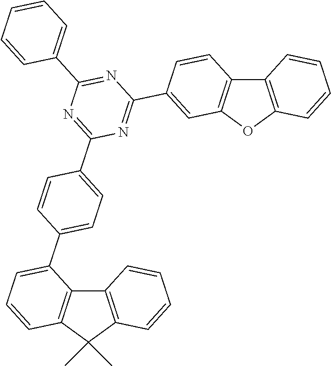 [SMILES: CC1(C)c2ccccc2-c2c(-c3ccc(-c4nc(-c5ccccc5)nc(-c5ccc6c(c5)oc5ccccc56)n4)cc3)cccc21]

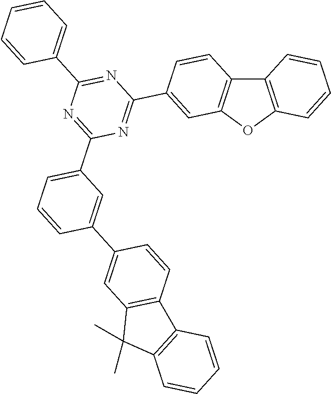 [SMILES: CC1(C)c2ccccc2-c2ccc(-c3cccc(-c4nc(-c5ccccc5)nc(-c5ccc6c(c5)oc5ccccc56)n4)c3)cc21]

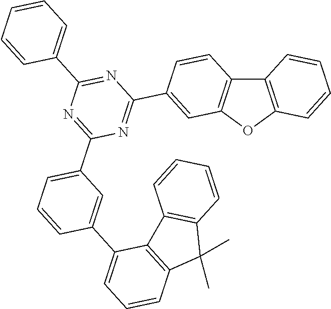 [SMILES: CC1(C)c2ccccc2-c2c(-c3cccc(-c4nc(-c5ccccc5)nc(-c5ccc6c(c5)oc5ccccc56)n4)c3)cccc21]

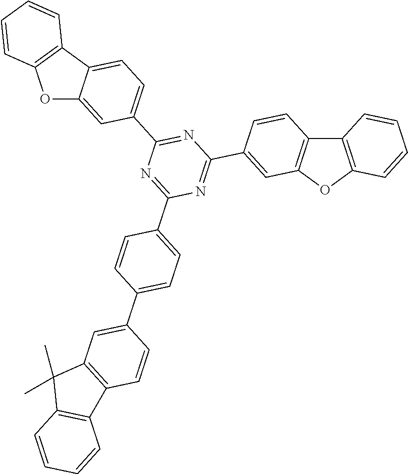 [SMILES: CC1(C)c2ccccc2-c2ccc(-c3ccc(-c4nc(-c5ccc6c(c5)oc5ccccc56)nc(-c5ccc6c(c5)oc5ccccc56)n4)cc3)cc21]

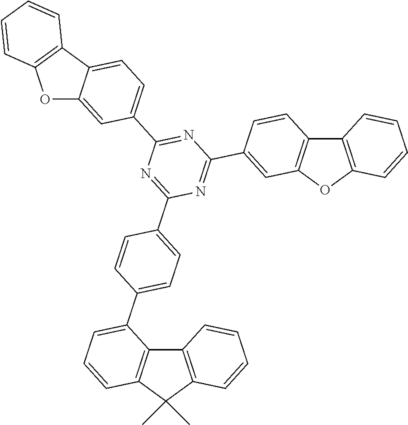 [SMILES: CC1(C)c2ccccc2-c2c(-c3ccc(-c4nc(-c5ccc6c(c5)oc5ccccc56)nc(-c5ccc6c(c5)oc5ccccc56)n4)cc3)cccc21]

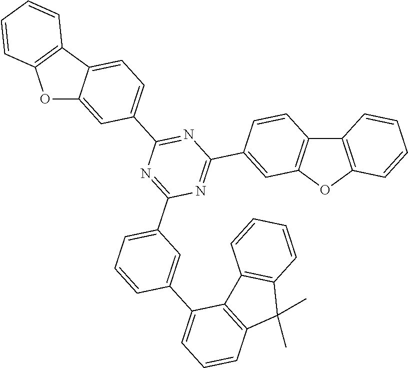 [SMILES: CC1(C)c2ccccc2-c2c(-c3cccc(-c4nc(-c5ccc6c(c5)oc5ccccc56)nc(-c5ccc6c(c5)oc5ccccc56)n4)c3)cccc21]

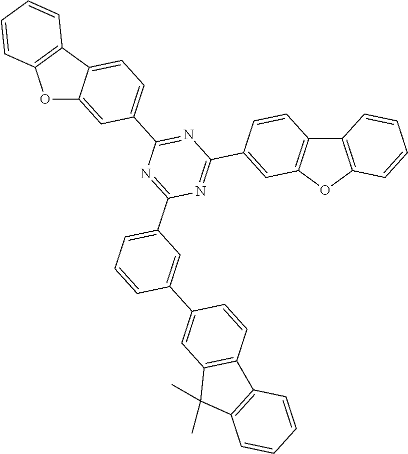 [SMILES: CC1(C)c2ccccc2-c2ccc(-c3cccc(-c4nc(-c5ccc6c(c5)oc5ccccc56)nc(-c5ccc6c(c5)oc5ccccc56)n4)c3)cc21]

The electronic device of the invention is preferably an organic electroluminescent device. The first electrode of the device is preferably the anode, and the second electrode is preferably the cathode.

In a preferred embodiment, layer E is an electron transport layer, especially a layer which is disposed between emitting layer and cathode and does not directly adjoin the emitting layer. In this case, it is preferable that layer E comprises a compound of the formula (E-1) in which three V groups are N, and the remaining V groups are CR⁴. In this case, it is particularly preferable that the group

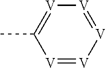

in formula (E-1) is 1,3,5-triazinyl substituted by R⁴ radicals.

In a preferred embodiment, layer E, especially when it is an electron transport layer, comprises a mixture of an alkali metal salt and a further compound. The further compound is preferably nonionic. Further preferably, the alkali metal salt is a lithium salt. The alkali metal salt is preferably a salt with an organic anion, more preferably 8-hydroxyquinolinate. Very particular preference is given to lithium 8-hydroxyquinolinate (LiQ).

Preferred cathodes of the electronic device are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used.

It may also be preferable to introduce a thin interlayer of a material having a high dielectric constant between a metallic cathode and the organic semiconductor. This layer is also referred to as electron injection layer. Materials used for this layer are preferably alkali metal or alkaline earth metal fluorides, but also the corresponding oxides or carbonates (e.g. LiF, Li₂O, BaF₂, MgO, NaF, CsF, Cs2CO₃, etc.). In a preferred embodiment, a mixture of a lanthanoid and a salt selected from alkali metal fluoride, alkaline earth metal fluoride, alkali metal oxide, alkaline earth metal oxide, alkali metal carbonate and alkaline earth metal carbonate is used for this purpose, especially a mixture of ytterbium (Yb) and LiF. In an alternative preferred embodiment, lithium quinolinate (LiQ) is used for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOx, Al/PtOx) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

The electronic device preferably comprises at least one further layer in addition to the emitting layer comprising a compound of the formula (EM-1) and to layer E. More preferably, this at least one further layer is disposed between the anode and the emitting layer. It is additionally more preferable that this at least one further layer is a hole-transporting layer. The term “hole-transporting layer” here encompasses the specific embodiments of hole injection layer (HIL), hole transport layer (HTL) and electron blocker layer (EBL).

Specifically, a hole injection layer is understood to mean a layer that directly adjoins the anode. In a preferred embodiment, this layer comprises a p-dopant and at least one hole-transporting compound. The latter is preferably selected from triarylamine compounds, more preferably from monotriarylamine compounds. It is most preferably selected from the preferred embodiments of hole transport materials that are specified further down. The p-dopants are likewise preferably selected from the preferred embodiments of p-dopants that are specified further down. In an alternative preferred embodiment, the hole injection layer comprises a compound having a low LUMO (LUMO=lowest unoccupied molecular orbital) as a main component or in pure form. The compound is preferably selected from derivatives of hexaazatriphenylene, as described in US 2007/0092755.

It is preferable that the electronic device comprises a hole injection layer. It preferably conforms to the preferred embodiments mentioned above. It is especially preferred that it comprises a p-dopant and a hole-transporting material that is a triarylamine compound.

Specifically, an electron blocker layer (EBL) is understood to mean a layer that directly adjoins the emitting layer on the anode side. The electron blocker layer may comprise one or more hole-transporting compounds, preferably one hole-transporting compound. The latter is preferably selected from triarylamine compounds, more preferably from monotriarylamine compounds. With very particular preference they are selected from the preferred embodiments of hole transport materials that are indicated later on below.

Specifically, a hole transport layer (HTL) is understood to mean a layer disposed between the hole injection layer and the electron blocker layer. In a preferred embodiment, this layer comprises a p-dopant and at least one hole-transporting compound. The latter is preferably selected from triarylamine compounds, more preferably from monotriarylamine compounds. With very particular preference they are selected from the preferred embodiments of hole transport materials that are indicated later on below. The p-dopants are likewise preferably selected from the preferred embodiments of p-dopants that are specified further down.

In an alternative preferred embodiment, the hole transport layer comprises a mixture of two or more hole-transporting compounds. These are preferably selected from triarylamine compounds, more preferably from monotriarylamine compounds. With very particular preference they are selected from the preferred embodiments of hole transport materials that are indicated later on below. The two or more hole-transporting compounds are preferably each present in the layer in a proportion of at least 20%, more preferably each in a proportion of at least 30%.

In the present application, figures in % are understood to mean % by volume where mixtures of compounds that are applied from the gas phase are concerned. By contrast, this is understood to mean % by mass where mixtures that are applied from solution are concerned.

In an alternative preferred embodiment, the hole transport layer comprises a single hole-transporting compound. This is preferably selected from triarylamine compounds, more preferably from monotriarylamine compounds. They are most preferably selected from the preferred embodiments of hole transport materials that are specified further down. p-Dopants used according to the present application are preferably those organic electron acceptor compounds capable of oxidizing one or more of the other compounds in the layer with which the p-dopant has been mixed.

Particularly preferred as p-dopants are quinodimethane compounds, azaindenofluorenediones, azaphenalenes, azatriphenylenes, I₂, metal halides, preferably transition metal halides, metal oxides, preferably metal oxides comprising at least one transition metal or a metal from main group 3, and transition metal complexes, preferably complexes of Cu, Co, Ni, Pd and Pt with ligands containing at least one oxygen atom as binding site.

Preference is further given to transition metal oxides as dopants, preferably oxides of rhenium, molybdenum and tungsten, more preferably Re₂O₇, MoO₃, WO₃ and ReO₃. Still further preference is given to complexes of bismuth in the (Ill) oxidation state, more particularly bismuth(III) complexes with electron-deficient ligands, more particularly carboxylate ligands.

The p-dopants are preferably in substantially homogeneous distribution in the p-doped layers. This can be achieved, for example, by co-evaporation of the p-dopant and the hole transport material matrix. The p-dopant is preferably present in a proportion of 1% to 10% in the p-doped layer.

Preferred p-dopants are especially the following compounds:

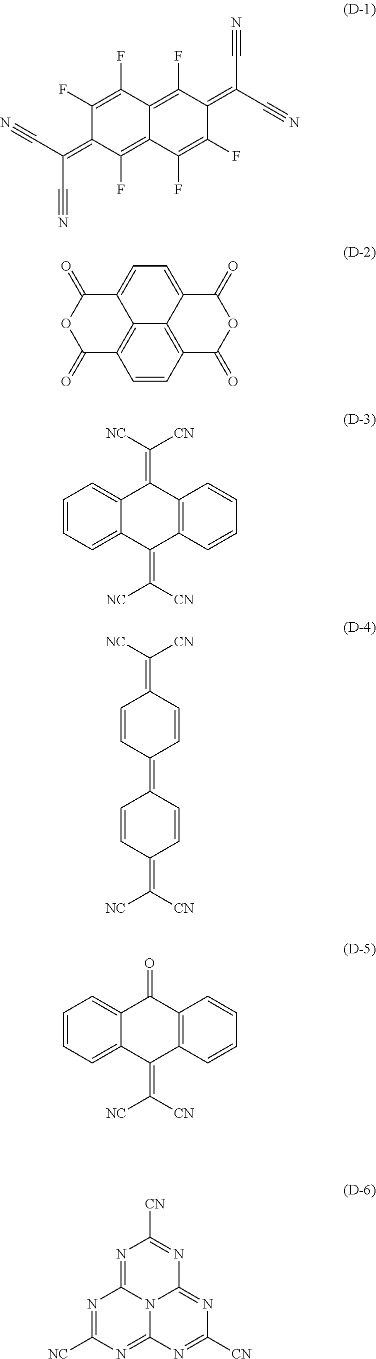

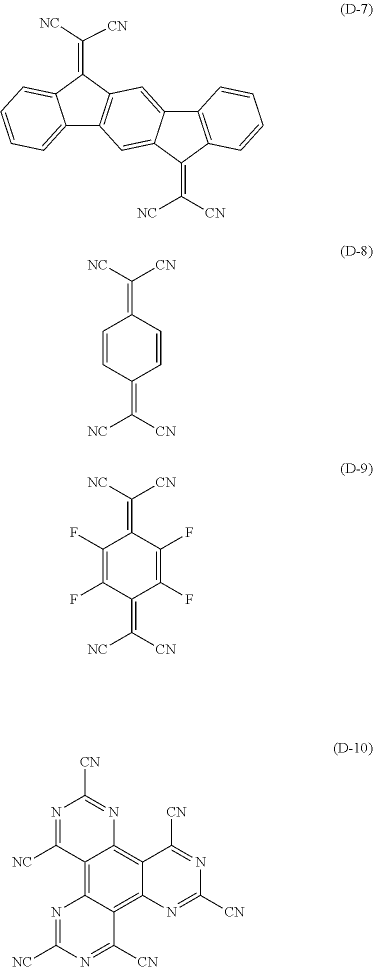 [SMILES: N#CC(C#N)=C1c2ccccc2-c2cc3c(cc21)-c1ccccc1C3=C(C#N)C#N ; N#CC(C#N)=c1ccc(=C(C#N)C#N)cc1 ; N#CC(C#N)=c1c(F)c(F)c(=C(C#N)C#N)c(F)c1F ; N#Cc1nc(C#N)c2c(n1)c1c(C#N)nc(C#N)nc1c1c(C#N)nc(C#N)nc21]

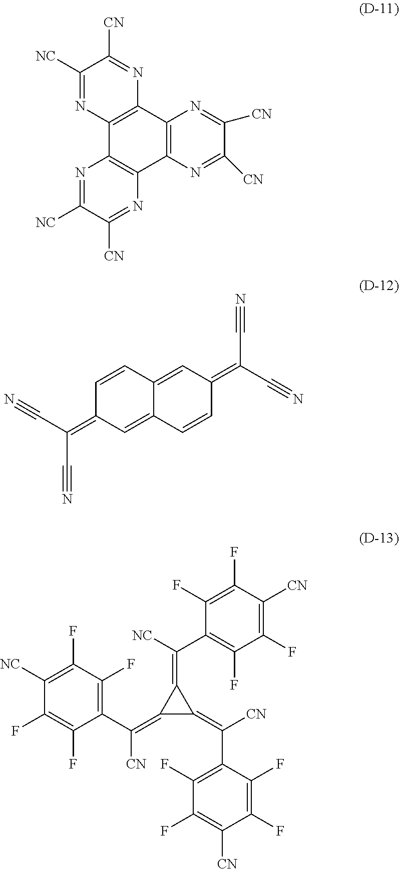 [SMILES: N#Cc1nc2c3nc(C#N)c(C#N)nc3c3nc(C#N)c(C#N)nc3c2nc1C#N ; N#CC(C#N)=c1ccc2cc(=C(C#N)C#N)ccc2c1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

Hole-transporting compounds used are preferably indenofluoreneamine derivatives, amine derivatives, hexaazatriphenylene derivatives, amine derivatives with fused aromatic systems, monobenzoindenofluoreneamines, dibenzoindenofluoreneamines, spirobifluoreneamines, fluoreneamines, spirodibenzopyranamines, dihydroacridine derivatives, spirodibenzofurans and spirodibenzothiophenes, phenanthrenediarylamines, spirotribenzotropolones, spirobifluorenes having meta-phenyldiamine groups, spirobisacridines, xanthenediarylamines, and 9,10-dihydroanthracene spiro compounds having diarylamino groups. The amine compounds mentioned are preferably monoamine compounds. Explicit examples of compounds for use in hole-transporting layers are shown in the following table:

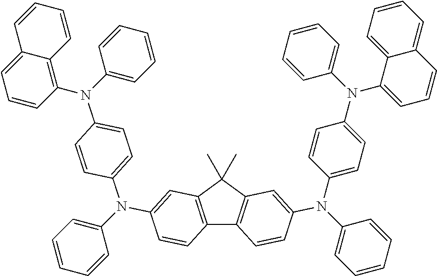 [SMILES: CC1(C)c2cc(N(c3ccccc3)c3ccc(N(c4ccccc4)c4cccc5ccccc45)cc3)ccc2-c2ccc(N(c3ccccc3)c3ccc(N(c4ccccc4)c4cccc5ccccc45)cc3)cc21]

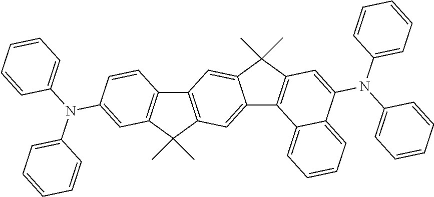 [SMILES: CC1(C)c2cc(N(c3ccccc3)c3ccccc3)ccc2-c2cc3c(cc21)-c1c(cc(N(c2ccccc2)c2ccccc2)c2ccccc12)C3(C)C]

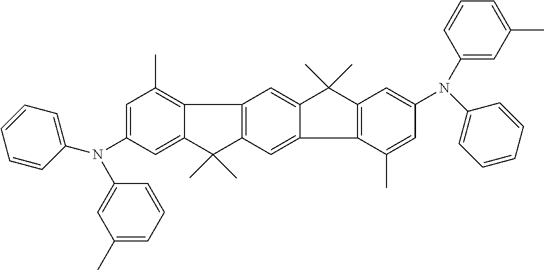 [SMILES: Cc1cccc(N(c2ccccc2)c2cc(C)c3c(c2)C(C)(C)c2cc4c(cc2-3)C(C)(C)c2cc(N(c3ccccc3)c3cccc(C)c3)cc(C)c2-4)c1]

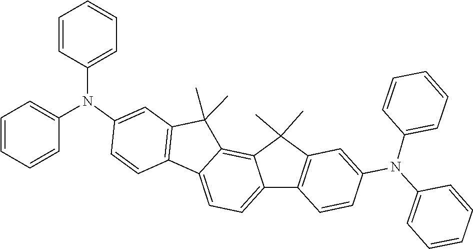 [SMILES: CC1(C)c2cc(N(c3ccccc3)c3ccccc3)ccc2-c2ccc3c(c21)C(C)(C)c1cc(N(c2ccccc2)c2ccccc2)ccc1-3]

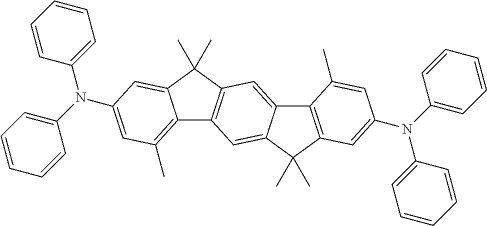 [SMILES: Cc1cc(N(c2ccccc2)c2ccccc2)cc2c1-c1cc3c(cc1C2(C)C)-c1c(C)cc(N(c2ccccc2)c2ccccc2)cc1C3(C)C]

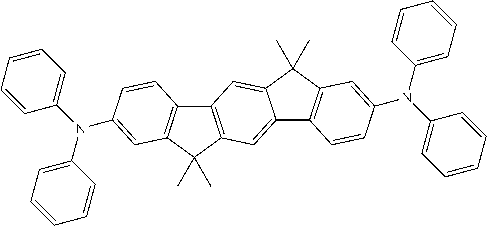 [SMILES: CC1(C)c2cc(N(c3ccccc3)c3ccccc3)ccc2-c2cc3c(cc21)-c1ccc(N(c2ccccc2)c2ccccc2)cc1C3(C)C]

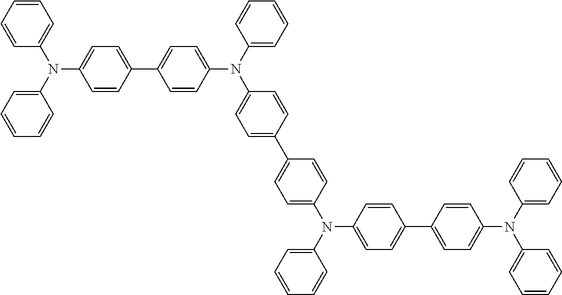 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

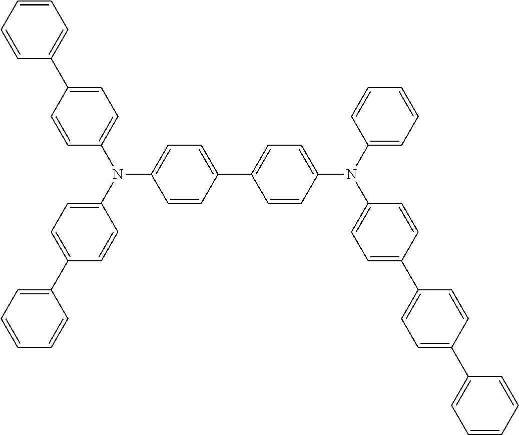 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

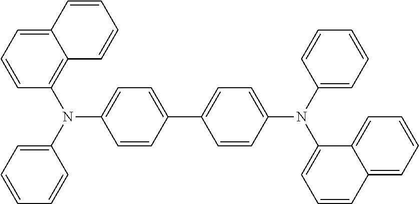 [SMILES: c1ccc(N(c2ccc(-c3ccc(N(c4ccccc4)c4cccc5ccccc45)cc3)cc2)c2cccc3ccccc23)cc1]

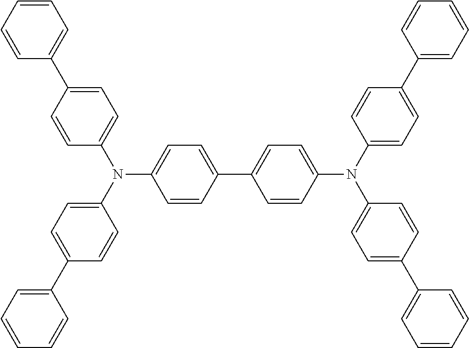 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

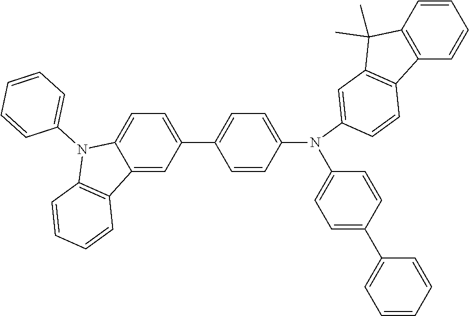 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

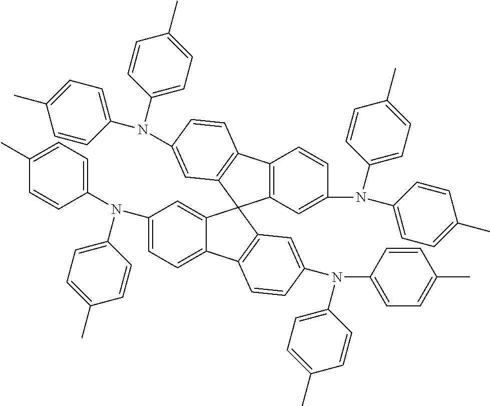

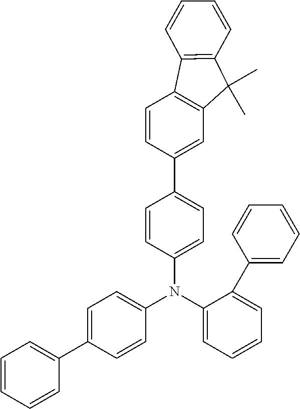 [SMILES: CC1(C)c2ccccc2-c2ccc(-c3ccc(N(c4ccc(-c5ccccc5)cc4)c4ccccc4-c4ccccc4)cc3)cc21]

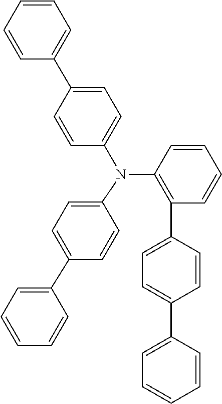 [SMILES: c1ccc(-c2ccc(-c3ccccc3N(c3ccc(-c4ccccc4)cc3)c3ccc(-c4ccccc4)cc3)cc2)cc1]

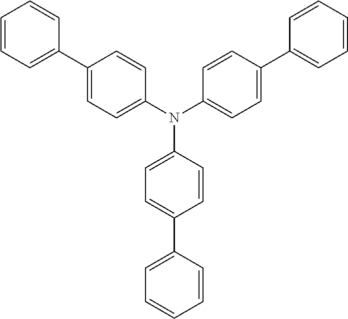 [SMILES: c1ccc(-c2ccc(N(c3ccc(-c4ccccc4)cc3)c3ccc(-c4ccccc4)cc3)cc2)cc1]

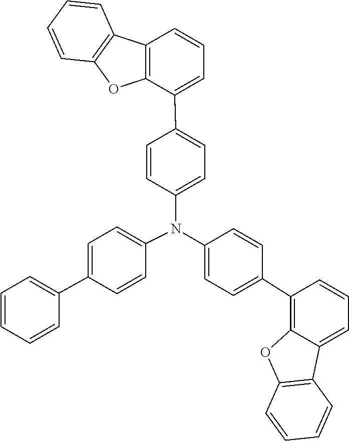 [SMILES: c1ccc(-c2ccc(N(c3ccc(-c4cccc5c4oc4ccccc45)cc3)c3ccc(-c4cccc5c4oc4ccccc45)cc3)cc2)cc1]

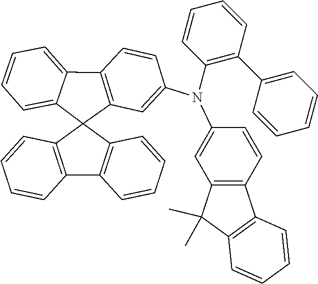 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

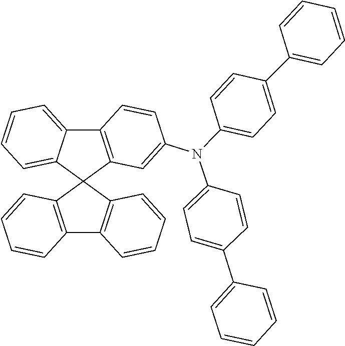 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

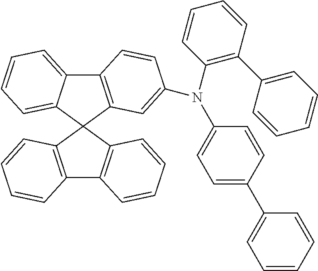 [SMILES: c1ccc(-c2ccc(N(c3ccc4c(c3)C3(c5ccccc5-c5ccccc53)c3ccccc3-4)c3ccccc3-c3ccccc3)cc2)cc1]

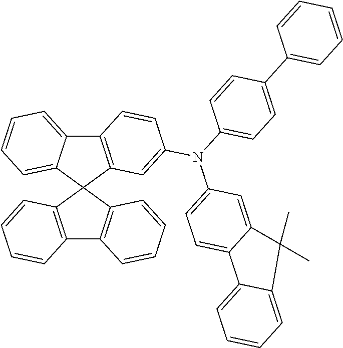 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21]

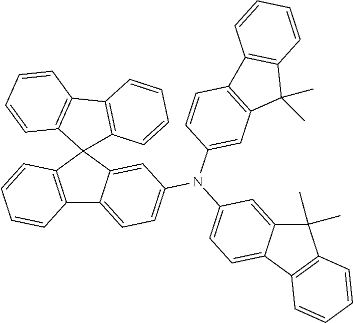 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21]

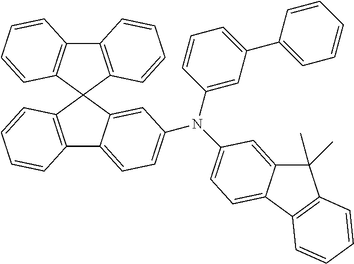 [SMILES: CC1(C)c2ccccc2-c2ccc(N(c3cccc(-c4ccccc4)c3)c3ccc4c(c3)C3(c5ccccc5-c5ccccc53)c3ccccc3-4)cc21]

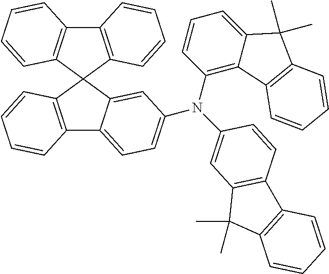 [SMILES: CC1(C)c2ccccc2-c2ccc(N(c3ccc4c(c3)C3(c5ccccc5-c5ccccc53)c3ccccc3-4)c3cccc4c3-c3ccccc3C4(C)C)cc21]

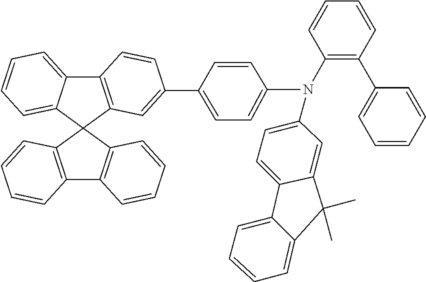 [SMILES: CC1(C)c2ccccc2-c2ccc(N(c3ccc(-c4ccc5c(c4)C4(c6ccccc6-c6ccccc64)c4ccccc4-5)cc3)c3ccccc3-c3ccccc3)cc21]

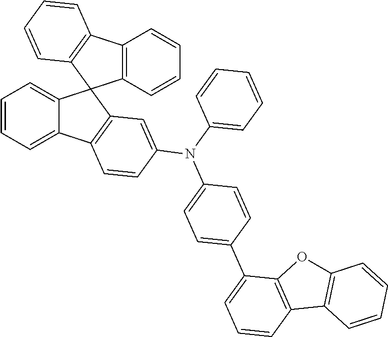 [SMILES: c1ccc(N(c2ccc(-c3cccc4c3oc3ccccc34)cc2)c2ccc3c(c2)C2(c4ccccc4-c4ccccc42)c2ccccc2-3)cc1]

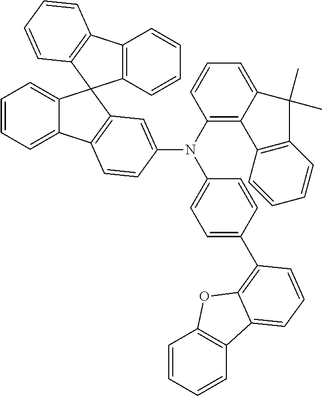 [SMILES: CC1(C)c2ccccc2-c2c(N(c3ccc(-c4cccc5c4oc4ccccc45)cc3)c3ccc4c(c3)C3(c5ccccc5-c5ccccc53)c3ccccc3-4)cccc21]

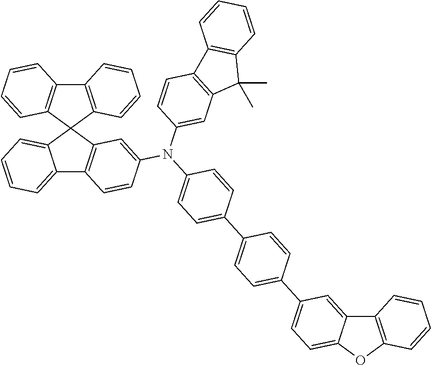 [SMILES: CC1(C)c2ccccc2-c2ccc(N(c3ccc(-c4ccc(-c5ccc6oc7ccccc7c6c5)cc4)cc3)c3ccc4c(c3)C3(c5ccccc5-c5ccccc53)c3ccccc3-4)cc21]

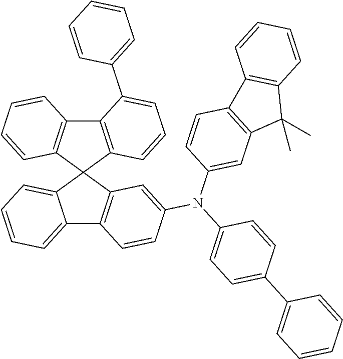 [SMILES: CC1(C)c2ccccc2-c2ccc(N(c3ccc(-c4ccccc4)cc3)c3ccc4c(c3)C3(c5ccccc5-4)c4ccccc4-c4c(-c5ccccc5)cccc43)cc21]

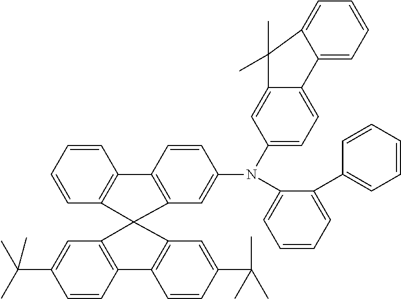 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

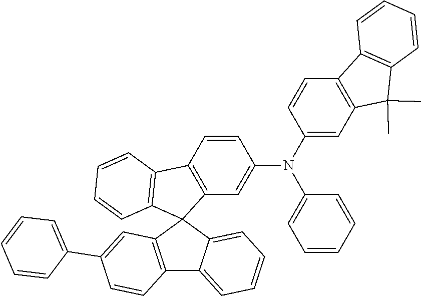 [SMILES: CC1(C)c2ccccc2-c2ccc(N(c3ccccc3)c3ccc4c(c3)C3(c5ccccc5-c5ccc(-c6ccccc6)cc53)c3ccccc3-4)cc21]

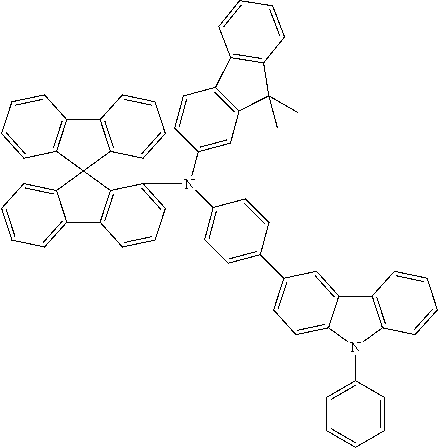 [SMILES: CC1(C)c2ccccc2-c2ccc(N(c3ccc(-c4ccc5c(c4)c4ccccc4n5-c4ccccc4)cc3)c3cccc4c3C3(c5ccccc5-c5ccccc53)c3ccccc3-4)cc21]

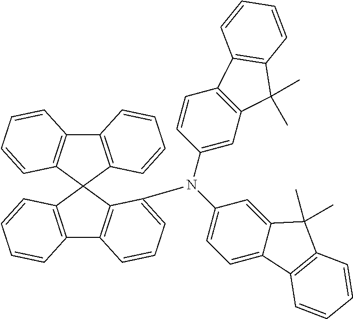 [SMILES: CC1(C)c2ccccc2-c2ccc(N(c3ccc4c(c3)C(C)(C)c3ccccc3-4)c3cccc4c3C3(c5ccccc5-c5ccccc53)c3ccccc3-4)cc21]

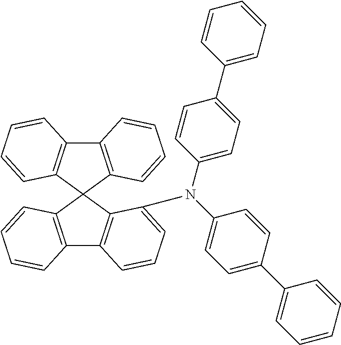 [SMILES: c1ccc(-c2ccc(N(c3ccc(-c4ccccc4)cc3)c3cccc4c3C3(c5ccccc5-c5ccccc53)c3ccccc3-4)cc2)cc1]

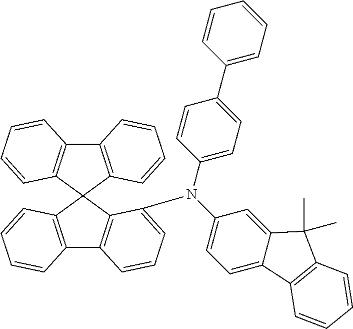 [SMILES: CC1(C)c2ccccc2-c2ccc(N(c3ccc(-c4ccccc4)cc3)c3cccc4c3C3(c5ccccc5-c5ccccc53)c3ccccc3-4)cc21]

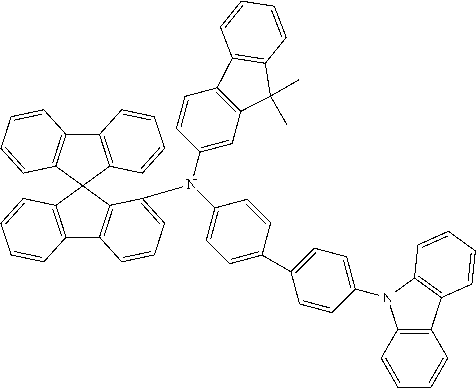 [SMILES: CC1(C)c2ccccc2-c2ccc(N(c3ccc(-c4ccc(-n5c6ccccc6c6ccccc65)cc4)cc3)c3cccc4c3C3(c5ccccc5-c5ccccc53)c3ccccc3-4)cc21]

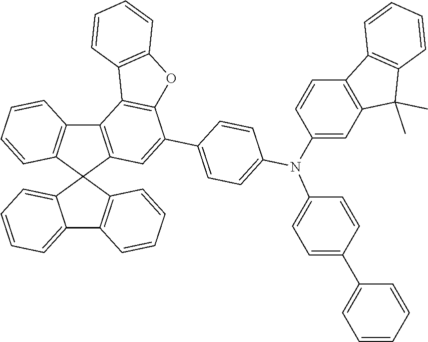 [SMILES: CC1(C)c2ccccc2-c2ccc(N(c3ccc(-c4ccccc4)cc3)c3ccc(-c4cc5c(c6c4oc4ccccc46)-c4ccccc4C54c5ccccc5-c5ccccc54)cc3)cc21]

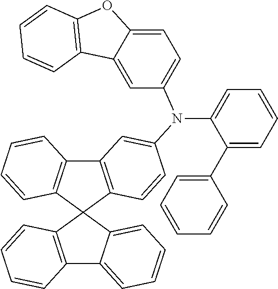 [SMILES: c1ccc(-c2ccccc2N(c2ccc3c(c2)-c2ccccc2C32c3ccccc3-c3ccccc32)c2ccc3oc4ccccc4c3c2)cc1]

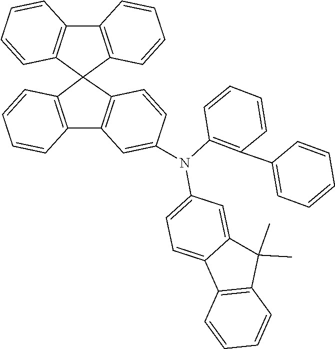 [SMILES: CC1(C)c2ccccc2-c2ccc(N(c3ccc4c(c3)-c3ccccc3C43c4ccccc4-c4ccccc43)c3ccccc3-c3ccccc3)cc21]

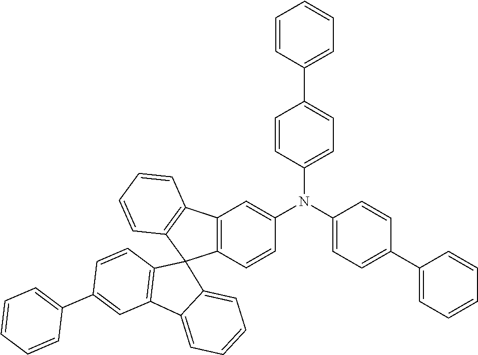 [SMILES: c1ccc(-c2ccc(N(c3ccc(-c4ccccc4)cc3)c3ccc4c(c3)-c3ccccc3C43c4ccccc4-c4cc(-c5ccccc5)ccc43)cc2)cc1]

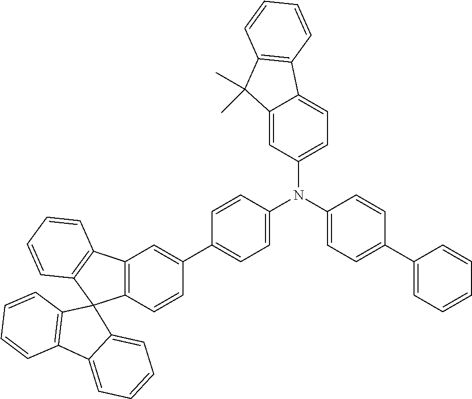 [SMILES: CC1(C)c2ccccc2-c2ccc(N(c3ccc(-c4ccccc4)cc3)c3ccc(-c4ccc5c(c4)-c4ccccc4C54c5ccccc5-c5ccccc54)cc3)cc21]

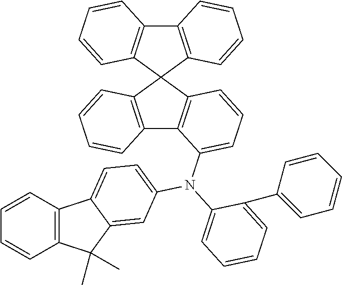 [SMILES: CC1(C)c2ccccc2-c2ccc(N(c3ccccc3-c3ccccc3)c3cccc4c3-c3ccccc3C43c4ccccc4-c4ccccc43)cc21]

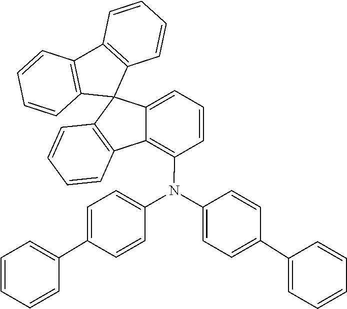 [SMILES: c1ccc(-c2ccc(N(c3ccc(-c4ccccc4)cc3)c3cccc4c3-c3ccccc3C43c4ccccc4-c4ccccc43)cc2)cc1]

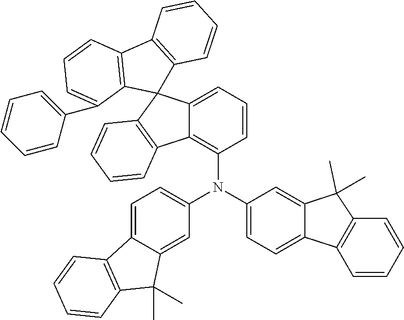 [SMILES: CC1(C)c2ccccc2-c2ccc(N(c3ccc4c(c3)C(C)(C)c3ccccc3-4)c3cccc4c3-c3ccccc3C43c4ccccc4-c4cccc(-c5ccccc5)c43)cc21]

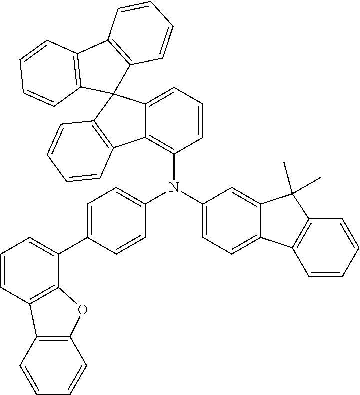 [SMILES: CC1(C)c2ccccc2-c2ccc(N(c3ccc(-c4cccc5c4oc4ccccc45)cc3)c3cccc4c3-c3ccccc3C43c4ccccc4-c4ccccc43)cc21]

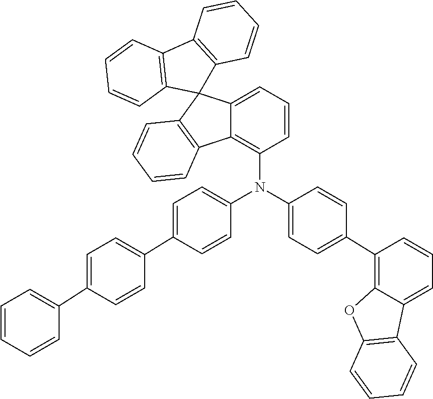 [SMILES: c1ccc(-c2ccc(-c3ccc(N(c4ccc(-c5cccc6c5oc5ccccc56)cc4)c4cccc5c4-c4ccccc4C54c5ccccc5-c5ccccc54)cc3)cc2)cc1]

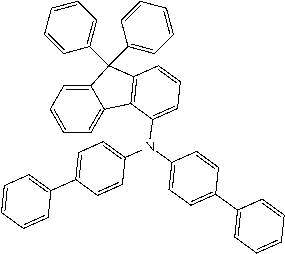 [SMILES: c1ccc(-c2ccc(N(c3ccc(-c4ccccc4)cc3)c3cccc4c3-c3ccccc3C4(c3ccccc3)c3ccccc3)cc2)cc1]

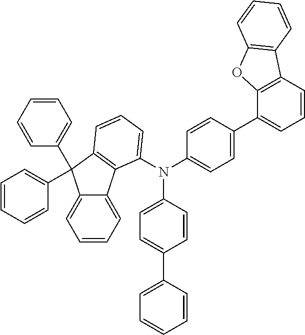 [SMILES: c1ccc(-c2ccc(N(c3ccc(-c4cccc5c4oc4ccccc45)cc3)c3cccc4c3-c3ccccc3C4(c3ccccc3)c3ccccc3)cc2)cc1]

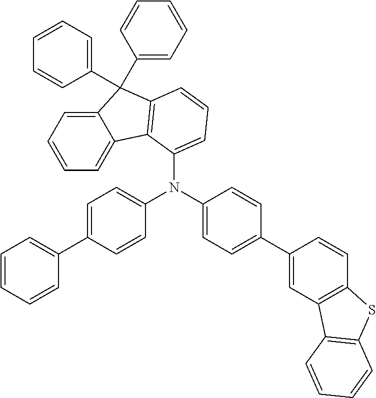 [SMILES: c1ccc(-c2ccc(N(c3ccc(-c4ccc5sc6ccccc6c5c4)cc3)c3cccc4c3-c3ccccc3C4(c3ccccc3)c3ccccc3)cc2)cc1]

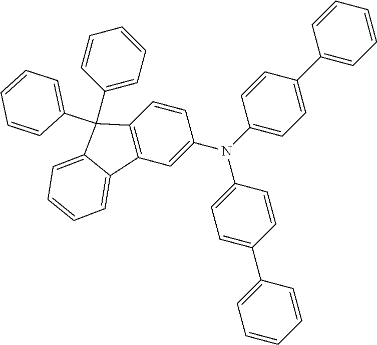 [SMILES: c1ccc(-c2ccc(N(c3ccc(-c4ccccc4)cc3)c3ccc4c(c3)-c3ccccc3C4(c3ccccc3)c3ccccc3)cc2)cc1]

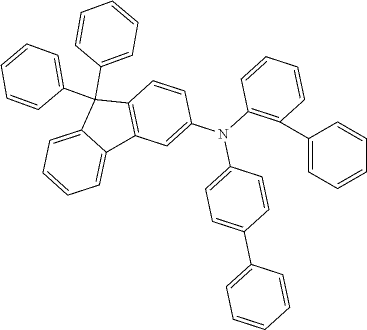 [SMILES: c1ccc(-c2ccc(N(c3ccc4c(c3)-c3ccccc3C4(c3ccccc3)c3ccccc3)c3ccccc3-c3ccccc3)cc2)cc1]

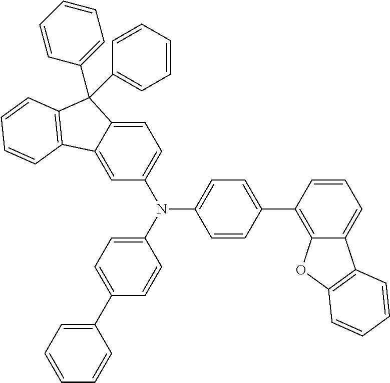 [SMILES: c1ccc(-c2ccc(N(c3ccc(-c4cccc5c4oc4ccccc45)cc3)c3ccc4c(c3)-c3ccccc3C4(c3ccccc3)c3ccccc3)cc2)cc1]

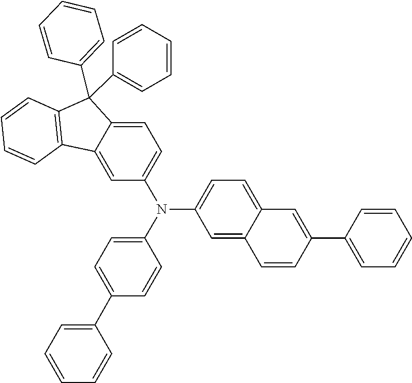 [SMILES: c1ccc(-c2ccc(N(c3ccc4c(c3)-c3ccccc3C4(c3ccccc3)c3ccccc3)c3ccc4cc(-c5ccccc5)ccc4c3)cc2)cc1]

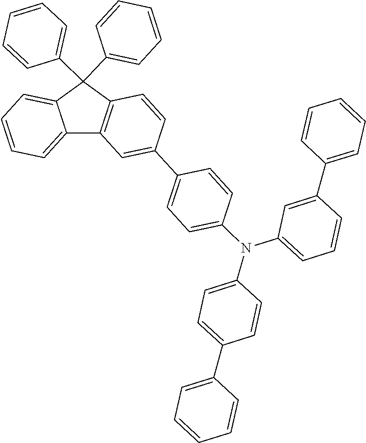 [SMILES: c1ccc(-c2ccc(N(c3ccc(-c4ccc5c(c4)-c4ccccc4C5(c4ccccc4)c4ccccc4)cc3)c3cccc(-c4ccccc4)c3)cc2)cc1]

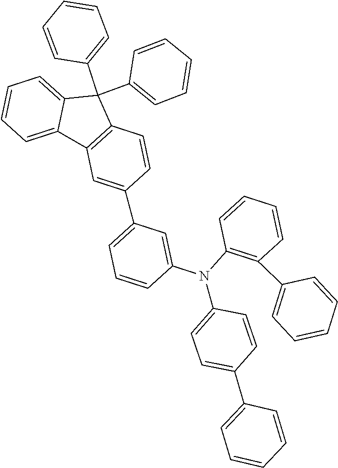 [SMILES: c1ccc(-c2ccc(N(c3cccc(-c4ccc5c(c4)-c4ccccc4C5(c4ccccc4)c4ccccc4)c3)c3ccccc3-c3ccccc3)cc2)cc1]

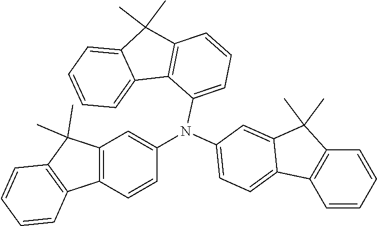 [SMILES: CC1(C)c2ccccc2-c2ccc(N(c3ccc4c(c3)C(C)(C)c3ccccc3-4)c3cccc4c3-c3ccccc3C4(C)C)cc21]

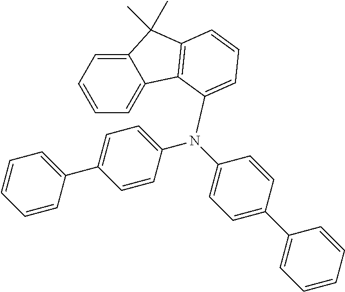 [SMILES: CC1(C)c2ccccc2-c2c(N(c3ccc(-c4ccccc4)cc3)c3ccc(-c4ccccc4)cc3)cccc21]

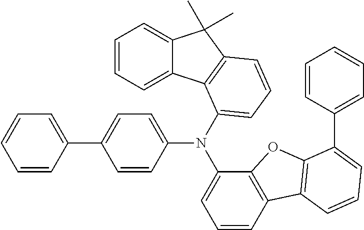 [SMILES: CC1(C)c2ccccc2-c2c(N(c3ccc(-c4ccccc4)cc3)c3cccc4c3oc3c(-c5ccccc5)cccc34)cccc21]

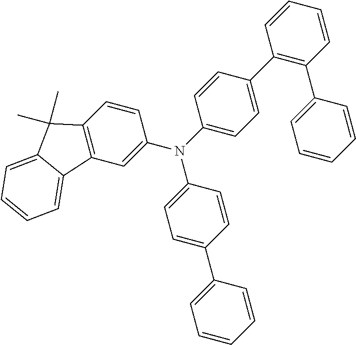 [SMILES: CC1(C)c2ccccc2-c2cc(N(c3ccc(-c4ccccc4)cc3)c3ccc(-c4ccccc4-c4ccccc4)cc3)ccc21]

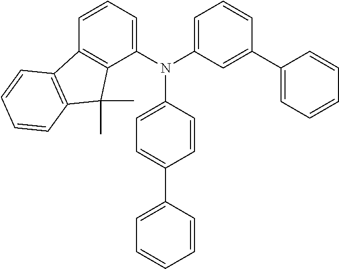 [SMILES: CC1(C)c2ccccc2-c2cccc(N(c3ccc(-c4ccccc4)cc3)c3cccc(-c4ccccc4)c3)c21]

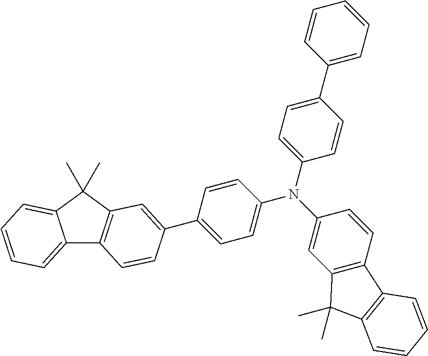 [SMILES: CC1(C)c2ccccc2-c2ccc(-c3ccc(N(c4ccc(-c5ccccc5)cc4)c4ccc5c(c4)C(C)(C)c4ccccc4-5)cc3)cc21]

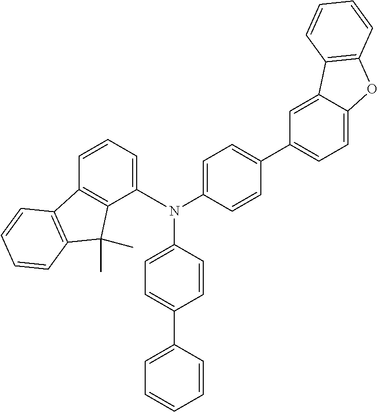 [SMILES: CC1(C)c2ccccc2-c2cccc(N(c3ccc(-c4ccccc4)cc3)c3ccc(-c4ccc5oc6ccccc6c5c4)cc3)c21]

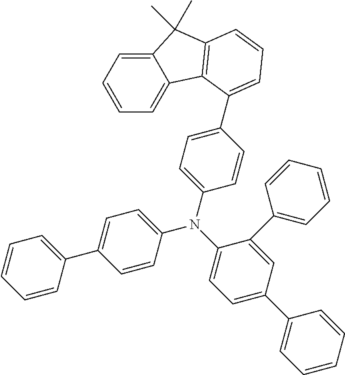 [SMILES: CC1(C)c2ccccc2-c2c(-c3ccc(N(c4ccc(-c5ccccc5)cc4)c4ccc(-c5ccccc5)cc4-c4ccccc4)cc3)cccc21]

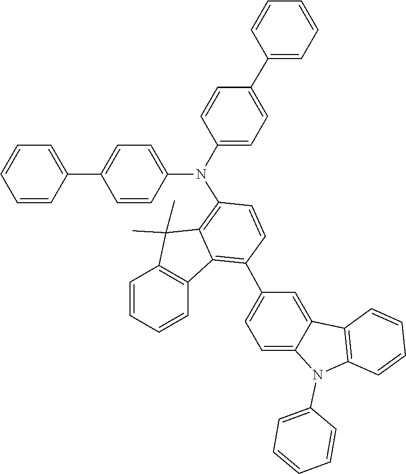 [SMILES: CC1(C)c2ccccc2-c2c(-c3ccc4c(c3)c3ccccc3n4-c3ccccc3)ccc(N(c3ccc(-c4ccccc4)cc3)c3ccc(-c4ccccc4)cc3)c21]

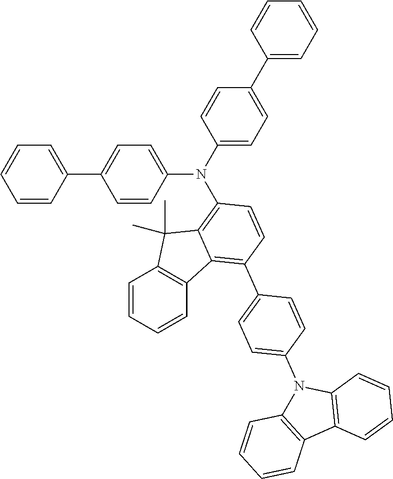 [SMILES: CC1(C)c2ccccc2-c2c(-c3ccc(-n4c5ccccc5c5ccccc54)cc3)ccc(N(c3ccc(-c4ccccc4)cc3)c3ccc(-c4ccccc4)cc3)c21]

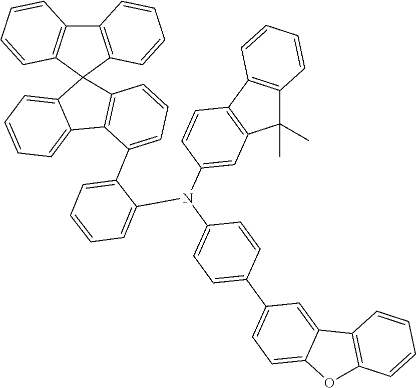 [SMILES: CC1(C)c2ccccc2-c2ccc(N(c3ccc(-c4ccc5oc6ccccc6c5c4)cc3)c3ccccc3-c3cccc4c3-c3ccccc3C43c4ccccc4-c4ccccc43)cc21]

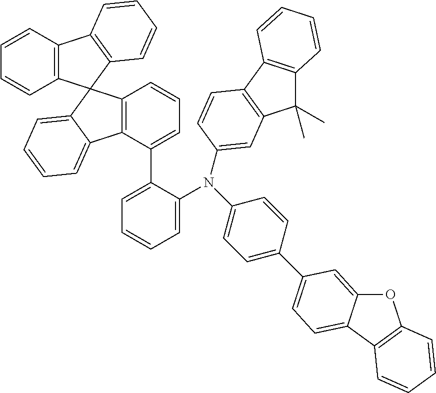 [SMILES: CC1(C)c2ccccc2-c2ccc(N(c3ccc(-c4ccc5c(c4)oc4ccccc45)cc3)c3ccccc3-c3cccc4c3-c3ccccc3C43c4ccccc4-c4ccccc43)cc21]

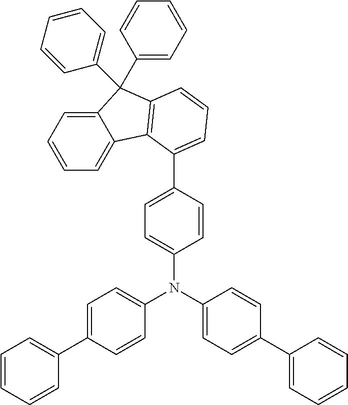 [SMILES: c1ccc(-c2ccc(N(c3ccc(-c4ccccc4)cc3)c3ccc(-c4cccc5c4-c4ccccc4C5(c4ccccc4)c4ccccc4)cc3)cc2)cc1]

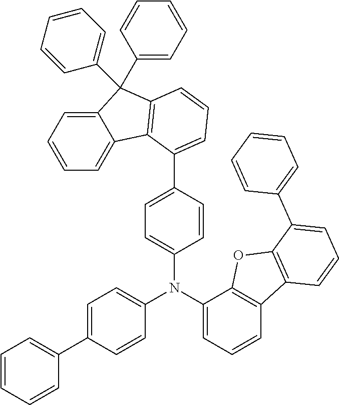 [SMILES: c1ccc(-c2ccc(N(c3ccc(-c4cccc5c4-c4ccccc4C5(c4ccccc4)c4ccccc4)cc3)c3cccc4c3oc3c(-c5ccccc5)cccc34)cc2)cc1]

The device of the invention preferably comprises the following layers between anode and cathode:
at least one hole-transporting layer between anode and emitting layer;
the emitting layer between hole-transporting layer and cathode; and
layer E as electron transport layer between emitting layer and cathode.

The device of the invention more preferably comprises the following layer arrangement between anode and cathode:
directly adjoining the anode, a hole injection layer;
between hole injection layer and emitting layer, a hole transport layer that is preferably p-doped;
between hole transport layer and emitting layer, an electron blocker layer;
between electron blocker layer and cathode, the emitting layer;
between emitting layer and cathode, preferably directly adjoining the emitting layer, a hole blocker layer (HBL);
between hole blocker layer and cathode, layer E as electron transport layer;
between layer E and the cathode, preferably directly adjoining the cathode, an electron injection layer.

It is especially preferable that the electronic device comprises a hole blocker layer. In a preferred embodiment, layer E may be a hole blocker layer. The hole blocker layer preferably comprises a compound of the formula (E-1). More preferably, in this case, exactly one or two V groups in the compound of the formula (E-1) are N, and the remaining V groups are CR⁴. Most preferably, two V groups are N, and the remaining V groups are CR⁴. In this case, it is most preferable that the group

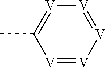

in formula (E-1) is pyrimidine substituted by R⁴ radicals.

On the cathode side of the emitting layer, the device preferably comprises one or more electron-transporting layers, one of which is layer E. The electronic device preferably comprises layer E as electron transport layer, and an electron injection layer on the cathode side thereof. There is preferably a hole blocker layer disposed between the emitting layer and electron transport layer. More preferably, therefore, the following layers are present between the emitting layer and the cathode, in this sequence, viewed from the emitting layer: hole blocker layer, preferably directly adjoining the emitting layer; layer E; electron injection layer, preferably directly adjoining the cathode.

It is preferable that the electronic device comprises an electron transport layer comprising a mixture comprising two or more, preferably two, materials. It is preferable that one of the materials is an alkali metal salt, more preferably a lithium salt. The alkali metal salt is preferably a salt with an organic anion, more preferably 8-hydroxyquinolinate. Most preferably, one of the materials is lithium 8-hydroxyquinolinate (LiQ). The other of the materials is preferably selected from organic compounds containing an electron-deficient nitrogen-containing heteroaromatic system, especially triazine, pyrimidine and benzimidazole.

Suitable materials as may be used in the electron injection layer, in the electron transport layer and/or in the hole blocker layer of the device of the invention are, as well as the compounds of the invention, for example, the compounds disclosed in Y. Shirota et al., Chem. Rev. 2007, 107(4), 953-1010, or other materials as used in these layers according to the prior art. More particularly, materials used for these layers may be any materials known according to the prior art for use in these layers. Especially suitable are aluminum complexes, for example Alq₃, zirconium complexes, for example Zrq₄, lithium complexes, for example Liq, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives. Explici examples of suitable compounds are shown in the following table:

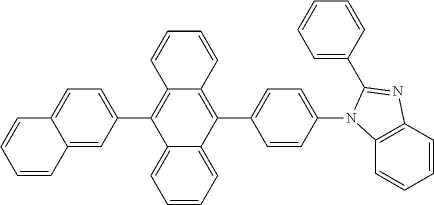 [SMILES: c1ccc(-c2nc3ccccc3n2-c2ccc(-c3c4ccccc4c(-c4ccc5ccccc5c4)c4ccccc34)cc2)cc1]

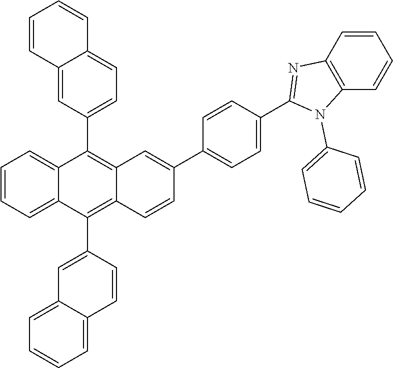 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

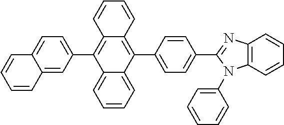 [SMILES: c1ccc(-n2c(-c3ccc(-c4c5ccccc5c(-c5ccc6ccccc6c5)c5ccccc45)cc3)nc3ccccc32)cc1]

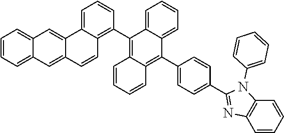 [SMILES: c1ccc(-n2c(-c3ccc(-c4c5ccccc5c(-c5cccc6c5ccc5cc7ccccc7cc56)c5ccccc45)cc3)nc3ccccc32)cc1]

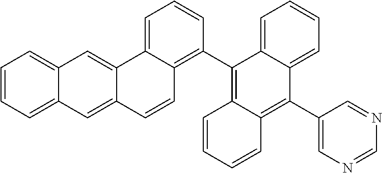 [SMILES: c1ccc2cc3c(ccc4c(-c5c6ccccc6c(-c6cncnc6)c6ccccc56)cccc43)cc2c1]

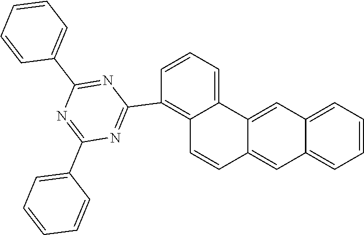 [SMILES: c1ccc(-c2nc(-c3ccccc3)nc(-c3cccc4c3ccc3cc5ccccc5cc34)n2)cc1]

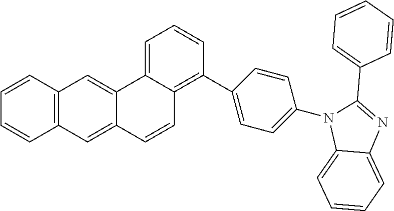 [SMILES: c1ccc(-c2nc3ccccc3n2-c2ccc(-c3cccc4c3ccc3cc5ccccc5cc34)cc2)cc1]

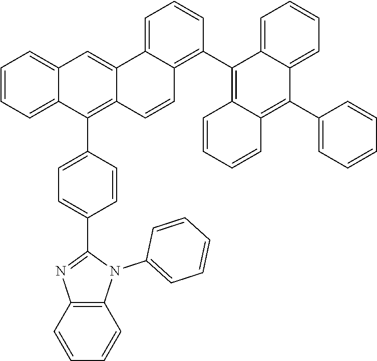 [SMILES: c1ccc(-c2c3ccccc3c(-c3cccc4c3ccc3c(-c5ccc(-c6nc7ccccc7n6-c6ccccc6)cc5)c5ccccc5cc34)c3ccccc23)cc1]

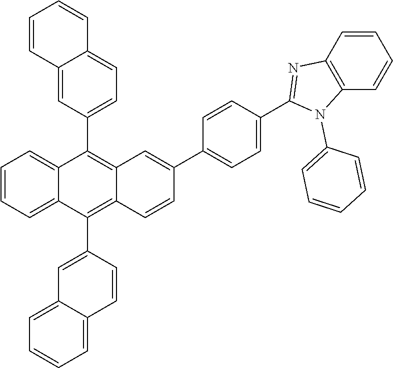 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

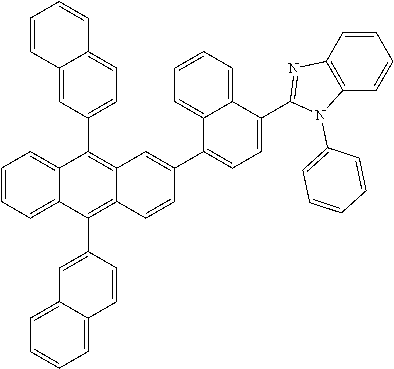 [SMILES: c1ccc(-n2c(-c3ccc(-c4ccc5c(-c6ccc7ccccc7c6)c6ccccc6c(-c6ccc7ccccc7c6)c5c4)c4ccccc34)nc3ccccc32)cc1]

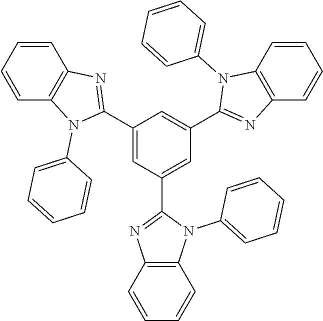 [SMILES: c1ccc(-n2c(-c3cc(-c4nc5ccccc5n4-c4ccccc4)cc(-c4nc5ccccc5n4-c4ccccc4)c3)nc3ccccc32)cc1]

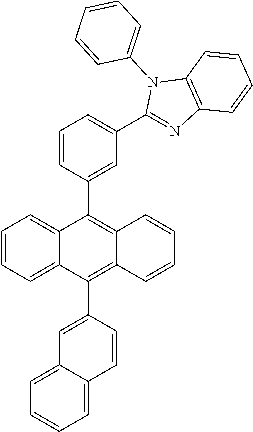 [SMILES: c1ccc(-n2c(-c3cccc(-c4c5ccccc5c(-c5ccc6ccccc6c5)c5ccccc45)c3)nc3ccccc32)cc1]

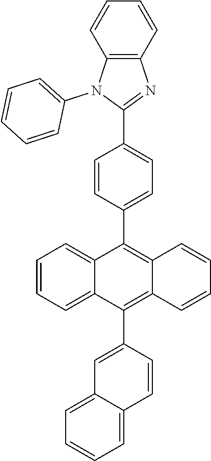 [SMILES: c1ccc(-n2c(-c3ccc(-c4c5ccccc5c(-c5ccc6ccccc6c5)c5ccccc45)cc3)nc3ccccc32)cc1]

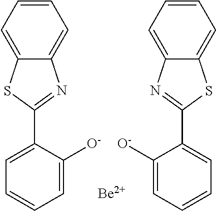

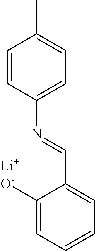 [SMILES: [Li+] ; Cc1ccc(/N=C/c2ccccc2[O-])cc1]

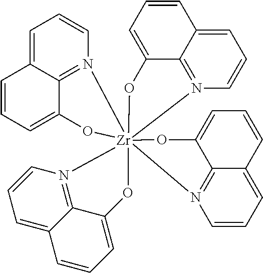

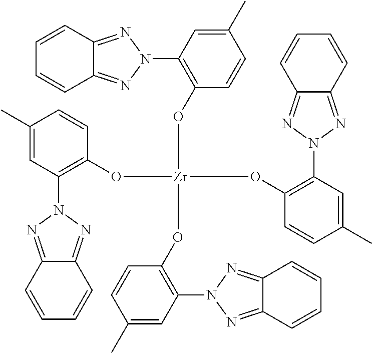

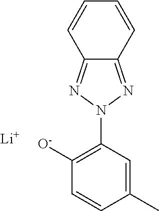 [SMILES: [Li+] ; Cc1ccc([O-])c(-n2nc3ccccc3n2)c1]

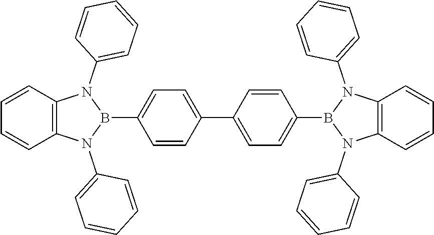 [SMILES: c1ccc(N2B(c3ccc(-c4ccc(B5N(c6ccccc6)c6ccccc6N5c5ccccc5)cc4)cc3)N(c3ccccc3)c3ccccc32)cc1]

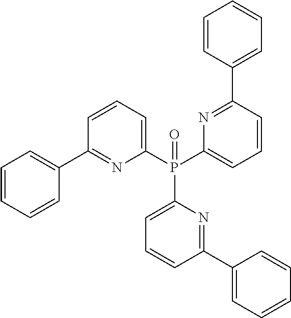 [SMILES: O=P(c1cccc(-c2ccccc2)n1)(c1cccc(-c2ccccc2)n1)c1cccc(-c2ccccc2)n1]

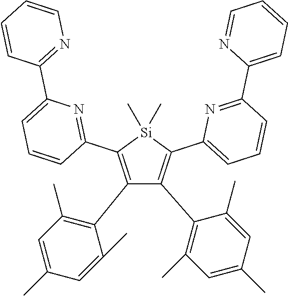 [SMILES: Cc1cc(C)c(C2=C(c3cccc(-c4ccccn4)n3)[Si](C)(C)C(c3cccc(-c4ccccn4)n3)=C2c2c(C)cc(C)cc2C)c(C)c1]

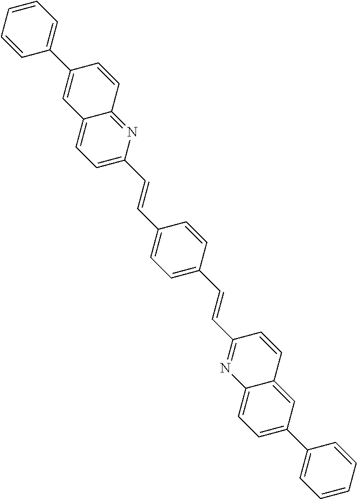 [SMILES: C(=C\c1ccc2cc(-c3ccccc3)ccc2n1)/c1ccc(/C=C/c2ccc3cc(-c4ccccc4)ccc3n2)cc1]

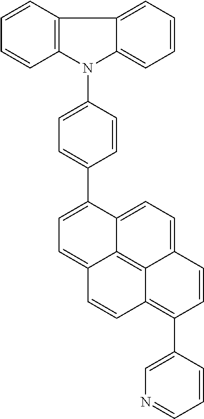 [SMILES: c1cncc(-c2ccc3ccc4c(-c5ccc(-n6c7ccccc7c7ccccc76)cc5)ccc5ccc2c3c54)c1]

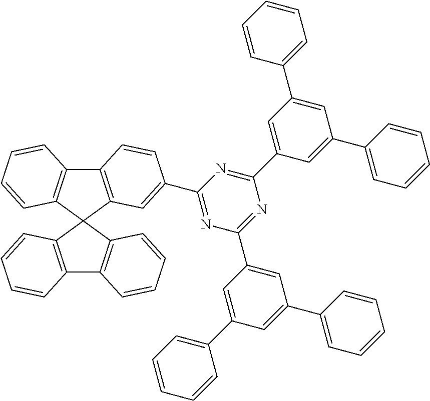 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

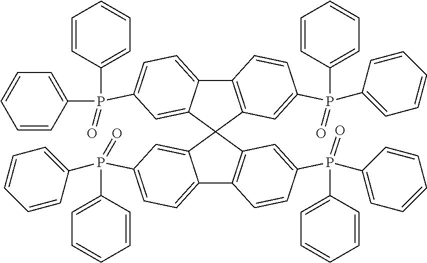 [SMILES: O=P(c1ccccc1)(c1ccccc1)c1ccc2c(c1)C1(c3cc(P(=O)(c4ccccc4)c4ccccc4)ccc3-2)c2cc(P(=O)(c3ccccc3)c3ccccc3)ccc2-c2ccc(P(=O)(c3ccccc3)c3ccccc3)cc21]

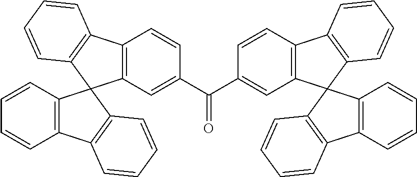 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2]

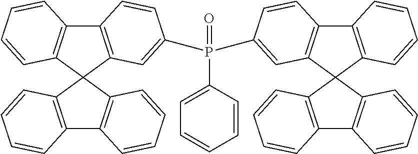 [SMILES: O=P(c1ccccc1)(c1ccc2c(c1)C1(c3ccccc3-c3ccccc31)c1ccccc1-2)c1ccc2c(c1)C1(c3ccccc3-c3ccccc31)c1ccccc1-2]

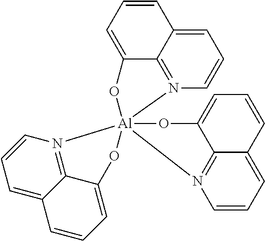

The emitting layer of the device comprises, as well as the compound of the formula (EM-1), preferably one or more further compounds, preferably exactly one further compound. The compound of the formula (EM-1) here is the emitting compound, and the further compound is the matrix compound. The matrix compound of the formula (EM-1) is present here in the layer in a proportion of 0.5% to 15%, preferably 0.5% to 10%, more preferably 3%-6%. The further compound is preferably present here in the layer in a proportion of 85% to 99.5%, preferably in a proportion of 90%-99.5% and more preferably in a proportion of 94%-97%.

The further compound is preferably selected from compounds known in the prior art as matrix materials for fluorescent emitters, especially compounds selected from the classes of the oligoarylenes (e.g. 2,2′,7,7′-tetraphenylspirobifluorene), especially the oligoarylenes containing fused aromatic groups, the oligoarylenevinylenes, the polypodal metal complexes, the hole-conducting compounds, the electron-conducting compounds, especially ketones, phosphine oxides, and sulfoxides; the atropisomers, the boronic acid derivatives and the benzanthracenes. Particularly preferred matrix materials are selected from the classes of the oligoarylenes comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes comprising anthracene, benzanthracene, benzophenanthrene and/or pyrene or atropisomers of these compounds. Most preferred are anthracene derivatives and benzanthracene derivatives. An oligoarylene in the context of this invention is understood to mean a compound in which at least three aryl or arylene groups are bonded to one another.

The compound of the formula (EM-1) is preferably a fluorescent compound. It preferably emits blue light.

The compound may also emit light by the mechanism of thermally activated delayed fluorescence (TADF), preferably likewise blue light. In this case, it is preferable that

LUMO(EM), i.e. the LUMO energy level of the emitting compound of the formula (EM-1), and HOMO(matrix), i.e. the HOMO energy level of the matrix material, is subject to the condition that:

$$LUMO ( EM ) - HOMO ( matrix ) > {S}_{1} ( EM ) - 0.4 eV ;$$

more preferably:

$$LUMO ( EM ) - HOMO ( matrix ) > {S}_{1} ( EM ) - 0.3 eV ;$$

and even more preferably:

$$LUMO ( E ) - HOMO ( matrix ) > {S}_{1} ( EM ) - 0.2 eV .$$

In this case, S₁(EM) is the energy of the first excited singlet state of the compound of the formula (EM-1).

It is additionally preferable that the energy of the T₁ state of the matrix material of the emitting layer, referred to hereinafter as T₁(matrix), is not more than 0.1 eV lower than the energy of the T₁ state of the compound of the formula (EM-1), referred to hereinafter as T₁(EM). More preferably, T₁(matrix) T₁(EM). Even more preferably: T₁(matrix)−T₁(EM) 0.1 eV, most preferably T₁(matrix)−T₁(EM) 0.2 eV.

Examples of suitable matrix materials in the emitting layer, in the case of emission by the compound of the formula (EM-1) by the TADF mechanism, are ketones, phosphine oxides, sulfoxides and sulfones, triarylamines, carbazole derivatives, e.g. CBP (N,N-biscarbazolylbiphenyl), or m-CBP, indolocarbazole derivatives, indenocarbazole derivatives, azacarbazoles, bipolar matrix materials, silanes, azaboroles or boronic esters, diazasilole derivatives, diazaphosphole derivatives, triazine derivatives, zinc complexes, or bridged carbazole derivatives.

For this use, preference is further given to electron-transporting organic compounds. Particular preference is given to electron-transporting organic compounds having a LUMO energy level of not more than −2.50 eV, more preferably not more than −2.60 eV, even more preferably not more than −2.65 eV and most preferably not more than −2.70 eV.

Particularly preferred matrix materials in the emitting layer, in the case of emission by the compound of the formula (EM-1) by the TADF mechanism, are selected from the substance classes of the triazines, the pyrimidines, the lactams, the metal complexes, especially the Be, Zn and Al complexes, the aromatic ketones, the aromatic phosphine oxides, the azaphospholes, the azaboroles substituted by at least one electron-conducting substituent, the quinoxalines, the quinolines and the isoquinolines.

Preferably, the emitting layer of the device emits blue light.

In a preferred embodiment of the invention, the device comprises two or three, preferably three, identical or different layer sequences stacked one on top of another, where each of the layer sequences comprises the following layers: hole injection layer, hole transport layer, electron blocker layer, emitting layer, and electron transport layer, and wherein at least one of the layer sequences comprises
an emitting layer comprising a compound of the formula (EM-1), and
a layer E, preferably as electron transport layer.

Preferably, all of the two or three layer sequences comprise
an emitting layer comprising a compound of the formula (EM-1),
a layer E, preferably as electron transport layer.

Preferably, all of the two or three layer sequences emit blue light.

It is further preferable that all of the two or three layer sequences contain an emitting layer comprising a compound of the formula (EM-1).

A double layer composed of adjoining n-CGL and p-CGL is preferably arranged between the layer sequences in each case, where the n-CGL is disposed on the anode side and the p-CGL correspondingly on the cathode side. CGL here stands for charge generation layer. Materials for use in such layers are known to the person skilled in the art. Preference is given to using a p-doped amine in the p-CGL, more preferably a material selected from the abovementioned preferred structure classes of hole transport materials.

In a preferred embodiment of the invention, the device emits light through the anode and the substrate layer (bottom emission).

In an alternative, likewise preferred embodiment of the invention, the device emits light through the cathode (top emission). In this embodiment, the cathode has a partly transparent and partly reflective configuration. For this purpose, for example, it is possible to use an alloy of Ag and Mg as cathode. In this embodiment, the anode is highly reflective. In addition, the device in this case preferably includes an outcoupling layer applied to the cathode and preferably comprising an amine compound. The layer thicknesses in this embodiment should be adapted to the materials used, especially to the refractive index of the layers and to the position of the recombination zone in the emitting layer, in order to achieve an optimal resonance effect.

In the embodiment with top emission, it is possible to achieve excellent efficiency of the OLED, combined with a narrow emission band.

After application of the layers, the device may be structured, contact-connected and finally sealed, in order to rule out damaging effects of water and air.

In a preferred embodiment, the device is characterized in that one or more layers are coated by a sublimation process. In this case, the materials are applied by vapor deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

It is further preferable that one or more layers of the device are coated by the OVPD (organic vapor phase deposition) method or with the aid of a carrier gas sublimation. In this case, the materials are applied at a pressure between 10-5 mbar and 1 bar. A special case of this method is the OVJP (organic vapor jet printing) method, in which the materials are applied directly by a nozzle and thus structured (for example M. S. Arnold et al., Appl. Phys. Lett. 2008, 92, 053301).

It is further preferable that one or more layers of the device are applied from solution, for example by spin-coating, or by any printing method, for example screen printing, flexographic printing, nozzle printing or offset printing, but more preferably LITI (light-induced thermal imaging, thermal transfer printing) or inkjet printing.

It is further preferable that the device is produced by applying one or more layers from solution and one or more layers by a sublimation method.

A process for producing the device comprises first providing a substrate with anode, in a later step applying the emitting layer comprising the compound of the formula (EM-1), in a subsequent step applying layer E, and in a subsequent step applying the anode. The emitting layer and layer E are preferably applied from the gas phase. More preferably, all layers between the anode and cathode of the device are applied from the gas phase.

The devices of the invention are preferably used in displays, as light sources in lighting applications and as light sources in medical and/or cosmetic applications.

### EXAMPLES

### A) General Production Process for the OLEDs and Characterization of the OLEDs

Glass plates which have been coated with structured ITO (indium tin oxide) in a thickness of 50 nm form the substrates to which the OLEDs are applied.

The OLEDs have the following layer structure: substrate/hole injection layer (HIL)/hole transport layer (HTL)/electron blocker layer (EBL)/emission layer (EML)/optional hole blocker layer (HBL)/electron transport layer (ETL)/electron injection layer (EIL) and finally a cathode. The cathode is formed by an aluminum layer of thickness 100 nm. The exact structure of the OLEDs can be found in the tables which follow. The materials present in the individual layers of the OLED are shown in a table below.

All materials are applied by thermal vapor deposition in a vacuum chamber. In this case, the emission layer consists of at least one matrix material (host material) and an emitting dopant (emitter) which is added to the matrix material(s) in a particular proportion by volume by co-evaporation. Details given in such a form as H:SEB (95%:5%) mean here that the material H is present in the layer in a proportion by volume of 95% and the material SEB in a proportion by volume of 5%. In an analogous manner, the electron transport layer and the hole injection layer also consist of a mixture of two materials.

The OLEDs are characterized in a standard manner. For this purpose, the operating voltage and the external quantum efficiency (EQE, measured in %) as a function of the luminance, calculated from current-voltage-luminance characteristics assuming Lambertian emission characteristics, are determined. The parameter EQE @10 mA/cm² refers to the external quantum efficiency which is attained at 10 mA/cm². The parameter U @10 mA/cm² refers to the operating voltage at 10 mA/cm².

B) Performance Data of OLEDs of the Invention with Bottom Emission Structure and Compound of the Formula (E-1) in the ETL

OLEDs comprising a compound selected from compounds ETM1-ETM17 in the electron transport layer are produced:

| | HIL | HTL | EBL | EML | ETL | EIL |
|---|---|---|---|---|---|---|
| Ex. | Thickness/nm | Thickness/nm | Thickness/nm | Thickness/nm | Thickness/nm | Thickness/nm |
| E1 | HTM:p-dopant (5%) | HTM | EBM | H:SEB(5%) | ETM1:LiQ (50%) | LiQ |
| | 20 nm | 180 nm | 10 nm | 20 nm | 30 nm | 1 nm |
| E2 | HTM:p-dopant (5%) | HTM | EBM | H:SEB(5%) | ETM2:LiQ (50%) | LiQ |
| | 20 nm | 180 nm | 10 nm | 20 nm | 30 nm | 1 nm |
| E3 | HTM:p-dopant (5%) | HTM | EBM | H:SEB(5%) | ETM3:LiQ (50%) | LiQ |
| | 20 nm | 180 nm | 10 nm | 20 nm | 30 nm | 1 nm |
| E4 | HTM:p-dopant (5%) | HTM | EBM | H:SEB(5%) | ETM4:LiQ (50%) | LiQ |
| | 20 nm | 180 nm | 10 nm | 20 nm | 30 nm | 1 nm |
| E5 | HTM:p-dopant (5%) | HTM | EBM | H:SEB(5%) | ETM5:LiQ (50%) | LiQ |
| | 20 nm | 180 nm | 10 nm | 20 nm | 30 nm | 1 nm |
| E6 | HTM:p-dopant (5%) | HTM | EBM | H:SEB(5%) | ETM6:LiQ (50%) | LiQ |
| | 20 nm | 180 nm | 10 nm | 20 nm | 30 nm | 1 nm |
| E7 | HTM:p-dopant (5%) | HTM | EBM | H:SEB(5%) | ETM7:LiQ (50%) | LiQ |
| | 20 nm | 180 nm | 10 nm | 20 nm | 30 nm | 1 nm |
| E8 | HTM:p-dopant (5%) | HTM | EBM | H:SEB(5%) | ETM8:LiQ (50%) | LiQ |
| | 20 nm | 180 nm | 10 nm | 20 nm | 30 nm | 1 nm |
| E9 | HTM:p-dopant (5%) | HTM | EBM | H:SEB(5%) | ETM9:LiQ (50%) | LiQ |
| | 20 nm | 180 nm | 10 nm | 20 nm | 30 nm | 1 nm |
| E10 | HTM:p-dopant (5%) | HTM | EBM | H:SEB(5%) | ETM10:LiQ (50%) | LiQ |
| | 20 nm | 180 nm | 10 nm | 20 nm | 30 nm | 1 nm |
| E11 | HTM:p-dopant (5%) | HTM | EBM | H:SEB(5%) | ETM11:LiQ (50%) | LiQ |
| | 20 nm | 180 nm | 10 nm | 20 nm | 30 nm | 1 nm |
| E12 | HTM:p-dopant (5%) | HTM | EBM | H:SEB(5%) | ETM12:LiQ (50%) | LiQ |
| | 20 nm | 180 nm | 10 nm | 20 nm | 30 nm | 1 nm |
| E13 | HTM:p-dopant (5%) | HTM | EBM | H:SEB(5%) | ETM13:LiQ (50%) | LiQ |
| | 20 nm | 180 nm | 10 nm | 20 nm | 30 nm | 1 nm |
| E14 | HTM:p-dopant (5%) | HTM | EBM | H:SEB(5%) | ETM14:LiQ (50%) | LiQ |
| | 20 nm | 180 nm | 10 nm | 20 nm | 30 nm | 1 nm |
| E15 | HTM:p-dopant (5%) | HTM | EBM | H:SEB(5%) | ETM15:LiQ (50%) | LiQ |
| | 20 nm | 180 nm | 10 nm | 20 nm | 30 nm | 1 nm |
| E16 | HTM:p-dopant (5%) | HTM | EBM | H:SEB(5%) | ETM16:LiQ (50%) | LiQ |
| | 20 nm | 180 nm | 10 nm | 20 nm | 30 nm | 1 nm |
| E17 | HTM:p-dopant (5%) | HTM | EBM | H:SEB(5%) | ETM17:LiQ (50%) | LiQ |
| | 20 nm | 180 nm | 10 nm | 20 nm | 30 nm | 1 nm |

These OLEDs can be used to obtain the following performance data:

| Ex. | U @ 10 mA/cm² (V) | EQE @ 10 mA/cm² (%) |
|---|---|---|
| E1 | 4.0 | 8.9 |
| E2 | 3.9 | 9.3 |
| E3 | 3.8 | 9.7 |
| E4 | 3.8 | 9.3 |
| E5 | 3.9 | 9.9 |
| E6 | 3.8 | 9.8 |
| E7 | 4.0 | 8.5 |
| E8 | 3.8 | 9.7 |
| E9 | 4.1 | 9.1 |
| E10 | 3.9 | 8.9 |
| E11 | 3.9 | 9.5 |
| E12 | 4.1 | 9.7 |
| E13 | 4.1 | 8.9 |
| E14 | 4.2 | 8.8 |
| E15 | 3.8 | 9.4 |
| E16 | 3.8 | 9.2 |
| E17 | 3.9 | 9.4 |

All OLEDs E1 to E17 show very high values for efficiency at low operating voltage.

### B) Comparison of the Performance Data Between OLEDs of the Invention and OLEDs Containing the Compound PA in the Emitting Layer

In addition to the OLEDs E1 and E9 detailed above, OLEDs containing the emitter PA rather than the emitter SEB in the emitting layer are produced:

| | HIL | HTL | EBL | EML | ETL | EIL |
|---|---|---|---|---|---|---|
| Ex. | Thickness/nm | Thickness/nm | Thickness/nm | Thickness/nm | Thickness/nm | Thickness/nm |
| V1 | HTM:p-dopant (5%) | HTM | EBM | H:PA(5%) | ETM1:LiQ (50%) | LiQ |
| | 20 nm | 180 nm | 10 nm | 20 nm | 30 nm | 1 nm |
| E1 | HTM:p-dopant (5%) | HTM | EBM | H:SEB(5%) | ETM1:LiQ (50%) | LiQ |
| | 20 nm | 180 nm | 10 nm | 20 nm | 30 nm | 1 nm |
| V2 | HTM:p-dopant (5%) | HTM | EBM | H:PA(5%) | ETM9:LiQ (50%) | LiQ |
| | 20 nm | 180 nm | 10 nm | 20 nm | 30 nm | 1 nm |
| E9 | HTM:p-dopant (5%) | HTM | EBM | H:SEB(5%) | ETM9:LiQ (50%) | LiQ |
| | 20 nm | 180 nm | 10 nm | 20 nm | 30 nm | 1 nm |

The following results are obtained:

| Ex. | U @ 10 mA/cm² (V) | EQE @ 10 mA/cm² (%) |
|---|---|---|
| V1 | 4.3 | 7.2 |
| E1 | 4.0 | 8.9 |
| V2 | 4.4 | 7.6 |
| E9 | 4.1 | 9.1 |

The results show that, in both cases, i.e. with the electron-transporting compound ETM1 and the electron-transporting compound ETM9 in the ETM, much better results for EQE and operating voltage are obtained for the OLEDs of the invention than for the OLEDs comprising the compound PA in the emitting layer.

D) Performance Data of OLEDs of the Invention with Bottom Emission structure and compound of the formula (E-1) in the HBL

OLEDs comprising a compound selected from compounds ETM18 and ETM19 in the hole blocker layer (HBL), and compound ETM1 in the ETL, are produced. In addition, a comparative OLED (V3) is produced, which is identical in structure to OLED E18, with the sole difference that it contains the compound PA as emitter in the emitting layer, and not the compound SEB:

| | HIL | HTL | EBL | EML | HBL | ETL | EIL |
|---|---|---|---|---|---|---|---|
| Ex. | Thickness/nm | Thickness/nm | Thickness/nm | Thickness/nm | Thickness/nm | Thickness/nm | Thickness/nm |
| V3 | HTM:p-dopant (5%) | HTM | EBM | H:PA(5%) | ETM18 | ETM1:LiQ (50%) | LiQ |
| | 20 nm | 180 nm | 10 nm | 20 nm | 10 nm | 20 nm | 1 nm |
| E18 | HTM:p-dopant (5%) | HTM | EBM | H:SEB(5%) | ETM18 | ETM1:LiQ (50%) | LiQ |
| | 20 nm | 180 nm | 10 nm | 20 nm | 10 nm | 20 nm | 1 nm |
| E19 | HTM:p-dopant (5%) | HTM | EBM | H:SEB(5%) | ETM19 | ETM1:LiQ (50%) | LiQ |
| | 20 nm | 180 nm | 10 nm | 20 nm | 10 nm | 20 nm | 1 nm |

These OLEDs can be used to obtain the following performance data:

| Ex. | U @ 10 mA/cm² (V) | 10 mA/cm² |
|---|---|---|
| V3 | 4.2 | 6.7 |
| E18 | 3.9 | 8.3 |
| E19 | 4.0 | 8.5 |

The OLEDs of the invention containing the compound ETM18 or ETM19 in the HBL have very high values for efficiency at low operating voltage.

In the case of the comparative OLED V3 containing compound PA as emitter in the emitting layer rather than the compound SEB, the corresponding performance data are much worse.

### E) Use of the Compounds of the Invention in the ETL of Blue-Fluorescing Devices Having Top Emission Structure

OLEDs are produced with the following structure:

substrate/HIL/HTL/EBL/EML/ETL/EIL/cathode/outcoupling layer.

The substrate used here is a glass plate coated with structured ITO (indium tin oxide) of thickness 50 nm. The cathode consists of a 15 nm-thick layer of a mixture of 91% Ag and 9% Mg. The outcoupling layer consists of a 70 nm-thick layer of the compound HTM. The structure of the layers HIL, HTL, EBL, EML, ETL and EIL is shown in the following table:

| | HIL | HTL | EBL | EML | ETL | EIL |
|---|---|---|---|---|---|---|
| Ex. | Thickness/nm | Thickness/nm | Thickness/nm | Thickness/nm | Thickness/nm | Thickness/nm |
| E20 | HTM:p-dopant (5%) | HTM | EBM | H:SEB(4%) | ETM1 LiQ(50%) | Yb:LiF(50%) |
| | 10 nm | 118 nm | 15 nm | 20 nm | 30 nm | 2 nm |

The OLED E20 containing the compound ETM1 in the ETL has color coordinates CIE x,y=0.14, 0.05. It attains a very high EQE at 10 mA/cm² of 16%-19%. The emission band of the OLEDs is very narrow and has a half-height width between 17 and 18 nm.

In addition, it is possible to produce the following OLEDs with top emission structure in which, by comparison with OLED E20, the material ETM-1 has been exchanged for one of materials ETM-2 to ETM-17:

| Ex. | HIL | HTL | EBL | EML | ETL | EIL |
|---|---|---|---|---|---|---|
| E21 | HTM:p-dopant (5%) | HTM | EBM | H:SEB(4%) | ETM-2 LiQ (50%) | Yb:LiF(50%) |
| E22 | HTM:p-dopant (5%) | HTM | EBM | H:SEB(4%) | ETM-3 LiQ (50%) | Yb:LiF(50%) |
| E23 | HTM:p-dopant (5%) | HTM | EBM | H:SEB(4%) | ETM-4 LiQ (50%) | Yb:LiF(50%) |
| E24 | HTM:p-dopant (5%) | HTM | EBM | H:SEB(4%) | ETM-5 LiQ (50%) | Yb:LiF(50%) |
| E25 | HTM:p-dopant (5%) | HTM | EBM | H:SEB(4%) | ETM-6 LiQ (50%) | Yb:LiF(50%) |
| E26 | HTM:p-dopant (5%) | HTM | EBM | H:SEB(4%) | ETM-7 LiQ (50%) | Yb:LiF(50%) |
| E27 | HTM:p-dopant (5%) | HTM | EBM | H:SEB(4%) | ETM-8 LiQ (50%) | Yb:LiF(50%) |
| E28 | HTM:p-dopant (5%) | HTM | EBM | H:SEB(4%) | ETM-9:LiQ (50%) | Yb:LiF(50%) |
| E29 | HTM:p-dopant (5%) | HTM | EBM | H:SEB(4%) | ETM-10:LiQ (50%) | Yb:LiF(50%) |
| E30 | HTM:p-dopant (5%) | HTM | EBM | H:SEB(4%) | ETM-11:LiQ (50%) | Yb:LiF(50%) |
| E31 | HTM:p-dopant (5%) | HTM | EBM | H:SEB(4%) | ETM-12:LiQ (50%) | Yb:LiF(50%) |
| E32 | HTM:p-dopant (5%) | HTM | EBM | H:SEB(4%) | ETM-13 LiQ (50%) | Yb:LiF(50%) |
| E33 | HTM:p-dopant (5%) | HTM | EBM | H:SEB(4%) | ETM-14:LiQ (50%) | Yb:LiF(50%) |
| E34 | HTM:p-dopant (5%) | HTM | EBM | H:SEB(4%) | ETM-15:LiQ (50%) | Yb:LiF(50%) |
| E35 | HTM:p-dopant (5%) | HTM | EBM | H:SEB(4%) | ETM-16:LiQ (50%) | Yb:LiF(50%) |
| E36 | HTM:p-dopant (5%) | HTM | EBM | H:SEB(4%) | ETM-17 LiQ (50%) | Yb:LiF(50%) |

It is possible here to obtain OLEDs having the color coordinates CIE x,y=0.14, 0.05. After adjustment of the layer thicknesses to the material combination used in order to optimize the resonance effect, it is possible for these OLEDs to attain very high EQE values at 10 mA/cm² of 16-19%, and very small half-height widths of the emission band of 17 to 18 nm.

Compounds used

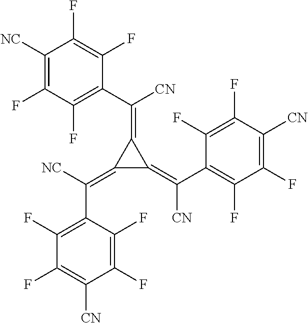 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

p-Dopant

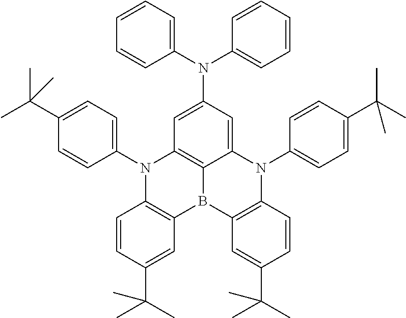 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

SEB

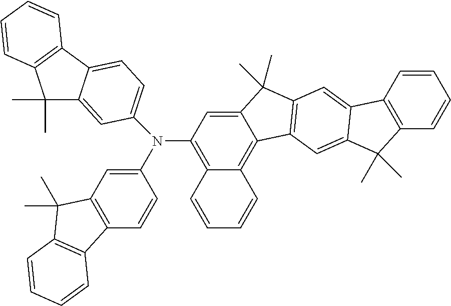 [SMILES: CC1(C)c2ccccc2-c2ccc(N(c3ccc4c(c3)C(C)(C)c3ccccc3-4)c3cc4c(c5ccccc35)-c3cc5c(cc3C4(C)C)-c3ccccc3C5(C)C)cc21]

PA

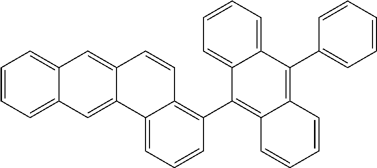 [SMILES: c1ccc(-c2c3ccccc3c(-c3cccc4c3ccc3cc5ccccc5cc34)c3ccccc23)cc1]

H

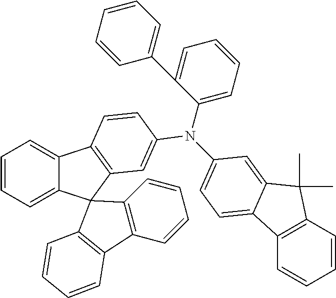 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

HTM

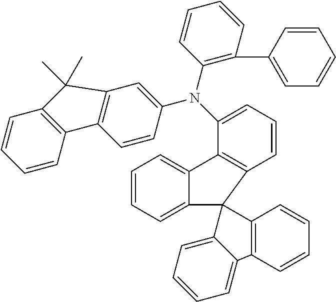 [SMILES: CC1(C)c2ccccc2-c2ccc(N(c3ccccc3-c3ccccc3)c3cccc4c3-c3ccccc3C43c4ccccc4-c4ccccc43)cc21]

EBM

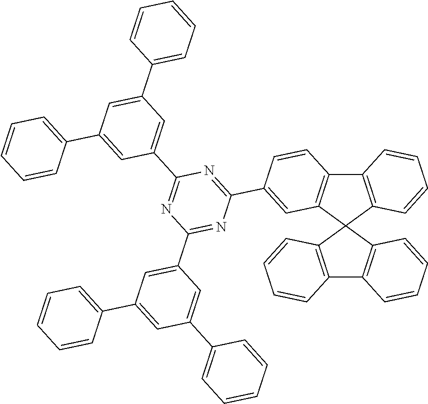 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ETM1

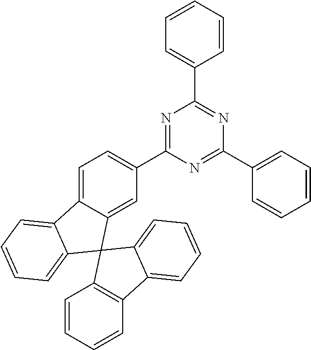 [SMILES: c1ccc(-c2nc(-c3ccccc3)nc(-c3ccc4c(c3)C3(c5ccccc5-c5ccccc53)c3ccccc3-4)n2)cc1]

ETM2

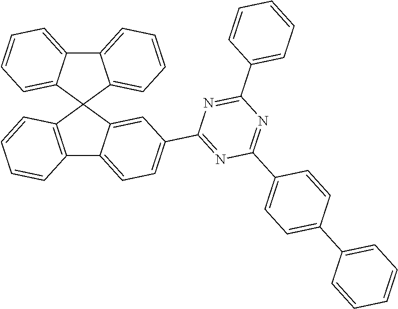 [SMILES: c1ccc(-c2ccc(-c3nc(-c4ccccc4)nc(-c4ccc5c(c4)C4(c6ccccc6-c6ccccc64)c4ccccc4-5)n3)cc2)cc1]

ETM3

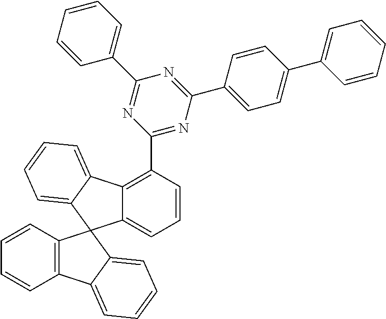 [SMILES: c1ccc(-c2ccc(-c3nc(-c4ccccc4)nc(-c4cccc5c4-c4ccccc4C54c5ccccc5-c5ccccc54)n3)cc2)cc1]

ETM4

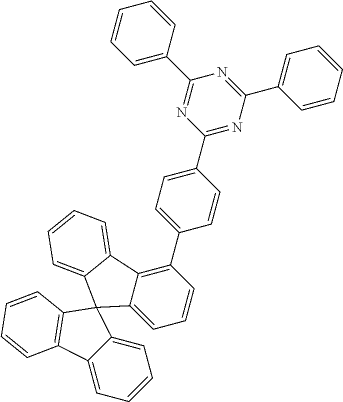 [SMILES: c1ccc(-c2nc(-c3ccccc3)nc(-c3ccc(-c4cccc5c4-c4ccccc4C54c5ccccc5-c5ccccc54)cc3)n2)cc1]

ETM5

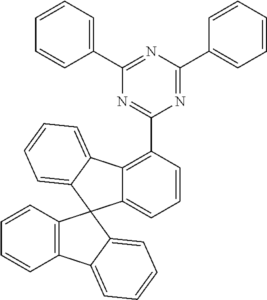 [SMILES: c1ccc(-c2nc(-c3ccccc3)nc(-c3cccc4c3-c3ccccc3C43c4ccccc4-c4ccccc43)n2)cc1]

ETM6

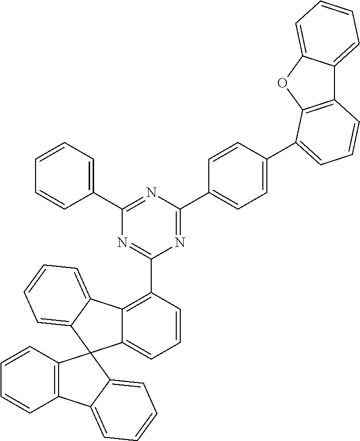 [SMILES: c1ccc(-c2nc(-c3ccc(-c4cccc5c4oc4ccccc45)cc3)nc(-c3cccc4c3-c3ccccc3C43c4ccccc4-c4ccccc43)n2)cc1]

ETM7

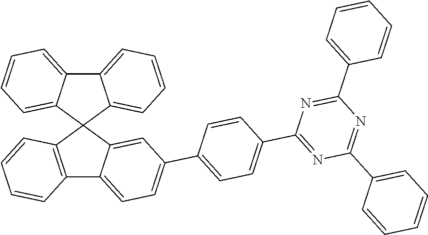 [SMILES: c1ccc(-c2nc(-c3ccccc3)nc(-c3ccc(-c4ccc5c(c4)C4(c6ccccc6-c6ccccc64)c4ccccc4-5)cc3)n2)cc1]

ETM8

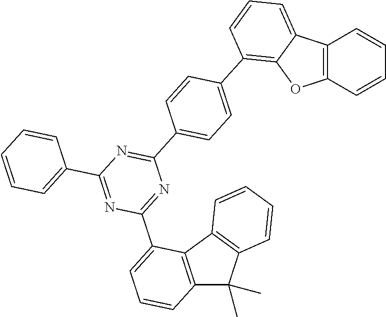 [SMILES: CC1(C)c2ccccc2-c2c(-c3nc(-c4ccccc4)nc(-c4ccc(-c5cccc6c5oc5ccccc56)cc4)n3)cccc21]

ETM9

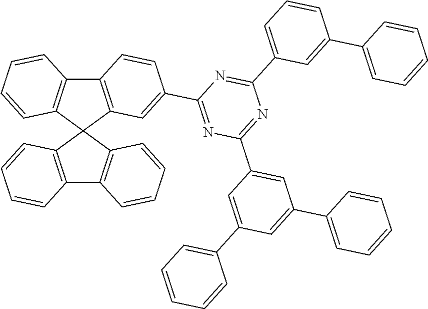 [SMILES: c1ccc(-c2cccc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ETM10

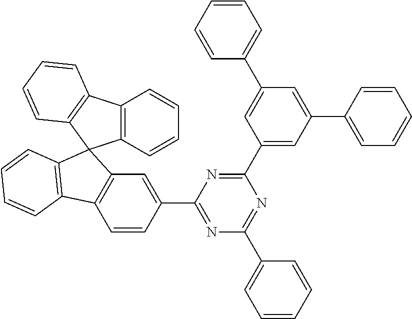 [SMILES: c1ccc(-c2cc(-c3ccccc3)cc(-c3nc(-c4ccccc4)nc(-c4ccc5c(c4)C4(c6ccccc6-c6ccccc64)c4ccccc4-5)n3)c2)cc1]

ETM11

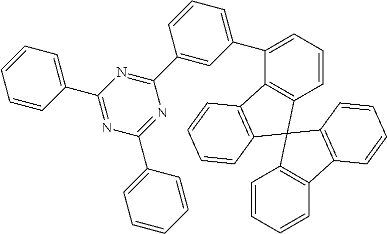 [SMILES: c1ccc(-c2nc(-c3ccccc3)nc(-c3cccc(-c4cccc5c4-c4ccccc4C54c5ccccc5-c5ccccc54)c3)n2)cc1]

ETM12

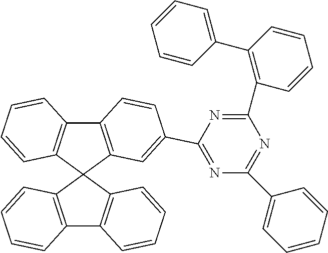 [SMILES: c1ccc(-c2nc(-c3ccc4c(c3)C3(c5ccccc5-c5ccccc53)c3ccccc3-4)nc(-c3ccccc3-c3ccccc3)n2)cc1]

ETM13

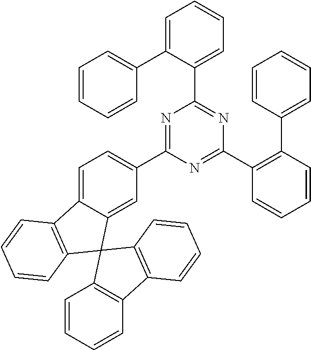 [SMILES: c1ccc(-c2ccccc2-c2nc(-c3ccc4c(c3)C3(c5ccccc5-c5ccccc53)c3ccccc3-4)nc(-c3ccccc3-c3ccccc3)n2)cc1]

ETM14

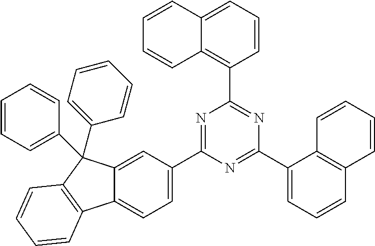 [SMILES: c1ccc(C2(c3ccccc3)c3ccccc3-c3ccc(-c4nc(-c5cccc6ccccc56)nc(-c5cccc6ccccc56)n4)cc32)cc1]

ETM15

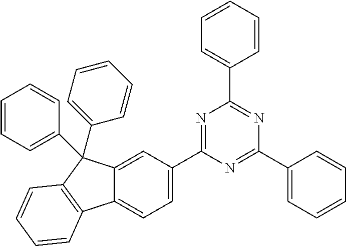 [SMILES: c1ccc(-c2nc(-c3ccccc3)nc(-c3ccc4c(c3)C(c3ccccc3)(c3ccccc3)c3ccccc3-4)n2)cc1]

ETM16

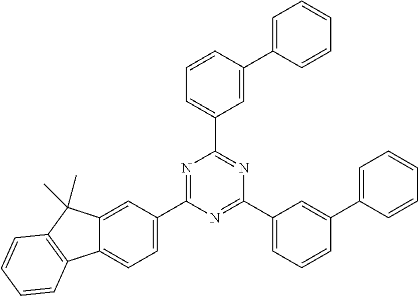 [SMILES: CC1(C)c2ccccc2-c2ccc(-c3nc(-c4cccc(-c5ccccc5)c4)nc(-c4cccc(-c5ccccc5)c4)n3)cc21]

ETM17

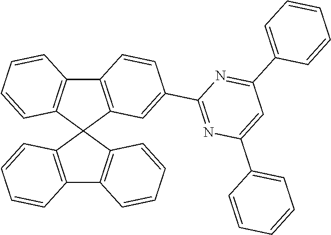 [SMILES: c1ccc(-c2cc(-c3ccccc3)nc(-c3ccc4c(c3)C3(c5ccccc5-c5ccccc53)c3ccccc3-4)n2)cc1]

ETM18

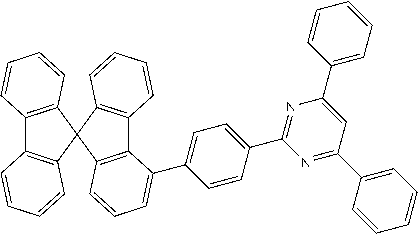 [SMILES: c1ccc(-c2cc(-c3ccccc3)nc(-c3ccc(-c4cccc5c4-c4ccccc4C54c5ccccc5-c5ccccc54)cc3)n2)cc1]

ETM19

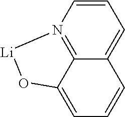

LiQ

1.-20. (canceled)

21. An electronic device comprising a first electrode, a second electrode and, arranged in between,
an emitting layer comprising a compound of a formula (EM-1-1-1-1-2) 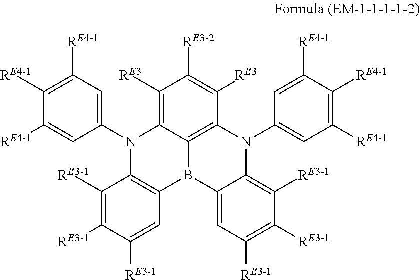
R^{E3}, R^{E3-1} are the same or different at each instance and is selected from H, D, F, Cl, Br, I, C(═O)R^{E4}, CN, N(R^{E4})₂, P(═O)(R^{E4})₂, OR^{E4}, S(═O)R^{E4}, S(═O)₂R^{E4}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E3} radicals optionally joined to one another and may form a ring; where the alkyl, alkoxy, alkenyl and alkynyl groups and the aromatic ring systems and heteroaromatic ring systems are each substituted by R^{E4} radicals; and where one or more CH₂ groups in the alkyl, alkoxy, alkenyl and alkynyl groups optionally replaced by —R^{E4}C═CR^{E4}—, —C≡—C—, C═O, C═NR^{E4}, —C(═O)O—, —C(═O)NR^{E4}—NR^{E4}, P(═O)(R^{E4}), —O—, —S—, SO or SO₂;
R^{E4}, R^{E4-1} is the same or different at each instance and is selected from H, D, F, Cl, Br, I, C(═O)R^{E5}, CN, N(R^{E5})₂, P(═O)(R^{E5})₂, OR^{E5}, S(═O)R^{E5}, S(═O)₂R^{E5}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{E4} radicals optionally joined to one another and may form a ring; where the alkyl, alkoxy, alkenyl and alkynyl groups and the aromatic ring systems and heteroaromatic ring systems are each substituted by R^{E5} radicals; and where one or more CH₂ groups in the alkyl, alkoxy, alkenyl and alkynyl groups is optionally replaced by —R^{E5}C═CR^{E5}—, —C≡C—, C═O, C═NR^{E5}, —C(═O)O—, —C(═O)NR^{E5}—, NR^{E5}, P(═O)(R^{E5}), —O—, —S—, SO or SO₂;
R^{E5} is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R^{E5} radicals optionally joined to one another and may form a ring; and where the alkyl, alkoxy, alkenyl and alkynyl groups, aromatic ring systems and heteroaromatic ring systems optionally substituted by one or more radicals selected from F and CN;
R^{E3-2} is selected from alkyl groups which have 1 to 10 carbon atoms and are substituted by R^{E4} radicals
a layer E which is disposed between the emitting layer and the second electrode and comprises a compound of a formula (E-1) 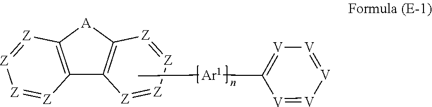
where
A is 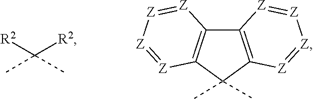
where the dotted bonds indicate the bonds of A to the rest of the formula;
Z, when no 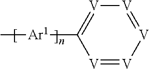
group is bonded thereto, is the same or different at each instance and is N and CR¹, and, when a 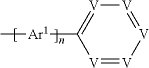
group is bonded thereto, is C;
V is the same or different at each instance and is selected from N and CR⁴, where at least two V groups in the ring must be N;
Ar¹ is the same or different at each instance and is selected from aromatic ring systems which have 6 to 40 aromatic ring atoms and are substituted by R³ radicals, and heteroaromatic ring systems which have 5 to 40 aromatic ring atoms and are substituted by R³ radicals;
R¹ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals optionally joined to one another and may form a ring; where the alkyl, alkoxy, alkenyl and alkynyl groups and the aromatic ring systems and heteroaromatic ring systems are each substituted by R⁵ radicals; and where one or more CH₂ groups in the alkyl, alkoxy, alkenyl and alkynyl groups is optionally replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R² is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R² radicals optionally joined to one another and may form a ring; where the alkyl, alkoxy, alkenyl and alkynyl groups and the aromatic ring systems and heteroaromatic ring systems are each substituted by R⁵ radicals; and where one or more CH₂ groups in the alkyl, alkoxy, alkenyl and alkynyl groups is optionally replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R³ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals optionally joined to one another and may form a ring; where the alkyl, alkoxy, alkenyl and alkynyl groups and the aromatic ring systems and heteroaromatic ring systems are each substituted by R⁵ radicals; and where one or more CH₂ groups in the alkyl, alkoxy, alkenyl and alkynyl groups is optionally replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R⁴ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals optionally joined to one another and may form a ring; where the alkyl, alkoxy, alkenyl and alkynyl groups and the aromatic ring systems and heteroaromatic ring systems are each substituted by R⁵ radicals; and where one or more CH₂ groups in the alkyl, alkoxy, alkenyl and alkynyl groups optionally replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R⁵ is the same or different at each instance and is selected from H, D, F, Cl, Br, I, C(═O)R⁶, CN, Si(R⁶)₃, N(R⁶)₂, P(═O)(R⁶)₂, OR⁶, S(═O)R⁶, S(═O)₂R⁶, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁵ radicals optionally joined to one another and may form a ring; where the alkyl, alkoxy, alkenyl and alkynyl groups and the aromatic ring systems and heteroaromatic ring systems are each substituted by R⁶ radicals; and where one or more CH₂ groups in the alkyl, alkoxy, alkenyl and alkynyl groups is optionally replaced by —R⁶C═CR⁶—, —C≡C—, Si(R⁶)₂, C═O, C═NR⁶, —C(═O)O—, —C(═O)NR⁶—, NR, P(═O)(R⁶), —O—, —S—, SO or SO₂;
R⁶ is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁶ radicals optionally joined to one another and may form a ring; and where the alkyl, alkoxy, alkenyl and alkynyl groups, aromatic ring systems and heteroaromatic ring systems is optionally substituted by one or more radicals selected from F and CN.

22. The electronic device as claimed in claim 21, wherein Z is CR¹ when no 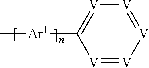
group is bonded thereto.

23. The electronic device as claimed in claim 21, wherein 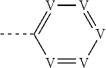
groups are selected from the following groups: 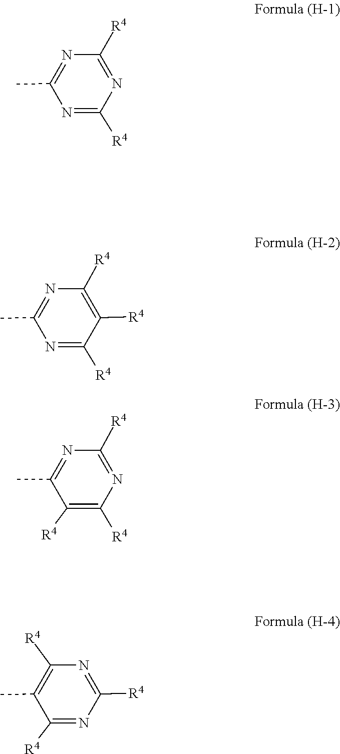
where the dotted line represents the bond to the rest of the formula.

24. The electronic device as claimed in claim 21, wherein Ar¹ is the same or different at each instance and is selected from divalent groups derived from benzene, biphenyl, terphenyl, naphthalene, fluorene, indenofluorene, indenocarbazole, spirobifluorene, dibenzofuran, dibenzothiophene, and carbazole, each of which optionally substituted by one or more R³ radicals.

25. The electronic device as claimed in claim 21, wherein the device is an organic electroluminescent device, wherein the first electrode is an anode, in that the second electrode is a cathode, and in that layer E is an electron transport layer.

26. The electronic device as claimed in claim 21, wherein layer E comprises a mixture of an alkali metal salt and a further compound.

27. The electronic device as claimed in claim 21, wherein the device comprises the following layers between anode and cathode:
at least one hole-transporting layer between anode and emitting layer;
the emitting layer between hole-transporting layer and cathode; and
layer E as electron transport layer between emitting layer and cathode.

28. The electronic device as claimed in claim 21, wherein the emitting layer of the device, as well as the compound of the formula (EM-1-1-1-1-2), comprises one or more further compounds selected from anthracene derivatives and benzanthracene derivatives.

29. The electronic device as claimed in claim 21, wherein the device comprises two or three identical or different layer sequences stacked one on top of another, where each of the layer sequences comprises the following layers: hole injection layer, hole transport layer, electron blocker layer, emitting layer, and electron transport layer, and wherein at least one of the layer sequences comprises
an emitting layer comprising a compound of the formula (EM-1-1-1-1-2), and
a layer E.

30. The electronic device as claimed in claim 21, wherein the device emits light through the cathode.

31. A process for producing an electronic device as claimed in claim 21, comprising the following steps: first providing a substrate with anode, in a later step applying the emitting layer comprising the compound of the formula (EM-1-1-1-1-2)), in a subsequent step applying layer E, and in a subsequent step applying the anode.

32. A method comprising incorporating the electronic device as claimed in claim 21 in displays, as a light source in lighting applications, or as a light source in medical and/or cosmetic applications.
